(19) United States
(12) Patent Application Publication
(10) Pub. No.: US 2023/0320203 A1
(43) Pub. Date: Oct. 5, 2023

(54) PLURALITY OF HOST MATERIALS, ORGANIC ELECTROLUMINESCENT COMPOUND, AND ORGANIC ELECTROLUMINESCENT DEVICE COMPRISING THE SAME

(71) Applicant: ROHM AND HAAS ELECTRONIC MATERIALS KOREA LTD., Chungcheongnam-do (KR)

(72) Inventors: Hyo-Soon PARK, Gyeonggi-do (KR); Jeong-Hwan JEON, Gyeonggi-do (KR); Hee-Ryong KANG, Gyeonggi-do (KR); Sang-Hee CHO, Gyeonggi-do (KR); Dong-Hyung LEE, Gyeonggi-do (KR); Jin-Man KIM, Gyeonggi-do (KR); Hong-Se OH, Gyeonggi-do (KR); Hyun-Woo KANG, Gyeonggi-do (KR)

(21) Appl. No.: 18/186,564

(22) Filed: Mar. 20, 2023

(30) Foreign Application Priority Data
Apr. 5, 2022 (KR) 10-2022-0042328
Mar. 9, 2023 (KR) 10-2023-0031333

(51) Int. Cl. H10K 85/60

(52) U.S. Cl. CPC H10K 85/636; H10K 50/11

(57) ABSTRACT

The present disclosure relates to a plurality of host materials, an organic electroluminescent compound, and an organic electroluminescent device comprising the same. By comprising a specific combination of compounds according to the present disclosure as a plurality of host materials, or by comprising the compound according to the present disclosure, an organic electroluminescent device having improved driving voltage, luminous efficiency and/or lifespan characteristics compared to conventional organic electroluminescent devices can be provided.

### TECHNICAL FIELD

The present disclosure relates to a plurality of host materials, an organic electroluminescent compound, and an organic electroluminescent device comprising the same.

### BACKGROUND ART

In 1987, Tang et al. of Eastman Kodak first developed a small molecular green organic electroluminescent device (OLED) by using TPD/Alq₃ bilayer consisting of a light-emitting layer and a charge transport layer. Thereafter, the development of OLEDs was rapidly effected and OLEDs have been commercialized. Currently, OLEDs mainly use phosphorescent materials having excellent luminous efficiency in panel implementation. In many applications such as TVs and lightings, the lifespan of OLEDs is insufficient and the higher efficiency of OLEDs is still required. Typically, the higher the luminance of an OLED, the shorter the lifespan the OLED has. Thus, OLEDs having high luminous efficiency and/or long lifespan are required for long-term use and high resolution of a display.

In order to improve luminous efficiency, driving voltage, and/or lifespan, various materials or concepts for an organic layer of an organic electroluminescent device have been proposed, but they were not satisfactory in practical use. Accordingly, there has been a continuous need to develop organic electroluminescent materials having more improved performances, for example, improved driving voltage, luminous efficiency, power efficiency, and/or lifespan properties, compared to a combination of specific compounds previously disclosed.

On the other hand, Chinese Patent Application Laid-open No. 110903258 discloses aromatic amine compounds. However, the aforementioned reference fails to specifically disclose specific compounds and specific combinations of host materials claimed in the present disclosure. Also, there has been a continuous need to develop light-emitting materials having more improved performances, for example, improved driving voltage, luminous efficiency, and/or lifespan properties, compared to a combination of specific compounds previously disclosed.

### DISCLOSURE OF INVENTION

### Technical Problem

An objective of the present disclosure is to provide a plurality of host materials capable of producing an organic electroluminescent device with improved driving voltage, luminous efficiency, and/or lifespan properties. Another objective of the present disclosure is to provide an organic electroluminescent compound having a novel structure suitable for application to organic electroluminescent devices. Still another objective of the present disclosure is to provide an organic electroluminescent device with improved driving voltage, luminous efficiency, and/or lifespan properties by comprising the compound according to the present disclosure or a specific combination of the compounds according to the present disclosure.

### Solution to Problem

As a result of intensive research to solve the above technical problems, the present inventors found that the above objectives can be achieved by a plurality of host materials comprising a first host material and a second host material, wherein the first host material comprises a compound represented by the following Formula 1, and the second host material comprises a compound represented by the following Formula 2. In addition, the present inventors found that the above objectives can be achieved by a compound represented by the following Formula 11.

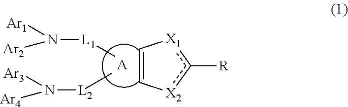

In Formula 1,
one of X₁ and X₂ represents —N═, and the other represents —O— or —S—;
R represents a substituted or unsubstituted (C1-C30)alkyl, a substituted or unsubstituted (C6-C30)aryl, or a substituted or unsubstituted (3- to 30-membered)heteroaryl;
ring A represents a (C6-C12)arene;
L₁ and L₂ each independently represent a single bond, a substituted or unsubstituted (C6-C30)arylene, or a substituted or unsubstituted (3- to 30-membered)heteroarylene; and
Ar₁ to Ar₄ each independently represent a substituted or unsubstituted (C6-C30)aryl, or a substituted or unsubstituted (3- to 30-membered)heteroaryl;

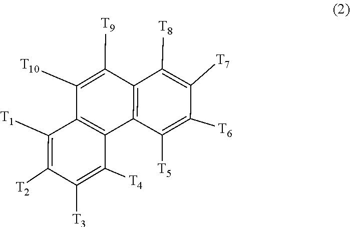

in Formula 2,
T₅ and T₆, T₇ and T₈, or both thereof are linked to each other to form a ring of the following Formula 3:

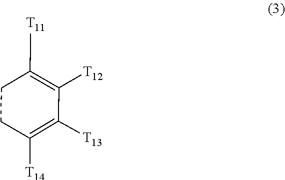

in Formulas 2 and 3,
T₁ to T₄, T₉ to T₁₄, and T₅ to T₈ that do not form a ring(s) each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, a substituted or unsubstituted (C6-C30)aryl(3- to 30-membered)heteroarylamino, or -L₃-Ar₅, provided that at least one of T₁ to T₁₄ represents -L₃-Ar₅;
L₃ each independently represents a single bond, a substituted or unsubstituted (C6-C30)arylene, or a substituted or unsubstituted (3- to 30-membered)heteroarylene;
Ar₅ each independently represents a substituted or unsubstituted (C6-C30)aryl or a substituted or unsubstituted (3- to 30-membered)heteroaryl;
[symbol] represents a fusion site with Formula 2; and
the heteroaryl and the heteroarylene contain one or more heteroatoms selected from B, N, O, S, Si and P.

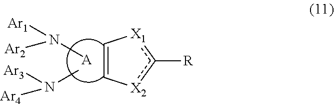

In Formula 11,
one of X₁ and X₂ represents —N═, and the other represents —O— or —S—;
R represents a substituted or unsubstituted (C1-C30)alkyl, a substituted or unsubstituted (C6-C30)aryl, or a substituted or unsubstituted (3- to 30-membered)heteroaryl;
ring A represents a (C6-C12)arene; and
Ar₁ to Ar₄ each independently represent a substituted or unsubstituted (C6-C30)aryl, or a substituted or unsubstituted (3- to 30-membered)heteroaryl;
provided that, when ring A is benzene, —N(Ar₁)(Ar₂) and —N(Ar₃)(Ar₄) are at an ortho or meta position to each other.

### Advantageous Effects of Invention

By comprising a specific combination of compounds according to the present disclosure as a plurality of host materials or by comprising the compound according to the present disclosure, an organic electroluminescent device having lower driving voltage, higher luminous efficiency and/or excellent lifespan properties compared to a conventional organic electroluminescent device is provided. In addition, it is possible to manufacture a display device or a lighting device using the same.

### MODE FOR THE INVENTION

Hereinafter, the present disclosure will be described in detail. However, the following description is intended to explain the present disclosure, and is not meant to restrict the scope of the present disclosure.

The term “organic electroluminescent compound” in the present disclosure means a compound that may be used in an organic electroluminescent device, and may be comprised in any layer constituting an organic electroluminescent device, as necessary.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (including a host material and a dopant material), an electron buffer material, a hole blocking material, an electron transport material, an electron injection material, etc.

The term “a plurality of host materials” in the present disclosure means a host material comprising a combination of two or more compounds that may be comprised in any light-emitting layer constituting an organic electroluminescent device. It may mean both a material before being comprised in an organic electroluminescent device (i.e. before vapor deposition) and a material after being comprised in an organic electroluminescent device (i.e. after vapor deposition). For example, the plurality of host materials of the present disclosure may be a combination of at least two host materials, which, optionally, may further comprise conventional materials included in the organic electroluminescent material. At least two compounds comprised in the plurality of host materials may be comprised together in one light-emitting layer, or each may be comprised in different light-emitting layers. For example, the at least two host materials may be mixture-evaporated or co-evaporated, or may be separately evaporated.

Herein, the term “(C1-C30)alkyl” is meant to be a linear or branched alkyl having 1 to 30 carbon atoms constituting the chain, in which the number of carbon atoms is preferably 1 to 10, and more preferably 1 to 6. The above alkyl may include methyl, ethyl, n-propyl, isopropyl, n-butyl, isobutyl, tert-butyl, sec-butyl, etc. The term “(C3-C30)cycloalkyl” is meant to be a monocyclic or polycyclic hydrocarbon having 3 to 30 ring backbone carbon atoms, and preferably 3 to 20 ring backbone carbon atoms, more preferably 3 to 7 ring backbone carbon atoms. Examples of the cycloalkyl may include cyclopropyl, cyclobutyl, cyclopentyl, cyclohexyl, cyclopentylmethyl, cyclohexylmethyl, etc. The term “(3- to 7-membered)heterocycloalkyl” in the present disclosure is meant to be a cycloalkyl having 3 to 7 ring backbone atoms and containing at least one heteroatom(s) selected from the group consisting of B, N, O, S, Si, and P, preferably the group consisting of O, S, and N. The above heterocycloalkyl includes tetrahydrofuran, pyrrolidine, thiolane, tetrahydropyran, etc. The term “(C6-C30)aryl,” “(C6-C30)arylene” or “(C6-C30)arene” in the present disclosure is meant to be a monocyclic or fused ring radical derived from an aromatic hydrocarbon having 6 to 30 ring backbone carbon atoms. The above aryl may be partially saturated, and may comprise a spiro structure. The above aryl may include phenyl, biphenyl, terphenyl, quinquephenyl, naphthyl, binaphthyl, phenylnaphthyl, naphthylphenyl, fluorenyl, phenylfluorenyl, diphenylfluorenyl, benzofluorenyl, dibenzofluorenyl, phenanthrenyl, phenylphenanthrenyl, benzophenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluorene]yl, spiro[cyclopentene-fluorene]yl, spiro[dihydroindene-fluorene]yl, azulenyl, tetramethyldihydrophenanthrenyl, etc. More specifically, the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenylyl, 3-biphenylyl, 4-biphenylyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The term “(3- to 30-membered)heteroaryl” or “(3- to 30-membered)heteroarylene” in the present disclosure is meant to be an aryl or arylene having 3 to 30 ring backbone atoms and including at least one, preferably 1 to 4 heteroatom(s) selected from the group consisting of B, N, O, S, Si, and P. It may be a monocyclic ring or a fused ring condensed with at least one benzene ring, and may be partially saturated. In addition, the above heteroaryl or heteroarylene comprises one formed by linking at least one heteroaryl or aryl group to a heteroaryl group via a single bond(s), and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, dibenzoselenophenyl, naphthobenzofuranyl, naphthobenzothiophenyl, naphthooxazolyl, benzofuroquinolyl, benzofuroquinazolinyl, benzofuronaphthyridinyl, benzofuropyrimidinyl, naphthofuropyrimidinyl, benzothienoquinolyl, benzothienoquinazolinyl, naphthyridinyl, benzothienonaphthyridinyl, benzothienopyrimidinyl, naphthothienopyrimidinyl, pyrimidoindolyl, benzopyrimidoindolyl, benzofuropyrazinyl, naphtofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzooxazolyl, isoindolyl, indolyl, indazolyl, benzothiadiazolyl, quinolyl, isoquinolyl, cinnolinyl, quinazolinyl, benzoquinazolinyl, quinoxalinyl, benzoquinoxalinyl, carbazolyl, benzocarbazolyl, dibenzocarbazolyl, phenoxazinyl, phenanthridinyl, benzodioxolyl, dihydroacridinyl, benzotriazolephenazinyl, imidazopyridyl, chromenoquinazolinyl, thiochromenoquinazolinyl, dimethylbenzoperimidinyl, indolocarbazolyl, indenocarbazolyl, etc. More specifically, the heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. In the present disclosure, “halogen” includes F, Cl, Br, and I.

In addition, “ortho (o-),” “meta (m-),” and “para (p-)” are prefixes, which represent the relative positions of substituents, respectively. Ortho indicates that two substituents are adjacent to each other, and for example, when two substituents in a benzene derivative occupy positions 1 and 2 or positions 2 and 3, it is called an ortho position. Meta indicates that two substituents are at positions 1 and 3, and for example, when two substituents in a benzene derivative occupy positions 1 and 3, it is called a meta position. Para indicates that two substituents are at positions 1 and 4, and for example, when two substituents in a benzene derivative occupy positions 1 and 4, it is called a para position.

In addition, “substituted” in the expression “substituted or unsubstituted” means that a hydrogen atom in a certain functional group is replaced with another atom or another functional group (i.e., a substituent), and also includes that the hydrogen atom is replaced with a group formed by a linkage of two or more substituents of the above substituents. For example, the “group formed by a linkage of two or more substituents” may be pyridine-triazine. That is, pyridine-triazine may be interpreted as a heteroaryl substituent, or as a substituent in which two heteroaryls are linked. Herein, the substituent(s) of the substituted alkyl, the substituted aryl, the substituted arylene, the substituted heteroaryl, the substituted heteroarylene, the substituted cycloalkyl, the substituted alkoxy, the substituted trialkylsilyl, the substituted dialkylarylsilyl, the substituted alkyldiarylsilyl, the substituted triarylsilyl, the substituted fused ring group of an aliphatic ring(s) and an aromatic ring(s), the substituted mono- or di-alkylamino, the substituted mono- or di-alkenylamino, the substituted alkylalkenylamino, the substituted mono- or di-arylamino, the substituted alkylarylamino, the substituted mono- or di-heteroarylamino, the substituted alkylheteroarylamino, the substituted alkenylarylamino, the substituted alkenylheteroarylamino, and the substituted arylheteroarylamino each independently are at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with at least one of a (C1-C30)alkyl(s) and a (C6-C30)aryl(s); a (C6-C30)aryl unsubstituted or substituted with at least one of deuterium, a cyano(s), a halogen(s), a (C1-C30)alkyl(s), a (C3-C30)cycloalkyl(s), a tri(C1-C30)alkylsilyl(s), a tri(C6-C30)arylsilyl(s), a (C6-C30)aryl(s), and a (3- to 30-membered)heteroaryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsilyl; a fused ring group of a (C3-C30) aliphatic ring(s) and a (C6-C30) aromatic ring(s); an amino; a mono- or di-(C1-C30)alkylamino; a mono- or di-(C2-C30)alkenylamino; a (C1-C30)alkyl(C2-C30)alkenylamino; a mono- or di-(C6-C30)arylamino; a (C1-C30)alkyl(C6-C30)arylamino; a mono- or di-(3- to 30-membered)heteroarylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a (C6-C30)arylphosphine; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. According to one embodiment of the present disclosure, the substituent(s), each independently, are at least one selected from the group consisting of a halogen; a cyano; a (C1-C20)alkyl; a (C3-C25)cycloalkyl; a (5- to 25-membered)heteroaryl unsubstituted or substituted with a (C6-C25)aryl(s); a (C6-C25)aryl unsubstituted or substituted with at least one of a halogen(s), a cyano(s), a (C1-C20)alkyl(s), a (C3-C25)cycloalkyl(s), a tri(C1-C20)alkylsilyl(s), a tri(C6-C25)arylsilyl(s), a (C6-C25)aryl(s) and a (5- to 25-membered)heteroaryl(s); a tri(C1-C20)alkylsilyl; and a tri(C6-C25)arylsilyl. According to another embodiment of the present disclosure, the substituent(s), each independently, are at least one selected from the group consisting of a cyano; a (C1-C10)alkyl; a (C3-C18)cycloalkyl; a (5- to 20-membered)heteroaryl unsubstituted or substituted with a (C6-C18)aryl(s); a (C6-C25)aryl unsubstituted or substituted with at least one of a cyano(s), a halogen(s), a (C1-C10)alkyl(s), a (C3-C18)cycloalkyl(s), a tri(C1-C10)alkylsilyl(s), a tri(C6-C18)arylsilyl(s), a (C6-C18)aryl(s) and a (5- to 20-membered)heteroaryl(s); a tri(C1-C10)alkylsilyl; and a tri(C6-C18)arylsilyl. For example, the substituent(s), each independently, may be at least one selected from the group consisting of a fluoro; a methyl; a substituted or unsubstituted phenyl; a naphthyl; a biphenyl; a phenanthrenyl; a dimethylfluorenyl; a diphenylfluorenyl; an anthracenyl; a naphthylphenyl; a phenylnaphthyl; a terphenyl; a chrysenyl; a triphenylenyl; a spirobifluorenyl; a (C22)aryl; a pyridyl substituted with a phenyl(s); a benzofuranyl; a benzothiophenyl; a dibenzofuranyl unsubstituted or substituted with a phenyl(s) or a biphenyl(s); a dibenzothiophenyl; a carbazolyl unsubstituted or substituted with a phenyl(s); a naphthooxazolyl unsubstituted or substituted with a phenyl(s); a phenoxazinyl etc., wherein the substituent(s) of the substituted phenyl(s) may be at least one selected from the group consisting of a cyano, a fluoro, a tert-butyl, a cyclohexyl, a carbazolyl, a trimethylsilyl and a triphenylsilyl.

In the present disclosure, a heteroaryl, a heteroarylene, and a heterocycloalkyl, each independently, may include at least one heteroatom(s) selected from the group consisting of B, N, O, S, Si and P. In addition, the heteroatom may be bonded to at least one selected from the group consisting of hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, and a substituted or unsubstituted (C6-C30)aryl(3- to 30-membered)heteroarylamino.

The plurality of host materials according to the present disclosure comprise a first host material and a second host material, wherein the first host material comprises at least one compound represented by Formula 1, and the second host material comprises at least one compound represented by Formula 2. According to one embodiment of the present disclosure, the compound represented by Formula 1 and the compound represented by Formula 2 are different from each other.

The present disclosure provides a compound represented by Formula 1, 2 or 11. The present disclosure can provide an organic electroluminescent material or an organic electroluminescent device comprising the organic electroluminescent compound, and the organic electroluminescent compound may be comprised as a host material in a light-emitting layer.

In Formulas 1 and 11, X₁ and X₂ are each independently —N═, —O— or —S—. According to one embodiment of the present disclosure, one of X₁ and X₂ represents —N═, and the other represents —O— or —S—. According to another embodiment of the present disclosure, one of X₁ and X₂ represents —N═, and the other represents —O—.

In Formulas 1 and 11, R represents a substituted or unsubstituted (C1-C30)alkyl, a substituted or unsubstituted (C6-C30)aryl, or a substituted or unsubstituted (3- to 30-membered)heteroaryl. According to one embodiment of the present disclosure, R represents a substituted or unsubstituted (C6-C25)aryl, or a substituted or unsubstituted (5- to 25-membered)heteroaryl. According to another embodiment of the present disclosure, R represents an unsubstituted (C6-C18)aryl, or an unsubstituted (5- to 20-membered)heteroaryl. For example, R may be a phenyl, a naphthyl, or a dibenzofuranyl, etc.

In Formulas 1 and 11, ring A represents a (C6-C12)arene. For example, ring A may be a benzene or a naphthalene.

In Formulas 1 and 11, L₁ and L₂ each independently represent a single bond, a substituted or unsubstituted (C6-C30)arylene, or a substituted or unsubstituted (3- to 30-membered)heteroarylene. According to one embodiment of the present disclosure, L₁ and L₂ each independently represent a single bond, or a substituted or unsubstituted (C6-C25)arylene. According to another embodiment of the present disclosure, L₁ and L₂ each independently represent a single bond, or an unsubstituted (C6-C18)arylene. For example, L₁ and L₂ may each independently be a single bond or a phenylene, etc.

In Formulas 1 and 11, Ar₁ to Ar₄ each independently represent a substituted or unsubstituted (C6-C30)aryl, or a substituted or unsubstituted (3- to 30-membered)heteroaryl. According to one embodiment of the present disclosure, Ar₁ to Ar₄ each independently represent a substituted or unsubstituted (C6-C18)aryl, or a substituted or unsubstituted (5- to 25-membered)heteroaryl. According to another embodiment of the present disclosure, Ar₁ to Ar₄ each independently represent a (C6-C18)aryl unsubstituted or substituted with a (C1-C30)alkyl(s), or a (5- to 20-membered)heteroaryl unsubstituted or substituted with a (C6-C18)aryl(s). For example, Ar₁ to Ar₄ may each independently be a phenyl, a naphthyl, a biphenyl, a dimethylfluorenyl, a phenanthrenyl, a terphenyl, a dibenzofuranyl, a dibenzothiophenyl, or a carbazolyl substituted with a phenyl(s), etc.

According to one embodiment of the present disclosure, in Formula 1, R and Ar₁ to Ar₄ each independently represent a substituted or unsubstituted phenyl, a substituted or unsubstituted naphthyl, a substituted or unsubstituted biphenyl, a substituted or unsubstituted terphenyl, a substituted or unsubstituted phenanthrenyl, a substituted or unsubstituted fluorenyl, a substituted or unsubstituted benzofluorenyl, a substituted or unsubstituted triphenylenyl, a substituted or unsubstituted spirobifluorenyl, a substituted or unsubstituted triazinyl, a substituted or unsubstituted pyrimidinyl, a substituted or unsubstituted quinolyl, a substituted or unsubstituted quinazolinyl, a substituted or unsubstituted quinoxalinyl, a substituted or unsubstituted benzoquinazolinyl, a substituted or unsubstituted benzoquinoxalinyl, a substituted or unsubstituted benzofuropyrimidinyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzonaphthofuranyl, or a substituted or unsubstituted benzonaphthothiophenyl.

According to one embodiment of the present disclosure, in Formula 11, R represents a substituted or unsubstituted phenyl, a substituted or unsubstituted biphenyl, a substituted or unsubstituted terphenyl, a substituted or unsubstituted naphthyl, a substituted or unsubstituted phenylnaphthyl, a substituted or unsubstituted naphthylphenyl, a substituted or unsubstituted phenanthrenyl, a substituted or unsubstituted dibenzofuranyl, or a substituted or unsubstituted dibenzothiophenyl.

According to one embodiment of the present disclosure, when ring A in Formula 1 is a benzene, -L₁-N(Ar₁)(Ar₂) and -L₂-N(Ar₃)(Ar₄) are at an ortho or meta position to each other. When ring A in Formula 11 is a benzene, —N(Ar₁)(Ar₂) and —N(Ar₃)(Ar₄) are at an ortho or meta position to each other.

According to one embodiment of the present disclosure, Formula 1 may be represented by at least one of the following Formulas 4 to 6.

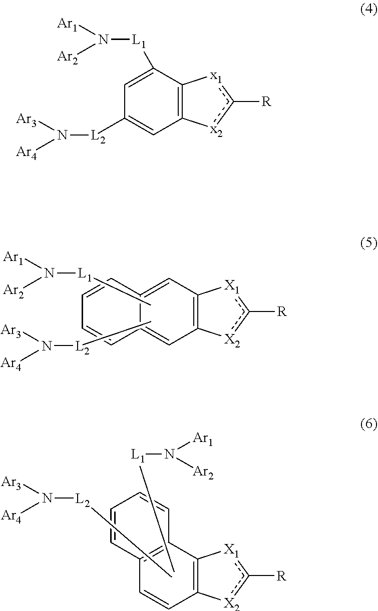

In Formulas 4 to 6, R, X₁, X₂, L₁, L₂, and Ar₁ to Ar₄ are as defined in Formula 1.

In Formula 2, T₅ and T₆, T₇ and T₈, or both thereof are linked to each other to form the ring of Formula 3. According to one embodiment of the present disclosure, T₅ and T₆ are linked to each other to form the ring of Formula 3, or T₇ and T₈ are linked to each other to form the ring of Formula 3.

In Formulas 2 and 3, T₁ to T₄, T₉ to T₁₄, and T₅ to T₈ that do not form a ring(s) each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, a substituted or unsubstituted (C6-C30)aryl(3- to 30-membered)heteroarylamino, or -L₃-Ar₅. According to one embodiment of the present disclosure, T₁ to T₄, T₉ to T₁₄, and T₅ to T₈ that do not form a ring(s) each independently represent hydrogen, a substituted or unsubstituted (C6-C25)aryl, or -L₃-Ar₅. According to another embodiment of the present disclosure, T₁ to T₄, T₉ to T₁₄, and T₅ to T₈ that do not form a ring(s) each independently represent hydrogen, an unsubstituted (C6-C18)aryl, or -L₃-Ar₅. For example, T₁ to T₄, T₉ to T₁₄, and T₅ to T₈ that do not form a ring(s) each independently represent hydrogen, a phenyl, a naphthyl, a biphenyl, or -L₃-Ar₅. At least one of T₁ to T₁₄ represents -L₃-Ar₅. According to one embodiment of the present disclosure, at least one of T₁ to T₁₄ is -L₃-Ar₅.

L₃ each independently represents a single bond, a substituted or unsubstituted (C6-C30)arylene, or a substituted or unsubstituted (3- to 30-membered)heteroarylene. According to one embodiment of the present disclosure, L₃ each independently represents a single bond, or a substituted or unsubstituted (C6-C25)arylene. According to another embodiment of the present disclosure, L₃ each independently represents a single bond, or a (C6-C18)arylene unsubstituted or substituted with a (C6-C18)aryl(s). For example, L₃ may each independently be a single bond, a phenylene unsubstituted or substituted with a phenyl(s), a naphthylene, or a biphenylene, etc.

Ar₅ each independently represents a substituted or unsubstituted (C6-C30)aryl, or a substituted or unsubstituted (3- to 30-membered)heteroaryl. According to one embodiment of the present disclosure, Ar₅ each independently represents a substituted or unsubstituted (5- to 25-membered)heteroaryl, and the substituent(s) of the substituted heteroaryl may be at least one selected from the group consisting of a cyano, a halogen, a (C1-C30)alkyl, a (C3-C30)cycloalkyl, a (C6-C30)aryl, a (3- to 30-membered)heteroaryl, a tri(C1-C30)alkylsilyl and a tri(C6-C30)arylsilyl. Specifically, Ar₅ may be a substituted or unsubstituted triazinyl, a substituted or unsubstituted pyrimidinyl, a substituted or unsubstituted quinolyl, a substituted or unsubstituted isoquinolyl, a substituted or unsubstituted benzothienoquinolyl, a substituted or unsubstituted naphthyridinyl, a substituted or unsubstituted quinazolinyl, a substituted or unsubstituted quinoxalinyl, a substituted or unsubstituted benzoquinazolinyl, a substituted or unsubstituted dibenzoquinazolinyl, a substituted or unsubstituted benzoquinoxalinyl, a substituted or unsubstituted dibenzoquinoxalinyl, a substituted or unsubstituted benzofuropyrimidinyl, a substituted or unsubstituted acenaphthopyrimidinyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzonaphthofuranyl, a substituted or unsubstituted benzonaphthothiophenyl, a substituted or unsubstituted benzoimidazolyl, or a substituted or unsubstituted phenanthroimidazolyl. For example, Ar₅ may be a substituted triazinyl, a substituted pyrimidinyl, a quinolyl substituted with a phenyl(s), an isoquinolyl substituted with a phenyl(s), an unsubstituted benzothienoquinolyl, a naphthyridinyl substituted with a phenyl(s), a quinazolinyl substituted with at least one of a phenyl(s) and a biphenyl(s), a quinoxalinyl substituted with at least one of a phenyl(s) and a biphenyl(s), a benzoquinoxalinyl substituted with a biphenyl(s), a dibenzoquinoxalinyl substituted with a biphenyl(s), a benzofuropyrimidinyl substituted with a biphenyl(s), an acenaphthopyrimidinyl substituted with a phenyl(s), a benzoimidazolyl substituted with a phenyl(s), a phenanthroimidazolyl substituted with a phenyl(s), a nitrogen-containing 17-membered heteroaryl substituted with a methyl(s), a 25-membered heteroaryl containing N and O, etc. The substituent(s) of the substituted triazinyl may be at least two selected from the group consisting of a phenyl unsubstituted or substituted with a cyano(s), a fluoro(s), a tert-butyl(s), a cyclohexyl(s), a carbazolyl(s), a trimethylsilyl(s) or a triphenylsilyl(s); a naphthyl; a biphenyl; a phenanthrenyl; a dimethylfluorenyl; a diphenylfluorenyl; an anthracenyl; a naphthylphenyl; a phenylnaphthyl; a terphenyl; a chrysenyl; a triphenylenyl; a spirobifluorenyl; a (C-22) aryl; a benzothiophenyl; a dibenzofuranyl unsubstituted or substituted with a phenyl(s) or a biphenyl(s); a dibenzothiophenyl; a carbazolyl unsubstituted or substituted with a phenyl(s); a naphthooxazolyl substituted with a phenyl(s); and a phenoxazinyl. The substituent(s) of the substituted pyrimidinyl may be at least one selected from the group consisting of a fluoro, a phenyl, a biphenyl, a pyridyl substituted with a phenyl(s) and a dibenzofuranyl.

In Formula 3, [symbol] represents a fusion site with Formula 2.

The heteroaryl and the heteroarylene contain one or more heteroatoms selected from B, N, O, S, Si and P.

According to one embodiment of the present disclosure, Formula 2 may be represented by at least one of the following Formulas 2-1 and 2-2.

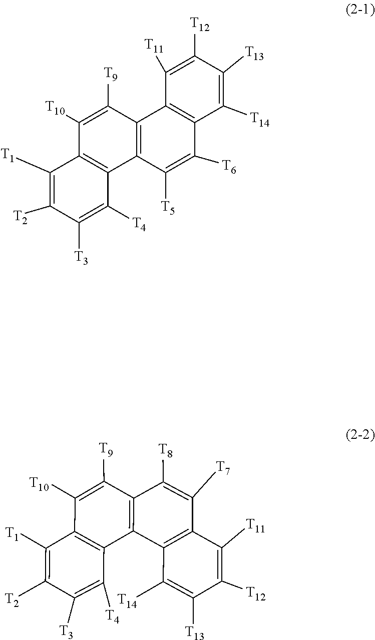

In Formulas 2-1 and 2-2, T₁ to T₄ and T₉ to T₁₄ are as defined in Formula 2, and T₅ to T₈ are as defined for T₅ to T₈ which do not form a ring(s) in Formula 2.

According to one embodiment of the present disclosure, Formula 2 may be represented by at least one of following Formulas.

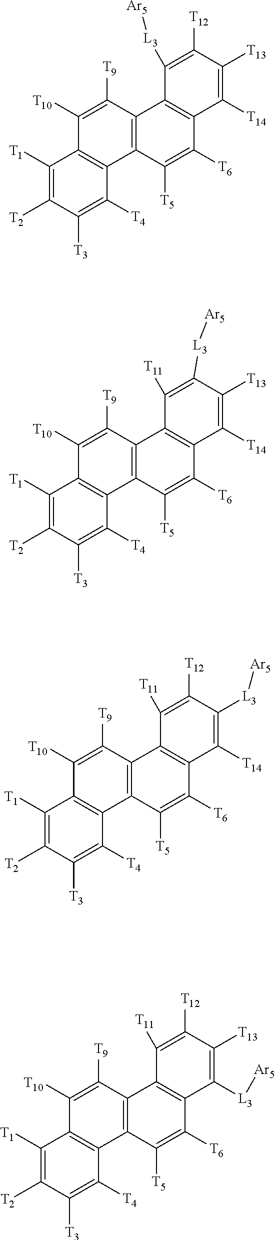

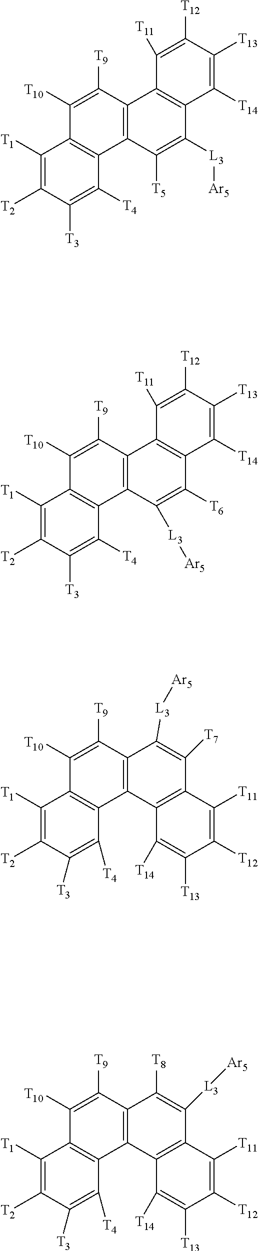

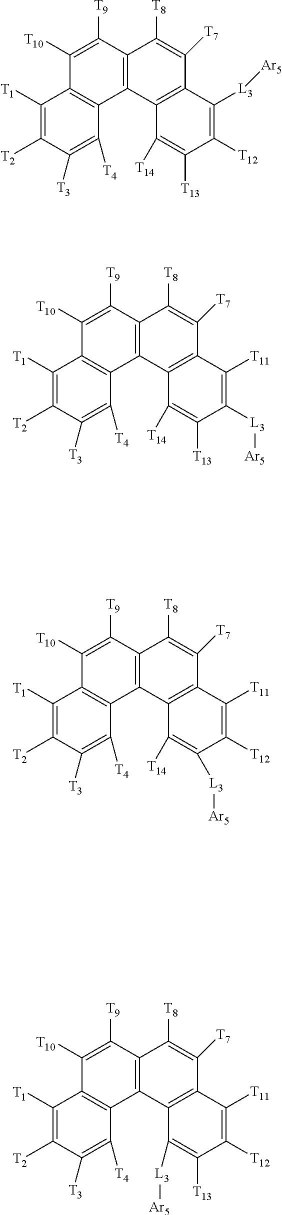

In the above Formulas,
T₁ to T₁₄ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino, and
L₃ and Ar₅ are as defined in Formula 2.

The compound represented by Formula 1 may be at least one selected from the following compounds, but is not limited thereto.

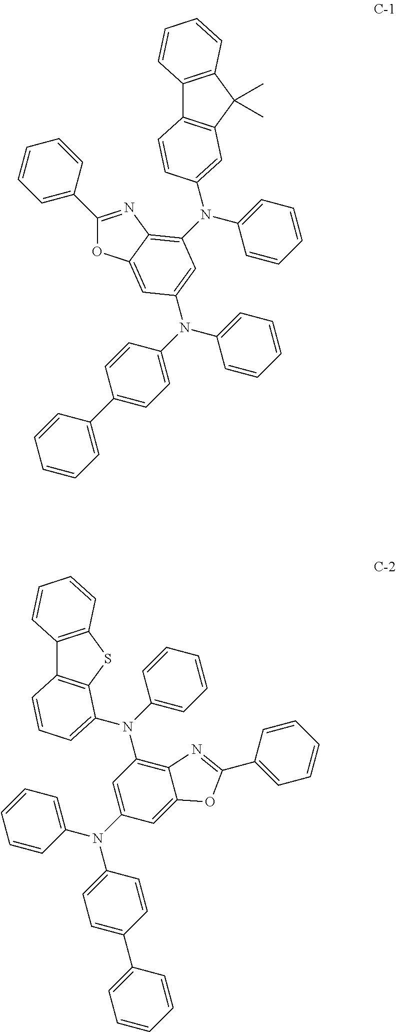 [SMILES: CC1(C)c2ccccc2-c2ccc(N(c3ccccc3)c3cc(N(c4ccccc4)c4ccc(-c5ccccc5)cc4)cc4oc(-c5ccccc5)nc34)cc21 ; c1ccc(-c2ccc(N(c3ccccc3)c3cc(N(c4ccccc4)c4cccc5c4sc4ccccc45)c4nc(-c5ccccc5)oc4c3)cc2)cc1]

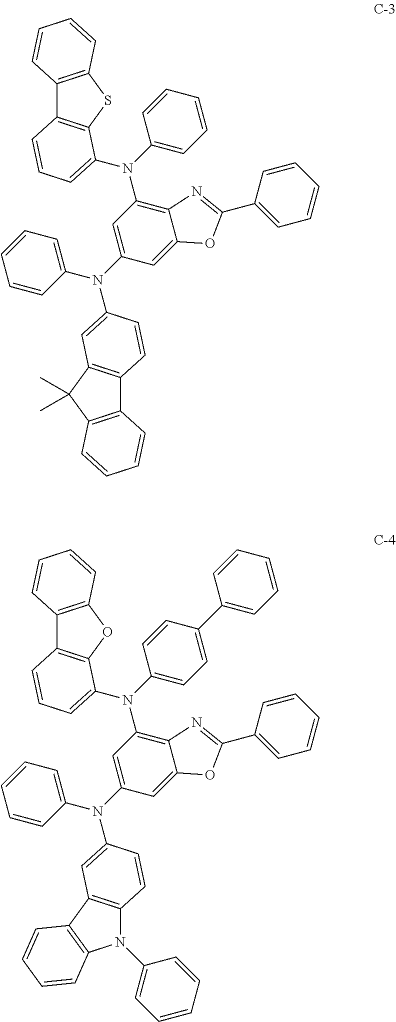 [SMILES: CC1(C)c2ccccc2-c2ccc(N(c3ccccc3)c3cc(N(c4ccccc4)c4cccc5c4sc4ccccc45)c4nc(-c5ccccc5)oc4c3)cc21 ; c1ccc(-c2ccc(N(c3cc(N(c4ccccc4)c4ccc5c(c4)c4ccccc4n5-c4ccccc4)cc4oc(-c5ccccc5)nc34)c3cccc4c3oc3ccccc34)cc2)cc1]

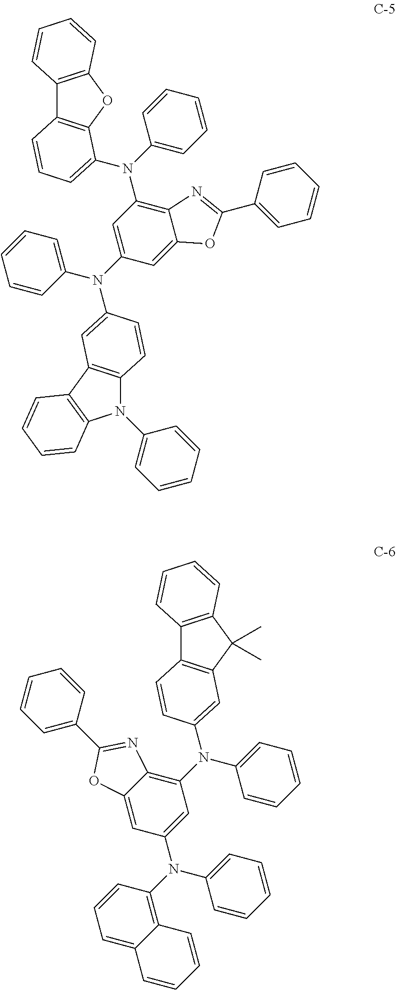 [SMILES: c1ccc(-c2nc3c(N(c4ccccc4)c4cccc5c4oc4ccccc45)cc(N(c4ccccc4)c4ccc5c(c4)c4ccccc4n5-c4ccccc4)cc3o2)cc1 ; CC1(C)c2ccccc2-c2ccc(N(c3ccccc3)c3cc(N(c4ccccc4)c4cccc5ccccc45)cc4oc(-c5ccccc5)nc34)cc21]

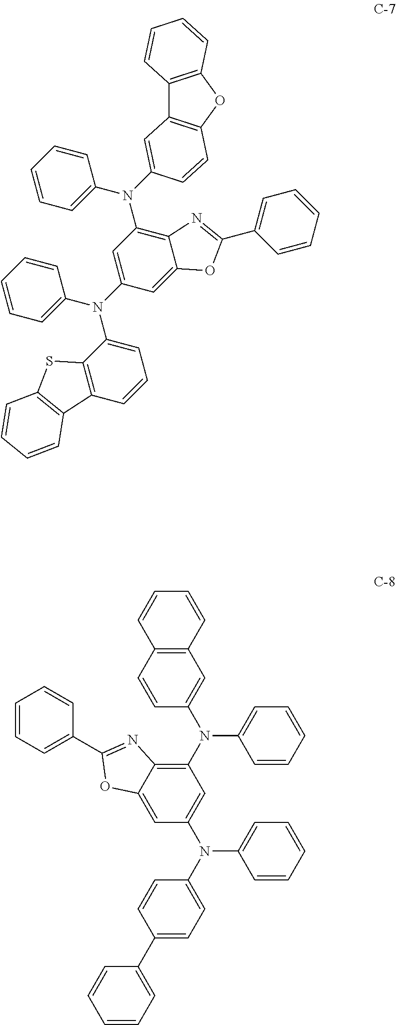 [SMILES: c1ccc(-c2nc3c(N(c4ccccc4)c4ccc5oc6ccccc6c5c4)cc(N(c4ccccc4)c4cccc5c4sc4ccccc45)cc3o2)cc1 ; c1ccc(-c2ccc(N(c3ccccc3)c3cc(N(c4ccccc4)c4ccc5ccccc5c4)c4nc(-c5ccccc5)oc4c3)cc2)cc1]

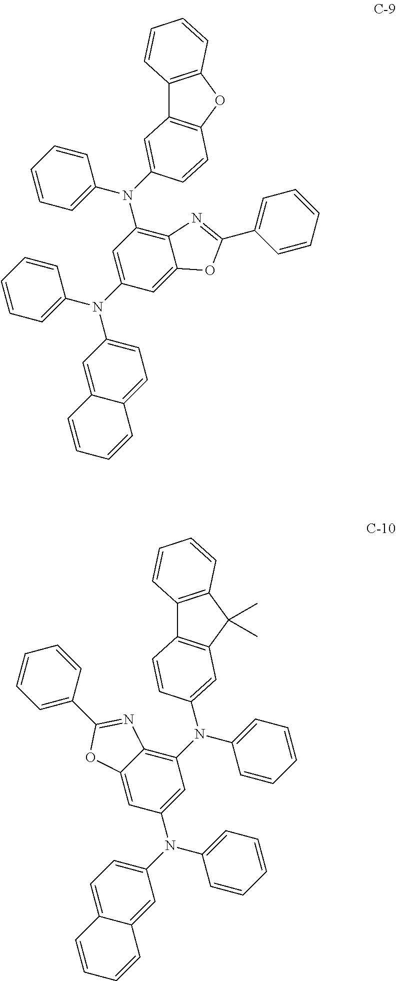 [SMILES: c1ccc(-c2nc3c(N(c4ccccc4)c4ccc5oc6ccccc6c5c4)cc(N(c4ccccc4)c4ccc5ccccc5c4)cc3o2)cc1 ; CC1(C)c2ccccc2-c2ccc(N(c3ccccc3)c3cc(N(c4ccccc4)c4ccc5ccccc5c4)cc4oc(-c5ccccc5)nc34)cc21]

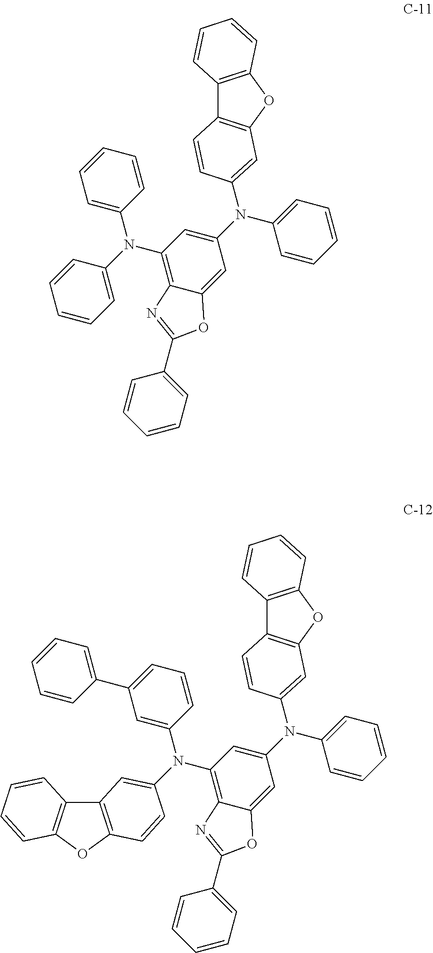 [SMILES: c1ccc(-c2nc3c(N(c4ccccc4)c4ccccc4)cc(N(c4ccccc4)c4ccc5c(c4)oc4ccccc45)cc3o2)cc1 ; c1ccc(-c2cccc(N(c3ccc4oc5ccccc5c4c3)c3cc(N(c4ccccc4)c4ccc5c(c4)oc4ccccc45)cc4oc(-c5ccccc5)nc34)c2)cc1]

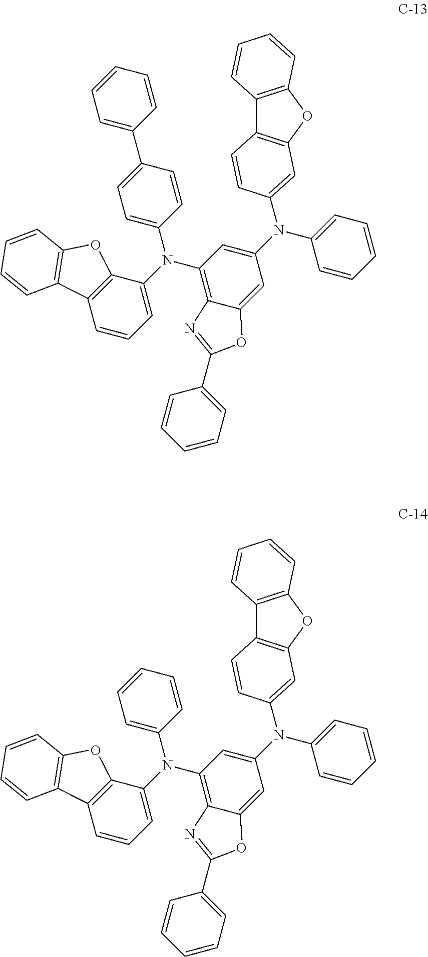 [SMILES: c1ccc(-c2ccc(N(c3cc(N(c4ccccc4)c4ccc5c(c4)oc4ccccc45)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccc5c(c4)oc4ccccc45)cc3o2)cc1]

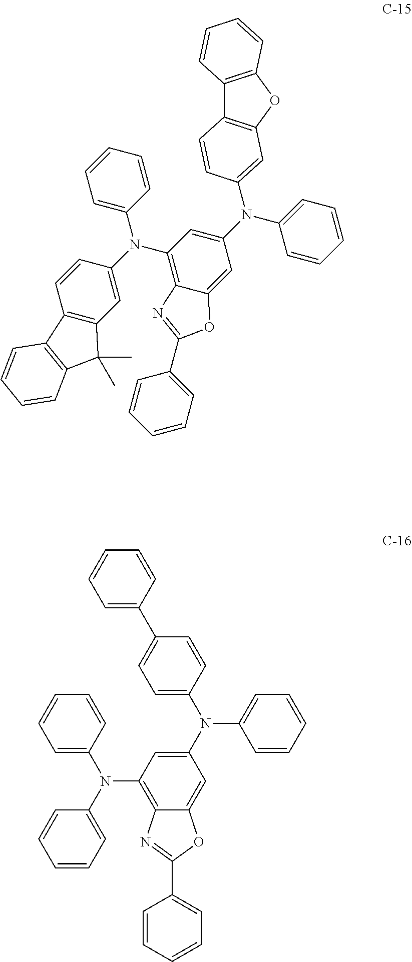 [SMILES: CC1(C)c2ccccc2-c2ccc(N(c3ccccc3)c3cc(N(c4ccccc4)c4ccc5c(c4)oc4ccccc45)cc4oc(-c5ccccc5)nc34)cc21 ; c1ccc(-c2ccc(N(c3ccccc3)c3cc(N(c4ccccc4)c4ccccc4)c4nc(-c5ccccc5)oc4c3)cc2)cc1]

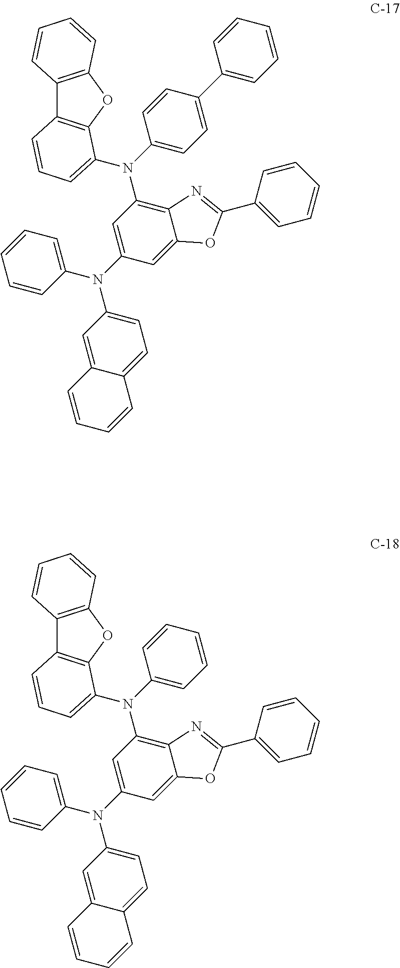 [SMILES: c1ccc(-c2ccc(N(c3cc(N(c4ccccc4)c4ccc5ccccc5c4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccc5ccccc5c4)cc3o2)cc1]

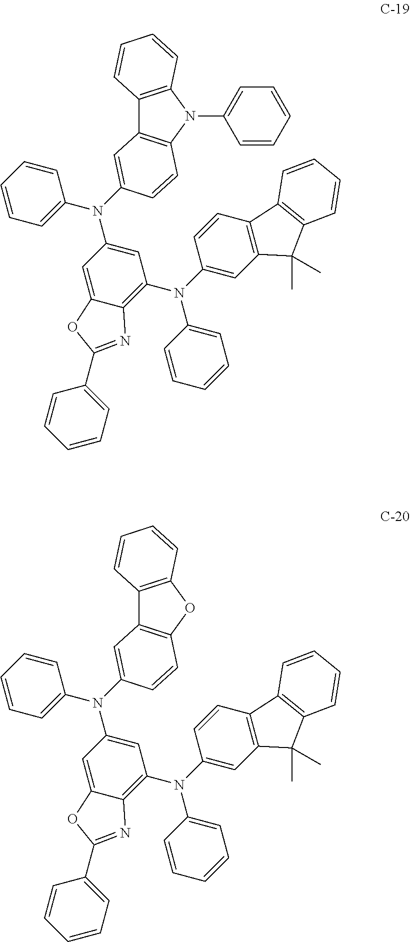 [SMILES: CC1(C)c2ccccc2-c2ccc(N(c3ccccc3)c3cc(N(c4ccccc4)c4ccc5c(c4)c4ccccc4n5-c4ccccc4)cc4oc(-c5ccccc5)nc34)cc21 ; CC1(C)c2ccccc2-c2ccc(N(c3ccccc3)c3cc(N(c4ccccc4)c4ccc5oc6ccccc6c5c4)cc4oc(-c5ccccc5)nc34)cc21]

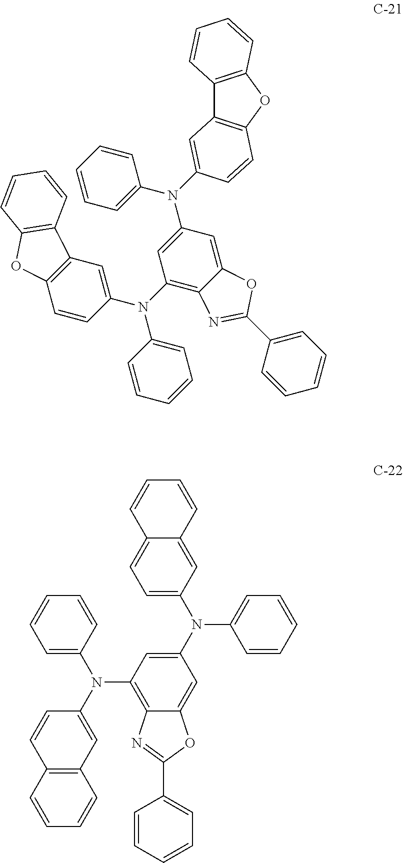 [SMILES: c1ccc(-c2nc3c(N(c4ccccc4)c4ccc5oc6ccccc6c5c4)cc(N(c4ccccc4)c4ccc5oc6ccccc6c5c4)cc3o2)cc1 ; c1ccc(-c2nc3c(N(c4ccccc4)c4ccc5ccccc5c4)cc(N(c4ccccc4)c4ccc5ccccc5c4)cc3o2)cc1]

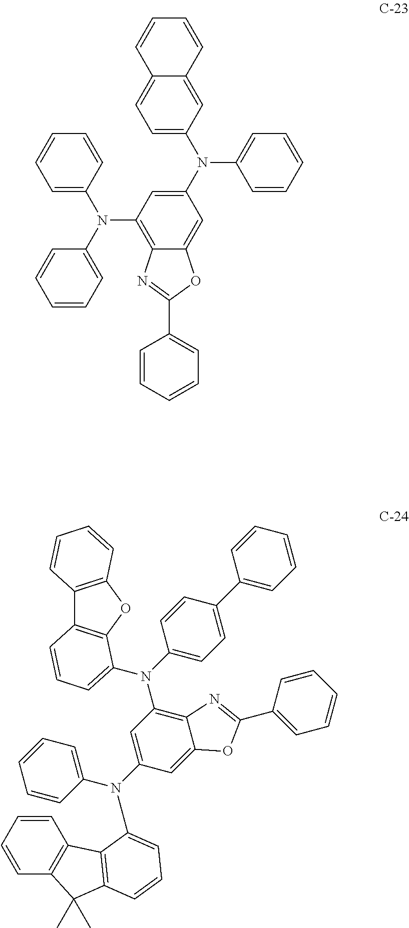 [SMILES: c1ccc(-c2nc3c(N(c4ccccc4)c4ccccc4)cc(N(c4ccccc4)c4ccc5ccccc5c4)cc3o2)cc1 ; CC1(C)c2ccccc2-c2c(N(c3ccccc3)c3cc(N(c4ccc(-c5ccccc5)cc4)c4cccc5c4oc4ccccc45)c4nc(-c5ccccc5)oc4c3)cccc21]

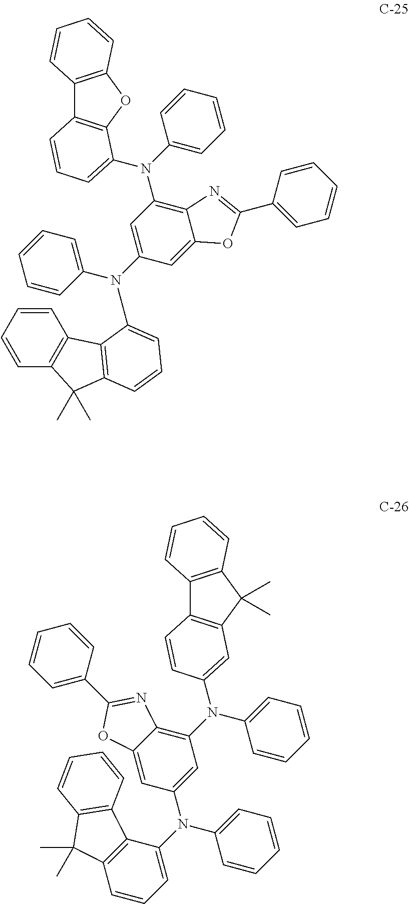 [SMILES: CC1(C)c2ccccc2-c2c(N(c3ccccc3)c3cc(N(c4ccccc4)c4cccc5c4oc4ccccc45)c4nc(-c5ccccc5)oc4c3)cccc21 ; CC1(C)c2ccccc2-c2ccc(N(c3ccccc3)c3cc(N(c4ccccc4)c4cccc5c4-c4ccccc4C5(C)C)cc4oc(-c5ccccc5)nc34)cc21]

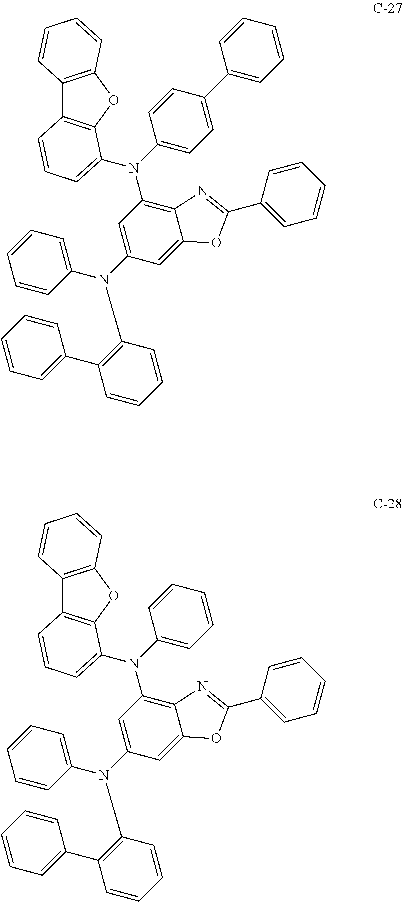 [SMILES: c1ccc(-c2ccc(N(c3cc(N(c4ccccc4)c4ccccc4-c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccccc4-c4ccccc4)cc3o2)cc1]

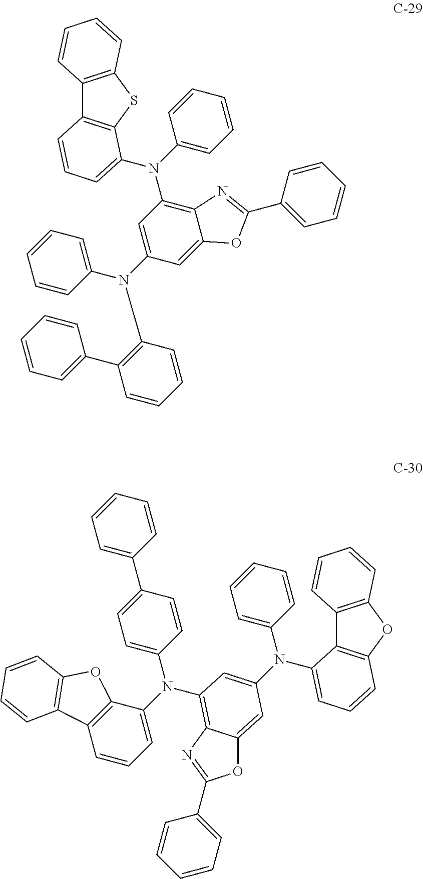 [SMILES: c1ccc(-c2nc3c(N(c4ccccc4)c4cccc5c4sc4ccccc45)cc(N(c4ccccc4)c4ccccc4-c4ccccc4)cc3o2)cc1 ; c1ccc(-c2ccc(N(c3cc(N(c4ccccc4)c4cccc5oc6ccccc6c45)cc4oc(-c5ccccc5)nc34)c3cccc4c3oc3ccccc34)cc2)cc1]

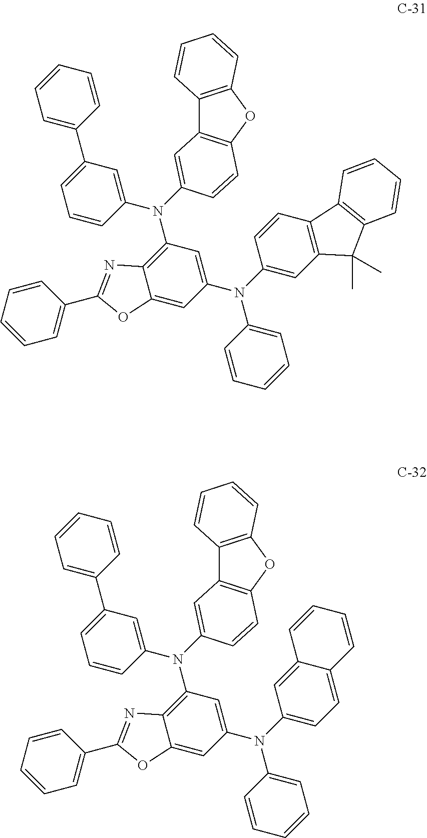 [SMILES: CC1(C)c2ccccc2-c2ccc(N(c3ccccc3)c3cc(N(c4cccc(-c5ccccc5)c4)c4ccc5oc6ccccc6c5c4)c4nc(-c5ccccc5)oc4c3)cc21 ; c1ccc(-c2cccc(N(c3ccc4oc5ccccc5c4c3)c3cc(N(c4ccccc4)c4ccc5ccccc5c4)cc4oc(-c5ccccc5)nc34)c2)cc1]

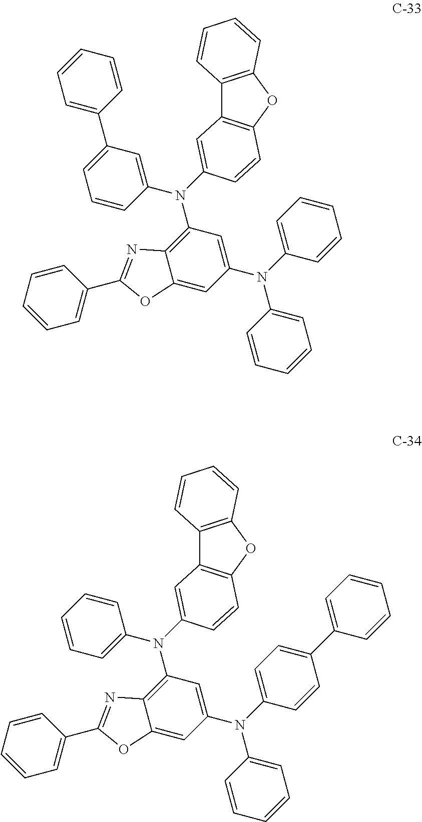 [SMILES: c1ccc(-c2cccc(N(c3ccc4oc5ccccc5c4c3)c3cc(N(c4ccccc4)c4ccccc4)cc4oc(-c5ccccc5)nc34)c2)cc1 ; c1ccc(-c2ccc(N(c3ccccc3)c3cc(N(c4ccccc4)c4ccc5oc6ccccc6c5c4)c4nc(-c5ccccc5)oc4c3)cc2)cc1]

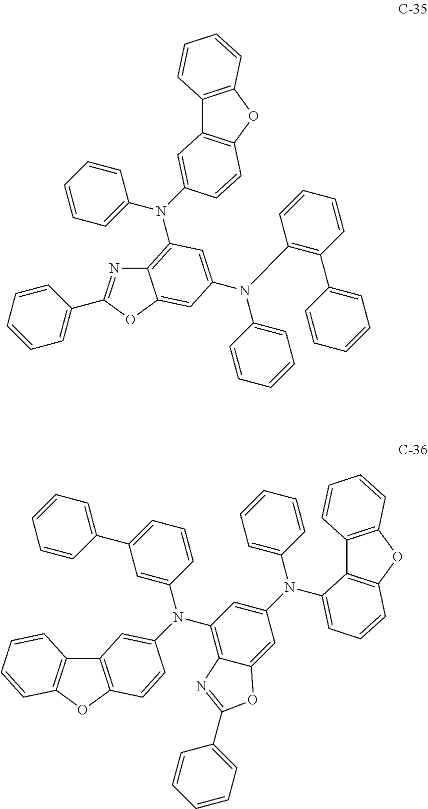 [SMILES: c1ccc(-c2nc3c(N(c4ccccc4)c4ccc5oc6ccccc6c5c4)cc(N(c4ccccc4)c4ccccc4-c4ccccc4)cc3o2)cc1 ; c1ccc(-c2cccc(N(c3ccc4oc5ccccc5c4c3)c3cc(N(c4ccccc4)c4cccc5oc6ccccc6c45)cc4oc(-c5ccccc5)nc34)c2)cc1]

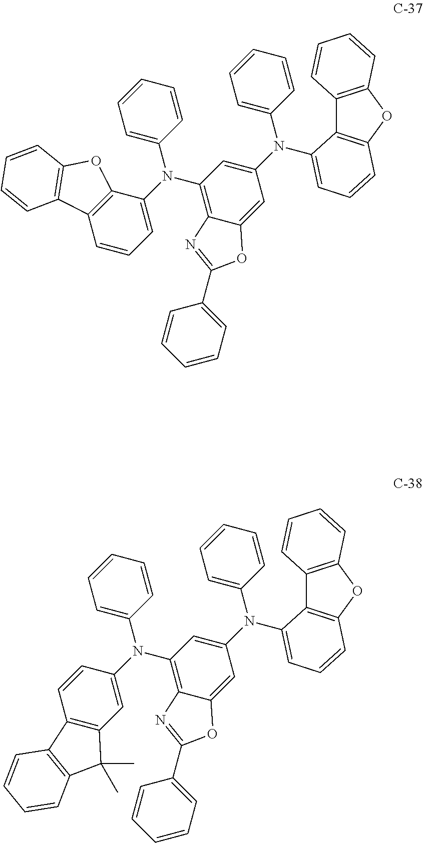 [SMILES: c1ccc(-c2nc3c(N(c4ccccc4)c4cccc5c4oc4ccccc45)cc(N(c4ccccc4)c4cccc5oc6ccccc6c45)cc3o2)cc1 ; CC1(C)c2ccccc2-c2ccc(N(c3ccccc3)c3cc(N(c4ccccc4)c4cccc5oc6ccccc6c45)cc4oc(-c5ccccc5)nc34)cc21]

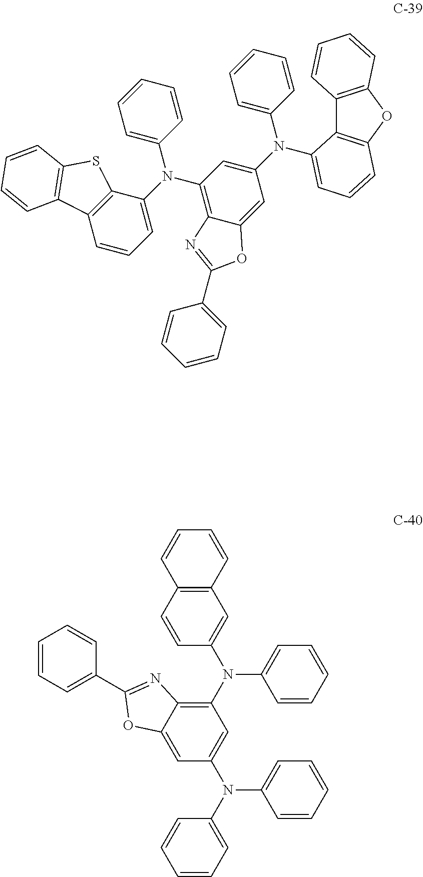 [SMILES: c1ccc(-c2nc3c(N(c4ccccc4)c4cccc5c4sc4ccccc45)cc(N(c4ccccc4)c4cccc5oc6ccccc6c45)cc3o2)cc1 ; c1ccc(-c2nc3c(N(c4ccccc4)c4ccc5ccccc5c4)cc(N(c4ccccc4)c4ccccc4)cc3o2)cc1]

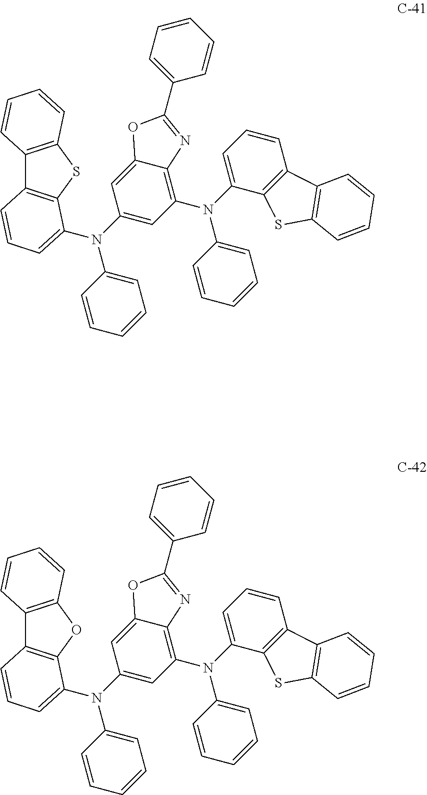 [SMILES: c1ccc(-c2nc3c(N(c4ccccc4)c4cccc5c4sc4ccccc45)cc(N(c4ccccc4)c4cccc5c4sc4ccccc45)cc3o2)cc1 ; c1ccc(-c2nc3c(N(c4ccccc4)c4cccc5c4sc4ccccc45)cc(N(c4ccccc4)c4cccc5c4oc4ccccc45)cc3o2)cc1]

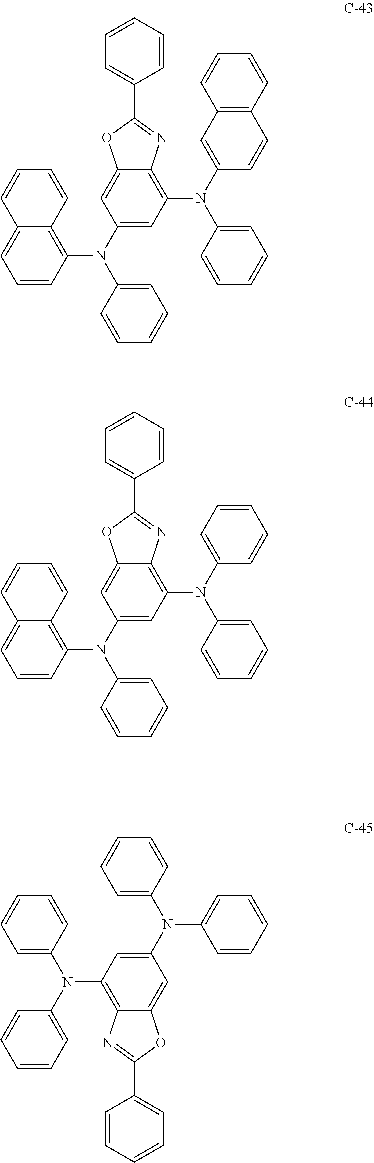 [SMILES: c1ccc(-c2nc3c(N(c4ccccc4)c4ccc5ccccc5c4)cc(N(c4ccccc4)c4cccc5ccccc45)cc3o2)cc1 ; c1ccc(-c2nc3c(N(c4ccccc4)c4ccccc4)cc(N(c4ccccc4)c4cccc5ccccc45)cc3o2)cc1 ; c1ccc(-c2nc3c(N(c4ccccc4)c4ccccc4)cc(N(c4ccccc4)c4ccccc4)cc3o2)cc1]

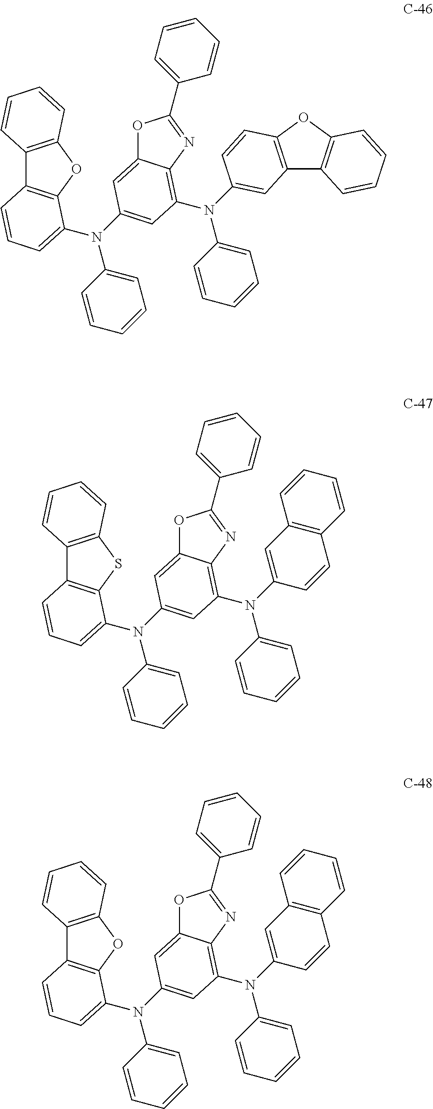 [SMILES: c1ccc(-c2nc3c(N(c4ccccc4)c4ccc5oc6ccccc6c5c4)cc(N(c4ccccc4)c4cccc5c4oc4ccccc45)cc3o2)cc1 ; c1ccc(-c2nc3c(N(c4ccccc4)c4ccc5ccccc5c4)cc(N(c4ccccc4)c4cccc5c4sc4ccccc45)cc3o2)cc1 ; c1ccc(-c2nc3c(N(c4ccccc4)c4ccc5ccccc5c4)cc(N(c4ccccc4)c4cccc5c4oc4ccccc45)cc3o2)cc1]

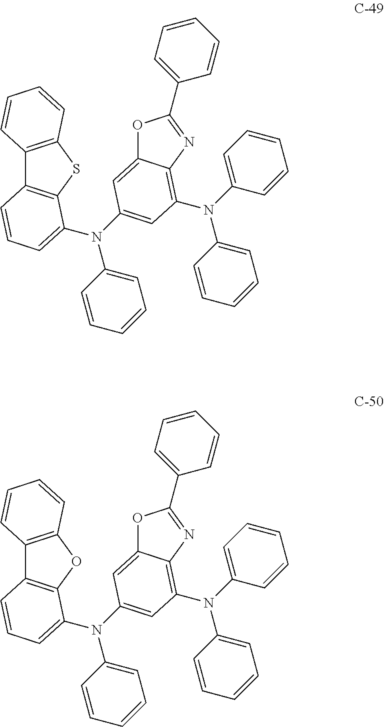 [SMILES: c1ccc(-c2nc3c(N(c4ccccc4)c4ccccc4)cc(N(c4ccccc4)c4cccc5c4sc4ccccc45)cc3o2)cc1 ; c1ccc(-c2nc3c(N(c4ccccc4)c4ccccc4)cc(N(c4ccccc4)c4cccc5c4oc4ccccc45)cc3o2)cc1]

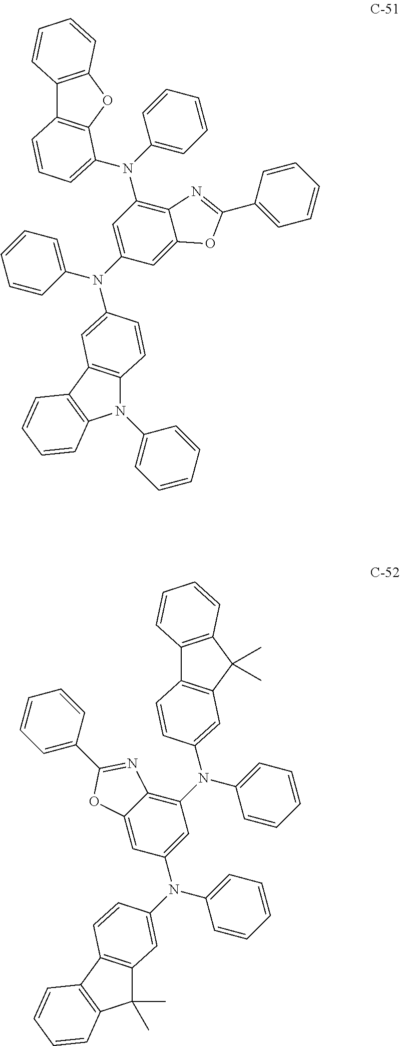 [SMILES: c1ccc(-c2nc3c(N(c4ccccc4)c4cccc5c4oc4ccccc45)cc(N(c4ccccc4)c4ccc5c(c4)c4ccccc4n5-c4ccccc4)cc3o2)cc1 ; CC1(C)c2ccccc2-c2ccc(N(c3ccccc3)c3cc(N(c4ccccc4)c4ccc5c(c4)C(C)(C)c4ccccc4-5)c4nc(-c5ccccc5)oc4c3)cc21]

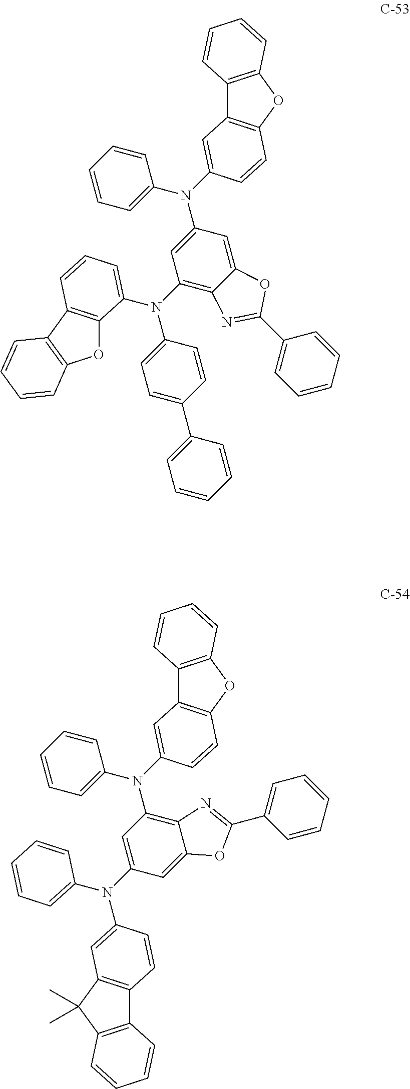 [SMILES: c1ccc(-c2ccc(N(c3cc(N(c4ccccc4)c4ccc5oc6ccccc6c5c4)cc4oc(-c5ccccc5)nc34)c3cccc4c3oc3ccccc34)cc2)cc1 ; CC1(C)c2ccccc2-c2ccc(N(c3ccccc3)c3cc(N(c4ccccc4)c4ccc5oc6ccccc6c5c4)c4nc(-c5ccccc5)oc4c3)cc21]

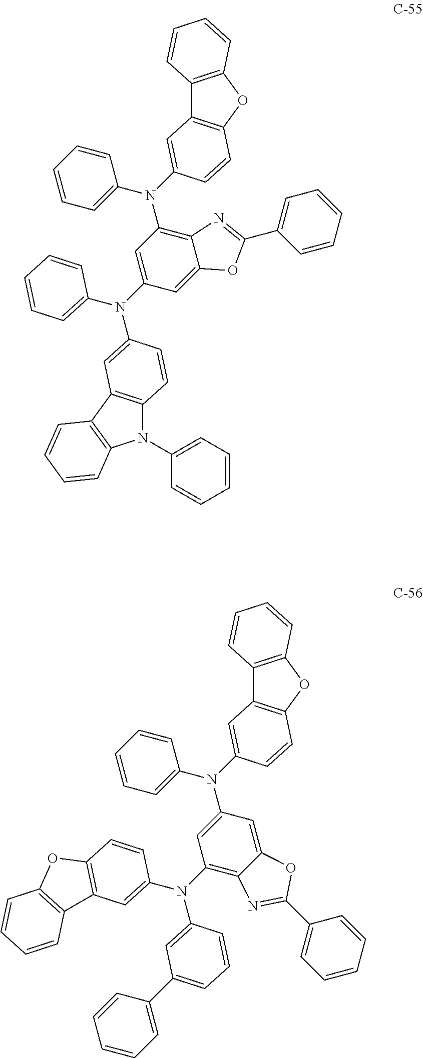 [SMILES: c1ccc(-c2nc3c(N(c4ccccc4)c4ccc5oc6ccccc6c5c4)cc(N(c4ccccc4)c4ccc5c(c4)c4ccccc4n5-c4ccccc4)cc3o2)cc1 ; c1ccc(-c2cccc(N(c3ccc4oc5ccccc5c4c3)c3cc(N(c4ccccc4)c4ccc5oc6ccccc6c5c4)cc4oc(-c5ccccc5)nc34)c2)cc1]

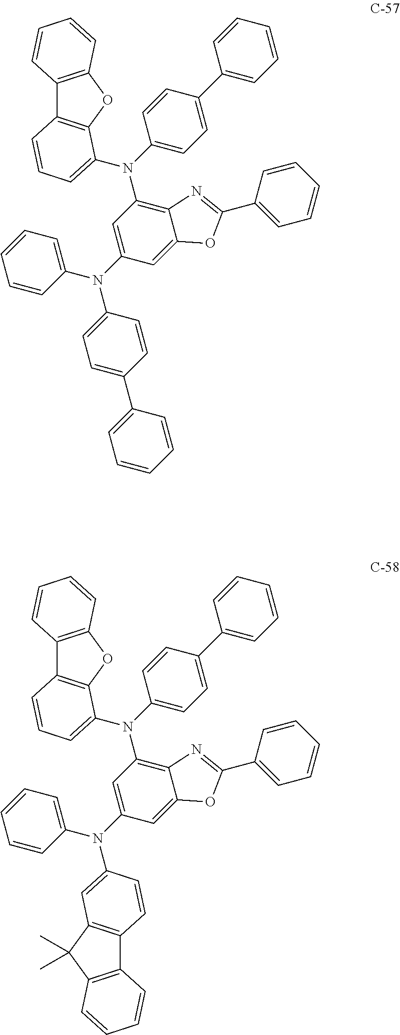 [SMILES: c1ccc(-c2ccc(N(c3ccccc3)c3cc(N(c4ccc(-c5ccccc5)cc4)c4cccc5c4oc4ccccc45)c4nc(-c5ccccc5)oc4c3)cc2)cc1 ; CC1(C)c2ccccc2-c2ccc(N(c3ccccc3)c3cc(N(c4ccc(-c5ccccc5)cc4)c4cccc5c4oc4ccccc45)c4nc(-c5ccccc5)oc4c3)cc21]

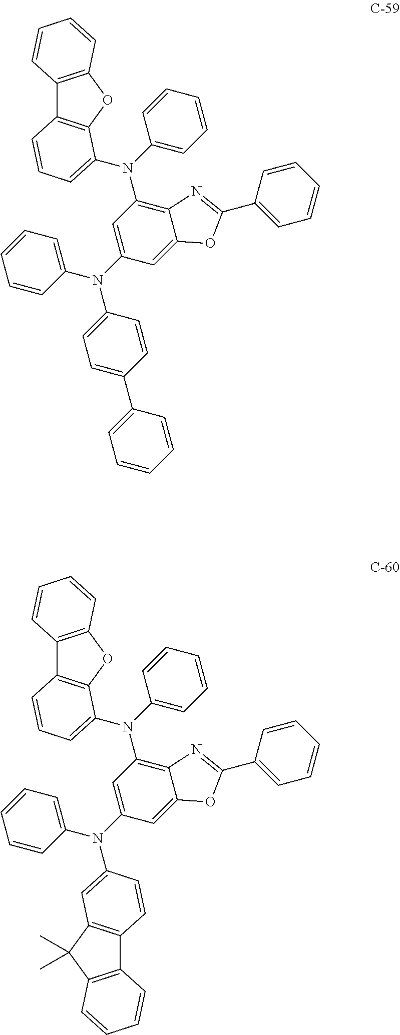 [SMILES: c1ccc(-c2ccc(N(c3ccccc3)c3cc(N(c4ccccc4)c4cccc5c4oc4ccccc45)c4nc(-c5ccccc5)oc4c3)cc2)cc1 ; CC1(C)c2ccccc2-c2ccc(N(c3ccccc3)c3cc(N(c4ccccc4)c4cccc5c4oc4ccccc45)c4nc(-c5ccccc5)oc4c3)cc21]

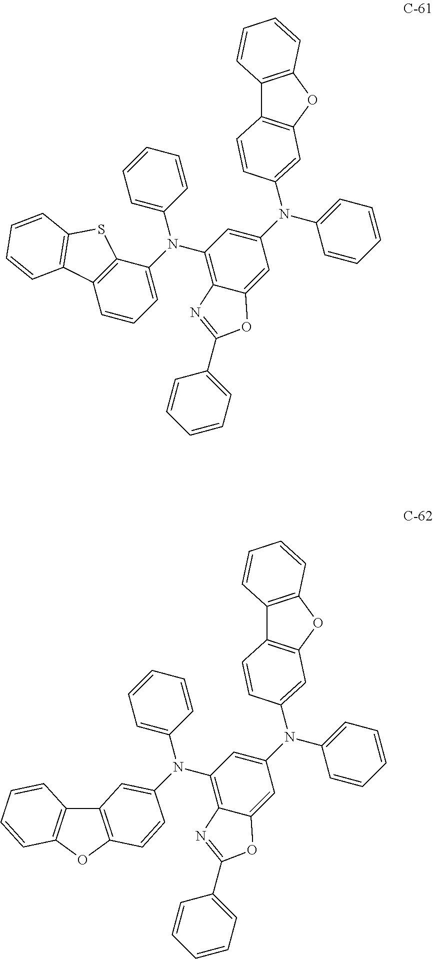 [SMILES: c1ccc(-c2nc3c(N(c4ccccc4)c4cccc5c4sc4ccccc45)cc(N(c4ccccc4)c4ccc5c(c4)oc4ccccc45)cc3o2)cc1 ; c1ccc(-c2nc3c(N(c4ccccc4)c4ccc5oc6ccccc6c5c4)cc(N(c4ccccc4)c4ccc5c(c4)oc4ccccc45)cc3o2)cc1]

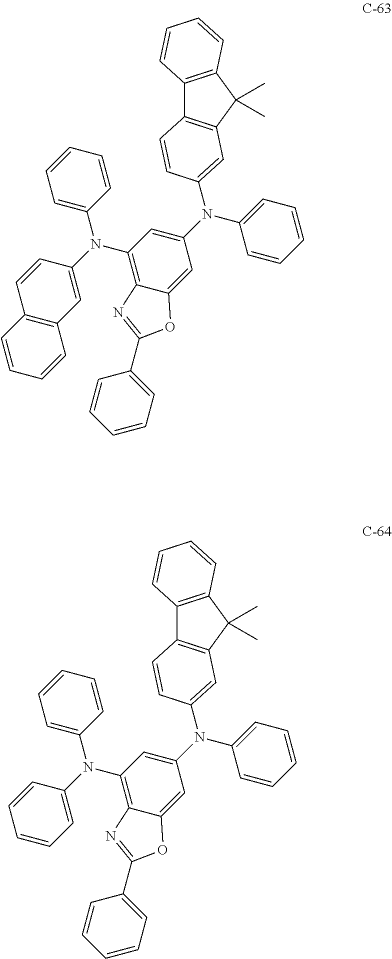 [SMILES: CC1(C)c2ccccc2-c2ccc(N(c3ccccc3)c3cc(N(c4ccccc4)c4ccc5ccccc5c4)c4nc(-c5ccccc5)oc4c3)cc21 ; CC1(C)c2ccccc2-c2ccc(N(c3ccccc3)c3cc(N(c4ccccc4)c4ccccc4)c4nc(-c5ccccc5)oc4c3)cc21]

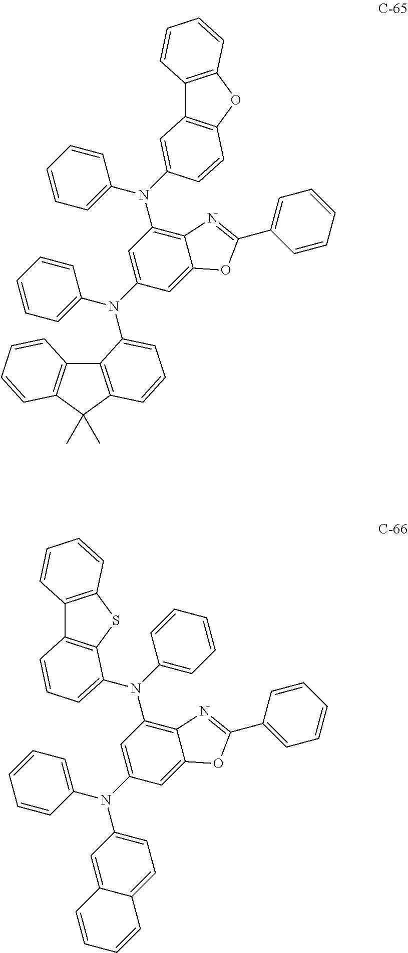 [SMILES: CC1(C)c2ccccc2-c2c(N(c3ccccc3)c3cc(N(c4ccccc4)c4ccc5oc6ccccc6c5c4)c4nc(-c5ccccc5)oc4c3)cccc21 ; c1ccc(-c2nc3c(N(c4ccccc4)c4cccc5c4sc4ccccc45)cc(N(c4ccccc4)c4ccc5ccccc5c4)cc3o2)cc1]

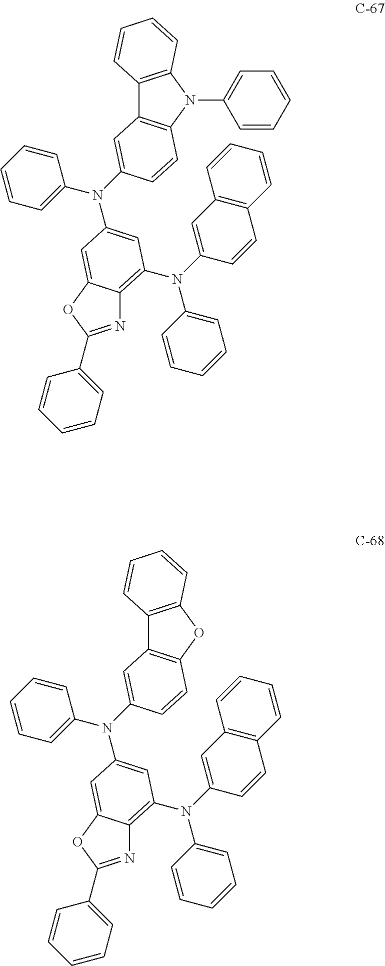 [SMILES: c1ccc(-c2nc3c(N(c4ccccc4)c4ccc5ccccc5c4)cc(N(c4ccccc4)c4ccc5c(c4)c4ccccc4n5-c4ccccc4)cc3o2)cc1 ; c1ccc(-c2nc3c(N(c4ccccc4)c4ccc5ccccc5c4)cc(N(c4ccccc4)c4ccc5oc6ccccc6c5c4)cc3o2)cc1]

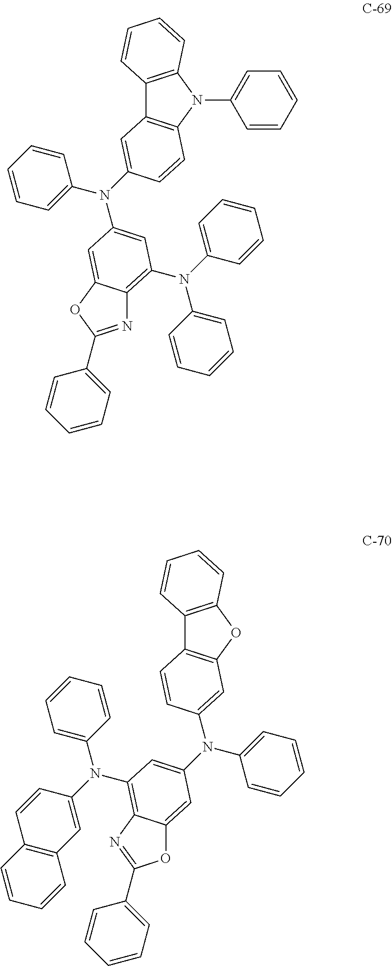 [SMILES: c1ccc(-c2nc3c(N(c4ccccc4)c4ccccc4)cc(N(c4ccccc4)c4ccc5c(c4)c4ccccc4n5-c4ccccc4)cc3o2)cc1 ; c1ccc(-c2nc3c(N(c4ccccc4)c4ccc5ccccc5c4)cc(N(c4ccccc4)c4ccc5c(c4)oc4ccccc45)cc3o2)cc1]

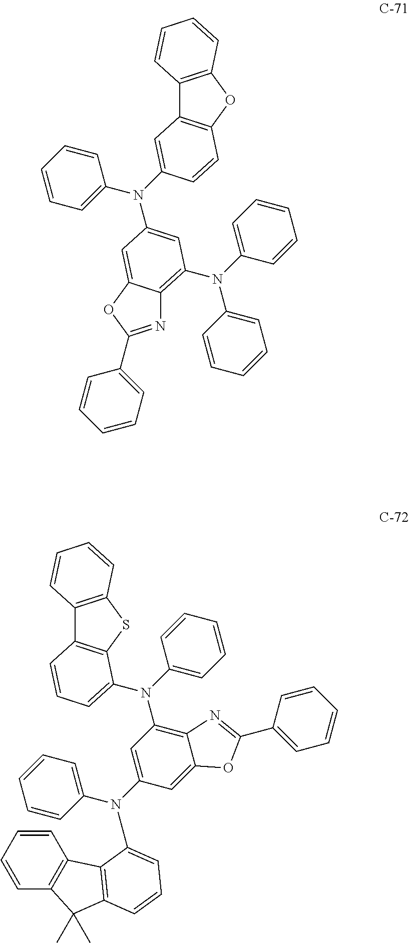 [SMILES: c1ccc(-c2nc3c(N(c4ccccc4)c4ccccc4)cc(N(c4ccccc4)c4ccc5oc6ccccc6c5c4)cc3o2)cc1 ; CC1(C)c2ccccc2-c2c(N(c3ccccc3)c3cc(N(c4ccccc4)c4cccc5c4sc4ccccc45)c4nc(-c5ccccc5)oc4c3)cccc21]

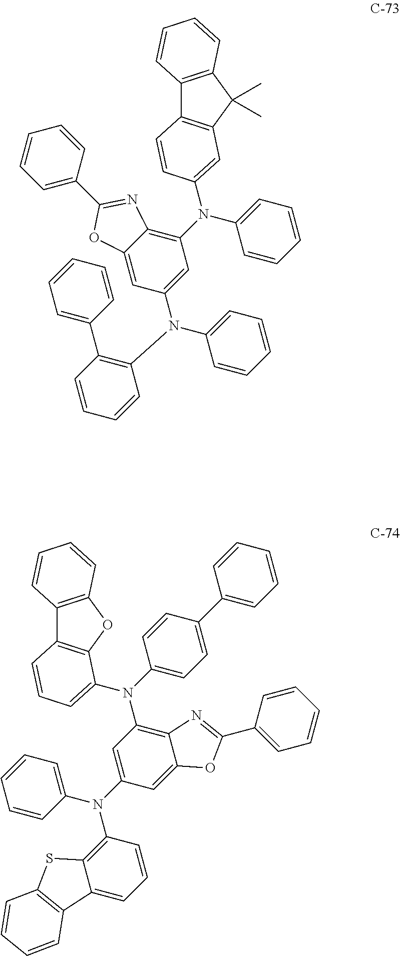 [SMILES: CC1(C)c2ccccc2-c2ccc(N(c3ccccc3)c3cc(N(c4ccccc4)c4ccccc4-c4ccccc4)cc4oc(-c5ccccc5)nc34)cc21 ; c1ccc(-c2ccc(N(c3cc(N(c4ccccc4)c4cccc5c4sc4ccccc45)cc4oc(-c5ccccc5)nc34)c3cccc4c3oc3ccccc34)cc2)cc1]

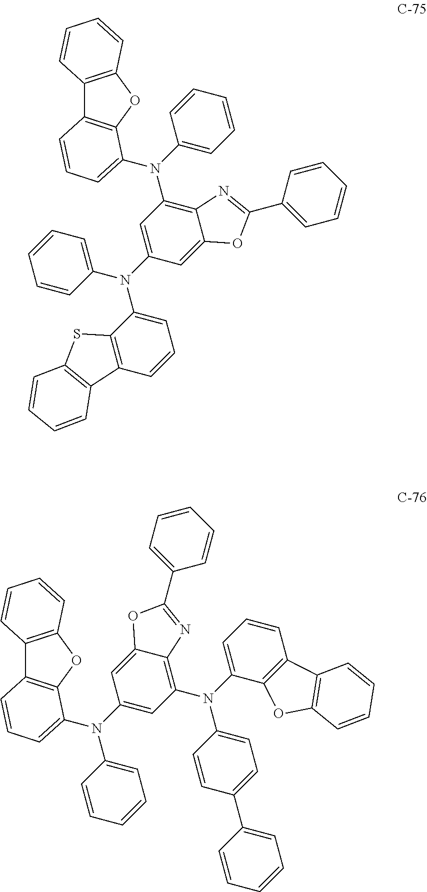 [SMILES: c1ccc(-c2nc3c(N(c4ccccc4)c4cccc5c4oc4ccccc45)cc(N(c4ccccc4)c4cccc5c4sc4ccccc45)cc3o2)cc1 ; c1ccc(-c2ccc(N(c3cc(N(c4ccccc4)c4cccc5c4oc4ccccc45)cc4oc(-c5ccccc5)nc34)c3cccc4c3oc3ccccc34)cc2)cc1]

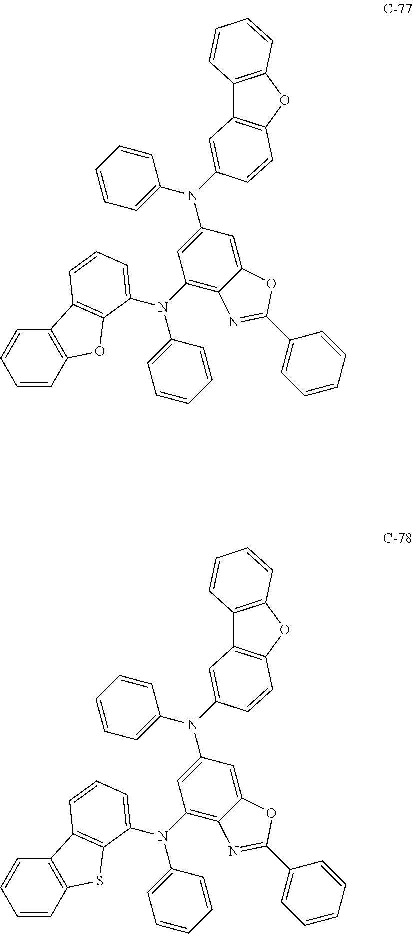 [SMILES: c1ccc(-c2nc3c(N(c4ccccc4)c4cccc5c4oc4ccccc45)cc(N(c4ccccc4)c4ccc5oc6ccccc6c5c4)cc3o2)cc1 ; c1ccc(-c2nc3c(N(c4ccccc4)c4cccc5c4sc4ccccc45)cc(N(c4ccccc4)c4ccc5oc6ccccc6c5c4)cc3o2)cc1]

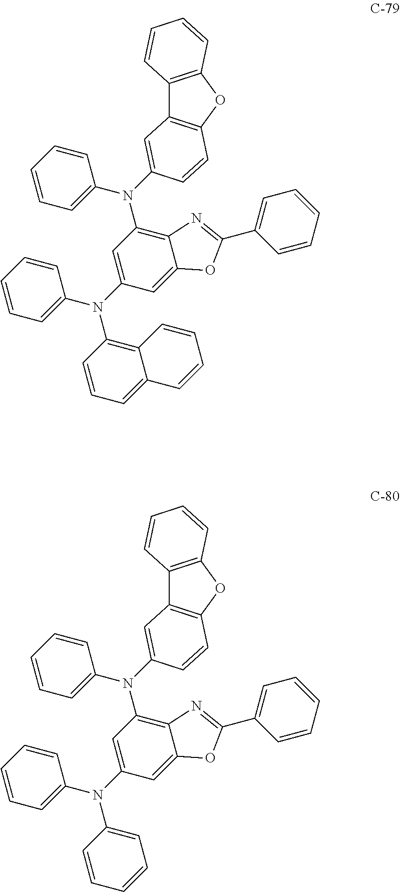 [SMILES: c1ccc(-c2nc3c(N(c4ccccc4)c4ccc5oc6ccccc6c5c4)cc(N(c4ccccc4)c4cccc5ccccc45)cc3o2)cc1 ; c1ccc(-c2nc3c(N(c4ccccc4)c4ccc5oc6ccccc6c5c4)cc(N(c4ccccc4)c4ccccc4)cc3o2)cc1]

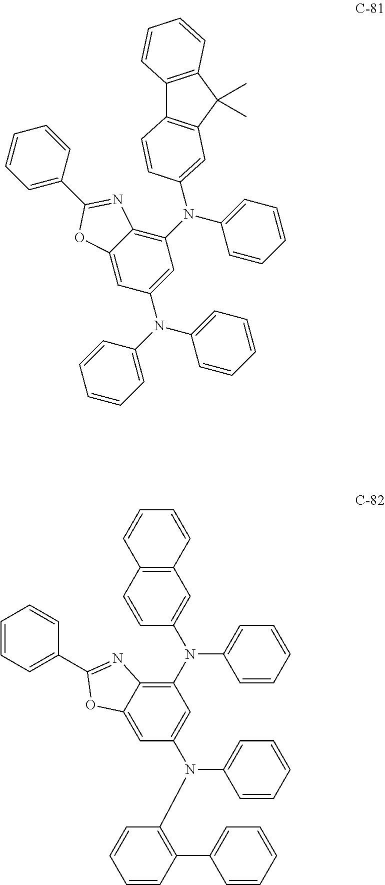 [SMILES: CC1(C)c2ccccc2-c2ccc(N(c3ccccc3)c3cc(N(c4ccccc4)c4ccccc4)cc4oc(-c5ccccc5)nc34)cc21 ; c1ccc(-c2nc3c(N(c4ccccc4)c4ccc5ccccc5c4)cc(N(c4ccccc4)c4ccccc4-c4ccccc4)cc3o2)cc1]

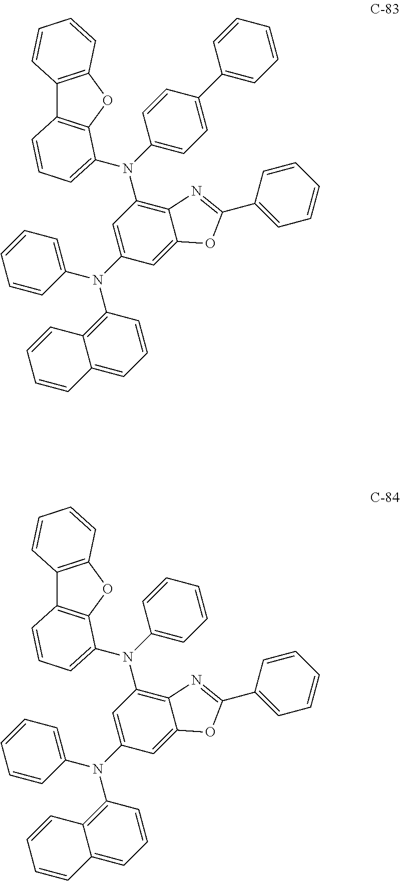 [SMILES: c1ccc(-c2ccc(N(c3cc(N(c4ccccc4)c4cccc5ccccc45)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4cccc5ccccc45)cc3o2)cc1]

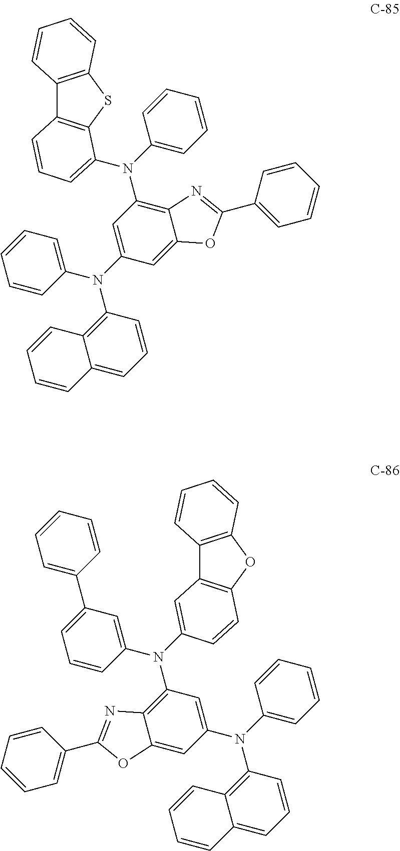 [SMILES: c1ccc(-c2nc3c(N(c4ccccc4)c4cccc5c4sc4ccccc45)cc(N(c4ccccc4)c4cccc5ccccc45)cc3o2)cc1 ; c1ccc(-c2cccc(N(c3ccc4oc5ccccc5c4c3)c3cc(N(c4ccccc4)c4cccc5ccccc45)cc4oc(-c5ccccc5)nc34)c2)cc1]

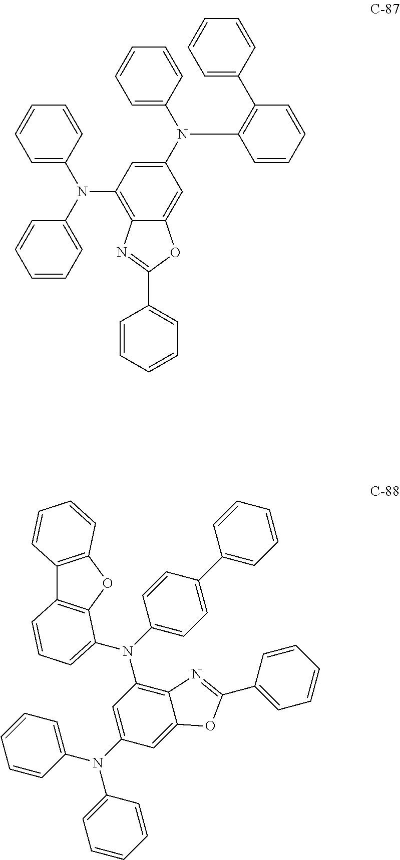 [SMILES: c1ccc(-c2nc3c(N(c4ccccc4)c4ccccc4)cc(N(c4ccccc4)c4ccccc4-c4ccccc4)cc3o2)cc1 ; c1ccc(-c2ccc(N(c3cc(N(c4ccccc4)c4ccccc4)cc4oc(-c5ccccc5)nc34)c3cccc4c3oc3ccccc34)cc2)cc1]

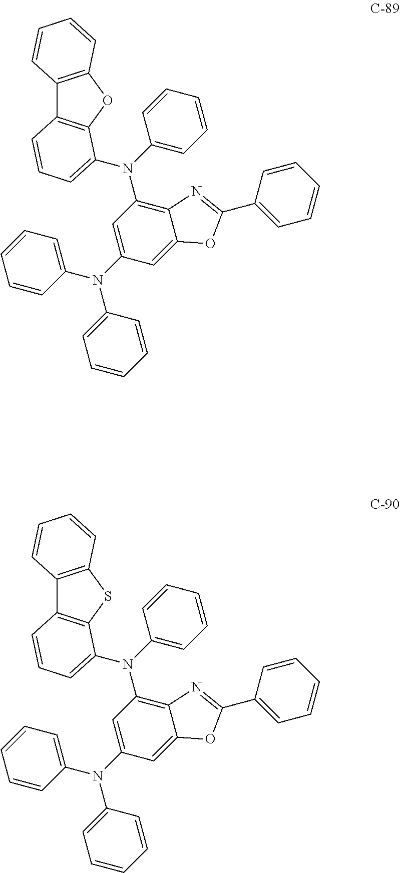 [SMILES: c1ccc(-c2nc3c(N(c4ccccc4)c4cccc5c4oc4ccccc45)cc(N(c4ccccc4)c4ccccc4)cc3o2)cc1 ; c1ccc(-c2nc3c(N(c4ccccc4)c4cccc5c4sc4ccccc45)cc(N(c4ccccc4)c4ccccc4)cc3o2)cc1]

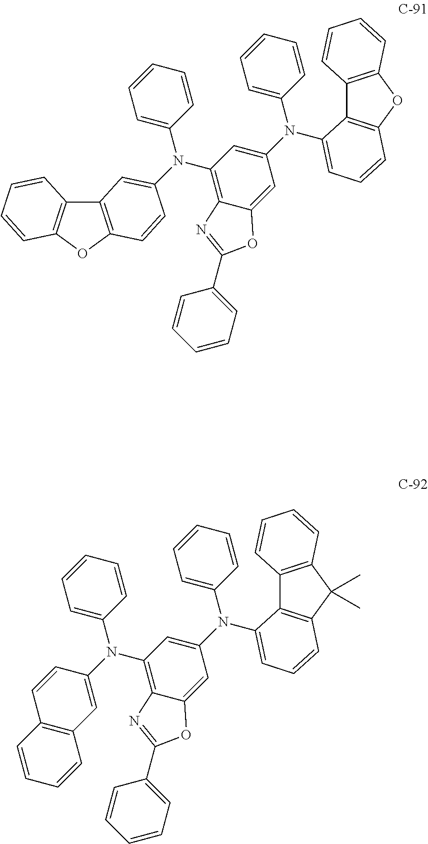 [SMILES: c1ccc(-c2nc3c(N(c4ccccc4)c4ccc5oc6ccccc6c5c4)cc(N(c4ccccc4)c4cccc5oc6ccccc6c45)cc3o2)cc1 ; CC1(C)c2ccccc2-c2c(N(c3ccccc3)c3cc(N(c4ccccc4)c4ccc5ccccc5c4)c4nc(-c5ccccc5)oc4c3)cccc21]

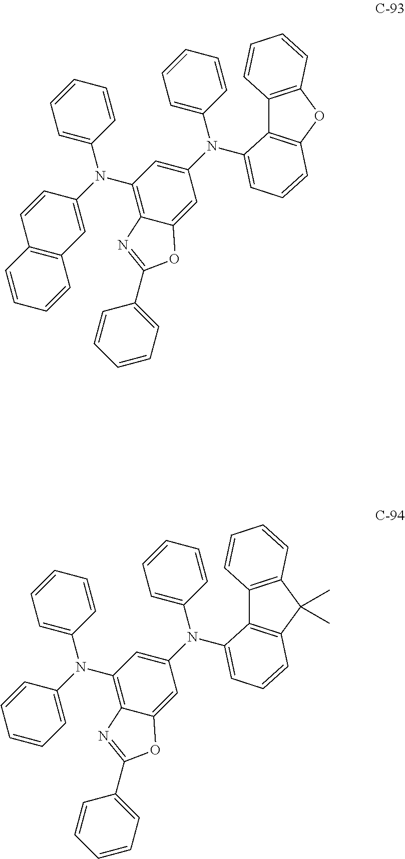 [SMILES: c1ccc(-c2nc3c(N(c4ccccc4)c4ccc5ccccc5c4)cc(N(c4ccccc4)c4cccc5oc6ccccc6c45)cc3o2)cc1 ; CC1(C)c2ccccc2-c2c(N(c3ccccc3)c3cc(N(c4ccccc4)c4ccccc4)c4nc(-c5ccccc5)oc4c3)cccc21]

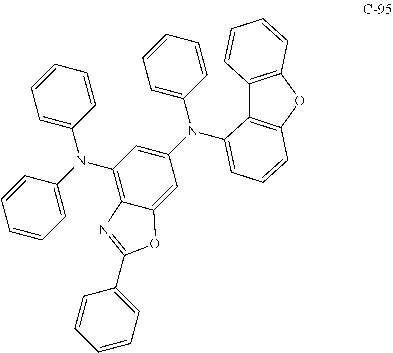 [SMILES: c1ccc(-c2nc3c(N(c4ccccc4)c4ccccc4)cc(N(c4ccccc4)c4cccc5oc6ccccc6c45)cc3o2)cc1]

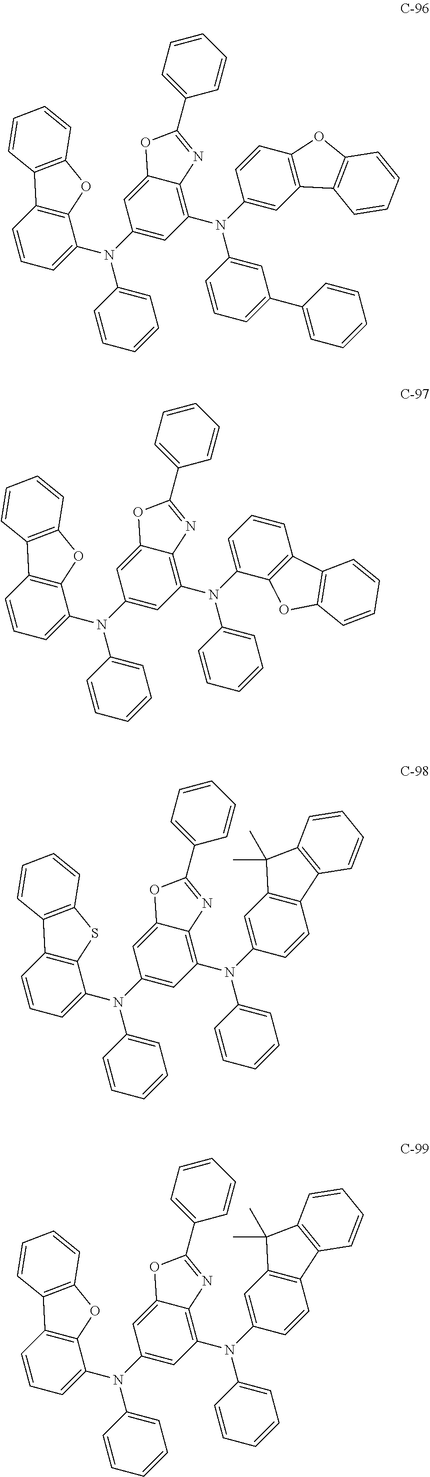 [SMILES: c1ccc(-c2cccc(N(c3ccc4oc5ccccc5c4c3)c3cc(N(c4ccccc4)c4cccc5c4oc4ccccc45)cc4oc(-c5ccccc5)nc34)c2)cc1 ; c1ccc(-c2nc3c(N(c4ccccc4)c4cccc5c4oc4ccccc45)cc(N(c4ccccc4)c4cccc5c4oc4ccccc45)cc3o2)cc1 ; CC1(C)c2ccccc2-c2ccc(N(c3ccccc3)c3cc(N(c4ccccc4)c4cccc5c4sc4ccccc45)cc4oc(-c5ccccc5)nc34)cc21 ; CC1(C)c2ccccc2-c2ccc(N(c3ccccc3)c3cc(N(c4ccccc4)c4cccc5c4oc4ccccc45)cc4oc(-c5ccccc5)nc34)cc21]

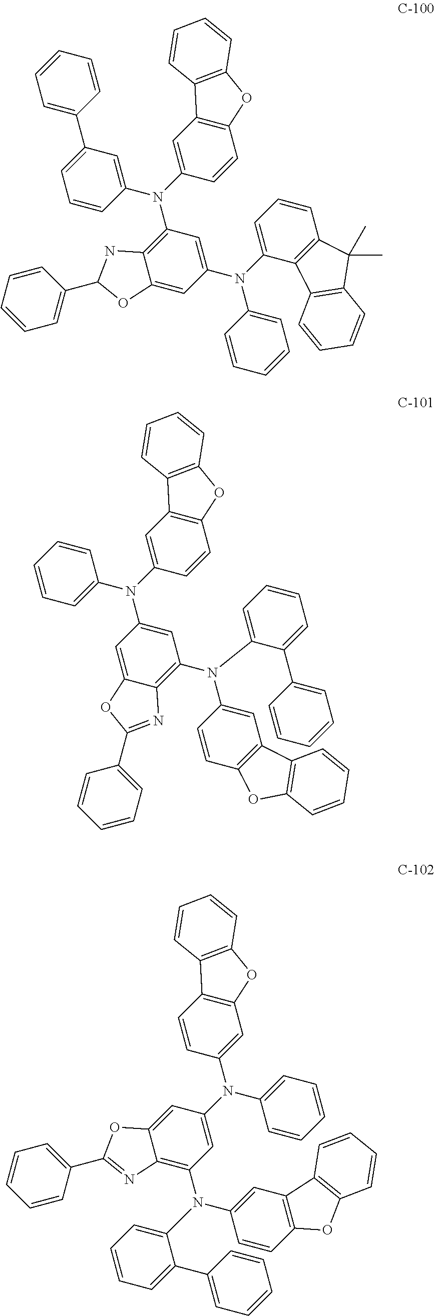 [SMILES: CC1(C)c2ccccc2-c2c(N(c3ccccc3)c3cc4c(c(N(c5cccc(-c6ccccc6)c5)c5ccc6oc7ccccc7c6c5)c3)NC(c3ccccc3)O4)cccc21 ; c1ccc(-c2nc3c(N(c4ccc5oc6ccccc6c5c4)c4ccccc4-c4ccccc4)cc(N(c4ccccc4)c4ccc5oc6ccccc6c5c4)cc3o2)cc1 ; c1ccc(-c2nc3c(N(c4ccc5oc6ccccc6c5c4)c4ccccc4-c4ccccc4)cc(N(c4ccccc4)c4ccc5c(c4)oc4ccccc45)cc3o2)cc1]

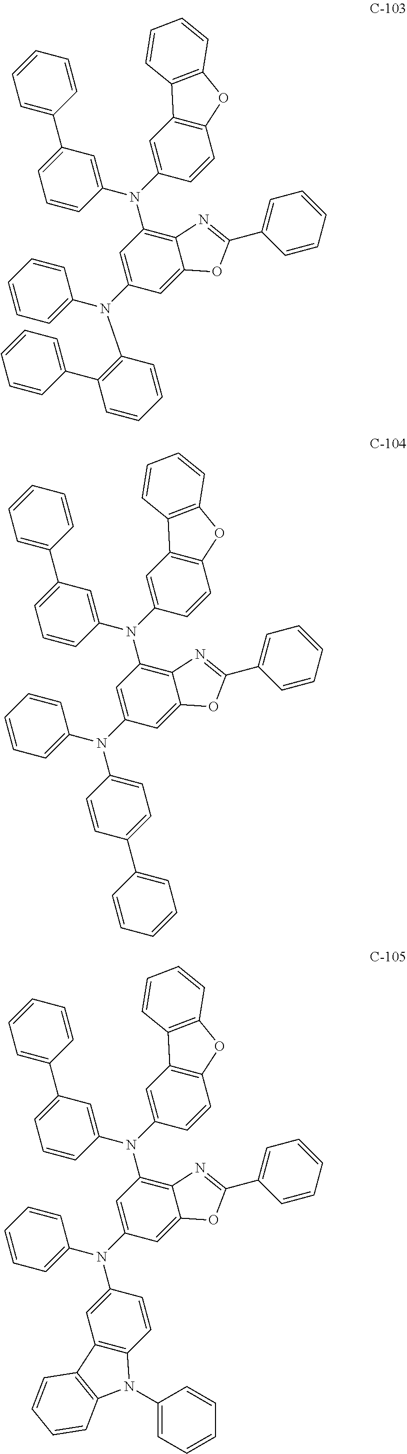

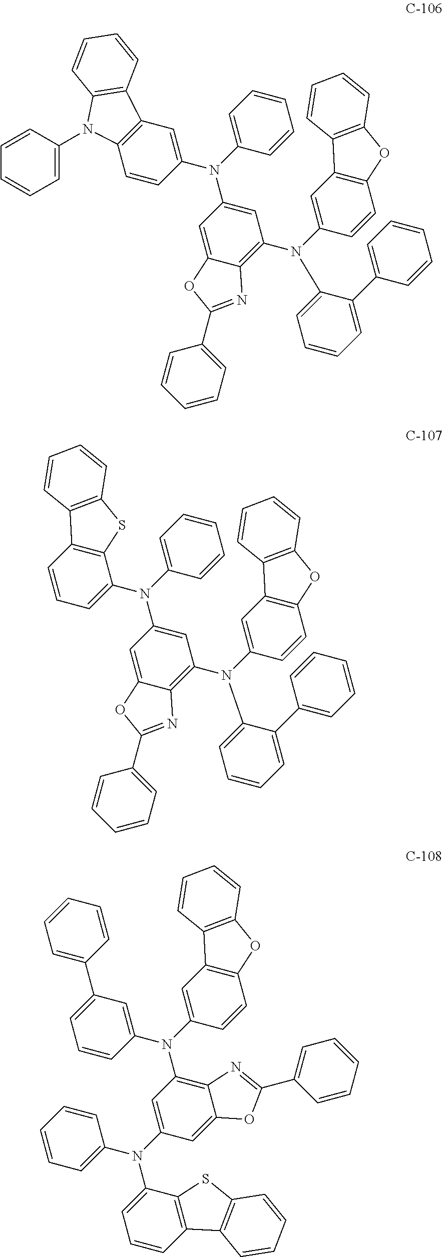 [SMILES: c1ccc(-c2nc3c(N(c4ccc5oc6ccccc6c5c4)c4ccccc4-c4ccccc4)cc(N(c4ccccc4)c4ccc5c(c4)c4ccccc4n5-c4ccccc4)cc3o2)cc1 ; c1ccc(-c2nc3c(N(c4ccc5oc6ccccc6c5c4)c4ccccc4-c4ccccc4)cc(N(c4ccccc4)c4cccc5c4sc4ccccc45)cc3o2)cc1 ; c1ccc(-c2cccc(N(c3ccc4oc5ccccc5c4c3)c3cc(N(c4ccccc4)c4cccc5c4sc4ccccc45)cc4oc(-c5ccccc5)nc34)c2)cc1]

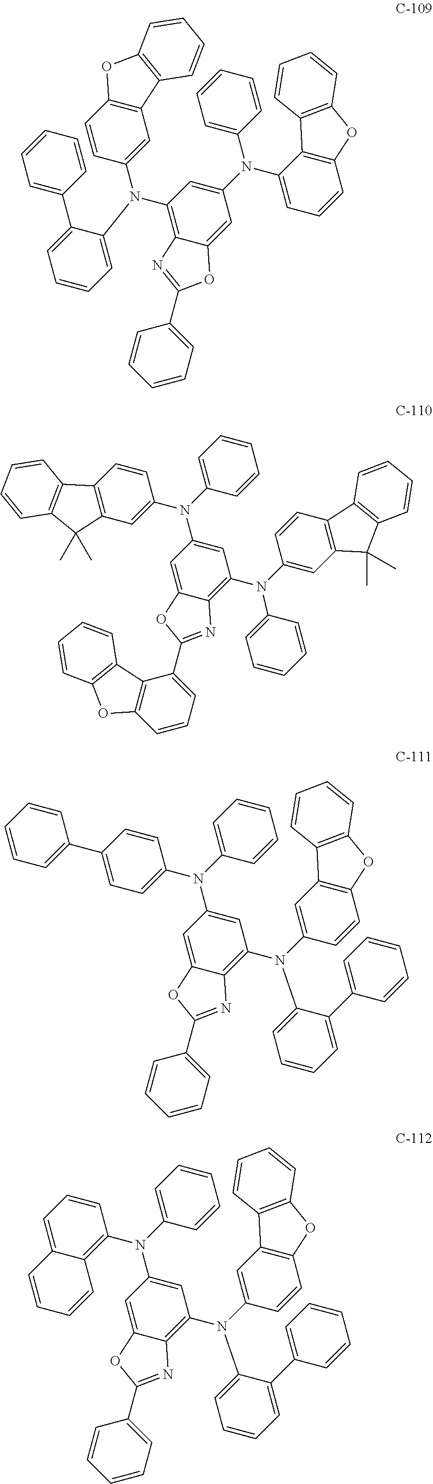 [SMILES: c1ccc(-c2nc3c(N(c4ccc5oc6ccccc6c5c4)c4ccccc4-c4ccccc4)cc(N(c4ccccc4)c4cccc5oc6ccccc6c45)cc3o2)cc1 ; CC1(C)c2ccccc2-c2ccc(N(c3ccccc3)c3cc(N(c4ccccc4)c4ccc5c(c4)C(C)(C)c4ccccc4-5)c4nc(-c5cccc6oc7ccccc7c56)oc4c3)cc21 ; c1ccc(-c2ccc(N(c3ccccc3)c3cc(N(c4ccc5oc6ccccc6c5c4)c4ccccc4-c4ccccc4)c4nc(-c5ccccc5)oc4c3)cc2)cc1 ; c1ccc(-c2nc3c(N(c4ccc5oc6ccccc6c5c4)c4ccccc4-c4ccccc4)cc(N(c4ccccc4)c4cccc5ccccc45)cc3o2)cc1]

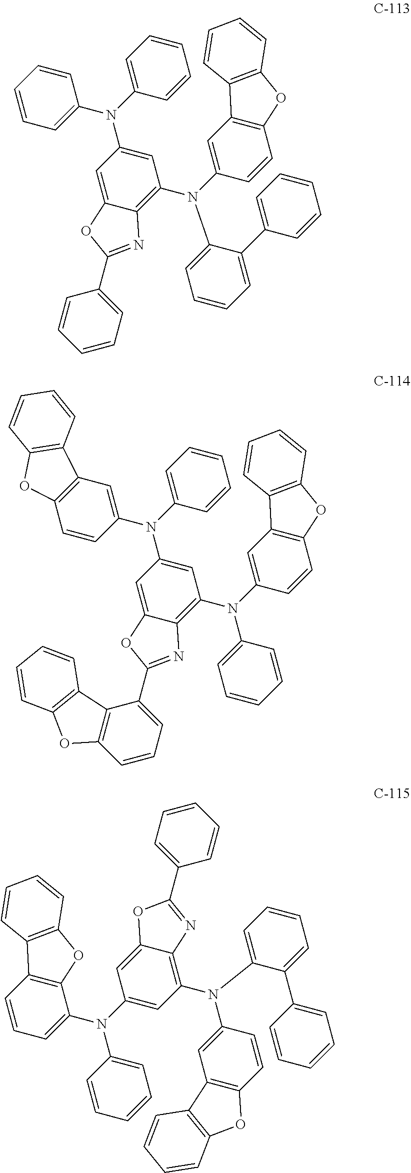

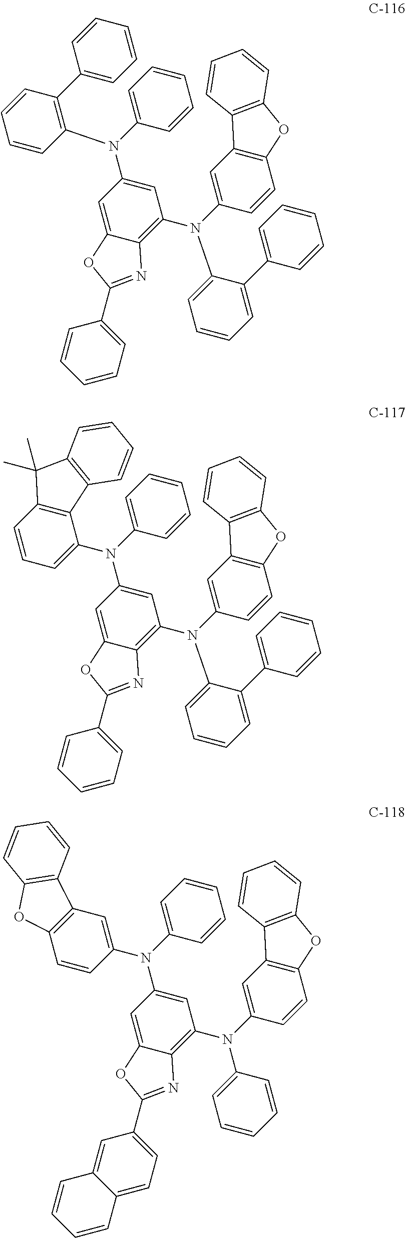

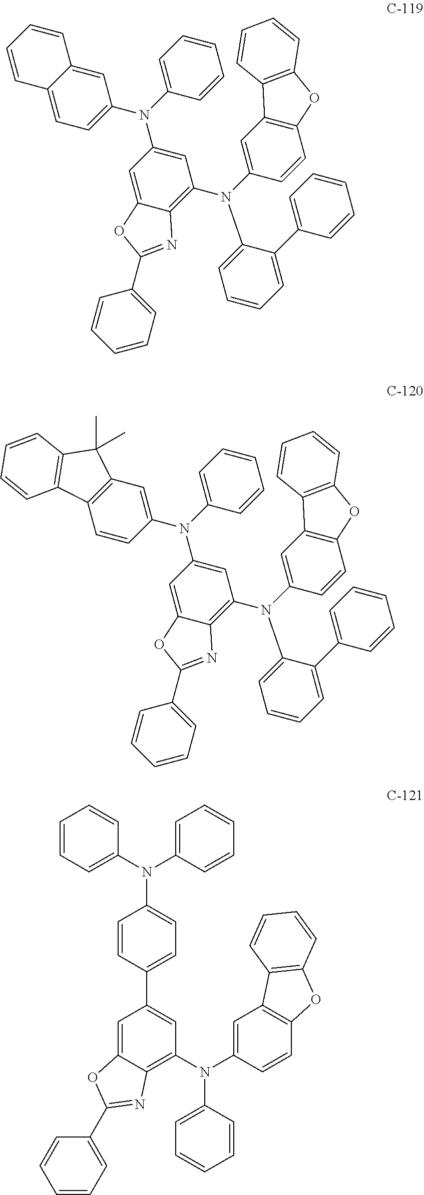 [SMILES: c1ccc(-c2nc3c(N(c4ccc5oc6ccccc6c5c4)c4ccccc4-c4ccccc4)cc(N(c4ccccc4)c4ccc5ccccc5c4)cc3o2)cc1 ; CC1(C)c2ccccc2-c2ccc(N(c3ccccc3)c3cc(N(c4ccc5oc6ccccc6c5c4)c4ccccc4-c4ccccc4)c4nc(-c5ccccc5)oc4c3)cc21 ; c1ccc(-c2nc3c(N(c4ccccc4)c4ccc5oc6ccccc6c5c4)cc(-c4ccc(N(c5ccccc5)c5ccccc5)cc4)cc3o2)cc1]

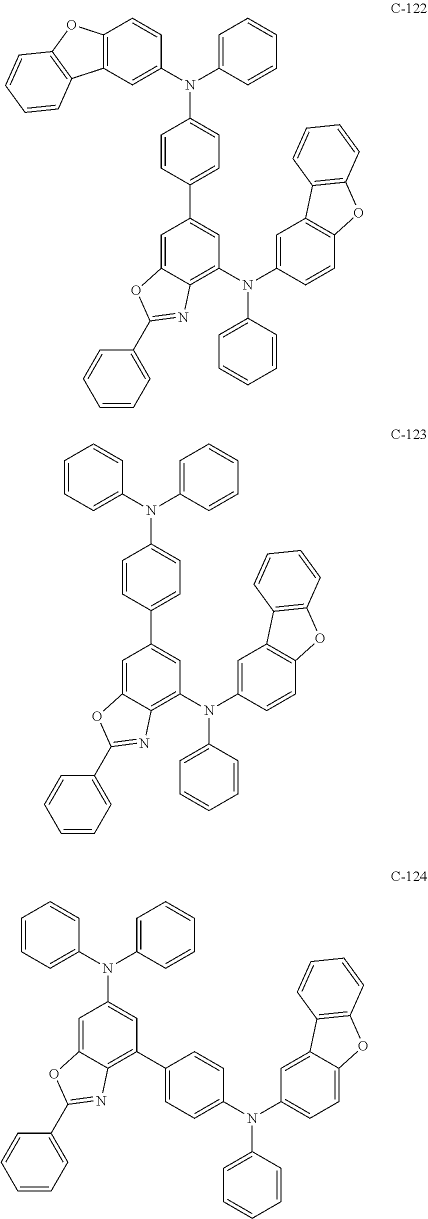

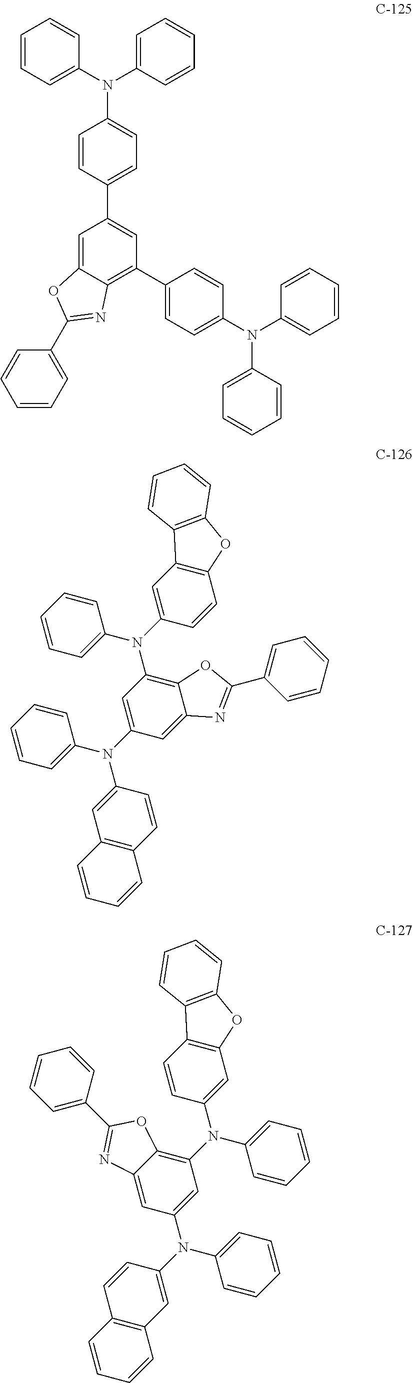 [SMILES: c1ccc(-c2nc3c(-c4ccc(N(c5ccccc5)c5ccccc5)cc4)cc(-c4ccc(N(c5ccccc5)c5ccccc5)cc4)cc3o2)cc1 ; c1ccc(-c2nc3cc(N(c4ccccc4)c4ccc5ccccc5c4)cc(N(c4ccccc4)c4ccc5oc6ccccc6c5c4)c3o2)cc1 ; c1ccc(-c2nc3cc(N(c4ccccc4)c4ccc5ccccc5c4)cc(N(c4ccccc4)c4ccc5c(c4)oc4ccccc45)c3o2)cc1]

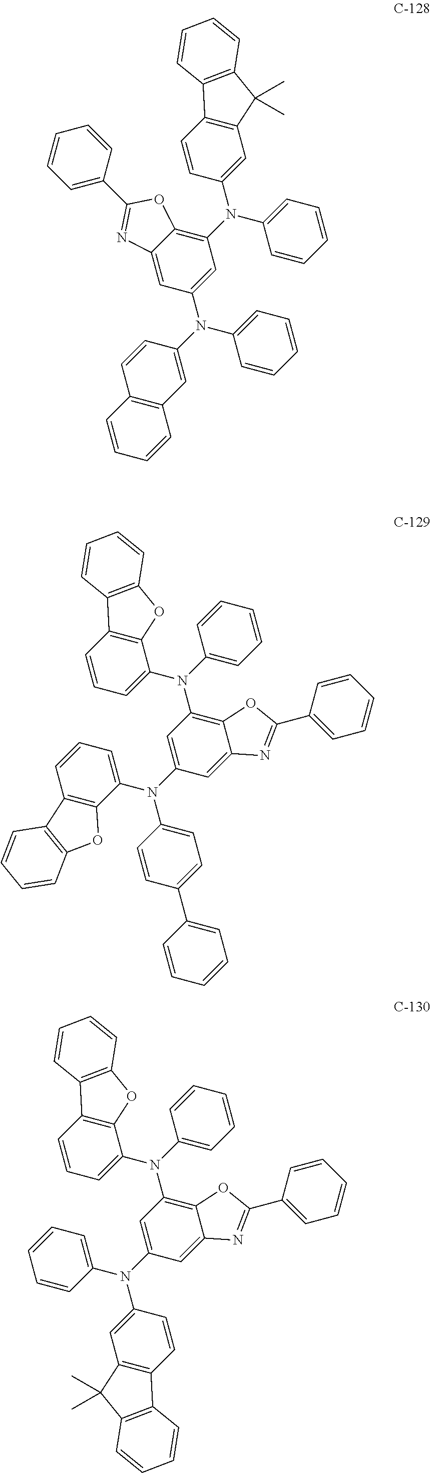 [SMILES: CC1(C)c2ccccc2-c2ccc(N(c3ccccc3)c3cc(N(c4ccccc4)c4ccc5ccccc5c4)cc4nc(-c5ccccc5)oc34)cc21 ; c1ccc(-c2ccc(N(c3cc(N(c4ccccc4)c4cccc5c4oc4ccccc45)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4cccc5c4oc4ccccc45)c4oc(-c5ccccc5)nc4c3)cc21]

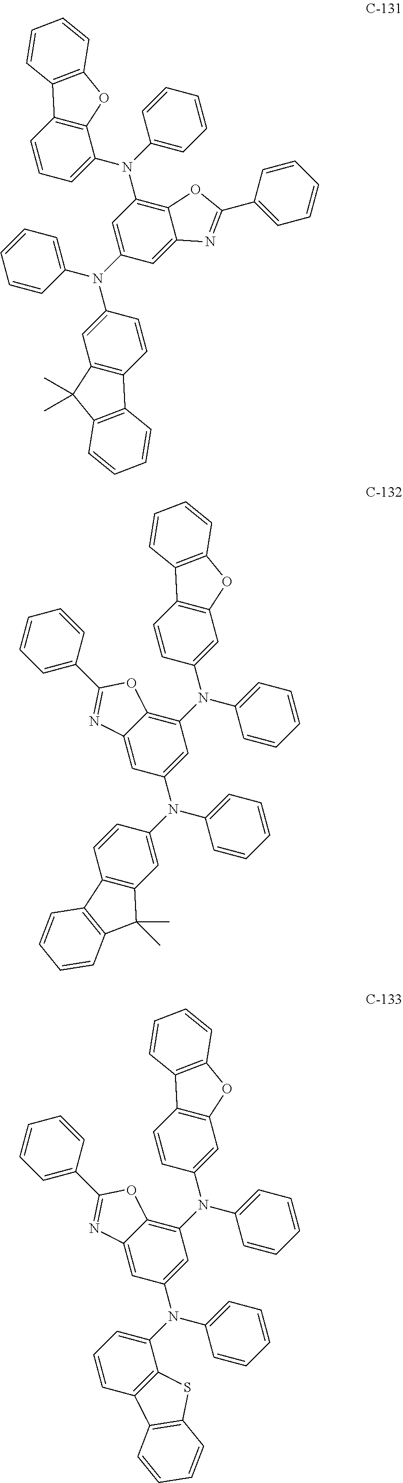 [SMILES: CC1(C)c2ccccc2-c2ccc(N(c3ccccc3)c3cc(N(c4ccccc4)c4cccc5c4oc4ccccc45)c4oc(-c5ccccc5)nc4c3)cc21 ; CC1(C)c2ccccc2-c2ccc(N(c3ccccc3)c3cc(N(c4ccccc4)c4ccc5c(c4)oc4ccccc45)c4oc(-c5ccccc5)nc4c3)cc21 ; c1ccc(-c2nc3cc(N(c4ccccc4)c4cccc5c4sc4ccccc45)cc(N(c4ccccc4)c4ccc5c(c4)oc4ccccc45)c3o2)cc1]

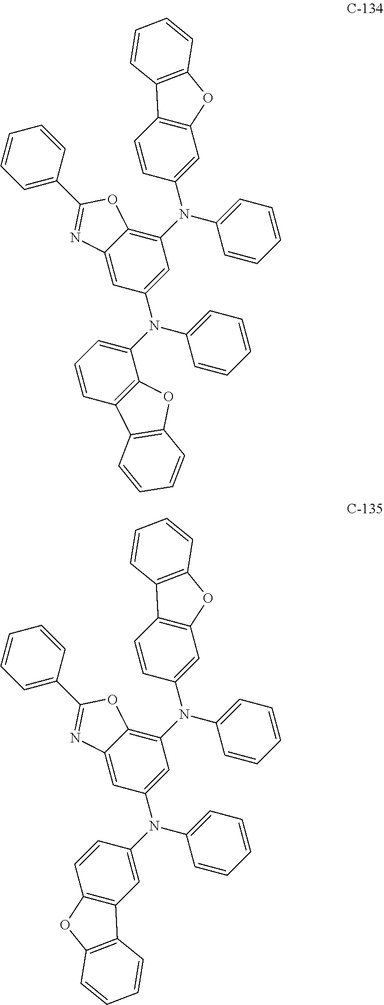

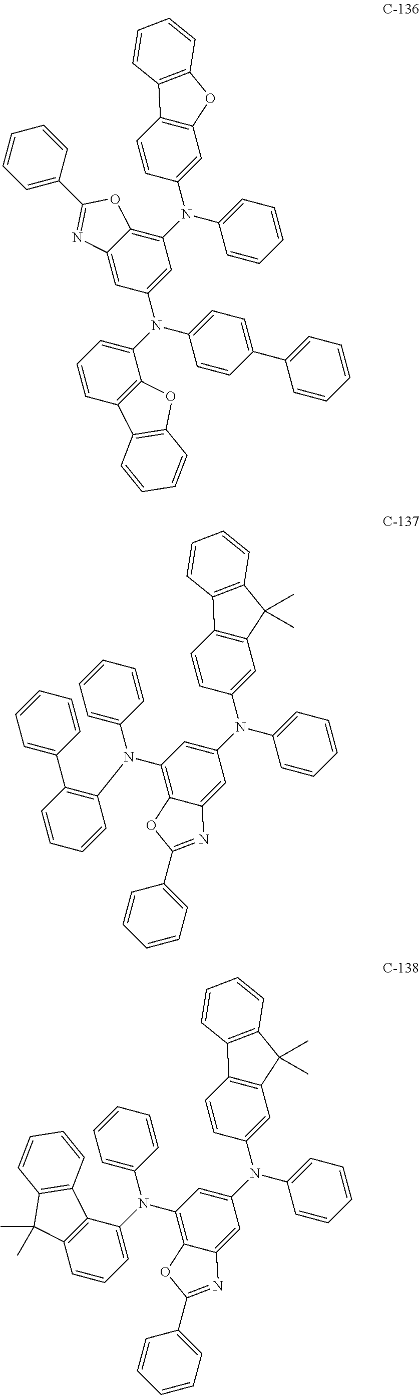 [SMILES: c1ccc(-c2ccc(N(c3cc(N(c4ccccc4)c4ccc5c(c4)oc4ccccc45)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4ccccc4-c4ccccc4)c4oc(-c5ccccc5)nc4c3)cc21 ; CC1(C)c2ccccc2-c2ccc(N(c3ccccc3)c3cc(N(c4ccccc4)c4cccc5c4-c4ccccc4C5(C)C)c4oc(-c5ccccc5)nc4c3)cc21]

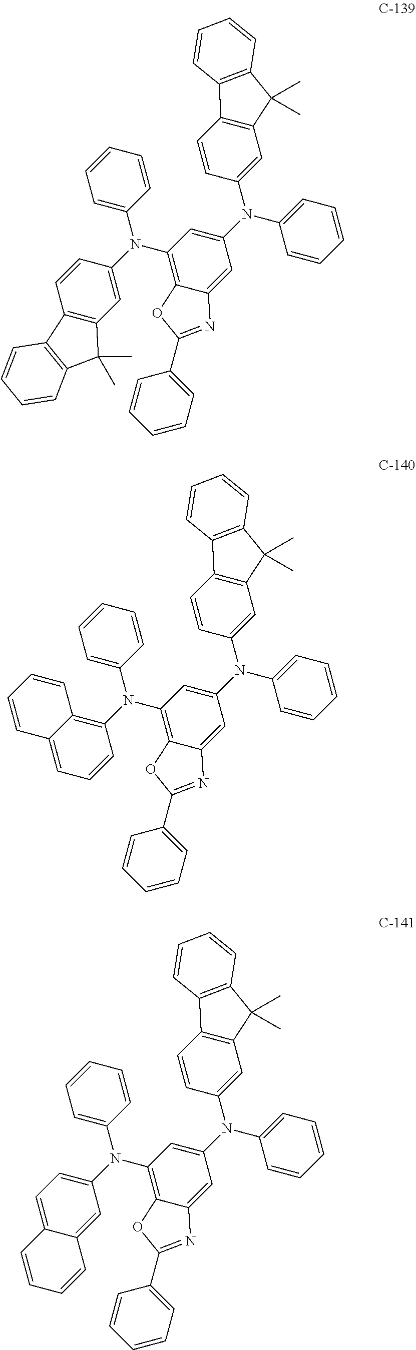 [SMILES: CC1(C)c2ccccc2-c2ccc(N(c3ccccc3)c3cc(N(c4ccccc4)c4ccc5c(c4)C(C)(C)c4ccccc4-5)c4oc(-c5ccccc5)nc4c3)cc21 ; CC1(C)c2ccccc2-c2ccc(N(c3ccccc3)c3cc(N(c4ccccc4)c4cccc5ccccc45)c4oc(-c5ccccc5)nc4c3)cc21 ; CC1(C)c2ccccc2-c2ccc(N(c3ccccc3)c3cc(N(c4ccccc4)c4ccc5ccccc5c4)c4oc(-c5ccccc5)nc4c3)cc21]

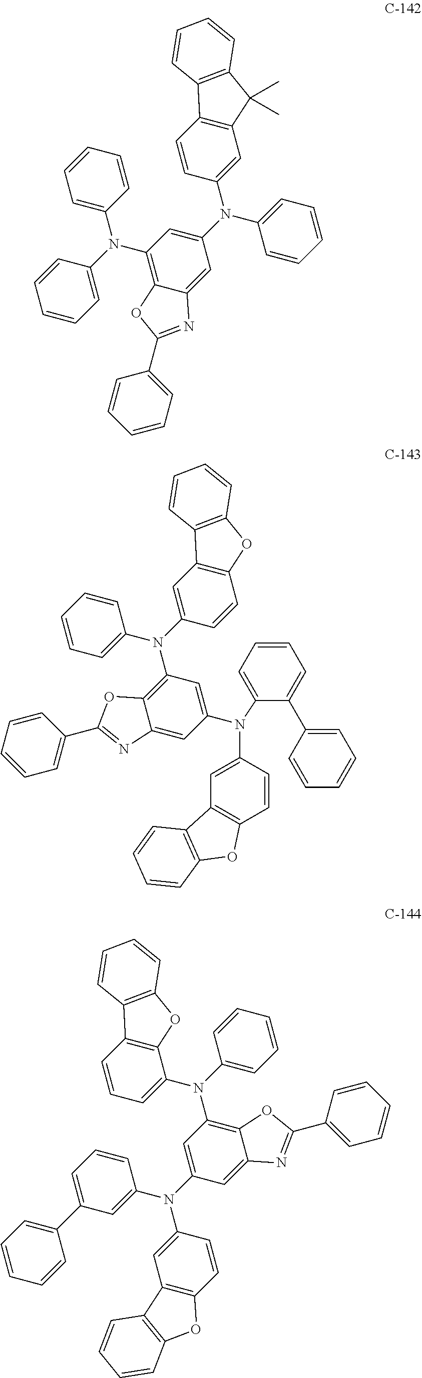 [SMILES: CC1(C)c2ccccc2-c2ccc(N(c3ccccc3)c3cc(N(c4ccccc4)c4ccccc4)c4oc(-c5ccccc5)nc4c3)cc21 ; c1ccc(-c2nc3cc(N(c4ccc5oc6ccccc6c5c4)c4ccccc4-c4ccccc4)cc(N(c4ccccc4)c4ccc5oc6ccccc6c5c4)c3o2)cc1 ; c1ccc(-c2cccc(N(c3cc(N(c4ccccc4)c4cccc5c4oc4ccccc45)c4oc(-c5ccccc5)nc4c3)c3ccc4oc5ccccc5c4c3)c2)cc1]

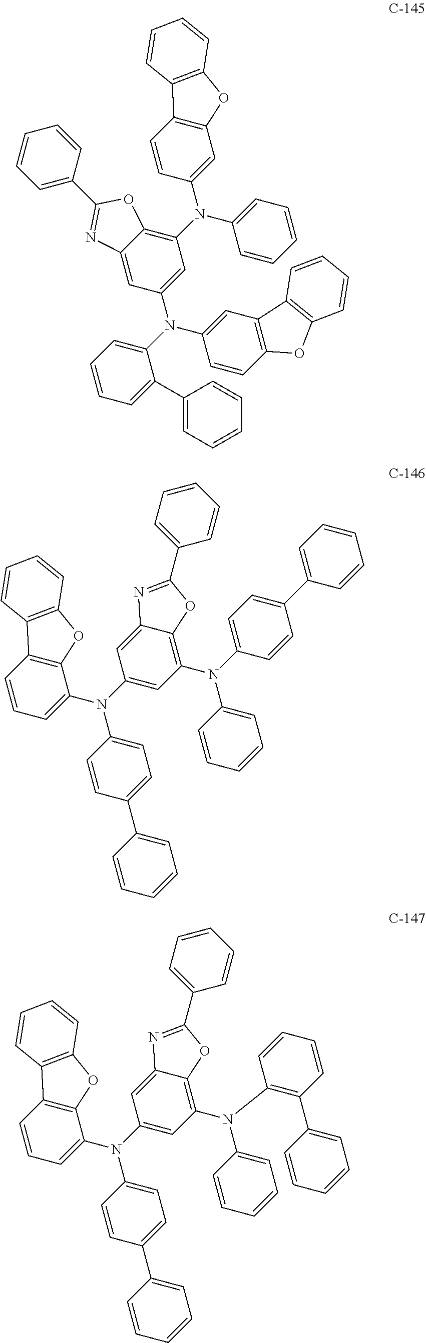

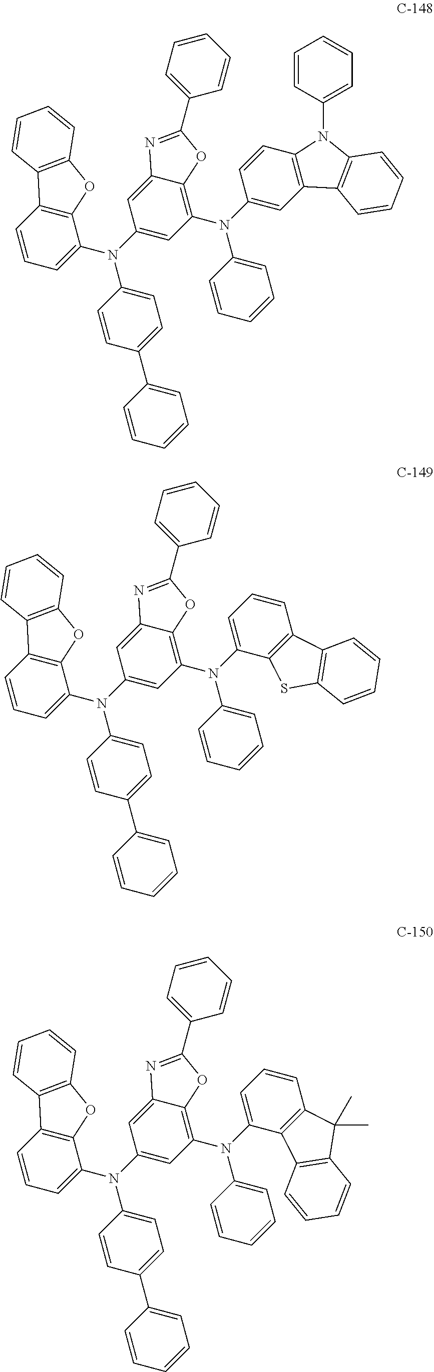

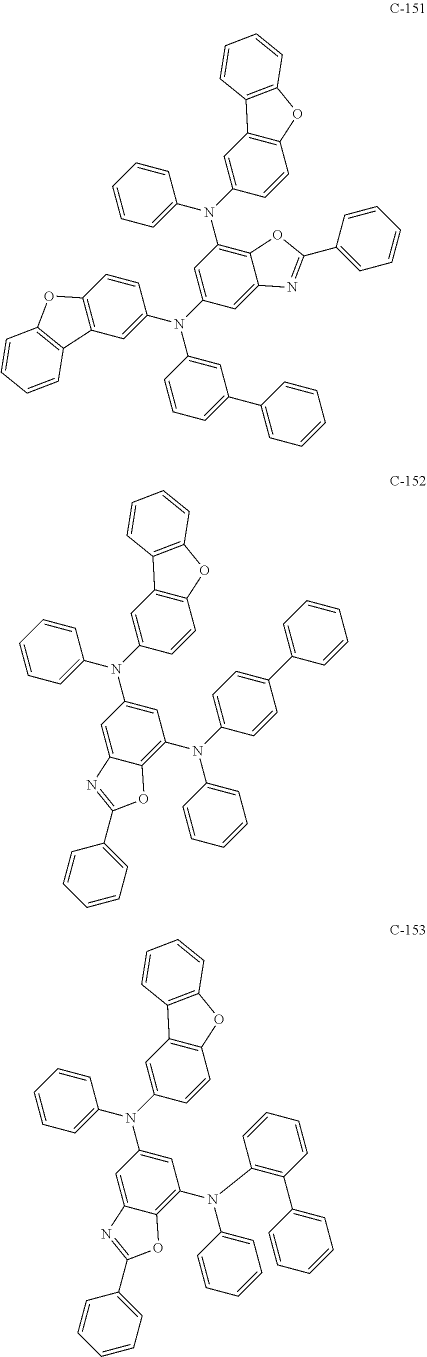 [SMILES: c1ccc(-c2cccc(N(c3cc(N(c4ccccc4)c4ccc5oc6ccccc6c5c4)c4oc(-c5ccccc5)nc4c3)c3ccc4oc5ccccc5c4c3)c2)cc1 ; c1ccc(-c2ccc(N(c3ccccc3)c3cc(N(c4ccccc4)c4ccc5oc6ccccc6c5c4)cc4nc(-c5ccccc5)oc34)cc2)cc1 ; c1ccc(-c2nc3cc(N(c4ccccc4)c4ccc5oc6ccccc6c5c4)cc(N(c4ccccc4)c4ccccc4-c4ccccc4)c3o2)cc1]

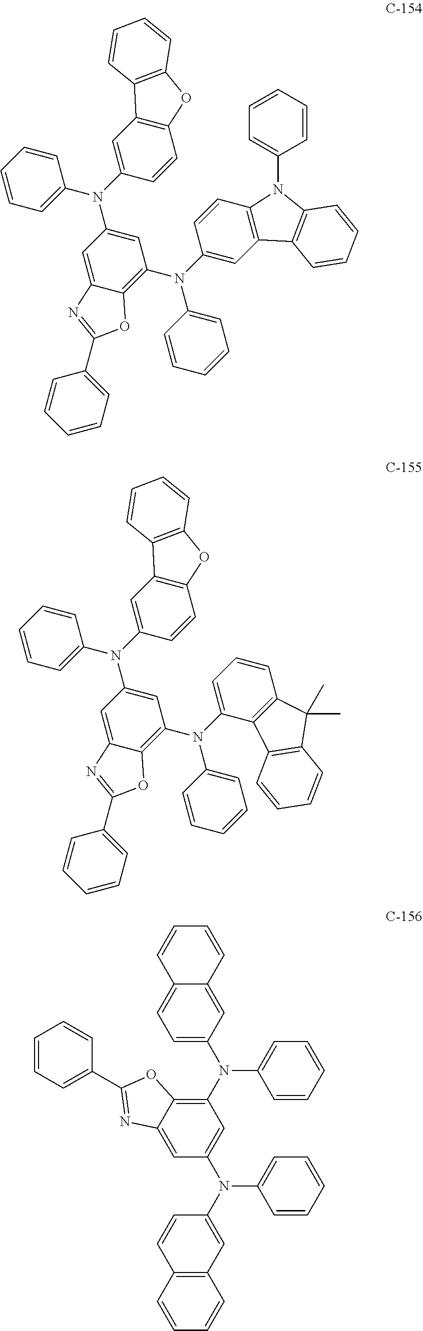 [SMILES: c1ccc(-c2nc3cc(N(c4ccccc4)c4ccc5oc6ccccc6c5c4)cc(N(c4ccccc4)c4ccc5c(c4)c4ccccc4n5-c4ccccc4)c3o2)cc1 ; CC1(C)c2ccccc2-c2c(N(c3ccccc3)c3cc(N(c4ccccc4)c4ccc5oc6ccccc6c5c4)cc4nc(-c5ccccc5)oc34)cccc21 ; c1ccc(-c2nc3cc(N(c4ccccc4)c4ccc5ccccc5c4)cc(N(c4ccccc4)c4ccc5ccccc5c4)c3o2)cc1]

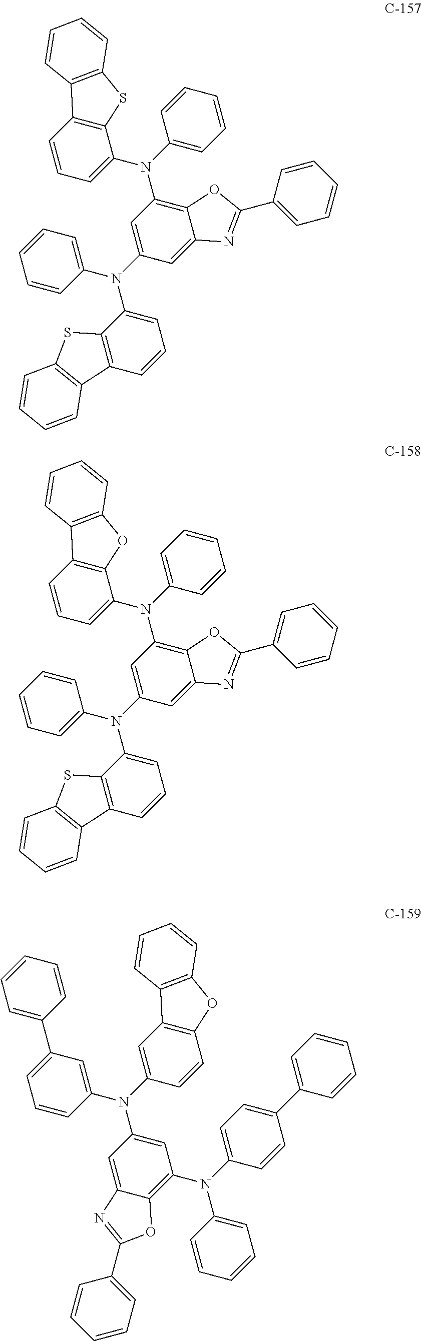

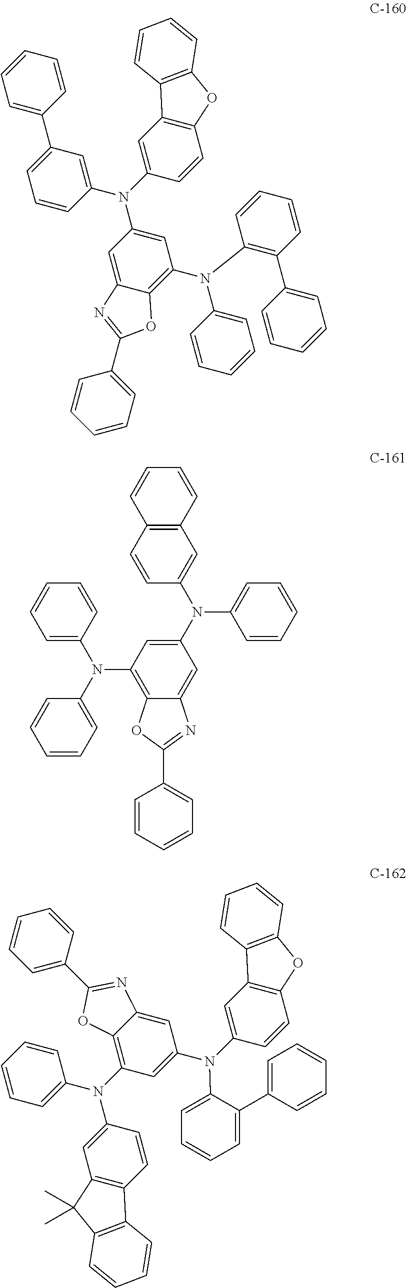

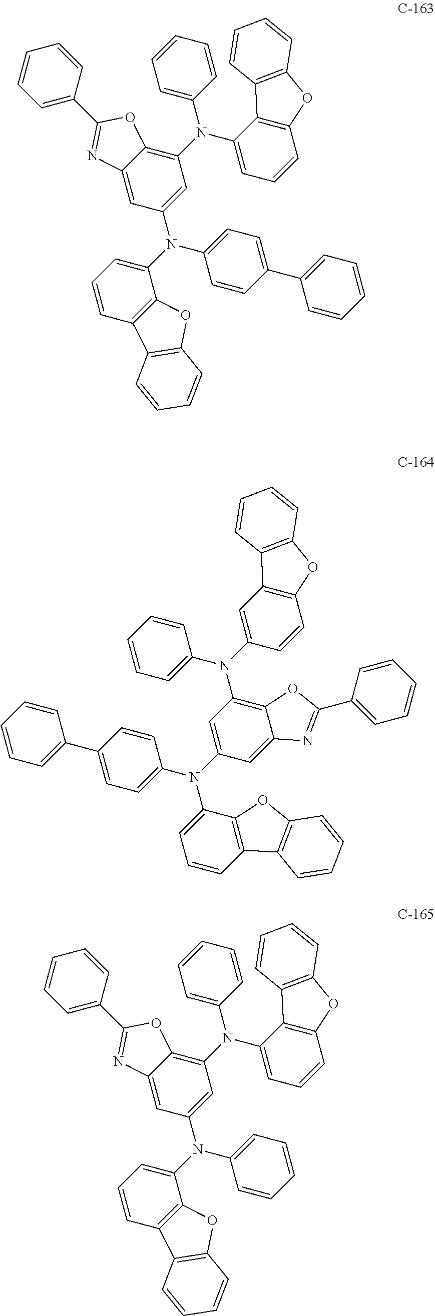

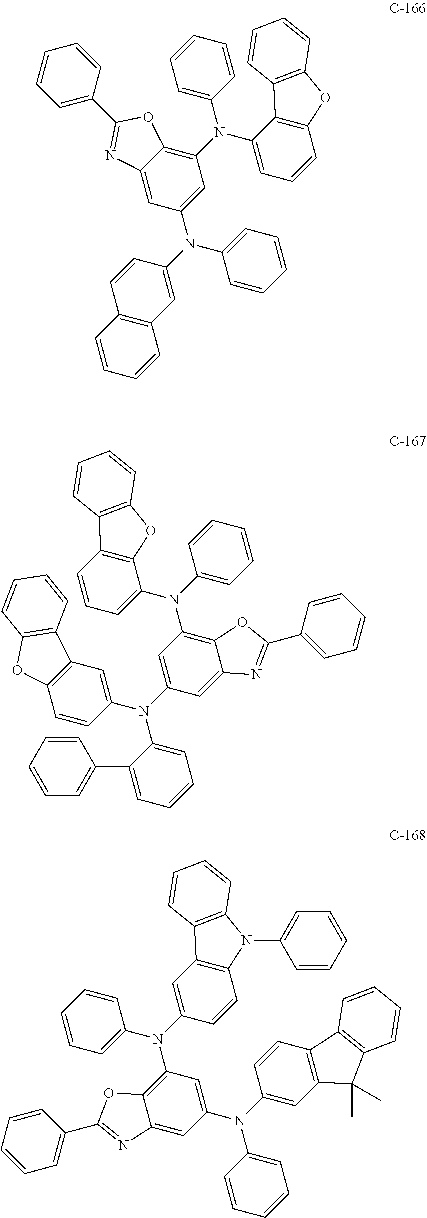 [SMILES: c1ccc(-c2nc3cc(N(c4ccccc4)c4ccc5ccccc5c4)cc(N(c4ccccc4)c4cccc5oc6ccccc6c45)c3o2)cc1 ; c1ccc(-c2nc3cc(N(c4ccc5oc6ccccc6c5c4)c4ccccc4-c4ccccc4)cc(N(c4ccccc4)c4cccc5c4oc4ccccc45)c3o2)cc1 ; CC1(C)c2ccccc2-c2ccc(N(c3ccccc3)c3cc(N(c4ccccc4)c4ccc5c(c4)c4ccccc4n5-c4ccccc4)c4oc(-c5ccccc5)nc4c3)cc21]

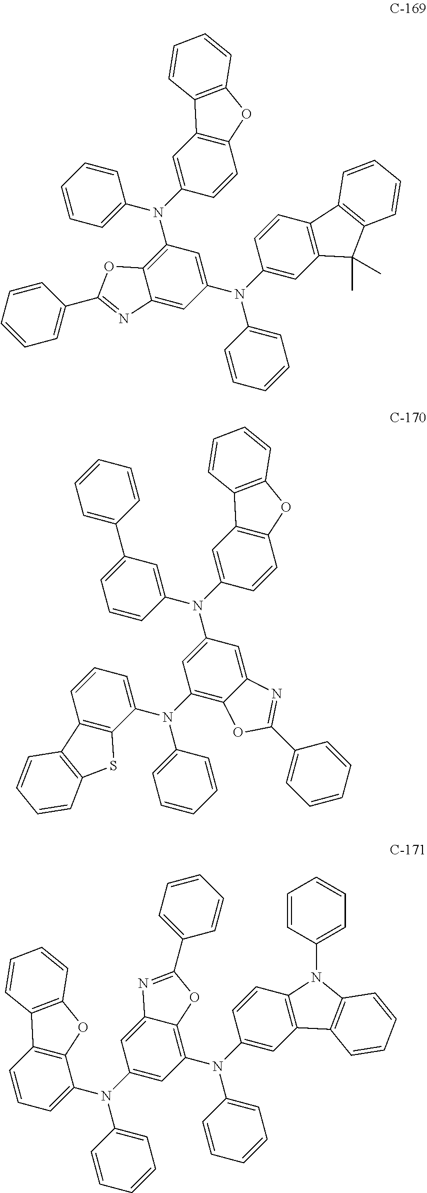

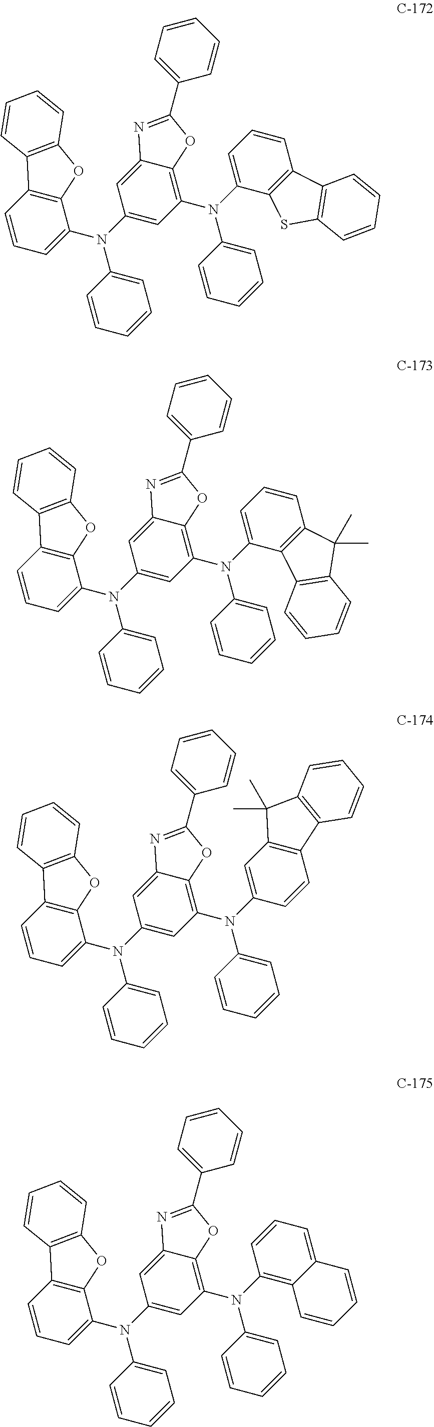 [SMILES: c1ccc(-c2nc3cc(N(c4ccccc4)c4cccc5c4oc4ccccc45)cc(N(c4ccccc4)c4cccc5c4sc4ccccc45)c3o2)cc1 ; CC1(C)c2ccccc2-c2c(N(c3ccccc3)c3cc(N(c4ccccc4)c4cccc5c4oc4ccccc45)cc4nc(-c5ccccc5)oc34)cccc21 ; CC1(C)c2ccccc2-c2ccc(N(c3ccccc3)c3cc(N(c4ccccc4)c4cccc5c4oc4ccccc45)cc4nc(-c5ccccc5)oc34)cc21 ; c1ccc(-c2nc3cc(N(c4ccccc4)c4cccc5c4oc4ccccc45)cc(N(c4ccccc4)c4cccc5ccccc45)c3o2)cc1]

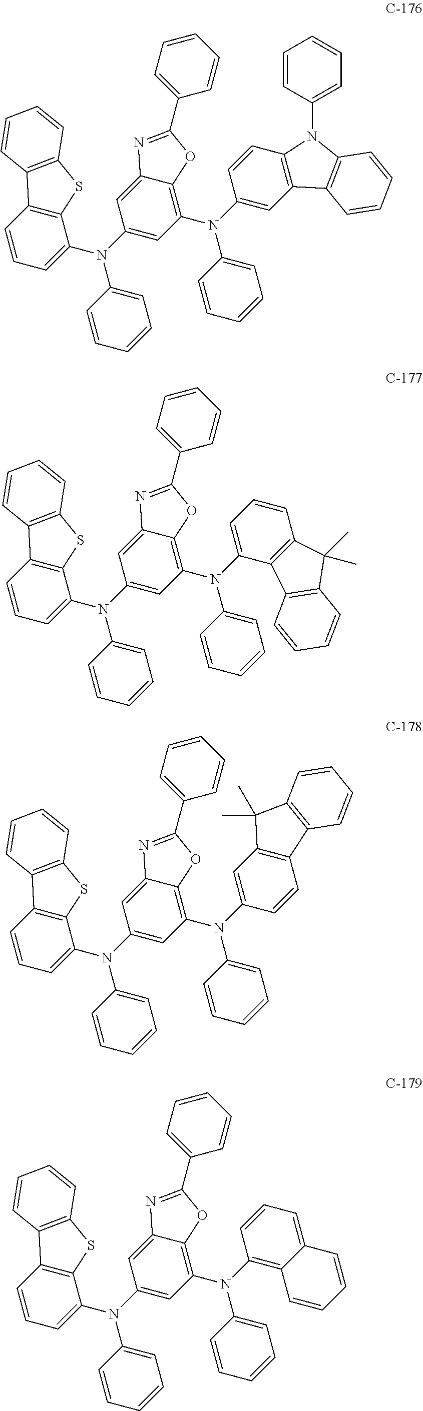 [SMILES: c1ccc(-c2nc3cc(N(c4ccccc4)c4cccc5c4sc4ccccc45)cc(N(c4ccccc4)c4ccc5c(c4)c4ccccc4n5-c4ccccc4)c3o2)cc1 ; CC1(C)c2ccccc2-c2c(N(c3ccccc3)c3cc(N(c4ccccc4)c4cccc5c4sc4ccccc45)cc4nc(-c5ccccc5)oc34)cccc21 ; CC1(C)c2ccccc2-c2ccc(N(c3ccccc3)c3cc(N(c4ccccc4)c4cccc5c4sc4ccccc45)cc4nc(-c5ccccc5)oc34)cc21 ; c1ccc(-c2nc3cc(N(c4ccccc4)c4cccc5c4sc4ccccc45)cc(N(c4ccccc4)c4cccc5ccccc45)c3o2)cc1]

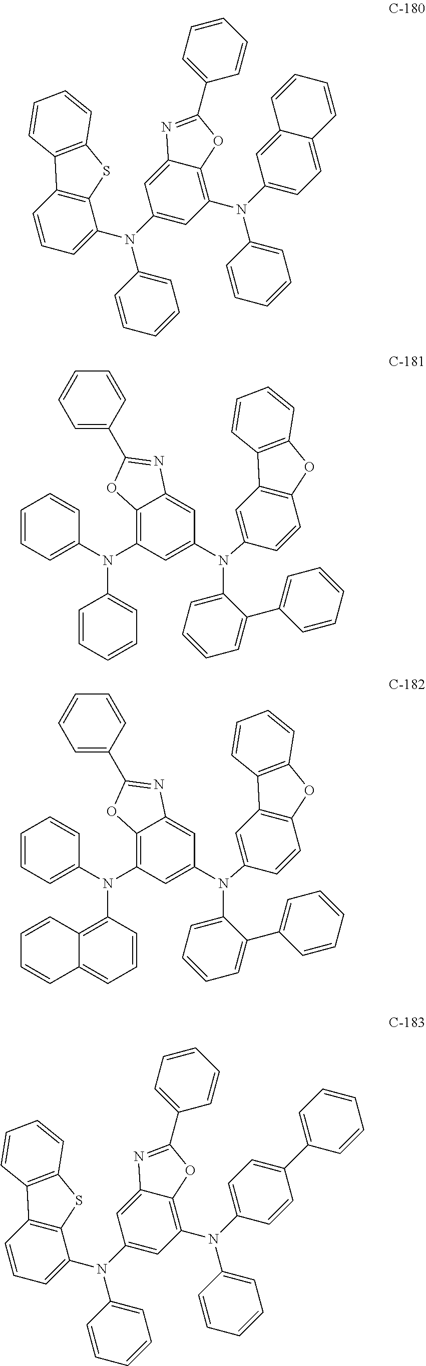

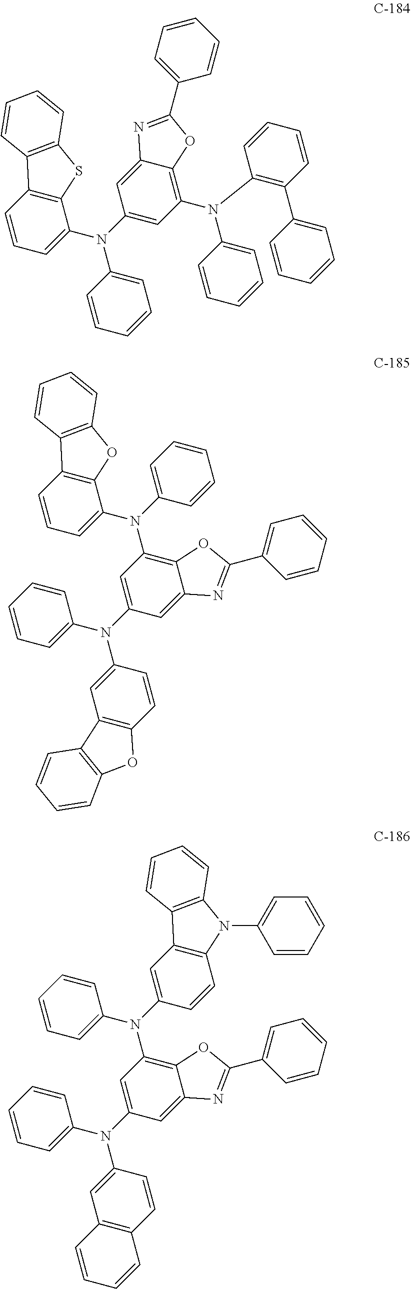 [SMILES: c1ccc(-c2nc3cc(N(c4ccccc4)c4cccc5c4sc4ccccc45)cc(N(c4ccccc4)c4ccccc4-c4ccccc4)c3o2)cc1 ; c1ccc(-c2nc3cc(N(c4ccccc4)c4ccc5oc6ccccc6c5c4)cc(N(c4ccccc4)c4cccc5c4oc4ccccc45)c3o2)cc1 ; c1ccc(-c2nc3cc(N(c4ccccc4)c4ccc5ccccc5c4)cc(N(c4ccccc4)c4ccc5c(c4)c4ccccc4n5-c4ccccc4)c3o2)cc1]

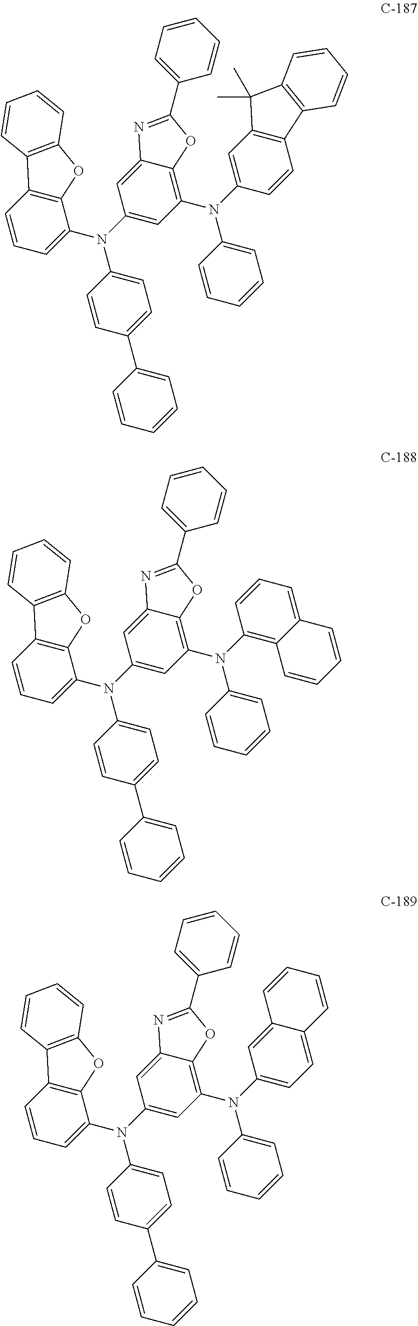

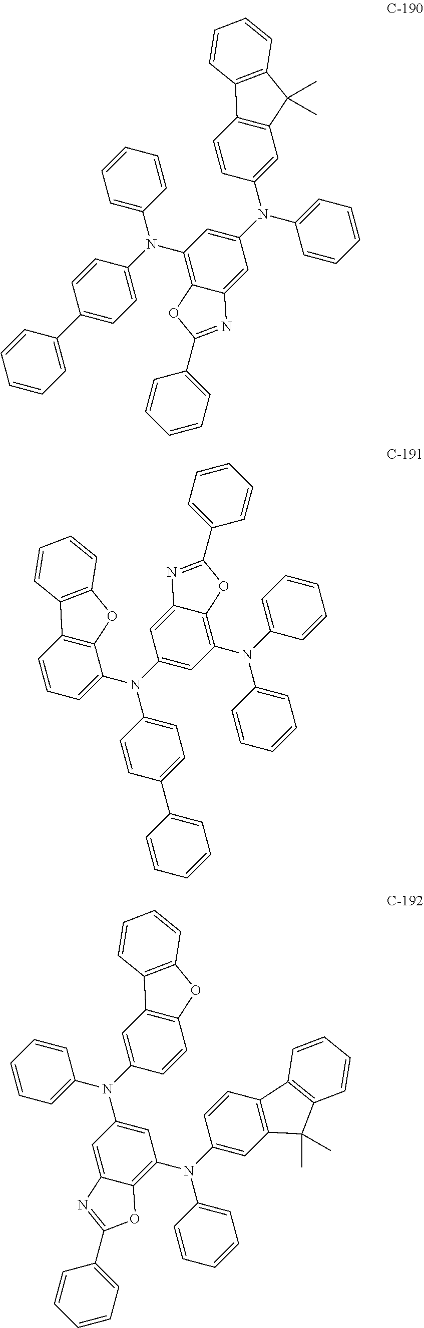

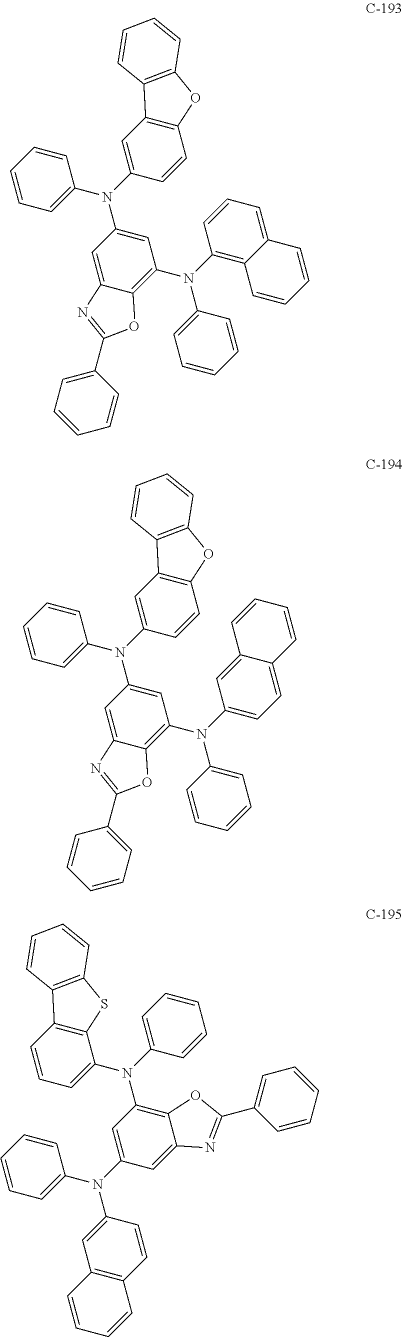

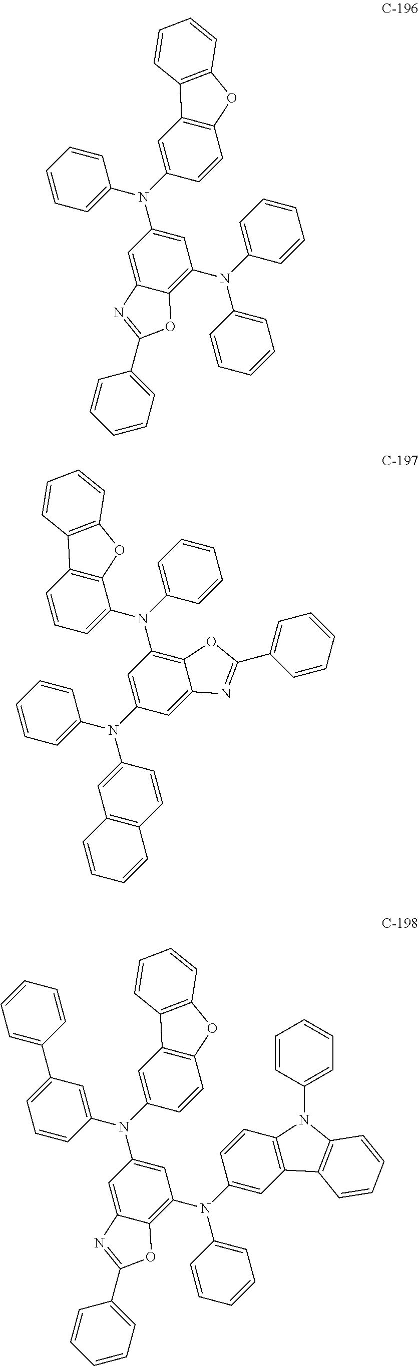 [SMILES: c1ccc(-c2nc3cc(N(c4ccccc4)c4ccc5oc6ccccc6c5c4)cc(N(c4ccccc4)c4ccccc4)c3o2)cc1 ; c1ccc(-c2nc3cc(N(c4ccccc4)c4ccc5ccccc5c4)cc(N(c4ccccc4)c4cccc5c4oc4ccccc45)c3o2)cc1 ; c1ccc(-c2cccc(N(c3cc(N(c4ccccc4)c4ccc5c(c4)c4ccccc4n5-c4ccccc4)c4oc(-c5ccccc5)nc4c3)c3ccc4oc5ccccc5c4c3)c2)cc1]

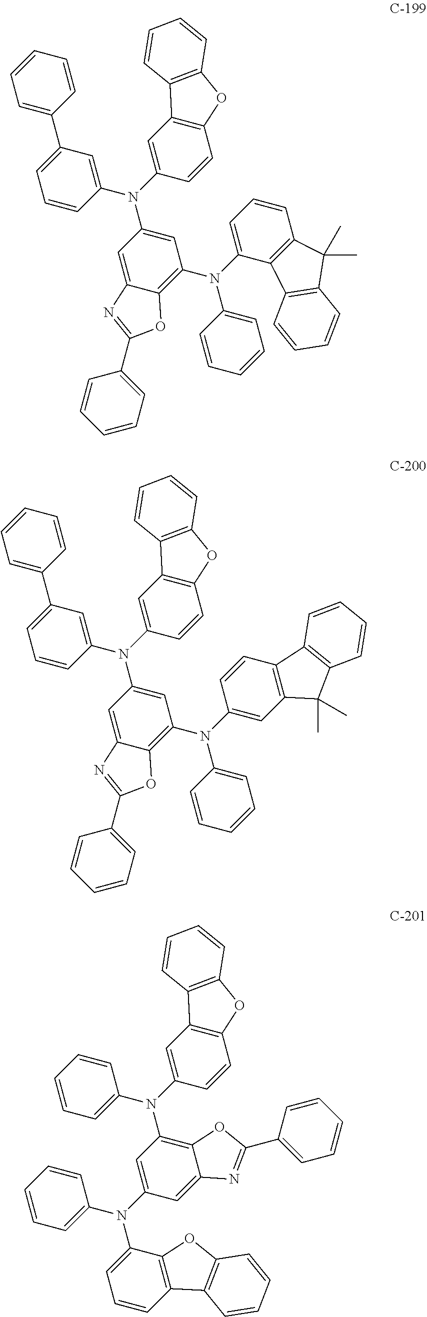 [SMILES: CC1(C)c2ccccc2-c2c(N(c3ccccc3)c3cc(N(c4cccc(-c5ccccc5)c4)c4ccc5oc6ccccc6c5c4)cc4nc(-c5ccccc5)oc34)cccc21 ; CC1(C)c2ccccc2-c2ccc(N(c3ccccc3)c3cc(N(c4cccc(-c5ccccc5)c4)c4ccc5oc6ccccc6c5c4)cc4nc(-c5ccccc5)oc34)cc21 ; c1ccc(-c2nc3cc(N(c4ccccc4)c4cccc5c4oc4ccccc45)cc(N(c4ccccc4)c4ccc5oc6ccccc6c5c4)c3o2)cc1]

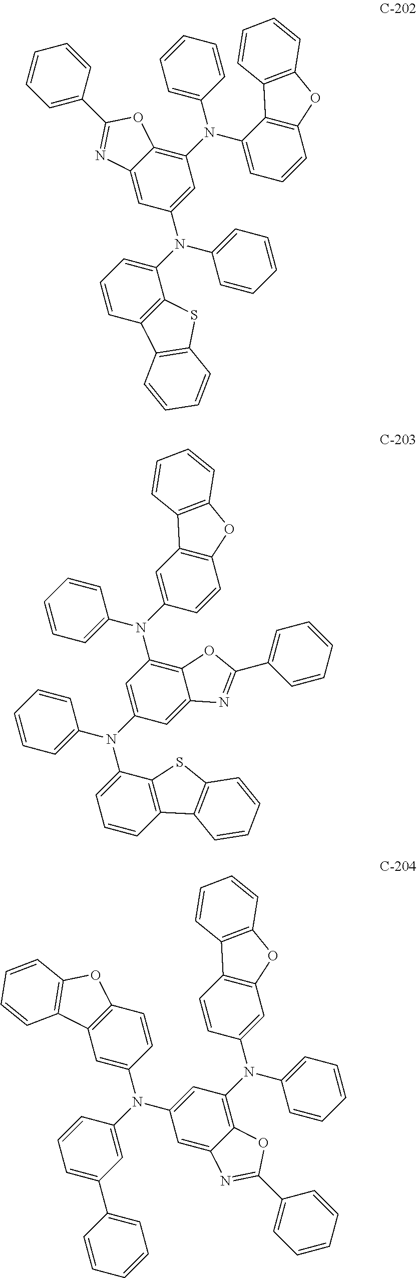

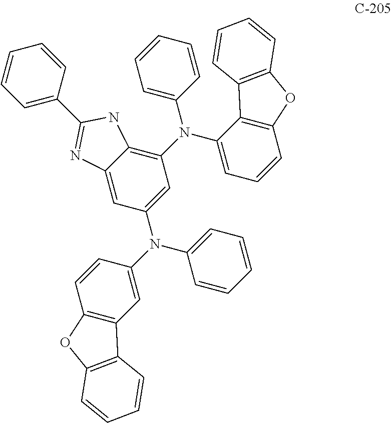 [SMILES: c1ccc(-c2nc3cc(N(c4ccccc4)c4ccc5oc6ccccc6c5c4)cc(N(c4ccccc4)c4cccc5oc6ccccc6c45)c3[nH]2)cc1]

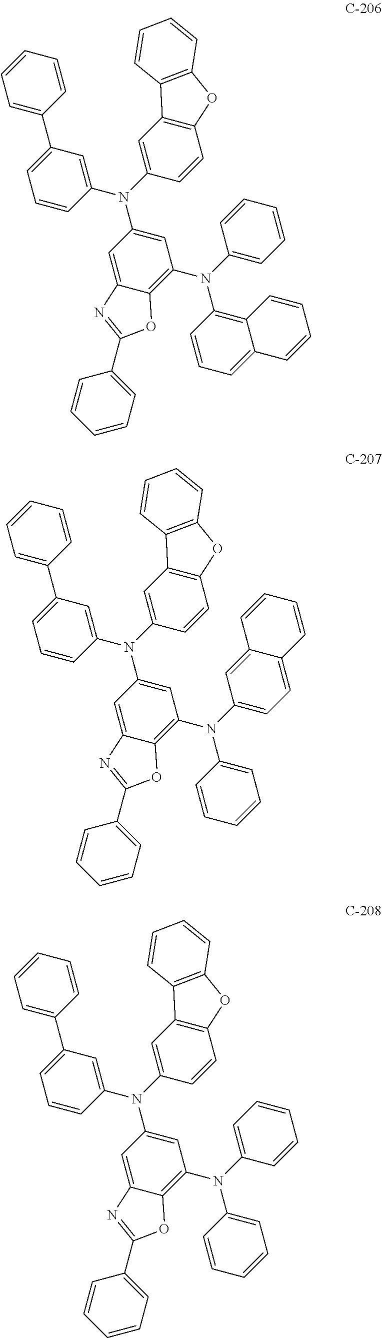 [SMILES: c1ccc(-c2cccc(N(c3cc(N(c4ccccc4)c4cccc5ccccc45)c4oc(-c5ccccc5)nc4c3)c3ccc4oc5ccccc5c4c3)c2)cc1 ; c1ccc(-c2cccc(N(c3cc(N(c4ccccc4)c4ccc5ccccc5c4)c4oc(-c5ccccc5)nc4c3)c3ccc4oc5ccccc5c4c3)c2)cc1 ; c1ccc(-c2cccc(N(c3cc(N(c4ccccc4)c4ccccc4)c4oc(-c5ccccc5)nc4c3)c3ccc4oc5ccccc5c4c3)c2)cc1]

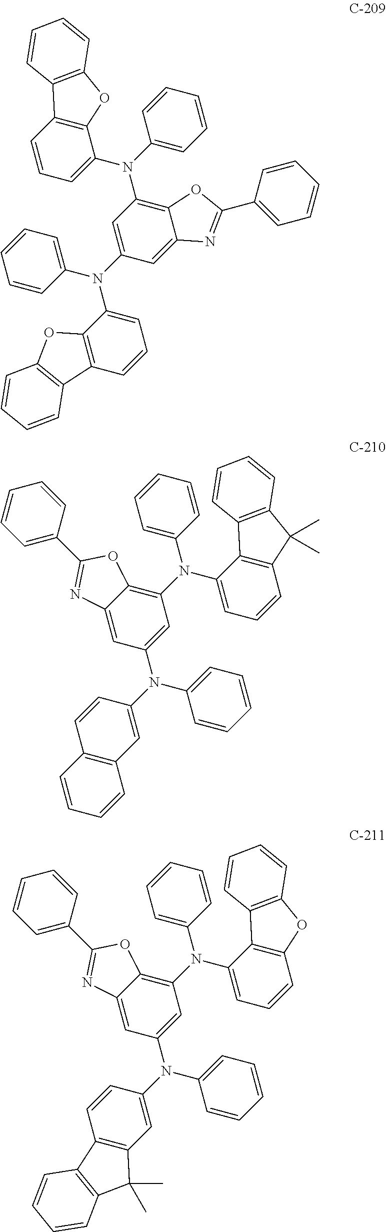 [SMILES: c1ccc(-c2nc3cc(N(c4ccccc4)c4cccc5c4oc4ccccc45)cc(N(c4ccccc4)c4cccc5c4oc4ccccc45)c3o2)cc1 ; CC1(C)c2ccccc2-c2c(N(c3ccccc3)c3cc(N(c4ccccc4)c4ccc5ccccc5c4)cc4nc(-c5ccccc5)oc34)cccc21 ; CC1(C)c2ccccc2-c2ccc(N(c3ccccc3)c3cc(N(c4ccccc4)c4cccc5oc6ccccc6c45)c4oc(-c5ccccc5)nc4c3)cc21]

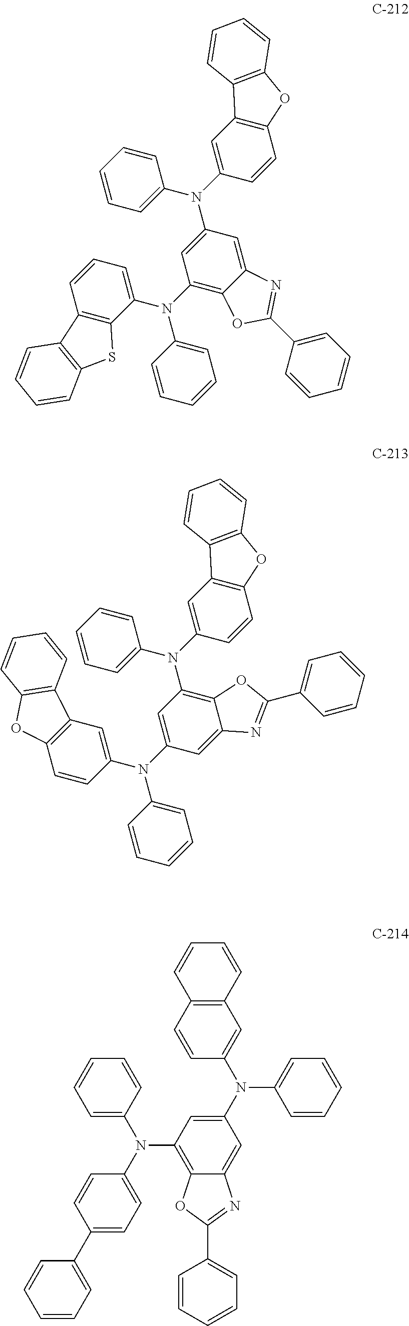 [SMILES: c1ccc(-c2nc3cc(N(c4ccccc4)c4ccc5oc6ccccc6c5c4)cc(N(c4ccccc4)c4cccc5c4sc4ccccc45)c3o2)cc1 ; c1ccc(-c2nc3cc(N(c4ccccc4)c4ccc5oc6ccccc6c5c4)cc(N(c4ccccc4)c4ccc5oc6ccccc6c5c4)c3o2)cc1 ; c1ccc(-c2ccc(N(c3ccccc3)c3cc(N(c4ccccc4)c4ccc5ccccc5c4)cc4nc(-c5ccccc5)oc34)cc2)cc1]

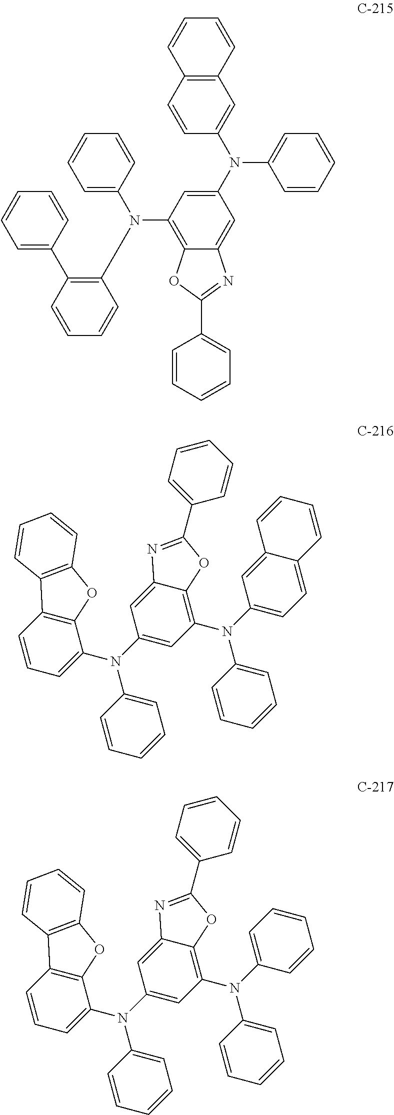

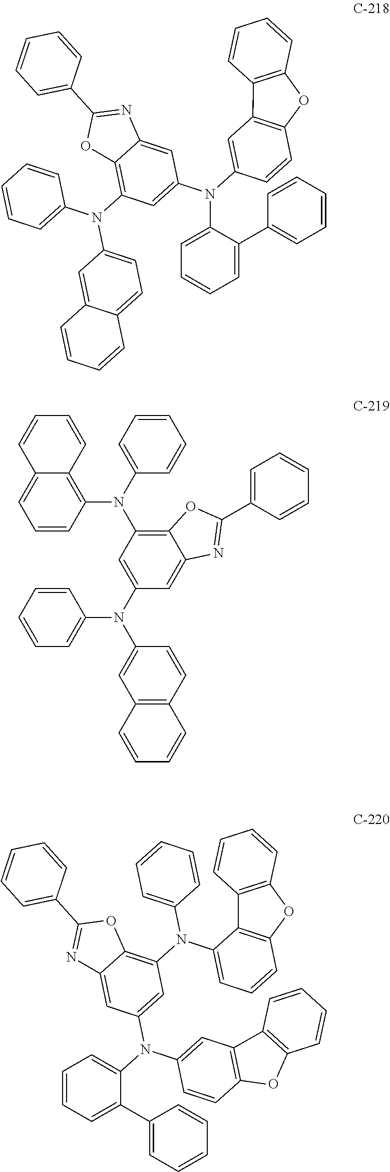 [SMILES: c1ccc(-c2nc3cc(N(c4ccc5oc6ccccc6c5c4)c4ccccc4-c4ccccc4)cc(N(c4ccccc4)c4ccc5ccccc5c4)c3o2)cc1 ; c1ccc(-c2nc3cc(N(c4ccccc4)c4ccc5ccccc5c4)cc(N(c4ccccc4)c4cccc5ccccc45)c3o2)cc1 ; c1ccc(-c2nc3cc(N(c4ccc5oc6ccccc6c5c4)c4ccccc4-c4ccccc4)cc(N(c4ccccc4)c4cccc5oc6ccccc6c45)c3o2)cc1]

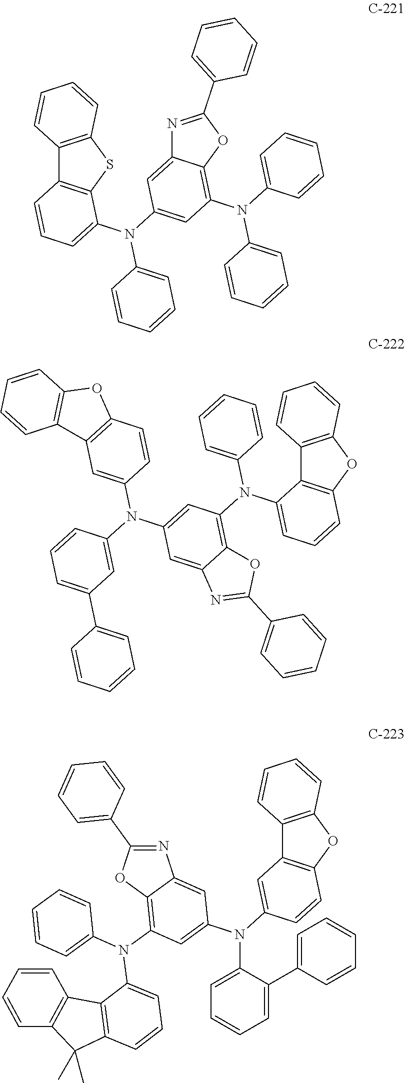 [SMILES: c1ccc(-c2nc3cc(N(c4ccccc4)c4cccc5c4sc4ccccc45)cc(N(c4ccccc4)c4ccccc4)c3o2)cc1 ; c1ccc(-c2cccc(N(c3cc(N(c4ccccc4)c4cccc5oc6ccccc6c45)c4oc(-c5ccccc5)nc4c3)c3ccc4oc5ccccc5c4c3)c2)cc1 ; CC1(C)c2ccccc2-c2c(N(c3ccccc3)c3cc(N(c4ccc5oc6ccccc6c5c4)c4ccccc4-c4ccccc4)cc4nc(-c5ccccc5)oc34)cccc21]

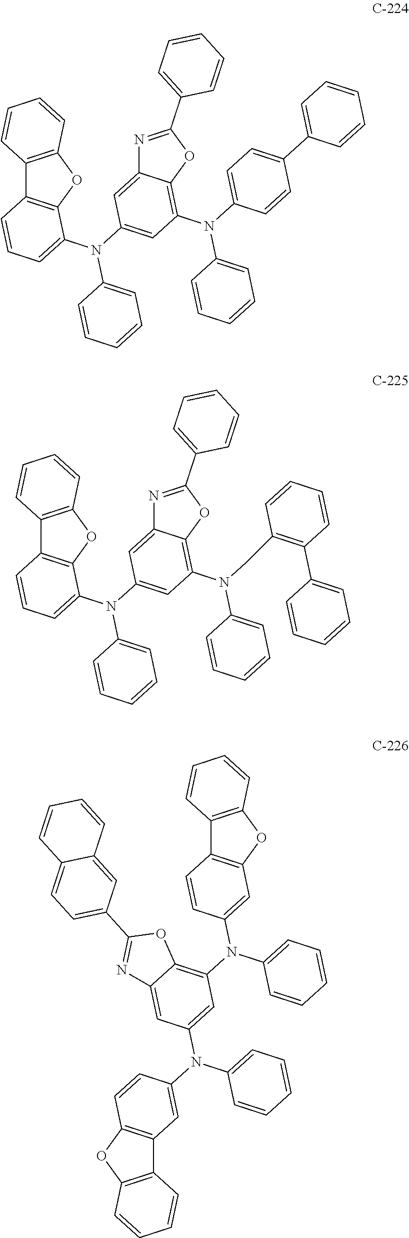 [SMILES: c1ccc(-c2ccc(N(c3ccccc3)c3cc(N(c4ccccc4)c4cccc5c4oc4ccccc45)cc4nc(-c5ccccc5)oc34)cc2)cc1 ; c1ccc(-c2nc3cc(N(c4ccccc4)c4cccc5c4oc4ccccc45)cc(N(Cc4ccccc4-c4ccccc4)c4ccccc4)c3o2)cc1 ; c1ccc(N(c2cc(N(c3ccccc3)c3ccc4c(c3)oc3ccccc34)c3oc(-c4ccc5ccccc5c4)nc3c2)c2ccc3oc4ccccc4c3c2)cc1]

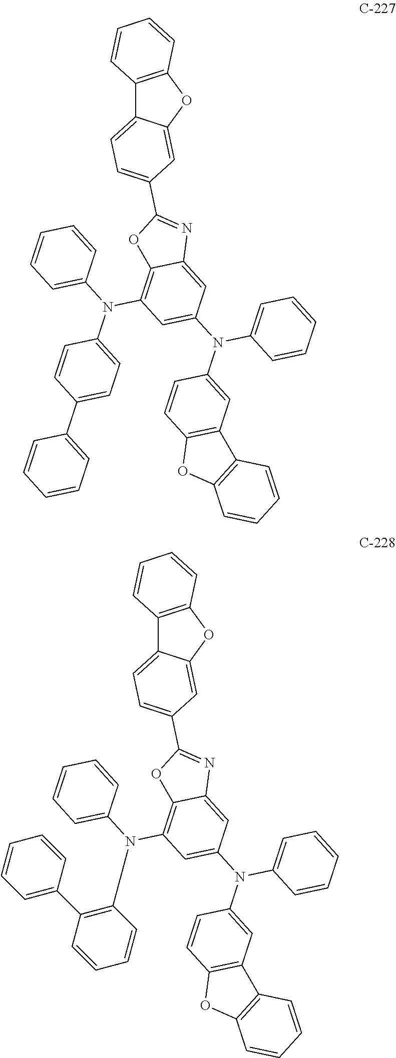 [SMILES: c1ccc(-c2ccc(N(c3ccccc3)c3cc(N(c4ccccc4)c4ccc5oc6ccccc6c5c4)cc4nc(-c5ccc6c(c5)oc5ccccc56)oc34)cc2)cc1 ; c1ccc(-c2ccccc2CN(c2ccccc2)c2cc(N(c3ccccc3)c3ccc4oc5ccccc5c4c3)cc3nc(-c4ccc5c(c4)oc4ccccc45)oc23)cc1]

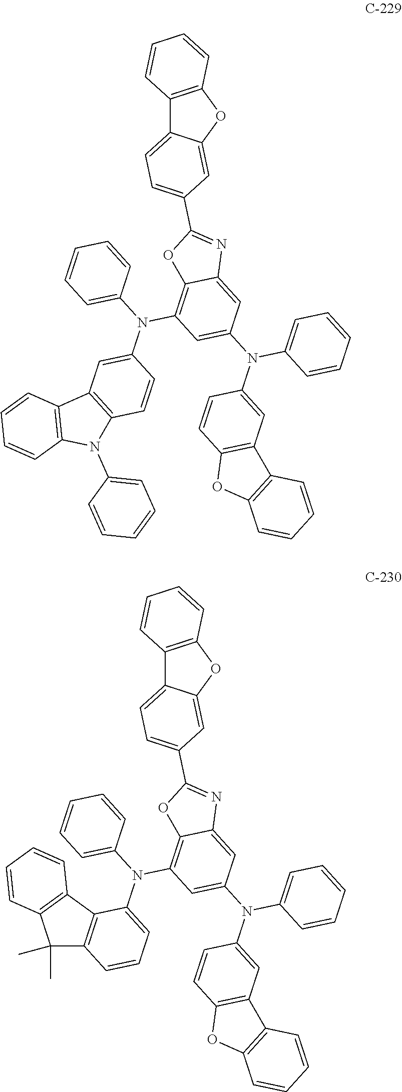 [SMILES: c1ccc(N(c2cc(N(c3ccccc3)c3ccc4c(c3)c3ccccc3n4-c3ccccc3)c3oc(-c4ccc5c(c4)oc4ccccc45)nc3c2)c2ccc3oc4ccccc4c3c2)cc1 ; CC1(C)c2ccccc2-c2c(N(c3ccccc3)c3cc(N(c4ccccc4)c4ccc5oc6ccccc6c5c4)cc4nc(-c5ccc6c(c5)oc5ccccc56)oc34)cccc21]

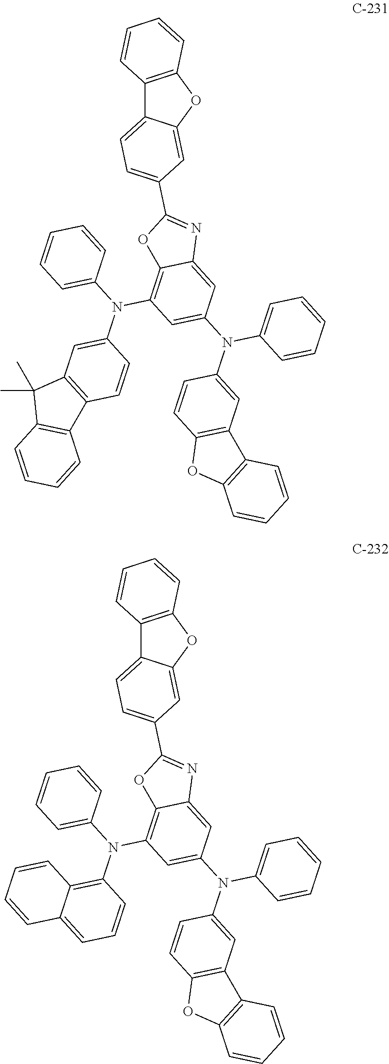 [SMILES: CC1(C)c2ccccc2-c2ccc(N(c3ccccc3)c3cc(N(c4ccccc4)c4ccc5oc6ccccc6c5c4)cc4nc(-c5ccc6c(c5)oc5ccccc56)oc34)cc21 ; c1ccc(N(c2cc(N(c3ccccc3)c3cccc4ccccc34)c3oc(-c4ccc5c(c4)oc4ccccc45)nc3c2)c2ccc3oc4ccccc4c3c2)cc1]

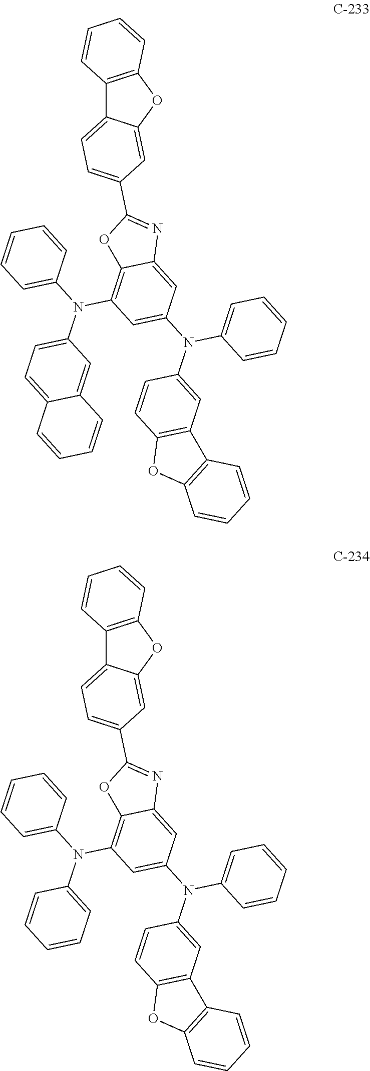 [SMILES: c1ccc(N(c2cc(N(c3ccccc3)c3ccc4ccccc4c3)c3oc(-c4ccc5c(c4)oc4ccccc45)nc3c2)c2ccc3oc4ccccc4c3c2)cc1 ; c1ccc(N(c2cc(N(c3ccccc3)c3ccccc3)c3oc(-c4ccc5c(c4)oc4ccccc45)nc3c2)c2ccc3oc4ccccc4c3c2)cc1]

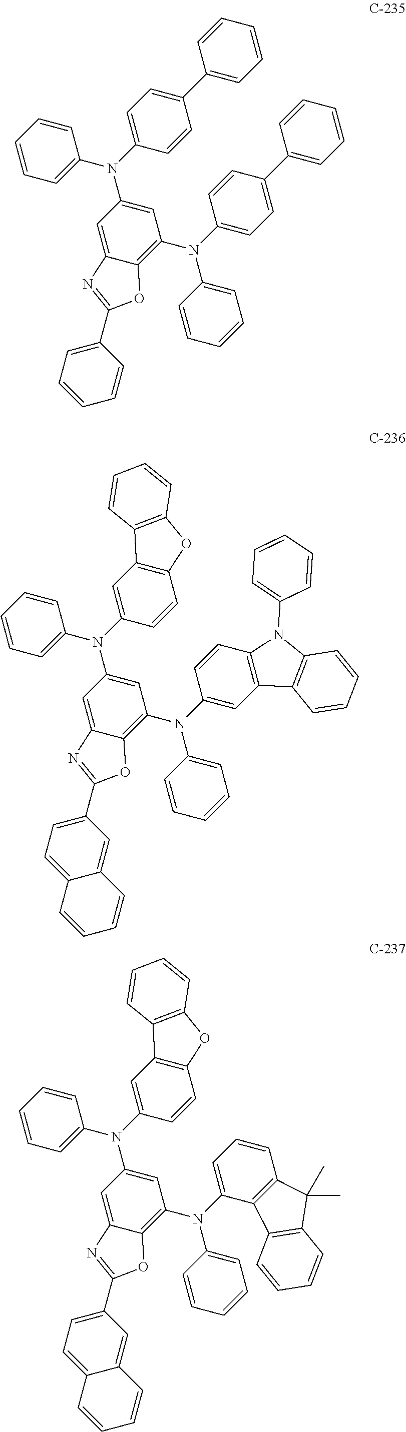

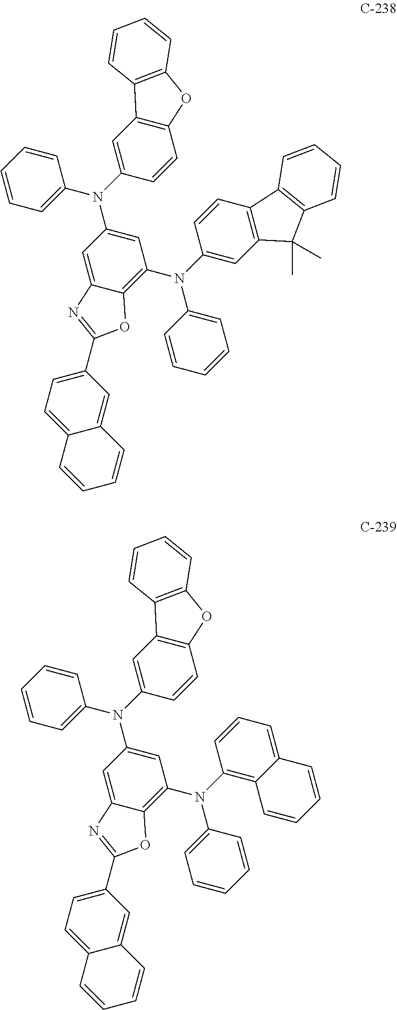 [SMILES: CC1(C)c2ccccc2-c2ccc(N(c3ccccc3)c3cc(N(c4ccccc4)c4ccc5oc6ccccc6c5c4)cc4nc(-c5ccc6ccccc6c5)oc34)cc21 ; c1ccc(N(c2cc(N(c3ccccc3)c3cccc4ccccc34)c3oc(-c4ccc5ccccc5c4)nc3c2)c2ccc3oc4ccccc4c3c2)cc1]

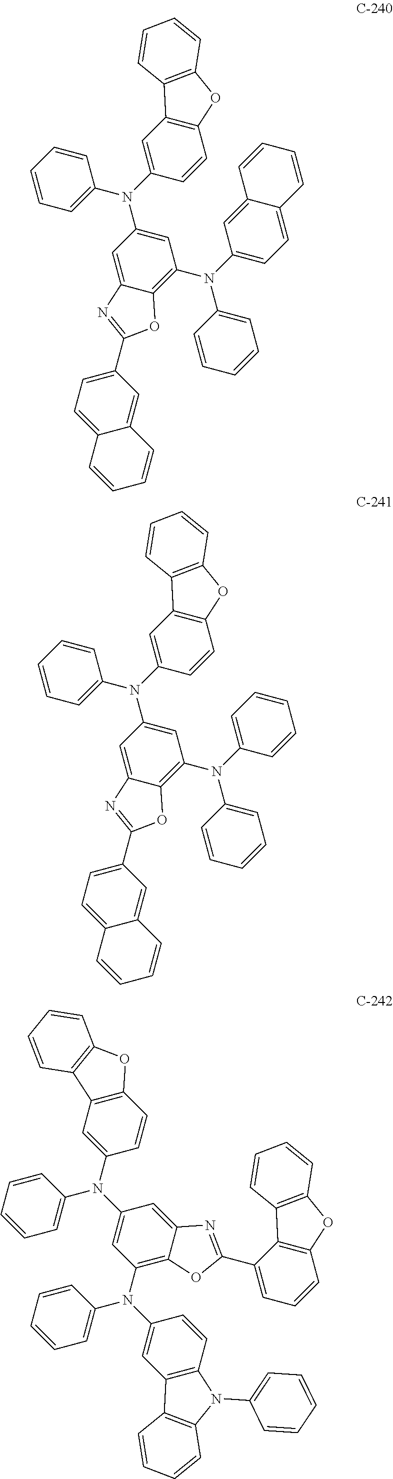

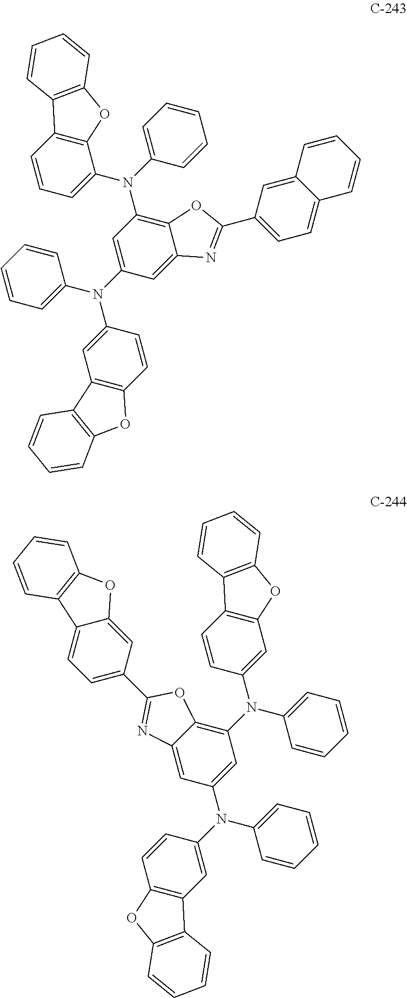 [SMILES: c1ccc(N(c2cc(N(c3ccccc3)c3cccc4c3oc3ccccc34)c3oc(-c4ccc5ccccc5c4)nc3c2)c2ccc3oc4ccccc4c3c2)cc1 ; c1ccc(N(c2cc(N(c3ccccc3)c3ccc4c(c3)oc3ccccc34)c3oc(-c4ccc5c(c4)oc4ccccc45)nc3c2)c2ccc3oc4ccccc4c3c2)cc1]

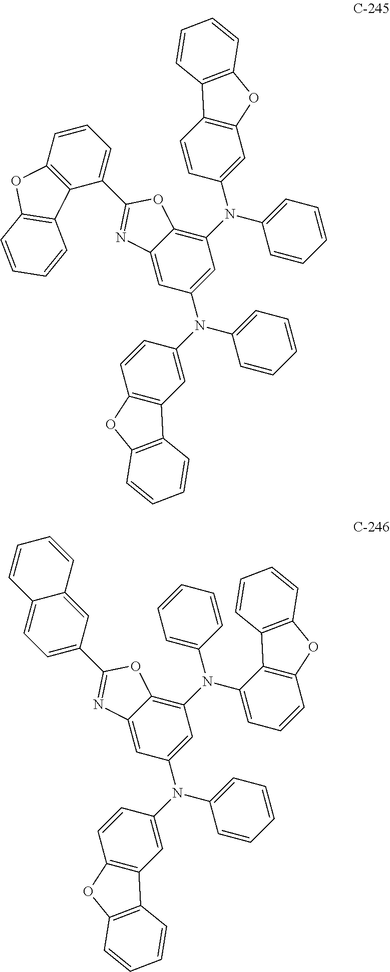 [SMILES: c1ccc(N(c2cc(N(c3ccccc3)c3ccc4c(c3)oc3ccccc34)c3oc(-c4cccc5oc6ccccc6c45)nc3c2)c2ccc3oc4ccccc4c3c2)cc1 ; c1ccc(N(c2cc(N(c3ccccc3)c3cccc4oc5ccccc5c34)c3oc(-c4ccc5ccccc5c4)nc3c2)c2ccc3oc4ccccc4c3c2)cc1]

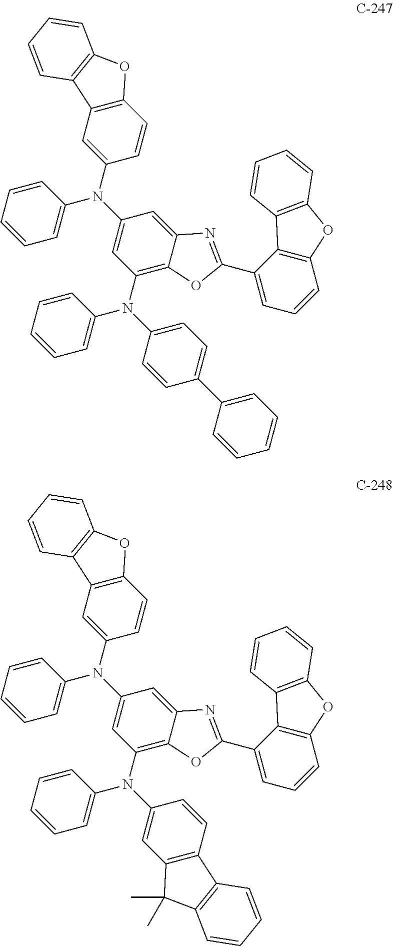 [SMILES: c1ccc(-c2ccc(N(c3ccccc3)c3cc(N(c4ccccc4)c4ccc5oc6ccccc6c5c4)cc4nc(-c5cccc6oc7ccccc7c56)oc34)cc2)cc1 ; CC1(C)c2ccccc2-c2ccc(N(c3ccccc3)c3cc(N(c4ccccc4)c4ccc5oc6ccccc6c5c4)cc4nc(-c5cccc6oc7ccccc7c56)oc34)cc21]

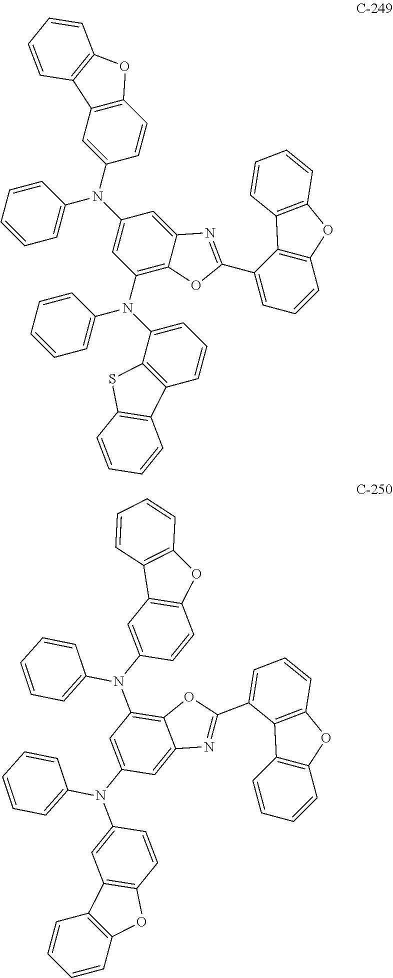

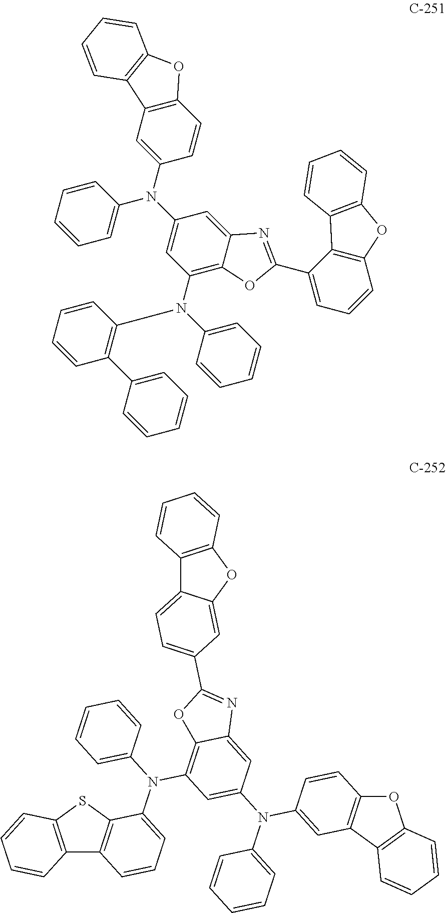 [SMILES: c1ccc(-c2ccccc2CN(c2ccccc2)c2cc(N(c3ccccc3)c3ccc4oc5ccccc5c4c3)cc3nc(-c4cccc5oc6ccccc6c45)oc23)cc1 ; c1ccc(N(c2cc(N(c3ccccc3)c3cccc4c3sc3ccccc34)c3oc(-c4ccc5c(c4)oc4ccccc45)nc3c2)c2ccc3oc4ccccc4c3c2)cc1]

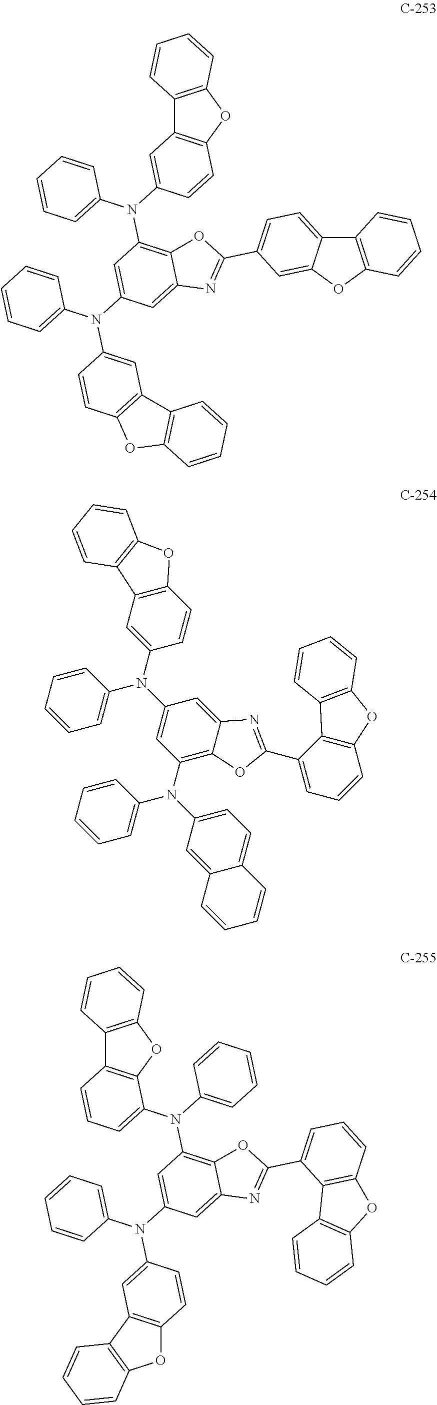 [SMILES: c1ccc(N(c2cc(N(c3ccccc3)c3ccc4oc5ccccc5c4c3)c3oc(-c4ccc5c(c4)oc4ccccc45)nc3c2)c2ccc3oc4ccccc4c3c2)cc1 ; c1ccc(N(c2cc(N(c3ccccc3)c3ccc4ccccc4c3)c3oc(-c4cccc5oc6ccccc6c45)nc3c2)c2ccc3oc4ccccc4c3c2)cc1 ; c1ccc(N(c2cc(N(c3ccccc3)c3cccc4c3oc3ccccc34)c3oc(-c4cccc5oc6ccccc6c45)nc3c2)c2ccc3oc4ccccc4c3c2)cc1]

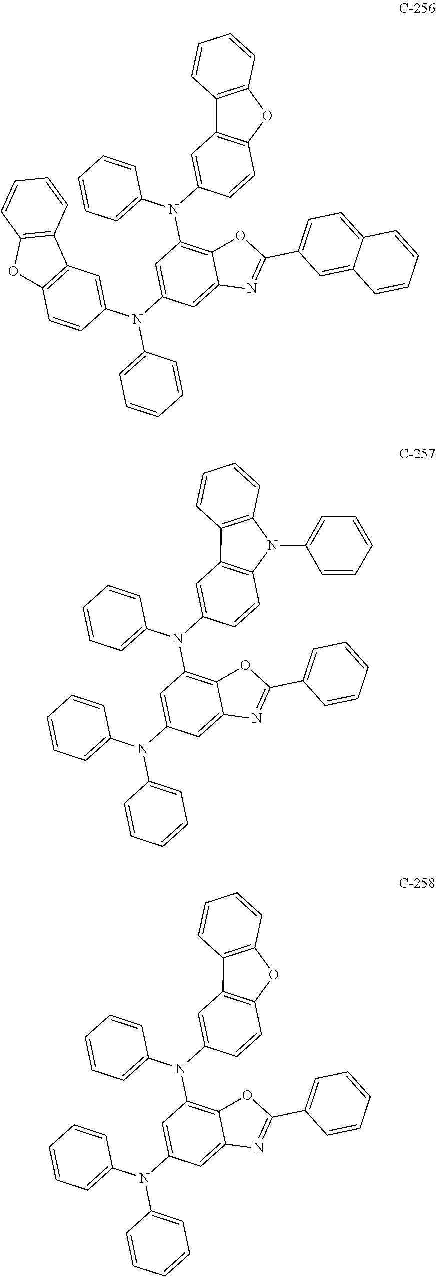 [SMILES: c1ccc(N(c2cc(N(c3ccccc3)c3ccc4oc5ccccc5c4c3)c3oc(-c4ccc5ccccc5c4)nc3c2)c2ccc3oc4ccccc4c3c2)cc1 ; c1ccc(-c2nc3cc(N(c4ccccc4)c4ccccc4)cc(N(c4ccccc4)c4ccc5c(c4)c4ccccc4n5-c4ccccc4)c3o2)cc1 ; c1ccc(-c2nc3cc(N(c4ccccc4)c4ccccc4)cc(N(c4ccccc4)c4ccc5oc6ccccc6c5c4)c3o2)cc1]

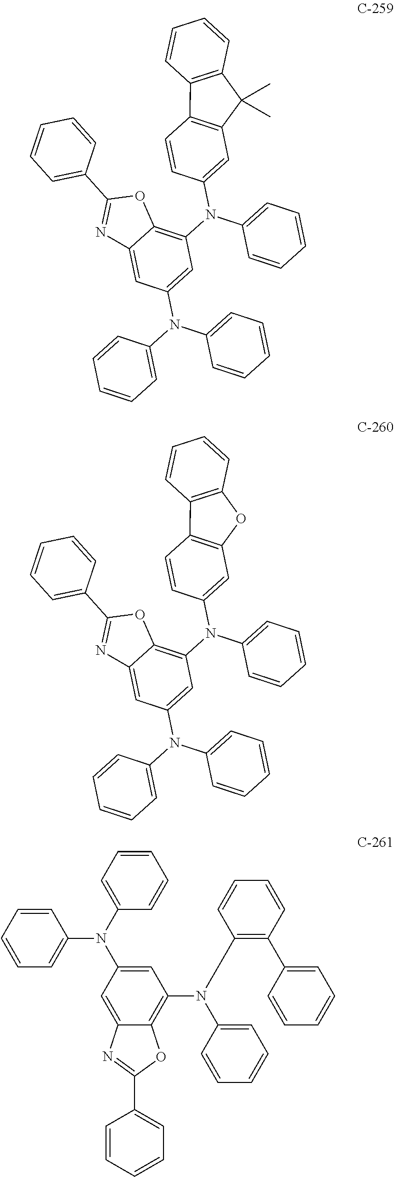

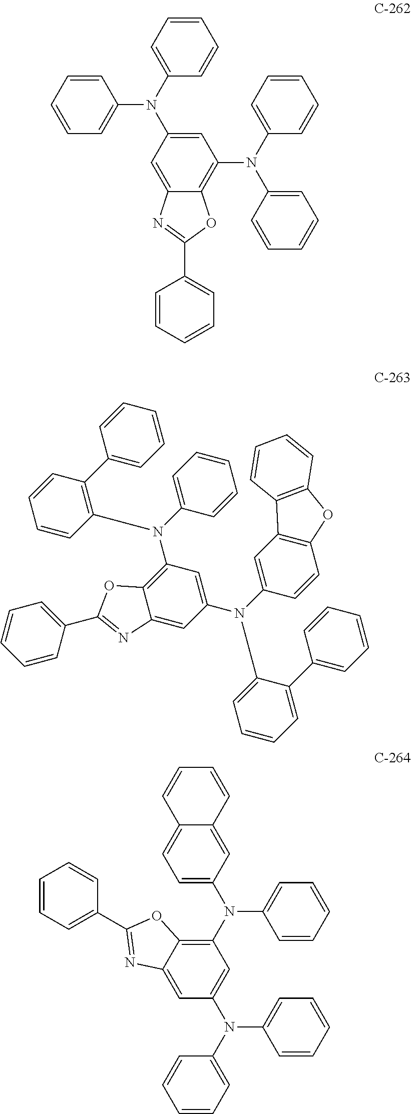

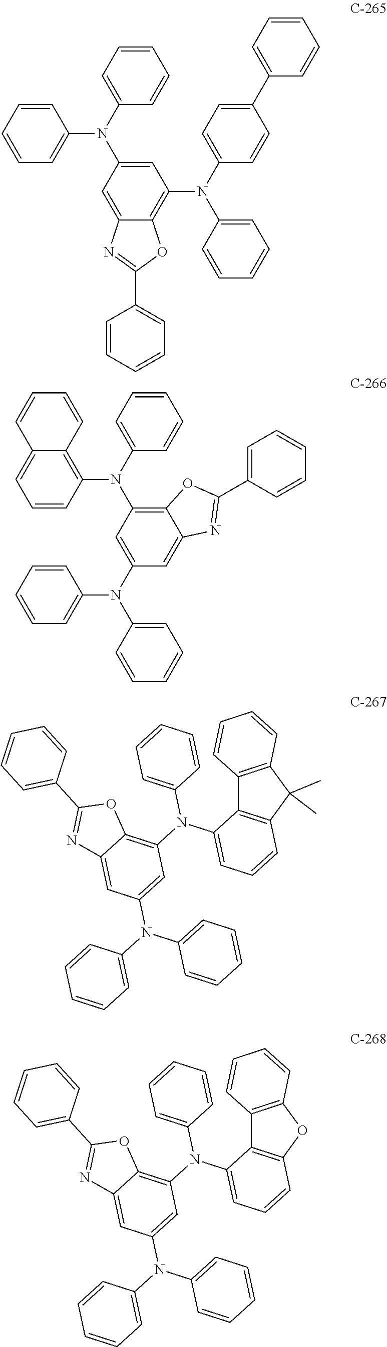

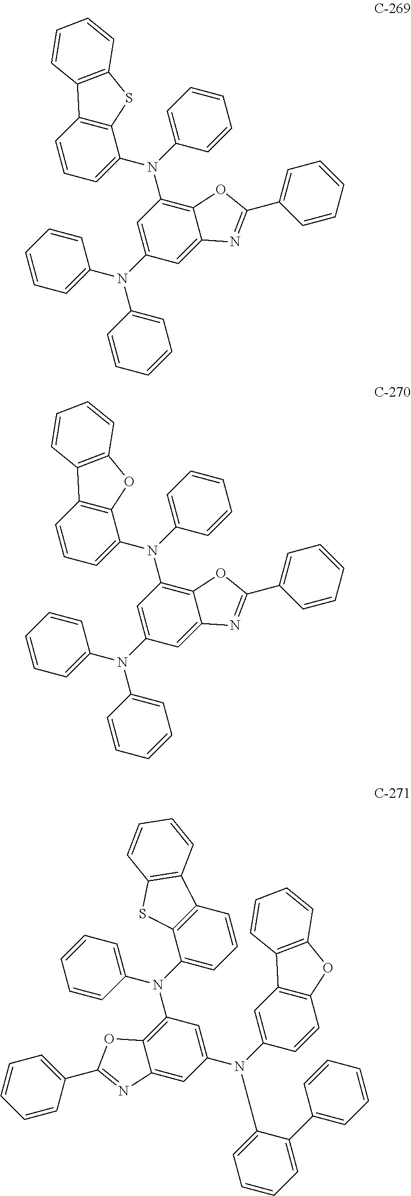

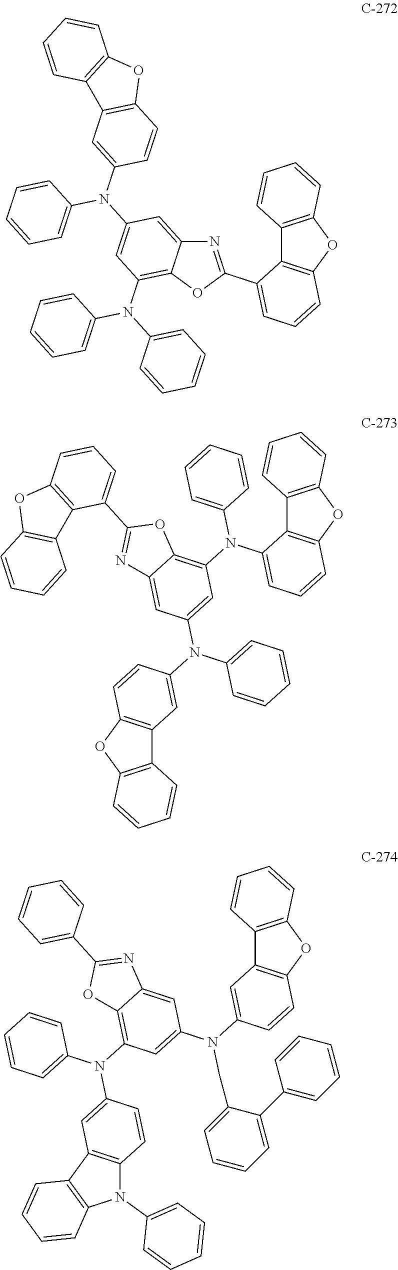 [SMILES: c1ccc(N(c2cc(N(c3ccccc3)c3ccccc3)c3oc(-c4cccc5oc6ccccc6c45)nc3c2)c2ccc3oc4ccccc4c3c2)cc1 ; c1ccc(N(c2cc(N(c3ccccc3)c3cccc4oc5ccccc5c34)c3oc(-c4cccc5oc6ccccc6c45)nc3c2)c2ccc3oc4ccccc4c3c2)cc1 ; c1ccc(-c2nc3cc(N(Cc4ccccc4-c4ccccc4)c4ccc5oc6ccccc6c5c4)cc(N(c4ccccc4)c4ccc5c(c4)c4ccccc4n5-c4ccccc4)c3o2)cc1]

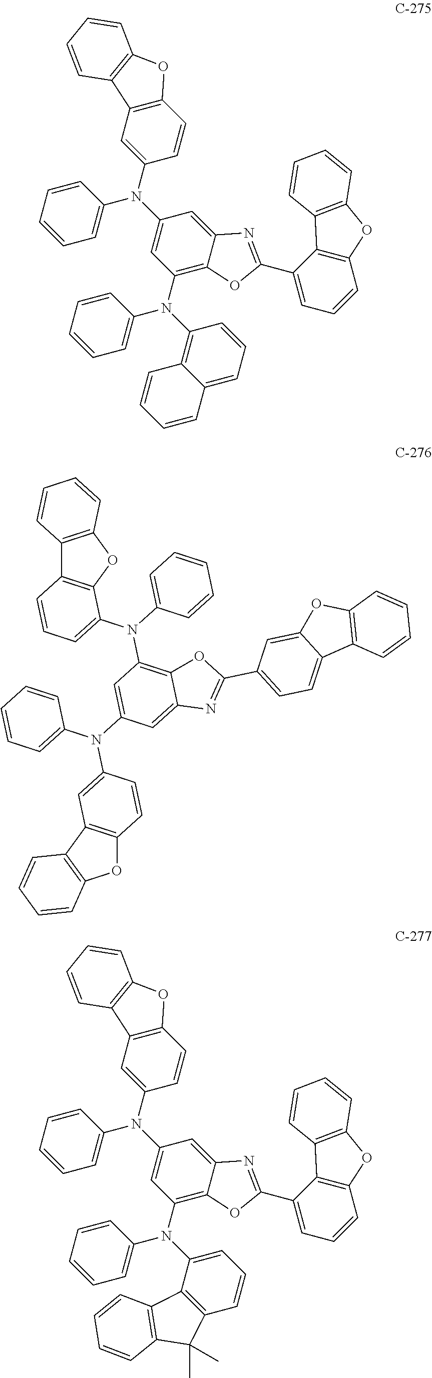

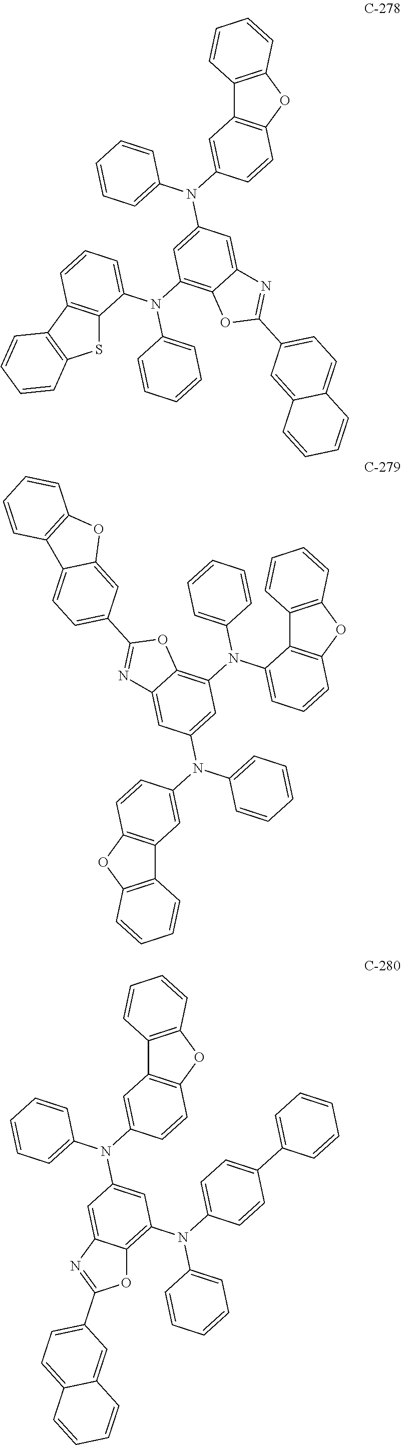

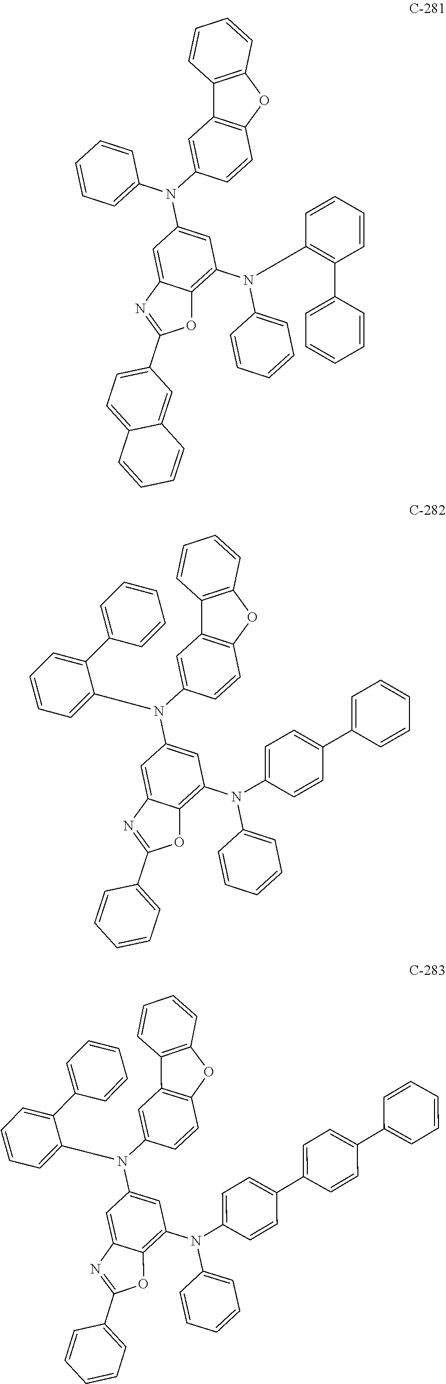 [SMILES: c1ccc(-c2ccccc2CN(c2ccccc2)c2cc(N(c3ccccc3)c3ccc4oc5ccccc5c4c3)cc3nc(-c4ccc5ccccc5c4)oc23)cc1 ; c1ccc(-c2ccc(N(c3ccccc3)c3cc(N(Cc4ccccc4-c4ccccc4)c4ccc5oc6ccccc6c5c4)cc4nc(-c5ccccc5)oc34)cc2)cc1 ; c1ccc(-c2ccc(-c3ccc(N(c4ccccc4)c4cc(N(Cc5ccccc5-c5ccccc5)c5ccc6oc7ccccc7c6c5)cc5nc(-c6ccccc6)oc45)cc3)cc2)cc1]

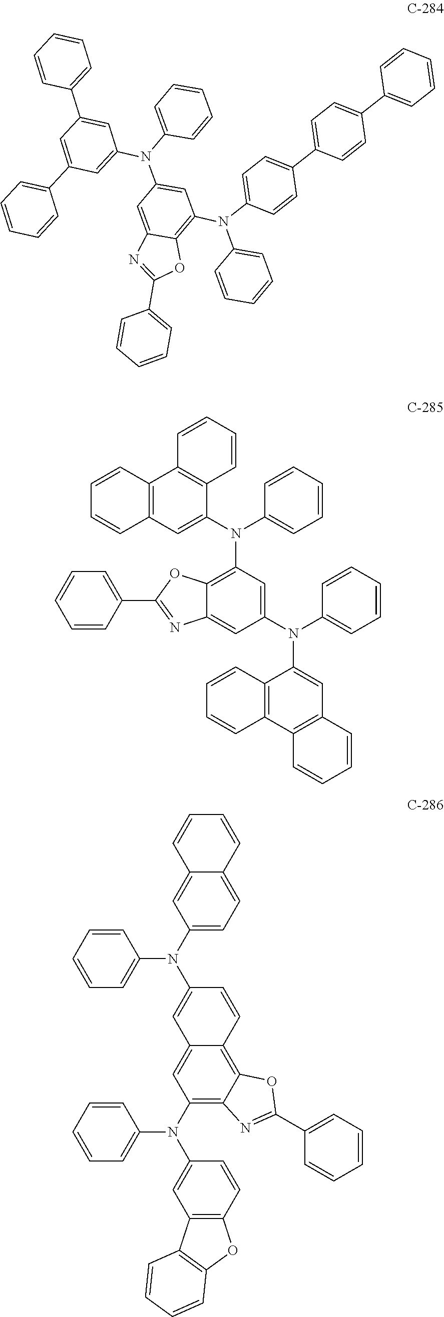 [SMILES: c1ccc(-c2ccc(-c3ccc(N(c4ccccc4)c4cc(N(c5ccccc5)c5cc(-c6ccccc6)cc(-c6ccccc6)c5)cc5nc(-c6ccccc6)oc45)cc3)cc2)cc1 ; c1ccc(-c2nc3cc(N(c4ccccc4)c4cc5ccccc5c5ccccc45)cc(N(c4ccccc4)c4cc5ccccc5c5ccccc45)c3o2)cc1 ; c1ccc(-c2nc3c(N(c4ccccc4)c4ccc5oc6ccccc6c5c4)cc4cc(N(c5ccccc5)c5ccc6ccccc6c5)ccc4c3o2)cc1]

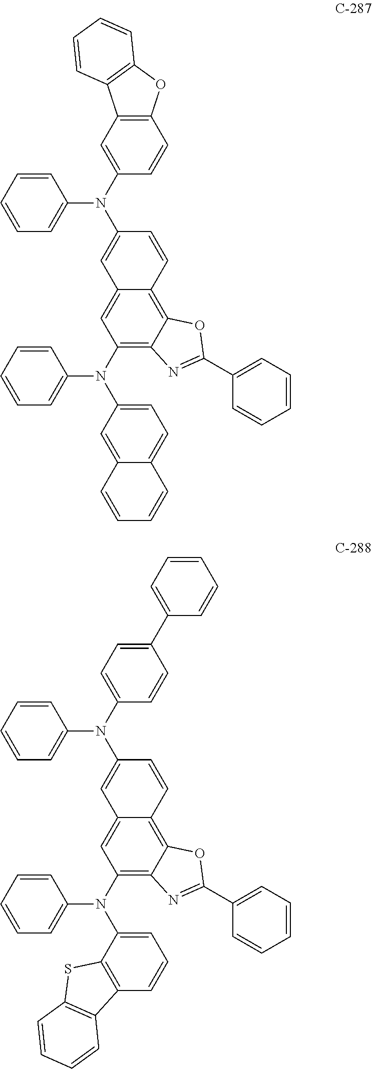

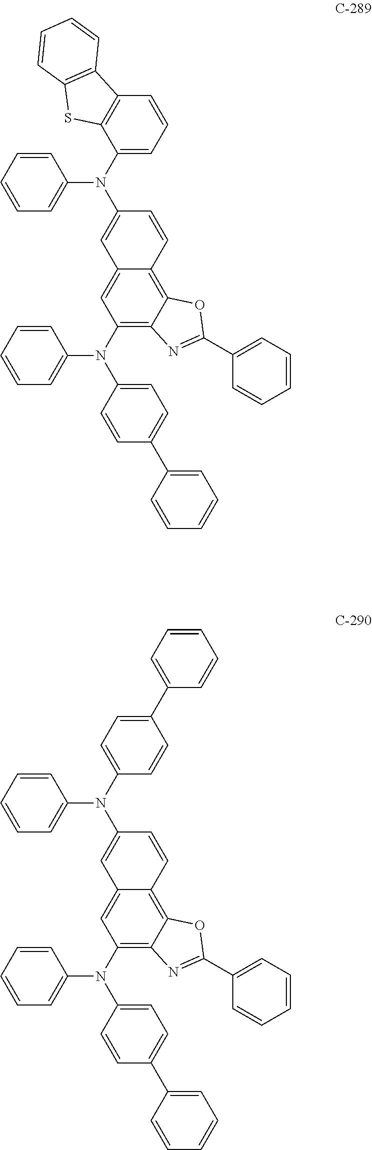 [SMILES: c1ccc(-c2ccc(N(c3ccccc3)c3cc4cc(N(c5ccccc5)c5cccc6c5sc5ccccc56)ccc4c4oc(-c5ccccc5)nc34)cc2)cc1 ; c1ccc(-c2ccc(N(c3ccccc3)c3ccc4c(c3)cc(N(c3ccccc3)c3ccc(-c5ccccc5)cc3)c3nc(-c5ccccc5)oc34)cc2)cc1]

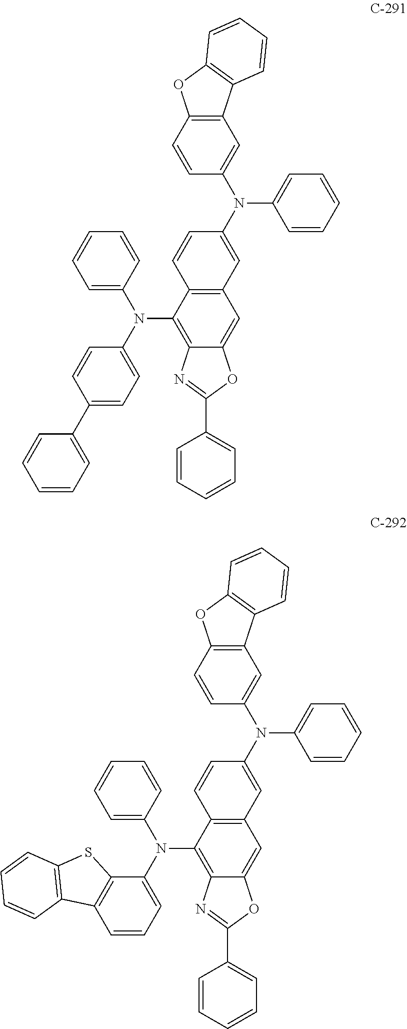 [SMILES: c1ccc(-c2ccc(N(c3ccccc3)c3c4ccc(N(c5ccccc5)c5ccc6oc7ccccc7c6c5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccc6oc7ccccc7c6c5)cc4cc3o2)cc1]

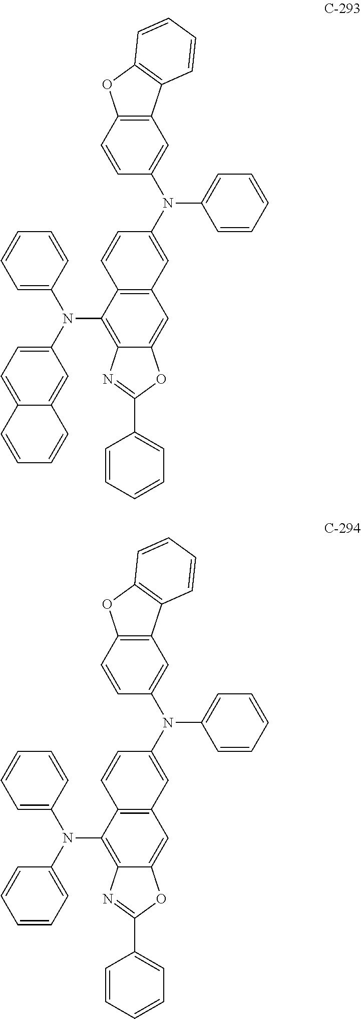 [SMILES: c1ccc(-c2nc3c(N(c4ccccc4)c4ccc5ccccc5c4)c4ccc(N(c5ccccc5)c5ccc6oc7ccccc7c6c5)cc4cc3o2)cc1 ; c1ccc(-c2nc3c(N(c4ccccc4)c4ccccc4)c4ccc(N(c5ccccc5)c5ccc6oc7ccccc7c6c5)cc4cc3o2)cc1]

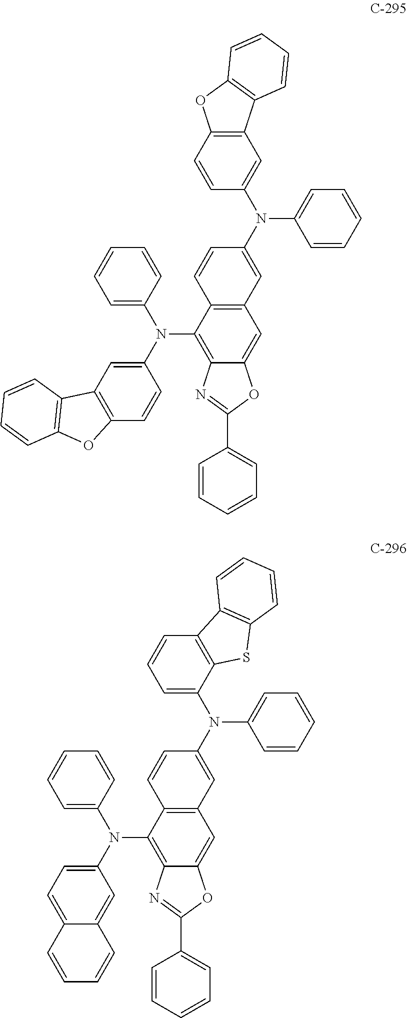

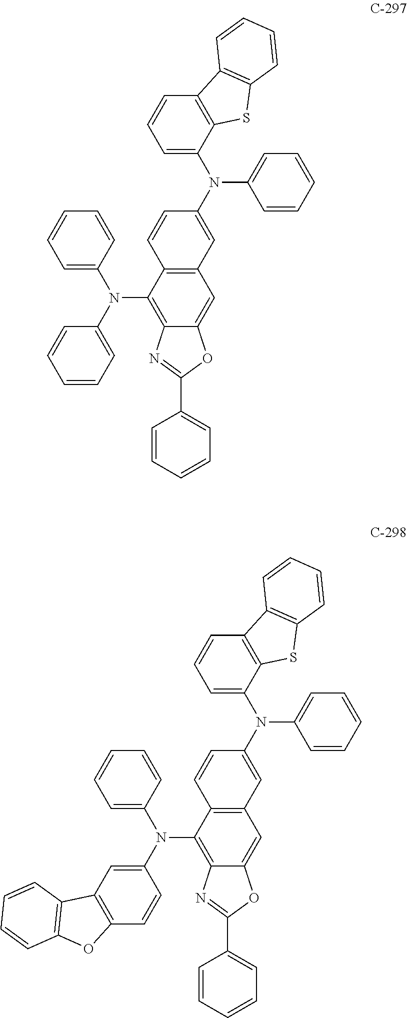 [SMILES: c1ccc(-c2nc3c(N(c4ccccc4)c4ccccc4)c4ccc(N(c5ccccc5)c5cccc6c5sc5ccccc56)cc4cc3o2)cc1 ; c1ccc(-c2nc3c(N(c4ccccc4)c4ccc5oc6ccccc6c5c4)c4ccc(N(c5ccccc5)c5cccc6c5sc5ccccc56)cc4cc3o2)cc1]

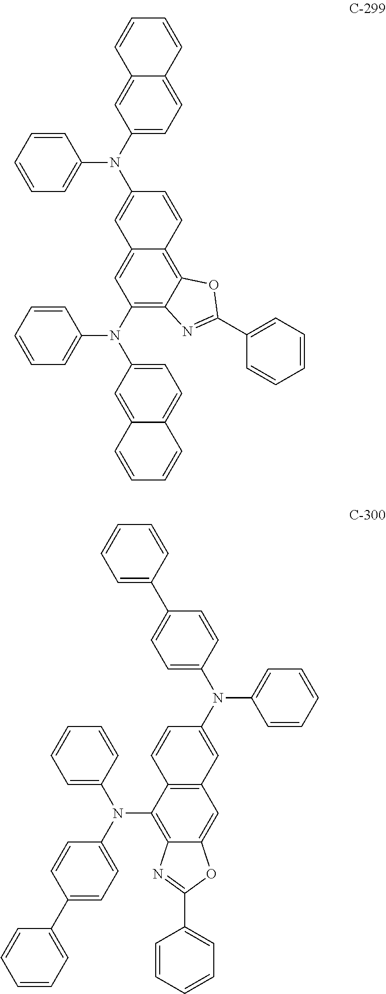

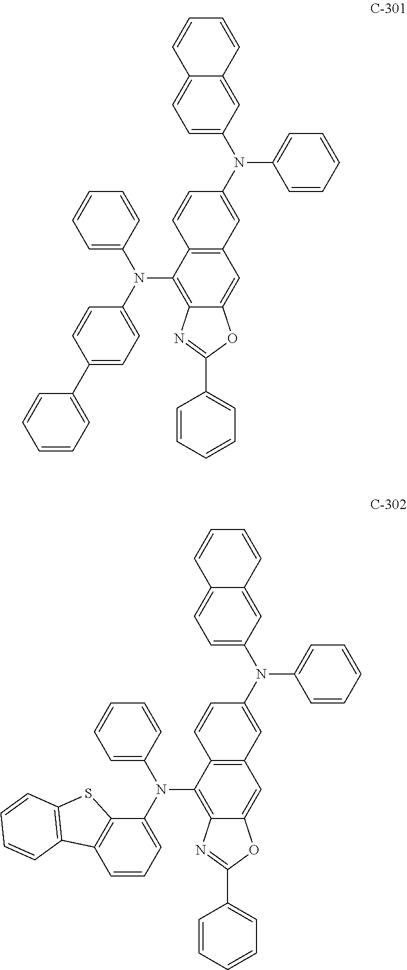 [SMILES: c1ccc(-c2ccc(N(c3ccccc3)c3c4ccc(N(c5ccccc5)c5ccc6ccccc6c5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccc6ccccc6c5)cc4cc3o2)cc1]

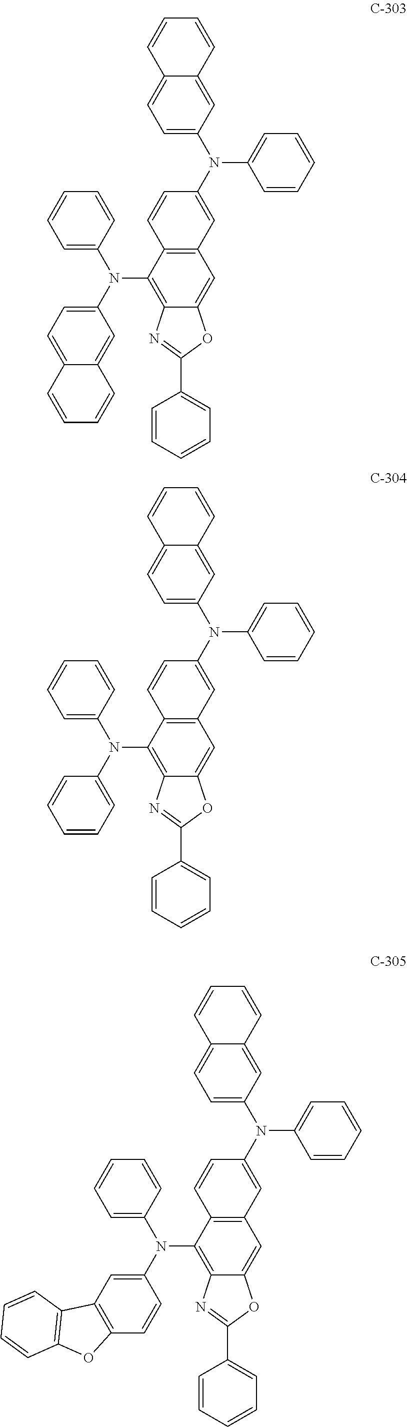

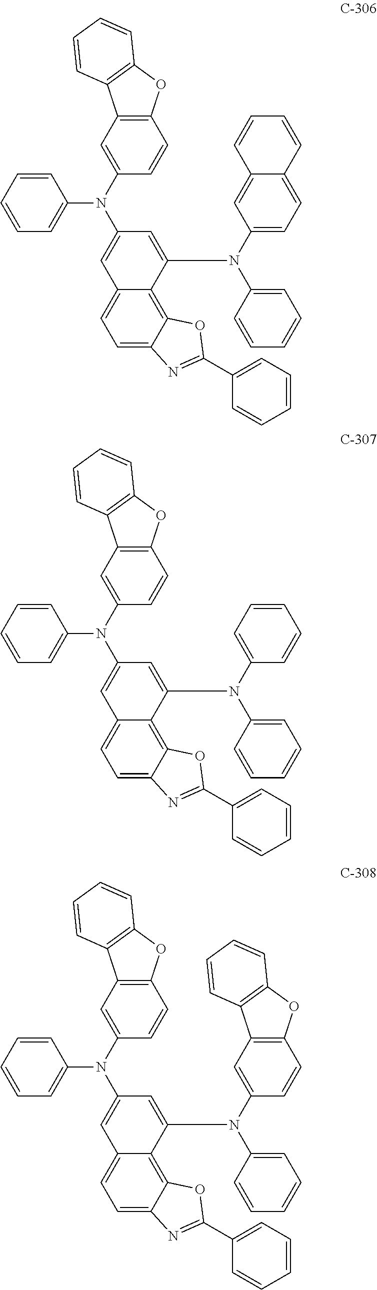 [SMILES: c1ccc(-c2nc3ccc4cc(N(c5ccccc5)c5ccc6oc7ccccc7c6c5)cc(CN(c5ccccc5)c5ccc6ccccc6c5)c4c3o2)cc1 ; c1ccc(-c2nc3ccc4cc(N(c5ccccc5)c5ccc6oc7ccccc7c6c5)cc(CN(c5ccccc5)c5ccccc5)c4c3o2)cc1 ; c1ccc(-c2nc3ccc4cc(N(c5ccccc5)c5ccc6oc7ccccc7c6c5)cc(CN(c5ccccc5)c5ccc6oc7ccccc7c6c5)c4c3o2)cc1]

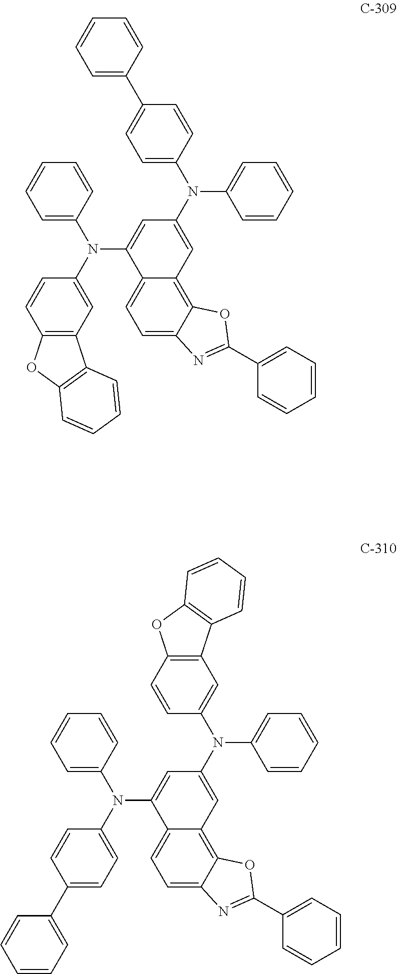 [SMILES: c1ccc(-c2ccc(N(c3ccccc3)c3cc(N(c4ccccc4)c4ccc5oc6ccccc6c5c4)c4ccc5nc(-c6ccccc6)oc5c4c3)cc2)cc1 ; c1ccc(-c2ccc(N(c3ccccc3)c3cc(N(c4ccccc4)c4ccc5oc6ccccc6c5c4)cc4c3ccc3nc(-c5ccccc5)oc34)cc2)cc1]

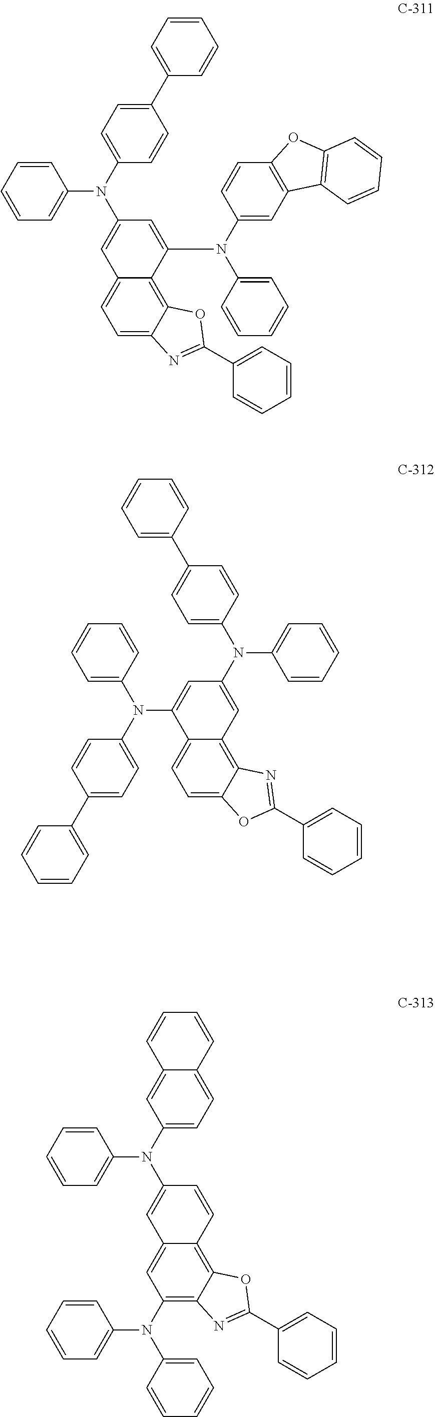 [SMILES: c1ccc(-c2ccc(N(c3ccccc3)c3cc(N(c4ccccc4)c4ccc5oc6ccccc6c5c4)c4c(ccc5nc(-c6ccccc6)oc54)c3)cc2)cc1 ; c1ccc(-c2ccc(N(c3ccccc3)c3cc(N(c4ccccc4)c4ccc(-c5ccccc5)cc4)c4ccc5oc(-c6ccccc6)nc5c4c3)cc2)cc1 ; c1ccc(-c2nc3c(N(c4ccccc4)c4ccccc4)cc4cc(N(c5ccccc5)c5ccc6ccccc6c5)ccc4c3o2)cc1]

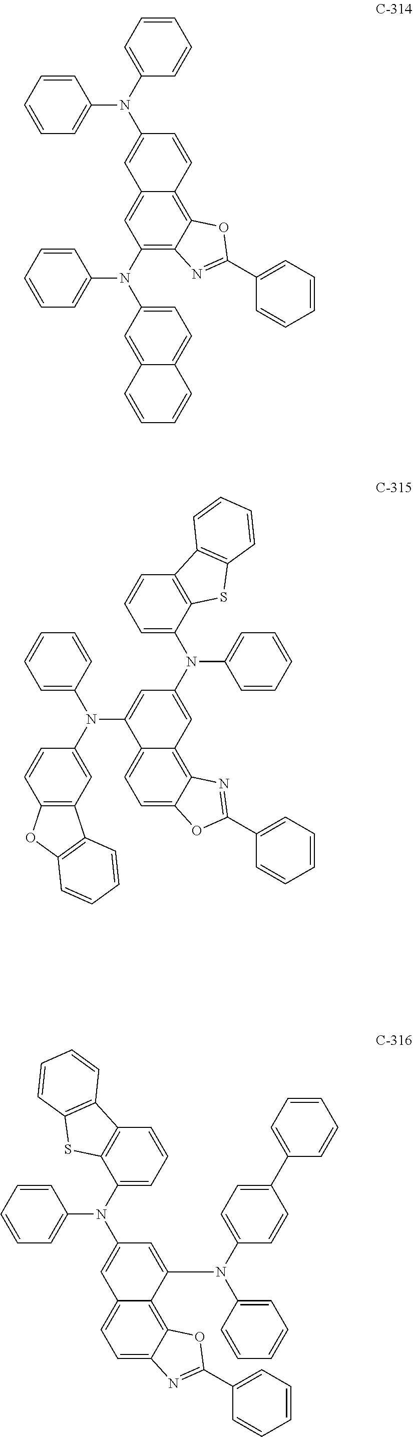 [SMILES: c1ccc(-c2nc3c(N(c4ccccc4)c4ccc5ccccc5c4)cc4cc(N(c5ccccc5)c5ccccc5)ccc4c3o2)cc1 ; c1ccc(-c2nc3c(ccc4c(N(c5ccccc5)c5ccc6oc7ccccc7c6c5)cc(N(c5ccccc5)c5cccc6c5sc5ccccc56)cc43)o2)cc1 ; c1ccc(-c2ccc(N(c3ccccc3)c3cc(N(c4ccccc4)c4cccc5c4sc4ccccc45)cc4ccc5nc(-c6ccccc6)oc5c34)cc2)cc1]

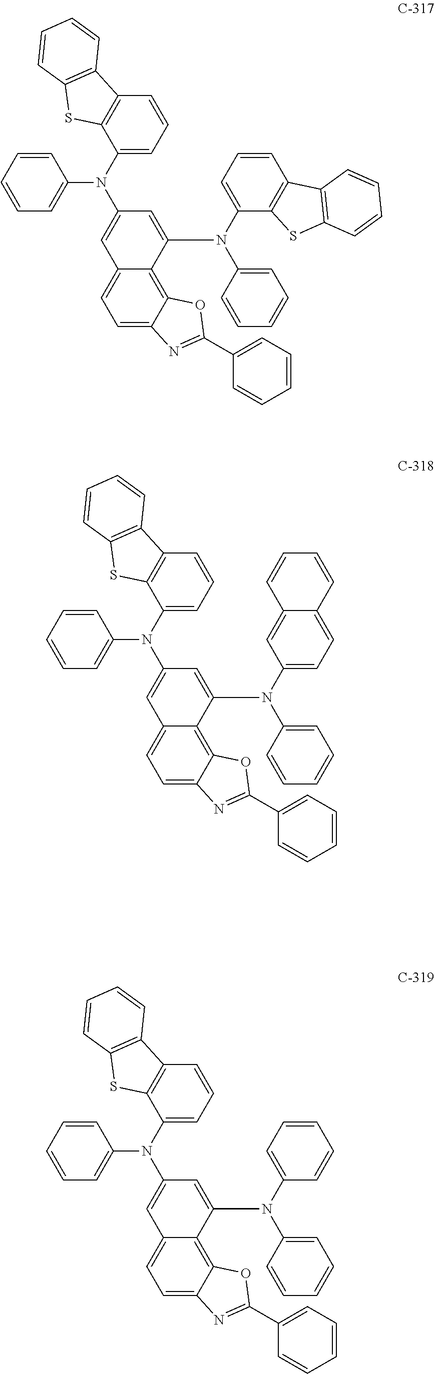 [SMILES: c1ccc(-c2nc3ccc4cc(N(c5ccccc5)c5cccc6c5sc5ccccc56)cc(N(c5ccccc5)c5cccc6c5sc5ccccc56)c4c3o2)cc1 ; c1ccc(-c2nc3ccc4cc(N(c5ccccc5)c5cccc6c5sc5ccccc56)cc(N(c5ccccc5)c5ccc6ccccc6c5)c4c3o2)cc1 ; c1ccc(-c2nc3ccc4cc(N(c5ccccc5)c5cccc6c5sc5ccccc56)cc(N(c5ccccc5)c5ccccc5)c4c3o2)cc1]

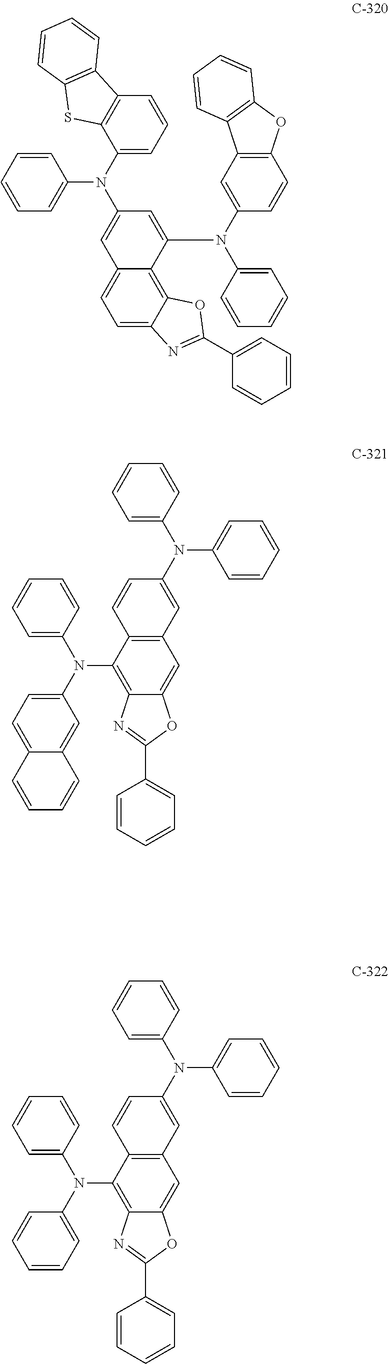 [SMILES: c1ccc(-c2nc3ccc4cc(N(c5ccccc5)c5cccc6c5sc5ccccc56)cc(N(c5ccccc5)c5ccc6oc7ccccc7c6c5)c4c3o2)cc1 ; c1ccc(-c2nc3c(N(c4ccccc4)c4ccc5ccccc5c4)c4ccc(N(c5ccccc5)c5ccccc5)cc4cc3o2)cc1 ; c1ccc(-c2nc3c(N(c4ccccc4)c4ccccc4)c4ccc(N(c5ccccc5)c5ccccc5)cc4cc3o2)cc1]

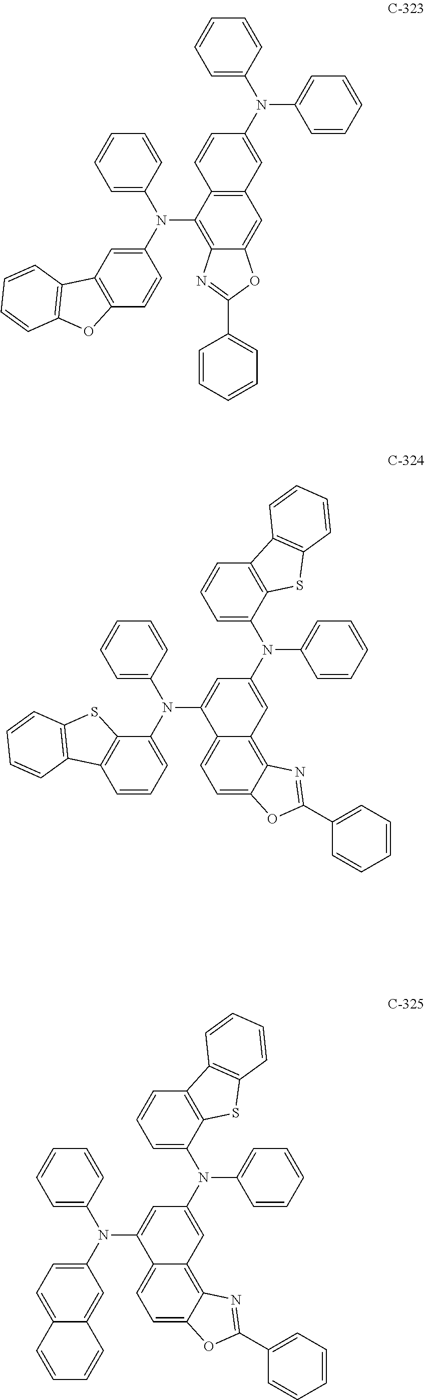 [SMILES: c1ccc(-c2nc3c(N(c4ccccc4)c4ccc5oc6ccccc6c5c4)c4ccc(N(c5ccccc5)c5ccccc5)cc4cc3o2)cc1 ; c1ccc(-c2nc3c(ccc4c(N(c5ccccc5)c5cccc6c5sc5ccccc56)cc(N(c5ccccc5)c5cccc6c5sc5ccccc56)cc43)o2)cc1 ; c1ccc(-c2nc3c(ccc4c(N(c5ccccc5)c5ccc6ccccc6c5)cc(N(c5ccccc5)c5cccc6c5sc5ccccc56)cc43)o2)cc1]

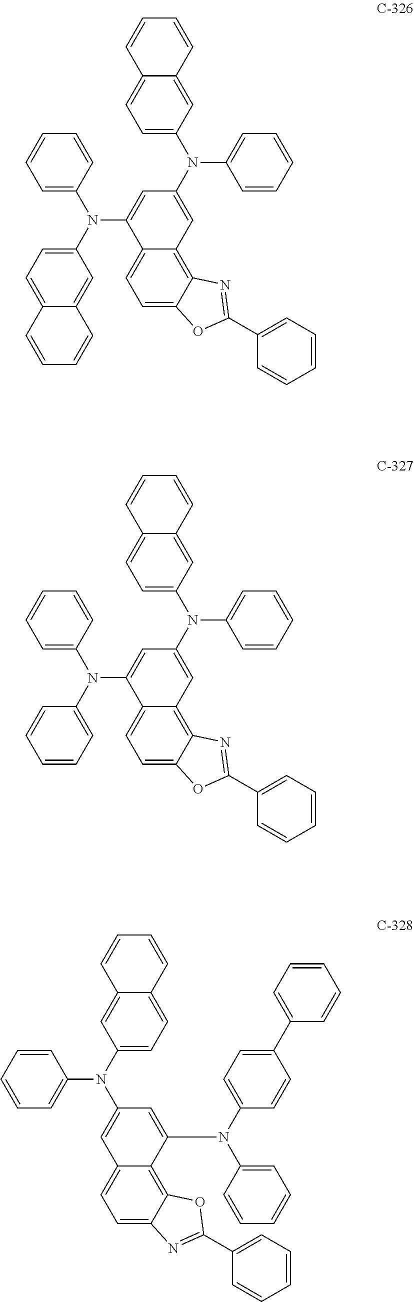 [SMILES: c1ccc(-c2nc3c(ccc4c(N(c5ccccc5)c5ccc6ccccc6c5)cc(N(c5ccccc5)c5ccc6ccccc6c5)cc43)o2)cc1 ; c1ccc(-c2nc3c(ccc4c(N(c5ccccc5)c5ccccc5)cc(N(c5ccccc5)c5ccc6ccccc6c5)cc43)o2)cc1 ; c1ccc(-c2ccc(N(c3ccccc3)c3cc(N(c4ccccc4)c4ccc5ccccc5c4)cc4ccc5nc(-c6ccccc6)oc5c34)cc2)cc1]

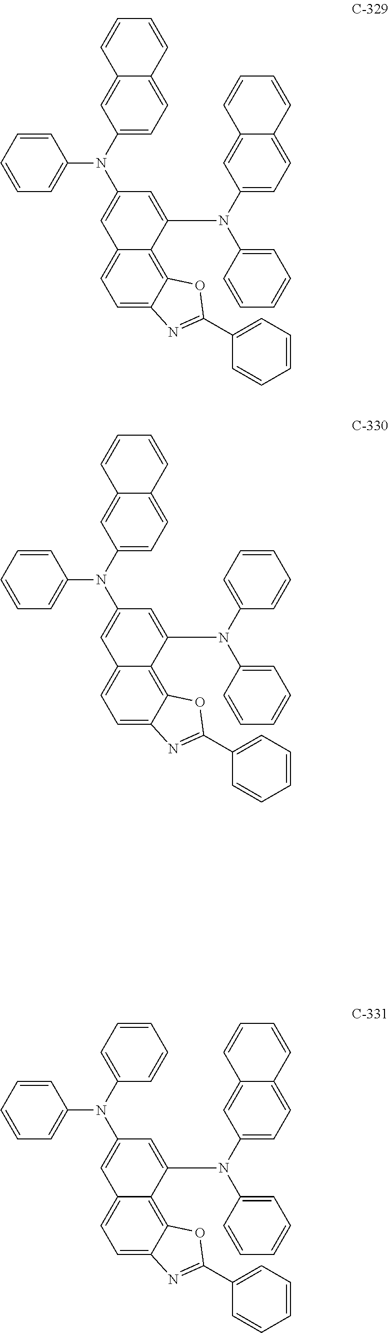 [SMILES: c1ccc(-c2nc3ccc4cc(N(c5ccccc5)c5ccc6ccccc6c5)cc(N(c5ccccc5)c5ccc6ccccc6c5)c4c3o2)cc1 ; c1ccc(-c2nc3ccc4cc(N(c5ccccc5)c5ccc6ccccc6c5)cc(N(c5ccccc5)c5ccccc5)c4c3o2)cc1 ; c1ccc(-c2nc3ccc4cc(N(c5ccccc5)c5ccccc5)cc(N(c5ccccc5)c5ccc6ccccc6c5)c4c3o2)cc1]

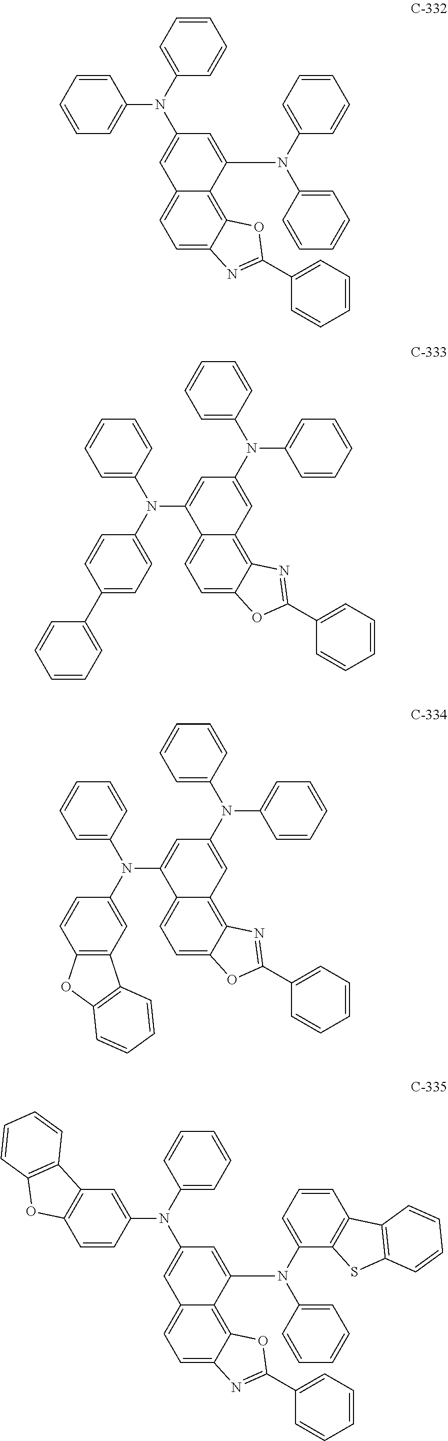 [SMILES: c1ccc(-c2nc3ccc4cc(N(c5ccccc5)c5ccccc5)cc(N(c5ccccc5)c5ccccc5)c4c3o2)cc1 ; c1ccc(-c2ccc(N(c3ccccc3)c3cc(N(c4ccccc4)c4ccccc4)cc4c3ccc3oc(-c5ccccc5)nc34)cc2)cc1 ; c1ccc(-c2nc3c(ccc4c(N(c5ccccc5)c5ccc6oc7ccccc7c6c5)cc(N(c5ccccc5)c5ccccc5)cc43)o2)cc1 ; c1ccc(-c2nc3ccc4cc(N(c5ccccc5)c5ccc6oc7ccccc7c6c5)cc(N(c5ccccc5)c5cccc6c5sc5ccccc56)c4c3o2)cc1]

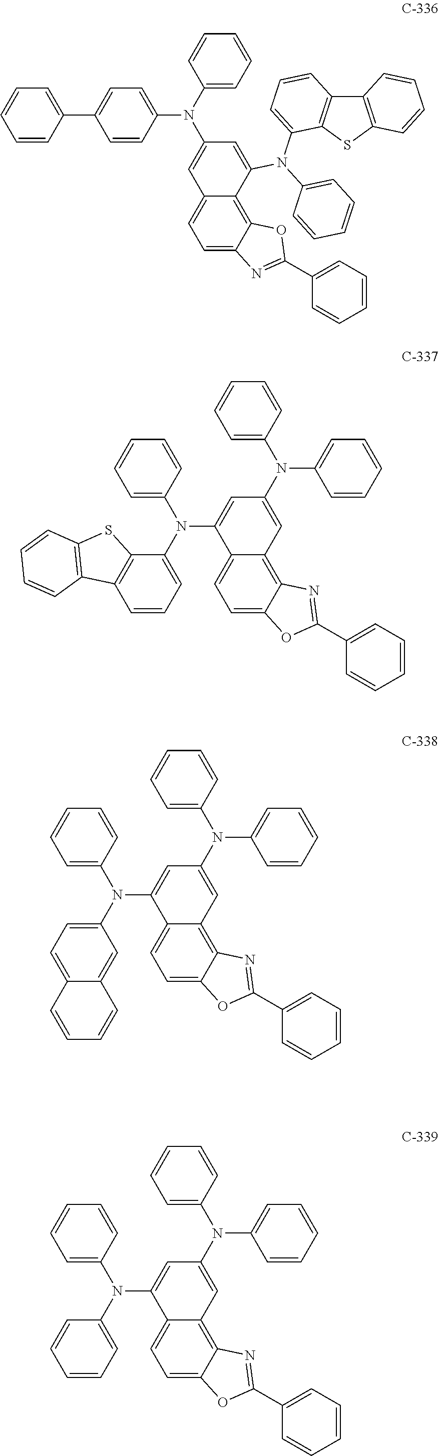 [SMILES: c1ccc(-c2ccc(N(c3ccccc3)c3cc(N(c4ccccc4)c4cccc5c4sc4ccccc45)c4c(ccc5nc(-c6ccccc6)oc54)c3)cc2)cc1 ; c1ccc(-c2nc3c(ccc4c(N(c5ccccc5)c5cccc6c5sc5ccccc56)cc(N(c5ccccc5)c5ccccc5)cc43)o2)cc1 ; c1ccc(-c2nc3c(ccc4c(N(c5ccccc5)c5ccc6ccccc6c5)cc(N(c5ccccc5)c5ccccc5)cc43)o2)cc1 ; c1ccc(-c2nc3c(ccc4c(N(c5ccccc5)c5ccccc5)cc(N(c5ccccc5)c5ccccc5)cc43)o2)cc1]

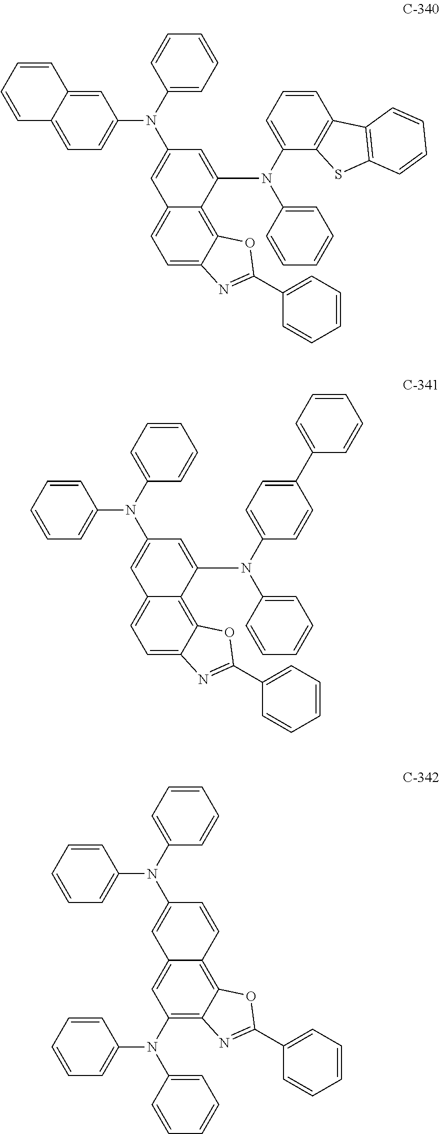 [SMILES: c1ccc(-c2nc3ccc4cc(N(c5ccccc5)c5ccc6ccccc6c5)cc(N(c5ccccc5)c5cccc6c5sc5ccccc56)c4c3o2)cc1 ; c1ccc(-c2ccc(N(c3ccccc3)c3cc(N(c4ccccc4)c4ccccc4)cc4ccc5nc(-c6ccccc6)oc5c34)cc2)cc1 ; c1ccc(-c2nc3c(N(c4ccccc4)c4ccccc4)cc4cc(N(c5ccccc5)c5ccccc5)ccc4c3o2)cc1]

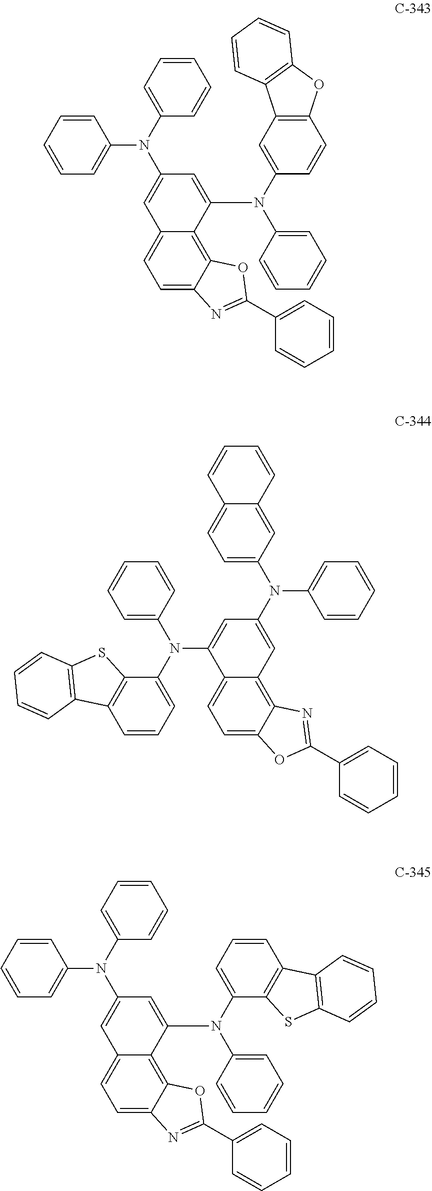 [SMILES: c1ccc(-c2nc3ccc4cc(N(c5ccccc5)c5ccccc5)cc(N(c5ccccc5)c5ccc6oc7ccccc7c6c5)c4c3o2)cc1 ; c1ccc(-c2nc3c(ccc4c(N(c5ccccc5)c5cccc6c5sc5ccccc56)cc(N(c5ccccc5)c5ccc6ccccc6c5)cc43)o2)cc1 ; c1ccc(-c2nc3ccc4cc(N(c5ccccc5)c5ccccc5)cc(N(c5ccccc5)c5cccc6c5sc5ccccc56)c4c3o2)cc1]

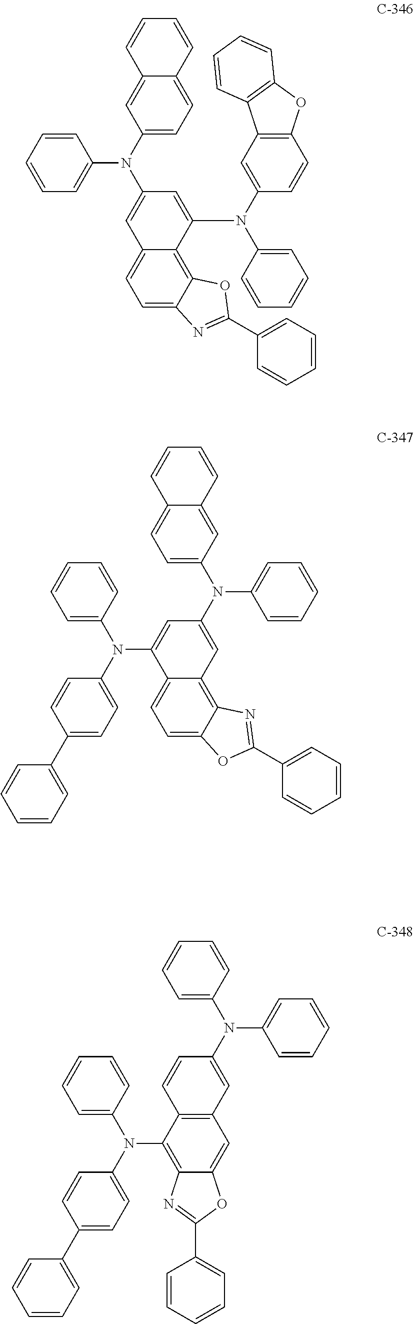 [SMILES: c1ccc(-c2nc3ccc4cc(N(c5ccccc5)c5ccc6ccccc6c5)cc(N(c5ccccc5)c5ccc6oc7ccccc7c6c5)c4c3o2)cc1 ; c1ccc(-c2ccc(N(c3ccccc3)c3cc(N(c4ccccc4)c4ccc5ccccc5c4)cc4c3ccc3oc(-c5ccccc5)nc34)cc2)cc1 ; c1ccc(-c2ccc(N(c3ccccc3)c3c4ccc(N(c5ccccc5)c5ccccc5)cc4cc4oc(-c5ccccc5)nc34)cc2)cc1]

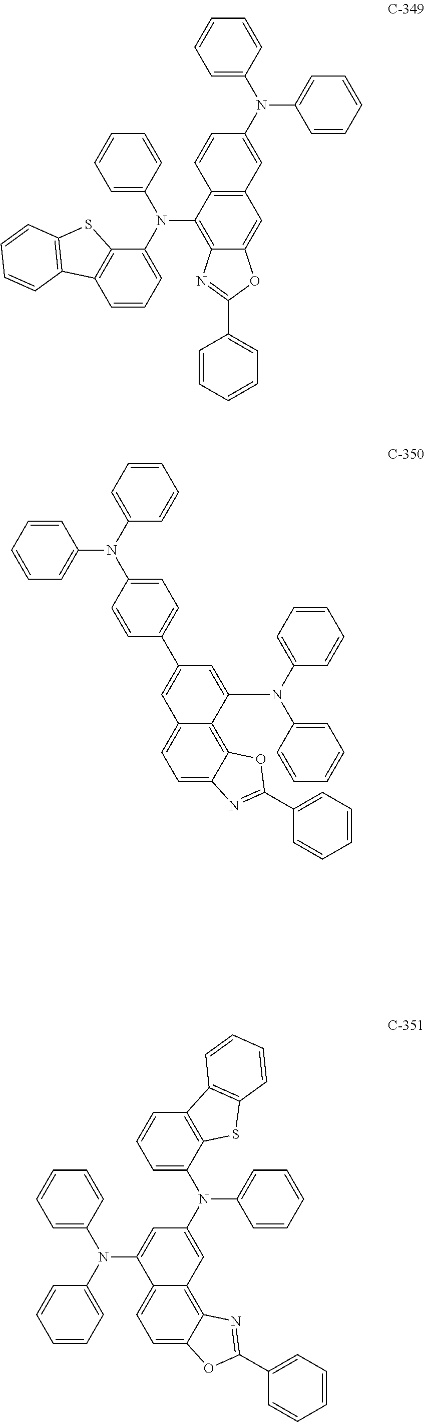 [SMILES: c1ccc(-c2nc3c(N(c4ccccc4)c4cccc5c4sc4ccccc45)c4ccc(N(c5ccccc5)c5ccccc5)cc4cc3o2)cc1 ; c1ccc(-c2nc3ccc4cc(-c5ccc(N(c6ccccc6)c6ccccc6)cc5)cc(N(c5ccccc5)c5ccccc5)c4c3o2)cc1 ; c1ccc(-c2nc3c(ccc4c(N(c5ccccc5)c5ccccc5)cc(N(c5ccccc5)c5cccc6c5sc5ccccc56)cc43)o2)cc1]

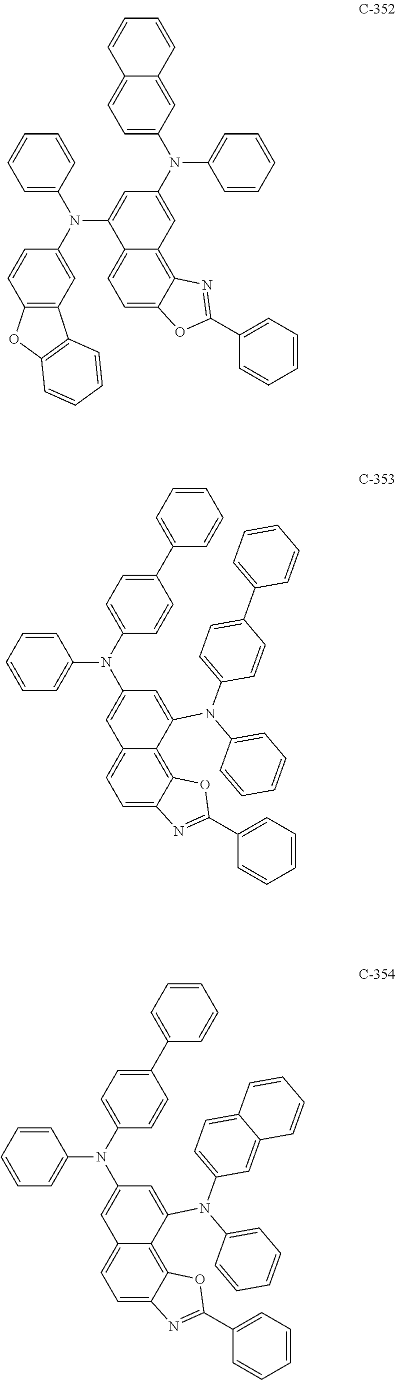 [SMILES: c1ccc(-c2nc3c(ccc4c(N(c5ccccc5)c5ccc6oc7ccccc7c6c5)cc(N(c5ccccc5)c5ccc6ccccc6c5)cc43)o2)cc1 ; c1ccc(-c2ccc(N(c3ccccc3)c3cc(N(c4ccccc4)c4ccc(-c5ccccc5)cc4)c4c(ccc5nc(-c6ccccc6)oc54)c3)cc2)cc1 ; c1ccc(-c2ccc(N(c3ccccc3)c3cc(N(c4ccccc4)c4ccc5ccccc5c4)c4c(ccc5nc(-c6ccccc6)oc54)c3)cc2)cc1]

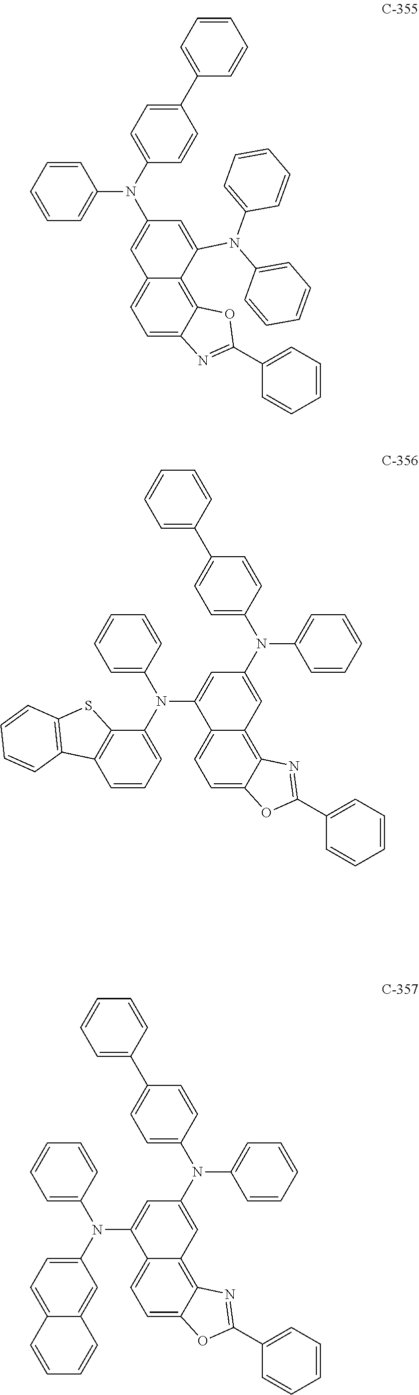 [SMILES: c1ccc(-c2ccc(N(c3ccccc3)c3cc(N(c4ccccc4)c4ccccc4)c4c(ccc5nc(-c6ccccc6)oc54)c3)cc2)cc1 ; c1ccc(-c2ccc(N(c3ccccc3)c3cc(N(c4ccccc4)c4cccc5c4sc4ccccc45)c4ccc5oc(-c6ccccc6)nc5c4c3)cc2)cc1 ; c1ccc(-c2ccc(N(c3ccccc3)c3cc(N(c4ccccc4)c4ccc5ccccc5c4)c4ccc5oc(-c6ccccc6)nc5c4c3)cc2)cc1]

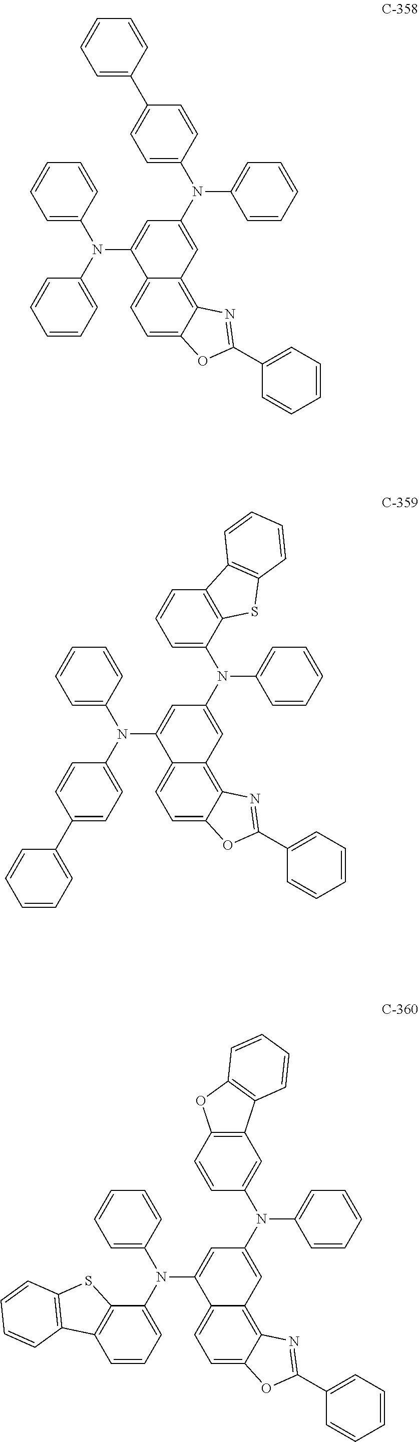 [SMILES: c1ccc(-c2ccc(N(c3ccccc3)c3cc(N(c4ccccc4)c4ccccc4)c4ccc5oc(-c6ccccc6)nc5c4c3)cc2)cc1 ; c1ccc(-c2ccc(N(c3ccccc3)c3cc(N(c4ccccc4)c4cccc5c4sc4ccccc45)cc4c3ccc3oc(-c5ccccc5)nc34)cc2)cc1 ; c1ccc(-c2nc3c(ccc4c(N(c5ccccc5)c5cccc6c5sc5ccccc56)cc(N(c5ccccc5)c5ccc6oc7ccccc7c6c5)cc43)o2)cc1]

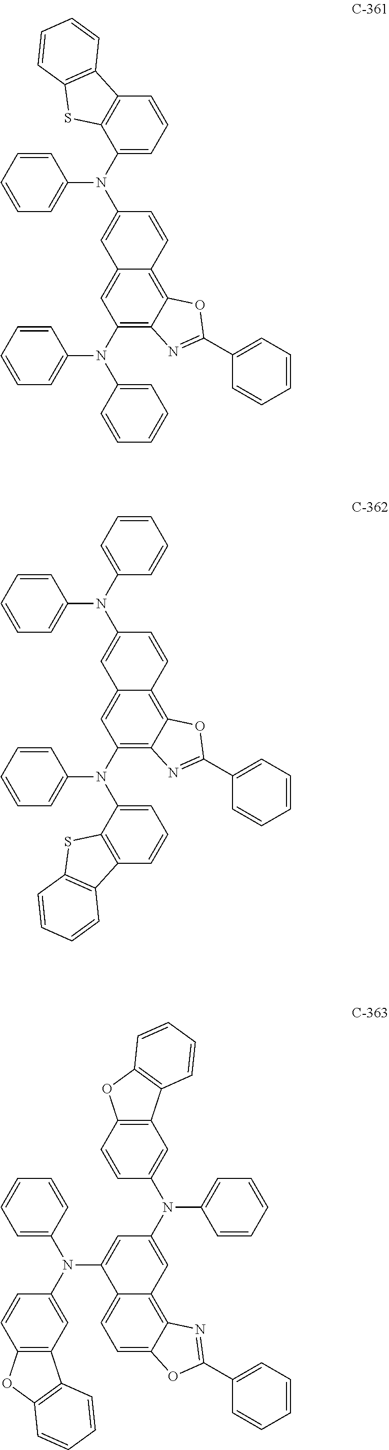 [SMILES: c1ccc(-c2nc3c(N(c4ccccc4)c4ccccc4)cc4cc(N(c5ccccc5)c5cccc6c5sc5ccccc56)ccc4c3o2)cc1 ; c1ccc(-c2nc3c(N(c4ccccc4)c4cccc5c4sc4ccccc45)cc4cc(N(c5ccccc5)c5ccccc5)ccc4c3o2)cc1 ; c1ccc(-c2nc3c(ccc4c(N(c5ccccc5)c5ccc6oc7ccccc7c6c5)cc(N(c5ccccc5)c5ccc6oc7ccccc7c6c5)cc43)o2)cc1]

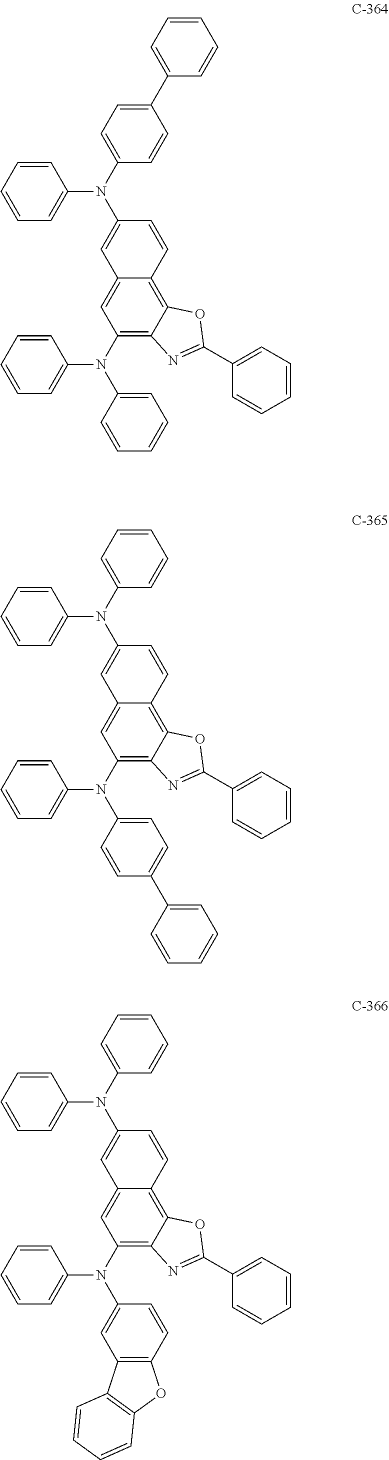 [SMILES: c1ccc(-c2ccc(N(c3ccccc3)c3ccc4c(c3)cc(N(c3ccccc3)c3ccccc3)c3nc(-c5ccccc5)oc34)cc2)cc1 ; c1ccc(-c2ccc(N(c3ccccc3)c3cc4cc(N(c5ccccc5)c5ccccc5)ccc4c4oc(-c5ccccc5)nc34)cc2)cc1 ; c1ccc(-c2nc3c(N(c4ccccc4)c4ccc5oc6ccccc6c5c4)cc4cc(N(c5ccccc5)c5ccccc5)ccc4c3o2)cc1]

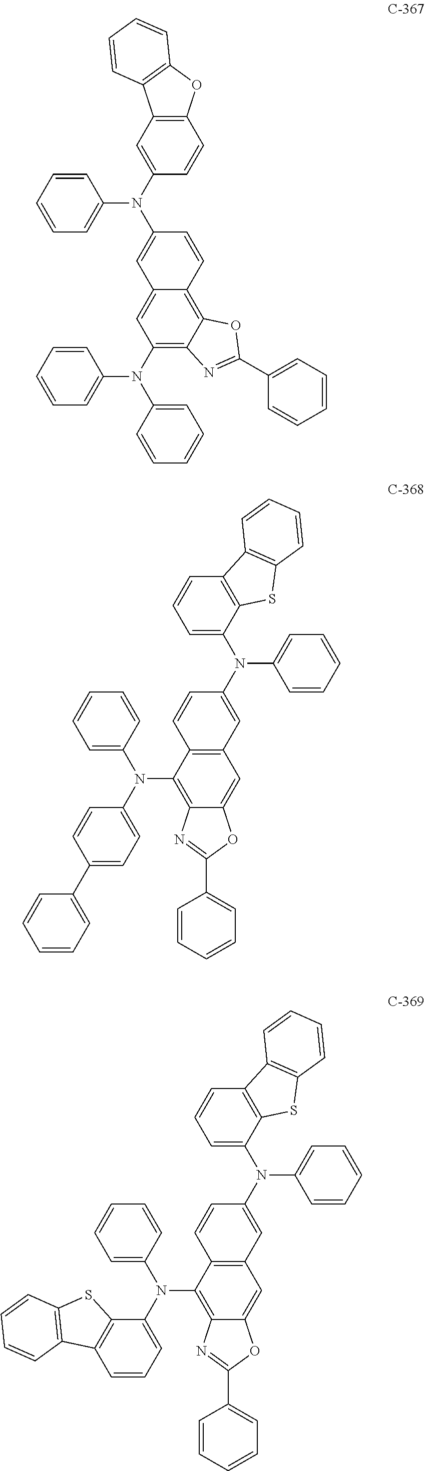 [SMILES: c1ccc(-c2nc3c(N(c4ccccc4)c4ccccc4)cc4cc(N(c5ccccc5)c5ccc6oc7ccccc7c6c5)ccc4c3o2)cc1 ; c1ccc(-c2ccc(N(c3ccccc3)c3c4ccc(N(c5ccccc5)c5cccc6c5sc5ccccc56)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5cccc6c5sc5ccccc56)cc4cc3o2)cc1]

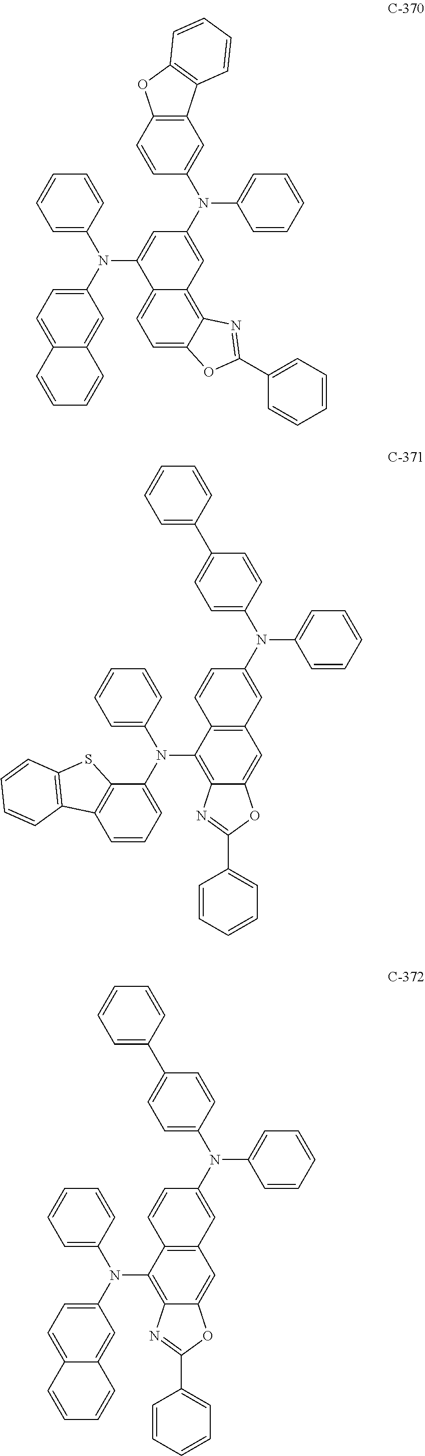 [SMILES: c1ccc(-c2nc3c(ccc4c(N(c5ccccc5)c5ccc6ccccc6c5)cc(N(c5ccccc5)c5ccc6oc7ccccc7c6c5)cc43)o2)cc1 ; c1ccc(-c2ccc(N(c3ccccc3)c3ccc4c(N(c5ccccc5)c5cccc6c5sc5ccccc56)c5nc(-c6ccccc6)oc5cc4c3)cc2)cc1 ; c1ccc(-c2ccc(N(c3ccccc3)c3ccc4c(N(c5ccccc5)c5ccc6ccccc6c5)c5nc(-c6ccccc6)oc5cc4c3)cc2)cc1]

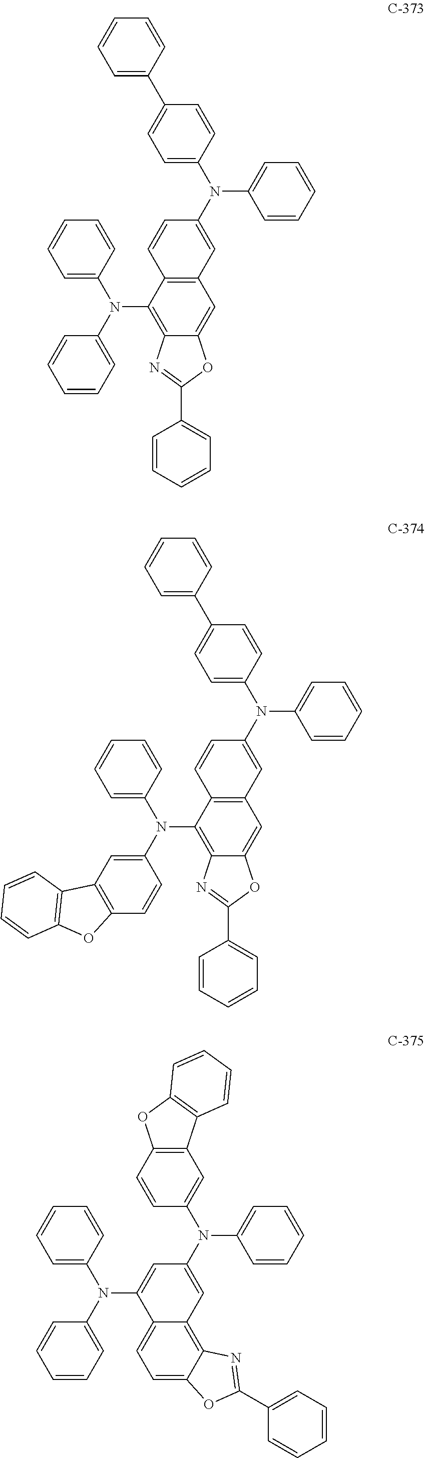 [SMILES: c1ccc(-c2ccc(N(c3ccccc3)c3ccc4c(N(c5ccccc5)c5ccccc5)c5nc(-c6ccccc6)oc5cc4c3)cc2)cc1 ; c1ccc(-c2ccc(N(c3ccccc3)c3ccc4c(N(c5ccccc5)c5ccc6oc7ccccc7c6c5)c5nc(-c6ccccc6)oc5cc4c3)cc2)cc1 ; c1ccc(-c2nc3c(ccc4c(N(c5ccccc5)c5ccccc5)cc(N(c5ccccc5)c5ccc6oc7ccccc7c6c5)cc43)o2)cc1]

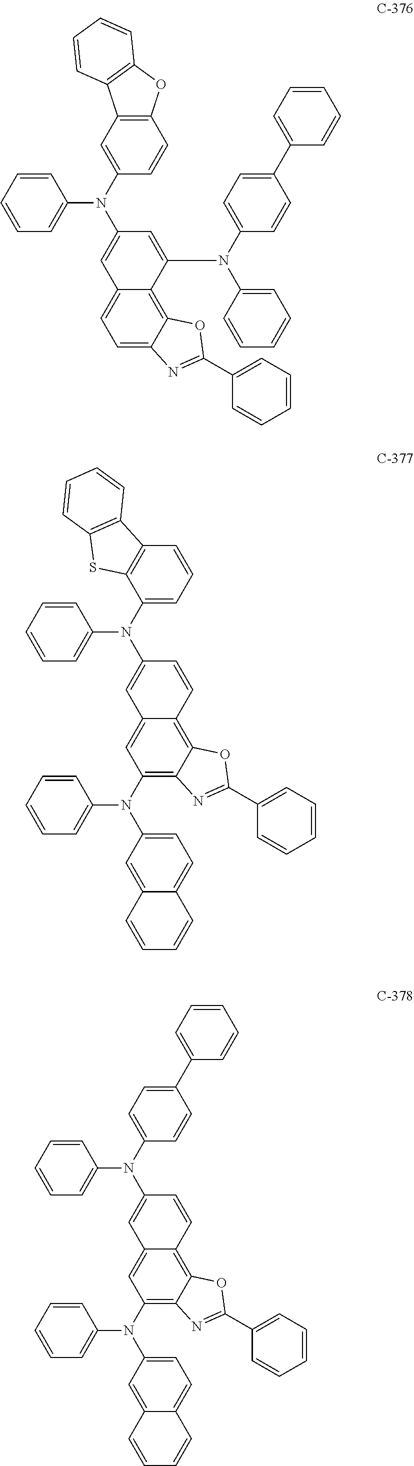 [SMILES: c1ccc(-c2ccc(N(c3ccccc3)c3cc(N(c4ccccc4)c4ccc5oc6ccccc6c5c4)cc4ccc5nc(-c6ccccc6)oc5c34)cc2)cc1 ; c1ccc(-c2nc3c(N(c4ccccc4)c4ccc5ccccc5c4)cc4cc(N(c5ccccc5)c5cccc6c5sc5ccccc56)ccc4c3o2)cc1 ; c1ccc(-c2ccc(N(c3ccccc3)c3ccc4c(c3)cc(N(c3ccccc3)c3ccc5ccccc5c3)c3nc(-c5ccccc5)oc34)cc2)cc1]

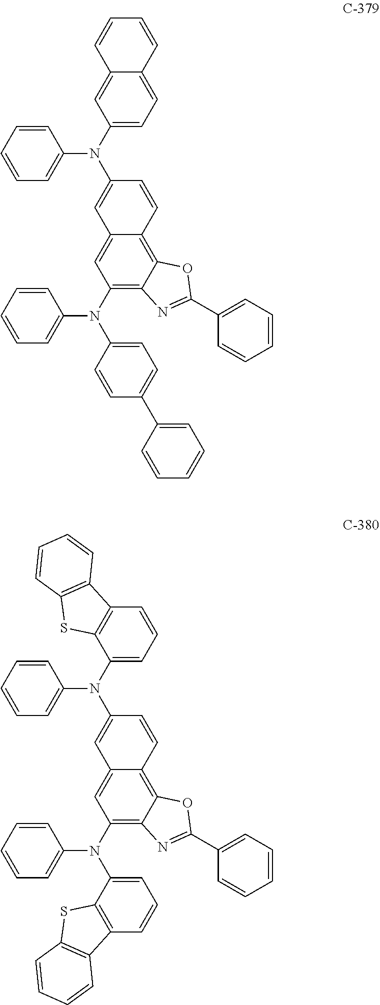 [SMILES: c1ccc(-c2ccc(N(c3ccccc3)c3cc4cc(N(c5ccccc5)c5ccc6ccccc6c5)ccc4c4oc(-c5ccccc5)nc34)cc2)cc1 ; c1ccc(-c2nc3c(N(c4ccccc4)c4cccc5c4sc4ccccc45)cc4cc(N(c5ccccc5)c5cccc6c5sc5ccccc56)ccc4c3o2)cc1]

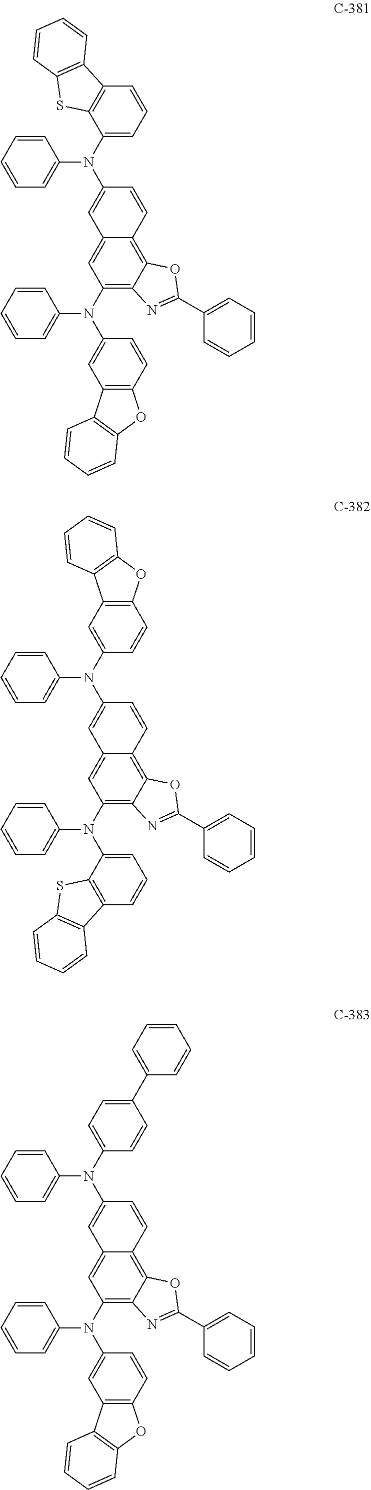 [SMILES: c1ccc(-c2nc3c(N(c4ccccc4)c4ccc5oc6ccccc6c5c4)cc4cc(N(c5ccccc5)c5cccc6c5sc5ccccc56)ccc4c3o2)cc1 ; c1ccc(-c2nc3c(N(c4ccccc4)c4cccc5c4sc4ccccc45)cc4cc(N(c5ccccc5)c5ccc6oc7ccccc7c6c5)ccc4c3o2)cc1 ; c1ccc(-c2ccc(N(c3ccccc3)c3ccc4c(c3)cc(N(c3ccccc3)c3ccc5oc6ccccc6c5c3)c3nc(-c5ccccc5)oc34)cc2)cc1]

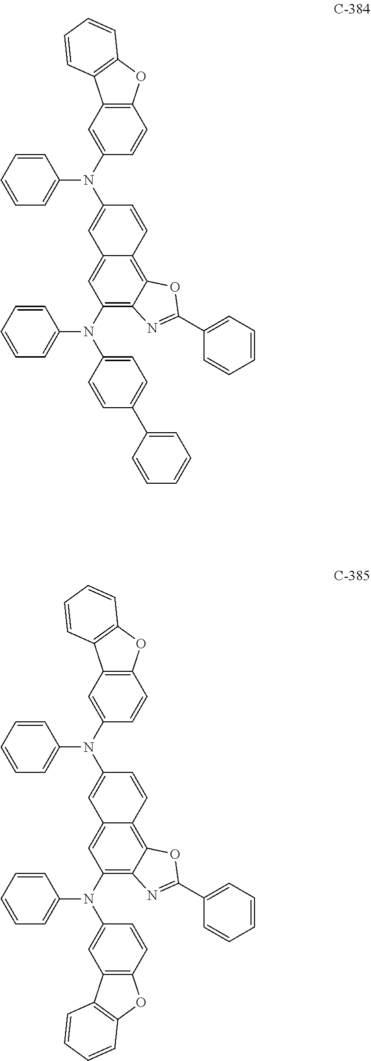 [SMILES: c1ccc(-c2ccc(N(c3ccccc3)c3cc4cc(N(c5ccccc5)c5ccc6oc7ccccc7c6c5)ccc4c4oc(-c5ccccc5)nc34)cc2)cc1 ; c1ccc(-c2nc3c(N(c4ccccc4)c4ccc5oc6ccccc6c5c4)cc4cc(N(c5ccccc5)c5ccc6oc7ccccc7c6c5)ccc4c3o2)cc1]

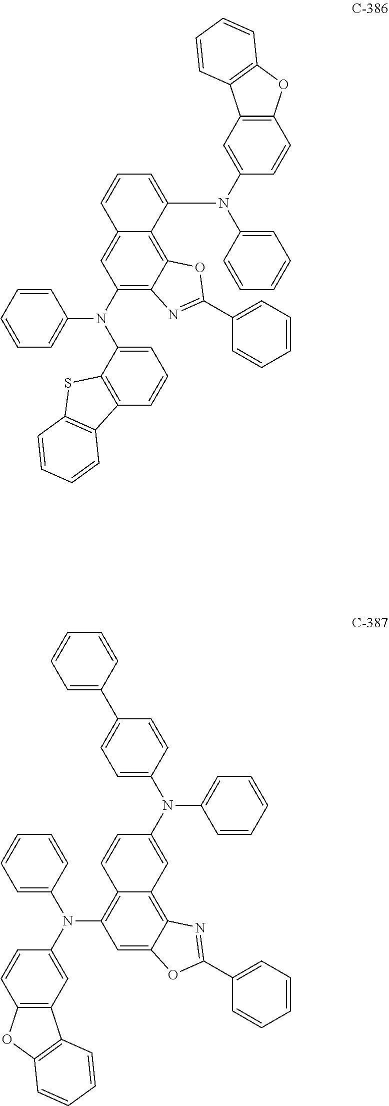 [SMILES: c1ccc(-c2nc3c(N(c4ccccc4)c4cccc5c4sc4ccccc45)cc4cccc(N(c5ccccc5)c5ccc6oc7ccccc7c6c5)c4c3o2)cc1 ; c1ccc(-c2ccc(N(c3ccccc3)c3ccc4c(N(c5ccccc5)c5ccc6oc7ccccc7c6c5)cc5oc(-c6ccccc6)nc5c4c3)cc2)cc1]

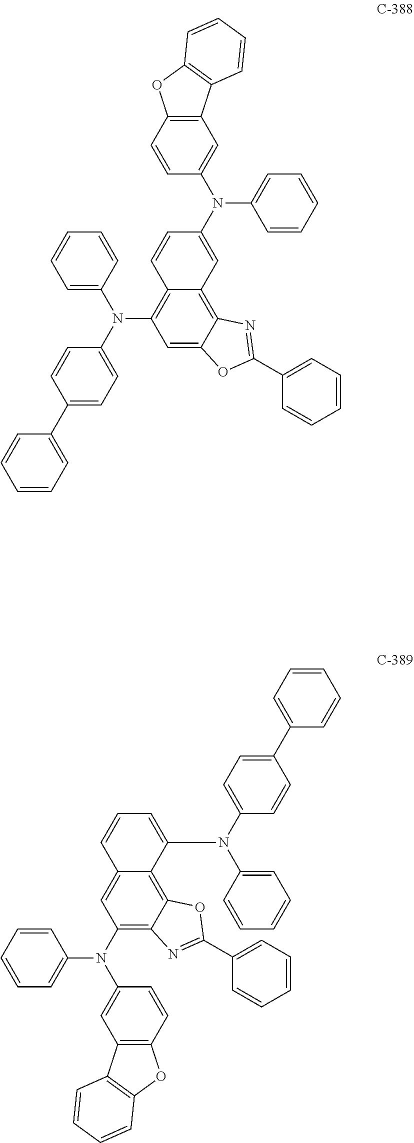 [SMILES: c1ccc(-c2ccc(N(c3ccccc3)c3cc4oc(-c5ccccc5)nc4c4cc(N(c5ccccc5)c5ccc6oc7ccccc7c6c5)ccc34)cc2)cc1 ; c1ccc(-c2ccc(N(c3ccccc3)c3cccc4cc(N(c5ccccc5)c5ccc6oc7ccccc7c6c5)c5nc(-c6ccccc6)oc5c34)cc2)cc1]

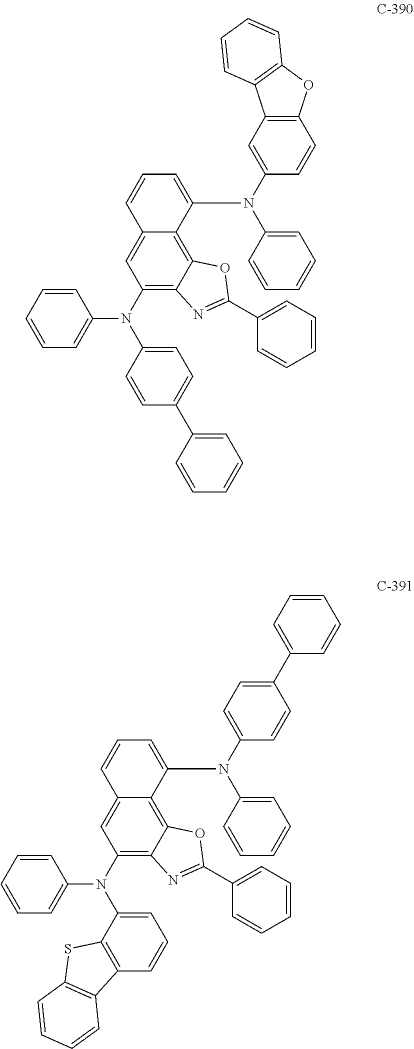 [SMILES: c1ccc(-c2ccc(N(c3ccccc3)c3cc4cccc(N(c5ccccc5)c5ccc6oc7ccccc7c6c5)c4c4oc(-c5ccccc5)nc34)cc2)cc1 ; c1ccc(-c2ccc(N(c3ccccc3)c3cccc4cc(N(c5ccccc5)c5cccc6c5sc5ccccc56)c5nc(-c6ccccc6)oc5c34)cc2)cc1]

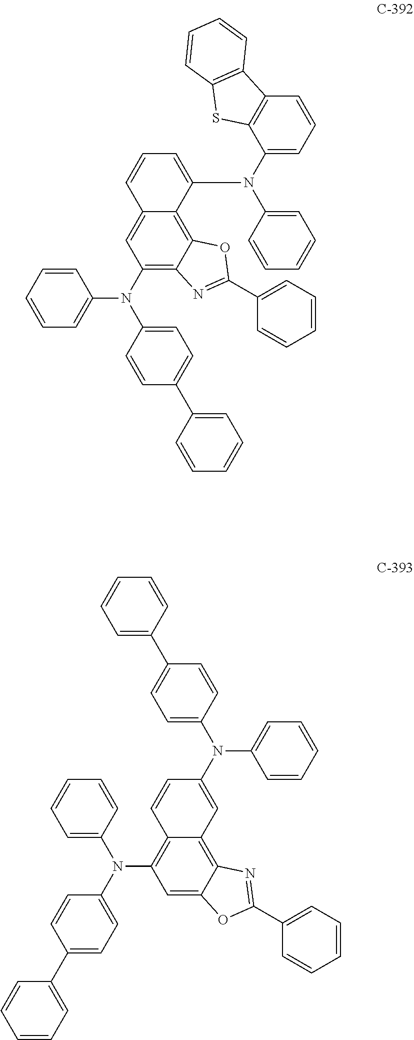 [SMILES: c1ccc(-c2ccc(N(c3ccccc3)c3cc4cccc(N(c5ccccc5)c5cccc6c5sc5ccccc56)c4c4oc(-c5ccccc5)nc34)cc2)cc1 ; c1ccc(-c2ccc(N(c3ccccc3)c3ccc4c(N(c5ccccc5)c5ccc(-c6ccccc6)cc5)cc5oc(-c6ccccc6)nc5c4c3)cc2)cc1]

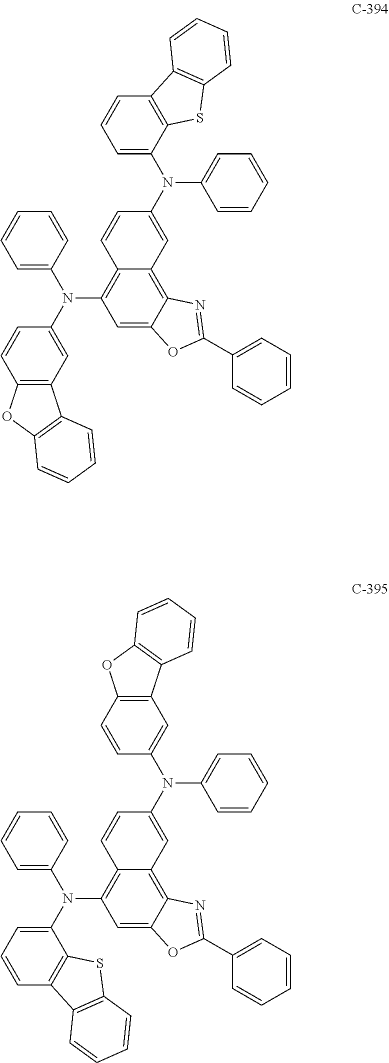 [SMILES: c1ccc(-c2nc3c(cc(N(c4ccccc4)c4ccc5oc6ccccc6c5c4)c4ccc(N(c5ccccc5)c5cccc6c5sc5ccccc56)cc43)o2)cc1 ; c1ccc(-c2nc3c(cc(N(c4ccccc4)c4cccc5c4sc4ccccc45)c4ccc(N(c5ccccc5)c5ccc6oc7ccccc7c6c5)cc43)o2)cc1]

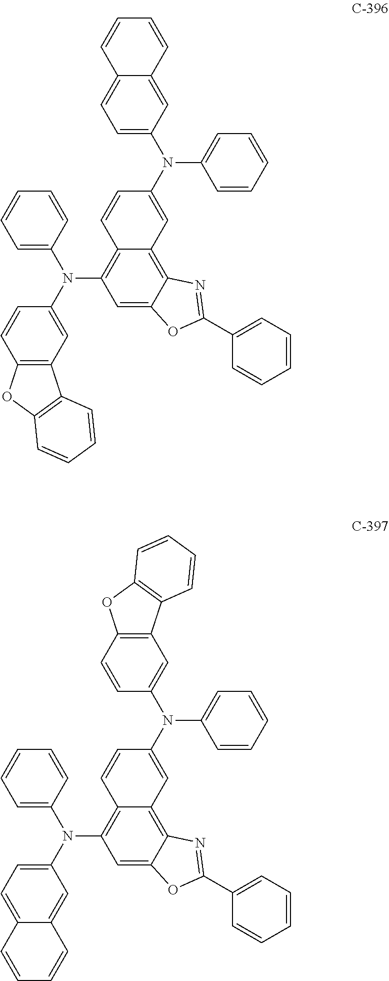 [SMILES: c1ccc(-c2nc3c(cc(N(c4ccccc4)c4ccc5oc6ccccc6c5c4)c4ccc(N(c5ccccc5)c5ccc6ccccc6c5)cc43)o2)cc1 ; c1ccc(-c2nc3c(cc(N(c4ccccc4)c4ccc5ccccc5c4)c4ccc(N(c5ccccc5)c5ccc6oc7ccccc7c6c5)cc43)o2)cc1]

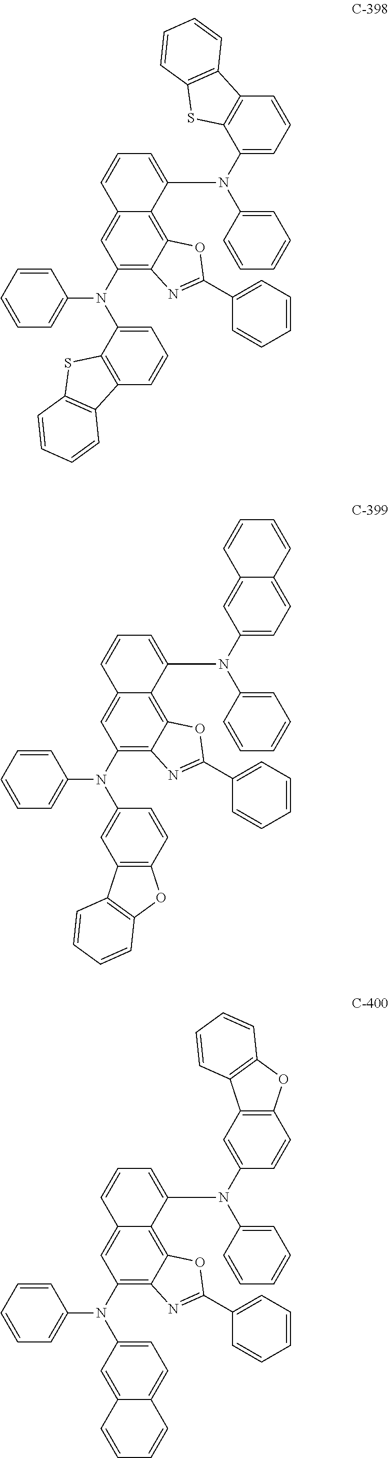 [SMILES: c1ccc(-c2nc3c(N(c4ccccc4)c4cccc5c4sc4ccccc45)cc4cccc(N(c5ccccc5)c5cccc6c5sc5ccccc56)c4c3o2)cc1 ; c1ccc(-c2nc3c(N(c4ccccc4)c4ccc5oc6ccccc6c5c4)cc4cccc(N(c5ccccc5)c5ccc6ccccc6c5)c4c3o2)cc1 ; c1ccc(-c2nc3c(N(c4ccccc4)c4ccc5ccccc5c4)cc4cccc(N(c5ccccc5)c5ccc6oc7ccccc7c6c5)c4c3o2)cc1]

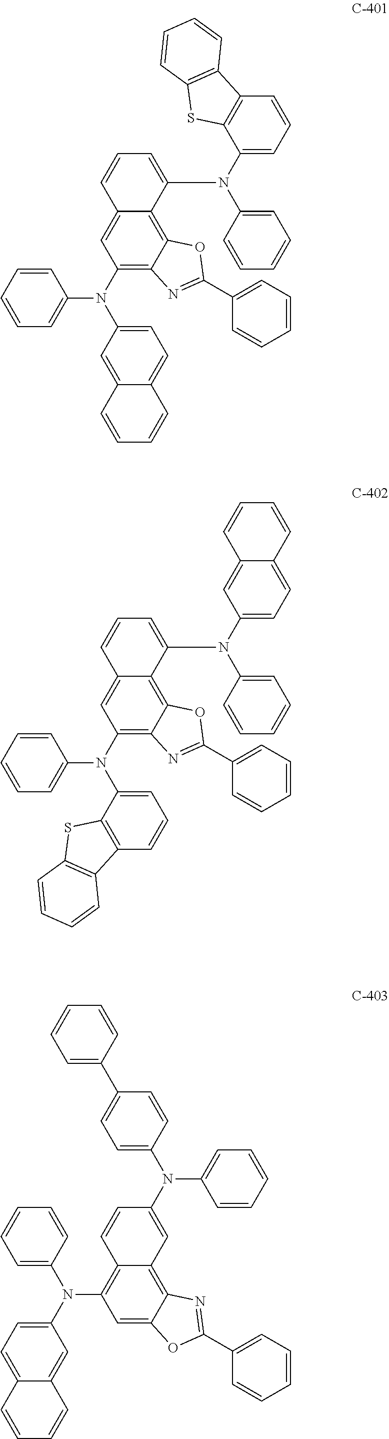 [SMILES: c1ccc(-c2nc3c(N(c4ccccc4)c4ccc5ccccc5c4)cc4cccc(N(c5ccccc5)c5cccc6c5sc5ccccc56)c4c3o2)cc1 ; c1ccc(-c2nc3c(N(c4ccccc4)c4cccc5c4sc4ccccc45)cc4cccc(N(c5ccccc5)c5ccc6ccccc6c5)c4c3o2)cc1 ; c1ccc(-c2ccc(N(c3ccccc3)c3ccc4c(N(c5ccccc5)c5ccc6ccccc6c5)cc5oc(-c6ccccc6)nc5c4c3)cc2)cc1]

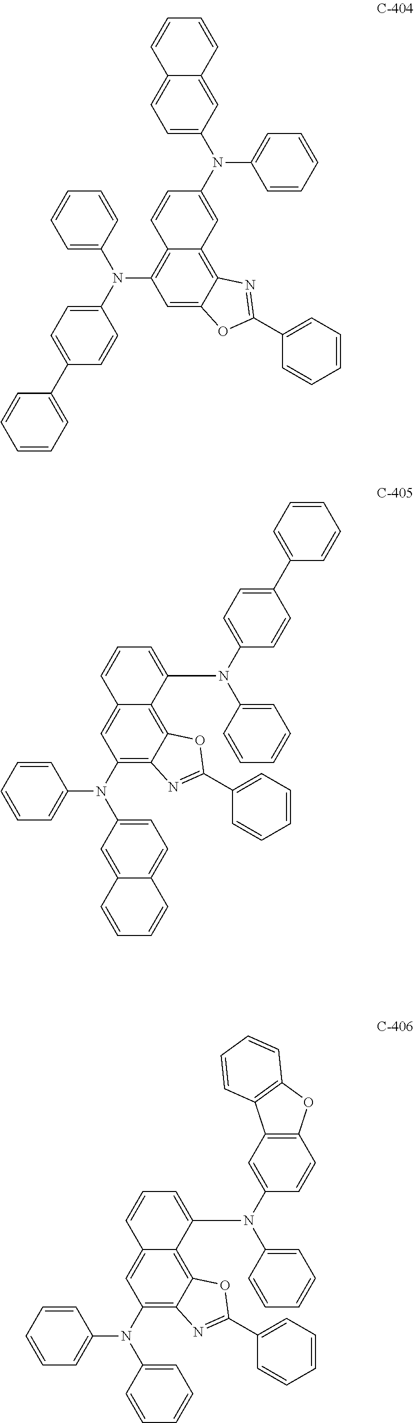 [SMILES: c1ccc(-c2ccc(N(c3ccccc3)c3cc4oc(-c5ccccc5)nc4c4cc(N(c5ccccc5)c5ccc6ccccc6c5)ccc34)cc2)cc1 ; c1ccc(-c2ccc(N(c3ccccc3)c3cccc4cc(N(c5ccccc5)c5ccc6ccccc6c5)c5nc(-c6ccccc6)oc5c34)cc2)cc1 ; c1ccc(-c2nc3c(N(c4ccccc4)c4ccccc4)cc4cccc(N(c5ccccc5)c5ccc6oc7ccccc7c6c5)c4c3o2)cc1]

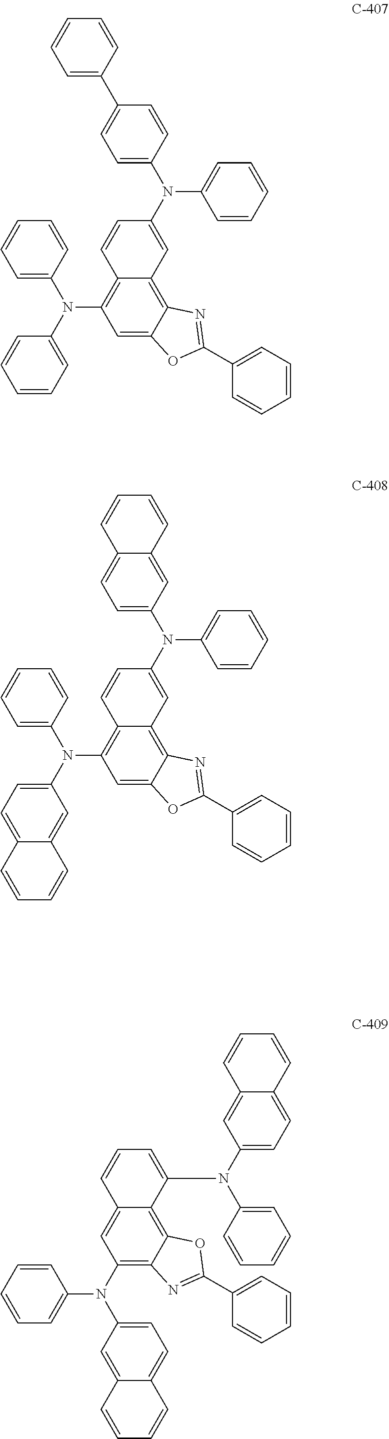 [SMILES: c1ccc(-c2ccc(N(c3ccccc3)c3ccc4c(N(c5ccccc5)c5ccccc5)cc5oc(-c6ccccc6)nc5c4c3)cc2)cc1 ; c1ccc(-c2nc3c(cc(N(c4ccccc4)c4ccc5ccccc5c4)c4ccc(N(c5ccccc5)c5ccc6ccccc6c5)cc43)o2)cc1 ; c1ccc(-c2nc3c(N(c4ccccc4)c4ccc5ccccc5c4)cc4cccc(N(c5ccccc5)c5ccc6ccccc6c5)c4c3o2)cc1]

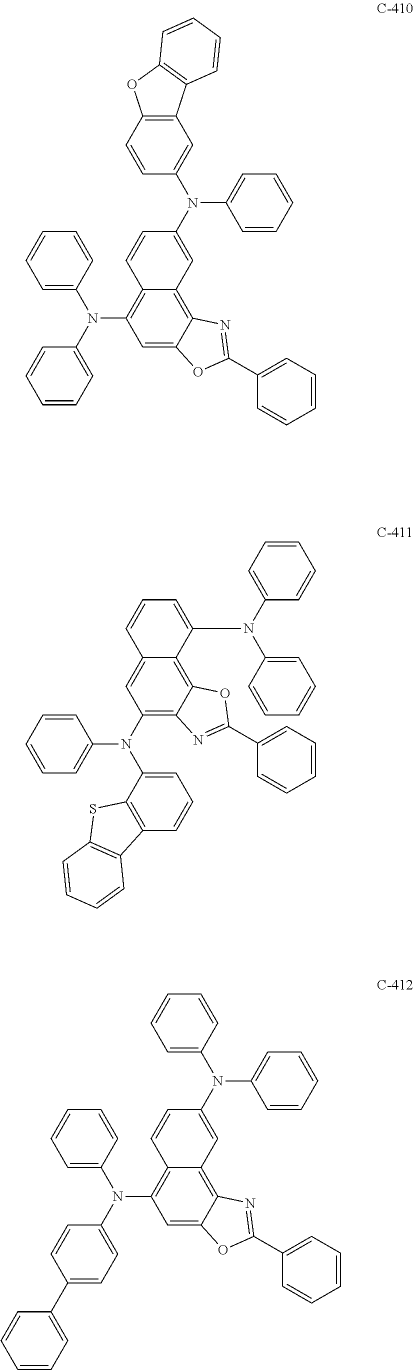 [SMILES: c1ccc(-c2nc3c(cc(N(c4ccccc4)c4ccccc4)c4ccc(N(c5ccccc5)c5ccc6oc7ccccc7c6c5)cc43)o2)cc1 ; c1ccc(-c2nc3c(N(c4ccccc4)c4cccc5c4sc4ccccc45)cc4cccc(N(c5ccccc5)c5ccccc5)c4c3o2)cc1 ; c1ccc(-c2ccc(N(c3ccccc3)c3cc4oc(-c5ccccc5)nc4c4cc(N(c5ccccc5)c5ccccc5)ccc34)cc2)cc1]

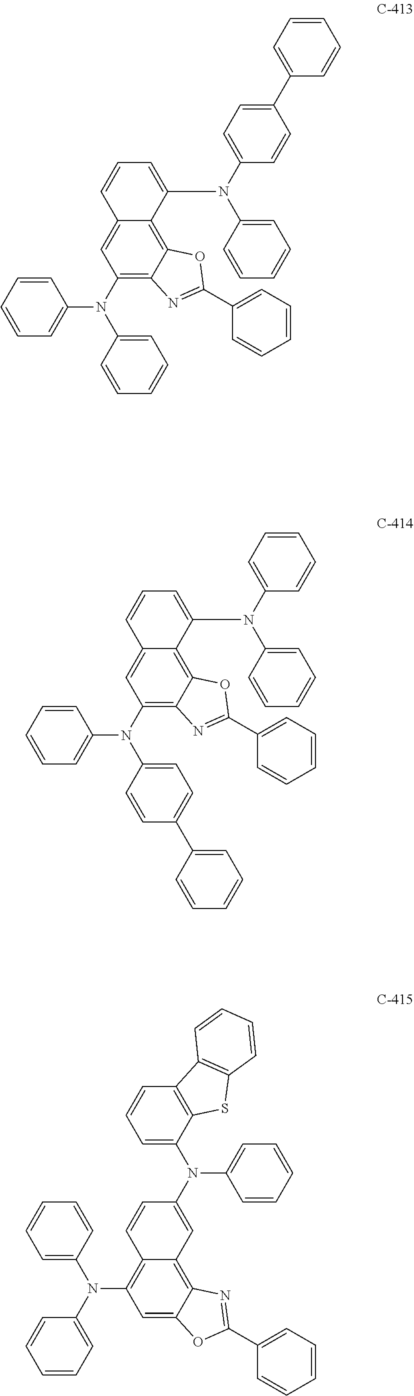 [SMILES: c1ccc(-c2ccc(N(c3ccccc3)c3cccc4cc(N(c5ccccc5)c5ccccc5)c5nc(-c6ccccc6)oc5c34)cc2)cc1 ; c1ccc(-c2ccc(N(c3ccccc3)c3cc4cccc(N(c5ccccc5)c5ccccc5)c4c4oc(-c5ccccc5)nc34)cc2)cc1 ; c1ccc(-c2nc3c(cc(N(c4ccccc4)c4ccccc4)c4ccc(N(c5ccccc5)c5cccc6c5sc5ccccc56)cc43)o2)cc1]

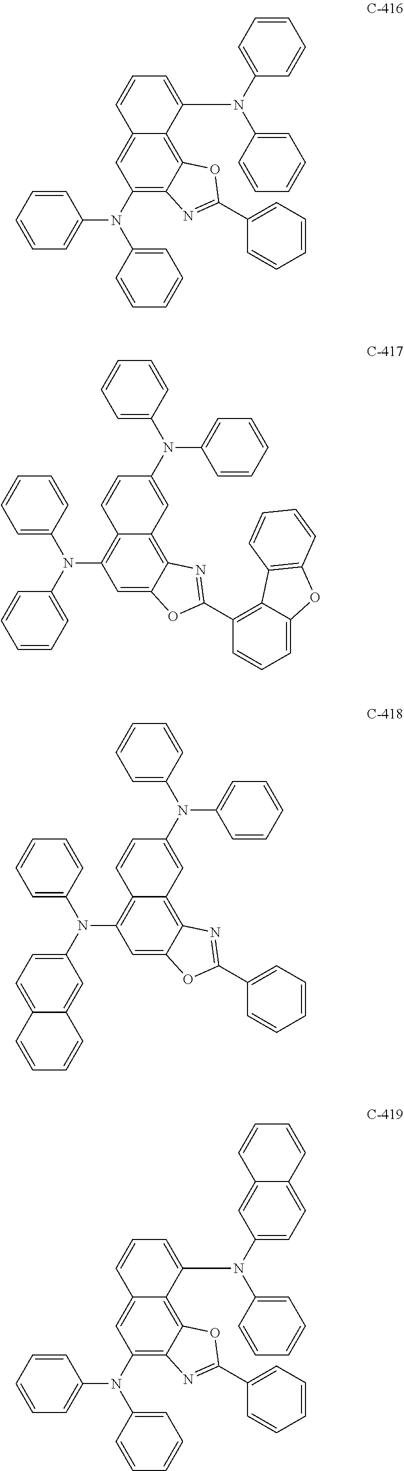 [SMILES: c1ccc(-c2nc3c(N(c4ccccc4)c4ccccc4)cc4cccc(N(c5ccccc5)c5ccccc5)c4c3o2)cc1 ; c1ccc(N(c2ccccc2)c2ccc3c(N(c4ccccc4)c4ccccc4)cc4oc(-c5cccc6oc7ccccc7c56)nc4c3c2)cc1 ; c1ccc(-c2nc3c(cc(N(c4ccccc4)c4ccc5ccccc5c4)c4ccc(N(c5ccccc5)c5ccccc5)cc43)o2)cc1 ; c1ccc(-c2nc3c(N(c4ccccc4)c4ccccc4)cc4cccc(N(c5ccccc5)c5ccc6ccccc6c5)c4c3o2)cc1]

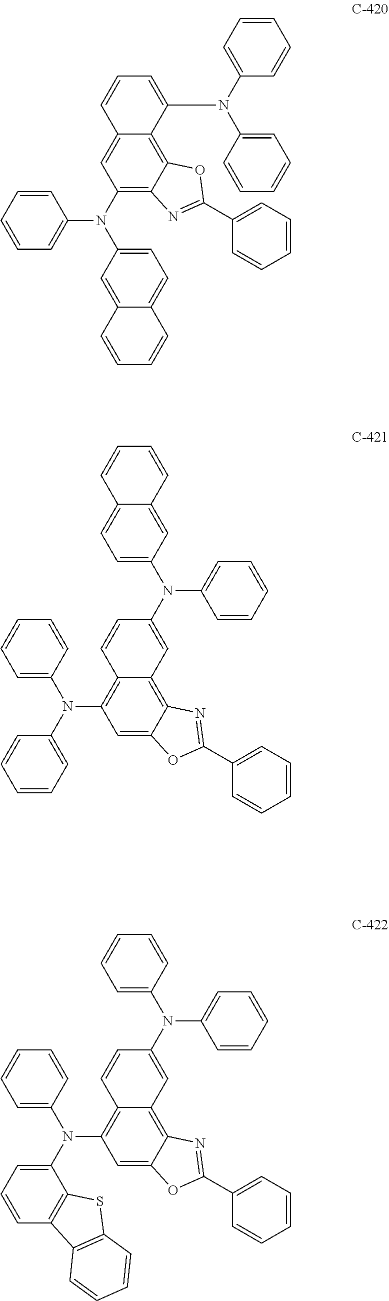 [SMILES: c1ccc(-c2nc3c(N(c4ccccc4)c4ccc5ccccc5c4)cc4cccc(N(c5ccccc5)c5ccccc5)c4c3o2)cc1 ; c1ccc(-c2nc3c(cc(N(c4ccccc4)c4ccccc4)c4ccc(N(c5ccccc5)c5ccc6ccccc6c5)cc43)o2)cc1 ; c1ccc(-c2nc3c(cc(N(c4ccccc4)c4cccc5c4sc4ccccc45)c4ccc(N(c5ccccc5)c5ccccc5)cc43)o2)cc1]

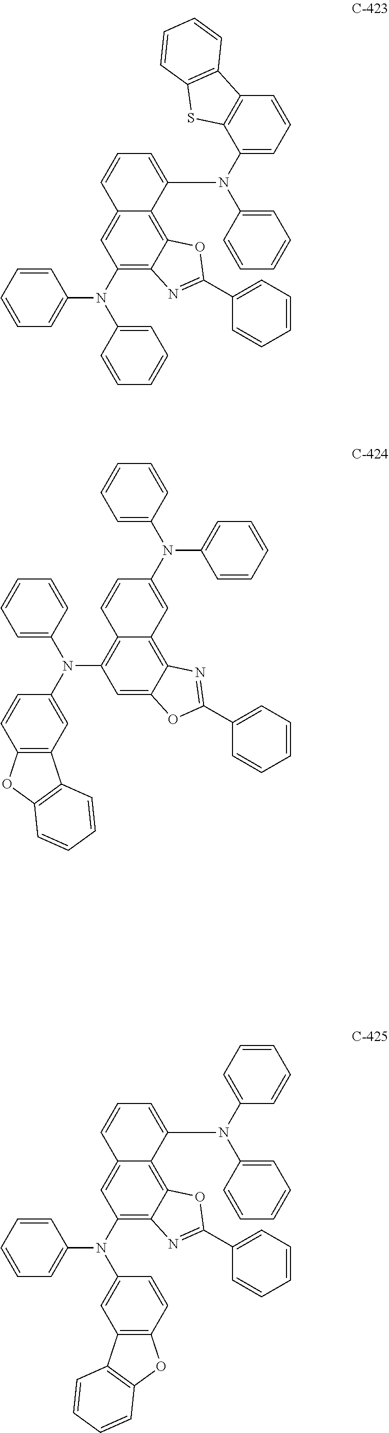 [SMILES: c1ccc(-c2nc3c(N(c4ccccc4)c4ccccc4)cc4cccc(N(c5ccccc5)c5cccc6c5sc5ccccc56)c4c3o2)cc1 ; c1ccc(-c2nc3c(cc(N(c4ccccc4)c4ccc5oc6ccccc6c5c4)c4ccc(N(c5ccccc5)c5ccccc5)cc43)o2)cc1 ; c1ccc(-c2nc3c(N(c4ccccc4)c4ccc5oc6ccccc6c5c4)cc4cccc(N(c5ccccc5)c5ccccc5)c4c3o2)cc1]

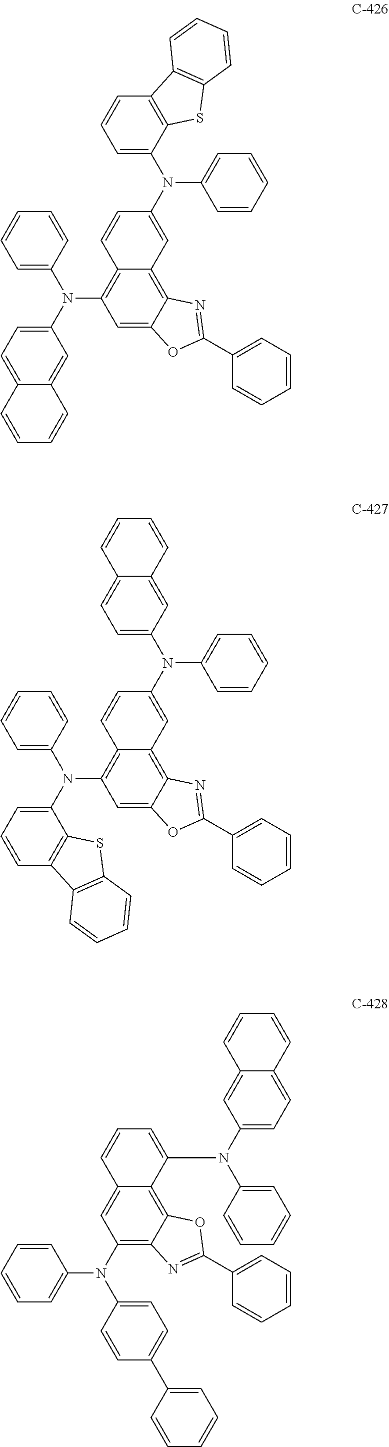 [SMILES: c1ccc(-c2nc3c(cc(N(c4ccccc4)c4ccc5ccccc5c4)c4ccc(N(c5ccccc5)c5cccc6c5sc5ccccc56)cc43)o2)cc1 ; c1ccc(-c2nc3c(cc(N(c4ccccc4)c4cccc5c4sc4ccccc45)c4ccc(N(c5ccccc5)c5ccc6ccccc6c5)cc43)o2)cc1 ; c1ccc(-c2ccc(N(c3ccccc3)c3cc4cccc(N(c5ccccc5)c5ccc6ccccc6c5)c4c4oc(-c5ccccc5)nc34)cc2)cc1]

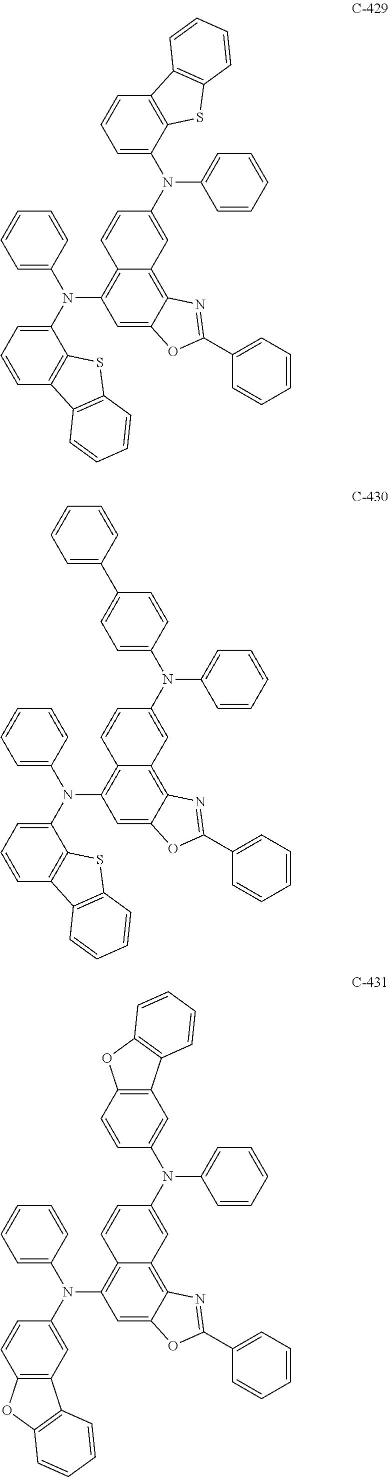

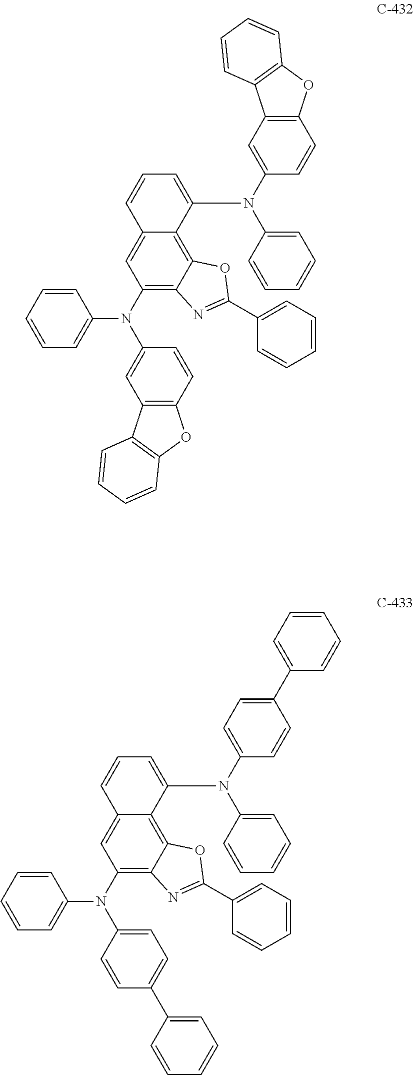 [SMILES: c1ccc(-c2nc3c(N(c4ccccc4)c4ccc5oc6ccccc6c5c4)cc4cccc(N(c5ccccc5)c5ccc6oc7ccccc7c6c5)c4c3o2)cc1 ; c1ccc(-c2ccc(N(c3ccccc3)c3cc4cccc(N(c5ccccc5)c5ccc(-c6ccccc6)cc5)c4c4oc(-c5ccccc5)nc34)cc2)cc1]

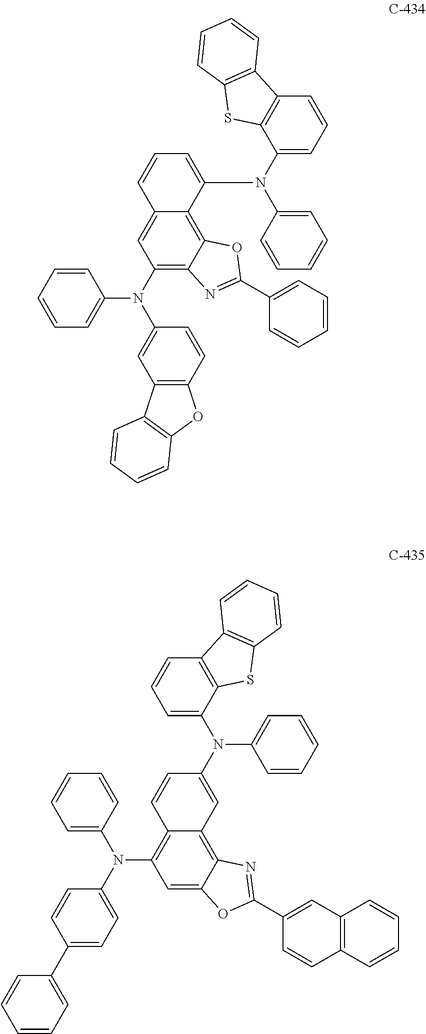 [SMILES: c1ccc(-c2nc3c(N(c4ccccc4)c4ccc5oc6ccccc6c5c4)cc4cccc(N(c5ccccc5)c5cccc6c5sc5ccccc56)c4c3o2)cc1 ; c1ccc(-c2ccc(N(c3ccccc3)c3cc4oc(-c5ccc6ccccc6c5)nc4c4cc(N(c5ccccc5)c5cccc6c5sc5ccccc56)ccc34)cc2)cc1]

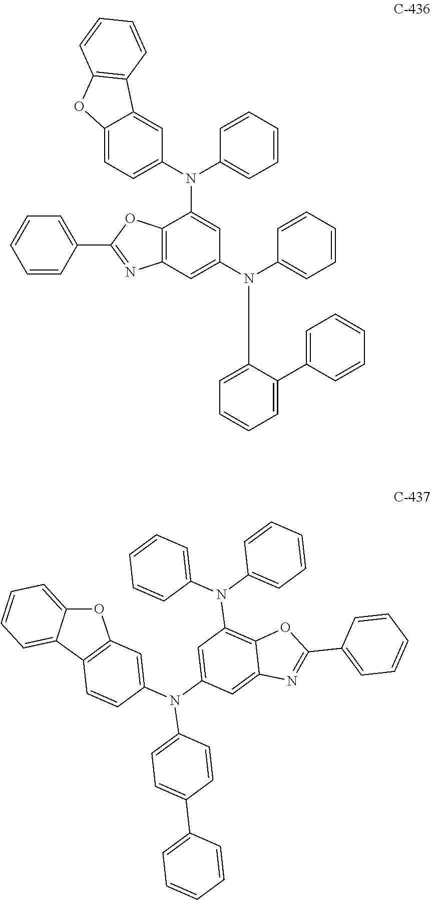 [SMILES: c1ccc(-c2nc3cc(N(c4ccccc4)c4ccccc4-c4ccccc4)cc(N(c4ccccc4)c4ccc5oc6ccccc6c5c4)c3o2)cc1 ; c1ccc(-c2ccc(N(c3cc(N(c4ccccc4)c4ccccc4)c4oc(-c5ccccc5)nc4c3)c3ccc4c(c3)oc3ccccc34)cc2)cc1]

The compound represented by Formula 11 may be at least one selected from compounds C-1 to C-120 and C-126 to C-435, but is not limited thereto.

The compound represented by Formula 2 may be at least one selected from the following compounds, but not limited thereto.

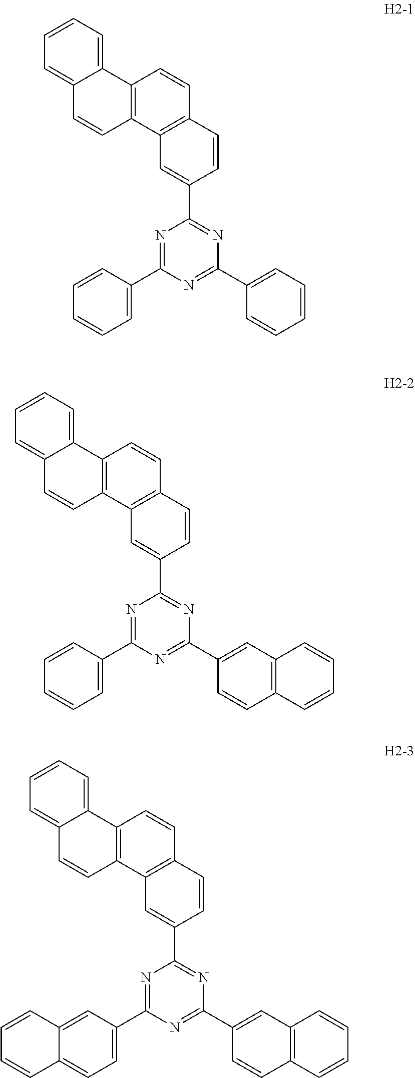 [SMILES: c1ccc(-c2nc(-c3ccccc3)nc(-c3ccc4ccc5c6ccccc6ccc5c4c3)n2)cc1 ; c1ccc(-c2nc(-c3ccc4ccccc4c3)nc(-c3ccc4ccc5c6ccccc6ccc5c4c3)n2)cc1 ; c1ccc2cc(-c3nc(-c4ccc5ccccc5c4)nc(-c4ccc5ccc6c7ccccc7ccc6c5c4)n3)ccc2c1]

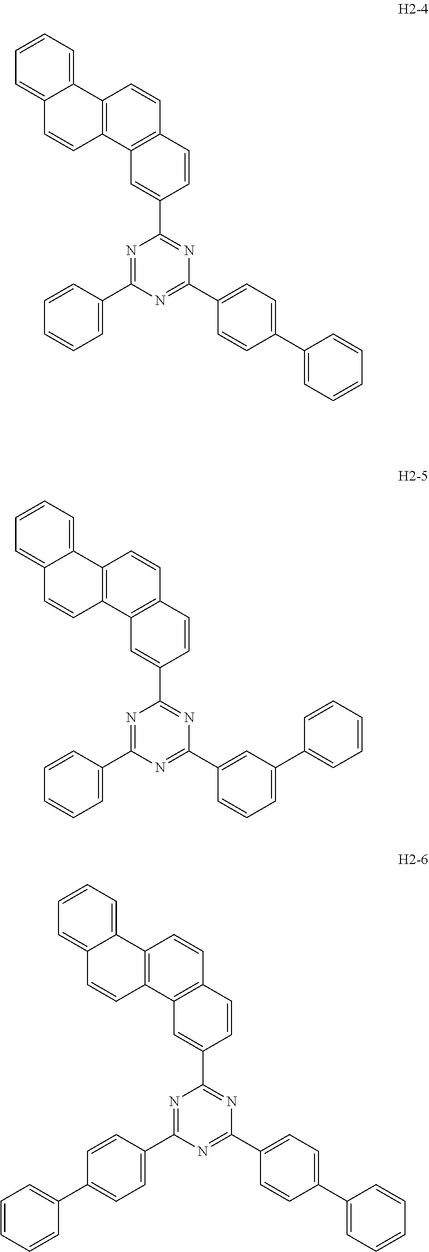 [SMILES: c1ccc(-c2ccc(-c3nc(-c4ccccc4)nc(-c4ccc5ccc6c7ccccc7ccc6c5c4)n3)cc2)cc1 ; c1ccc(-c2cccc(-c3nc(-c4ccccc4)nc(-c4ccc5ccc6c7ccccc7ccc6c5c4)n3)c2)cc1 ; c1ccc(-c2ccc(-c3nc(-c4ccc(-c5ccccc5)cc4)nc(-c4ccc5ccc6c7ccccc7ccc6c5c4)n3)cc2)cc1]

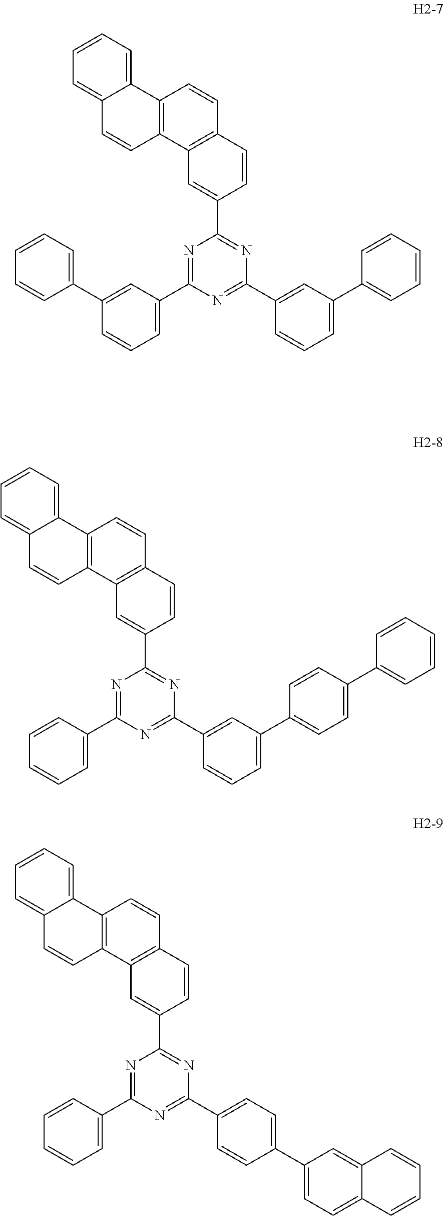 [SMILES: c1ccc(-c2cccc(-c3nc(-c4cccc(-c5ccccc5)c4)nc(-c4ccc5ccc6c7ccccc7ccc6c5c4)n3)c2)cc1 ; c1ccc(-c2ccc(-c3cccc(-c4nc(-c5ccccc5)nc(-c5ccc6ccc7c8ccccc8ccc7c6c5)n4)c3)cc2)cc1 ; c1ccc(-c2nc(-c3ccc(-c4ccc5ccccc5c4)cc3)nc(-c3ccc4ccc5c6ccccc6ccc5c4c3)n2)cc1]

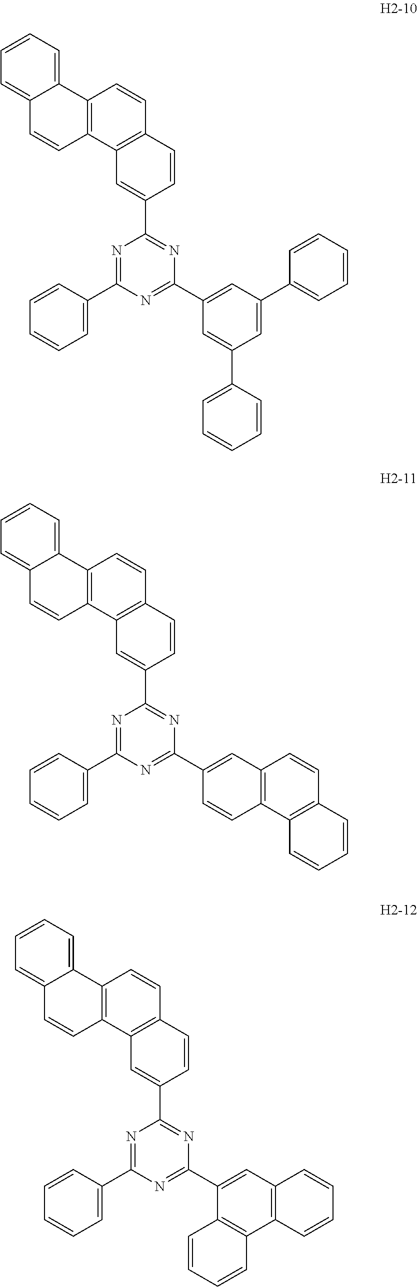 [SMILES: c1ccc(-c2cc(-c3ccccc3)cc(-c3nc(-c4ccccc4)nc(-c4ccc5ccc6c7ccccc7ccc6c5c4)n3)c2)cc1 ; c1ccc(-c2nc(-c3ccc4c(ccc5ccccc54)c3)nc(-c3ccc4ccc5c6ccccc6ccc5c4c3)n2)cc1 ; c1ccc(-c2nc(-c3ccc4ccc5c6ccccc6ccc5c4c3)nc(-c3cc4ccccc4c4ccccc34)n2)cc1]

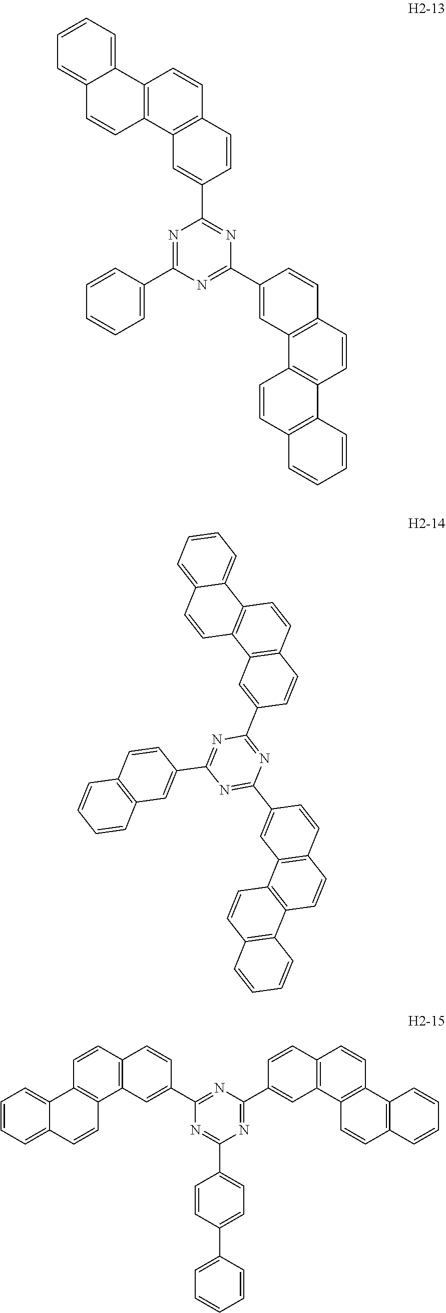 [SMILES: c1ccc(-c2nc(-c3ccc4ccc5c6ccccc6ccc5c4c3)nc(-c3ccc4ccc5c6ccccc6ccc5c4c3)n2)cc1 ; c1ccc2cc(-c3nc(-c4ccc5ccc6c7ccccc7ccc6c5c4)nc(-c4ccc5ccc6c7ccccc7ccc6c5c4)n3)ccc2c1 ; c1ccc(-c2ccc(-c3nc(-c4ccc5ccc6c7ccccc7ccc6c5c4)nc(-c4ccc5ccc6c7ccccc7ccc6c5c4)n3)cc2)cc1]

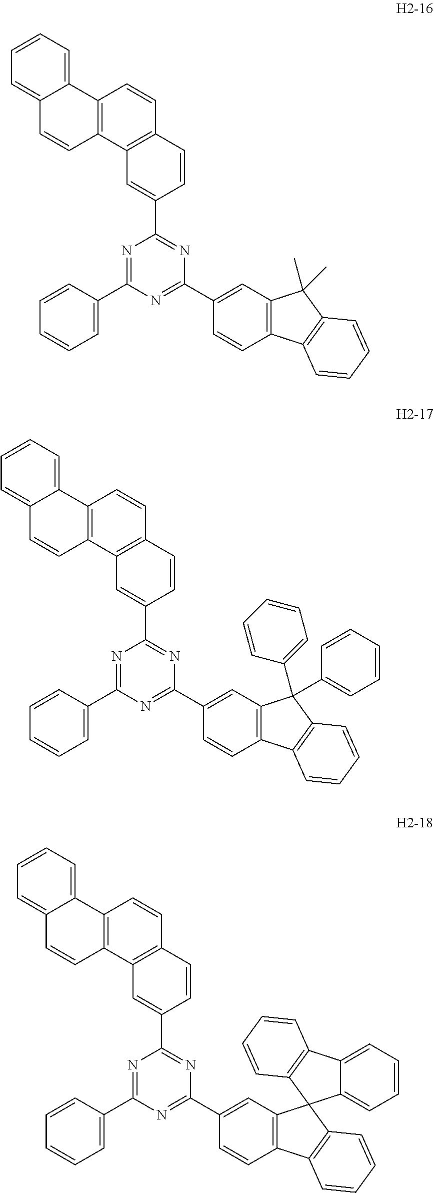 [SMILES: CC1(C)c2ccccc2-c2ccc(-c3nc(-c4ccccc4)nc(-c4ccc5ccc6c7ccccc7ccc6c5c4)n3)cc21 ; c1ccc(-c2nc(-c3ccc4c(c3)C(c3ccccc3)(c3ccccc3)c3ccccc3-4)nc(-c3ccc4ccc5c6ccccc6ccc5c4c3)n2)cc1 ; c1ccc(-c2nc(-c3ccc4c(c3)C3(c5ccccc5-c5ccccc53)c3ccccc3-4)nc(-c3ccc4ccc5c6ccccc6ccc5c4c3)n2)cc1]

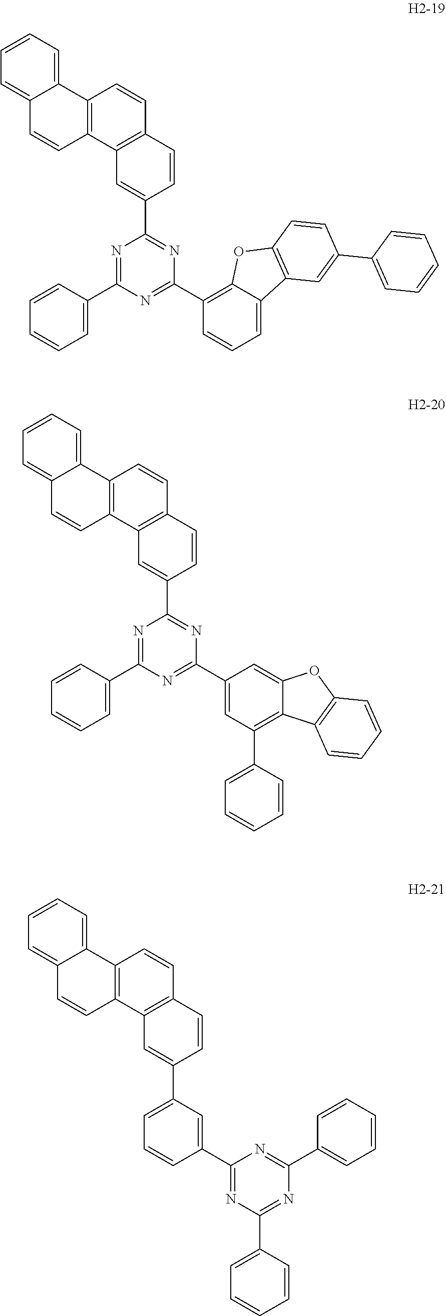 [SMILES: c1ccc(-c2ccc3oc4c(-c5nc(-c6ccccc6)nc(-c6ccc7ccc8c9ccccc9ccc8c7c6)n5)cccc4c3c2)cc1 ; c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccccc3)nc(-c3cccc(-c4ccc5ccc6c7ccccc7ccc6c5c4)c3)n2)cc1]

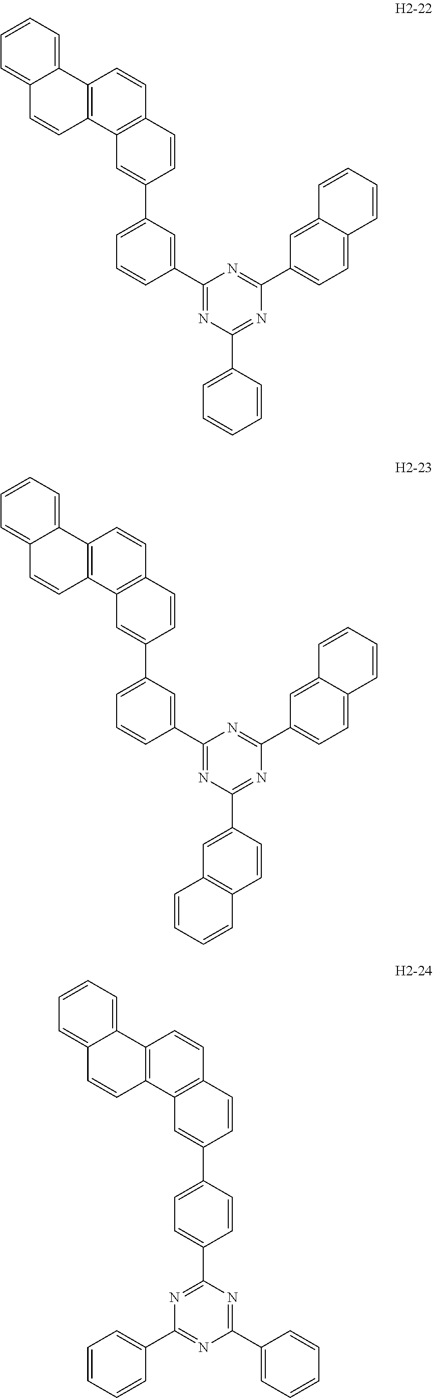 [SMILES: c1ccc(-c2nc(-c3cccc(-c4ccc5ccc6c7ccccc7ccc6c5c4)c3)nc(-c3ccc4ccccc4c3)n2)cc1 ; c1cc(-c2ccc3ccc4c5ccccc5ccc4c3c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5ccc6c7ccccc7ccc6c5c4)cc3)n2)cc1]

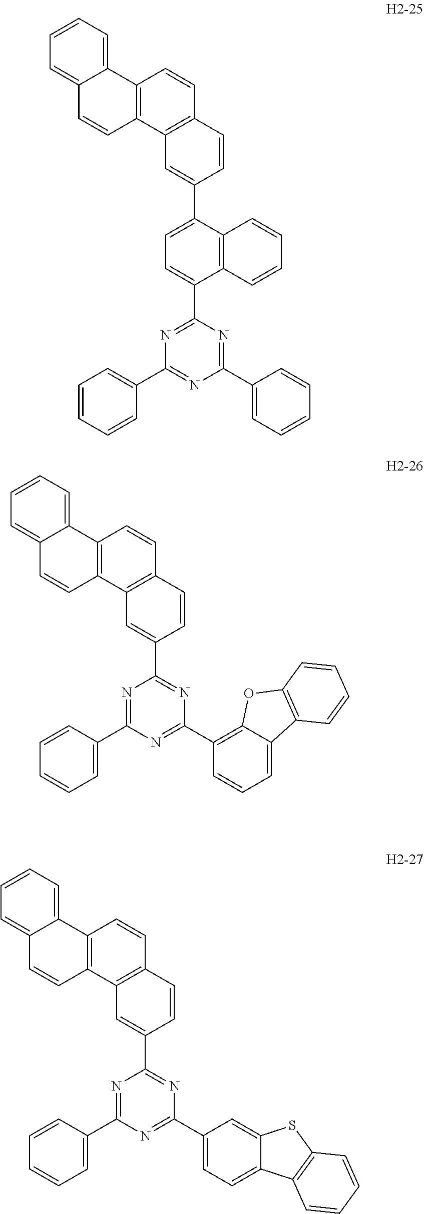 [SMILES: c1ccc(-c2nc(-c3ccccc3)nc(-c3ccc(-c4ccc5ccc6c7ccccc7ccc6c5c4)c4ccccc34)n2)cc1 ; c1ccc(-c2nc(-c3ccc4ccc5c6ccccc6ccc5c4c3)nc(-c3cccc4c3oc3ccccc34)n2)cc1 ; c1ccc(-c2nc(-c3ccc4c(c3)sc3ccccc34)nc(-c3ccc4ccc5c6ccccc6ccc5c4c3)n2)cc1]

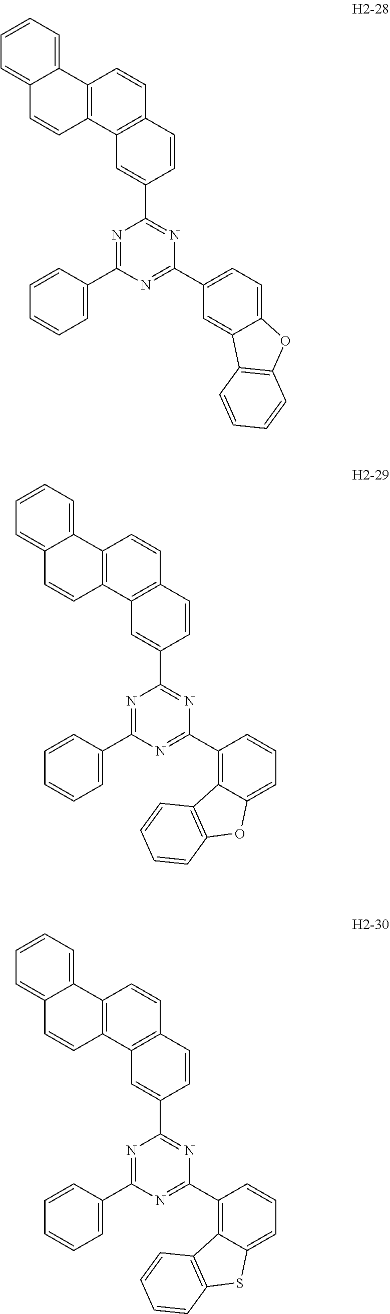 [SMILES: c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-c3cccc4sc5ccccc5c34)n2)cc1]

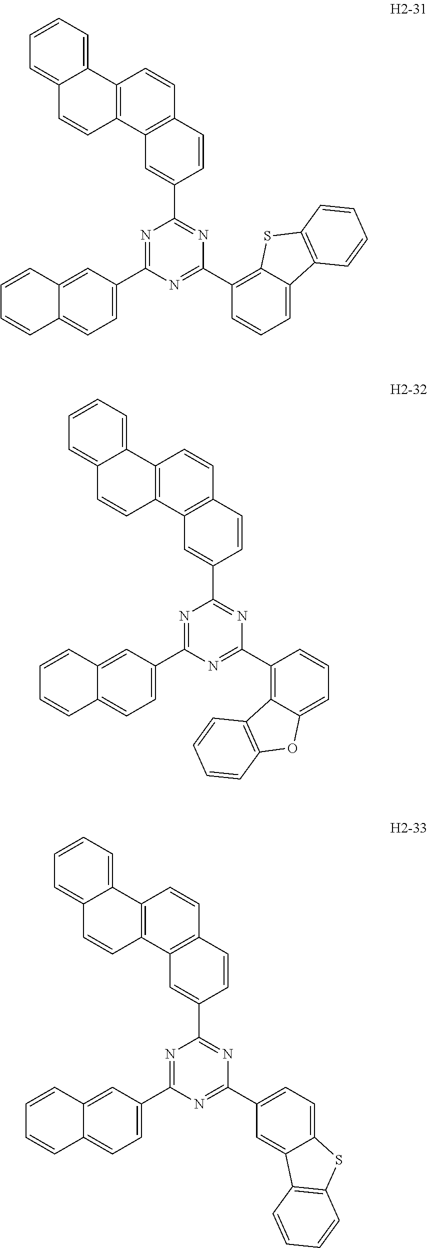 [SMILES: c1ccc2cc(-c3nc(-c4ccc5ccc6c7ccccc7ccc6c5c4)nc(-c4cccc5c4sc4ccccc45)n3)ccc2c1 ; c1ccc2cc(-c3nc(-c4ccc5ccc6c7ccccc7ccc6c5c4)nc(-c4cccc5oc6ccccc6c45)n3)ccc2c1 ; c1ccc2cc(-c3nc(-c4ccc5ccc6c7ccccc7ccc6c5c4)nc(-c4ccc5sc6ccccc6c5c4)n3)ccc2c1]

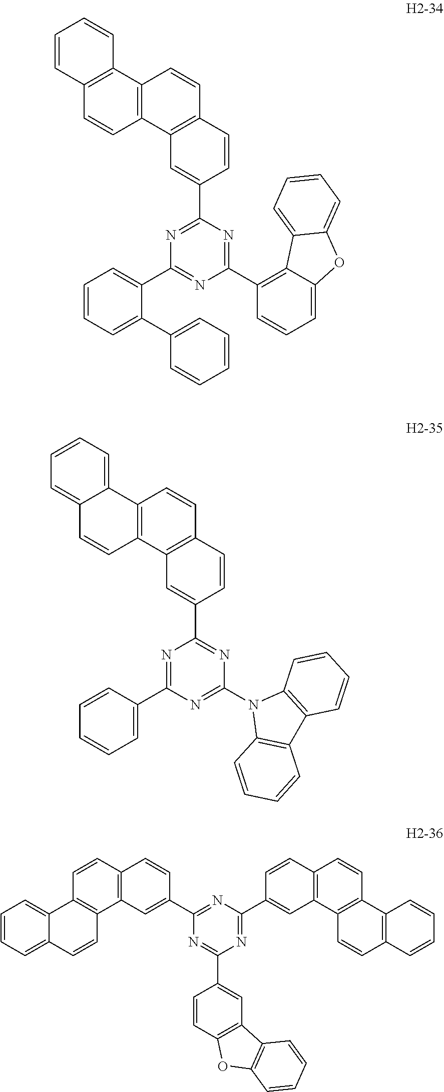 [SMILES: c1ccc(-c2ccccc2-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-n3c4ccccc4c4ccccc43)n2)cc1 ; c1ccc2c(c1)ccc1c3cc(-c4nc(-c5ccc6ccc7c8ccccc8ccc7c6c5)nc(-c5ccc6oc7ccccc7c6c5)n4)ccc3ccc21]

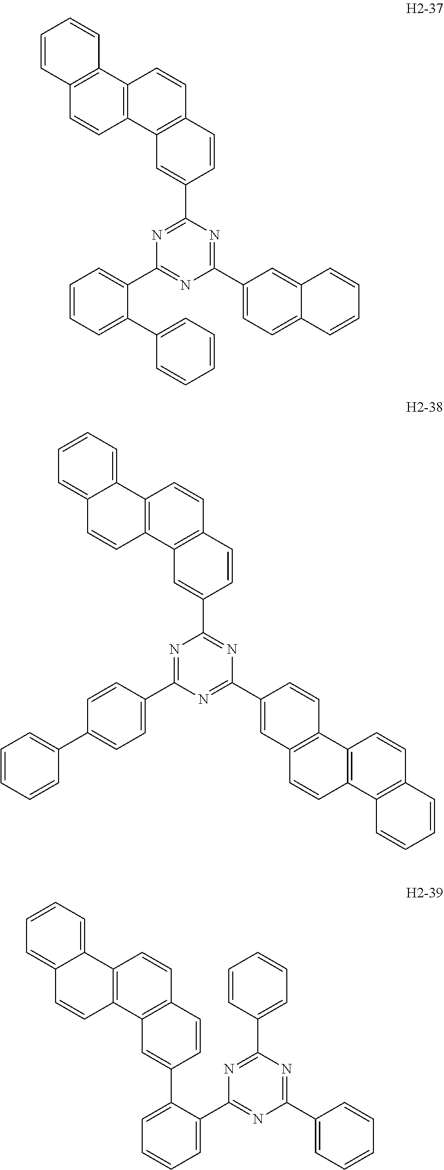 [SMILES: c1ccc(-c2ccccc2-c2nc(-c3ccc4ccccc4c3)nc(-c3ccc4ccc5c6ccccc6ccc5c4c3)n2)cc1 ; c1ccc(-c2ccc(-c3nc(-c4ccc5c(ccc6c7ccccc7ccc56)c4)nc(-c4ccc5ccc6c7ccccc7ccc6c5c4)n3)cc2)cc1 ; c1ccc(-c2nc(-c3ccccc3)nc(-c3ccccc3-c3ccc4ccc5c6ccccc6ccc5c4c3)n2)cc1]

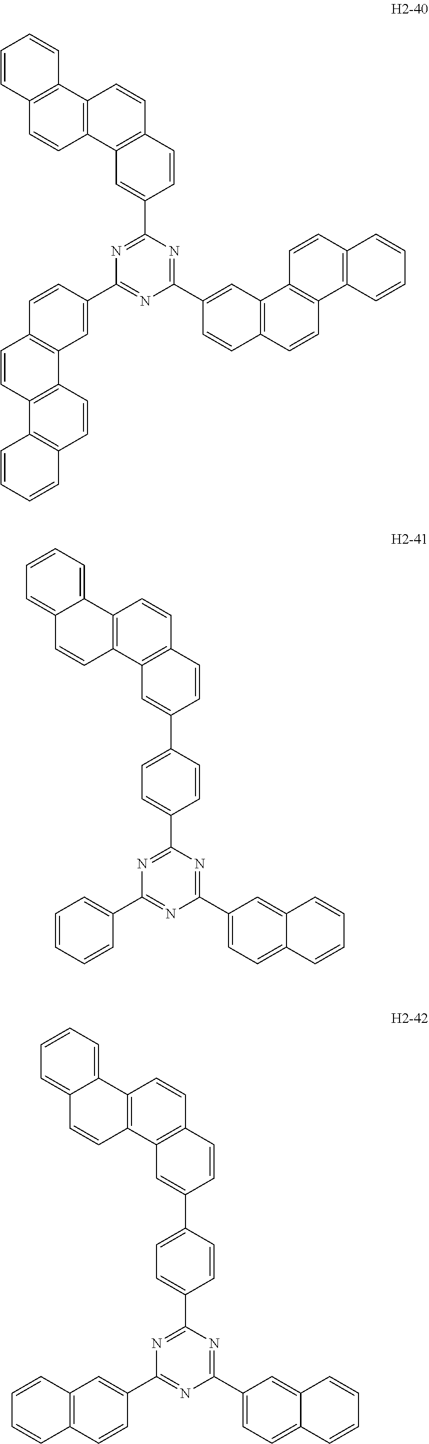 [SMILES: c1ccc2c(c1)ccc1c3cc(-c4nc(-c5ccc6ccc7c8ccccc8ccc7c6c5)nc(-c5ccc6ccc7c8ccccc8ccc7c6c5)n4)ccc3ccc21 ; c1ccc(-c2nc(-c3ccc(-c4ccc5ccc6c7ccccc7ccc6c5c4)cc3)nc(-c3ccc4ccccc4c3)n2)cc1 ; c1ccc2cc(-c3nc(-c4ccc(-c5ccc6ccc7c8ccccc8ccc7c6c5)cc4)nc(-c4ccc5ccccc5c4)n3)ccc2c1]

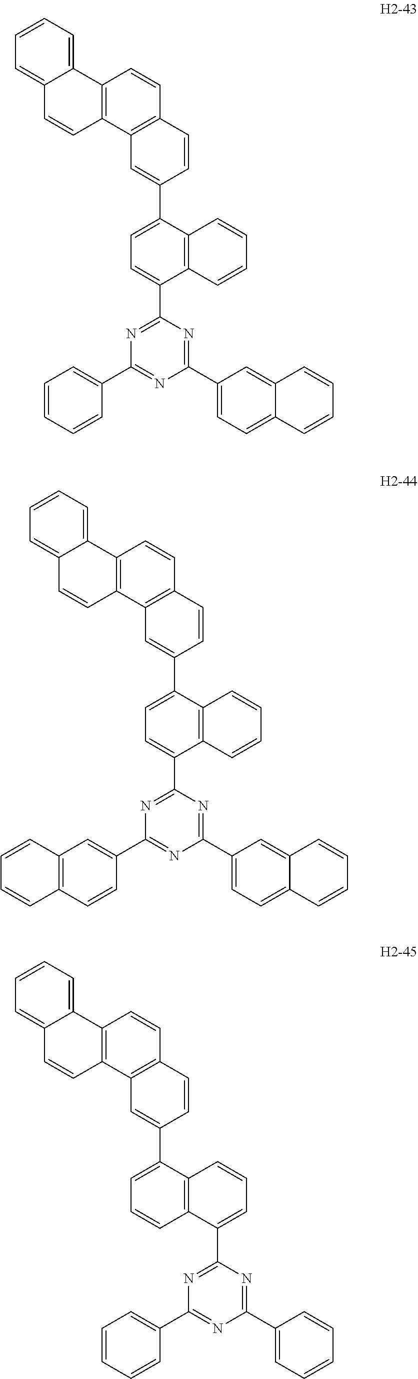 [SMILES: c1ccc(-c2nc(-c3ccc4ccccc4c3)nc(-c3ccc(-c4ccc5ccc6c7ccccc7ccc6c5c4)c4ccccc34)n2)cc1 ; c1ccc2cc(-c3nc(-c4ccc5ccccc5c4)nc(-c4ccc(-c5ccc6ccc7c8ccccc8ccc7c6c5)c5ccccc45)n3)ccc2c1 ; c1ccc(-c2nc(-c3ccccc3)nc(-c3cccc4c(-c5ccc6ccc7c8ccccc8ccc7c6c5)cccc34)n2)cc1]

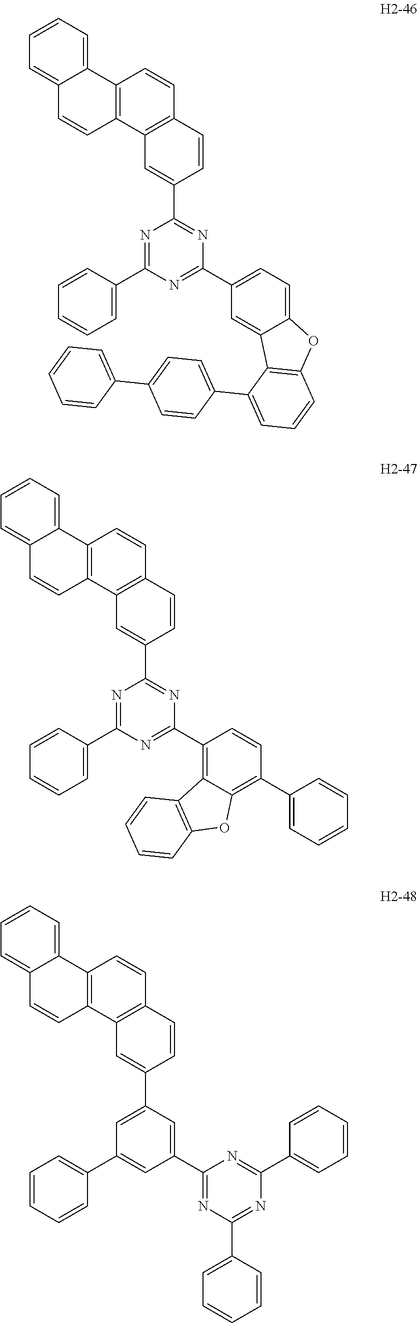 [SMILES: c1ccc(-c2ccc(-c3cccc4oc5ccc(-c6nc(-c7ccccc7)nc(-c7ccc8ccc9c%10ccccc%10ccc9c8c7)n6)cc5c34)cc2)cc1 ; c1ccc(-c2nc(-c3ccc4ccc5c6ccccc6ccc5c4c3)nc(-c3ccc(-c4ccccc4)c4oc5ccccc5c34)n2)cc1 ; c1ccc(-c2cc(-c3ccc4ccc5c6ccccc6ccc5c4c3)cc(-c3nc(-c4ccccc4)nc(-c4ccccc4)n3)c2)cc1]

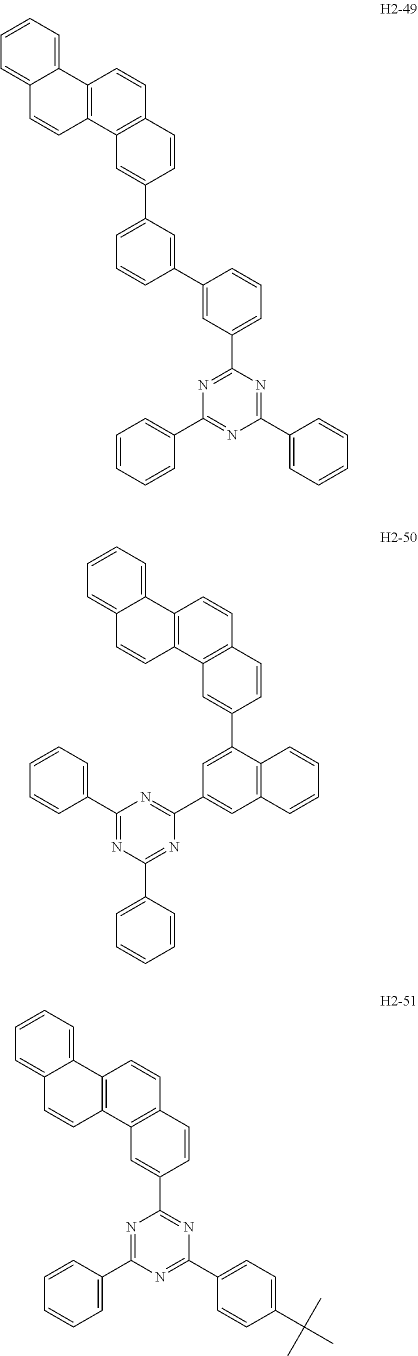 [SMILES: c1ccc(-c2nc(-c3ccccc3)nc(-c3cccc(-c4cccc(-c5ccc6ccc7c8ccccc8ccc7c6c5)c4)c3)n2)cc1 ; c1ccc(-c2nc(-c3ccccc3)nc(-c3cc(-c4ccc5ccc6c7ccccc7ccc6c5c4)c4ccccc4c3)n2)cc1 ; CC(C)(C)c1ccc(-c2nc(-c3ccccc3)nc(-c3ccc4ccc5c6ccccc6ccc5c4c3)n2)cc1]

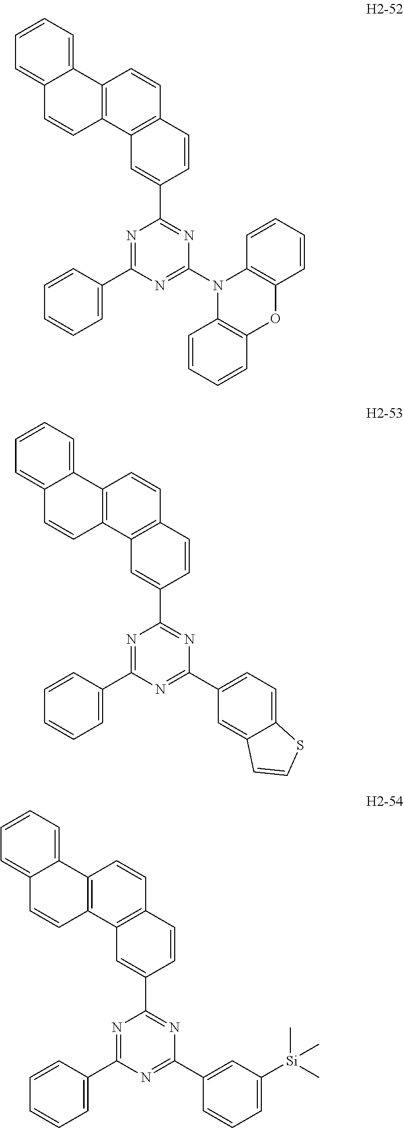 [SMILES: c1ccc(-c2nc(-c3ccc4ccc5c6ccccc6ccc5c4c3)nc(N3c4ccccc4Oc4ccccc43)n2)cc1 ; c1ccc(-c2nc(-c3ccc4sccc4c3)nc(-c3ccc4ccc5c6ccccc6ccc5c4c3)n2)cc1 ; C[Si](C)(C)c1cccc(-c2nc(-c3ccccc3)nc(-c3ccc4ccc5c6ccccc6ccc5c4c3)n2)c1]

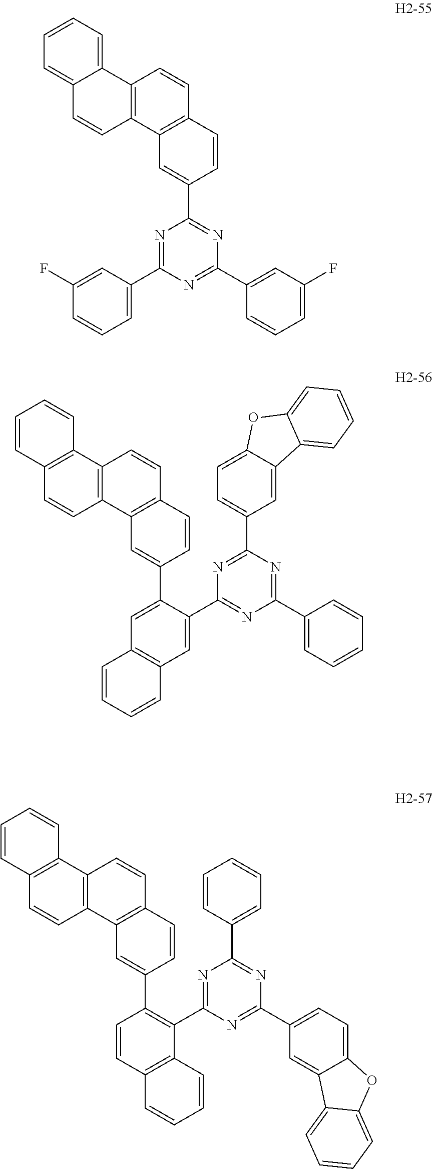 [SMILES: Fc1cccc(-c2nc(-c3cccc(F)c3)nc(-c3ccc4ccc5c6ccccc6ccc5c4c3)n2)c1 ; c1ccc(-c2nc(-c3ccc4oc5ccccc5c4c3)nc(-c3cc4ccccc4cc3-c3ccc4ccc5c6ccccc6ccc5c4c3)n2)cc1 ; c1ccc(-c2nc(-c3ccc4oc5ccccc5c4c3)nc(-c3c(-c4ccc5ccc6c7ccccc7ccc6c5c4)ccc4ccccc34)n2)cc1]

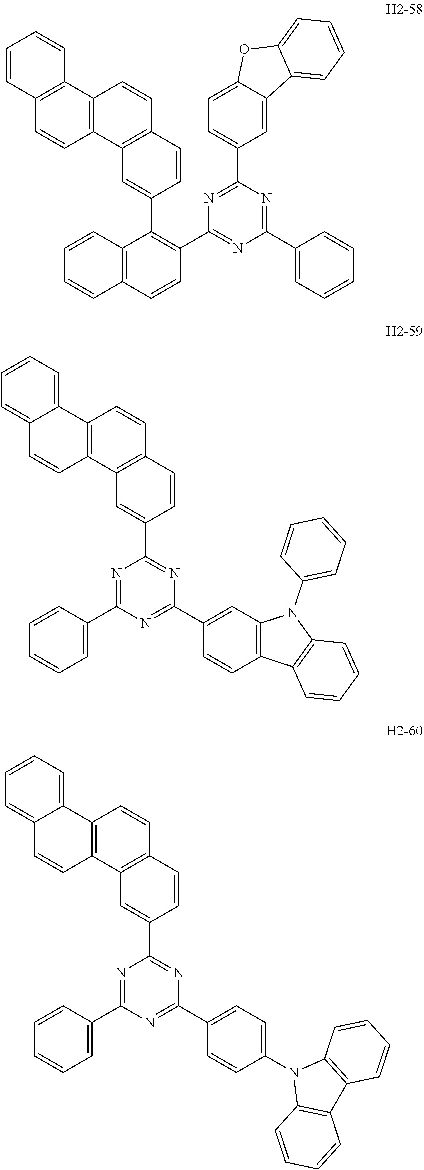 [SMILES: c1ccc(-c2nc(-c3ccc4oc5ccccc5c4c3)nc(-c3ccc4ccccc4c3-c3ccc4ccc5c6ccccc6ccc5c4c3)n2)cc1 ; c1ccc(-c2nc(-c3ccc4ccc5c6ccccc6ccc5c4c3)nc(-c3ccc4c5ccccc5n(-c5ccccc5)c4c3)n2)cc1 ; c1ccc(-c2nc(-c3ccc(-n4c5ccccc5c5ccccc54)cc3)nc(-c3ccc4ccc5c6ccccc6ccc5c4c3)n2)cc1]

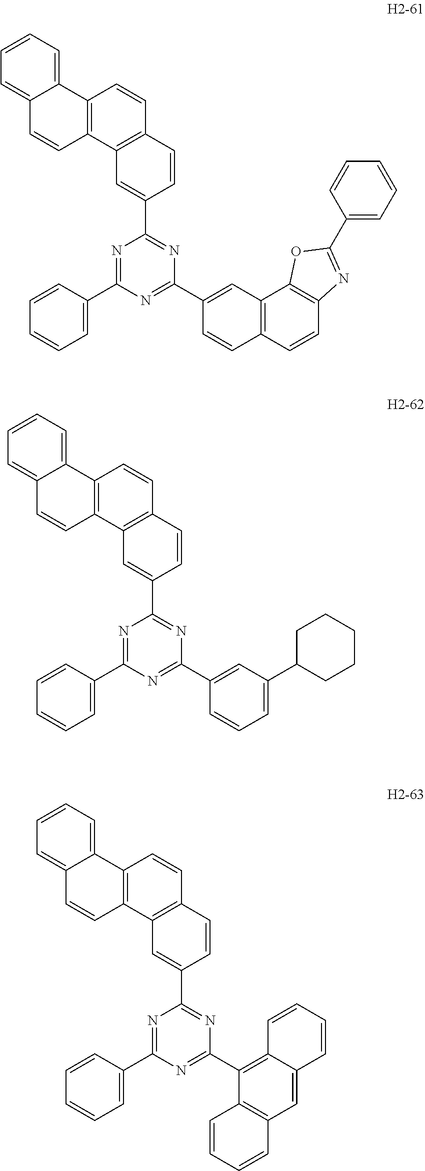 [SMILES: c1ccc(-c2nc(-c3ccc4ccc5c6ccccc6ccc5c4c3)nc(-c3ccc4ccc5nc(-c6ccccc6)oc5c4c3)n2)cc1 ; c1ccc(-c2nc(-c3cccc(C4CCCCC4)c3)nc(-c3ccc4ccc5c6ccccc6ccc5c4c3)n2)cc1 ; c1ccc(-c2nc(-c3ccc4ccc5c6ccccc6ccc5c4c3)nc(-c3c4ccccc4cc4ccccc34)n2)cc1]

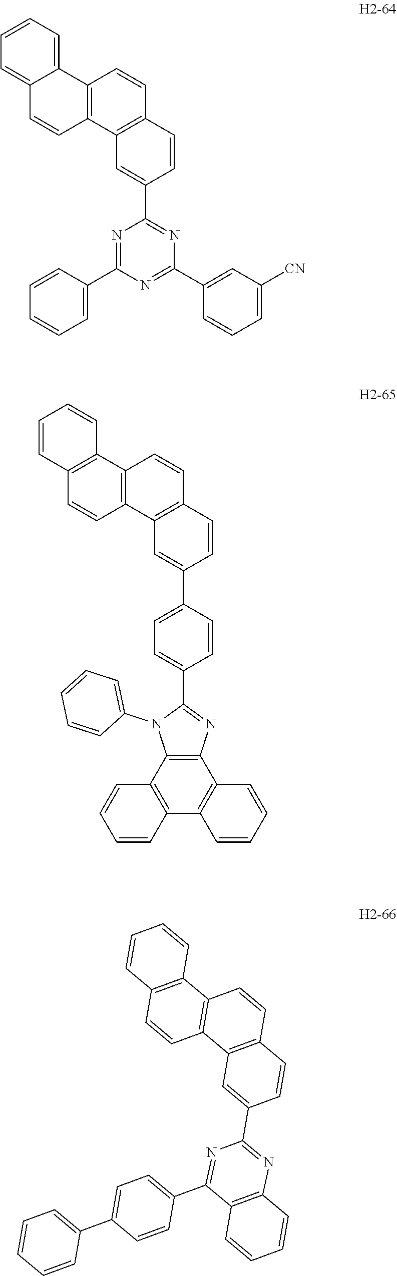 [SMILES: N#Cc1cccc(-c2nc(-c3ccccc3)nc(-c3ccc4ccc5c6ccccc6ccc5c4c3)n2)c1 ; c1ccc(-n2c(-c3ccc(-c4ccc5ccc6c7ccccc7ccc6c5c4)cc3)nc3c4ccccc4c4ccccc4c32)cc1 ; c1ccc(-c2ccc(-c3nc(-c4ccc5ccc6c7ccccc7ccc6c5c4)nc4ccccc34)cc2)cc1]

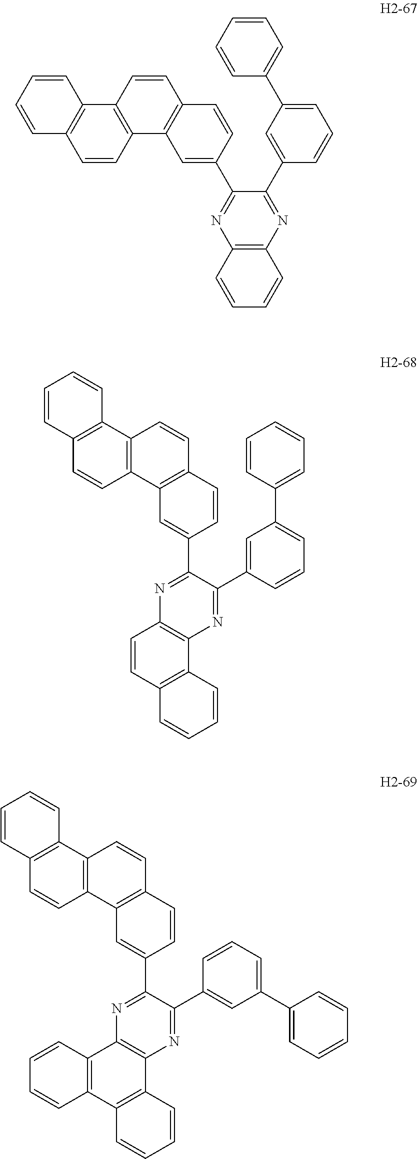 [SMILES: c1ccc(-c2cccc(-c3nc4ccccc4nc3-c3ccc4ccc5c6ccccc6ccc5c4c3)c2)cc1 ; c1ccc(-c2cccc(-c3nc4c(ccc5ccccc54)nc3-c3ccc4ccc5c6ccccc6ccc5c4c3)c2)cc1 ; c1ccc(-c2cccc(-c3nc4c5ccccc5c5ccccc5c4nc3-c3ccc4ccc5c6ccccc6ccc5c4c3)c2)cc1]

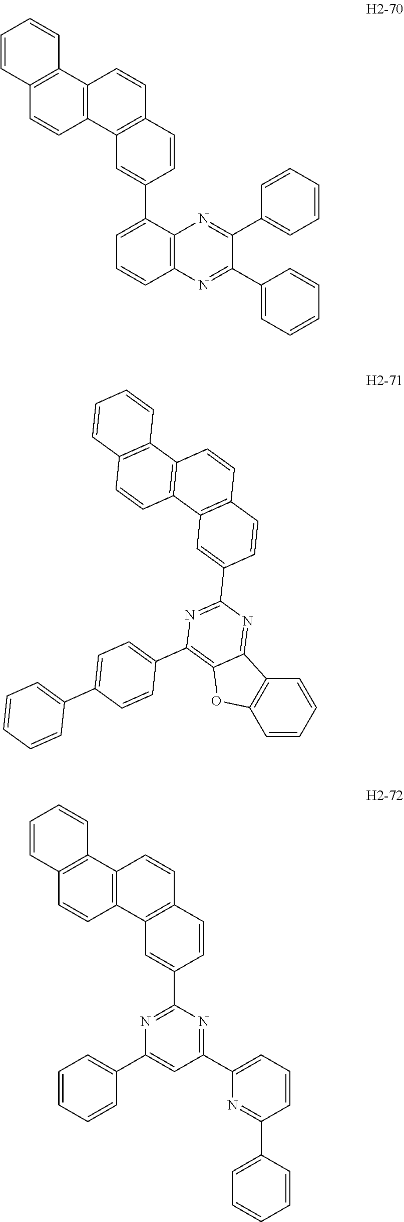 [SMILES: c1ccc(-c2nc3cccc(-c4ccc5ccc6c7ccccc7ccc6c5c4)c3nc2-c2ccccc2)cc1 ; c1ccc(-c2ccc(-c3nc(-c4ccc5ccc6c7ccccc7ccc6c5c4)nc4c3oc3ccccc34)cc2)cc1 ; c1ccc(-c2cccc(-c3cc(-c4ccccc4)nc(-c4ccc5ccc6c7ccccc7ccc6c5c4)n3)n2)cc1]

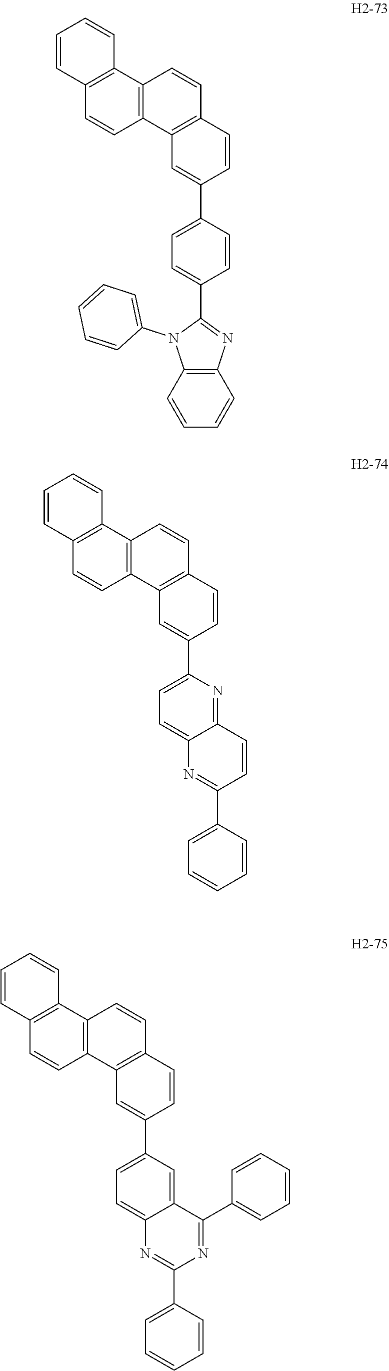 [SMILES: c1ccc(-n2c(-c3ccc(-c4ccc5ccc6c7ccccc7ccc6c5c4)cc3)nc3ccccc32)cc1 ; c1ccc(-c2ccc3nc(-c4ccc5ccc6c7ccccc7ccc6c5c4)ccc3n2)cc1 ; c1ccc(-c2nc(-c3ccccc3)c3cc(-c4ccc5ccc6c7ccccc7ccc6c5c4)ccc3n2)cc1]

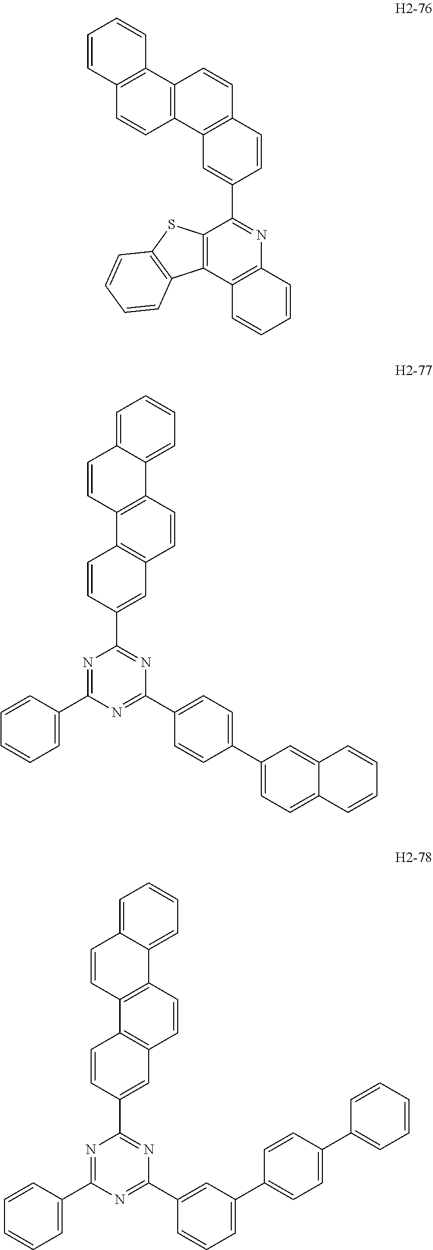

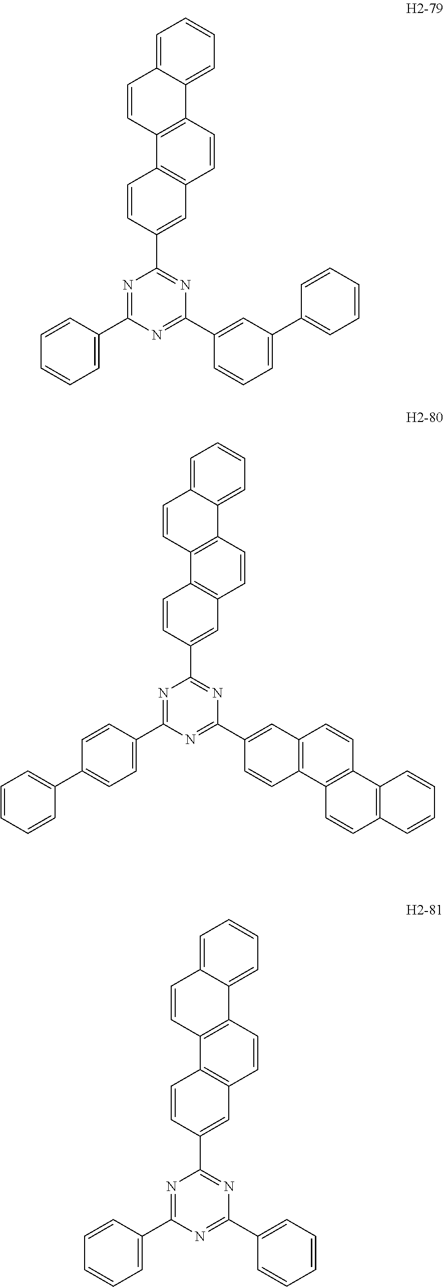 [SMILES: c1ccc(-c2cccc(-c3nc(-c4ccccc4)nc(-c4ccc5c(ccc6c7ccccc7ccc56)c4)n3)c2)cc1 ; c1ccc(-c2ccc(-c3nc(-c4ccc5c(ccc6c7ccccc7ccc56)c4)nc(-c4ccc5c(ccc6c7ccccc7ccc56)c4)n3)cc2)cc1 ; c1ccc(-c2nc(-c3ccccc3)nc(-c3ccc4c(ccc5c6ccccc6ccc45)c3)n2)cc1]

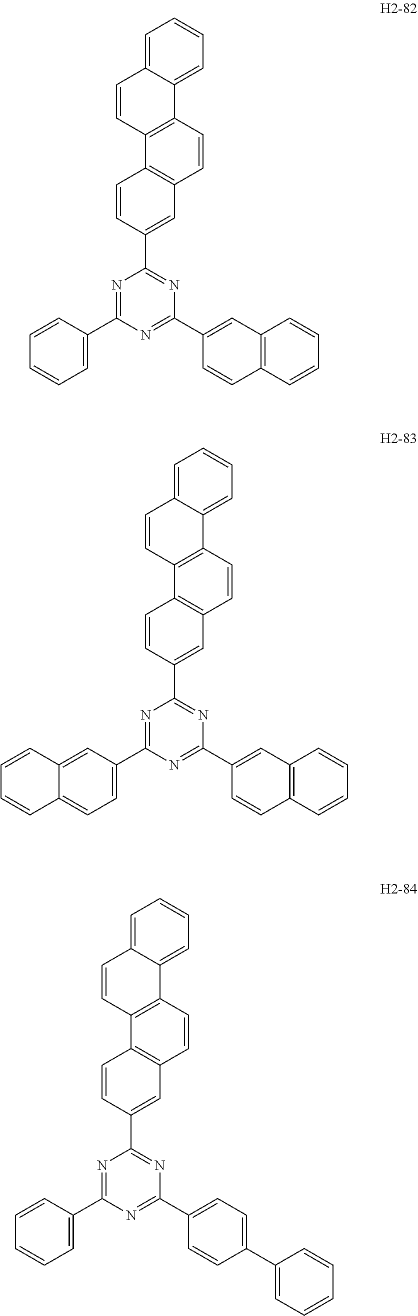 [SMILES: c1ccc(-c2nc(-c3ccc4ccccc4c3)nc(-c3ccc4c(ccc5c6ccccc6ccc45)c3)n2)cc1 ; c1ccc2cc(-c3nc(-c4ccc5ccccc5c4)nc(-c4ccc5c(ccc6c7ccccc7ccc56)c4)n3)ccc2c1 ; c1ccc(-c2ccc(-c3nc(-c4ccccc4)nc(-c4ccc5c(ccc6c7ccccc7ccc56)c4)n3)cc2)cc1]

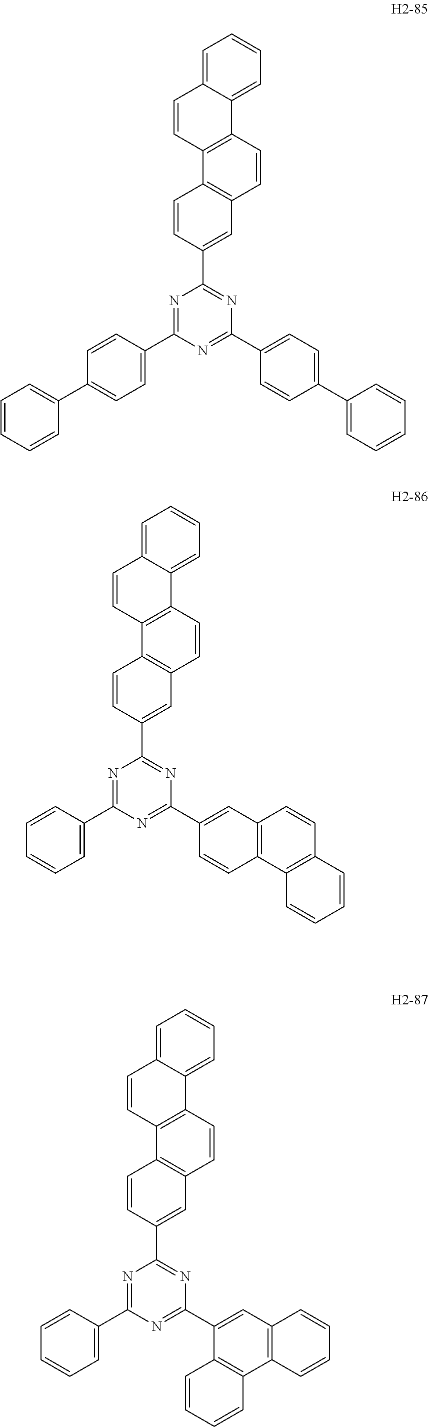 [SMILES: c1ccc(-c2ccc(-c3nc(-c4ccc(-c5ccccc5)cc4)nc(-c4ccc5c(ccc6c7ccccc7ccc56)c4)n3)cc2)cc1 ; c1ccc(-c2nc(-c3ccc4c(ccc5ccccc54)c3)nc(-c3ccc4c(ccc5c6ccccc6ccc45)c3)n2)cc1 ; c1ccc(-c2nc(-c3ccc4c(ccc5c6ccccc6ccc45)c3)nc(-c3cc4ccccc4c4ccccc34)n2)cc1]

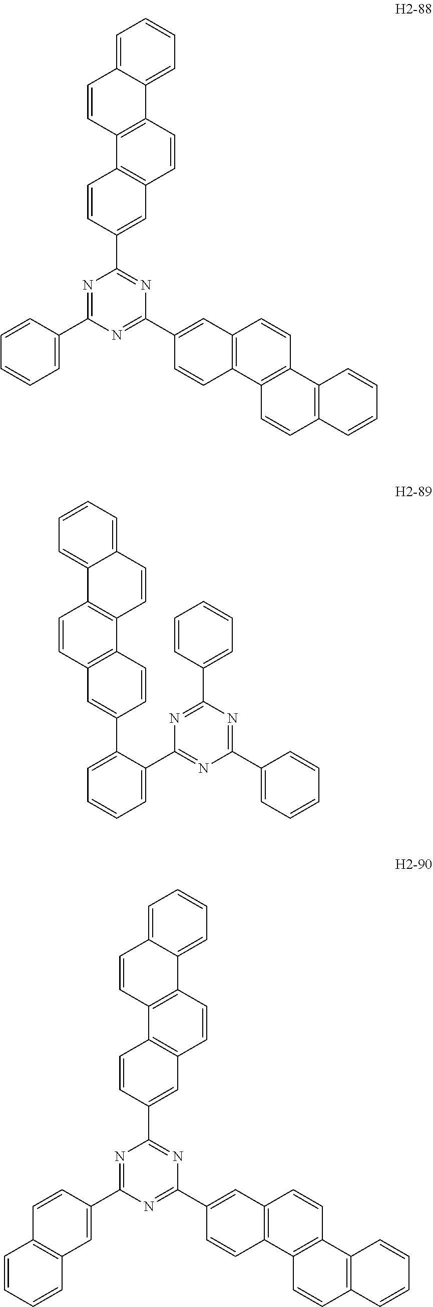 [SMILES: c1ccc(-c2nc(-c3ccc4c(ccc5c6ccccc6ccc45)c3)nc(-c3ccc4c(ccc5c6ccccc6ccc45)c3)n2)cc1 ; c1ccc(-c2nc(-c3ccccc3)nc(-c3ccccc3-c3ccc4c(ccc5c6ccccc6ccc45)c3)n2)cc1 ; c1ccc2cc(-c3nc(-c4ccc5c(ccc6c7ccccc7ccc56)c4)nc(-c4ccc5c(ccc6c7ccccc7ccc56)c4)n3)ccc2c1]

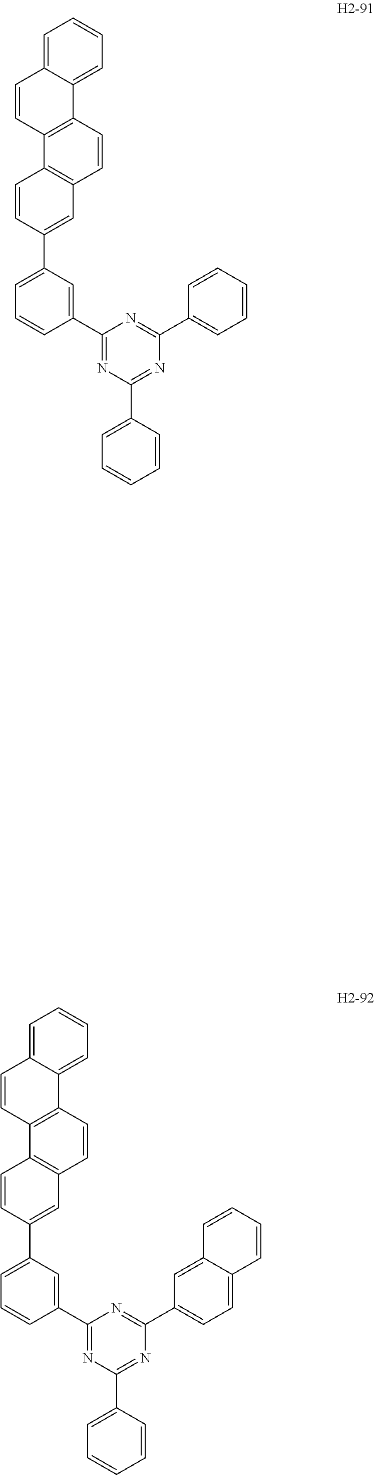 [SMILES: c1ccc(-c2nc(-c3ccccc3)nc(-c3cccc(-c4ccc5c(ccc6c7ccccc7ccc56)c4)c3)n2)cc1 ; c1ccc(-c2nc(-c3cccc(-c4ccc5c(ccc6c7ccccc7ccc56)c4)c3)nc(-c3ccc4ccccc4c3)n2)cc1]

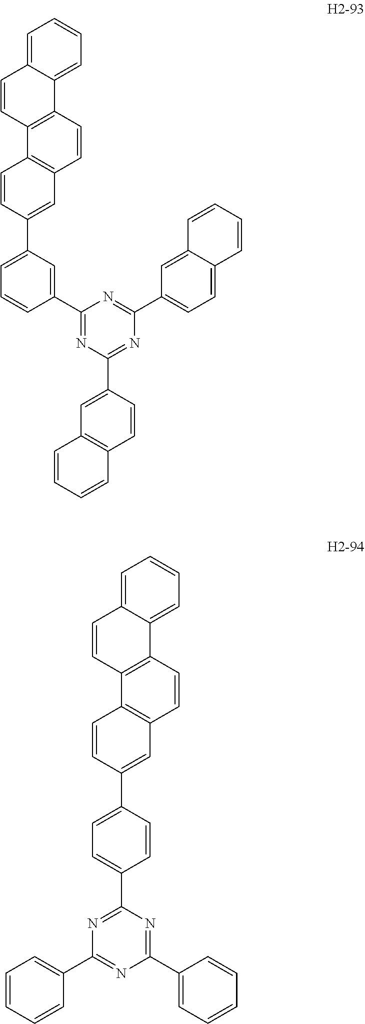 [SMILES: c1cc(-c2ccc3c(ccc4c5ccccc5ccc34)c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5c(ccc6c7ccccc7ccc56)c4)cc3)n2)cc1]

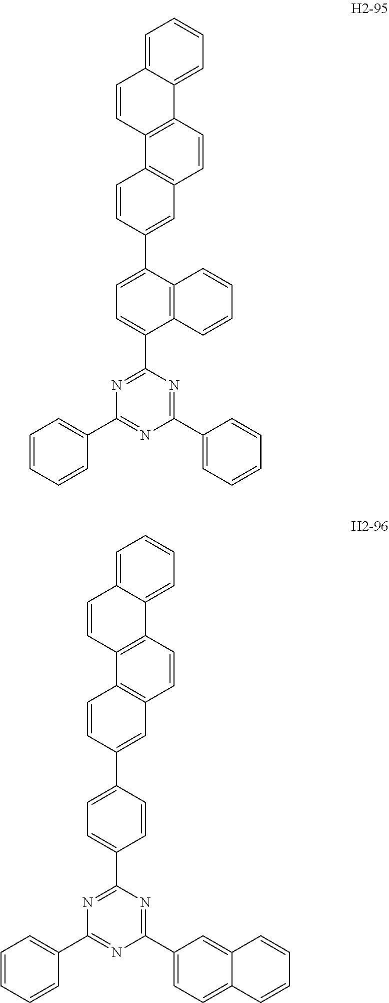 [SMILES: c1ccc(-c2nc(-c3ccccc3)nc(-c3ccc(-c4ccc5c(ccc6c7ccccc7ccc56)c4)c4ccccc34)n2)cc1 ; c1ccc(-c2nc(-c3ccc(-c4ccc5c(ccc6c7ccccc7ccc56)c4)cc3)nc(-c3ccc4ccccc4c3)n2)cc1]

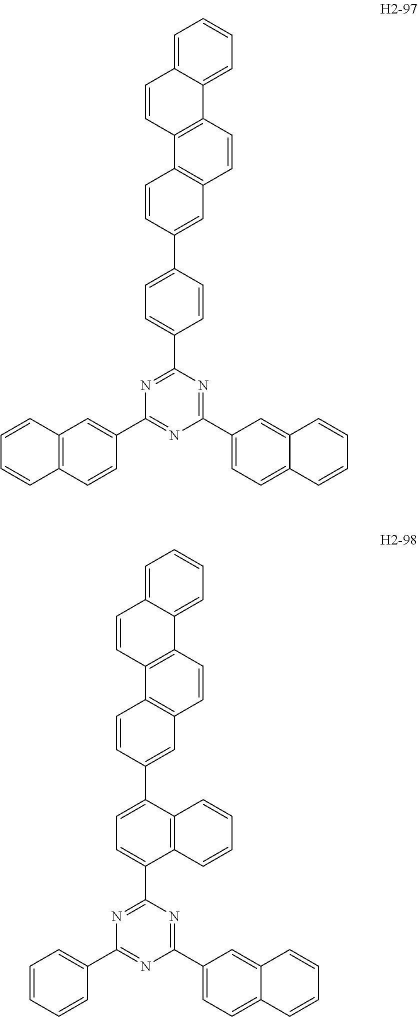 [SMILES: c1ccc2cc(-c3nc(-c4ccc(-c5ccc6c(ccc7c8ccccc8ccc67)c5)cc4)nc(-c4ccc5ccccc5c4)n3)ccc2c1 ; c1ccc(-c2nc(-c3ccc4ccccc4c3)nc(-c3ccc(-c4ccc5c(ccc6c7ccccc7ccc56)c4)c4ccccc34)n2)cc1]

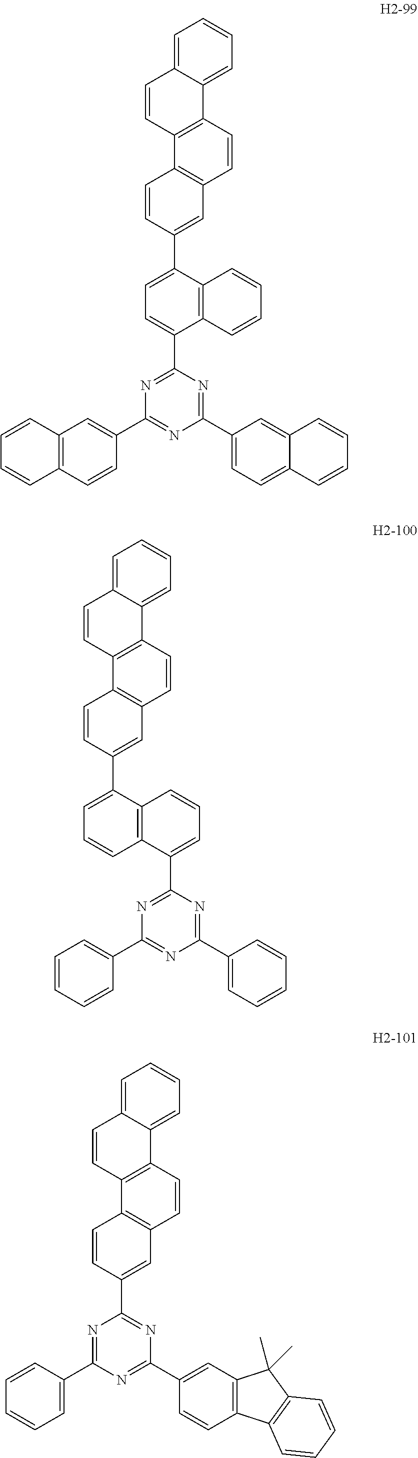 [SMILES: c1ccc2cc(-c3nc(-c4ccc5ccccc5c4)nc(-c4ccc(-c5ccc6c(ccc7c8ccccc8ccc67)c5)c5ccccc45)n3)ccc2c1 ; c1ccc(-c2nc(-c3ccccc3)nc(-c3cccc4c(-c5ccc6c(ccc7c8ccccc8ccc67)c5)cccc34)n2)cc1 ; CC1(C)c2ccccc2-c2ccc(-c3nc(-c4ccccc4)nc(-c4ccc5c(ccc6c7ccccc7ccc56)c4)n3)cc21]

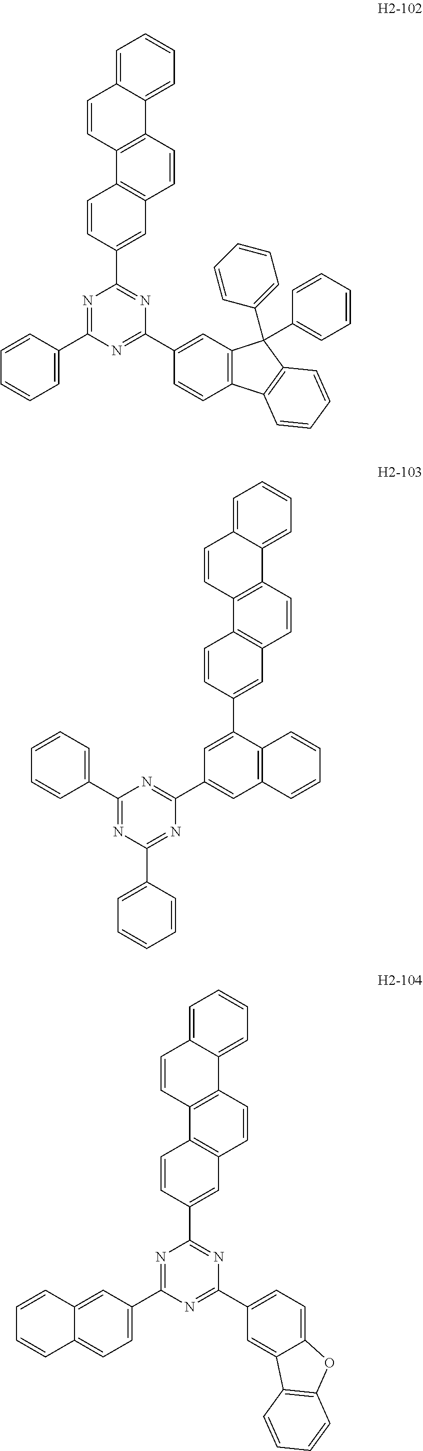 [SMILES: c1ccc(-c2nc(-c3ccc4c(c3)C(c3ccccc3)(c3ccccc3)c3ccccc3-4)nc(-c3ccc4c(ccc5c6ccccc6ccc45)c3)n2)cc1 ; c1ccc(-c2nc(-c3ccccc3)nc(-c3cc(-c4ccc5c(ccc6c7ccccc7ccc56)c4)c4ccccc4c3)n2)cc1 ; c1ccc2cc(-c3nc(-c4ccc5c(ccc6c7ccccc7ccc56)c4)nc(-c4ccc5oc6ccccc6c5c4)n3)ccc2c1]

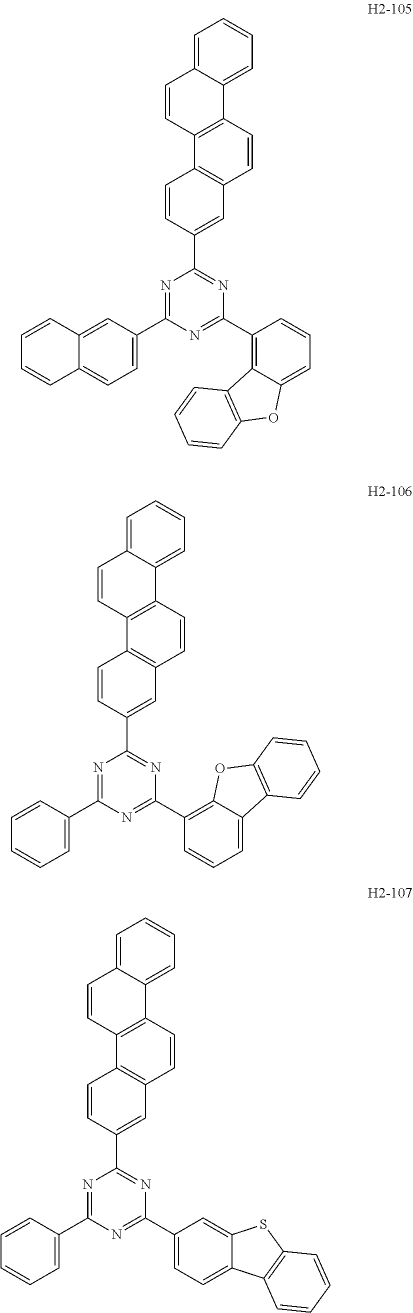 [SMILES: c1ccc2cc(-c3nc(-c4ccc5c(ccc6c7ccccc7ccc56)c4)nc(-c4cccc5oc6ccccc6c45)n3)ccc2c1 ; c1ccc(-c2nc(-c3ccc4c(ccc5c6ccccc6ccc45)c3)nc(-c3cccc4c3oc3ccccc34)n2)cc1 ; c1ccc(-c2nc(-c3ccc4c(ccc5c6ccccc6ccc45)c3)nc(-c3ccc4c(c3)sc3ccccc34)n2)cc1]

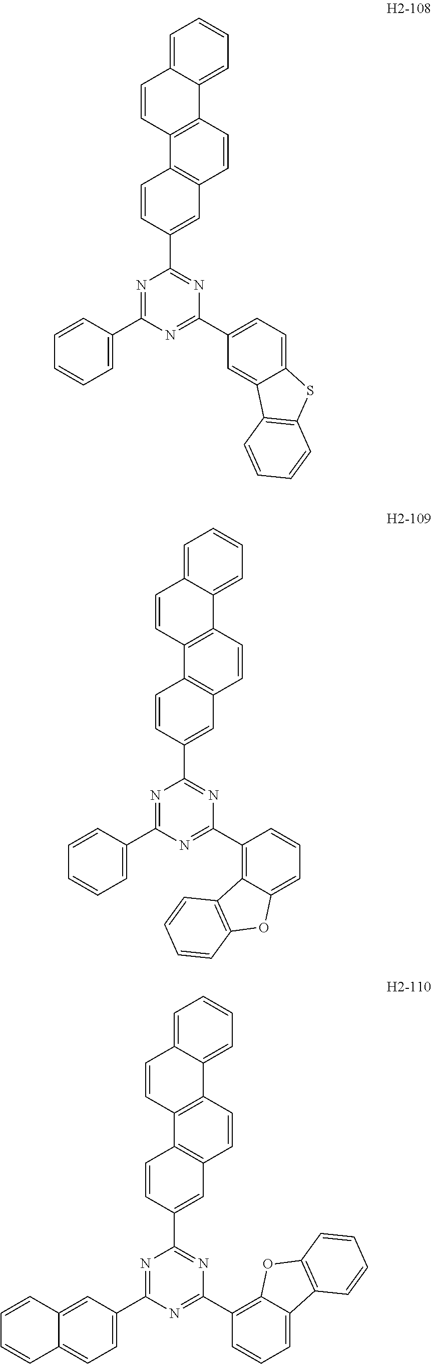

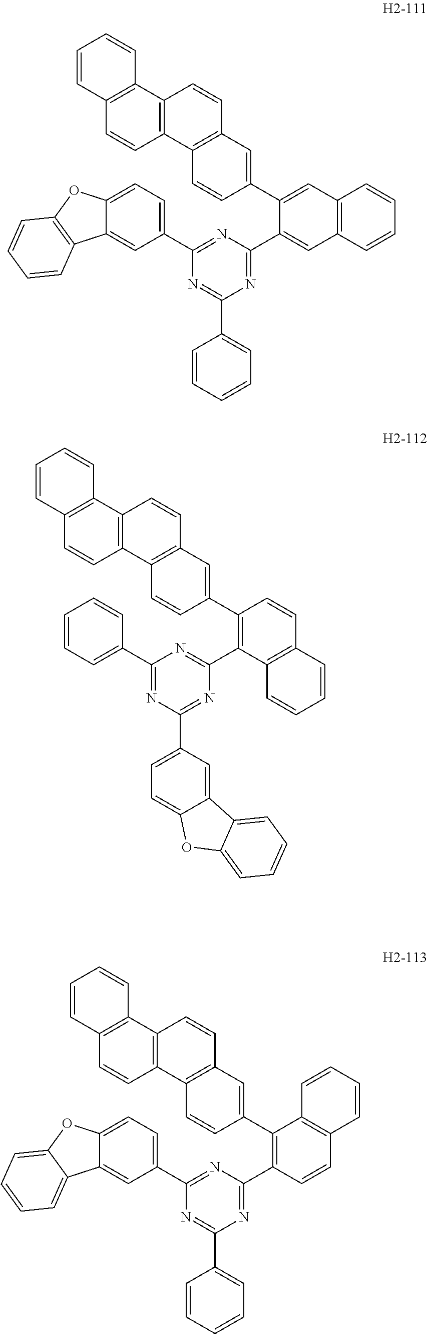 [SMILES: c1ccc(-c2nc(-c3ccc4oc5ccccc5c4c3)nc(-c3cc4ccccc4cc3-c3ccc4c(ccc5c6ccccc6ccc45)c3)n2)cc1 ; c1ccc(-c2nc(-c3ccc4oc5ccccc5c4c3)nc(-c3c(-c4ccc5c(ccc6c7ccccc7ccc56)c4)ccc4ccccc34)n2)cc1 ; c1ccc(-c2nc(-c3ccc4oc5ccccc5c4c3)nc(-c3ccc4ccccc4c3-c3ccc4c(ccc5c6ccccc6ccc45)c3)n2)cc1]

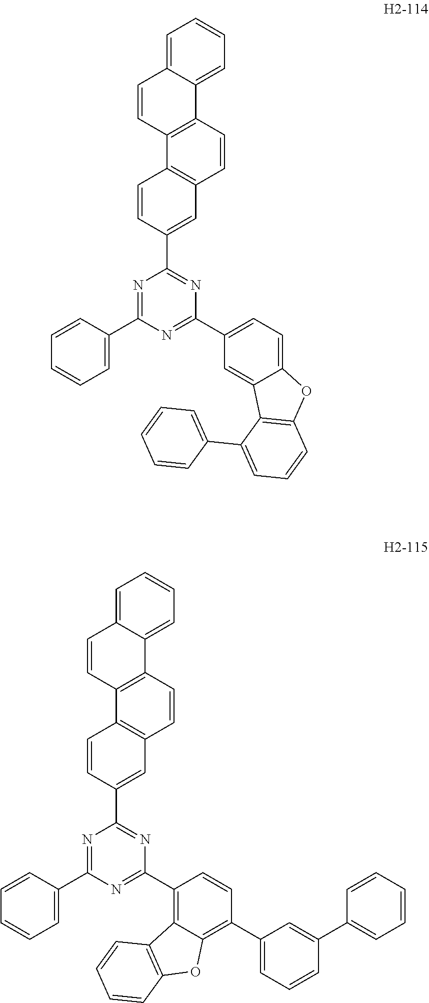 [SMILES: c1ccc(-c2nc(-c3ccc4c(ccc5c6ccccc6ccc45)c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6c(ccc7c8ccccc8ccc67)c5)n4)c4c3oc3ccccc34)c2)cc1]

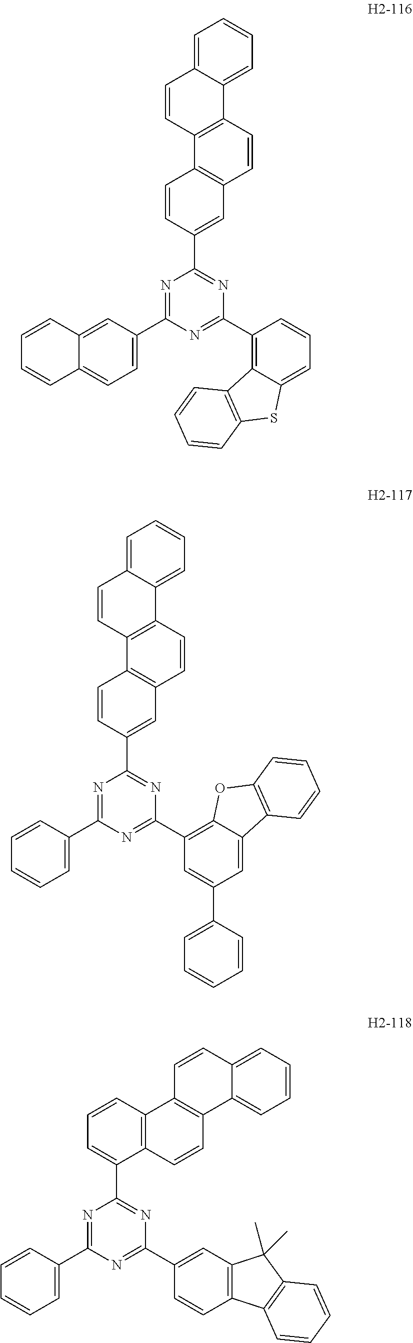 [SMILES: c1ccc2cc(-c3nc(-c4ccc5c(ccc6c7ccccc7ccc56)c4)nc(-c4cccc5sc6ccccc6c45)n3)ccc2c1 ; c1ccc(-c2cc(-c3nc(-c4ccccc4)nc(-c4ccc5c(ccc6c7ccccc7ccc56)c4)n3)c3oc4ccccc4c3c2)cc1 ; CC1(C)c2ccccc2-c2ccc(-c3nc(-c4ccccc4)nc(-c4cccc5c4ccc4c6ccccc6ccc54)n3)cc21]

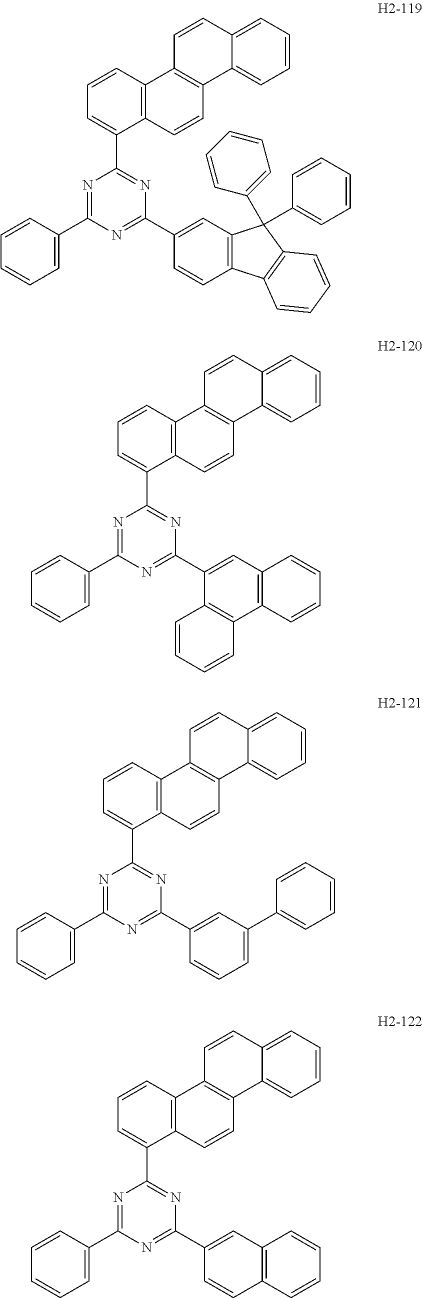

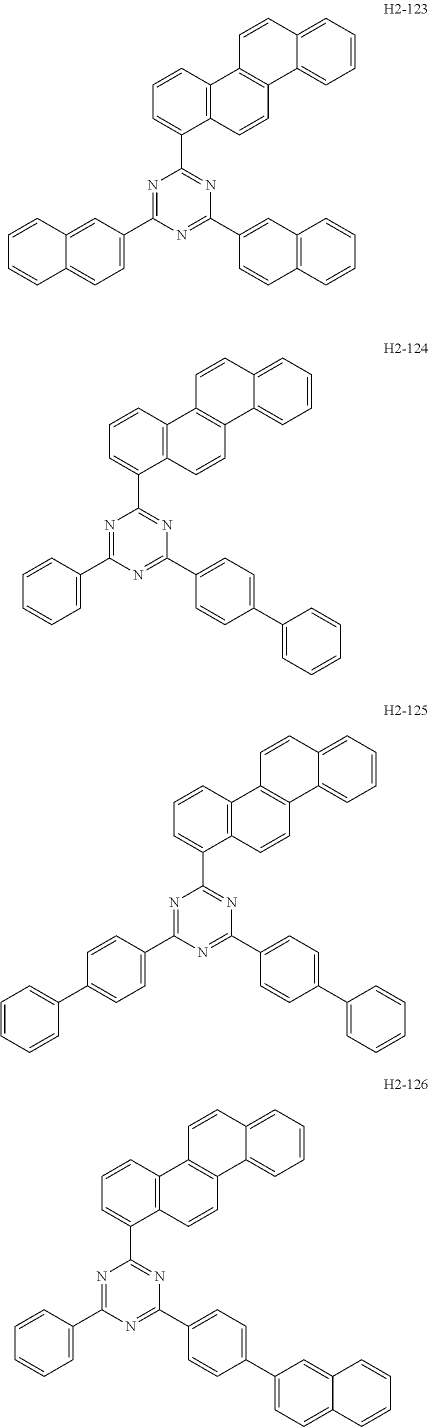 [SMILES: c1ccc2cc(-c3nc(-c4ccc5ccccc5c4)nc(-c4cccc5c4ccc4c6ccccc6ccc54)n3)ccc2c1 ; c1ccc(-c2ccc(-c3nc(-c4ccccc4)nc(-c4cccc5c4ccc4c6ccccc6ccc54)n3)cc2)cc1 ; c1ccc(-c2ccc(-c3nc(-c4ccc(-c5ccccc5)cc4)nc(-c4cccc5c4ccc4c6ccccc6ccc54)n3)cc2)cc1 ; c1ccc(-c2nc(-c3ccc(-c4ccc5ccccc5c4)cc3)nc(-c3cccc4c3ccc3c5ccccc5ccc43)n2)cc1]

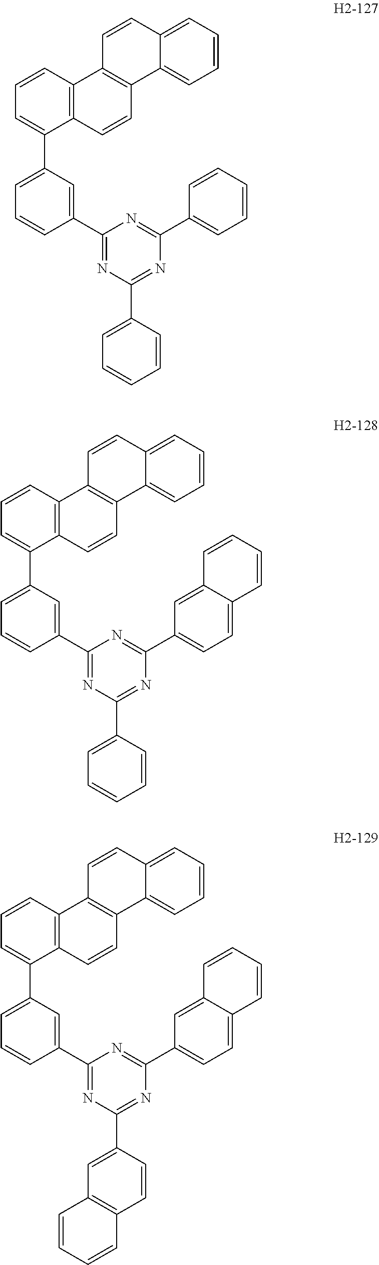

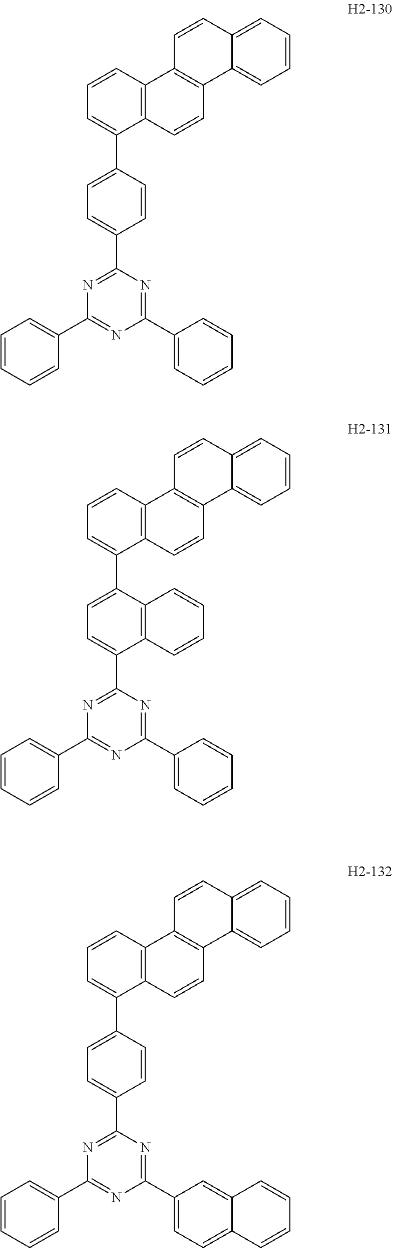 [SMILES: c1ccc(-c2nc(-c3ccccc3)nc(-c3ccc(-c4cccc5c4ccc4c6ccccc6ccc54)cc3)n2)cc1 ; c1ccc(-c2nc(-c3ccccc3)nc(-c3ccc(-c4cccc5c4ccc4c6ccccc6ccc54)c4ccccc34)n2)cc1 ; c1ccc(-c2nc(-c3ccc(-c4cccc5c4ccc4c6ccccc6ccc54)cc3)nc(-c3ccc4ccccc4c3)n2)cc1]

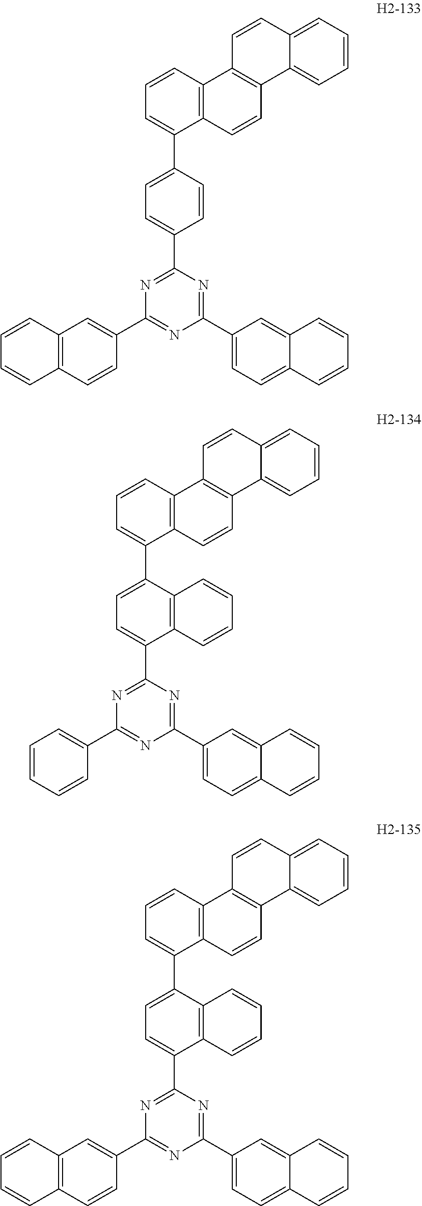 [SMILES: c1ccc2cc(-c3nc(-c4ccc(-c5cccc6c5ccc5c7ccccc7ccc65)cc4)nc(-c4ccc5ccccc5c4)n3)ccc2c1 ; c1ccc(-c2nc(-c3ccc4ccccc4c3)nc(-c3ccc(-c4cccc5c4ccc4c6ccccc6ccc54)c4ccccc34)n2)cc1 ; c1ccc2cc(-c3nc(-c4ccc5ccccc5c4)nc(-c4ccc(-c5cccc6c5ccc5c7ccccc7ccc65)c5ccccc45)n3)ccc2c1]

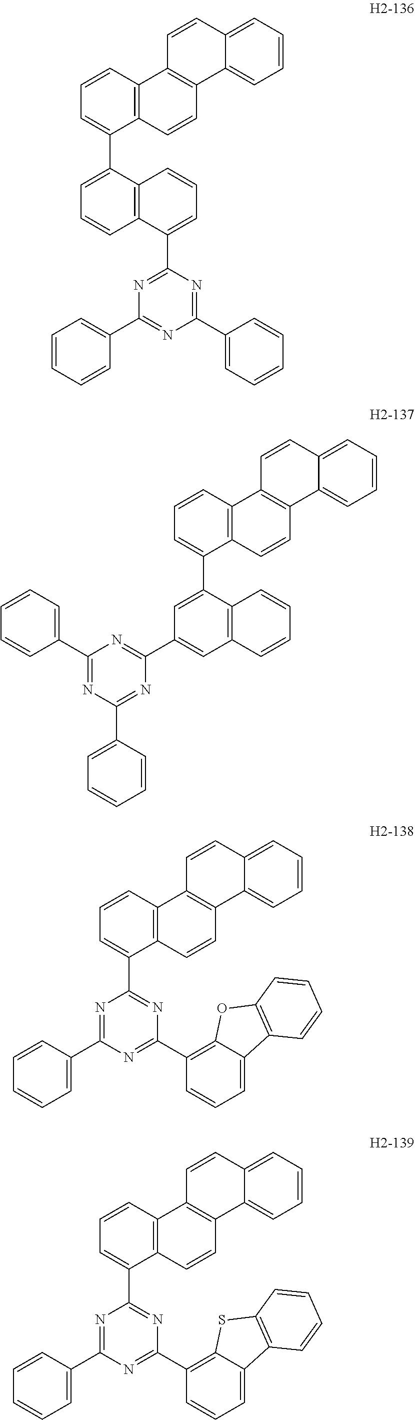

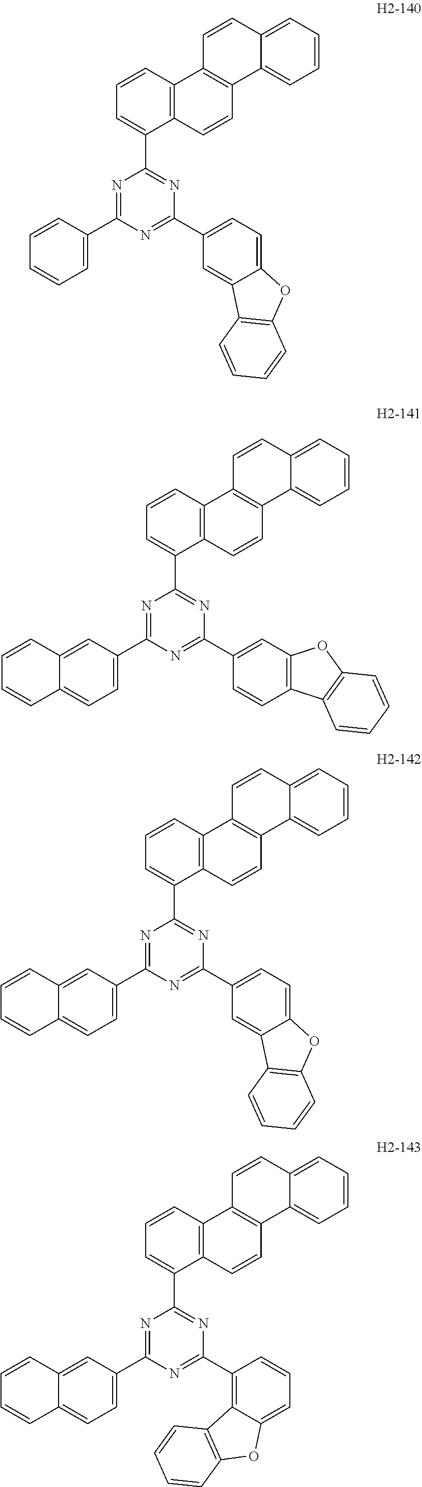

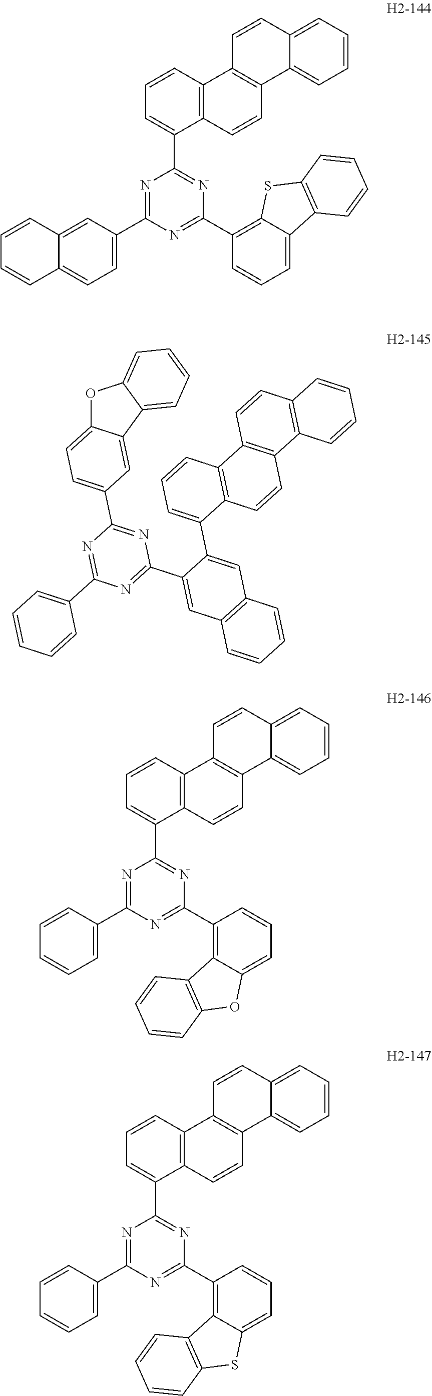 [SMILES: c1ccc2cc(-c3nc(-c4cccc5c4ccc4c6ccccc6ccc54)nc(-c4cccc5c4sc4ccccc45)n3)ccc2c1 ; c1ccc(-c2nc(-c3ccc4oc5ccccc5c4c3)nc(-c3cc4ccccc4cc3-c3cccc4c3ccc3c5ccccc5ccc43)n2)cc1 ; c1ccc(-c2nc(-c3cccc4c3ccc3c5ccccc5ccc43)nc(-c3cccc4oc5ccccc5c34)n2)cc1 ; c1ccc(-c2nc(-c3cccc4c3ccc3c5ccccc5ccc43)nc(-c3cccc4sc5ccccc5c34)n2)cc1]

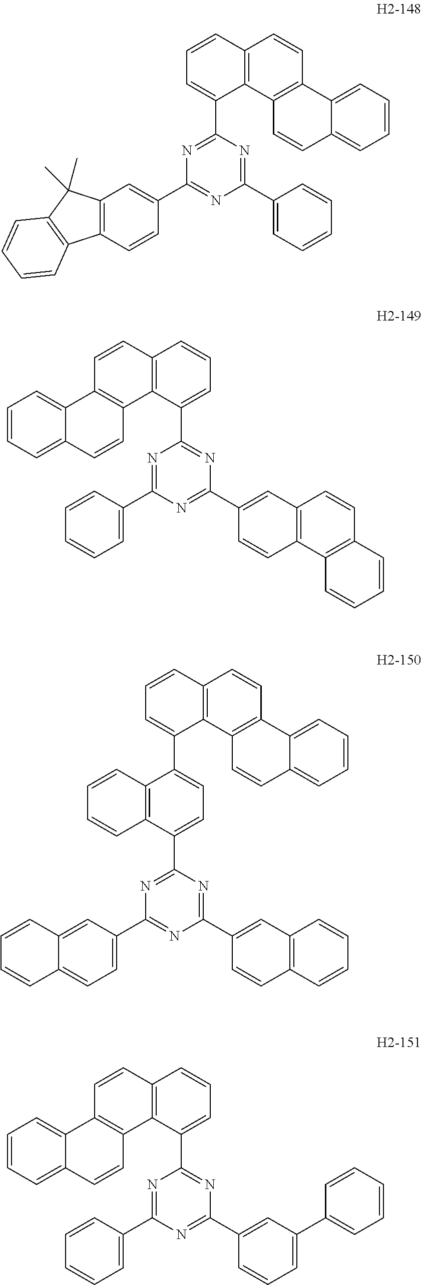 [SMILES: CC1(C)c2ccccc2-c2ccc(-c3nc(-c4ccccc4)nc(-c4cccc5ccc6c7ccccc7ccc6c45)n3)cc21 ; c1ccc(-c2nc(-c3ccc4c(ccc5ccccc54)c3)nc(-c3cccc4ccc5c6ccccc6ccc5c34)n2)cc1 ; c1ccc2cc(-c3nc(-c4ccc5ccccc5c4)nc(-c4ccc(-c5cccc6ccc7c8ccccc8ccc7c56)c5ccccc45)n3)ccc2c1 ; c1ccc(-c2cccc(-c3nc(-c4ccccc4)nc(-c4cccc5ccc6c7ccccc7ccc6c45)n3)c2)cc1]

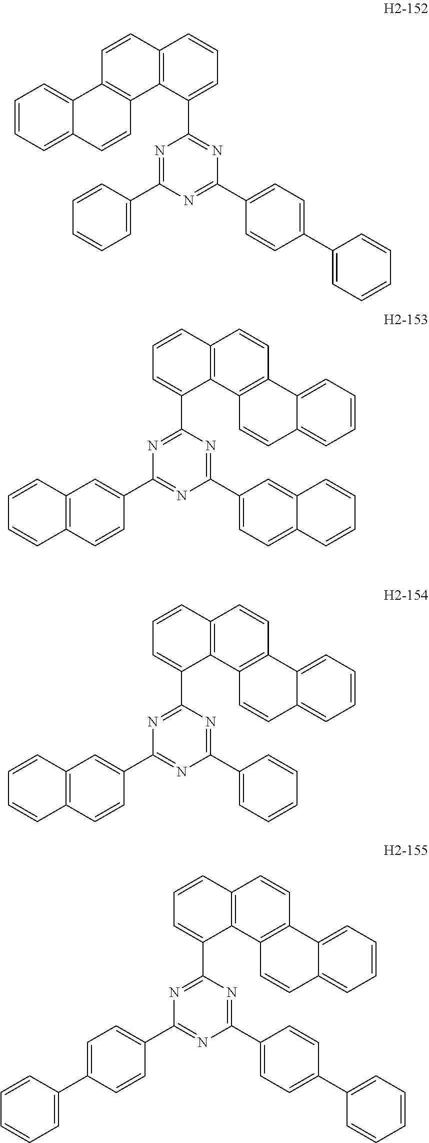 [SMILES: c1ccc(-c2ccc(-c3nc(-c4ccccc4)nc(-c4cccc5ccc6c7ccccc7ccc6c45)n3)cc2)cc1 ; c1ccc2cc(-c3nc(-c4ccc5ccccc5c4)nc(-c4cccc5ccc6c7ccccc7ccc6c45)n3)ccc2c1 ; c1ccc(-c2nc(-c3ccc4ccccc4c3)nc(-c3cccc4ccc5c6ccccc6ccc5c34)n2)cc1 ; c1ccc(-c2ccc(-c3nc(-c4ccc(-c5ccccc5)cc4)nc(-c4cccc5ccc6c7ccccc7ccc6c45)n3)cc2)cc1]

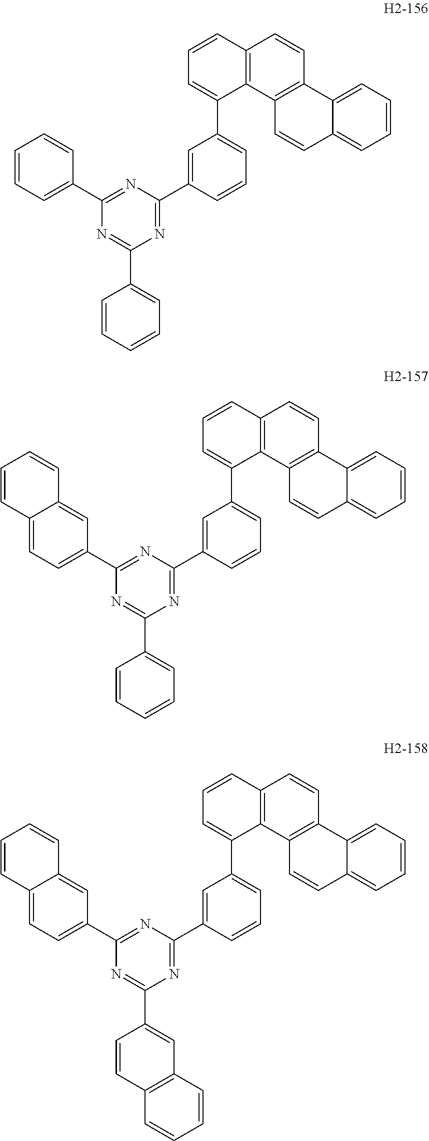 [SMILES: c1ccc(-c2nc(-c3ccccc3)nc(-c3cccc(-c4cccc5ccc6c7ccccc7ccc6c45)c3)n2)cc1 ; c1ccc(-c2nc(-c3cccc(-c4cccc5ccc6c7ccccc7ccc6c45)c3)nc(-c3ccc4ccccc4c3)n2)cc1 ; c1cc(-c2nc(-c3ccc4ccccc4c3)nc(-c3ccc4ccccc4c3)n2)cc(-c2cccc3ccc4c5ccccc5ccc4c23)c1]

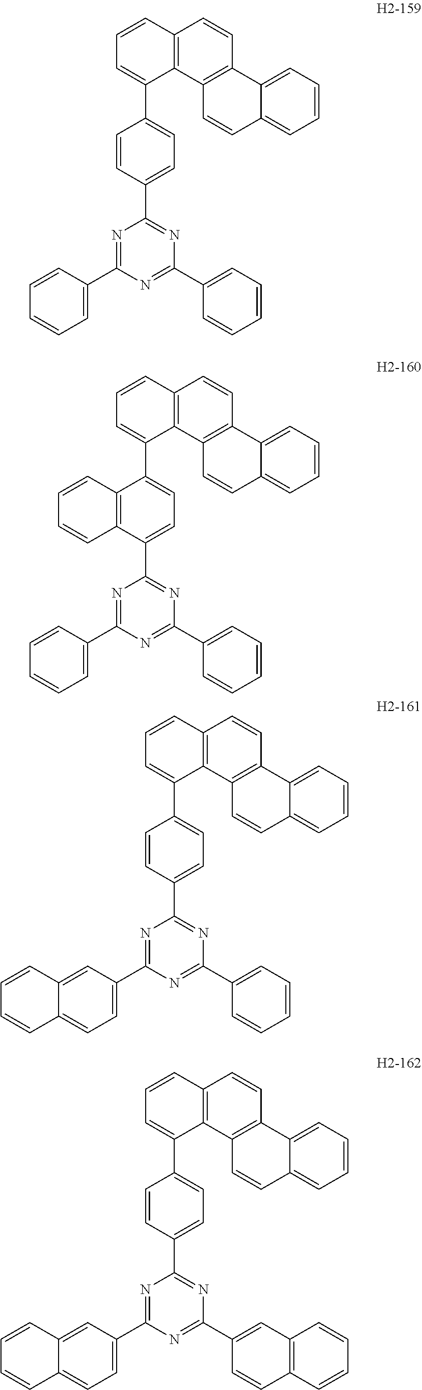

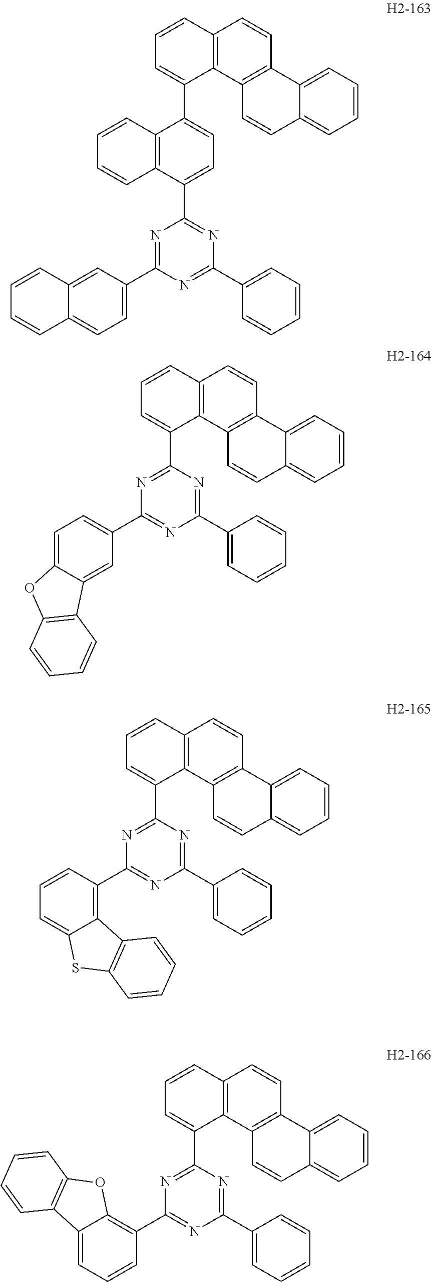 [SMILES: c1ccc(-c2nc(-c3ccc4ccccc4c3)nc(-c3ccc(-c4cccc5ccc6c7ccccc7ccc6c45)c4ccccc34)n2)cc1 ; c1ccc(-c2nc(-c3ccc4oc5ccccc5c4c3)nc(-c3cccc4ccc5c6ccccc6ccc5c34)n2)cc1 ; c1ccc(-c2nc(-c3cccc4ccc5c6ccccc6ccc5c34)nc(-c3cccc4sc5ccccc5c34)n2)cc1 ; c1ccc(-c2nc(-c3cccc4c3oc3ccccc34)nc(-c3cccc4ccc5c6ccccc6ccc5c34)n2)cc1]

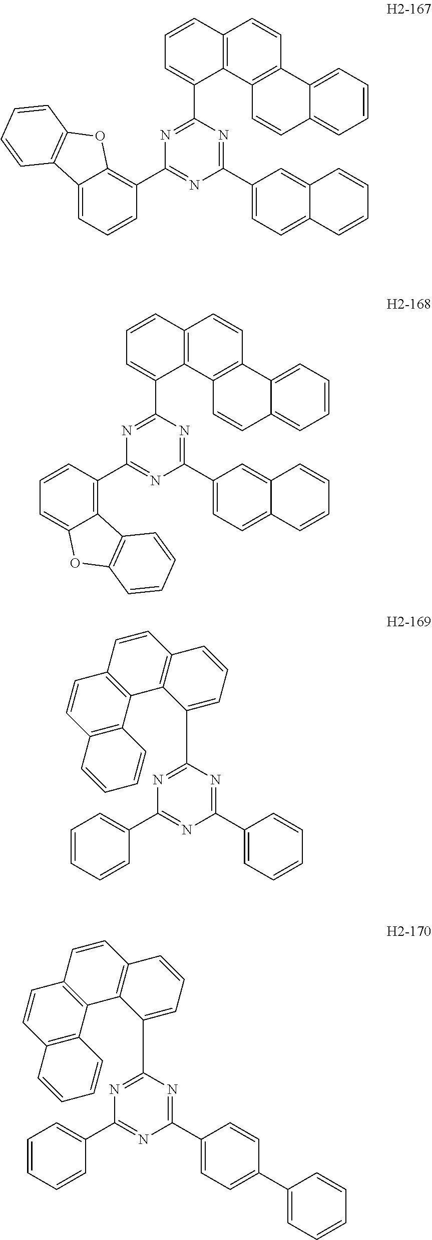

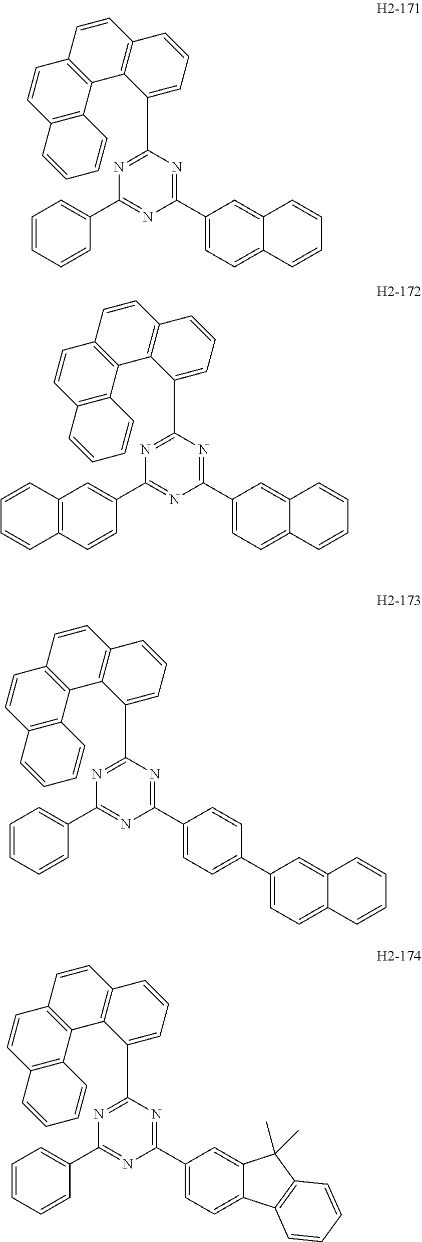 [SMILES: c1ccc(-c2nc(-c3ccc4ccccc4c3)nc(-c3cccc4ccc5ccc6ccccc6c5c34)n2)cc1 ; c1ccc2cc(-c3nc(-c4ccc5ccccc5c4)nc(-c4cccc5ccc6ccc7ccccc7c6c45)n3)ccc2c1 ; c1ccc(-c2nc(-c3ccc(-c4ccc5ccccc5c4)cc3)nc(-c3cccc4ccc5ccc6ccccc6c5c34)n2)cc1 ; CC1(C)c2ccccc2-c2ccc(-c3nc(-c4ccccc4)nc(-c4cccc5ccc6ccc7ccccc7c6c45)n3)cc21]

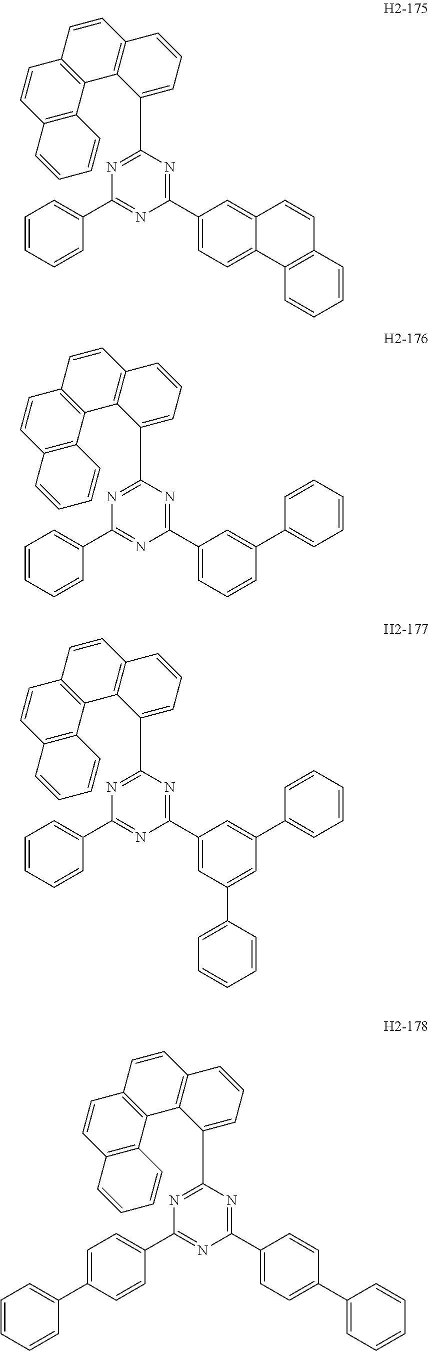 [SMILES: c1ccc(-c2nc(-c3ccc4c(ccc5ccccc54)c3)nc(-c3cccc4ccc5ccc6ccccc6c5c34)n2)cc1 ; c1ccc(-c2cccc(-c3nc(-c4ccccc4)nc(-c4cccc5ccc6ccc7ccccc7c6c45)n3)c2)cc1 ; c1ccc(-c2cc(-c3ccccc3)cc(-c3nc(-c4ccccc4)nc(-c4cccc5ccc6ccc7ccccc7c6c45)n3)c2)cc1 ; c1ccc(-c2ccc(-c3nc(-c4ccc(-c5ccccc5)cc4)nc(-c4cccc5ccc6ccc7ccccc7c6c45)n3)cc2)cc1]

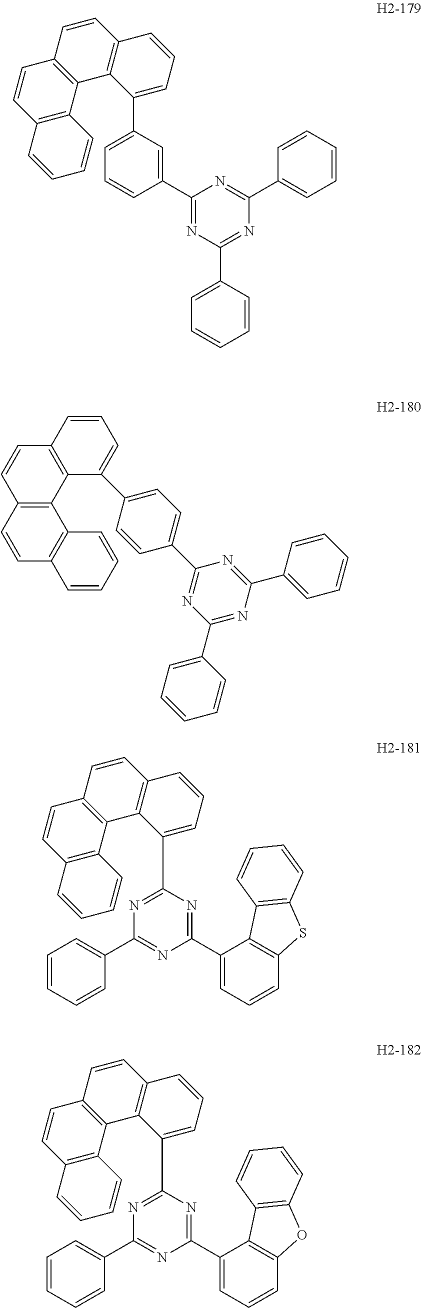 [SMILES: c1ccc(-c2nc(-c3ccccc3)nc(-c3cccc(-c4cccc5ccc6ccc7ccccc7c6c45)c3)n2)cc1 ; c1ccc(-c2nc(-c3ccccc3)nc(-c3ccc(-c4cccc5ccc6ccc7ccccc7c6c45)cc3)n2)cc1 ; c1ccc(-c2nc(-c3cccc4sc5ccccc5c34)nc(-c3cccc4ccc5ccc6ccccc6c5c34)n2)cc1 ; c1ccc(-c2nc(-c3cccc4oc5ccccc5c34)nc(-c3cccc4ccc5ccc6ccccc6c5c34)n2)cc1]

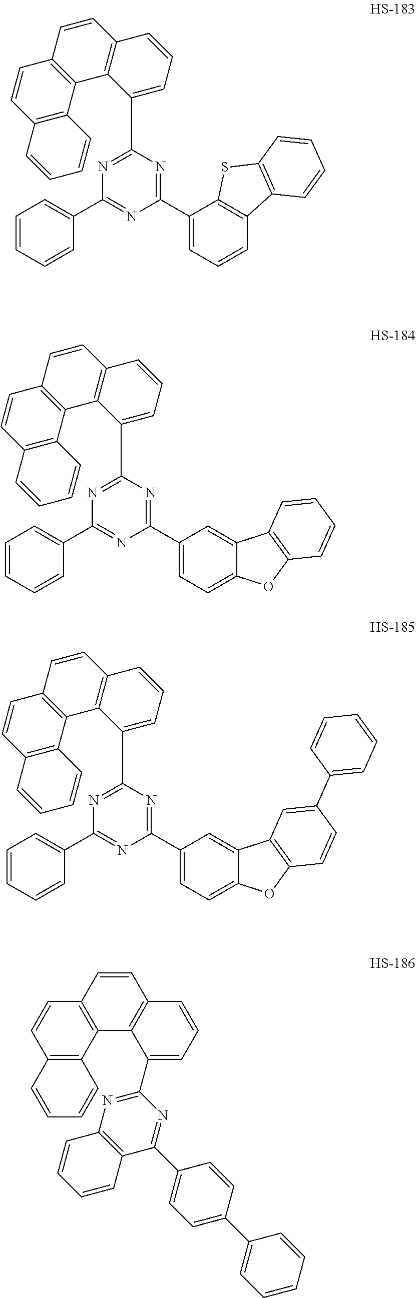 [SMILES: c1ccc(-c2nc(-c3cccc4c3sc3ccccc34)nc(-c3cccc4ccc5ccc6ccccc6c5c34)n2)cc1 ; c1ccc(-c2nc(-c3ccc4oc5ccccc5c4c3)nc(-c3cccc4ccc5ccc6ccccc6c5c34)n2)cc1 ; c1ccc(-c2ccc3oc4ccc(-c5nc(-c6ccccc6)nc(-c6cccc7ccc8ccc9ccccc9c8c67)n5)cc4c3c2)cc1 ; c1ccc(-c2ccc(-c3nc(-c4cccc5ccc6ccc7ccccc7c6c45)nc4ccccc34)cc2)cc1]

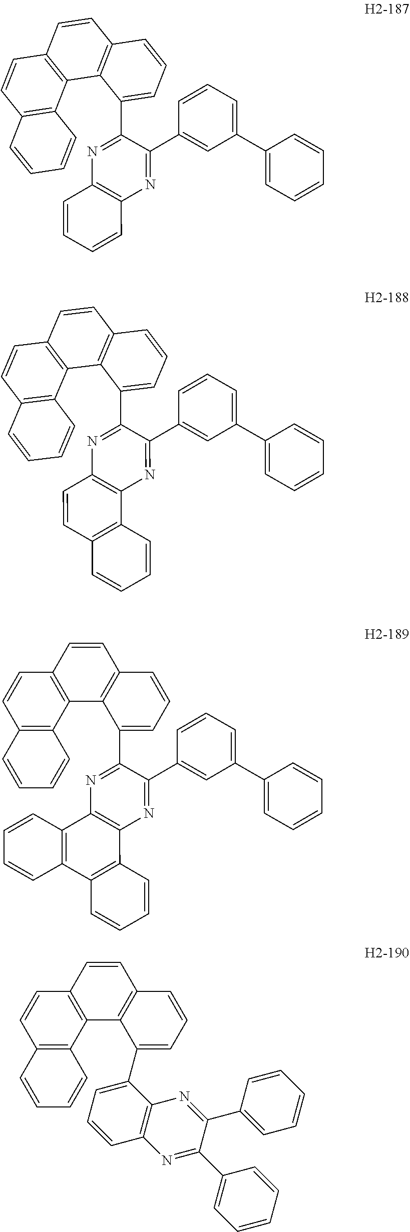

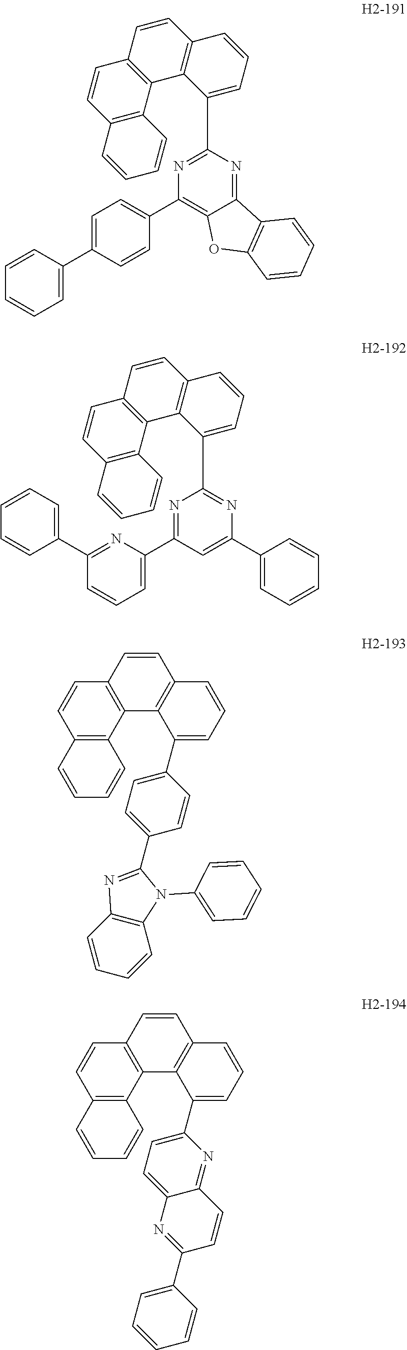

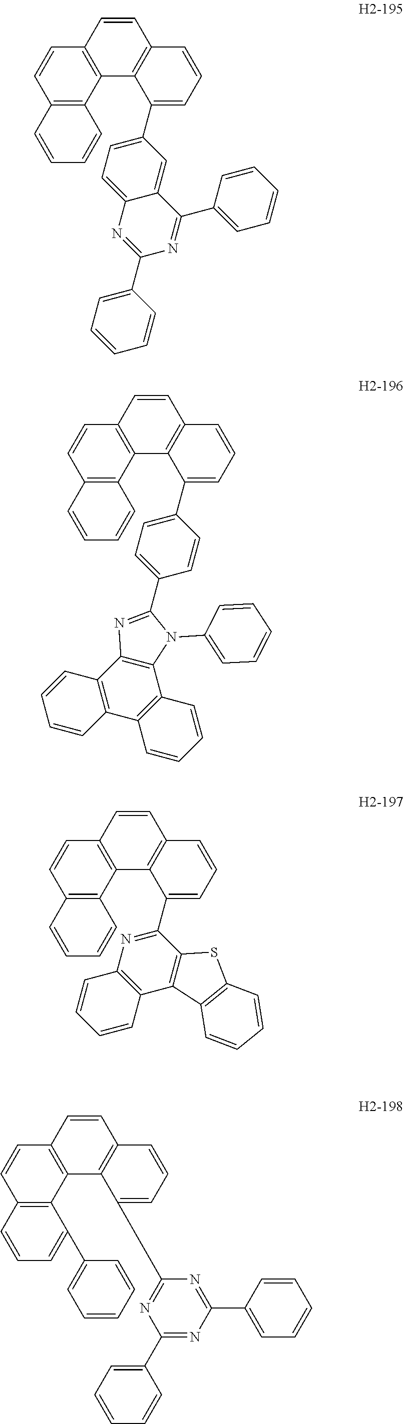

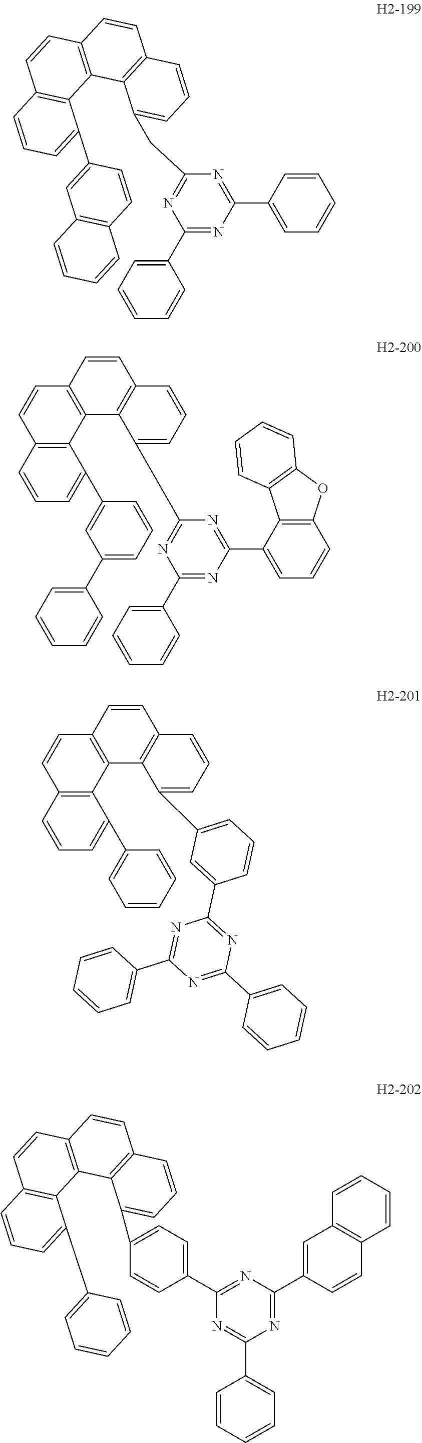

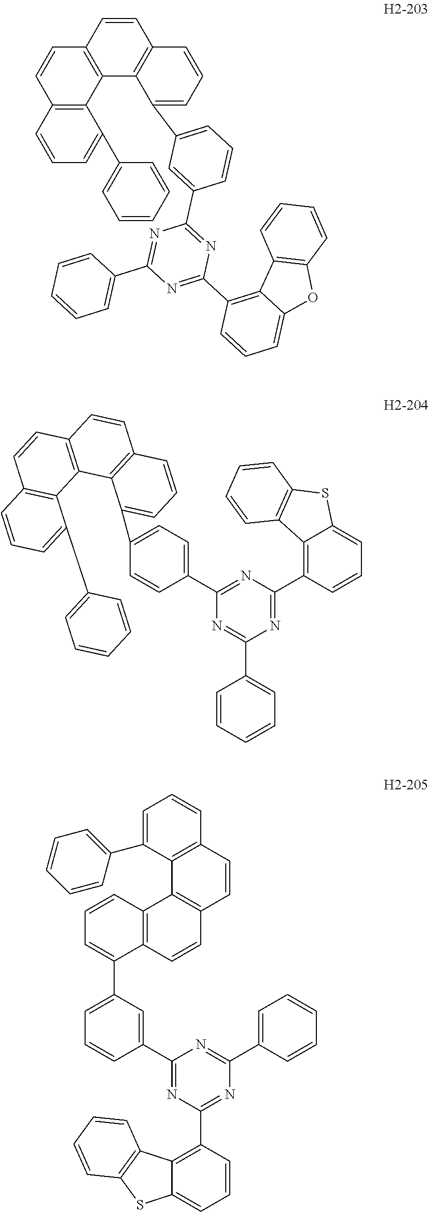 [SMILES: c1ccc(-c2nc(-c3cccc(-c4cccc5ccc6ccc7cccc(-c8ccccc8)c7c6c45)c3)nc(-c3cccc4oc5ccccc5c34)n2)cc1 ; c1ccc(-c2nc(-c3ccc(-c4cccc5ccc6ccc7cccc(-c8ccccc8)c7c6c45)cc3)nc(-c3cccc4sc5ccccc5c34)n2)cc1 ; c1ccc(-c2nc(-c3cccc(-c4cccc5c4ccc4ccc6cccc(-c7ccccc7)c6c45)c3)nc(-c3cccc4sc5ccccc5c34)n2)cc1]

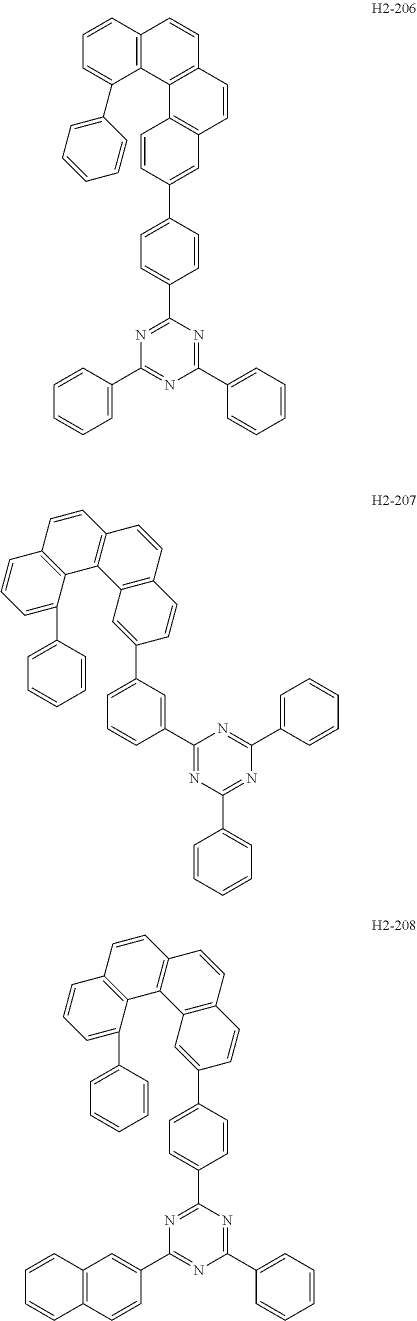 [SMILES: c1ccc(-c2nc(-c3ccccc3)nc(-c3ccc(-c4ccc5c(ccc6ccc7cccc(-c8ccccc8)c7c65)c4)cc3)n2)cc1 ; c1ccc(-c2nc(-c3ccccc3)nc(-c3cccc(-c4ccc5ccc6ccc7cccc(-c8ccccc8)c7c6c5c4)c3)n2)cc1 ; c1ccc(-c2nc(-c3ccc(-c4ccc5ccc6ccc7cccc(-c8ccccc8)c7c6c5c4)cc3)nc(-c3ccc4ccccc4c3)n2)cc1]

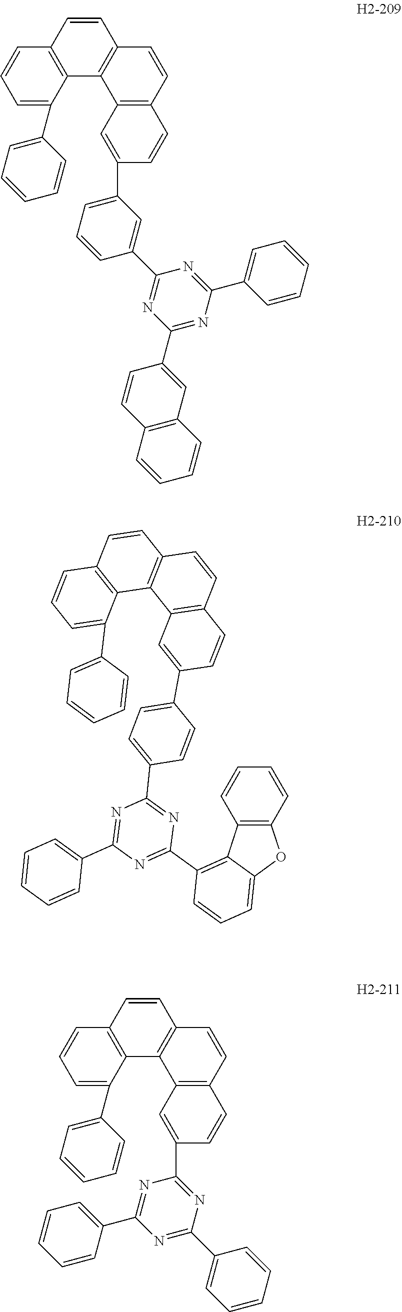 [SMILES: c1ccc(-c2nc(-c3cccc(-c4ccc5ccc6ccc7cccc(-c8ccccc8)c7c6c5c4)c3)nc(-c3ccc4ccccc4c3)n2)cc1 ; c1ccc(-c2nc(-c3ccc(-c4ccc5ccc6ccc7cccc(-c8ccccc8)c7c6c5c4)cc3)nc(-c3cccc4oc5ccccc5c34)n2)cc1 ; c1ccc(-c2nc(-c3ccccc3)nc(-c3ccc4ccc5ccc6cccc(-c7ccccc7)c6c5c4c3)n2)cc1]

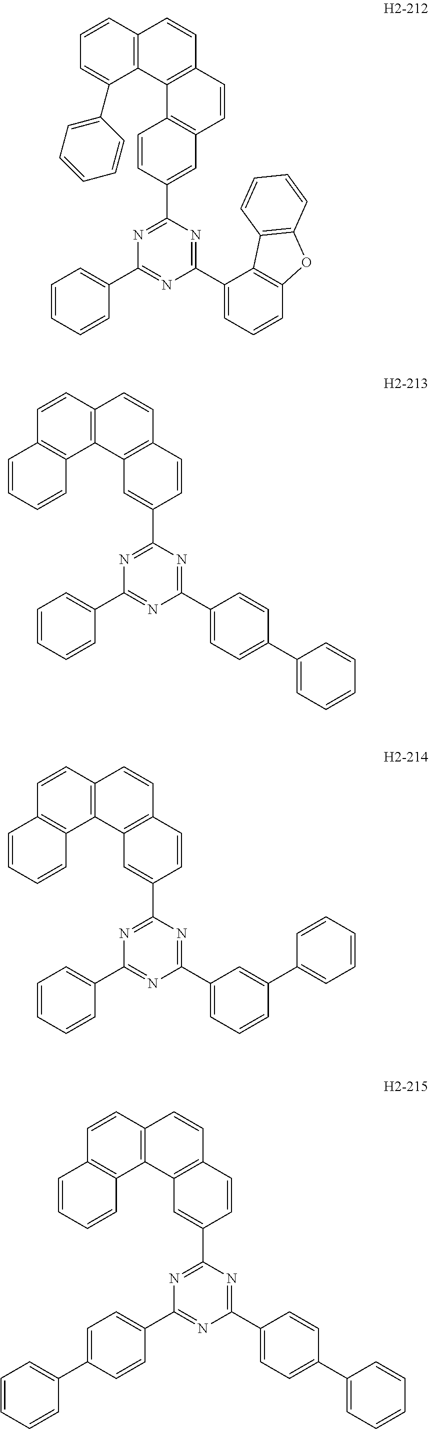 [SMILES: c1ccc(-c2nc(-c3ccc4c(ccc5ccc6cccc(-c7ccccc7)c6c54)c3)nc(-c3cccc4oc5ccccc5c34)n2)cc1 ; c1ccc(-c2ccc(-c3nc(-c4ccccc4)nc(-c4ccc5ccc6ccc7ccccc7c6c5c4)n3)cc2)cc1 ; c1ccc(-c2cccc(-c3nc(-c4ccccc4)nc(-c4ccc5ccc6ccc7ccccc7c6c5c4)n3)c2)cc1 ; c1ccc(-c2ccc(-c3nc(-c4ccc(-c5ccccc5)cc4)nc(-c4ccc5ccc6ccc7ccccc7c6c5c4)n3)cc2)cc1]

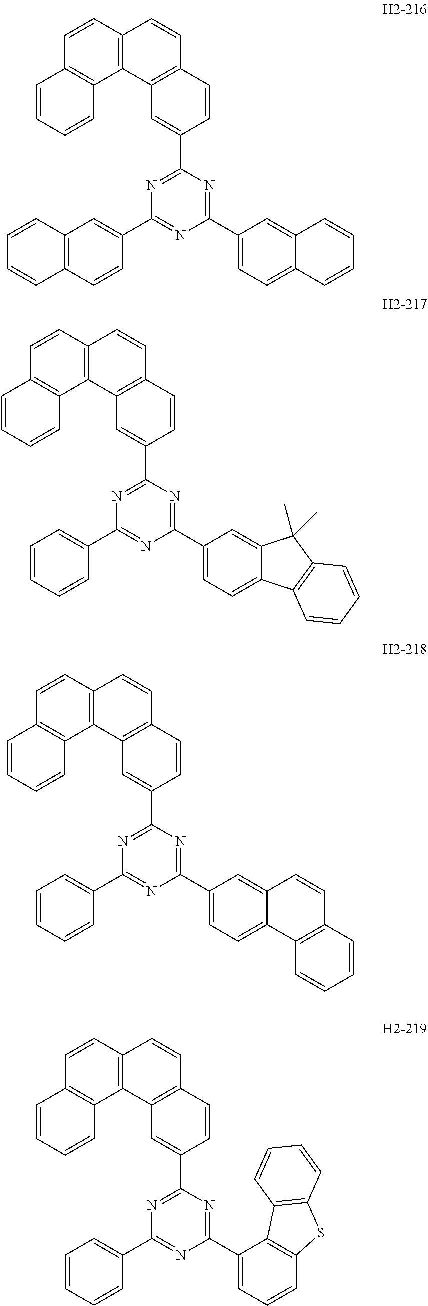 [SMILES: c1ccc2cc(-c3nc(-c4ccc5ccccc5c4)nc(-c4ccc5ccc6ccc7ccccc7c6c5c4)n3)ccc2c1 ; CC1(C)c2ccccc2-c2ccc(-c3nc(-c4ccccc4)nc(-c4ccc5ccc6ccc7ccccc7c6c5c4)n3)cc21 ; c1ccc(-c2nc(-c3ccc4c(ccc5ccccc54)c3)nc(-c3ccc4ccc5ccc6ccccc6c5c4c3)n2)cc1 ; c1ccc(-c2nc(-c3ccc4ccc5ccc6ccccc6c5c4c3)nc(-c3cccc4sc5ccccc5c34)n2)cc1]

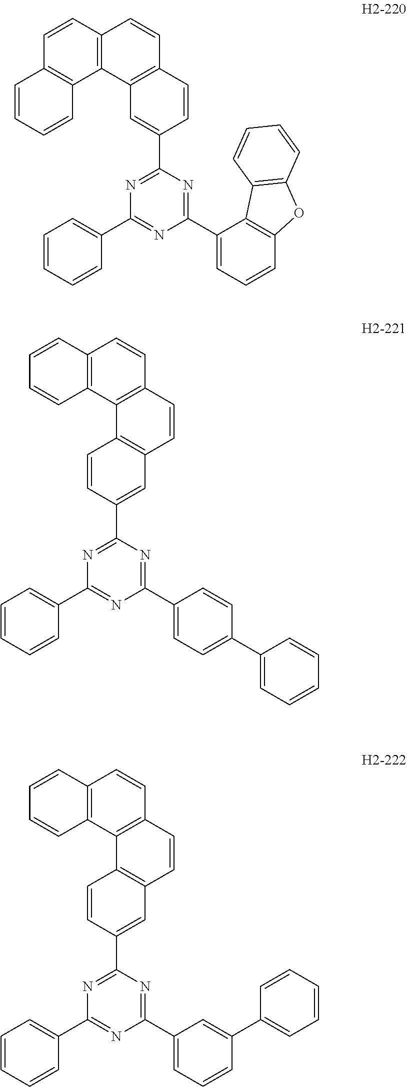 [SMILES: c1ccc(-c2nc(-c3ccc4ccc5ccc6ccccc6c5c4c3)nc(-c3cccc4oc5ccccc5c34)n2)cc1 ; c1ccc(-c2ccc(-c3nc(-c4ccccc4)nc(-c4ccc5c(ccc6ccc7ccccc7c65)c4)n3)cc2)cc1 ; c1ccc(-c2cccc(-c3nc(-c4ccccc4)nc(-c4ccc5c(ccc6ccc7ccccc7c65)c4)n3)c2)cc1]

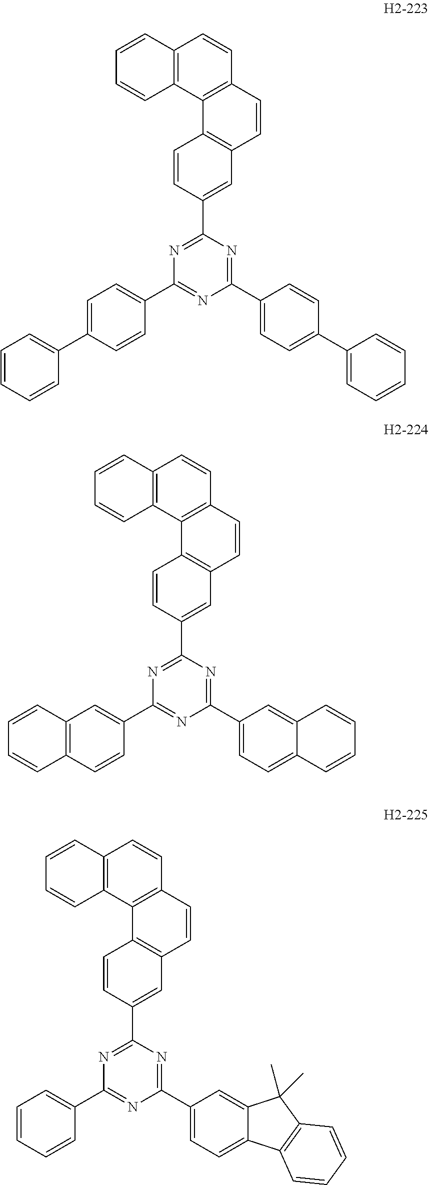 [SMILES: c1ccc(-c2ccc(-c3nc(-c4ccc(-c5ccccc5)cc4)nc(-c4ccc5c(ccc6ccc7ccccc7c65)c4)n3)cc2)cc1 ; c1ccc2cc(-c3nc(-c4ccc5ccccc5c4)nc(-c4ccc5c(ccc6ccc7ccccc7c65)c4)n3)ccc2c1 ; CC1(C)c2ccccc2-c2ccc(-c3nc(-c4ccccc4)nc(-c4ccc5c(ccc6ccc7ccccc7c65)c4)n3)cc21]

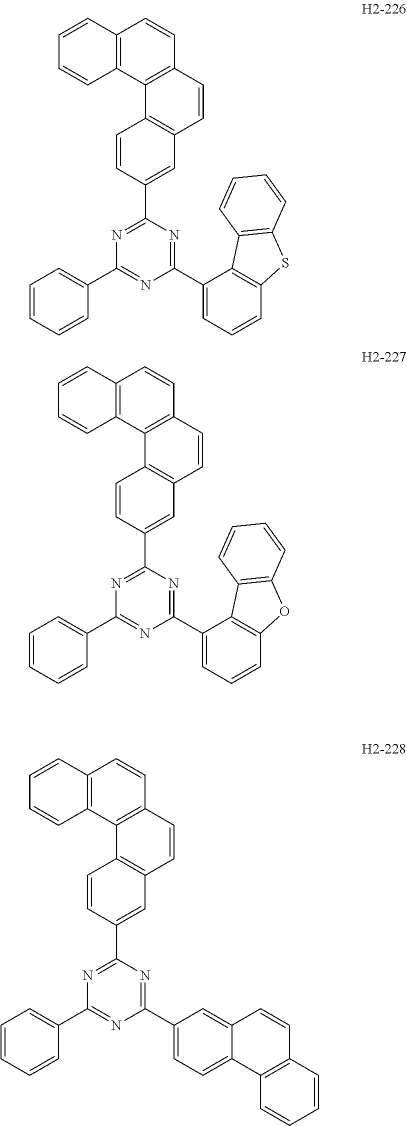

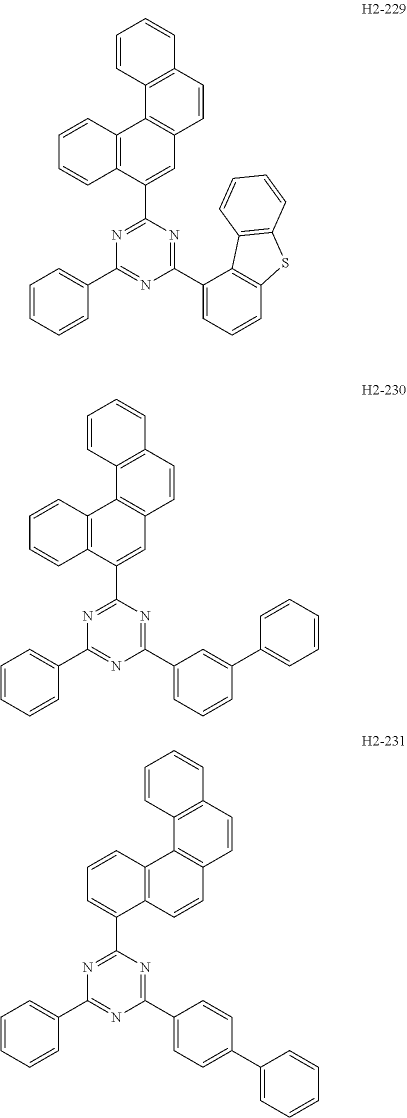

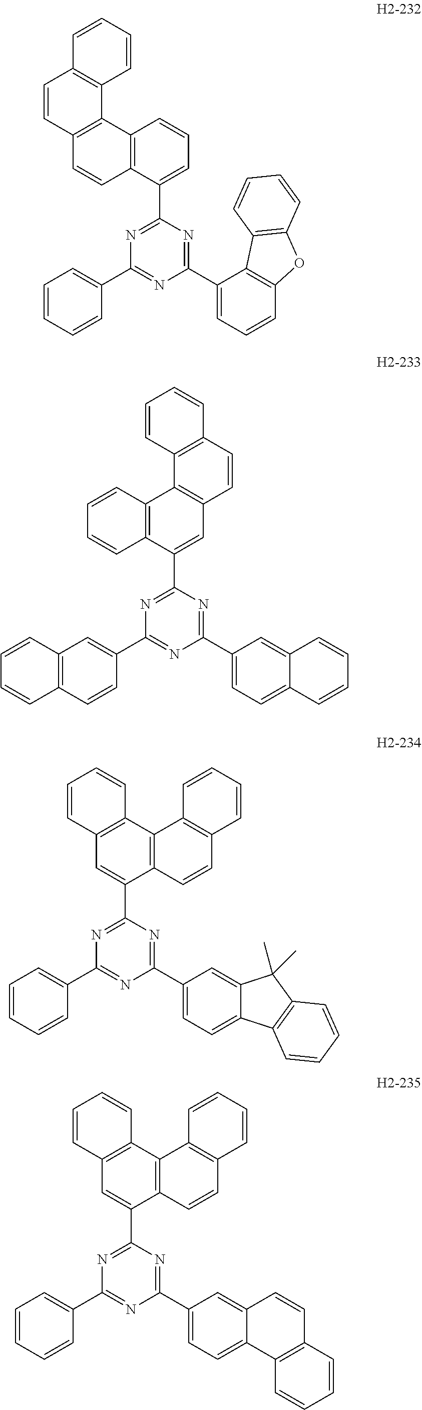 [SMILES: c1ccc(-c2nc(-c3cccc4c3ccc3ccc5ccccc5c34)nc(-c3cccc4oc5ccccc5c34)n2)cc1 ; c1ccc2cc(-c3nc(-c4ccc5ccccc5c4)nc(-c4cc5ccc6ccccc6c5c5ccccc45)n3)ccc2c1 ; CC1(C)c2ccccc2-c2ccc(-c3nc(-c4ccccc4)nc(-c4cc5ccccc5c5c4ccc4ccccc45)n3)cc21 ; c1ccc(-c2nc(-c3ccc4c(ccc5ccccc54)c3)nc(-c3cc4ccccc4c4c3ccc3ccccc34)n2)cc1]

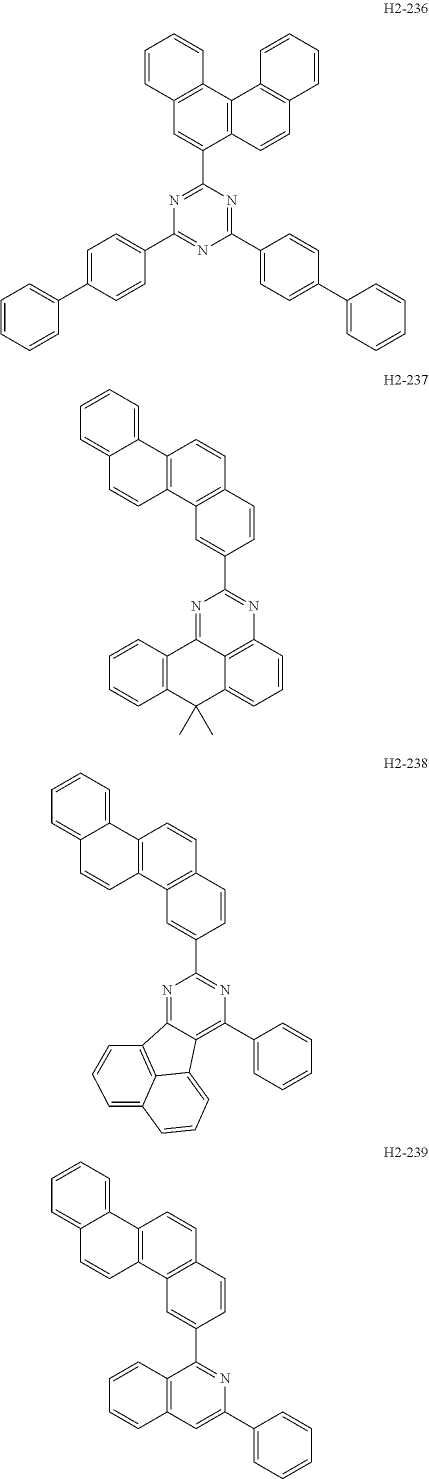 [SMILES: c1ccc(-c2ccc(-c3nc(-c4ccc(-c5ccccc5)cc4)nc(-c4cc5ccccc5c5c4ccc4ccccc45)n3)cc2)cc1 ; CC1(C)c2ccccc2-c2nc(-c3ccc4ccc5c6ccccc6ccc5c4c3)nc3cccc1c23 ; c1ccc(-c2nc(-c3ccc4ccc5c6ccccc6ccc5c4c3)nc3c2-c2cccc4cccc-3c24)cc1 ; c1ccc(-c2cc3ccccc3c(-c3ccc4ccc5c6ccccc6ccc5c4c3)n2)cc1]

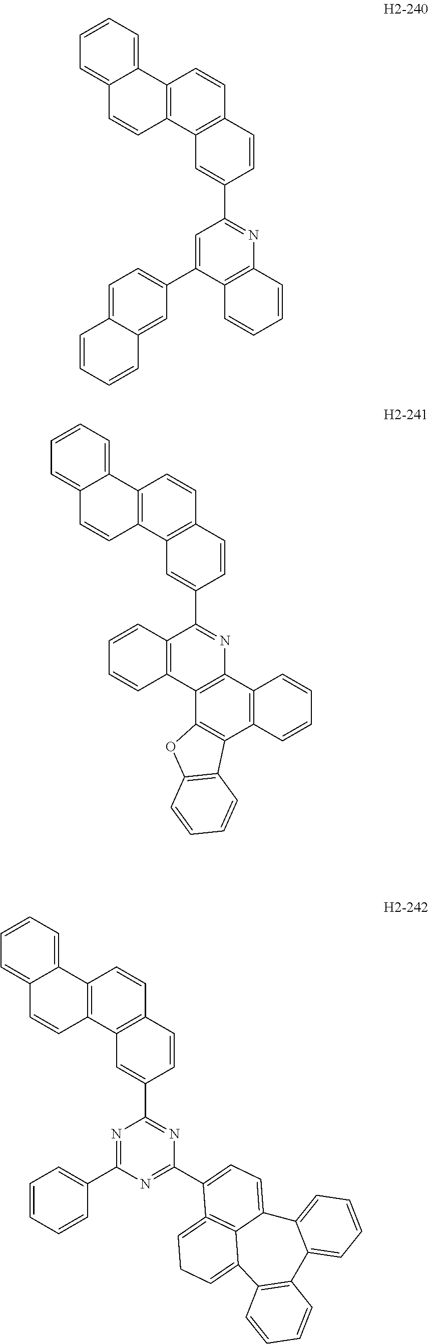

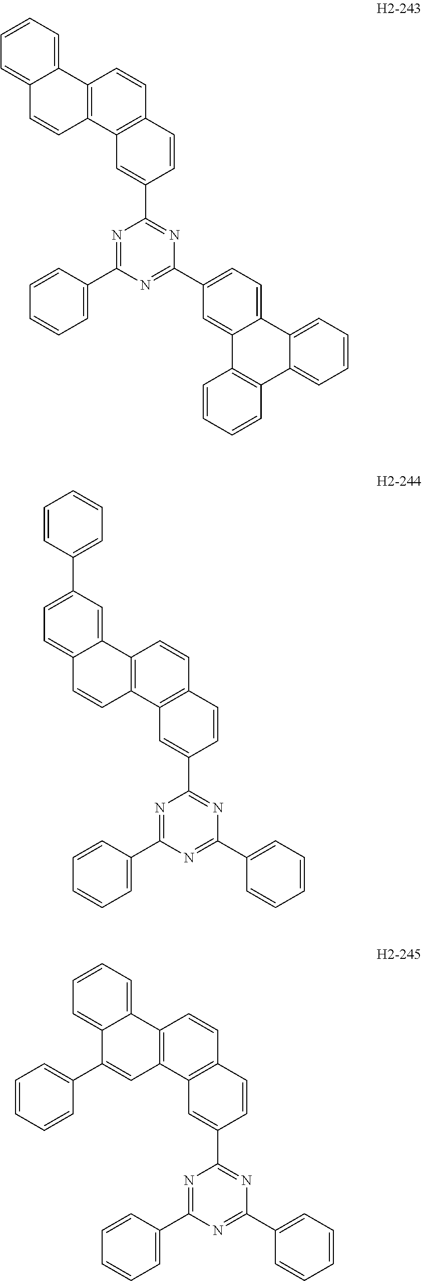 [SMILES: c1ccc(-c2nc(-c3ccc4ccc5c6ccccc6ccc5c4c3)nc(-c3ccc4c5ccccc5c5ccccc5c4c3)n2)cc1 ; c1ccc(-c2ccc3ccc4c5cc(-c6nc(-c7ccccc7)nc(-c7ccccc7)n6)ccc5ccc4c3c2)cc1 ; c1ccc(-c2nc(-c3ccccc3)nc(-c3ccc4ccc5c6ccccc6c(-c6ccccc6)cc5c4c3)n2)cc1]

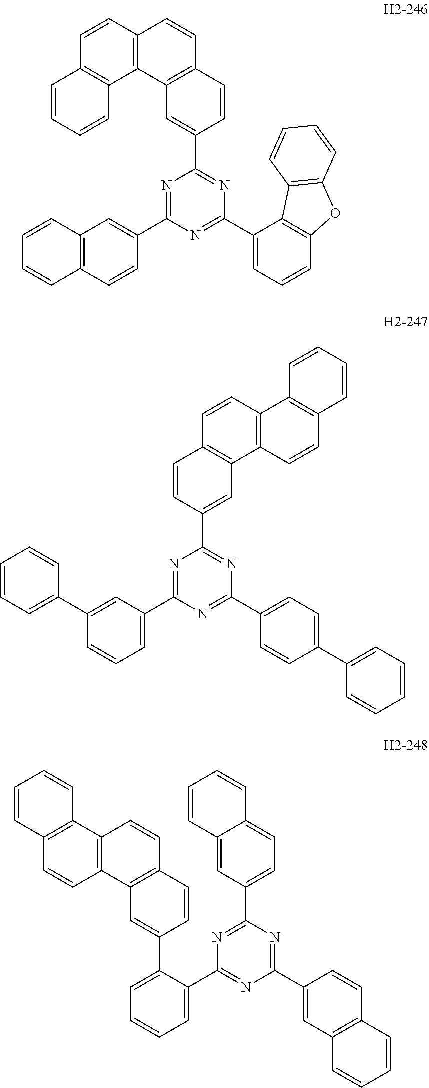 [SMILES: c1ccc2cc(-c3nc(-c4ccc5ccc6ccc7ccccc7c6c5c4)nc(-c4cccc5oc6ccccc6c45)n3)ccc2c1 ; c1ccc(-c2ccc(-c3nc(-c4cccc(-c5ccccc5)c4)nc(-c4ccc5ccc6c7ccccc7ccc6c5c4)n3)cc2)cc1 ; c1ccc(-c2nc(-c3ccc4ccccc4c3)nc(-c3ccc4ccccc4c3)n2)c(-c2ccc3ccc4c5ccccc5ccc4c3c2)c1]

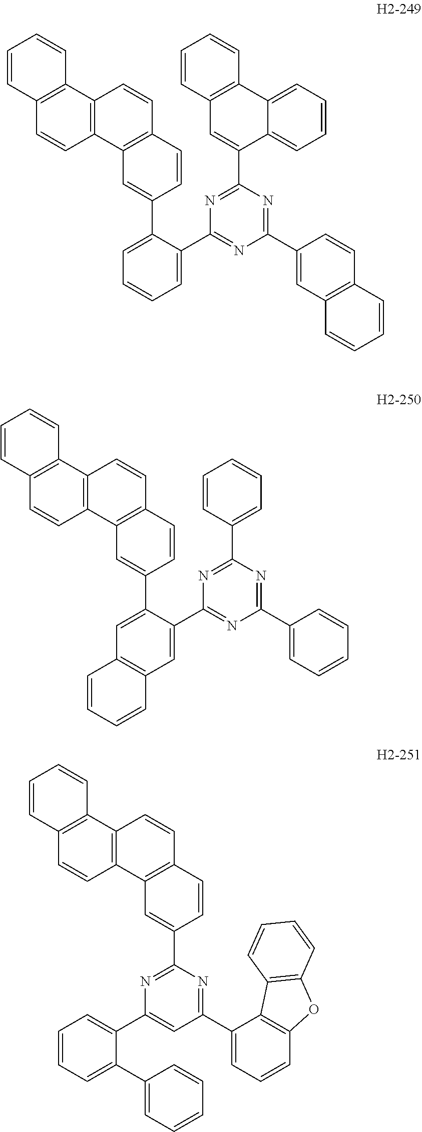 [SMILES: c1ccc(-c2nc(-c3ccc4ccccc4c3)nc(-c3cc4ccccc4c4ccccc34)n2)c(-c2ccc3ccc4c5ccccc5ccc4c3c2)c1 ; c1ccc(-c2nc(-c3ccccc3)nc(-c3cc4ccccc4cc3-c3ccc4ccc5c6ccccc6ccc5c4c3)n2)cc1 ; c1ccc(-c2ccccc2-c2cc(-c3cccc4oc5ccccc5c34)nc(-c3ccc4ccc5c6ccccc6ccc5c4c3)n2)cc1]

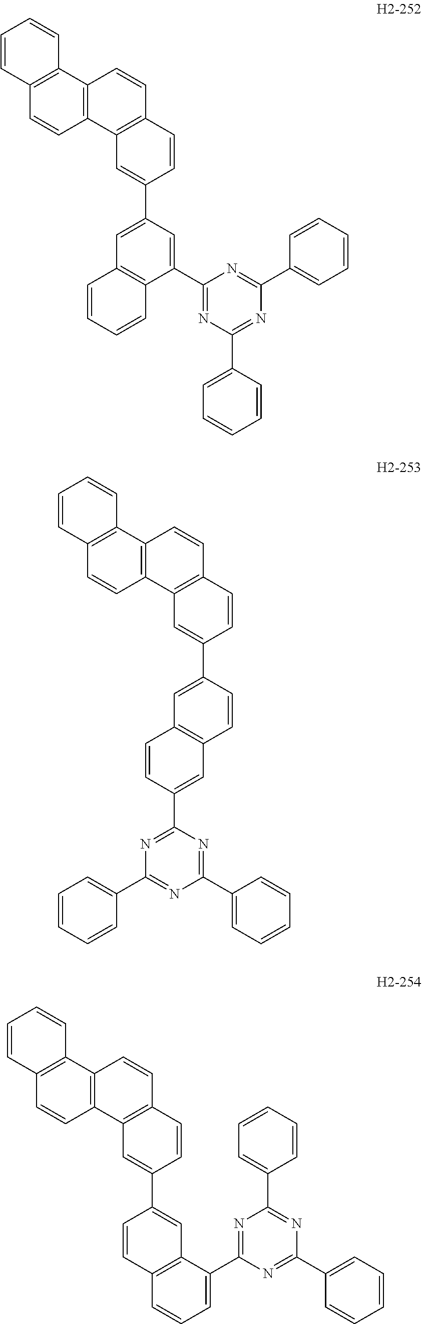 [SMILES: c1ccc(-c2nc(-c3ccccc3)nc(-c3cc(-c4ccc5ccc6c7ccccc7ccc6c5c4)cc4ccccc34)n2)cc1 ; c1ccc(-c2nc(-c3ccccc3)nc(-c3ccc4cc(-c5ccc6ccc7c8ccccc8ccc7c6c5)ccc4c3)n2)cc1 ; c1ccc(-c2nc(-c3ccccc3)nc(-c3cccc4ccc(-c5ccc6ccc7c8ccccc8ccc7c6c5)cc34)n2)cc1]

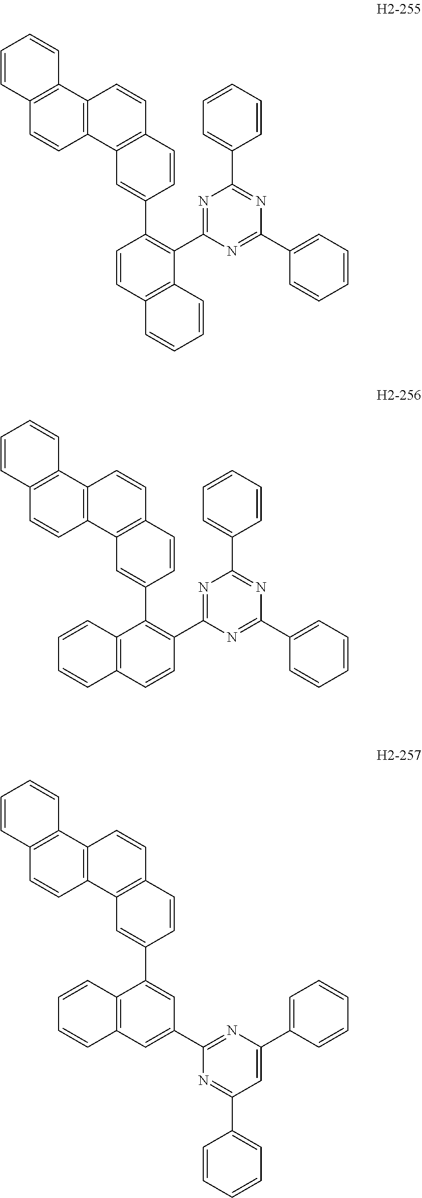 [SMILES: c1ccc(-c2nc(-c3ccccc3)nc(-c3c(-c4ccc5ccc6c7ccccc7ccc6c5c4)ccc4ccccc34)n2)cc1 ; c1ccc(-c2nc(-c3ccccc3)nc(-c3ccc4ccccc4c3-c3ccc4ccc5c6ccccc6ccc5c4c3)n2)cc1 ; c1ccc(-c2cc(-c3ccccc3)nc(-c3cc(-c4ccc5ccc6c7ccccc7ccc6c5c4)c4ccccc4c3)n2)cc1]

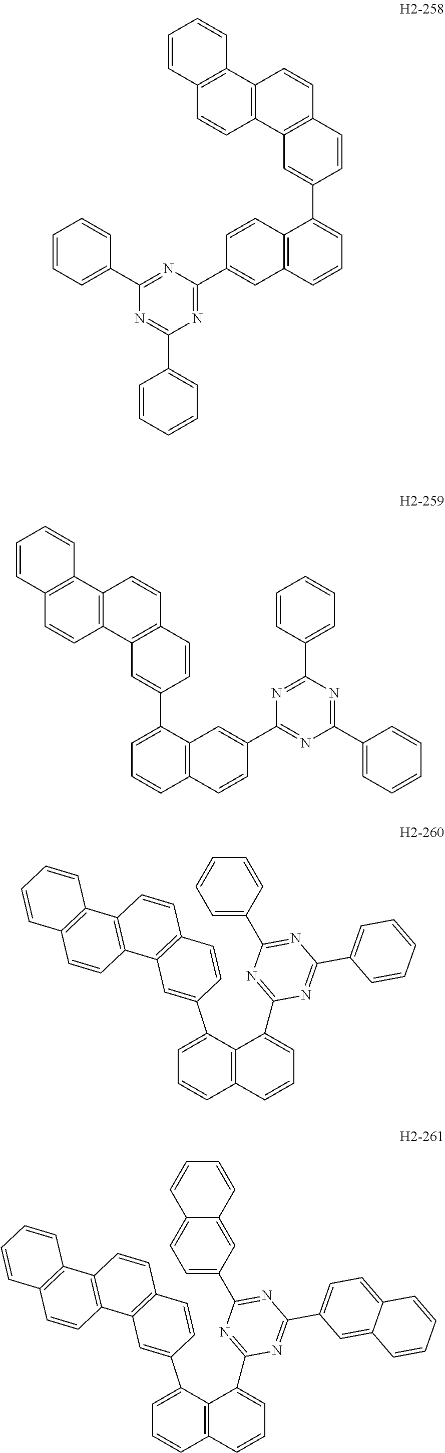 [SMILES: c1ccc(-c2nc(-c3ccccc3)nc(-c3ccc4c(-c5ccc6ccc7c8ccccc8ccc7c6c5)cccc4c3)n2)cc1 ; c1ccc(-c2nc(-c3ccccc3)nc(-c3ccc4cccc(-c5ccc6ccc7c8ccccc8ccc7c6c5)c4c3)n2)cc1 ; c1ccc(-c2nc(-c3ccccc3)nc(-c3cccc4cccc(-c5ccc6ccc7c8ccccc8ccc7c6c5)c34)n2)cc1 ; c1ccc2cc(-c3nc(-c4ccc5ccccc5c4)nc(-c4cccc5cccc(-c6ccc7ccc8c9ccccc9ccc8c7c6)c45)n3)ccc2c1]

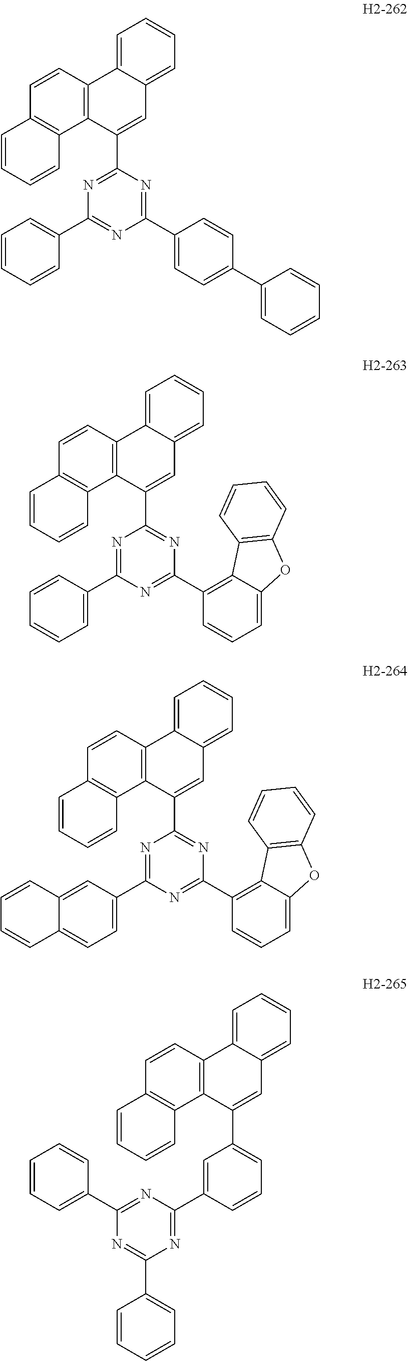

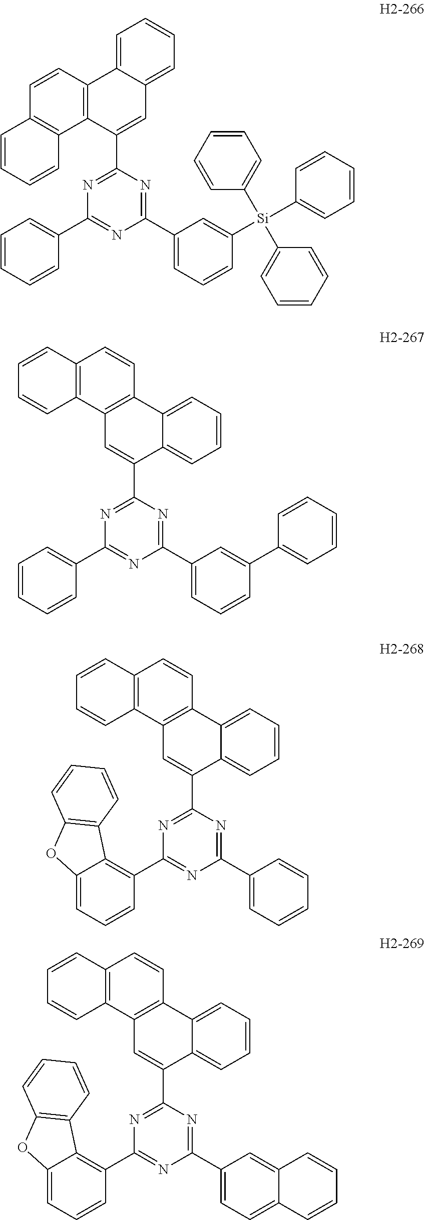

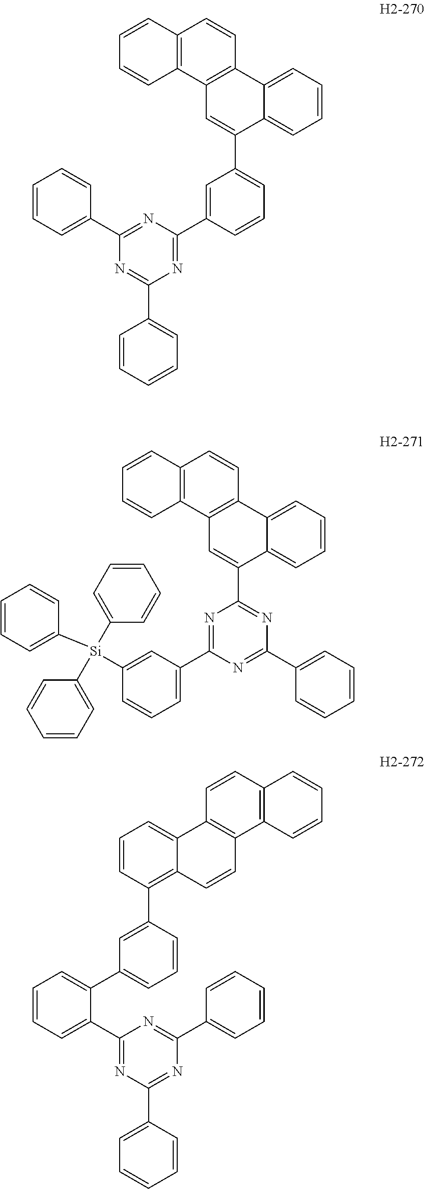 [SMILES: c1ccc(-c2nc(-c3ccccc3)nc(-c3cccc(-c4cc5c6ccccc6ccc5c5ccccc45)c3)n2)cc1 ; c1ccc(-c2nc(-c3cccc([Si](c4ccccc4)(c4ccccc4)c4ccccc4)c3)nc(-c3cc4c5ccccc5ccc4c4ccccc34)n2)cc1 ; c1ccc(-c2nc(-c3ccccc3)nc(-c3ccccc3-c3cccc(-c4cccc5c4ccc4c6ccccc6ccc54)c3)n2)cc1]

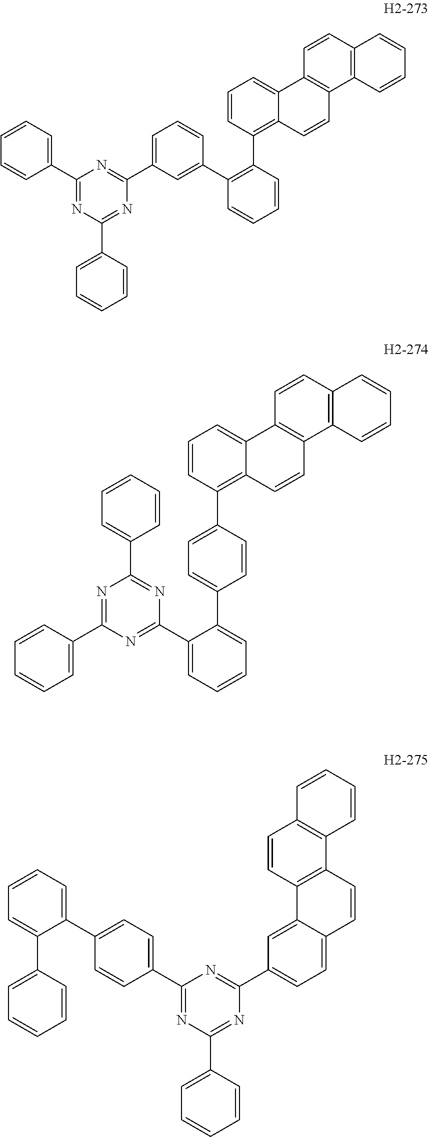 [SMILES: c1ccc(-c2nc(-c3ccccc3)nc(-c3cccc(-c4ccccc4-c4cccc5c4ccc4c6ccccc6ccc54)c3)n2)cc1 ; c1ccc(-c2nc(-c3ccccc3)nc(-c3ccccc3-c3ccc(-c4cccc5c4ccc4c6ccccc6ccc54)cc3)n2)cc1 ; c1ccc(-c2nc(-c3ccc(-c4ccccc4-c4ccccc4)cc3)nc(-c3ccc4ccc5c6ccccc6ccc5c4c3)n2)cc1]

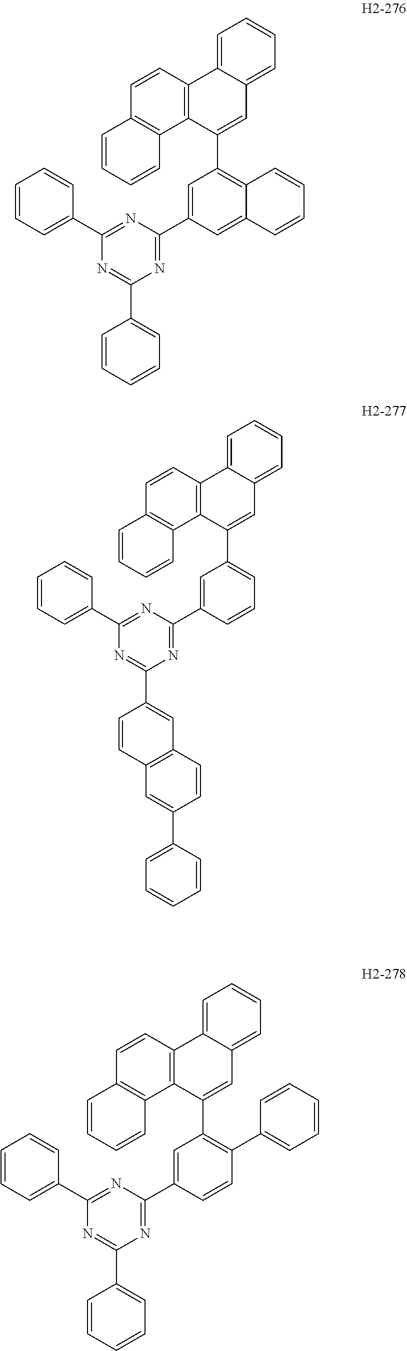 [SMILES: c1ccc(-c2nc(-c3ccccc3)nc(-c3cc(-c4cc5ccccc5c5ccc6ccccc6c45)c4ccccc4c3)n2)cc1 ; c1ccc(-c2ccc3cc(-c4nc(-c5ccccc5)nc(-c5cccc(-c6cc7ccccc7c7ccc8ccccc8c67)c5)n4)ccc3c2)cc1 ; c1ccc(-c2nc(-c3ccccc3)nc(-c3ccc(-c4ccccc4)c(-c4cc5ccccc5c5ccc6ccccc6c45)c3)n2)cc1]

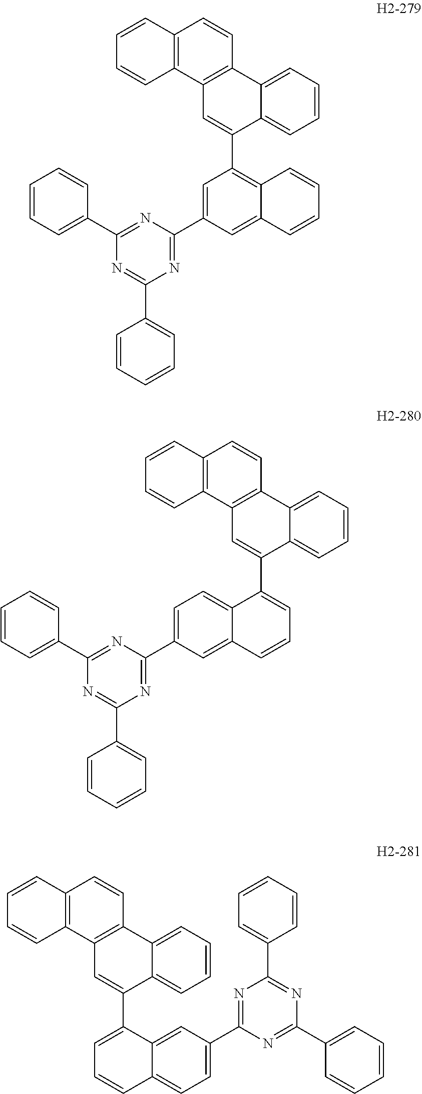 [SMILES: c1ccc(-c2nc(-c3ccccc3)nc(-c3cc(-c4cc5c6ccccc6ccc5c5ccccc45)c4ccccc4c3)n2)cc1 ; c1ccc(-c2nc(-c3ccccc3)nc(-c3ccc4c(-c5cc6c7ccccc7ccc6c6ccccc56)cccc4c3)n2)cc1 ; c1ccc(-c2nc(-c3ccccc3)nc(-c3ccc4cccc(-c5cc6c7ccccc7ccc6c6ccccc56)c4c3)n2)cc1]

At least one of compounds C-1 to C-120 and C-126 to C-435 may be used in an organic electroluminescent device. In addition, a combination of at least one of compounds C-1 to C-437 and at least one of compounds H2-1 to H2-281 may be used in an organic electroluminescent device.

The organic electroluminescent compound represented by Formula 11 according to the present disclosure may be comprised in at least one layer selected from a light-emitting layer, a hole injection layer, a hole transport layer, a hole auxiliary layer, a light-emitting auxiliary layer, an electron transport layer, an electron buffer layer, an electron injection layer, an interlayer, a hole blocking layer, and an electron blocking layer, and in some cases, it may preferably be comprised in at least one layer selected from a light-emitting layer, a hole transport layer, a hole auxiliary layer, a light-emitting auxiliary layer, an electron transport layer, an electron buffer layer, a hole blocking layer, and an electron blocking layer. When used in a light-emitting layer, the organic electroluminescent compound represented by Formula 11 may be comprised as a host material, and may be comprised as a material for an electron transport layer and/or a material for an electron buffer layer. If necessary, the organic electroluminescent compound of the present disclosure may be used as a co-host material.

The compounds represented by Formulas 1 and 11 according to the present disclosure may be prepared by synthetic methods known to those skilled in the art, for example, by referring to the following Reaction Schemes 1-1 and 1-2, and Yeon-Ho Cho, et al. Tetrahedron, Volume 69, Issue 32, 2013, Pages 6565-6573, etc., but not limited thereto. The compound represented by Formula 2 according to the present disclosure may be prepared by synthetic methods known to those skilled in the art, for example, by referring to the following Reaction Schemes 2-1 and 2-2, but not limited thereto.

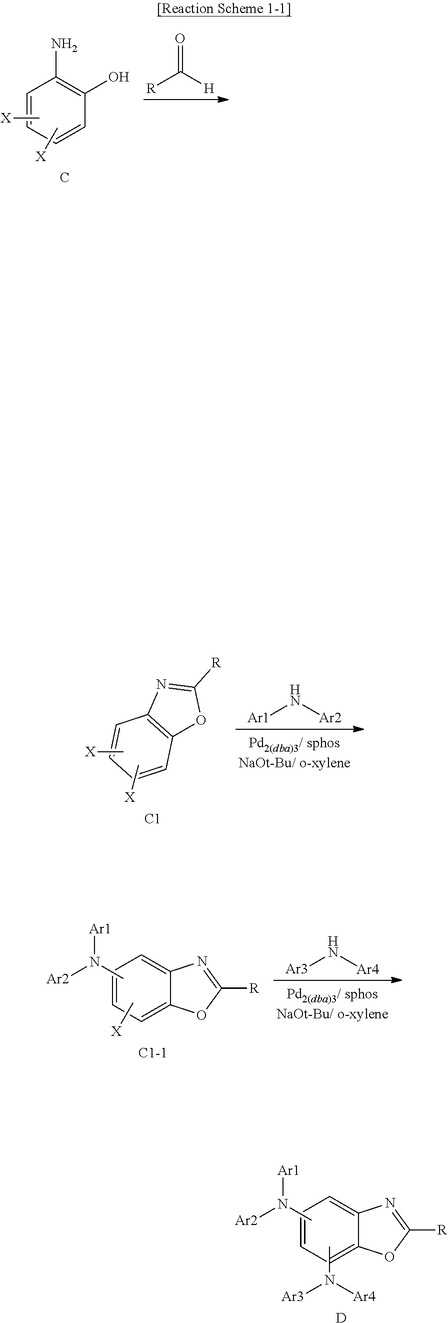

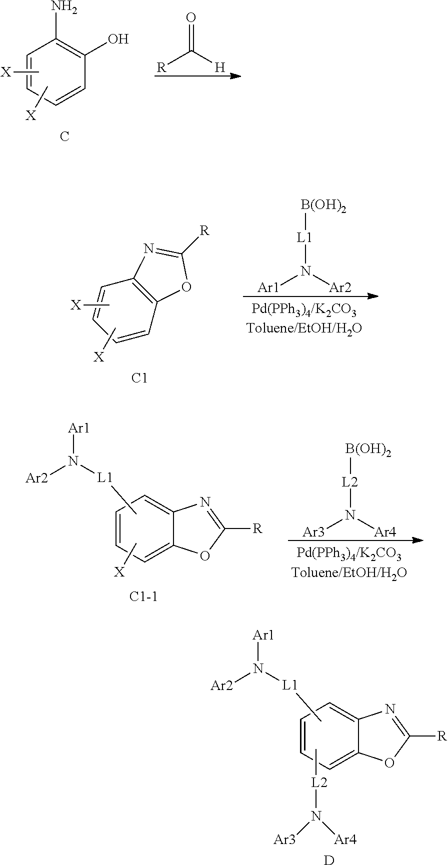

In Reaction Schemes 1-1 and 1-2, X represents a halogen, and R, L₁, L₂, and Ar₁ to Ar₄ are as defined in Formulas 1 and 11.

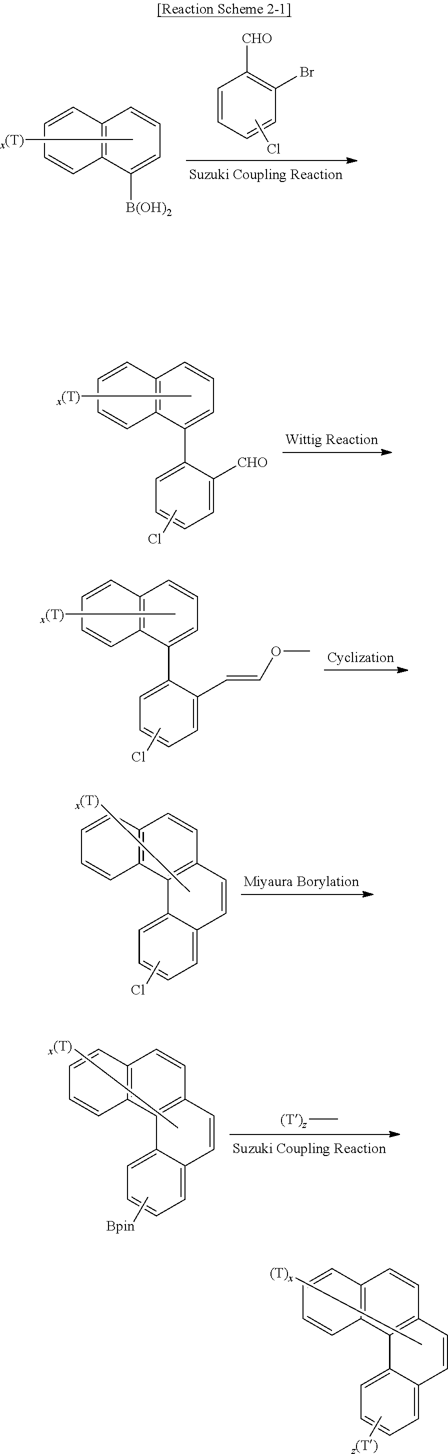

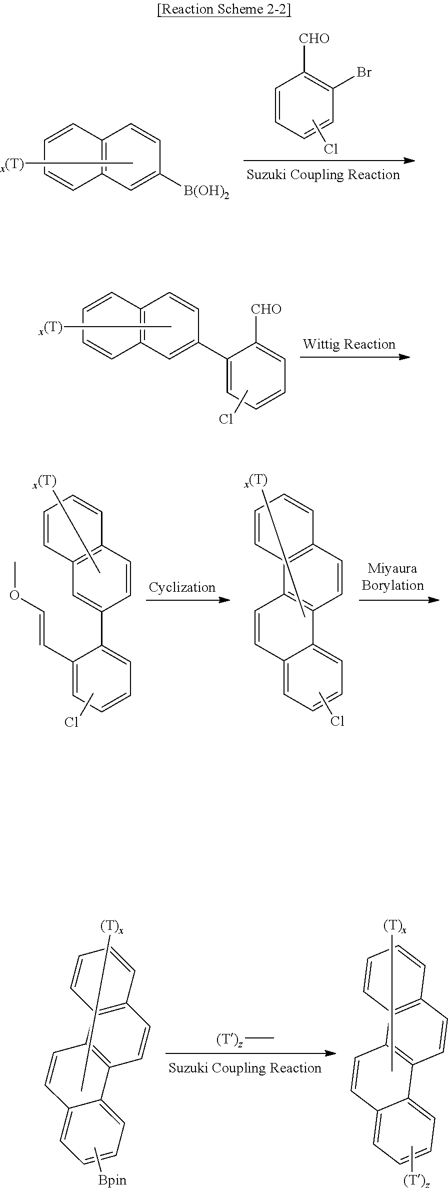

In Reaction Schemes 2-1 and 2-2, T and T′ each independently are defined for T₁ to T₄ in Formula 2, x represents an integer of 1 to 8, and z represents an integer of 1 to 4, where if x and z are 2 or more, each of T and each of T′ may be the same as or different from each other.

Although illustrative synthesis examples of the compounds represented by Formulas 1, 2 and 11 are described above, one skilled in the art will be able to readily understand that all of them are based on a Buchwald-Hartwig cross coupling reaction, an N-arylation reaction, a H-mont-mediated etherification reaction, a Miyaura borylation reaction, a Suzuki cross-coupling reaction, an Intramolecular acid-induced cyclization reaction, a Pd(II)-catalyzed oxidative cyclization reaction, a Grignard reaction, a Heck reaction, a Cyclic Dehydration reaction, an SN1 substitution reaction, an SN2 substitution reaction, a Phosphine-mediated reductive cyclization reaction, a Wittig reaction, etc., and the above reactions proceed even when substituents defined in Formulas 1, 2 and 11 other than the substituents specified in the specific synthesis examples are bonded.

The present disclosure provides an organic electroluminescent device comprising an anode; a cathode; and at least one light-emitting layer between the anode and the cathode, wherein the at least one light-emitting layer may comprise a plurality of host materials according to the present disclosure. The first host material and the second host material according to the present disclosure may be comprised together in one light-emitting layer or may be respectively comprised in different light-emitting layers among a plurality of light-emitting layers. The plurality of host materials of the present disclosure may comprise the compound represented by Formula 1 and the compound represented by Formula 2 in a ratio of about 1:99 to about 99:1, preferably about 10:90 to about 90:10, more preferably about 30:70 to about 70:30. In addition, the compound represented by Formula 1 and the compound represented by Formula 2 in a desired ratio may be combined by mixing them in a shaker, by dissolving them in a glass tube by heat, or by dissolving them in a solvent, etc.

According to one embodiment of the present disclosure, the doping concentration of a dopant compound with respect to a host compound of the light-emitting layer may be less than 20 wt %. The dopants comprised in the organic electroluminescent device of the present disclosure may be at least one phosphorescent or fluorescent dopant, and is preferably a phosphorescent dopant. The phosphorescent dopant materials applied to the organic electroluminescent device according to the present disclosure are not particularly limited, but may be a complex compound of a metal atom selected from iridium (Ir), osmium (Os), copper (Cu), and platinum (Pt), preferably ortho-metallated complex compounds of a metal atom selected from iridium (Ir), osmium (Os), copper (Cu), and platinum (Pt), and more preferably ortho-metallated iridium complex compounds.

The dopant comprised in the organic electroluminescent device of the present disclosure may be a compound represented by the following Formula 101, but is not limited thereto.

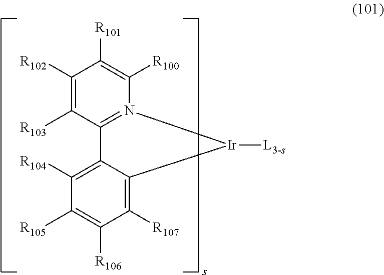

In Formula 101,
L is selected from the following structures 1 to 3:

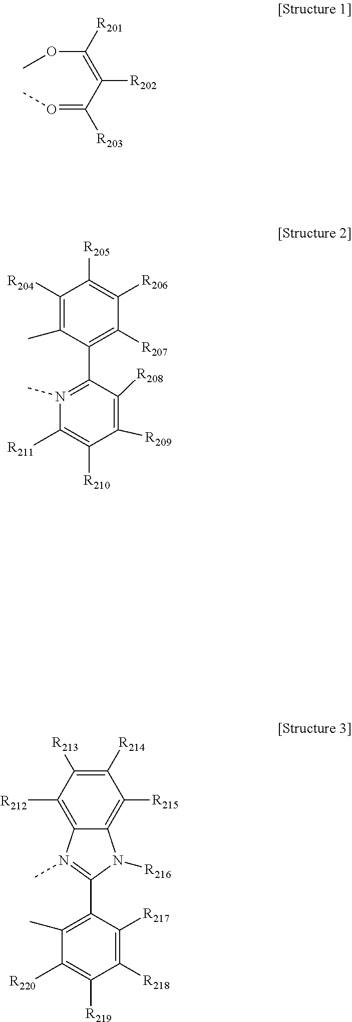

R₁₀₀ to R₁₀₃ each independently represent hydrogen, deuterium, a halogen, a (C1-C30)alkyl unsubstituted or substituted with deuterium and/or a halogen(s), a substituted or unsubstituted (C3-C30)cycloalkyl, a substituted or unsubstituted (C6-C30)aryl, a cyano, a substituted or unsubstituted (3- to 30-membered)heteroaryl, or a substituted or unsubstituted (C1-C30)alkoxy; or may be linked to an adjacent substituent(s) to form a ring(s), for example, a substituted or unsubstituted quinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline, together with pyridine;
R₁₀₄ to R₁₀₇ each independently represent hydrogen, deuterium, a halogen, a (C1-C30)alkyl unsubstituted or substituted with deuterium and/or a halogen(s), a substituted or unsubstituted (C3-C30)cycloalkyl, a substituted or unsubstituted (C6-C30)aryl, a substituted or unsubstituted (3- to 30-membered)heteroaryl, a cyano, or a substituted or unsubstituted (C1-C30)alkoxy; or may be linked to an adjacent substituent(s) to form a substituted or unsubstituted ring(s), for example, a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine, together with benzene;
R₂₀₁ to R₂₂₀ each independently represent hydrogen, deuterium, a halogen, a (C1-C30)alkyl unsubstituted or substituted with deuterium and/or a halogen(s), a substituted or unsubstituted (C3-C30)cycloalkyl, or a substituted or unsubstituted (C6-C30)aryl; or may be linked to an adjacent substituent(s) to form a substituted or unsubstituted ring(s); and
s is an integer from 1 to 3.

The specific examples of the dopant compound are as follows, but are not limited thereto.

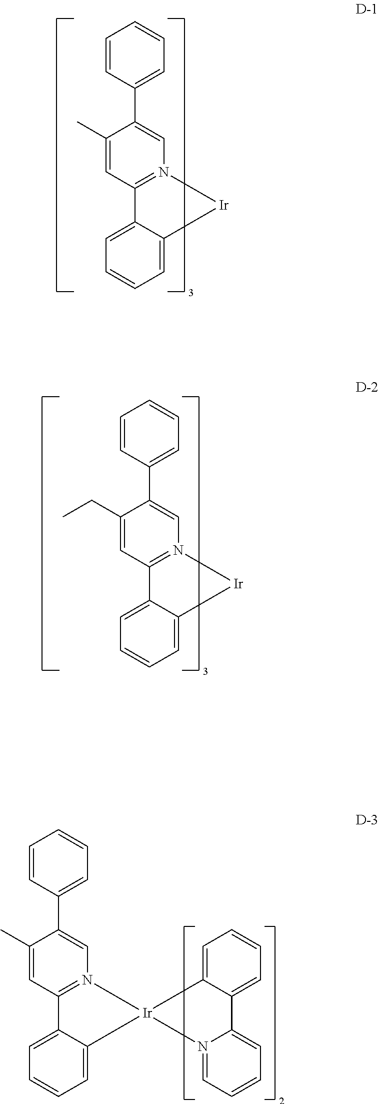

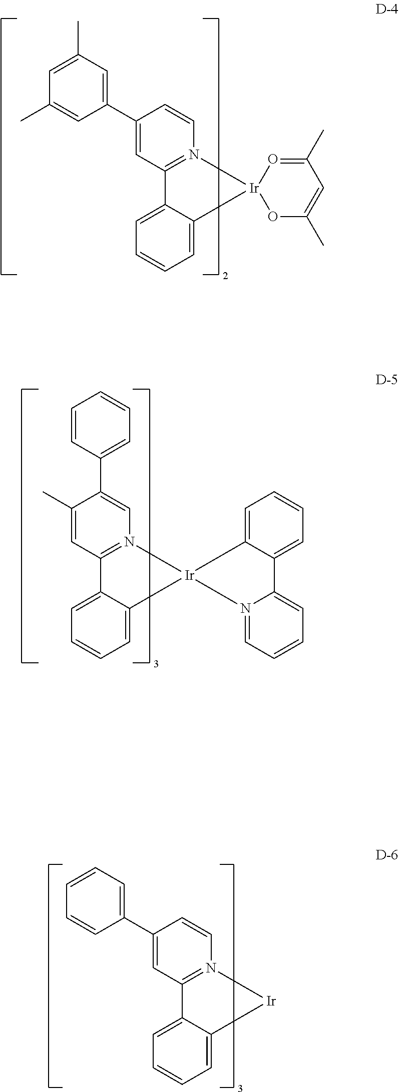

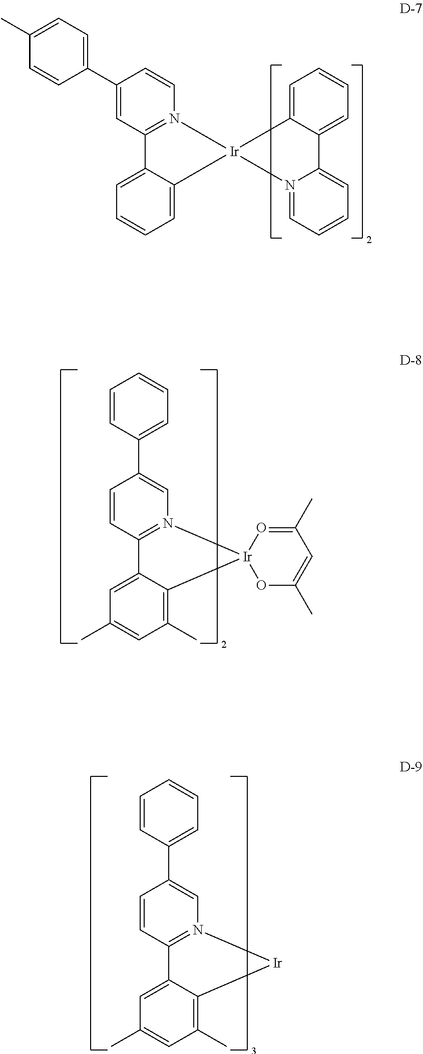

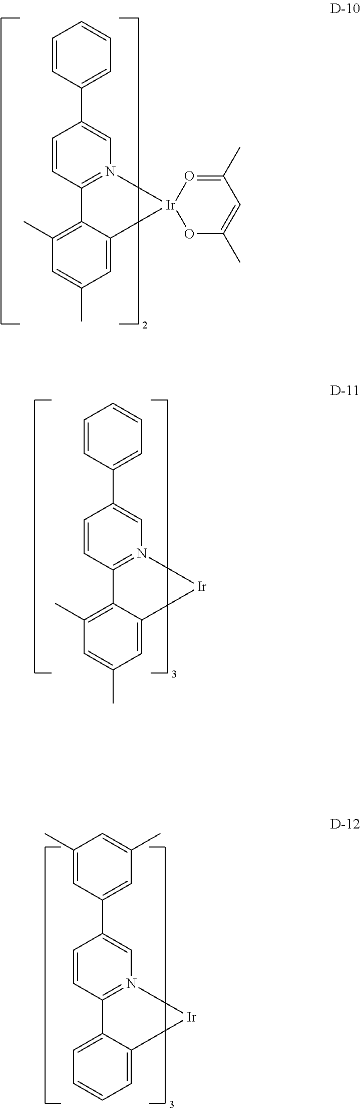

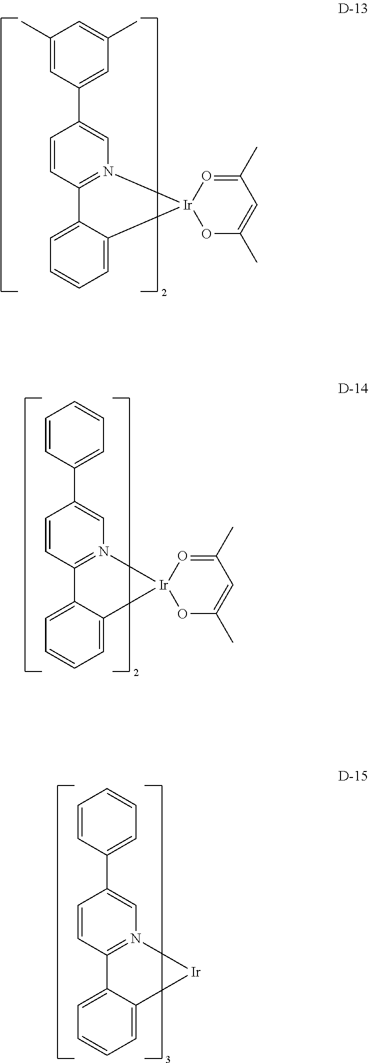

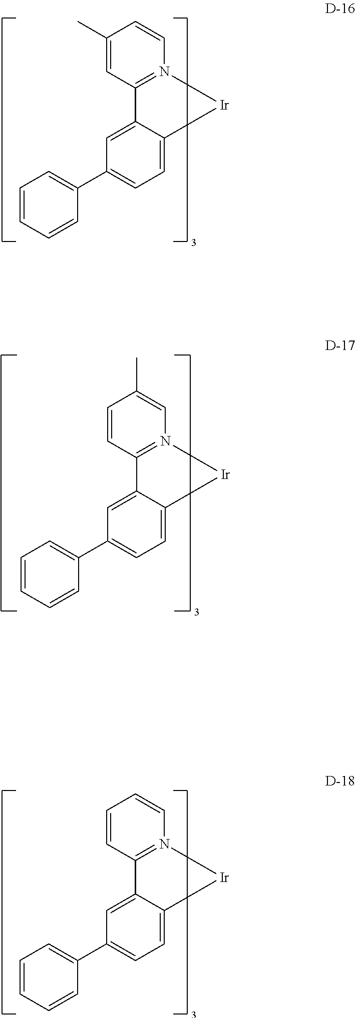

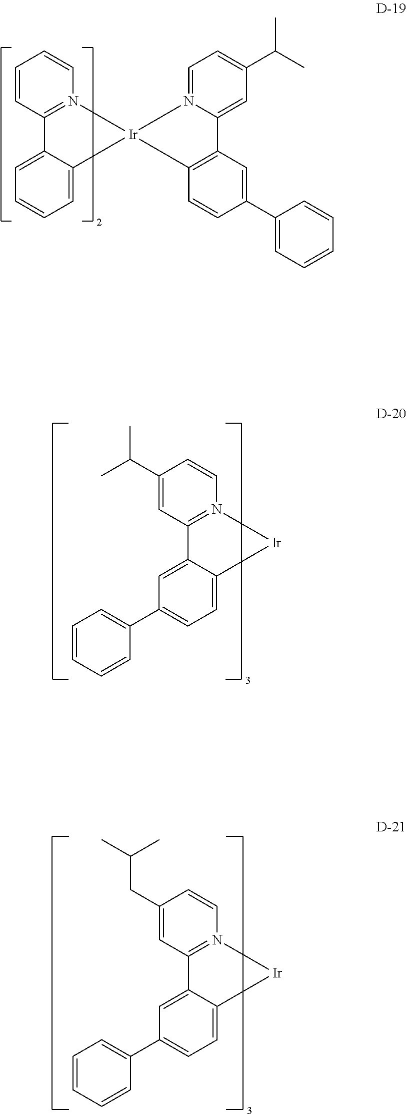

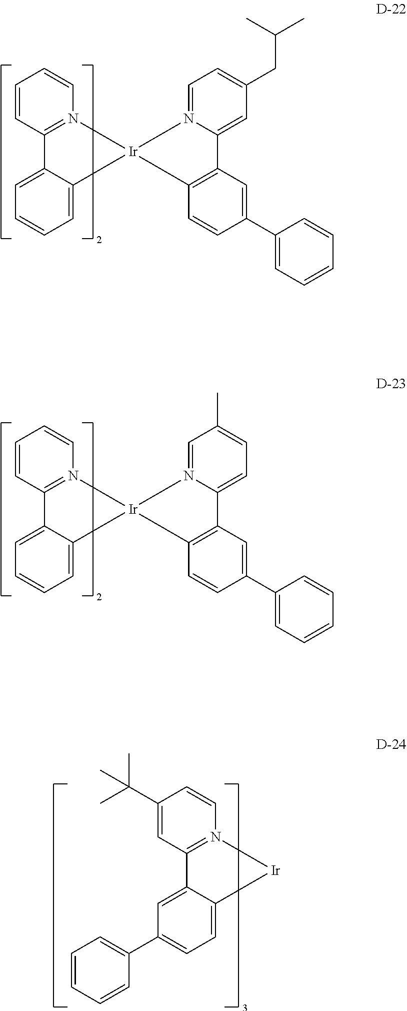

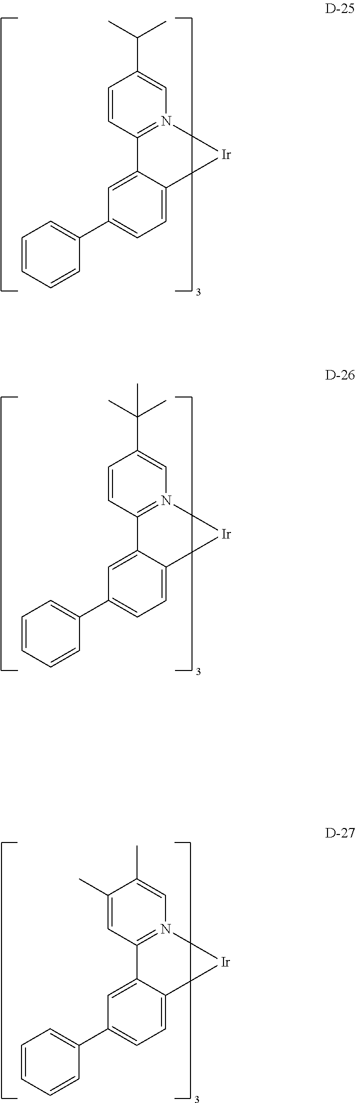

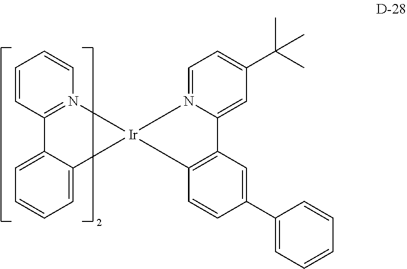

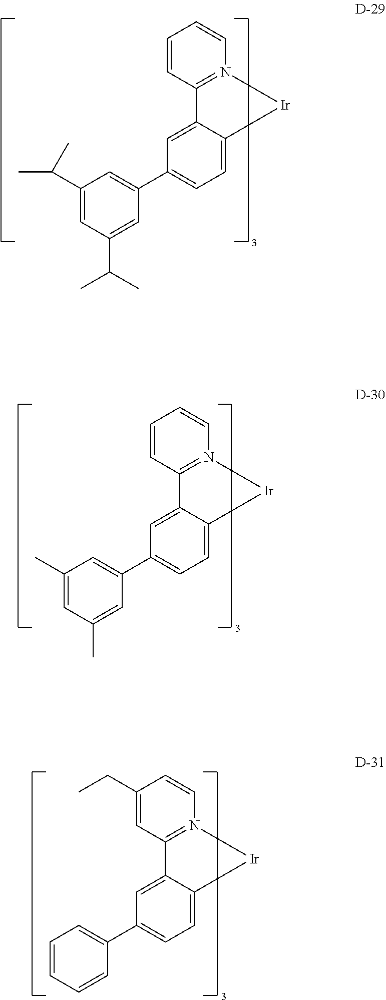

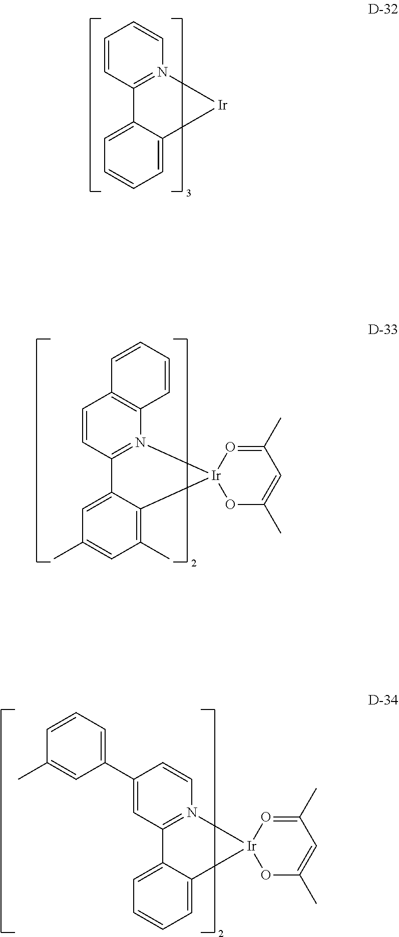

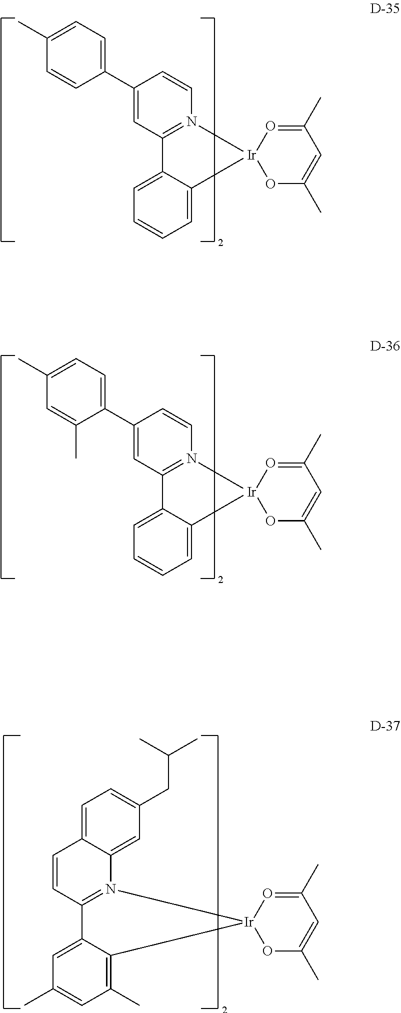

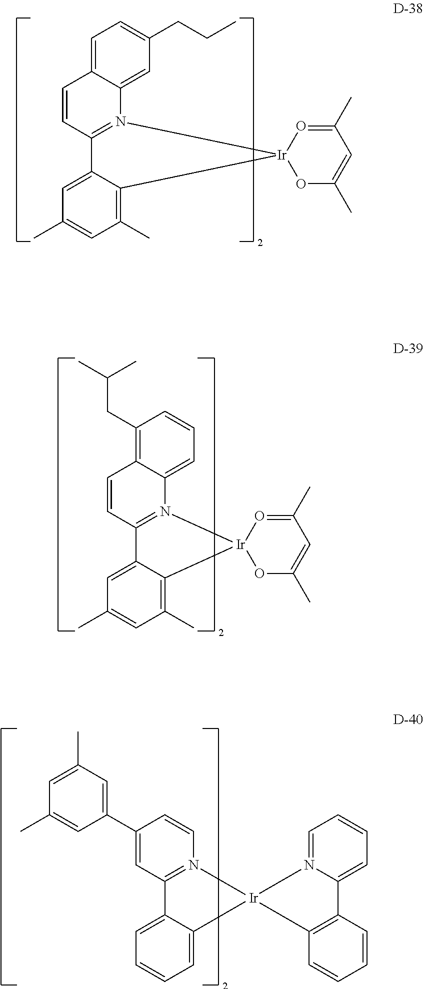

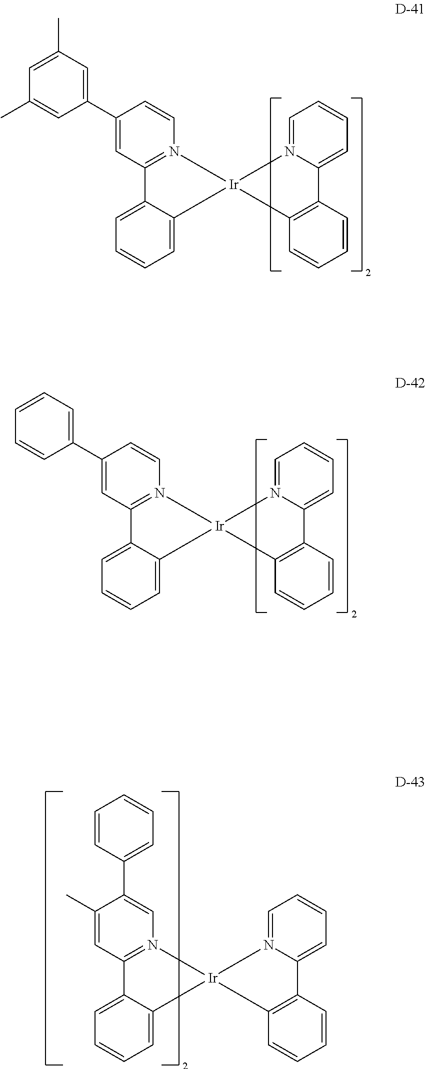

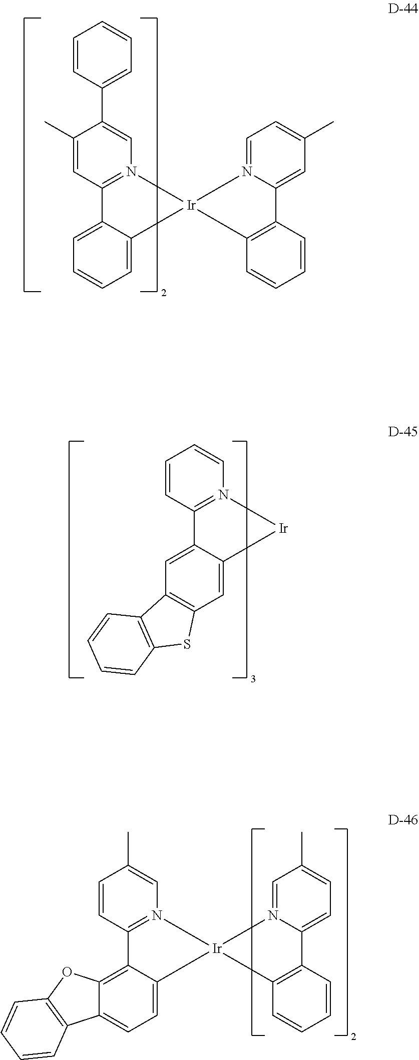

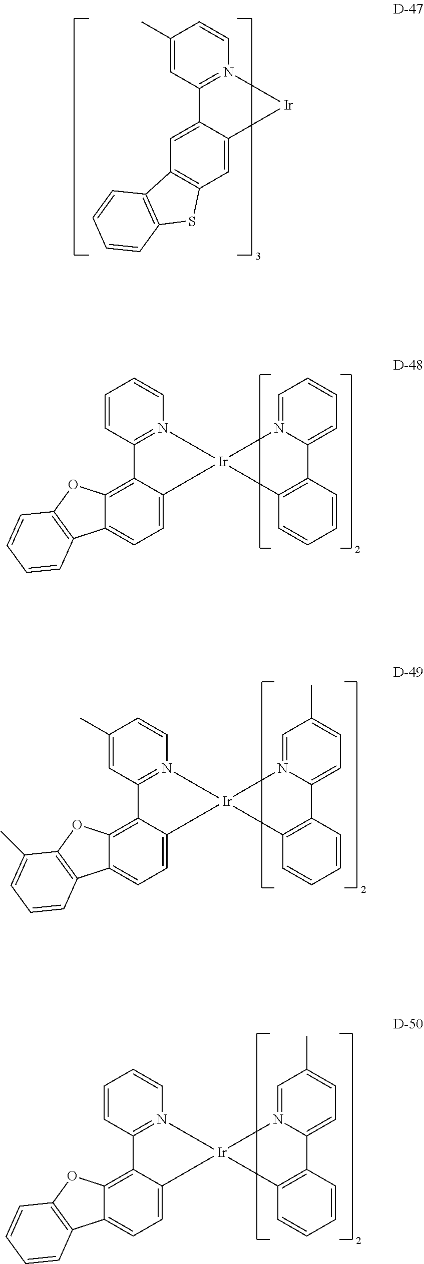

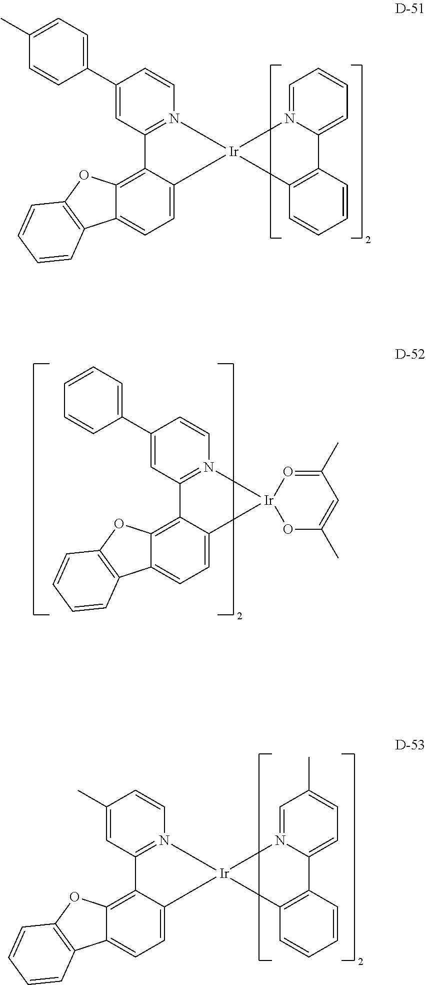

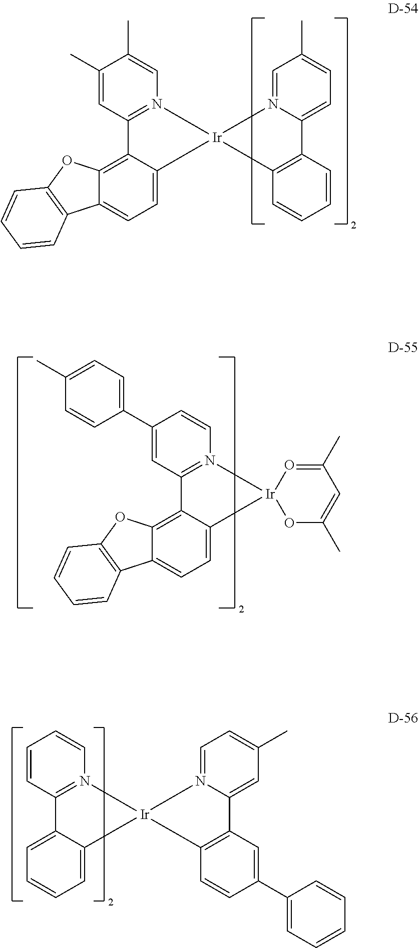

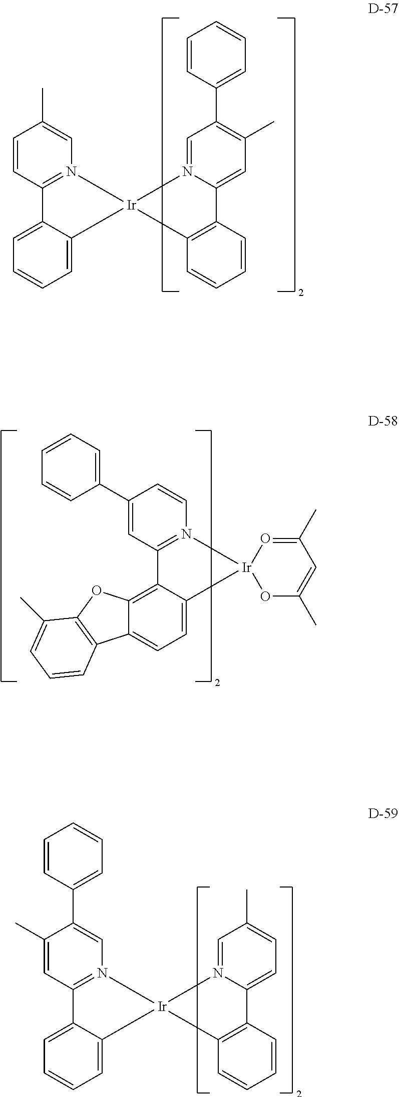

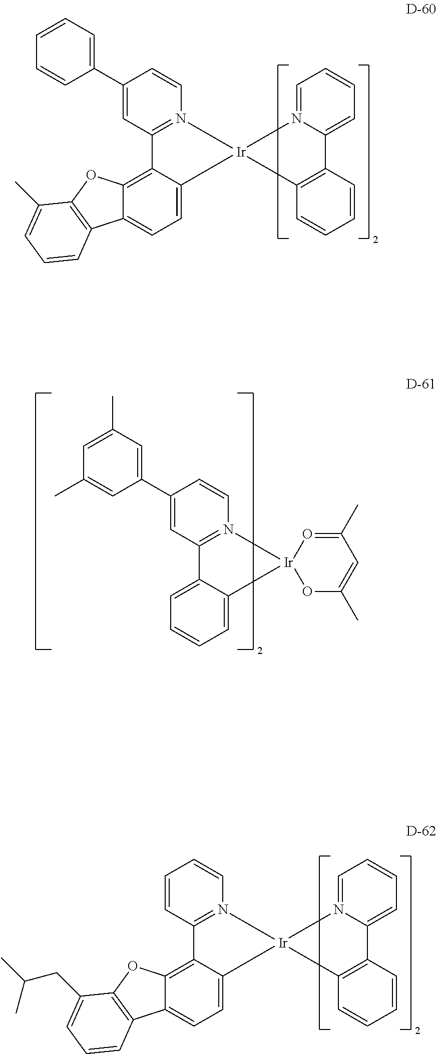

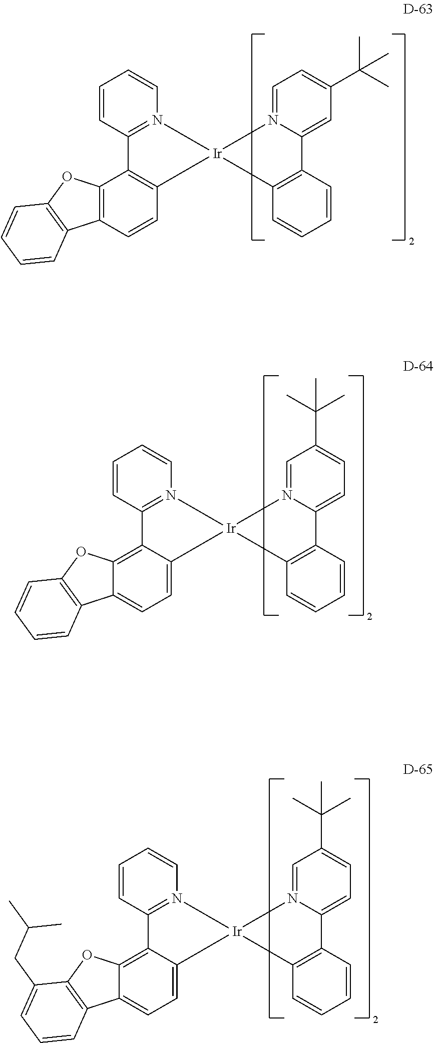

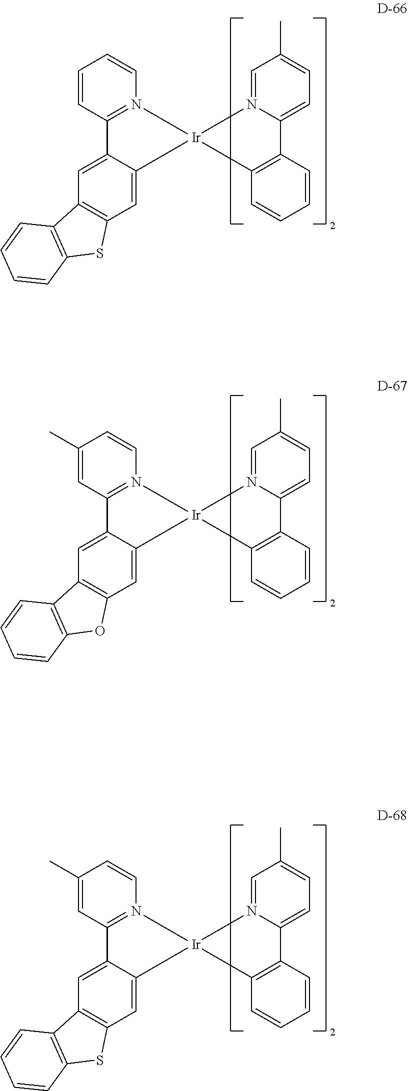

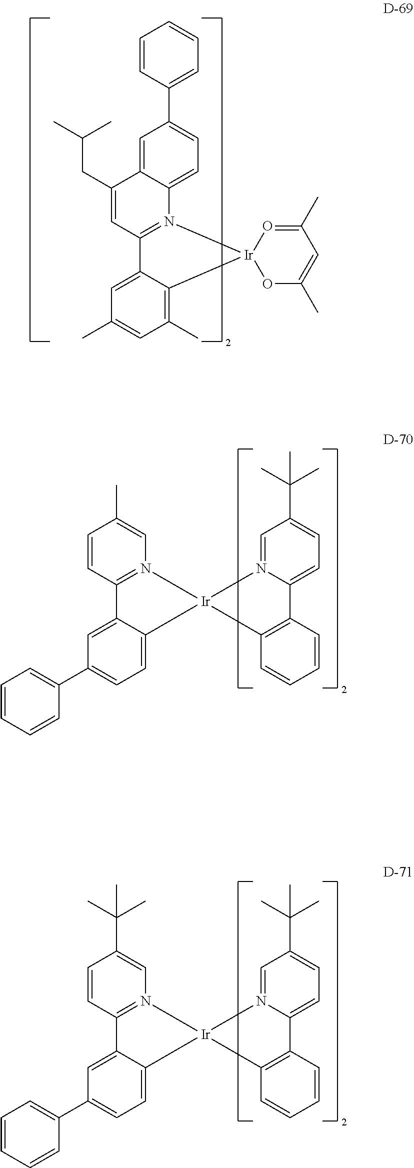

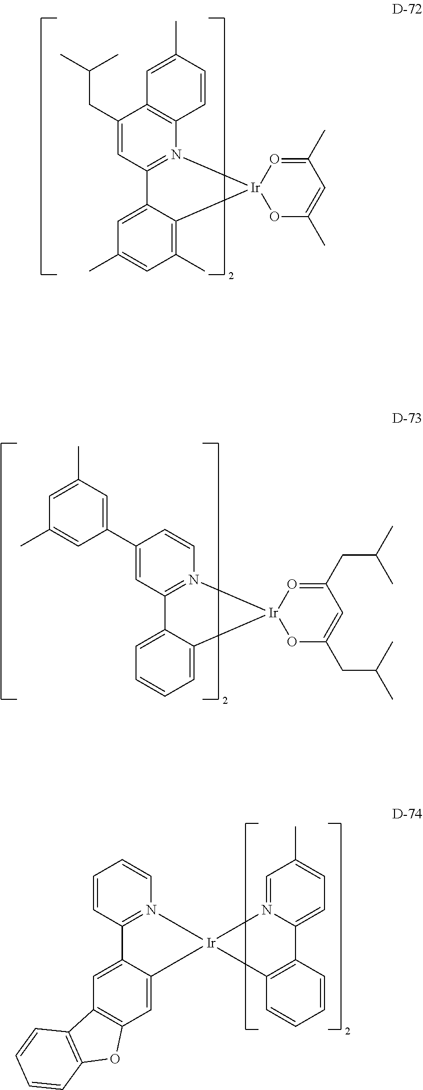

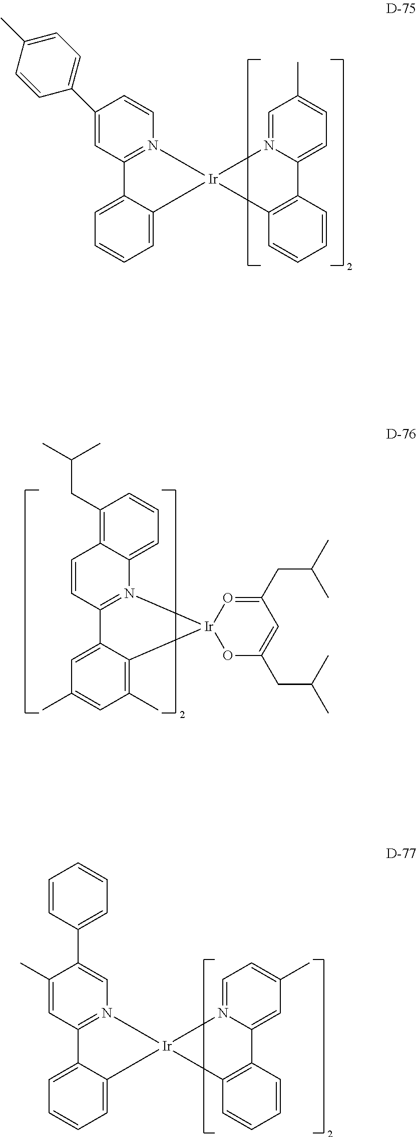

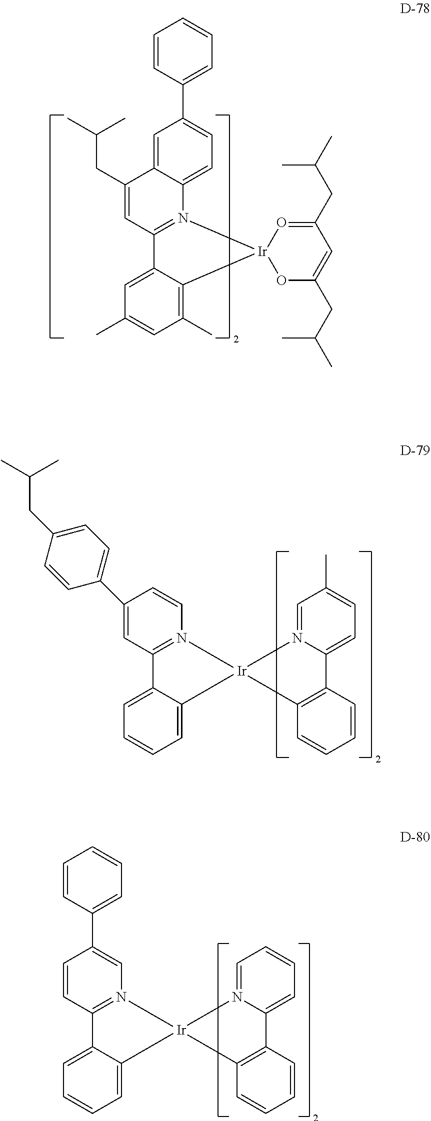

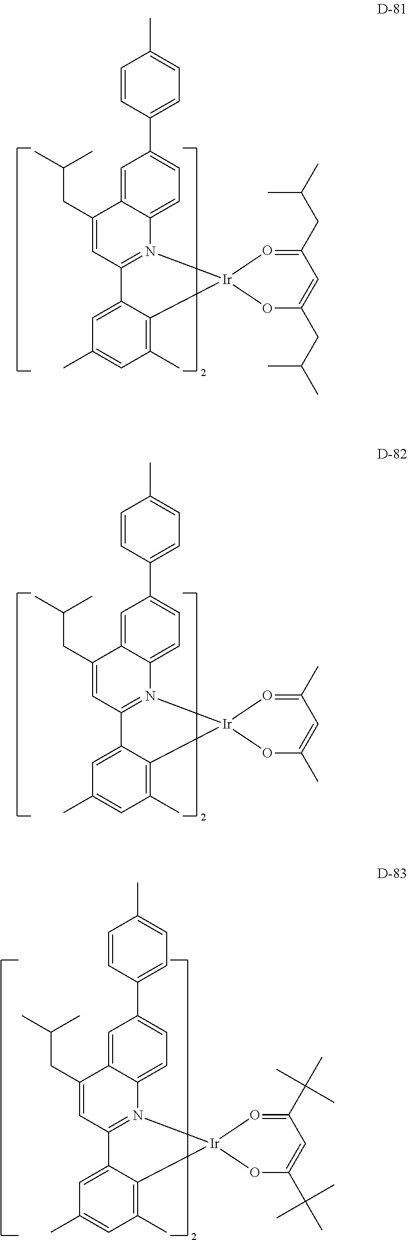

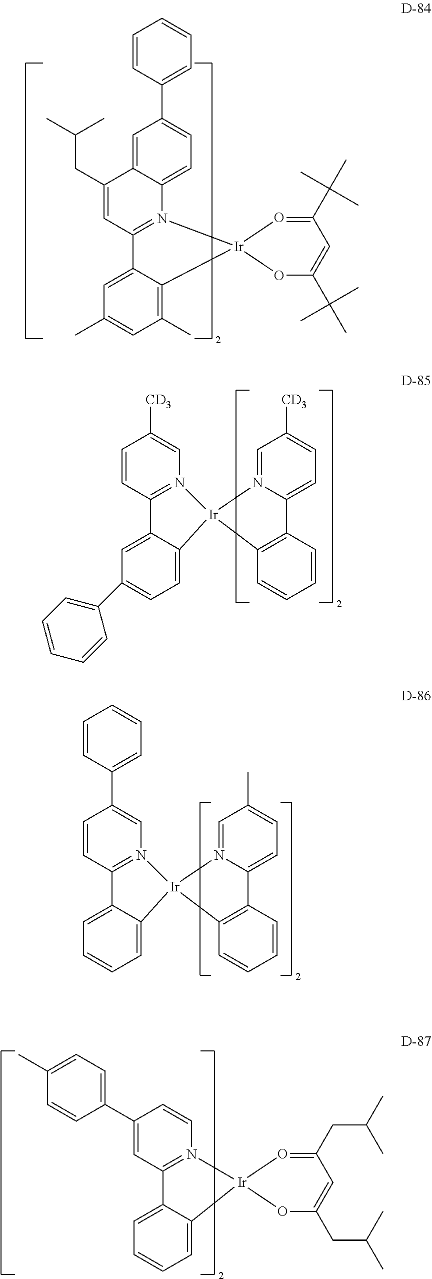

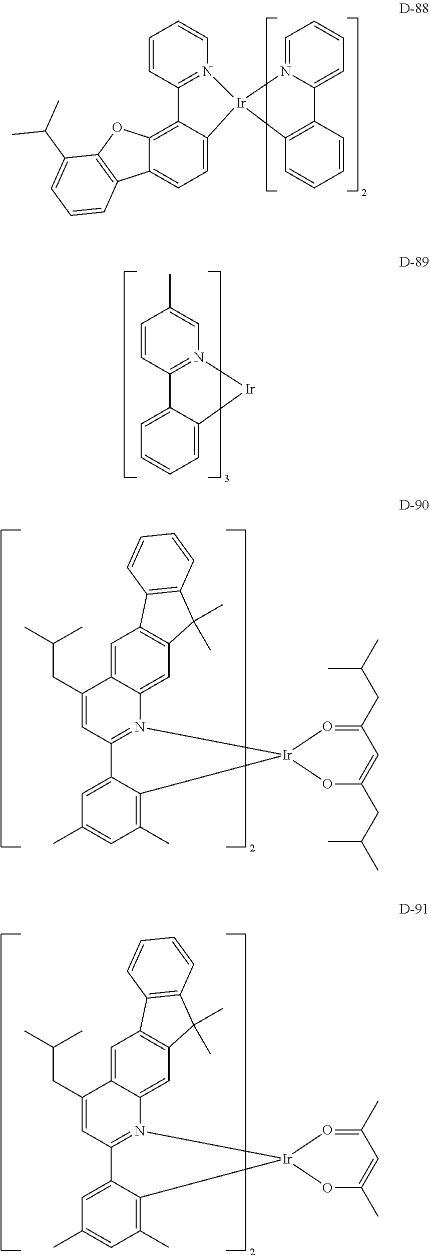

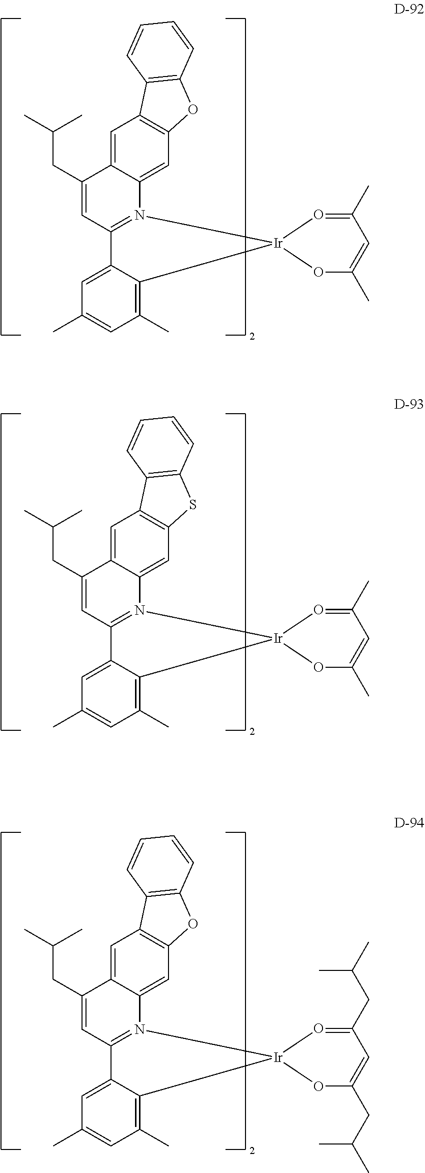

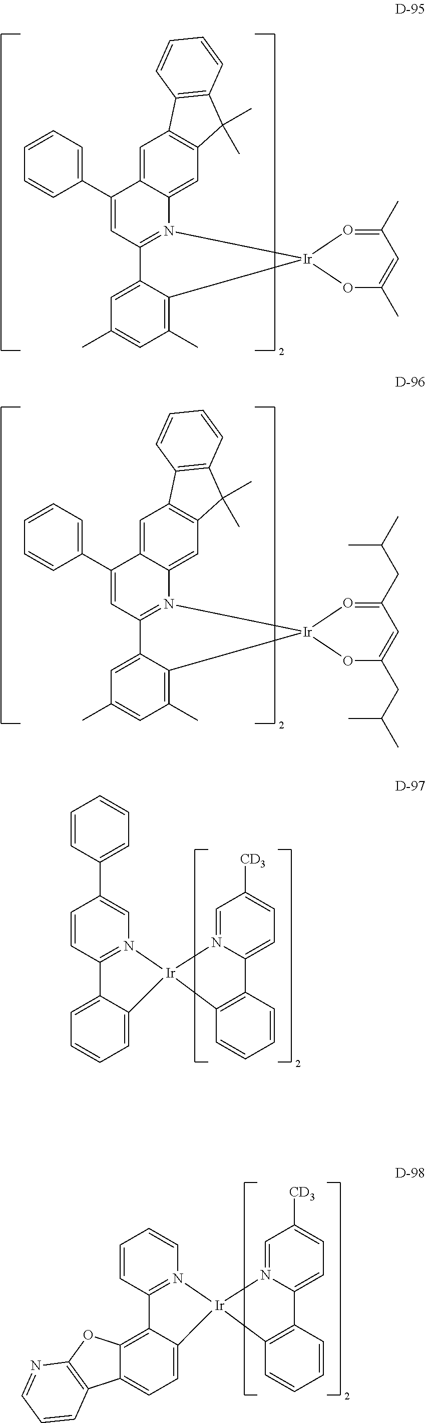

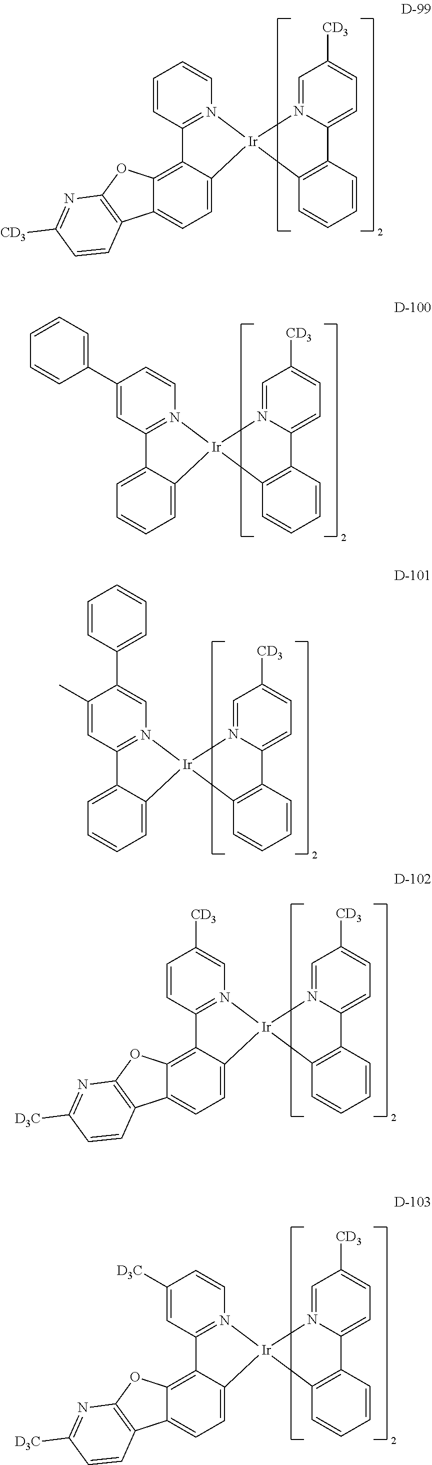

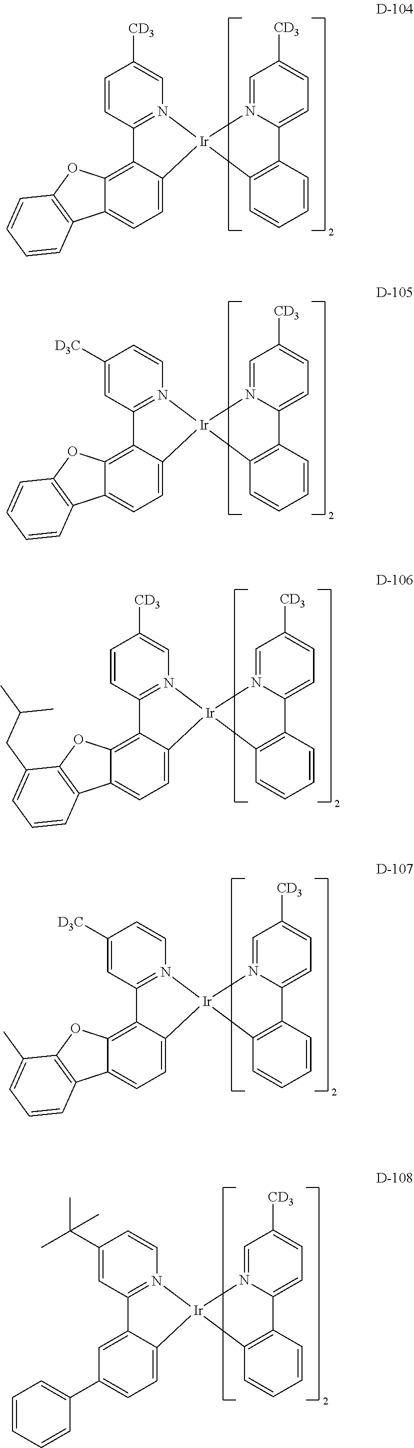

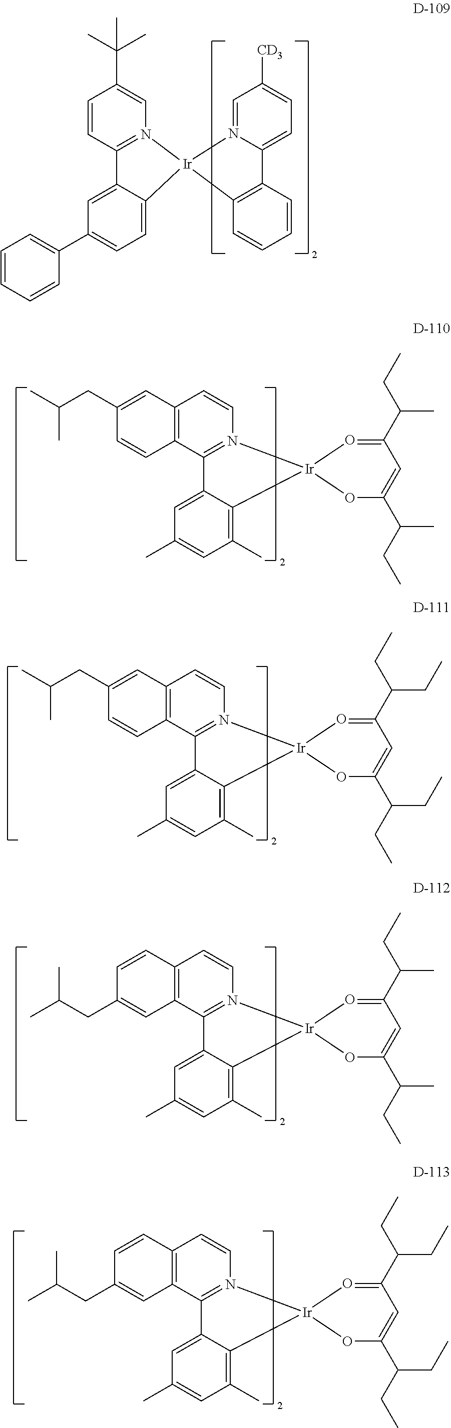

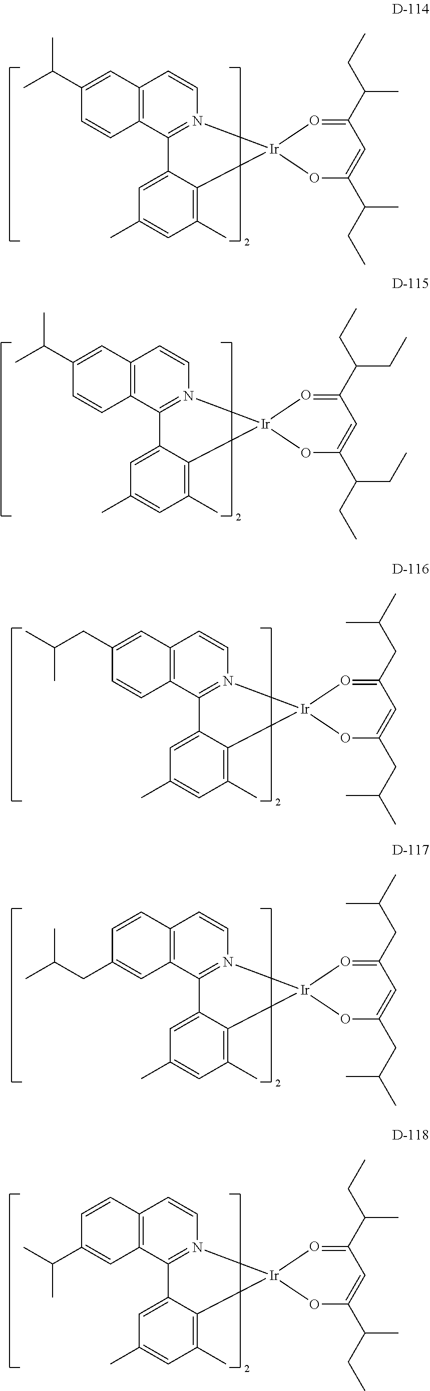

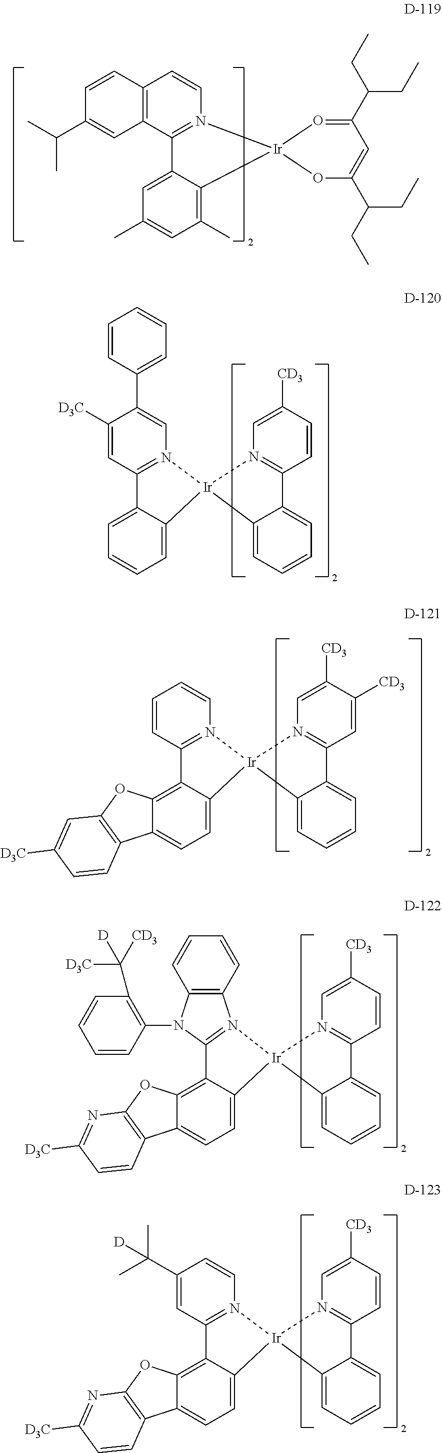

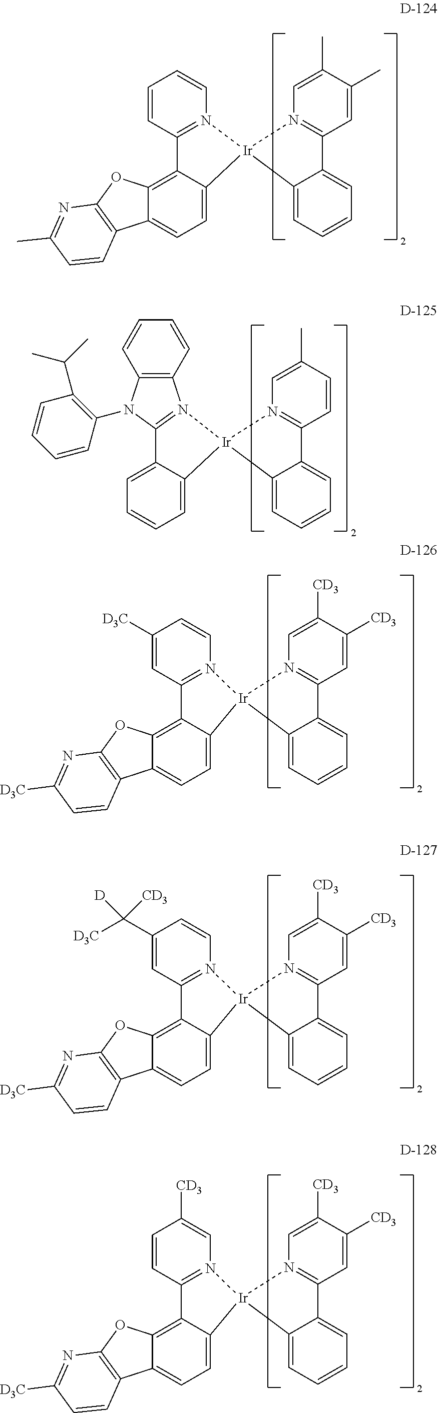

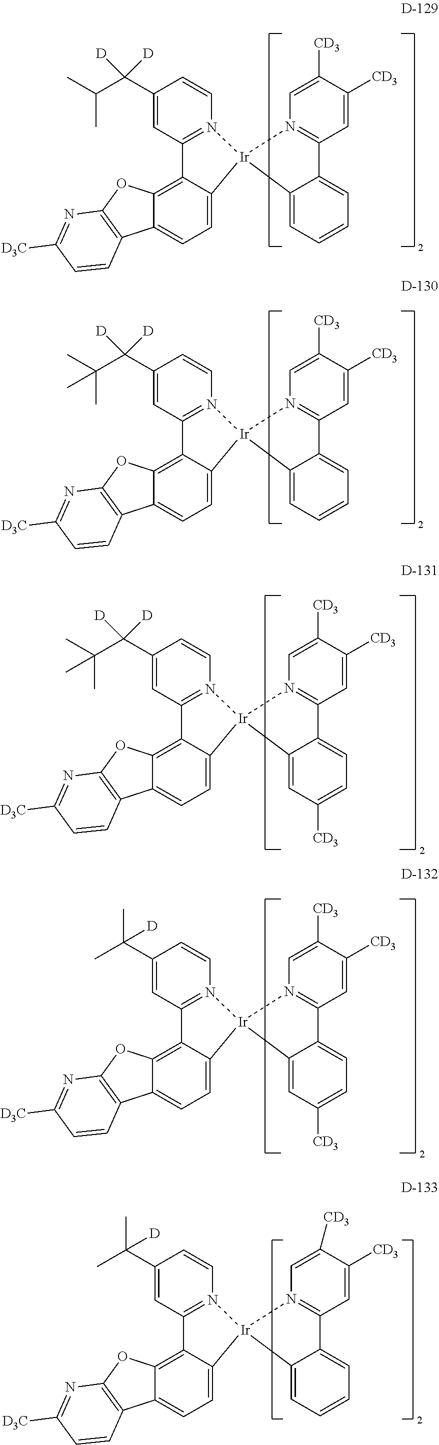

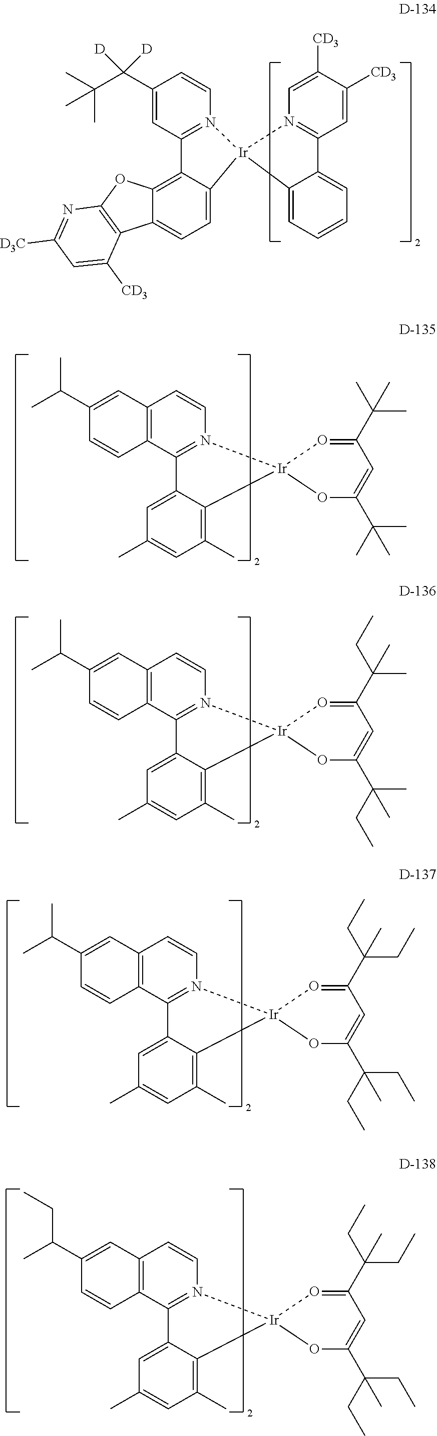

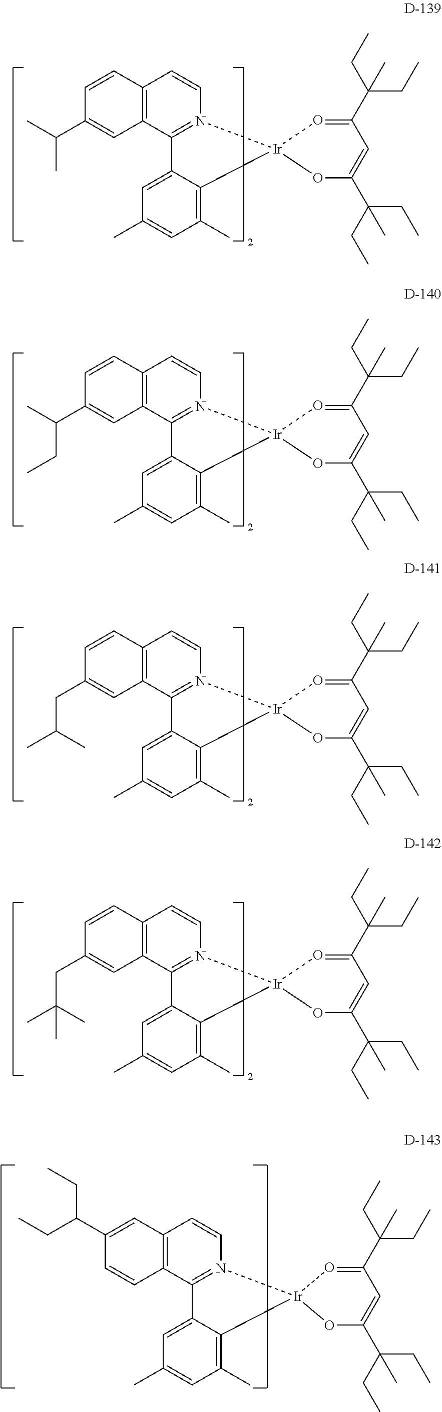

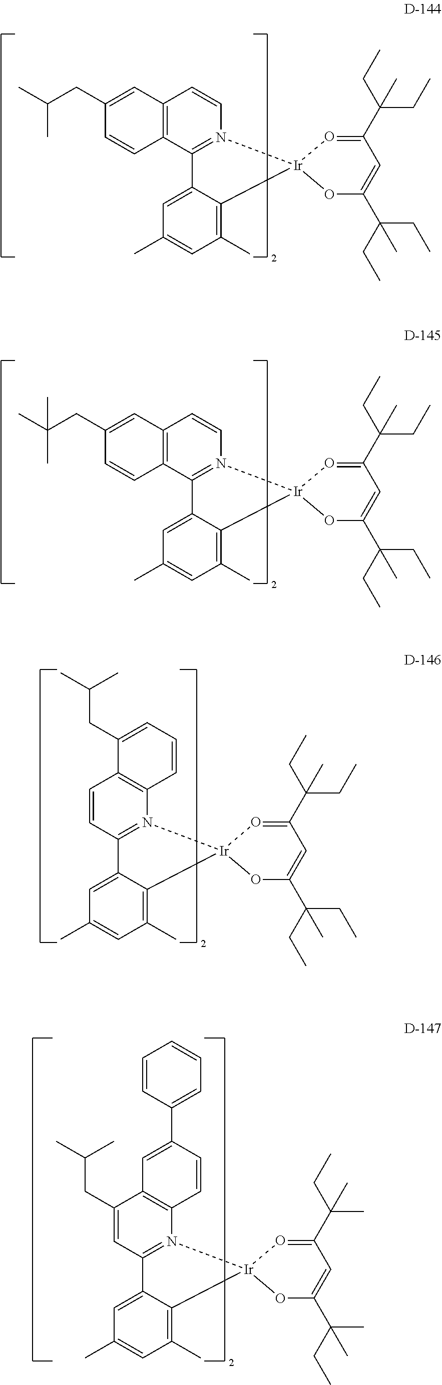

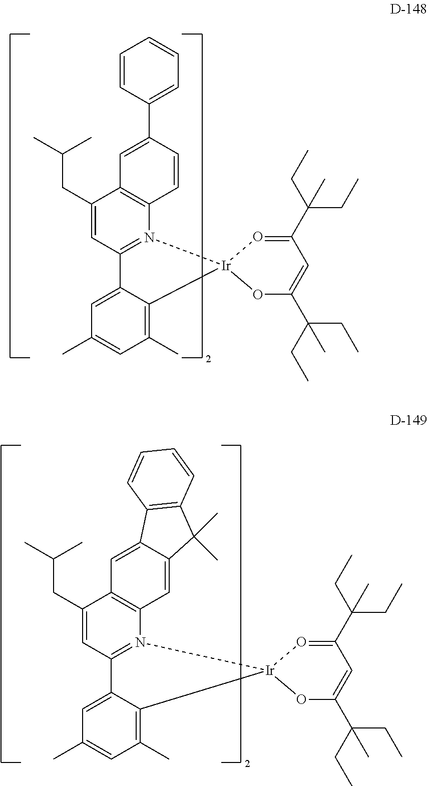

An organic electroluminescent device according to the present disclosure comprises an anode; a cathode; and at least one organic layer between the anode and the cathode. The organic layer comprises a light-emitting layer, and may further comprise at least one layer selected from a hole injection layer, a hole transport layer, a hole auxiliary layer, a light-emitting auxiliary layer, an electron transport layer, an electron buffer layer, an electron injection layer, an interlayer, a hole blocking layer, and an electron blocking layer. Each of the layers may be further configured as a plurality of layers.

The anode and the cathode may be formed of a transparent conductive material, or a transflective or reflective conductive material. The organic electroluminescent device may be a top emission type, a bottom emission type, or a both-sides emission type depending on the types of materials forming the anode and the cathode. The hole injection layer may further be doped with a p-dopant, and the electron injection layer may further be doped with an n-dopant.

The organic layer may further comprise at least one selected from the group consisting of arylamine-based compounds and styrylamine-based compounds. In addition, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising the metal.

In addition, the organic electroluminescent device according to the present disclosure may emit white light by further comprising at least one light-emitting layer, which comprises a blue, a red, or a green electroluminescent compound known in the field, besides the compound of the present disclosure. If necessary, it may further comprise a yellow or an orange light-emitting layer.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both electrode(s). Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. Such a surface layer provides operation stability for the organic electroluminescent device. Preferably, the chalcogenide includes SiO_{X}(1≤X≤2), AlO_{X}(1≤X≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

A hole injection layer, a hole transport layer, an electron blocking layer, or a combination thereof can be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. The hole transport layer or the electron blocking layer may also be multi-layers.

An electron buffer layer, a hole blocking layer, an electron transport layer, an electron injection layer, or a combination thereof can be used between the light-emitting layer and the cathode. The electron buffer layer may be multi-layers in order to control the electron injection and improve the interfacial properties between the light-emitting layer and the electron injection layer, wherein each of the multi-layers may use two compounds simultaneously. The hole blocking layer or the electron transport layer may also be multi-layers, wherein each layer may use a plurality of compounds.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer may be placed between the hole transport layer (or hole injection layer) and the light-emitting layer, and may be effective to promote or block the hole transport rate (or the hole injection rate), thereby enabling the charge balance to be controlled. Further, the electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. When an organic electroluminescent device includes two or more hole transport layers, the hole transport layer, which is further included, may be used as the hole auxiliary layer or the electron blocking layer. The light-emitting auxiliary layer, the hole auxiliary layer, or the electron blocking layer may have an effect of improving the efficiency and/or the lifespan of the organic electroluminescent device.

Further, in the organic electroluminescent device of the present disclosure a mixed region of an electron transport compound and a reductive dopant, or a mixed region of a hole transport compound and an oxidative dopant may be preferably placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation, and thus it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare-earth metals, and mixtures thereof. A reductive dopant layer may be employed as a charge generating layer to produce an organic electroluminescent device having two or more light-emitting layers and emitting white light.

An organic electroluminescent material according to one embodiment may be used as light-emitting materials for a white organic light-emitting device. The white organic light-emitting device has been suggested to have various structures such as a side-by-side structure or a stacking structure depending on the arrangement of R (red), G (green) or YG (yellow green), and B (blue) light-emitting parts, or color conversion material (CCM) method, etc. In addition, the organic electroluminescent material according to one embodiment may also be applied to the organic electroluminescent device comprising a quantum dot (QD).

In order to form each layer of the organic electroluminescent device of the present disclosure, dry film-forming methods such as vacuum evaporation, sputtering, plasma, ion plating methods, etc., or wet film-forming methods such as ink jet printing, nozzle printing, slot coating, spin coating, dip coating, flow coating methods, etc., can be used. When the first and second host compounds of the present disclosure are used to form a film, a co-evaporation process or a mixture-evaporation process is carried out. When forming a film of the first host material and the second host material of the present disclosure, co-deposition or mixed deposition is performed.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

In addition, it is possible to manufacture a display system, for example, a display system for smart phones, tablets, notebooks, PCs, TVs, or cars; or a lighting system, for example, an outdoor or indoor lighting system by using the organic electroluminescent device of the present disclosure.

Hereinafter, the preparation method of the compound according to the present disclosure and the physical properties thereof, and driving voltage and luminous efficiency of the organic electroluminescent device (OLED) comprising the plurality of host materials of the present disclosure will be explained with reference to the representative compounds of the present disclosure. However, the following examples only describe the characteristics of the OLED device comprising the compound according to the present disclosure, but the present disclosure is not limited to the following examples.

### Example 1: Preparation of Compound C-235

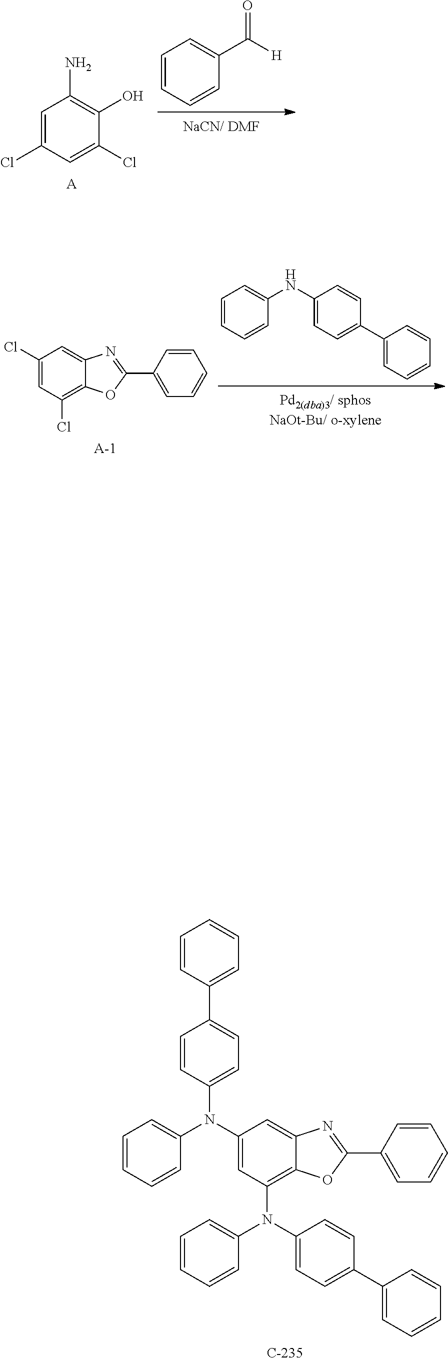

1) Synthesis of Compound A-1

Compound A (9 g, 50.6 mmol), benzaldehyde (6.44 g, 60.7 mmol), and NaCN (2.48 g, 50.6 mmol) in a flask were dissolved in 180 mL of DMF, and then stirred under reflux at 140° C. for 3 hours. After completion of the reaction, the mixture was cooled to room temperature and separated using a silica filter to obtain Compound A-1 (6.0 g, yield: 45%).

2) Synthesis of Compound C-235

Compound A-1 (4.0 g, 15.1 mmol), N,4-diphenylaniline (8.2 g, 33.3 mmol), Pd₂(dba)₃ (0.693 g, 0.757 mmol), sphos (0.622 g, 1.51 mmol), and NaOt-Bu (1.46 g, 15.1 mmol) were added to 80 mL of o-xylene and then stirred under reflux at 180° C. for 0.5 hours. Thereafter, the mixture was cooled to room temperature and separated using a silica filter to obtain Compound C-235 (4.50 g, yield: 43.6%).

| Compound | MW | M.P. | Color |
|---|---|---|---|
| C-235 | 681.82 | 130.9° C. | Yellow |

### Example 2: Preparation of Compound C-21

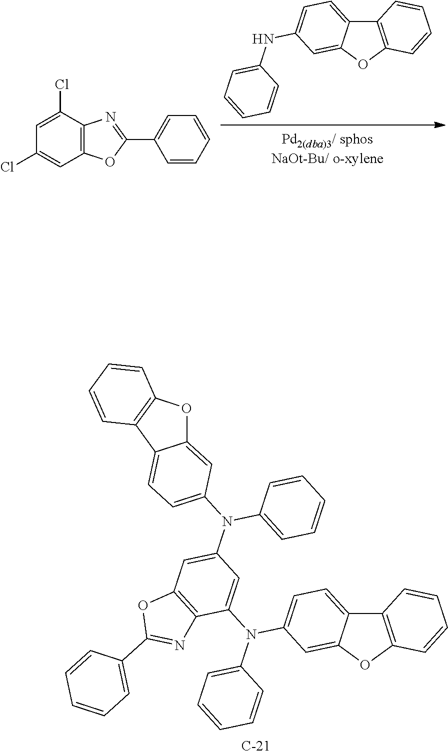

1) Synthesis of Compound C-21

Compound B (4.0 g, 15.1 mmol), N-phenyldibenzofuran-3-amine (8.05 g, 31.0 mmol), Pd₂(dba)₃ (0.693 g, 0.757 mmol), sphos (0.622 g, 1.51 mmol), and NaOt-Bu (3.64 g, 37.9 mmol) were added to 80 mL of o-xylene and then stirred under reflux at 180° C. for 2 hours. Thereafter, the mixture was cooled to room temperature and separated using a silica filter to obtain Compound C-21 (2.20 g, yield: 20.5%).

| Compound | MW | M.P. | Color |
|---|---|---|---|
| C-21 | 709.79 | 247.8° C. | Yellowish |
| | | | White |

### Example 3: Preparation of Compound C-436

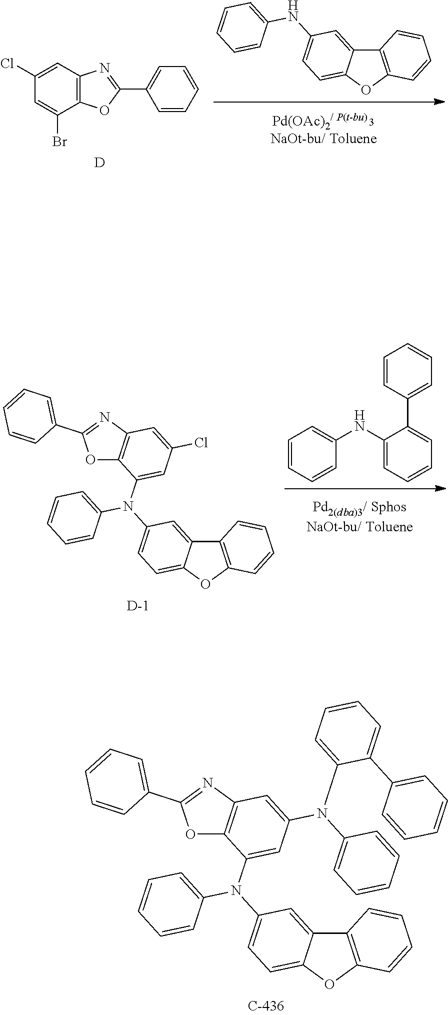

1) Synthesis of Compound 0-1

Compound D (10.0 g, 15.1 mmol), N-phenyldibenzofuran-2-amine (9.24 g, 35.6 mmol), Pd(OAc)₂ (0.728 g, 3.24 mmol), P(t-Bu)₃ (2.62 g, 6.48 mmol), and NaOt-Bu (7.79 g, 81.0 mmol) were added to 160 mL of toluene and then stirred under reflux at 180° C. for 2 hours. Thereafter, the mixture was cooled to room temperature and separated using a silica filter to obtain Compound D-1 (5.00 g, yield: 31.7%).

2) Synthesis of Compound C-436

Compound D-1 (4.4 g, 15.1 mmol), N,2-diphenylaniline (2.44 g, 9.94 mmol), Pd₂(dba)₃ (0.693 g, 0.757 mmol), sphos (0.622 g, 1.51 mmol), and NaOt-Bu (3.64 g, 37.9 mmol) were added to 50 mL of o-xylene and then stirred under reflux at 180° C. for 2 hours. Thereafter, the mixture was cooled to room temperature and separated using a silica filter to obtain Compound C-436 (2.00 g, yield: 31.8%).

| Compound | MW | M.P. | Color |
|---|---|---|---|
| C-436 | 695.81 | 179.5° C. | Yellowish |
| | | | White |

### Example 4: Preparation of Compound C-437

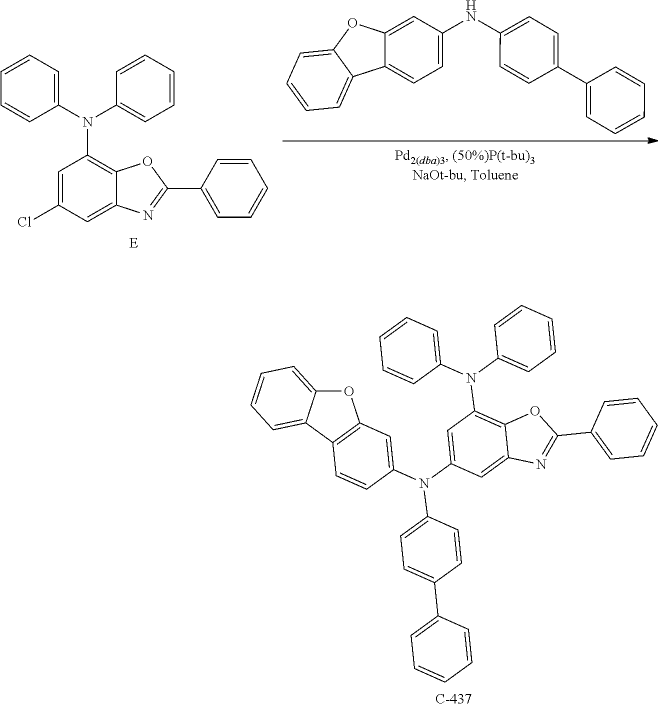 [SMILES: Clc1cc(N(c2ccccc2)c2ccccc2)c2oc(-c3ccccc3)nc2c1 ; c1ccc(-c2ccc(Nc3ccc4c(c3)oc3ccccc34)cc2)cc1 ; c1ccc(-c2ccc(N(c3cc(N(c4ccccc4)c4ccccc4)c4oc(-c5ccccc5)nc4c3)c3ccc4c(c3)oc3ccccc34)cc2)cc1]

1) Synthesis of Compound C-437

Compound E (6.2 g, 15.6 mmol), N-([1,1′-biphenyl]-4-yl)dibenzo[b,d]furan-3-amine (4.73 g, 14.1 mmol), Pd₂(dba)₃ (0.64 g, 0.7 mmol), 50% P(t-Bu)₃ (0.7 mL, 1.4 mmol), and NaOt-Bu (2.70 g, 22.0 mmol) in a flask were added to 70 mL of toluene and then stirred under reflux at 150° C. After cooling to room temperature, the mixture was filtered through a celite filter, dissolved in methylene chloride, and separated by column chromatography. After adding MeOH, the resulting solid was filtered under reduced pressure to obtain Compound C-437 (5.7 g, yield: 58%).

| Compound | MW | M.P. | Color |
|---|---|---|---|
| C-437 | 695.82 | 208° C. | Yellow |

### Device Examples 1 to 3: Manufacture of OLEDs Co-Deposited with the First Host Compound and the Second Host Compound According to the Present Disclosure

An OLED according to the present disclosure was manufactured. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and then was stored in isopropyl alcohol. The ITO substrate was mounted on a substrate holder of a vacuum vapor deposition apparatus. Compound HI-1 was introduced into a cell of the vacuum vapor deposition apparatus, and compound HT-1 was introduced into another cell. The two materials were evaporated at different rates, and compound HI-1 was deposited in a doping amount of 3 wt % based to the total amount of compound HI-1 and compound HT-1 to form a hole injection layer with a thickness of 10 nm. Subsequently, compound HT-1 was deposited on the hole injection layer to form a first hole transport layer with a thickness of 80 nm. Next, compound HT-2 was introduced into another cell of the vacuum vapor deposition apparatus and was evaporated by applying an electric current to the cell, thereby depositing a second hole transport layer with a thickness of 60 nm on the first hole transport layer. After forming the hole injection layer and the hole transport layers, a light-emitting layer was deposited thereon as follows: the first host compound and the second host compound shown in Table 1 below were respectively introduced into two cells of the vacuum vapor deposition apparatus as hosts, and compound D-39 was introduced into another cell as a dopant. The two host compounds were evaporated at a rate of 1:1 and the dopant material was simultaneously evaporated at a different rate, and the dopant was deposited in a doping amount of 3 wt % based on the total amount of the hosts and dopant to form a light-emitting layer with a thickness of 40 nm on the second hole transport layer. Then, compound ET-1 and compound EI-1 were evaporated at a weight ratio of 50:50 as an electron transport material to form an electron transport layer having a thickness of 35 nm on the light-emitting layer. After depositing compound EI-1 as an electron injection layer with a thickness of 2 nm on the electron transport layer, an Al cathode was deposited with a thickness of 80 nm on the electron injection layer by using another vacuum vapor deposition apparatus, thereby producing an OLED. All the materials used for manufacturing the OLED were purified by vacuum sublimation at 10-6 torr.

### Device Comparative Example 1: Manufacture of an OLED Comprising a Comparative Compound Alone as a Host

An OLED was manufactured in the same manner as in Device Example 1, except that H2-146 was used alone as the second host compound as a host of the light-emitting layer.

The driving voltage, the luminous efficiency, and the light-emitting color at a luminance of 1,000 nit, and the time taken for luminance to decrease from 100% to 95% at a luminance of 10,000 nit (lifespan; T95) of the OLEDs produced in Device Examples 1 to 3 and Device Comparative Example 1 are shown in Table 1 below.

TABLE 1

| | | | | | | Life- |
|---|---|---|---|---|---|---|
| | | | Driving | Luminous | Light- | span |
| | First | Second | Voltage | Efficiency | Emitting | T95 |
| | Host | Host | [V] | [cd/A] | color | [hr] |
| Device | C-235 | H2-146 | 3.1 | 36.0 | Red | 41.0 |
| Example 1 | | | | | | |
| Device | C-21 | H2-146 | 3.4 | 35.3 | Red | 141.0 |
| Example 2 | | | | | | |
| Device | C-436 | H2-146 | 3.4 | 35.2 | Red | 34.1 |
| Example 3 | | | | | | |
| Device | — | H2-146 | 3.5 | 31.8 | Red | 17.7 |
| Compar- | | | | | | |
| ative | | | | | | |
| Example 1 | | | | | | |

From Table 1 above, it can be confirmed that the OLEDs comprising a specific combination of compounds according to the present disclosure as host materials (Device Examples 1 to 3) exhibit excellent luminous efficiency and lifespan characteristics while having an equivalent or higher driving voltage, compared to the OLED (Device Comparative Example 1) that do not contain a plurality of host materials according to the present disclosure.

The compounds used in Device Examples 1 to 3 and Device Comparative Example 1 above are shown in Table 2 below.

TABLE 2

| | |
|---|---|
| Hole Injection Layer/ Hole Transport Layer | 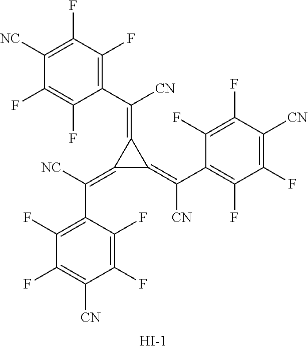 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; [I-]] |
| | 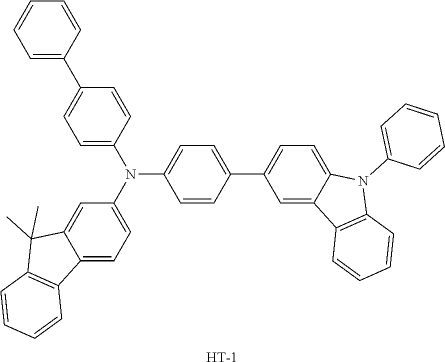 |
| | 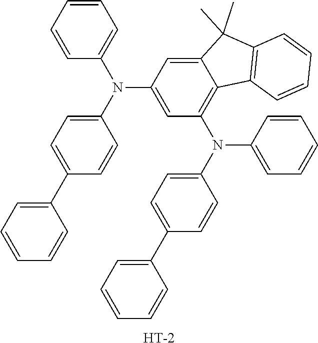 |
| Light-Emitting Layer | 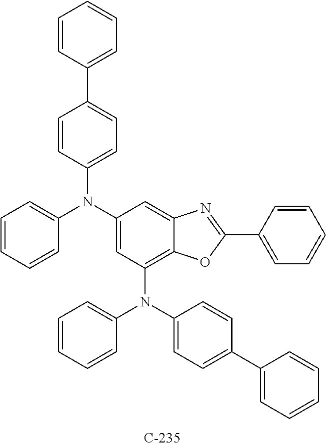 [SMILES: c1ccc(-c2ccc(N(c3ccccc3)c3cc(N(c4ccccc4)c4ccc(-c5ccccc5)cc4)c4oc(-c5ccccc5)nc4c3)cc2)cc1] |
| | 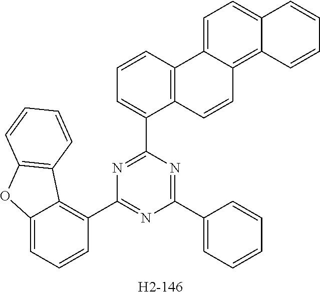 [SMILES: c1ccc(-c2nc(-c3cccc4c3ccc3c5ccccc5ccc43)nc(-c3cccc4oc5ccccc5c34)n2)cc1 ; "H2-146"] |
| | 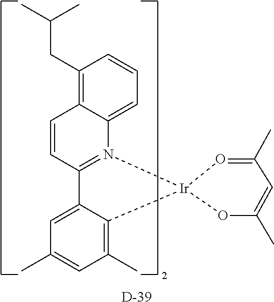 |
| | 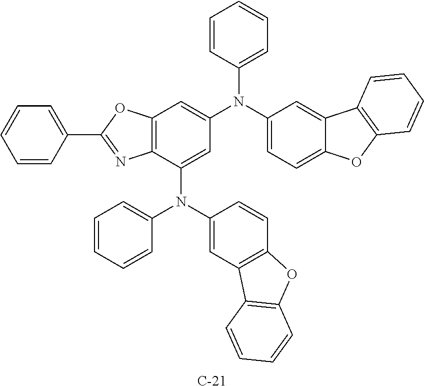 |
| | 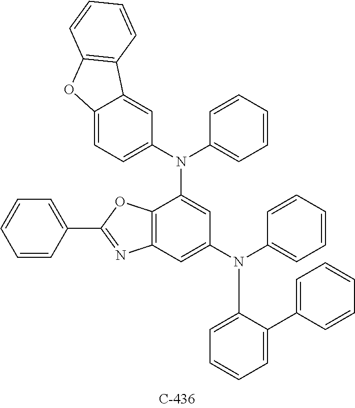 [SMILES: c1ccc(-c2nc3cc(N(c4ccccc4)c4ccccc4-c4ccccc4)cc(N(c4ccccc4)c4ccc5oc6ccccc6c5c4)c3o2)cc1] |
| Electron transport Layer/ Electron Injection Layer | 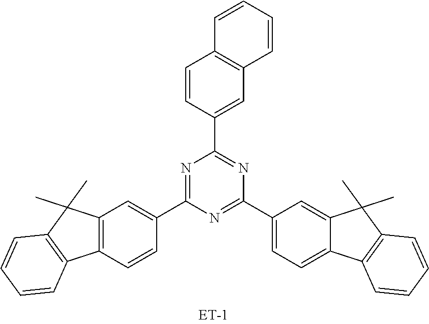 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | 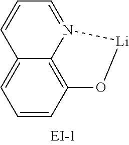 |

### Device Example 4: Manufacture of an OLED Deposited with the Second Hole Transport Layer According to the Present Disclosure

An OLED according to the present disclosure was manufactured. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and then was stored in isopropyl alcohol. The ITO substrate was mounted on a substrate holder of a vacuum vapor deposition apparatus. Compound HI-1 was introduced into a cell of the vacuum vapor deposition apparatus, and Compound HT-3 was introduced into another cell. The two materials were evaporated at different rates, and Compound HI-1 was deposited in a doping amount of 3 wt % based on the total amount of Compound HI-1 and compound HT-3 to form a first hole injection layer with a thickness of 10 nm. Subsequently, Compound HT-3 was deposited on the first hole injection layer to form a first hole transport layer with a thickness of 90 nm. Next, Compound C-235 was introduced into another cell of the vacuum vapor deposition apparatus and was evaporated by applying an electric current to the cell, thereby depositing a second hole transport layer with a thickness of 60 nm on the first hole transport layer. After forming the hole injection layer and the hole transport layers, a light-emitting layer was deposited thereon as follows: the host compound shown in Table 4 below was introduced into two cells of the vacuum vapor deposition apparatus as a host, and Compound 0-1 was introduced into another cell as a dopant. The two materials were evaporated at different rates, and the dopant was deposited in a doping amount of 2 wt % based on the total amount of the host and dopant to form a light-emitting layer with a thickness of 40 nm on the second hole transport layer. Subsequently, compound HBL was deposited on the light-emitting layer to form an electron buffer layer with a thickness of 5 nm. Then, Compound ET-2 and Compound EI-1 were evaporated at a weight ratio of 50:50 as an electron transport material to form an electron transport layer having a thickness of 30 nm on the electron buffer layer. After depositing Compound EI-1 as an electron injection layer with a thickness of 2 nm on the electron transport layer, an Al cathode was deposited with a thickness of 80 nm on the electron injection layer by using another vacuum vapor deposition apparatus, thereby producing an OLED. All the materials used for manufacturing the OLED were purified by vacuum sublimation at 10-6 torr.

### Device Comparative Example 2

An OLED was manufactured in the same manner as in Device Example 4, except that Compound F was used as a material for the second hole transport layer.

The driving voltage, the luminous efficiency, and the light-emitting color at a luminance of 1,000 nit of the OLEDs produced in Device Example 4 and Device Comparative Example 2 manufactured as described above are shown in Table 3 below.

TABLE 3

| | | Driving | Luminous | Light- |
|---|---|---|---|---|
| | Second Hole | Voltage | Efficiency | Emitting |
| | Transport Layer | [V] | [lm/W] | color |
| Device | C-235 | 3.1 | 27.9 | Red |
| Example 4 | | | | |
| Device | F | 4.0 | 26.6 | Red |
| Comparative | | | | |
| Example 2 | | | | |

From Table 3 above, it can be confirmed that the OLED comprising a specific compound according to the present disclosure as a material for a second hole transport layer (Device Example 4) exhibits an equivalent or higher luminous efficiency with much lower driving voltage, compared to the OLED (Device Comparative Example 2) that does not contain a specific compound according to the present disclosure as a material for a second hole transport layer.

The compounds used in Device Example 4 and Device Comparative Example 2 above are shown in Table 4 below.

TABLE 4

| | |
|---|---|
| Hole Injection Layer/ First Hole Transport Layer | 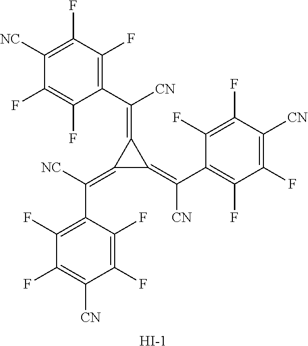 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; [I-]] |
| | 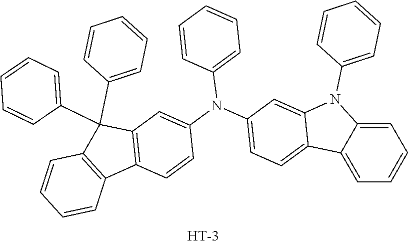 |
| Second Hole Transport Layer | 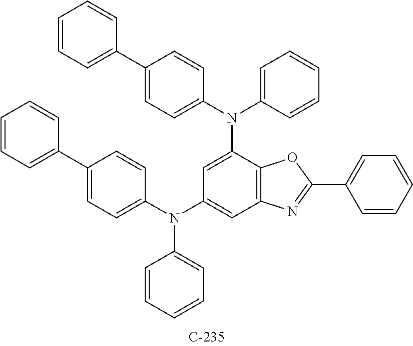 [SMILES: c1ccc(-c2ccc(N(c3ccccc3)c3cc(N(c4ccccc4)c4ccc(-c5ccccc5)cc4)c4oc(-c5ccccc5)nc4c3)cc2)cc1] |
| | 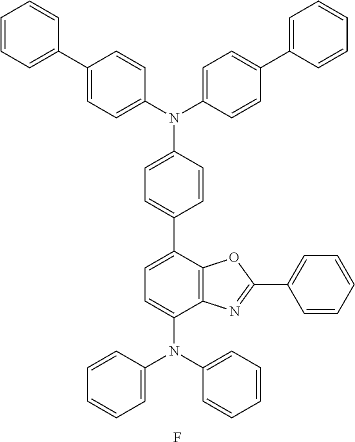 |
| Light Emitting Layer/ Electron Buffer Layer | 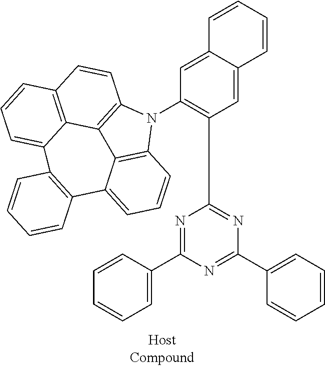 [SMILES: c1ccc(-c2nc(-c3ccccc3)nc(-c3cc4ccccc4cc3-n3c4cccc5c4c4c6c(cccc6ccc43)-c3ccccc3-5)n2)cc1] |
| | 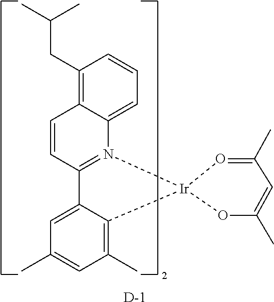 |
| | 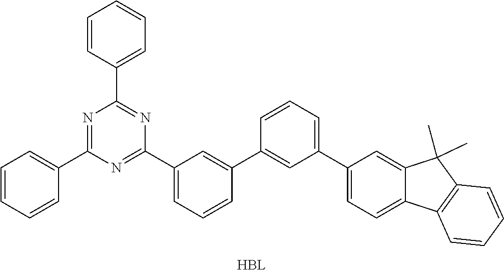 [SMILES: CC1(C)c2ccccc2-c2ccc(-c3cccc(-c4cccc(-c5nc(-c6ccccc6)nc(-c6ccccc6)n5)c4)c3)cc21] |
| Electron Transport Layer/ Electron Injection Layer | 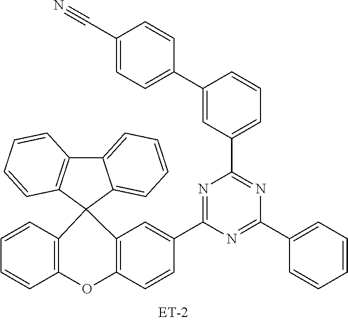 [SMILES: N#Cc1ccc(-c2cccc(-c3nc(-c4ccccc4)nc(-c4ccc5c(c4)C4(c6ccccc6O5)c5ccccc5-c5ccccc54)n3)c2)cc1] |
| | 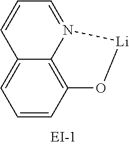 |

1. A plurality of host materials comprising at least one first host compound and at least one second host compound, wherein the first host compound is represented by the following Formula 1, and the second host compound is represented by following Formula 2: 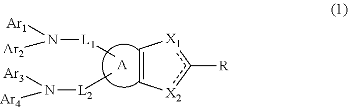
in Formula 1,
one of X₁ and X₂ represents —N═, and the other represents —O— or —S—;
R represents a substituted or unsubstituted (C1-C30)alkyl, a substituted or unsubstituted (C6-C30)aryl, or a substituted or unsubstituted (3- to 30-membered)heteroaryl;
ring A represents (C6-C12)arene;
L₁ and L₂ each independently represent a single bond, a substituted or unsubstituted (C6-C30)arylene, or a substituted or unsubstituted (3- to 30-membered)heteroarylene; and
Ar₁ to Ar₄ each independently represent a substituted or unsubstituted (C6-C30)aryl, or a substituted or unsubstituted (3- to 30-membered)heteroaryl; 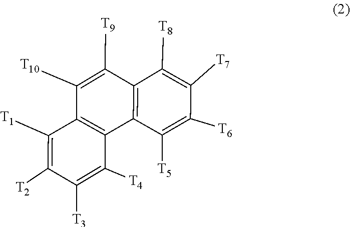
in Formula 2,
T₅ and T₆, T₇ and T₈, or both thereof are linked to each other to form a ring of the following Formula 3; 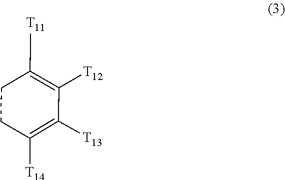
in Formulas 2 and 3,
T₁ to T₄, T₉ to T₁₄, and T₅ to T₈ that do not form a ring(s) each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, a substituted or unsubstituted (C6-C30)aryl(3- to 30-membered)heteroarylamino, or -L₃-Ar₅, provided that at least one of T₁ to T₁₄ represents -L₃-Ar₅;
L₃ each independently represents a single bond, a substituted or unsubstituted (C6-C30)arylene, or a substituted or unsubstituted (3- to 30-membered)heteroarylene;
Ar₅ each independently represents a substituted or unsubstituted (C6-C30)aryl, or a substituted or unsubstituted (3- to 30-membered)heteroaryl; [symbol]
represents a fusion site with Formula 2; and
the heteroaryl and the heteroarylene contain one or more heteroatoms selected from B, N, O, S, Si and P.

2. The plurality of host materials according to claim 1, wherein the substituent(s) of the substituted alkyl, the substituted aryl, the substituted arylene, the substituted heteroaryl, the substituted heteroarylene, the substituted cycloalkyl, the substituted alkoxy, the substituted trialkylsilyl, the substituted dialkylarylsilyl, the substituted alkyldiarylsilyl, the substituted triarylsilyl, the substituted fused ring group of an aliphatic ring(s) and an aromatic ring(s), the substituted mono- or di-alkylamino, the substituted mono- or di-alkenylamino, the substituted alkylalkenylamino, the substituted mono- or di-arylamino, the substituted alkylarylamino, the substituted mono- or di-heteroarylamino, the substituted alkylheteroarylamino, the substituted alkenylarylamino, the substituted alkenylheteroarylamino, and the substituted arylheteroarylamino are each independently at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (3- to 30-membered)heteroaryl unsubstituted or substituted with at least one of a (C1-C30)alkyl(s) and a (C6-C30)aryl(s); a (C6-C30)aryl unsubstituted or substituted with at least one of deuterium, a cyano(s), a halogen(s), a (C1-C30)alkyl(s), a (C3-C30)cycloalkyl(s), a tri(C1-C30)alkylsilyl(s), a tri(C6-C30)arylsilyl(s), a (C6-C30)aryl(s), and a (3- to 30-membered)heteroaryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsilyl; a fused ring group of a (C3-C30) aliphatic ring(s) and a (C6-C30) aromatic ring(s); an amino; a mono- or di-(C1-C30)alkylamino; a mono- or di-(C2-C30)alkenylamino; a (C1-C30)alkyl(C2-C30)alkenylamino; a mono- or di-(C6-C30)arylamino; a (C1-C30)alkyl(C6-C30)arylamino; a mono- or di-(3- to 30-membered)heteroarylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a (C6-C30)arylphosphine; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

3. The plurality of host materials according to claim 1, wherein Formula 1 is represented by at least one of the following Formulas 4 to 6: 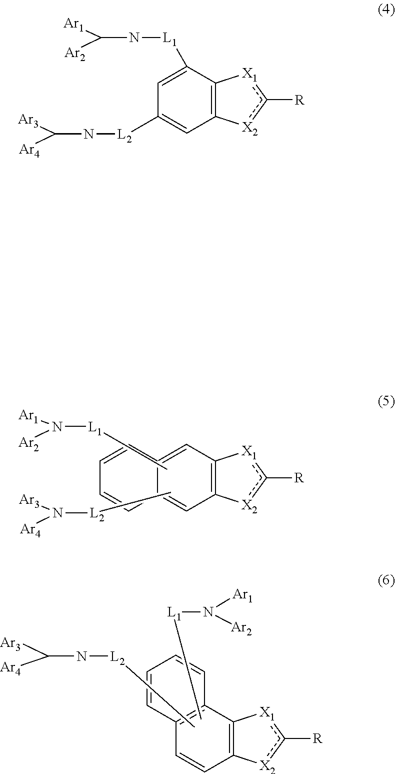
in Formulas 4 to 6, R, X₁, X₂, L₁, L₂, and Ar₁ to Ar₄ are as defined in claim 1.

4. The plurality of host materials according to claim 1, wherein R and Ar₁ to Ar₄ in Formula 1 are each independently a substituted or unsubstituted phenyl, a substituted or unsubstituted naphthyl, a substituted or unsubstituted biphenyl, a substituted or unsubstituted terphenyl, a substituted or unsubstituted phenanthrenyl, a substituted or unsubstituted fluorenyl, a substituted or unsubstituted benzofluorenyl, a substituted or unsubstituted triphenylenyl, a substituted or unsubstituted spirobifluorenyl, a substituted or unsubstituted triazinyl, a substituted or unsubstituted pyrimidinyl, a substituted or unsubstituted quinolyl, a substituted or unsubstituted quinazolinyl, a substituted or unsubstituted quinoxalinyl, a substituted or unsubstituted benzoquinazolinyl, a substituted or unsubstituted benzoquinoxalinyl, a substituted or unsubstituted benzofuropyrimidinyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzonaphthofuranyl, or a substituted or unsubstituted benzonaphthothiophenyl.

5. The plurality of host materials according to claim 1, wherein Formula 2 is represented by at least one of the following Formulas 2-1 and 2-2: 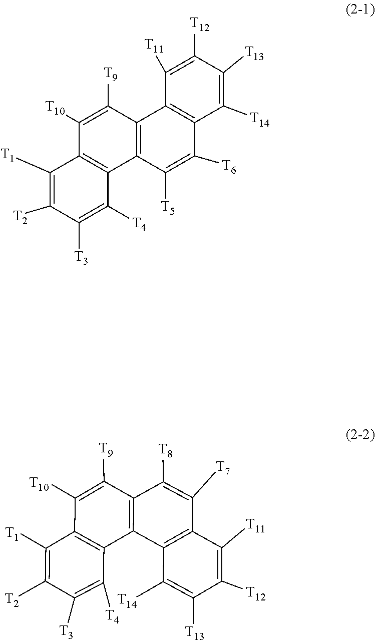
in Formulas 2-1 and 2-2,
T₁ to T₄ and T₉ to T₁₄ are as defined in claim 1, and
T₅ to T₈ are as defined for T₅ to T₈ which do not form a ring(s) in claim 1.

6. The plurality of host materials according to claim 1, wherein Formula 2 is represented by at least one of the following Formulas: 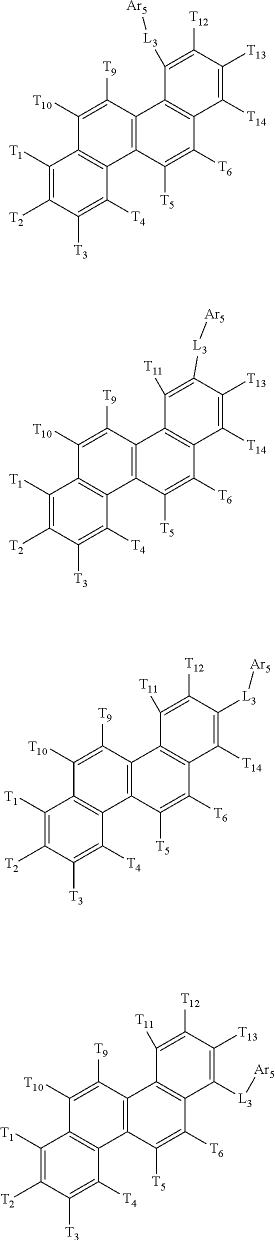 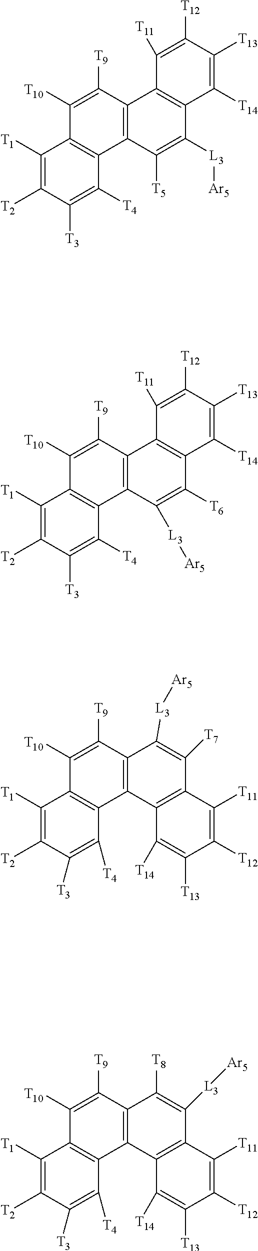 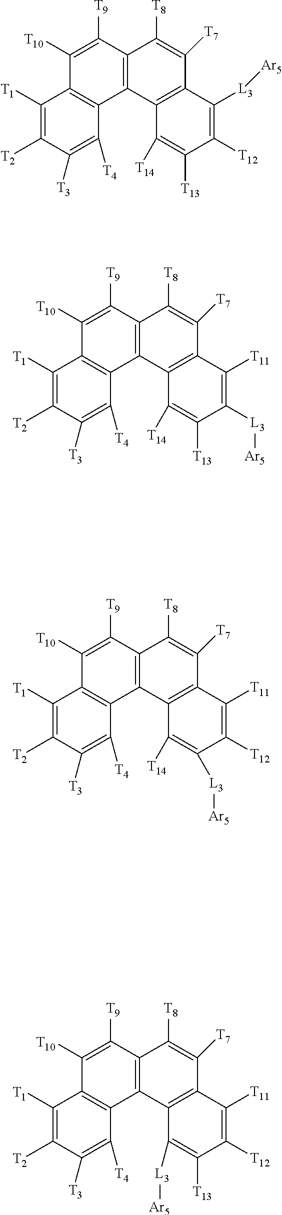
in the above Formulas,
T₁ to T₁₄ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino, and
L₃ and Ar₅ are as defined in claim 1.

7. The plurality of host materials according to claim 1, wherein Ar₅ in Formula 2 is a substituted or unsubstituted triazinyl, a substituted or unsubstituted pyrimidinyl, a substituted or unsubstituted quinolyl, a substituted or unsubstituted isoquinolyl, a substituted or unsubstituted benzothienoquinolyl, a substituted or unsubstituted naphthyridinyl, a substituted or unsubstituted quinazolinyl, a substituted or unsubstituted quinoxalinyl, a substituted or unsubstituted benzoquinazolinyl, a substituted or unsubstituted dibenzoquinazolinyl, a substituted or unsubstituted benzoquinoxalinyl, a substituted or unsubstituted dibenzoquinoxalinyl, a substituted or unsubstituted benzofuropyrimidinyl, a substituted or unsubstituted acenaphthopyrimidinyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzonaphthofuranyl, a substituted or unsubstituted benzonaphthothiophenyl, a substituted or unsubstituted benzoimidazolyl, or a substituted or unsubstituted phenanthroimidazolyl.

8. The plurality of host materials according to claim 1, wherein the compound represented by Formula 1 is at least one selected from the following compounds:

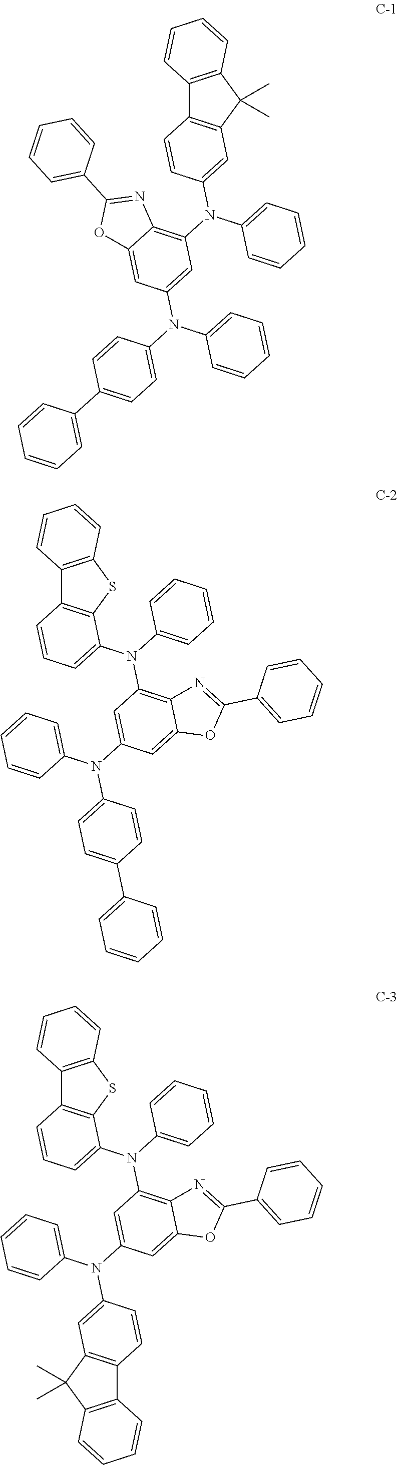

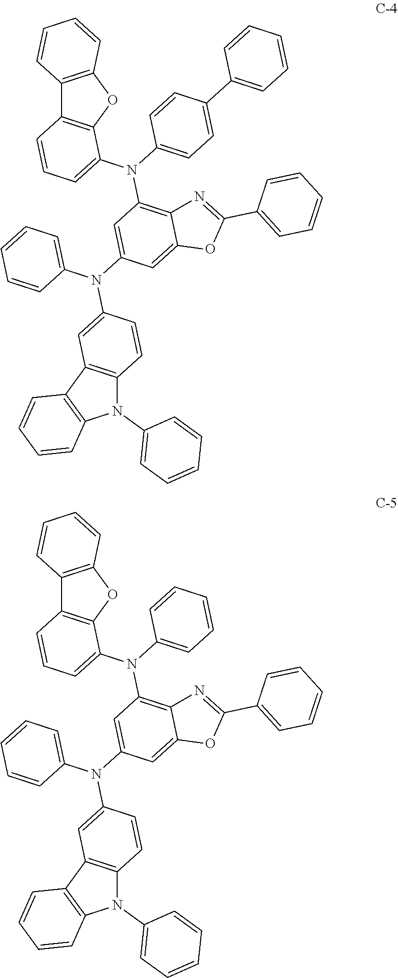 [SMILES: c1ccc(-c2ccc(N(c3cc(N(c4ccccc4)c4ccc5c(c4)c4ccccc4n5-c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccc5c(c4)c4ccccc4n5-c4ccccc4)cc3o2)cc1]

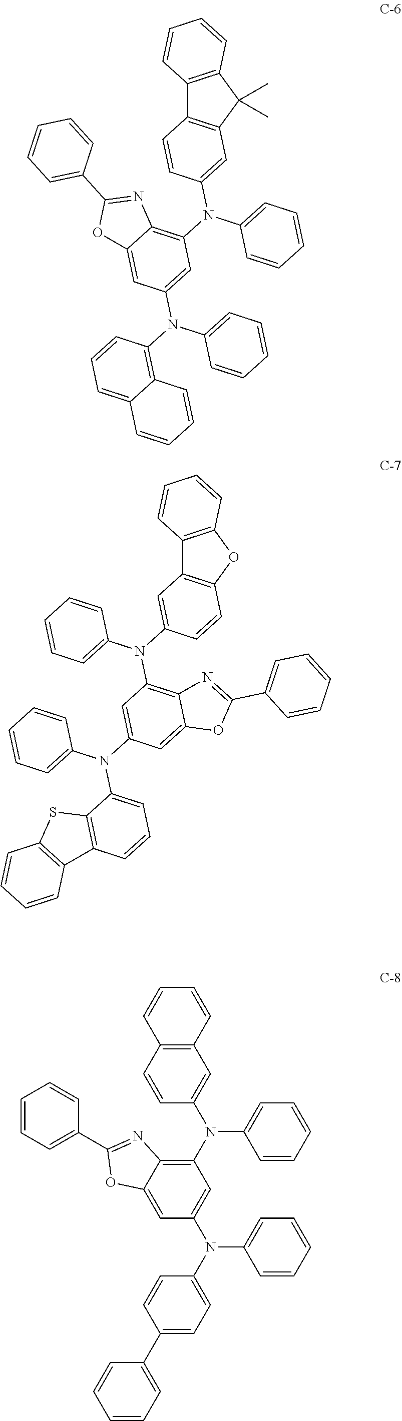

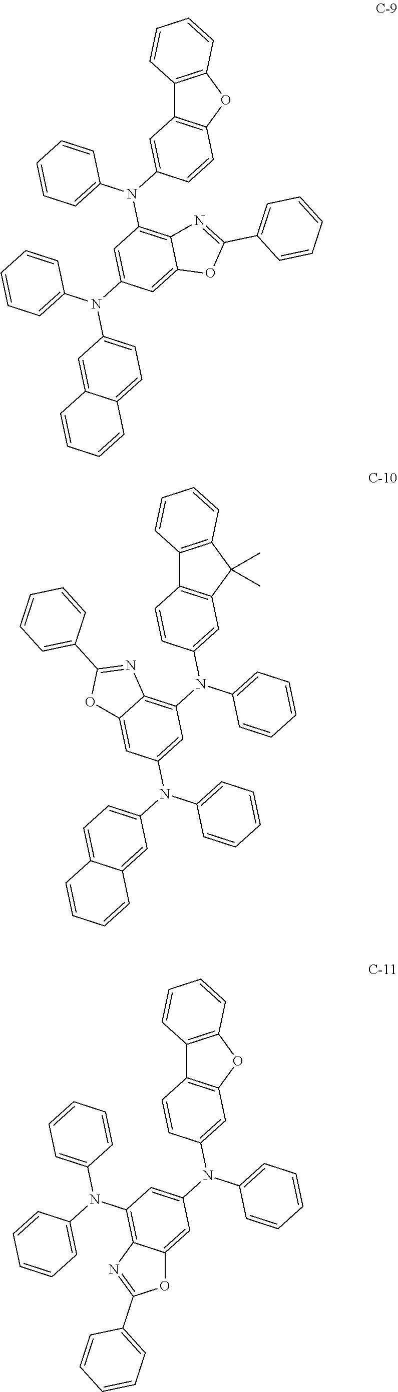 [SMILES: c1ccc(-c2nc3c(N(c4ccccc4)c4ccc5oc6ccccc6c5c4)cc(N(c4ccccc4)c4ccc5ccccc5c4)cc3o2)cc1 ; CC1(C)c2ccccc2-c2ccc(N(c3ccccc3)c3cc(N(c4ccccc4)c4ccc5ccccc5c4)cc4oc(-c5ccccc5)nc34)cc21 ; c1ccc(-c2nc3c(N(c4ccccc4)c4ccccc4)cc(N(c4ccccc4)c4ccc5c(c4)oc4ccccc45)cc3o2)cc1]

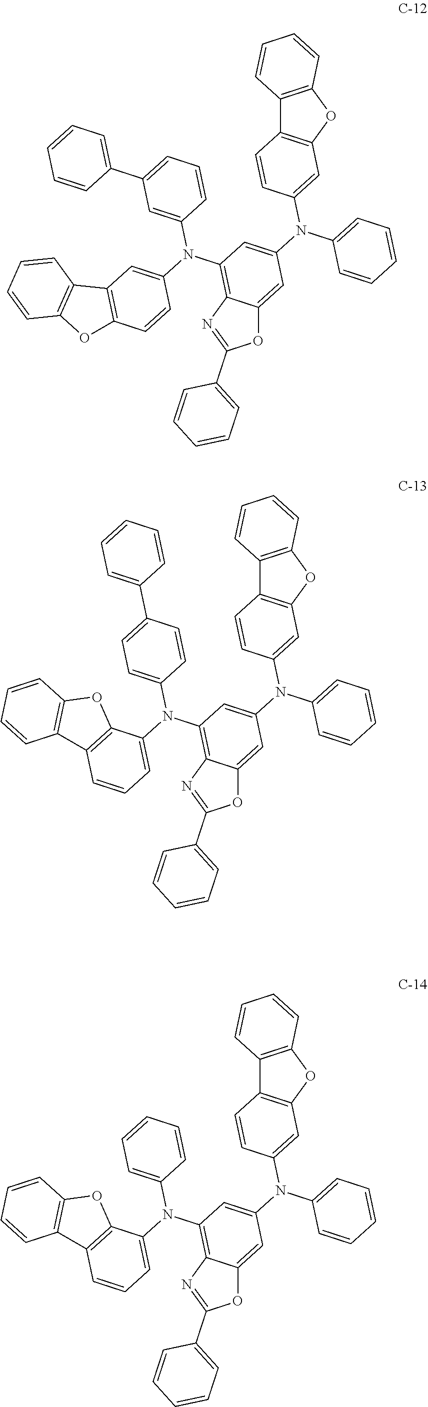 [SMILES: c1ccc(-c2cccc(N(c3ccc4oc5ccccc5c4c3)c3cc(N(c4ccccc4)c4ccc5c(c4)oc4ccccc45)cc4oc(-c5ccccc5)nc34)c2)cc1 ; c1ccc(-c2ccc(N(c3cc(N(c4ccccc4)c4ccc5c(c4)oc4ccccc45)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccc5c(c4)oc4ccccc45)cc3o2)cc1]

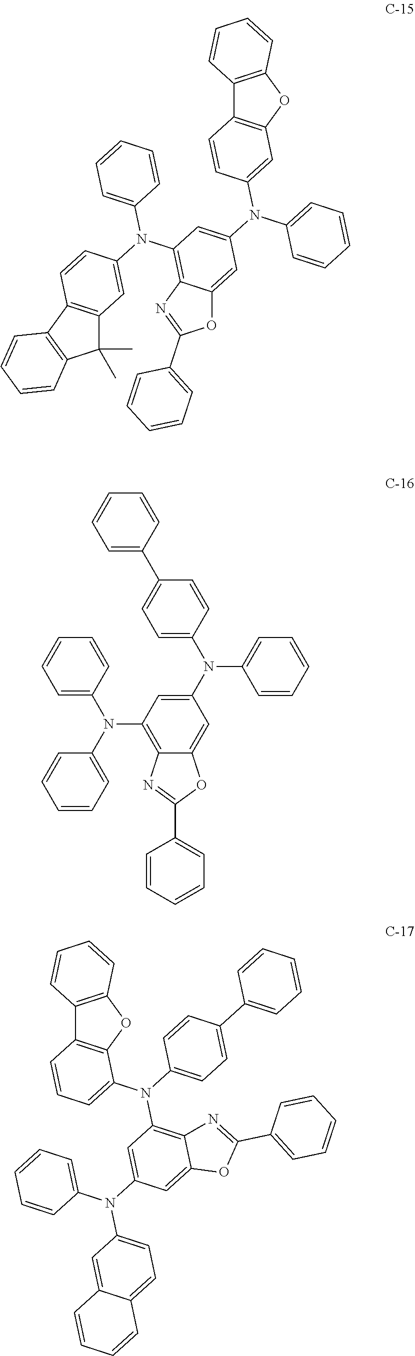 [SMILES: CC1(C)c2ccccc2-c2ccc(N(c3ccccc3)c3cc(N(c4ccccc4)c4ccc5c(c4)oc4ccccc45)cc4oc(-c5ccccc5)nc34)cc21 ; c1ccc(-c2ccc(N(c3ccccc3)c3cc(N(c4ccccc4)c4ccccc4)c4nc(-c5ccccc5)oc4c3)cc2)cc1 ; c1ccc(-c2ccc(N(c3cc(N(c4ccccc4)c4ccc5ccccc5c4)cc4oc(-c5ccccc5)nc34)c3cccc4c3oc3ccccc34)cc2)cc1]

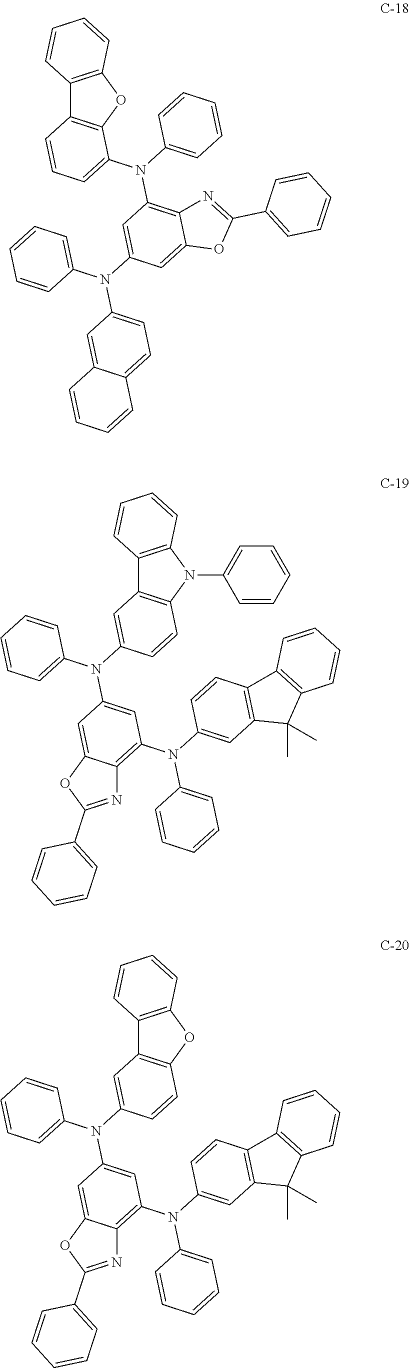 [SMILES: c1ccc(-c2nc3c(N(c4ccccc4)c4cccc5c4oc4ccccc45)cc(N(c4ccccc4)c4ccc5ccccc5c4)cc3o2)cc1 ; CC1(C)c2ccccc2-c2ccc(N(c3ccccc3)c3cc(N(c4ccccc4)c4ccc5c(c4)c4ccccc4n5-c4ccccc4)cc4oc(-c5ccccc5)nc34)cc21 ; CC1(C)c2ccccc2-c2ccc(N(c3ccccc3)c3cc(N(c4ccccc4)c4ccc5oc6ccccc6c5c4)cc4oc(-c5ccccc5)nc34)cc21]

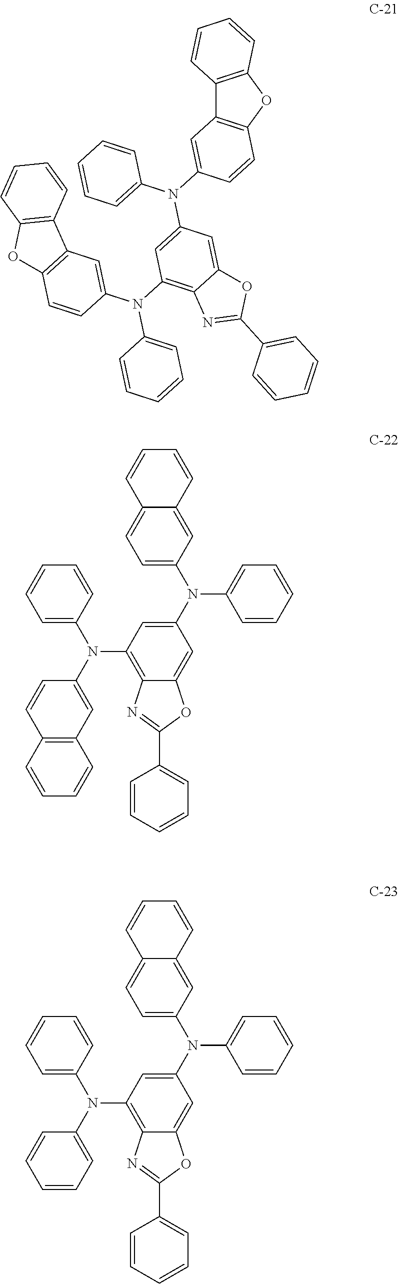 [SMILES: c1ccc(-c2nc3c(N(c4ccccc4)c4ccc5oc6ccccc6c5c4)cc(N(c4ccccc4)c4ccc5oc6ccccc6c5c4)cc3o2)cc1 ; c1ccc(-c2nc3c(N(c4ccccc4)c4ccc5ccccc5c4)cc(N(c4ccccc4)c4ccc5ccccc5c4)cc3o2)cc1 ; c1ccc(-c2nc3c(N(c4ccccc4)c4ccccc4)cc(N(c4ccccc4)c4ccc5ccccc5c4)cc3o2)cc1]

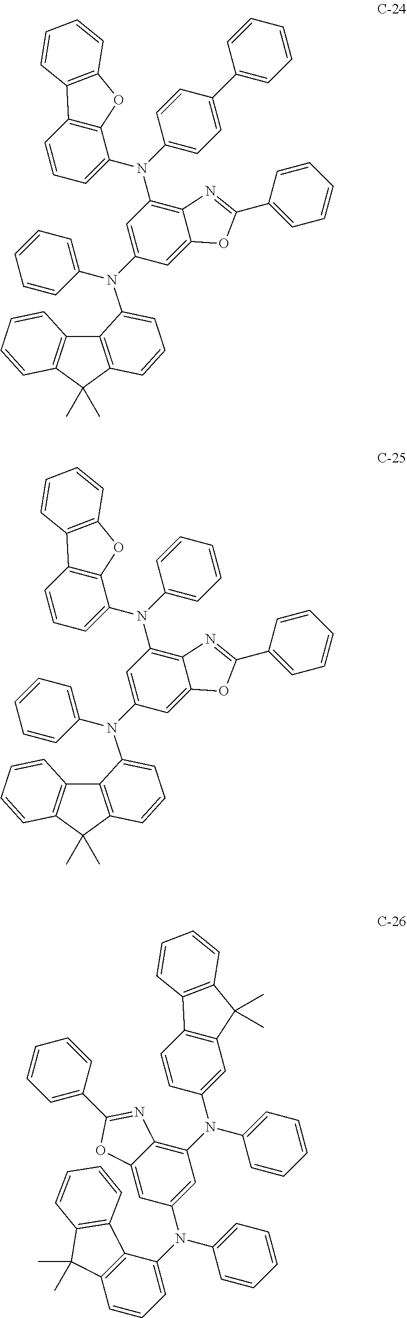 [SMILES: CC1(C)c2ccccc2-c2c(N(c3ccccc3)c3cc(N(c4ccc(-c5ccccc5)cc4)c4cccc5c4oc4ccccc45)c4nc(-c5ccccc5)oc4c3)cccc21 ; CC1(C)c2ccccc2-c2c(N(c3ccccc3)c3cc(N(c4ccccc4)c4cccc5c4oc4ccccc45)c4nc(-c5ccccc5)oc4c3)cccc21 ; CC1(C)c2ccccc2-c2ccc(N(c3ccccc3)c3cc(N(c4ccccc4)c4cccc5c4-c4ccccc4C5(C)C)cc4oc(-c5ccccc5)nc34)cc21]

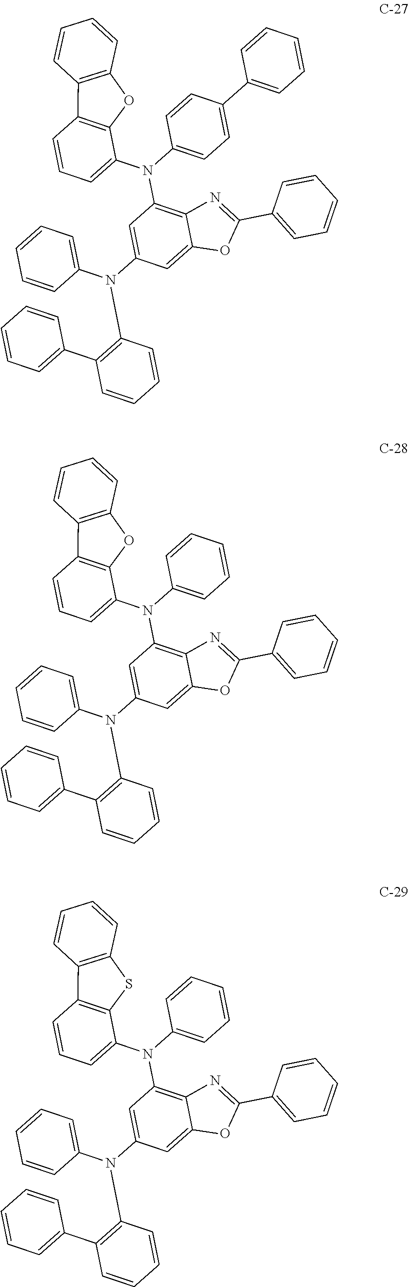 [SMILES: c1ccc(-c2ccc(N(c3cc(N(c4ccccc4)c4ccccc4-c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccccc4-c4ccccc4)cc3o2)cc1 ; c1ccc(-c2nc3c(N(c4ccccc4)c4cccc5c4sc4ccccc45)cc(N(c4ccccc4)c4ccccc4-c4ccccc4)cc3o2)cc1]

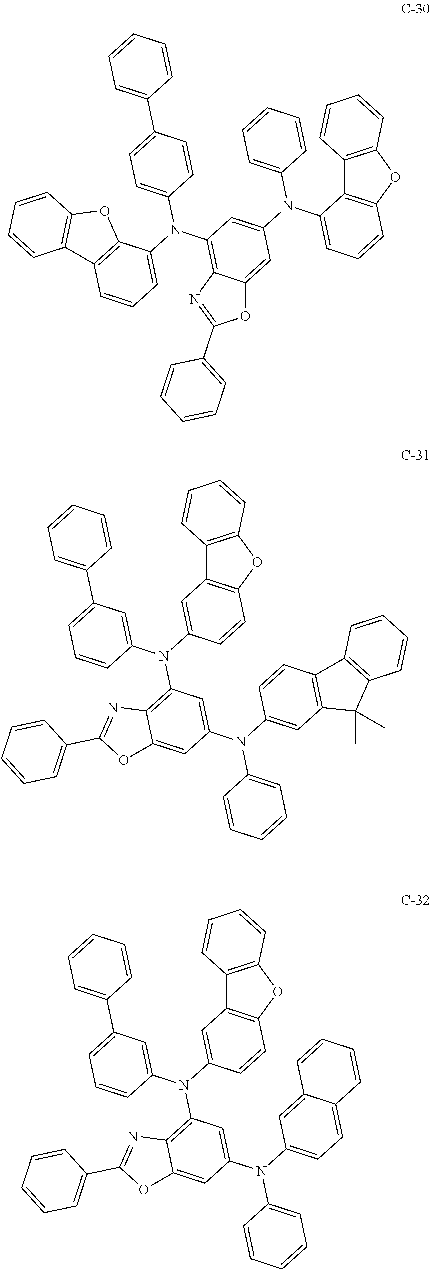 [SMILES: c1ccc(-c2ccc(N(c3cc(N(c4ccccc4)c4cccc5oc6ccccc6c45)cc4oc(-c5ccccc5)nc34)c3cccc4c3oc3ccccc34)cc2)cc1 ; CC1(C)c2ccccc2-c2ccc(N(c3ccccc3)c3cc(N(c4cccc(-c5ccccc5)c4)c4ccc5oc6ccccc6c5c4)c4nc(-c5ccccc5)oc4c3)cc21 ; c1ccc(-c2cccc(N(c3ccc4oc5ccccc5c4c3)c3cc(N(c4ccccc4)c4ccc5ccccc5c4)cc4oc(-c5ccccc5)nc34)c2)cc1]

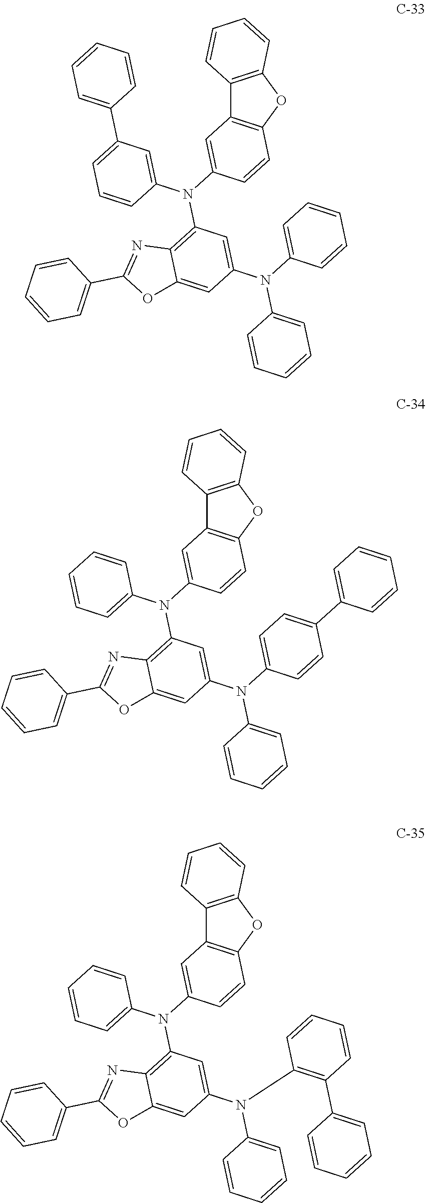 [SMILES: c1ccc(-c2cccc(N(c3ccc4oc5ccccc5c4c3)c3cc(N(c4ccccc4)c4ccccc4)cc4oc(-c5ccccc5)nc34)c2)cc1 ; c1ccc(-c2ccc(N(c3ccccc3)c3cc(N(c4ccccc4)c4ccc5oc6ccccc6c5c4)c4nc(-c5ccccc5)oc4c3)cc2)cc1 ; c1ccc(-c2nc3c(N(c4ccccc4)c4ccc5oc6ccccc6c5c4)cc(N(c4ccccc4)c4ccccc4-c4ccccc4)cc3o2)cc1]

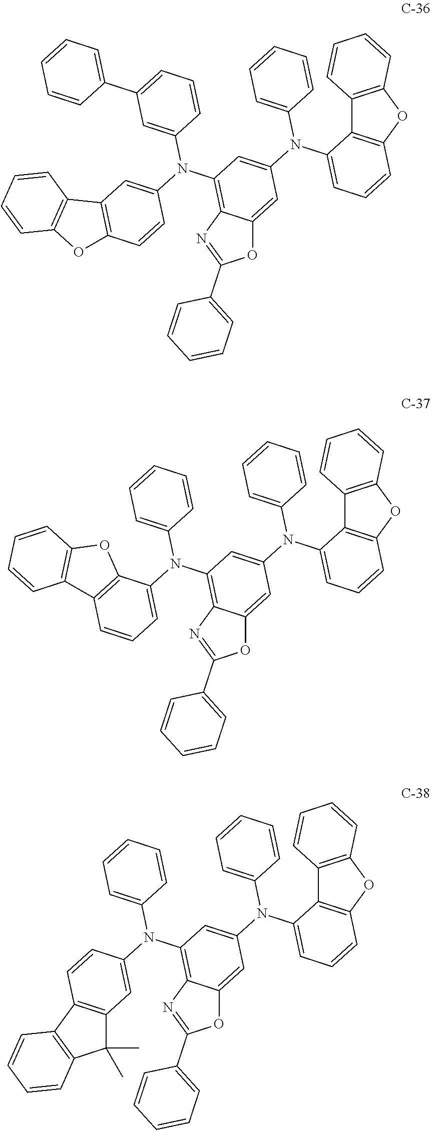 [SMILES: c1ccc(-c2cccc(N(c3ccc4oc5ccccc5c4c3)c3cc(N(c4ccccc4)c4cccc5oc6ccccc6c45)cc4oc(-c5ccccc5)nc34)c2)cc1 ; c1ccc(-c2nc3c(N(c4ccccc4)c4cccc5c4oc4ccccc45)cc(N(c4ccccc4)c4cccc5oc6ccccc6c45)cc3o2)cc1 ; CC1(C)c2ccccc2-c2ccc(N(c3ccccc3)c3cc(N(c4ccccc4)c4cccc5oc6ccccc6c45)cc4oc(-c5ccccc5)nc34)cc21]

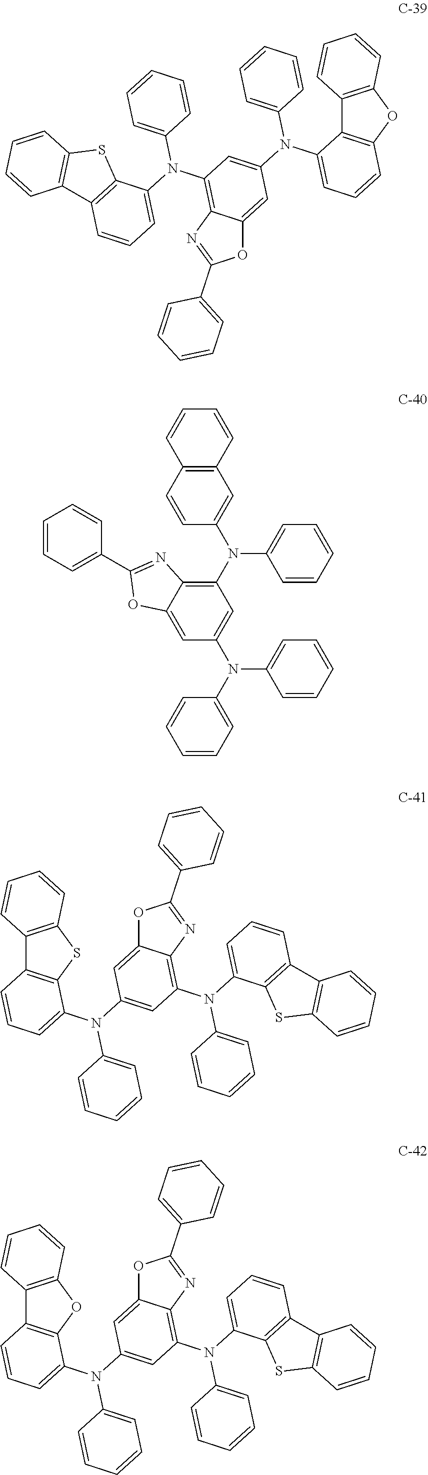 [SMILES: c1ccc(-c2nc3c(N(c4ccccc4)c4cccc5c4sc4ccccc45)cc(N(c4ccccc4)c4cccc5oc6ccccc6c45)cc3o2)cc1 ; c1ccc(-c2nc3c(N(c4ccccc4)c4ccc5ccccc5c4)cc(N(c4ccccc4)c4ccccc4)cc3o2)cc1 ; c1ccc(-c2nc3c(N(c4ccccc4)c4cccc5c4sc4ccccc45)cc(N(c4ccccc4)c4cccc5c4sc4ccccc45)cc3o2)cc1 ; c1ccc(-c2nc3c(N(c4ccccc4)c4cccc5c4sc4ccccc45)cc(N(c4ccccc4)c4cccc5c4oc4ccccc45)cc3o2)cc1]

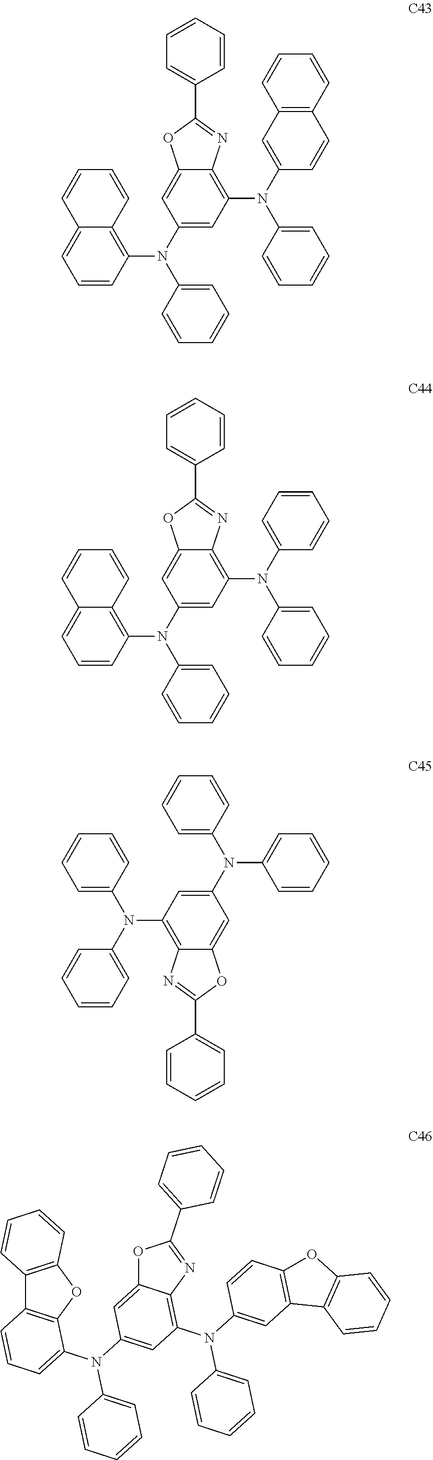

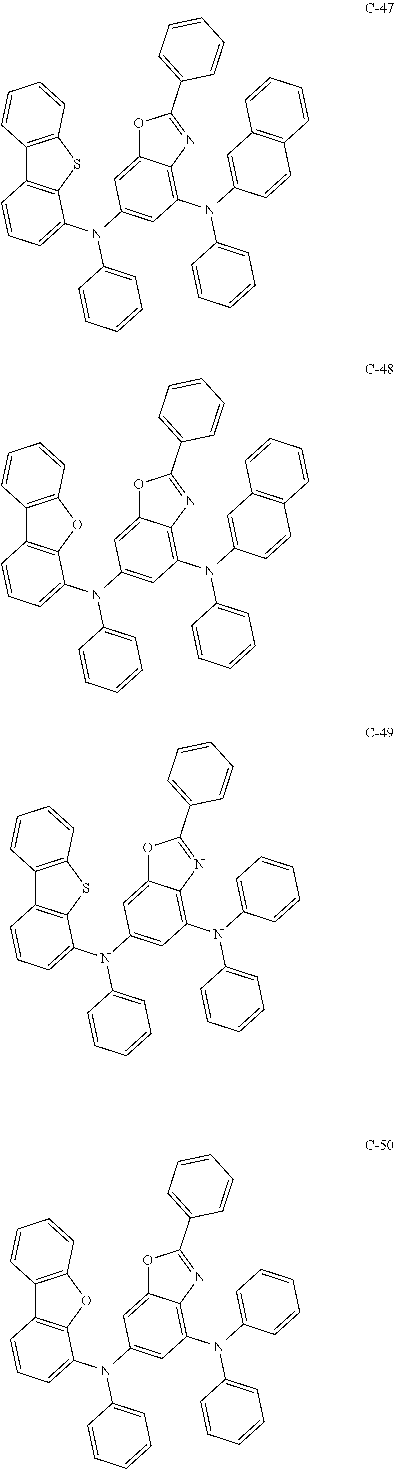 [SMILES: c1ccc(-c2nc3c(N(c4ccccc4)c4ccc5ccccc5c4)cc(N(c4ccccc4)c4cccc5c4sc4ccccc45)cc3o2)cc1 ; c1ccc(-c2nc3c(N(c4ccccc4)c4ccc5ccccc5c4)cc(N(c4ccccc4)c4cccc5c4oc4ccccc45)cc3o2)cc1 ; c1ccc(-c2nc3c(N(c4ccccc4)c4ccccc4)cc(N(c4ccccc4)c4cccc5c4sc4ccccc45)cc3o2)cc1 ; c1ccc(-c2nc3c(N(c4ccccc4)c4ccccc4)cc(N(c4ccccc4)c4cccc5c4oc4ccccc45)cc3o2)cc1]

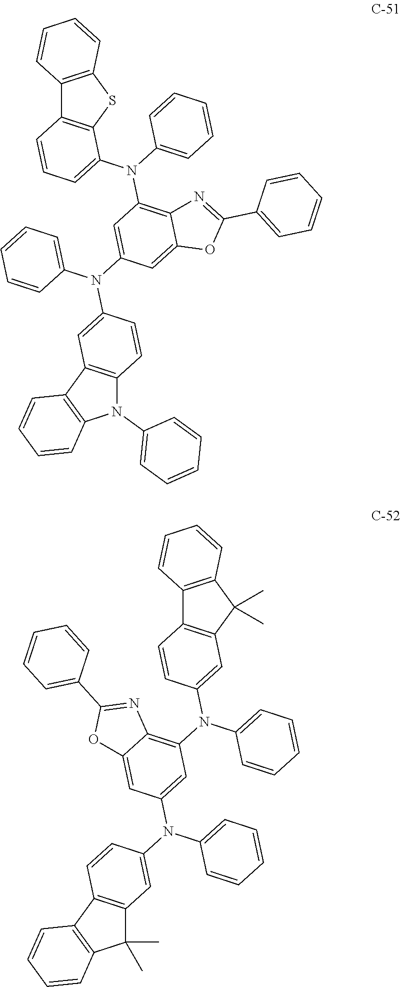 [SMILES: c1ccc(-c2nc3c(N(c4ccccc4)c4cccc5c4sc4ccccc45)cc(N(c4ccccc4)c4ccc5c(c4)c4ccccc4n5-c4ccccc4)cc3o2)cc1 ; CC1(C)c2ccccc2-c2ccc(N(c3ccccc3)c3cc(N(c4ccccc4)c4ccc5c(c4)C(C)(C)c4ccccc4-5)c4nc(-c5ccccc5)oc4c3)cc21]

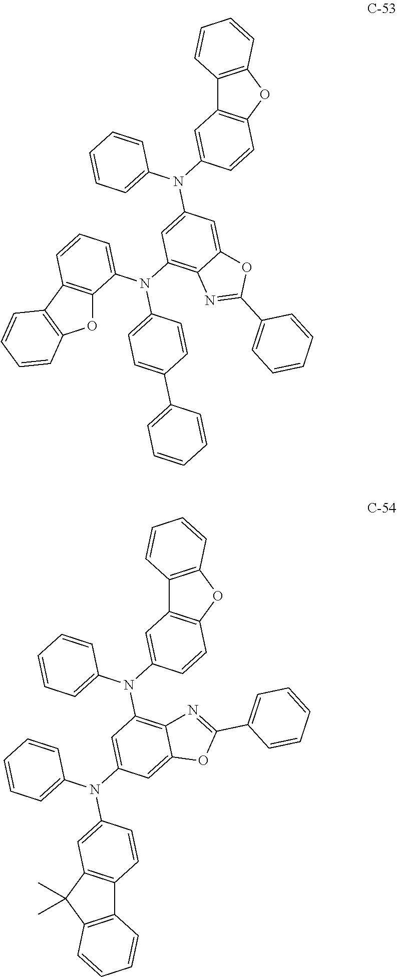 [SMILES: c1ccc(-c2ccc(N(c3cc(N(c4ccccc4)c4ccc5oc6ccccc6c5c4)cc4oc(-c5ccccc5)nc34)c3cccc4c3oc3ccccc34)cc2)cc1 ; CC1(C)c2ccccc2-c2ccc(N(c3ccccc3)c3cc(N(c4ccccc4)c4ccc5oc6ccccc6c5c4)c4nc(-c5ccccc5)oc4c3)cc21]

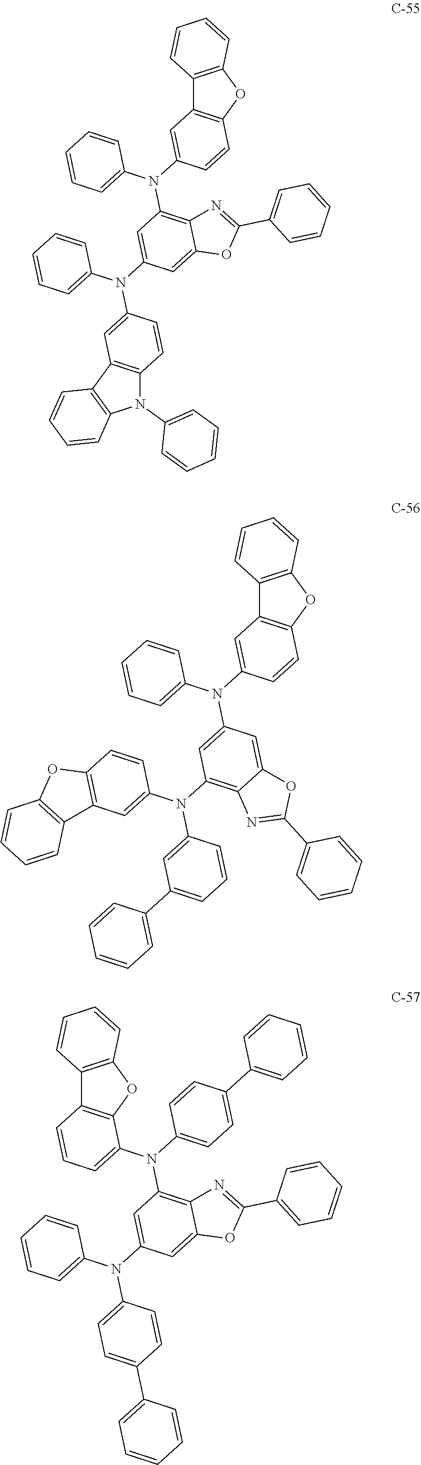 [SMILES: c1ccc(-c2nc3c(N(c4ccccc4)c4ccc5oc6ccccc6c5c4)cc(N(c4ccccc4)c4ccc5c(c4)c4ccccc4n5-c4ccccc4)cc3o2)cc1 ; c1ccc(-c2cccc(N(c3ccc4oc5ccccc5c4c3)c3cc(N(c4ccccc4)c4ccc5oc6ccccc6c5c4)cc4oc(-c5ccccc5)nc34)c2)cc1 ; c1ccc(-c2ccc(N(c3ccccc3)c3cc(N(c4ccc(-c5ccccc5)cc4)c4cccc5c4oc4ccccc45)c4nc(-c5ccccc5)oc4c3)cc2)cc1]

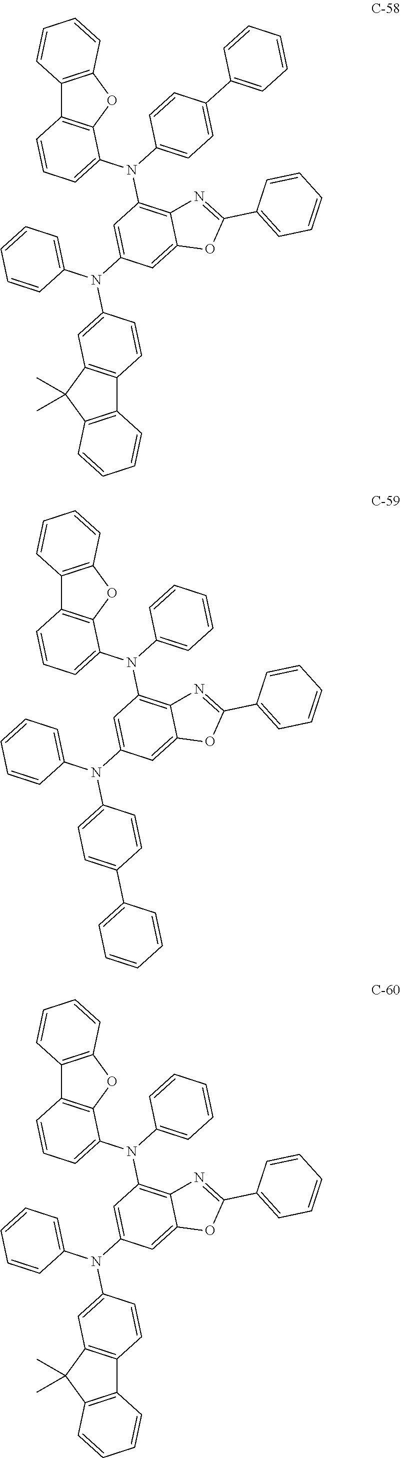

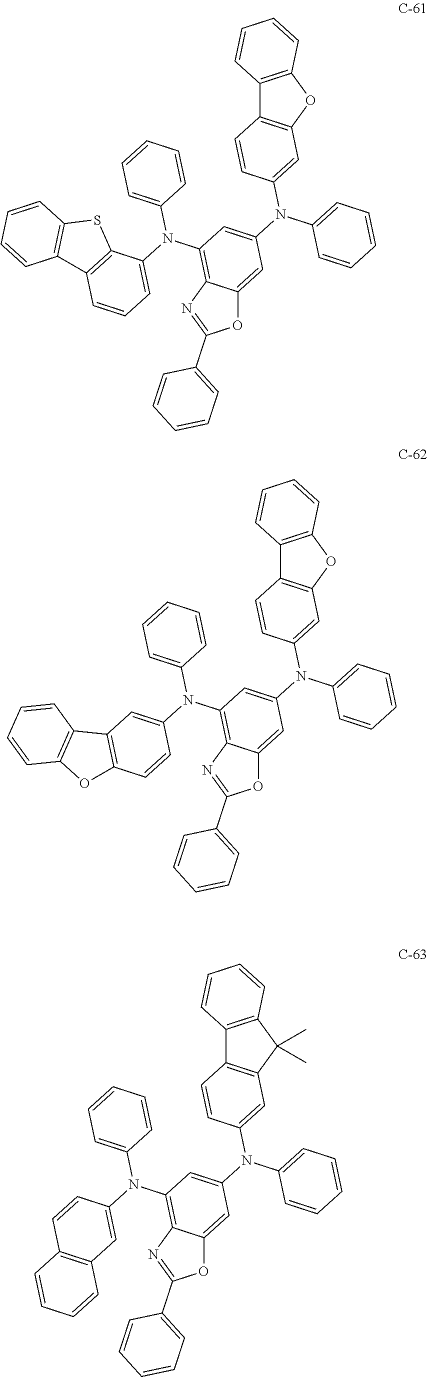 [SMILES: c1ccc(-c2nc3c(N(c4ccccc4)c4cccc5c4sc4ccccc45)cc(N(c4ccccc4)c4ccc5c(c4)oc4ccccc45)cc3o2)cc1 ; c1ccc(-c2nc3c(N(c4ccccc4)c4ccc5oc6ccccc6c5c4)cc(N(c4ccccc4)c4ccc5c(c4)oc4ccccc45)cc3o2)cc1 ; CC1(C)c2ccccc2-c2ccc(N(c3ccccc3)c3cc(N(c4ccccc4)c4ccc5ccccc5c4)c4nc(-c5ccccc5)oc4c3)cc21]

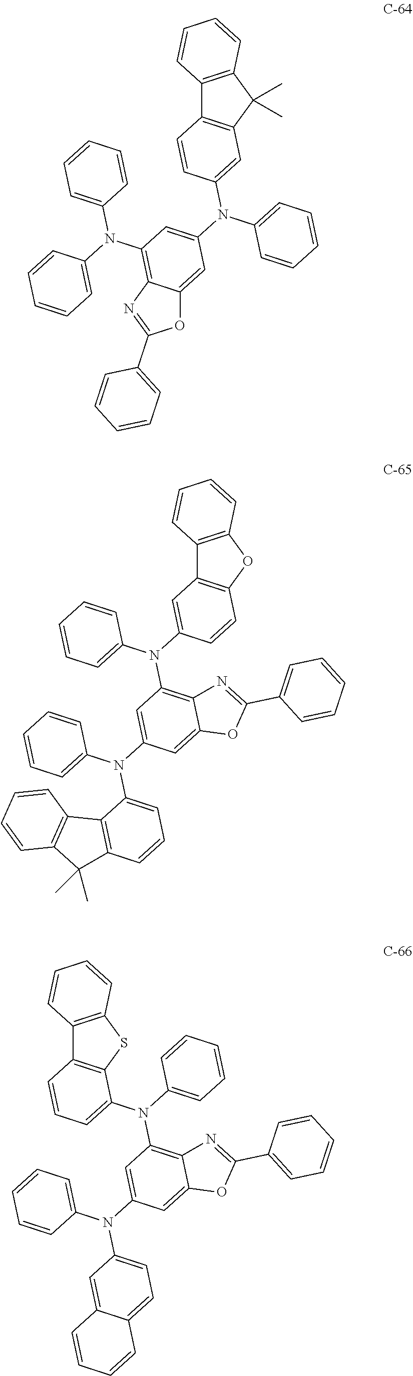 [SMILES: CC1(C)c2ccccc2-c2ccc(N(c3ccccc3)c3cc(N(c4ccccc4)c4ccccc4)c4nc(-c5ccccc5)oc4c3)cc21 ; CC1(C)c2ccccc2-c2c(N(c3ccccc3)c3cc(N(c4ccccc4)c4ccc5oc6ccccc6c5c4)c4nc(-c5ccccc5)oc4c3)cccc21 ; c1ccc(-c2nc3c(N(c4ccccc4)c4cccc5c4sc4ccccc45)cc(N(c4ccccc4)c4ccc5ccccc5c4)cc3o2)cc1]

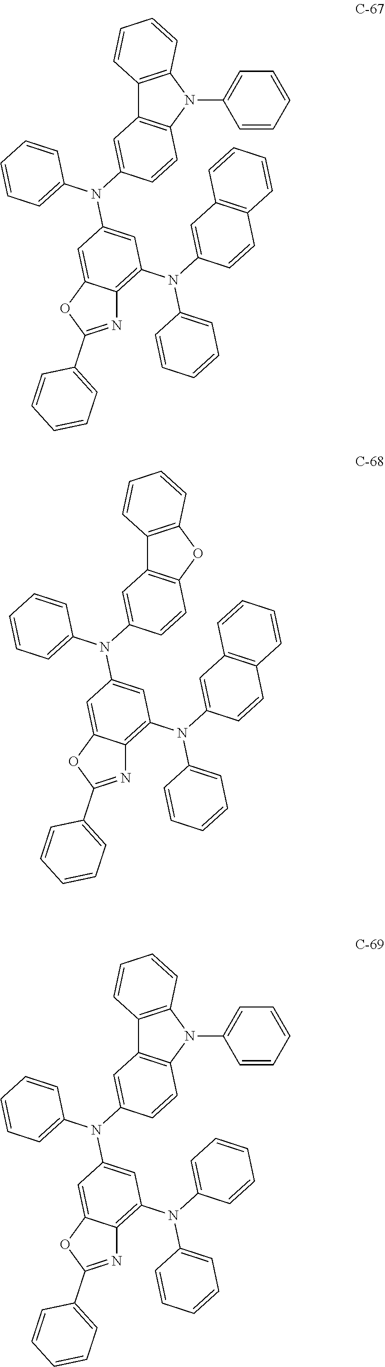 [SMILES: c1ccc(-c2nc3c(N(c4ccccc4)c4ccc5ccccc5c4)cc(N(c4ccccc4)c4ccc5c(c4)c4ccccc4n5-c4ccccc4)cc3o2)cc1 ; c1ccc(-c2nc3c(N(c4ccccc4)c4ccc5ccccc5c4)cc(N(c4ccccc4)c4ccc5oc6ccccc6c5c4)cc3o2)cc1 ; c1ccc(-c2nc3c(N(c4ccccc4)c4ccccc4)cc(N(c4ccccc4)c4ccc5c(c4)c4ccccc4n5-c4ccccc4)cc3o2)cc1]

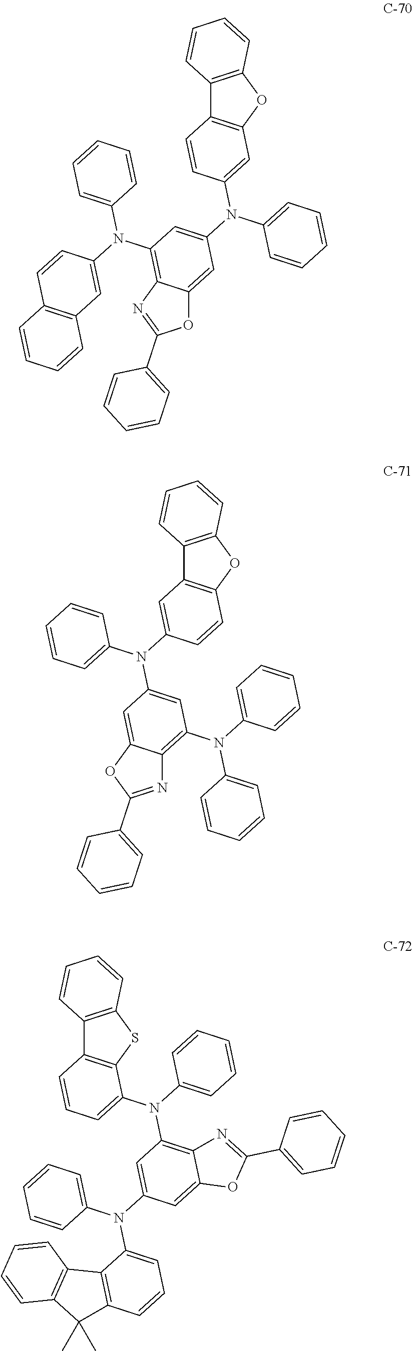 [SMILES: c1ccc(-c2nc3c(N(c4ccccc4)c4ccc5ccccc5c4)cc(N(c4ccccc4)c4ccc5c(c4)oc4ccccc45)cc3o2)cc1 ; c1ccc(-c2nc3c(N(c4ccccc4)c4ccccc4)cc(N(c4ccccc4)c4ccc5oc6ccccc6c5c4)cc3o2)cc1 ; CC1(C)c2ccccc2-c2c(N(c3ccccc3)c3cc(N(c4ccccc4)c4cccc5c4sc4ccccc45)c4nc(-c5ccccc5)oc4c3)cccc21]

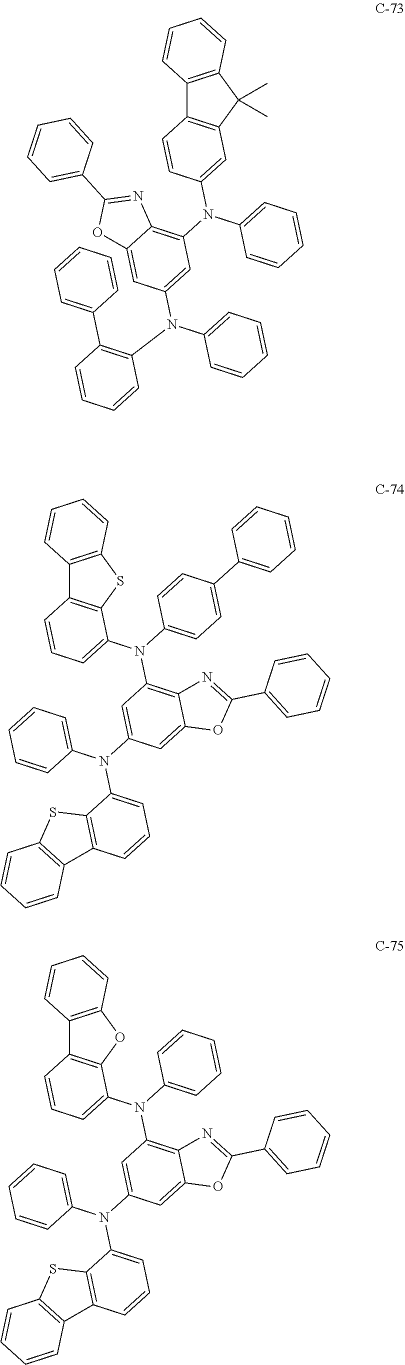 [SMILES: CC1(C)c2ccccc2-c2ccc(N(c3ccccc3)c3cc(N(c4ccccc4)c4ccccc4-c4ccccc4)cc4oc(-c5ccccc5)nc34)cc21 ; c1ccc(-c2ccc(N(c3cc(N(c4ccccc4)c4cccc5c4sc4ccccc45)cc4oc(-c5ccccc5)nc34)c3cccc4c3sc3ccccc34)cc2)cc1 ; c1ccc(-c2nc3c(N(c4ccccc4)c4cccc5c4oc4ccccc45)cc(N(c4ccccc4)c4cccc5c4sc4ccccc45)cc3o2)cc1]

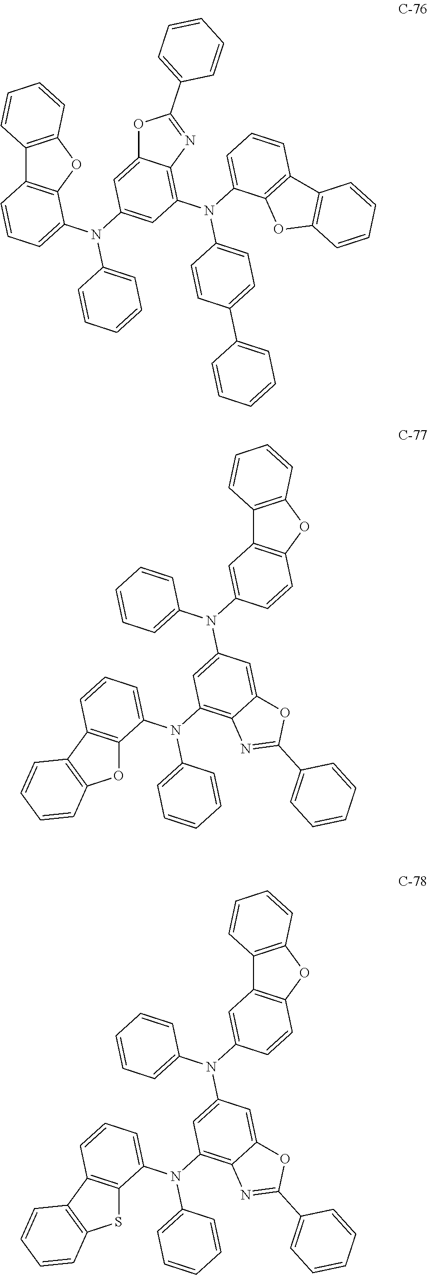

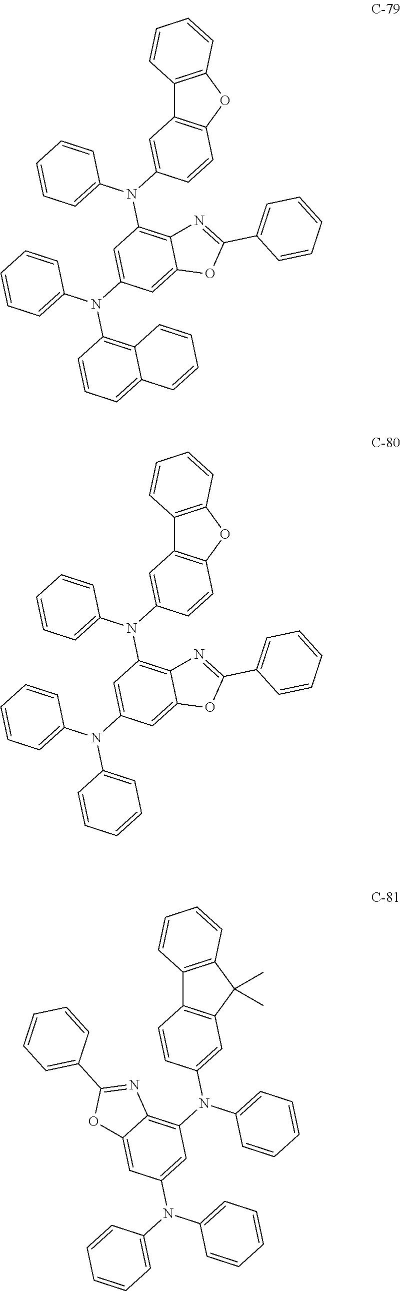 [SMILES: c1ccc(-c2nc3c(N(c4ccccc4)c4ccc5oc6ccccc6c5c4)cc(N(c4ccccc4)c4cccc5ccccc45)cc3o2)cc1 ; c1ccc(-c2nc3c(N(c4ccccc4)c4ccc5oc6ccccc6c5c4)cc(N(c4ccccc4)c4ccccc4)cc3o2)cc1 ; CC1(C)c2ccccc2-c2ccc(N(c3ccccc3)c3cc(N(c4ccccc4)c4ccccc4)cc4oc(-c5ccccc5)nc34)cc21]

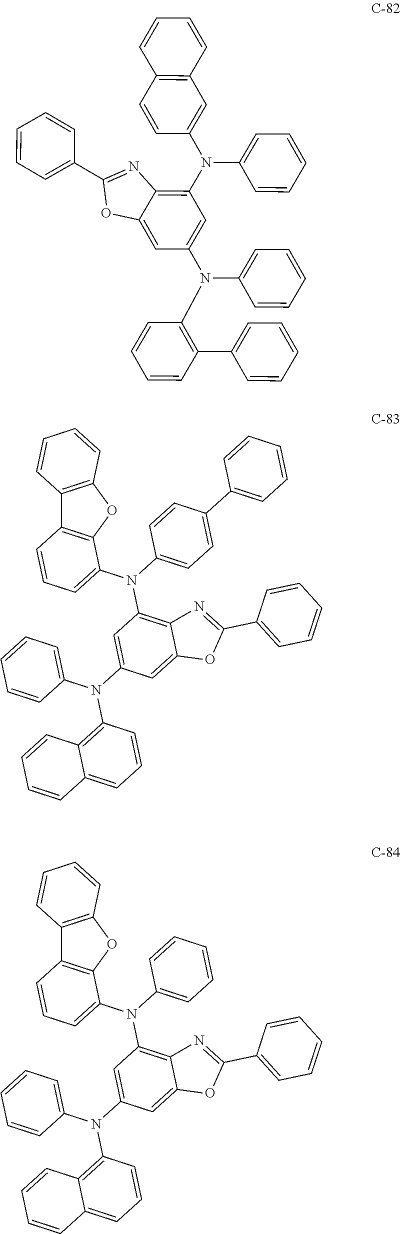 [SMILES: c1ccc(-c2nc3c(N(c4ccccc4)c4ccc5ccccc5c4)cc(N(c4ccccc4)c4ccccc4-c4ccccc4)cc3o2)cc1 ; c1ccc(-c2ccc(N(c3cc(N(c4ccccc4)c4cccc5ccccc45)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4cccc5ccccc45)cc3o2)cc1]

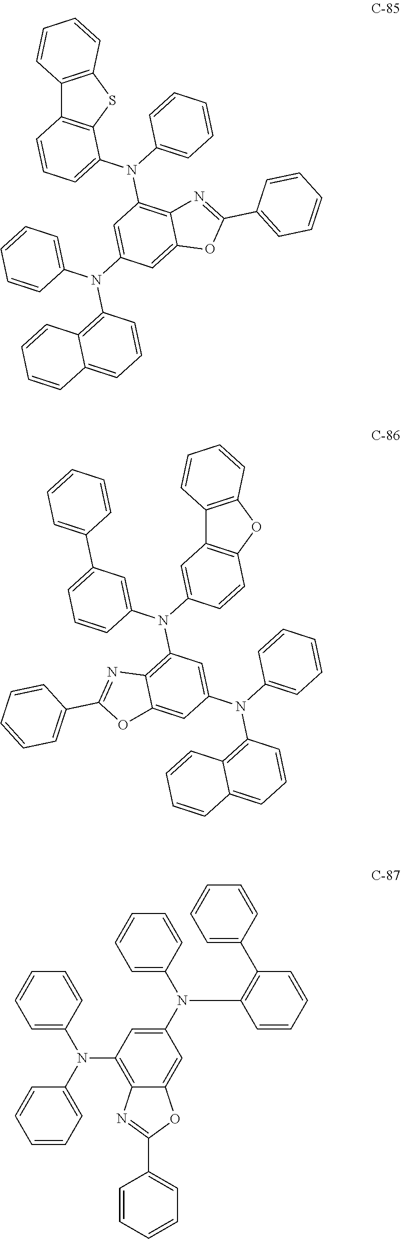 [SMILES: c1ccc(-c2nc3c(N(c4ccccc4)c4cccc5c4sc4ccccc45)cc(N(c4ccccc4)c4cccc5ccccc45)cc3o2)cc1 ; c1ccc(-c2cccc(N(c3ccc4oc5ccccc5c4c3)c3cc(N(c4ccccc4)c4cccc5ccccc45)cc4oc(-c5ccccc5)nc34)c2)cc1 ; c1ccc(-c2nc3c(N(c4ccccc4)c4ccccc4)cc(N(c4ccccc4)c4ccccc4-c4ccccc4)cc3o2)cc1]

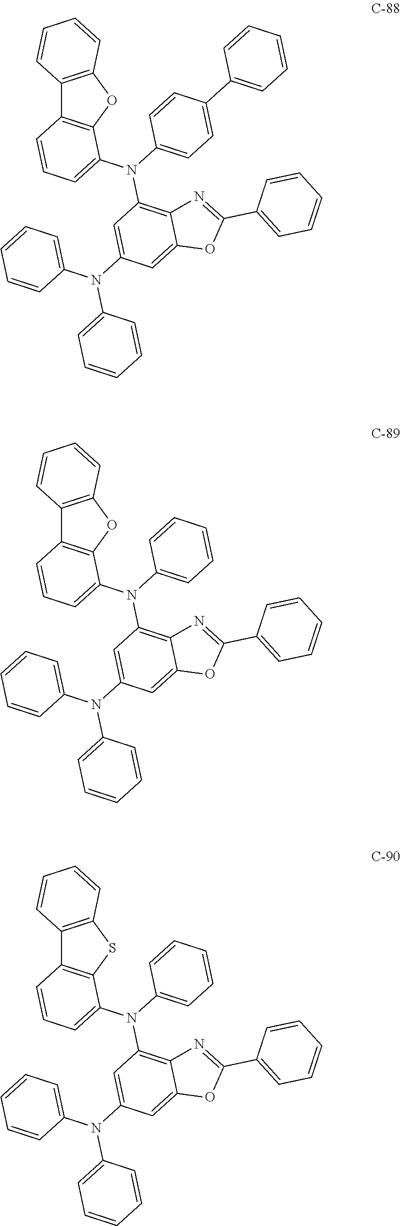 [SMILES: c1ccc(-c2ccc(N(c3cc(N(c4ccccc4)c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccccc4)cc3o2)cc1 ; c1ccc(-c2nc3c(N(c4ccccc4)c4cccc5c4sc4ccccc45)cc(N(c4ccccc4)c4ccccc4)cc3o2)cc1]

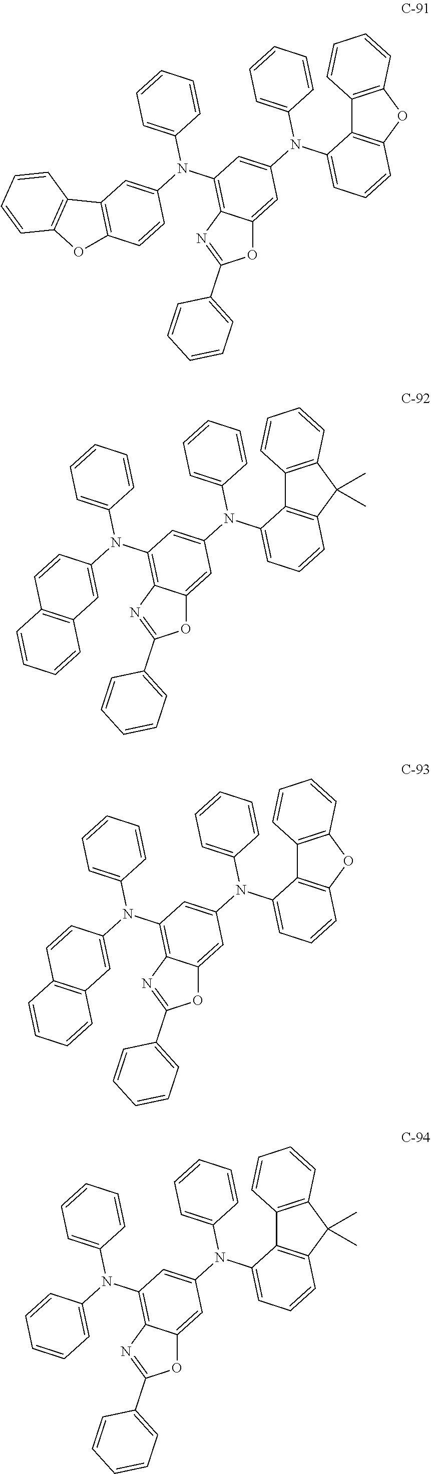 [SMILES: c1ccc(-c2nc3c(N(c4ccccc4)c4ccc5oc6ccccc6c5c4)cc(N(c4ccccc4)c4cccc5oc6ccccc6c45)cc3o2)cc1 ; CC1(C)c2ccccc2-c2c(N(c3ccccc3)c3cc(N(c4ccccc4)c4ccc5ccccc5c4)c4nc(-c5ccccc5)oc4c3)cccc21 ; c1ccc(-c2nc3c(N(c4ccccc4)c4ccc5ccccc5c4)cc(N(c4ccccc4)c4cccc5oc6ccccc6c45)cc3o2)cc1 ; CC1(C)c2ccccc2-c2c(N(c3ccccc3)c3cc(N(c4ccccc4)c4ccccc4)c4nc(-c5ccccc5)oc4c3)cccc21]

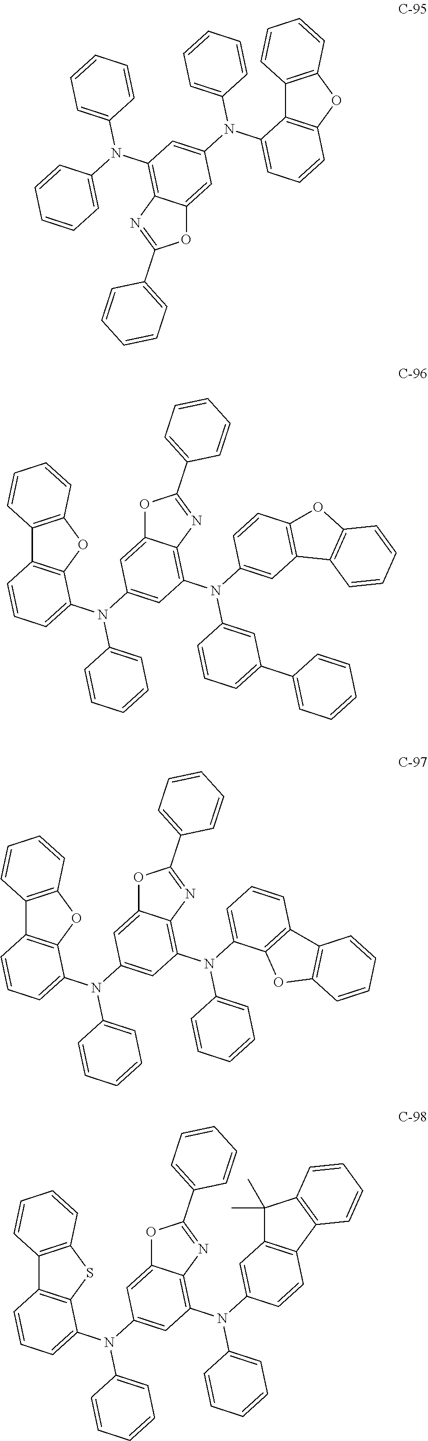 [SMILES: c1ccc(-c2nc3c(N(c4ccccc4)c4ccccc4)cc(N(c4ccccc4)c4cccc5oc6ccccc6c45)cc3o2)cc1 ; c1ccc(-c2cccc(N(c3ccc4oc5ccccc5c4c3)c3cc(N(c4ccccc4)c4cccc5c4oc4ccccc45)cc4oc(-c5ccccc5)nc34)c2)cc1 ; c1ccc(-c2nc3c(N(c4ccccc4)c4cccc5c4oc4ccccc45)cc(N(c4ccccc4)c4cccc5c4oc4ccccc45)cc3o2)cc1 ; CC1(C)c2ccccc2-c2ccc(N(c3ccccc3)c3cc(N(c4ccccc4)c4cccc5c4sc4ccccc45)cc4oc(-c5ccccc5)nc34)cc21]

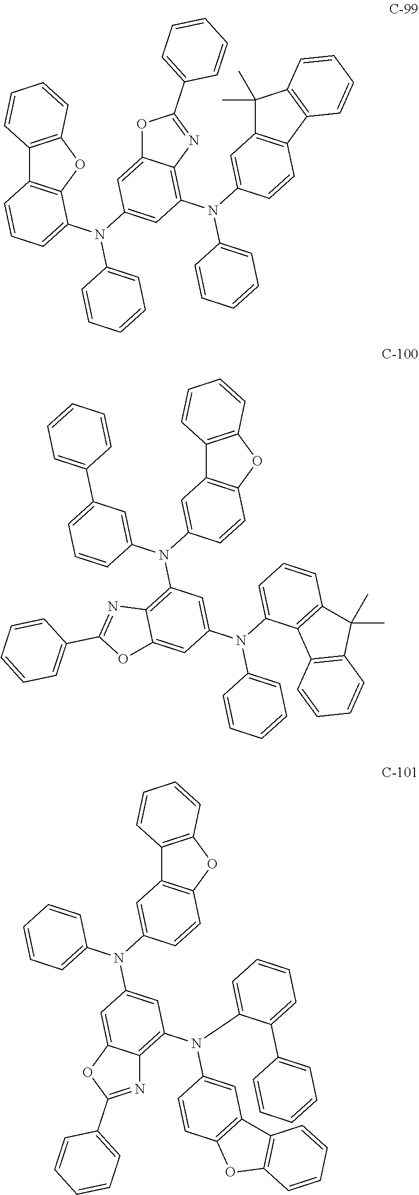 [SMILES: CC1(C)c2ccccc2-c2ccc(N(c3ccccc3)c3cc(N(c4ccccc4)c4cccc5c4oc4ccccc45)cc4oc(-c5ccccc5)nc34)cc21 ; CC1(C)c2ccccc2-c2c(N(c3ccccc3)c3cc(N(c4cccc(-c5ccccc5)c4)c4ccc5oc6ccccc6c5c4)c4nc(-c5ccccc5)oc4c3)cccc21 ; c1ccc(-c2nc3c(N(c4ccc5oc6ccccc6c5c4)c4ccccc4-c4ccccc4)cc(N(c4ccccc4)c4ccc5oc6ccccc6c5c4)cc3o2)cc1]

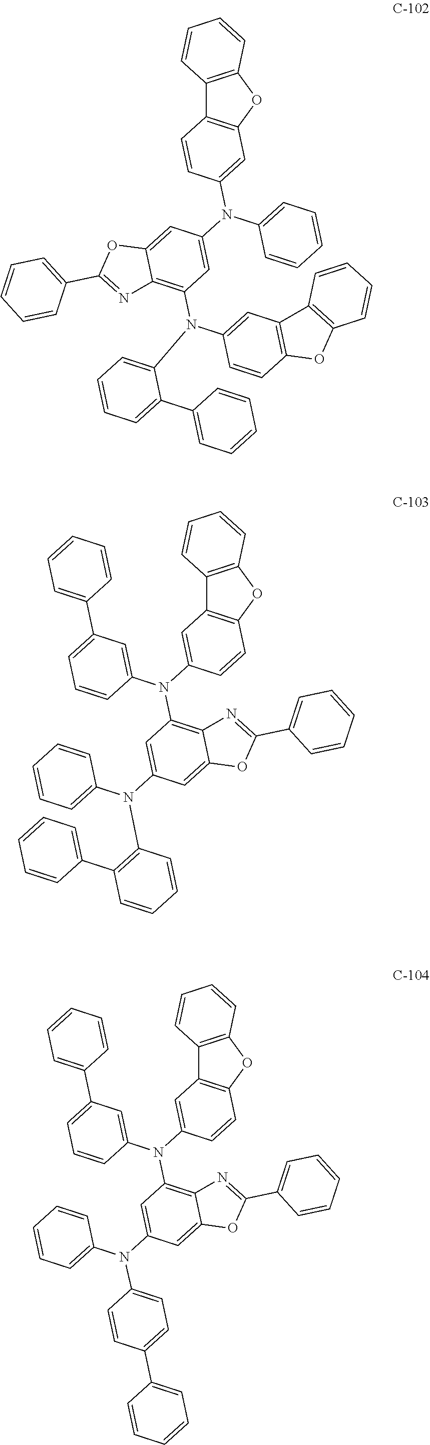 [SMILES: c1ccc(-c2nc3c(N(c4ccc5oc6ccccc6c5c4)c4ccccc4-c4ccccc4)cc(N(c4ccccc4)c4ccc5c(c4)oc4ccccc45)cc3o2)cc1 ; c1ccc(-c2cccc(N(c3ccc4oc5ccccc5c4c3)c3cc(N(c4ccccc4)c4ccccc4-c4ccccc4)cc4oc(-c5ccccc5)nc34)c2)cc1 ; c1ccc(-c2ccc(N(c3ccccc3)c3cc(N(c4cccc(-c5ccccc5)c4)c4ccc5oc6ccccc6c5c4)c4nc(-c5ccccc5)oc4c3)cc2)cc1]

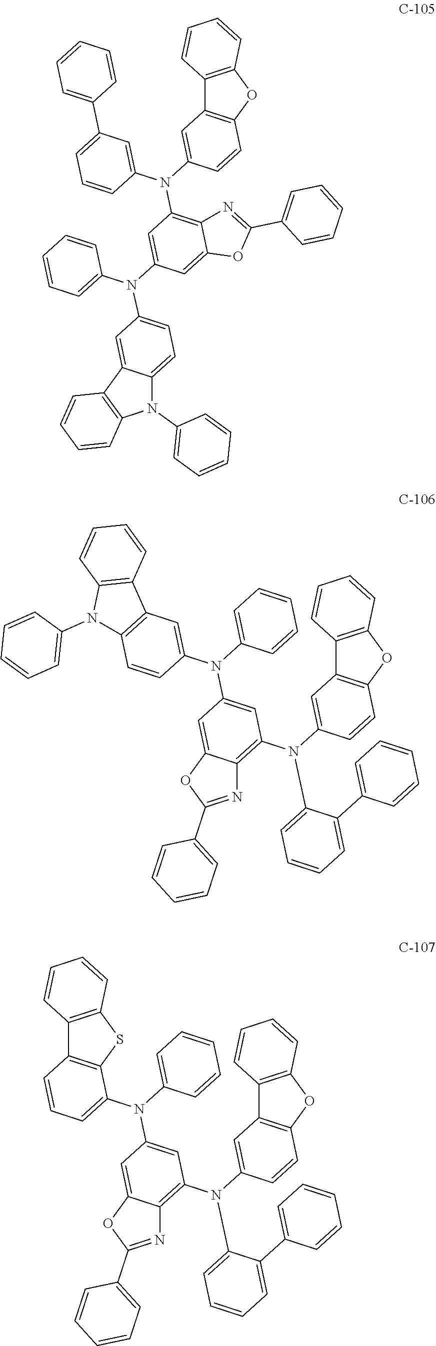 [SMILES: c1ccc(-c2cccc(N(c3ccc4oc5ccccc5c4c3)c3cc(N(c4ccccc4)c4ccc5c(c4)c4ccccc4n5-c4ccccc4)cc4oc(-c5ccccc5)nc34)c2)cc1 ; c1ccc(-c2nc3c(N(c4ccc5oc6ccccc6c5c4)c4ccccc4-c4ccccc4)cc(N(c4ccccc4)c4ccc5c(c4)c4ccccc4n5-c4ccccc4)cc3o2)cc1 ; c1ccc(-c2nc3c(N(c4ccc5oc6ccccc6c5c4)c4ccccc4-c4ccccc4)cc(N(c4ccccc4)c4cccc5c4sc4ccccc45)cc3o2)cc1]

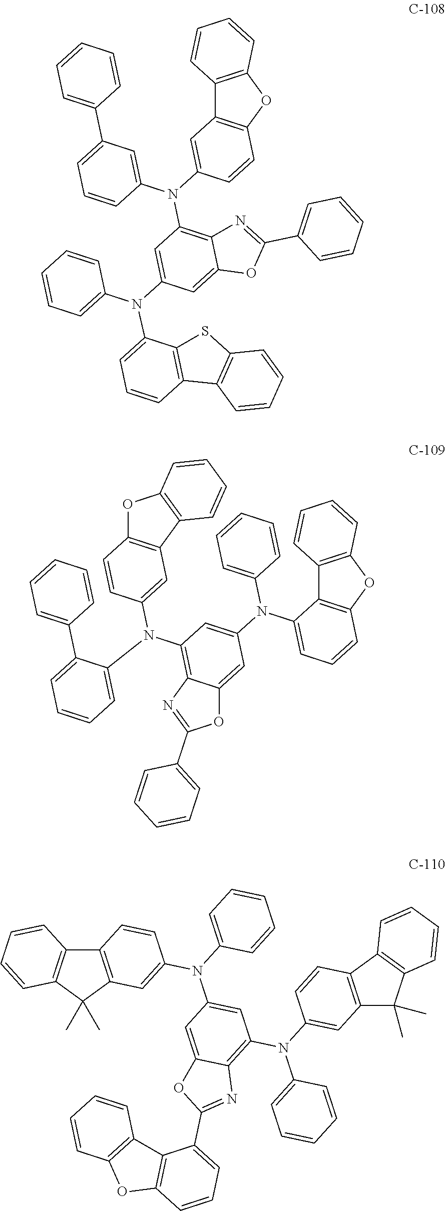 [SMILES: c1ccc(-c2cccc(N(c3ccc4oc5ccccc5c4c3)c3cc(N(c4ccccc4)c4cccc5c4sc4ccccc45)cc4oc(-c5ccccc5)nc34)c2)cc1 ; c1ccc(-c2nc3c(N(c4ccc5oc6ccccc6c5c4)c4ccccc4-c4ccccc4)cc(N(c4ccccc4)c4cccc5oc6ccccc6c45)cc3o2)cc1 ; CC1(C)c2ccccc2-c2ccc(N(c3ccccc3)c3cc(N(c4ccccc4)c4ccc5c(c4)C(C)(C)c4ccccc4-5)c4nc(-c5cccc6oc7ccccc7c56)oc4c3)cc21]

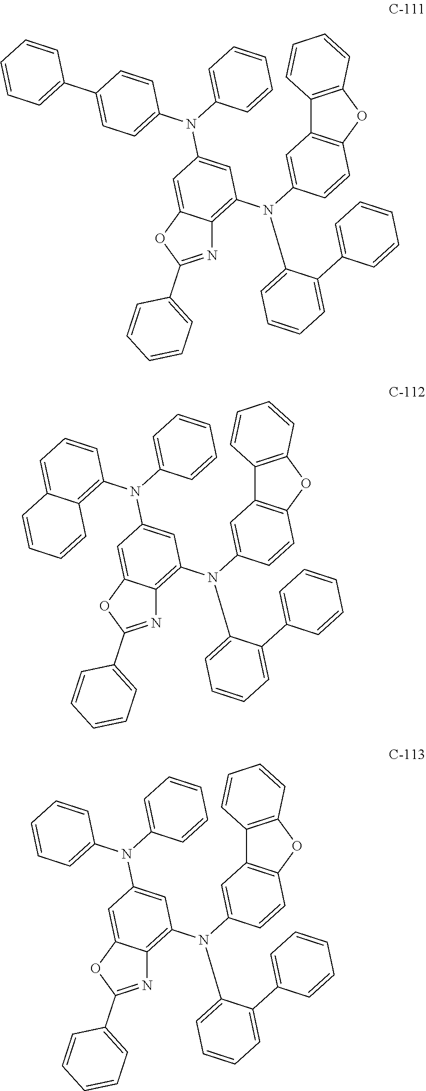 [SMILES: c1ccc(-c2ccc(N(c3ccccc3)c3cc(N(c4ccc5oc6ccccc6c5c4)c4ccccc4-c4ccccc4)c4nc(-c5ccccc5)oc4c3)cc2)cc1 ; c1ccc(-c2nc3c(N(c4ccc5oc6ccccc6c5c4)c4ccccc4-c4ccccc4)cc(N(c4ccccc4)c4cccc5ccccc45)cc3o2)cc1 ; c1ccc(-c2nc3c(N(c4ccc5oc6ccccc6c5c4)c4ccccc4-c4ccccc4)cc(N(c4ccccc4)c4ccccc4)cc3o2)cc1]

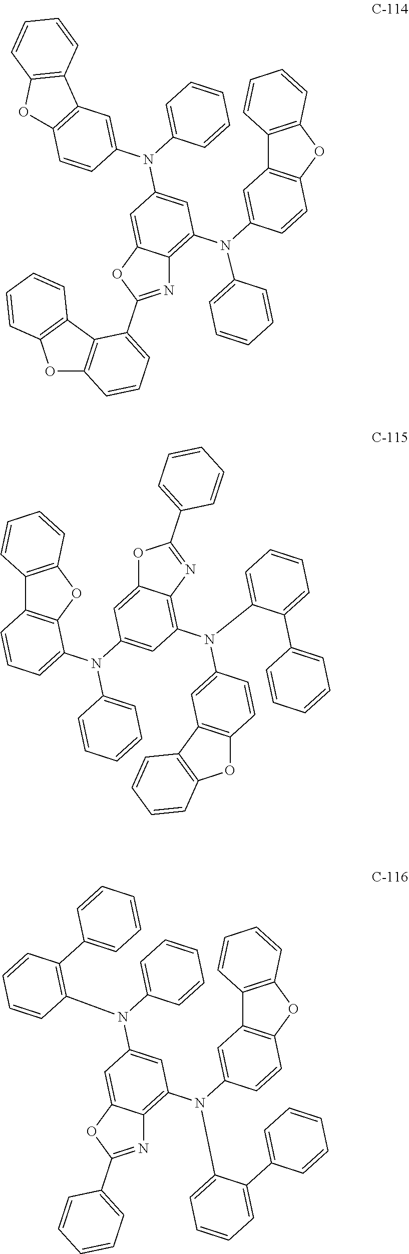 [SMILES: c1ccc(N(c2cc(N(c3ccccc3)c3ccc4oc5ccccc5c4c3)c3nc(-c4cccc5oc6ccccc6c45)oc3c2)c2ccc3oc4ccccc4c3c2)cc1 ; c1ccc(-c2nc3c(N(c4ccc5oc6ccccc6c5c4)c4ccccc4-c4ccccc4)cc(N(c4ccccc4)c4cccc5c4oc4ccccc45)cc3o2)cc1 ; c1ccc(-c2nc3c(N(c4ccc5oc6ccccc6c5c4)c4ccccc4-c4ccccc4)cc(N(c4ccccc4)c4ccccc4-c4ccccc4)cc3o2)cc1]

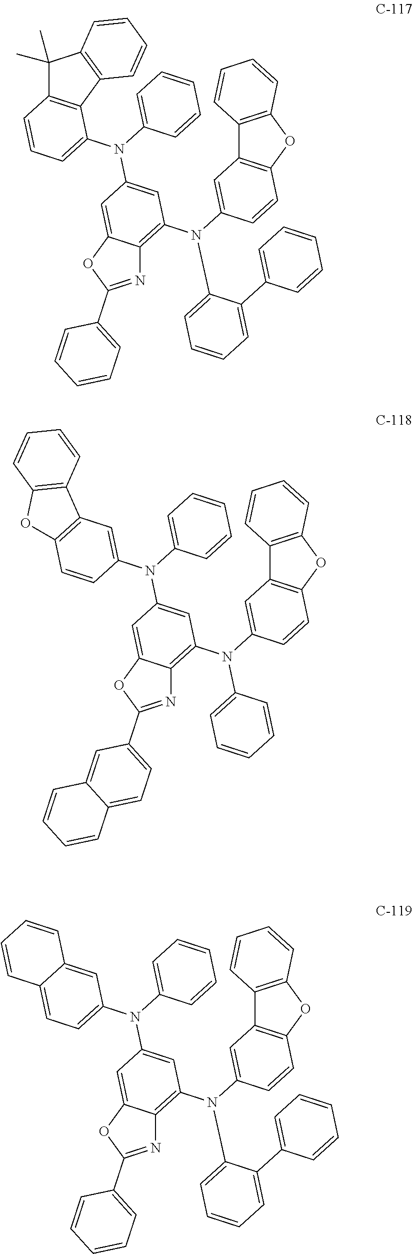 [SMILES: CC1(C)c2ccccc2-c2c(N(c3ccccc3)c3cc(N(c4ccc5oc6ccccc6c5c4)c4ccccc4-c4ccccc4)c4nc(-c5ccccc5)oc4c3)cccc21 ; c1ccc(N(c2cc(N(c3ccccc3)c3ccc4oc5ccccc5c4c3)c3nc(-c4ccc5ccccc5c4)oc3c2)c2ccc3oc4ccccc4c3c2)cc1 ; c1ccc(-c2nc3c(N(c4ccc5oc6ccccc6c5c4)c4ccccc4-c4ccccc4)cc(N(c4ccccc4)c4ccc5ccccc5c4)cc3o2)cc1]

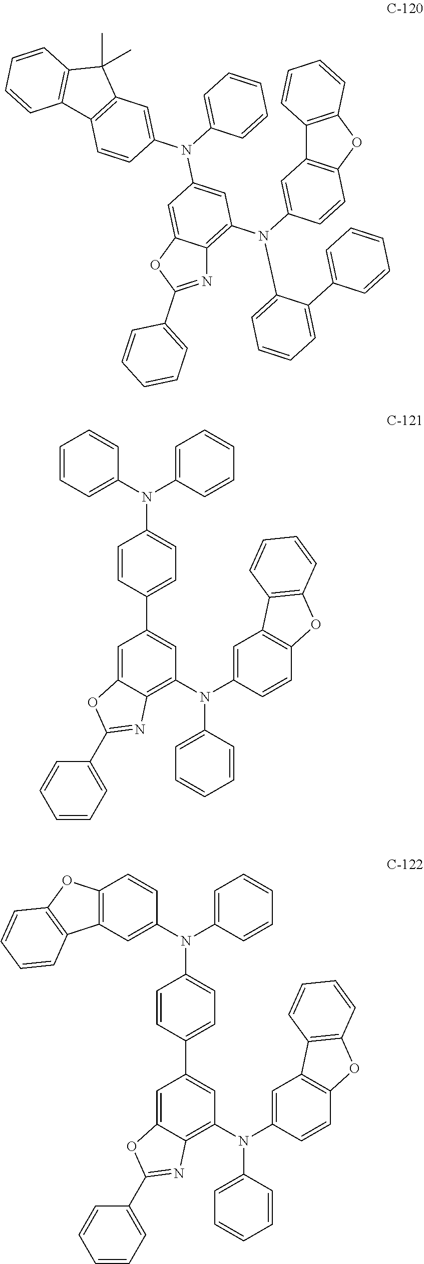 [SMILES: CC1(C)c2ccccc2-c2ccc(N(c3ccccc3)c3cc(N(c4ccc5oc6ccccc6c5c4)c4ccccc4-c4ccccc4)c4nc(-c5ccccc5)oc4c3)cc21 ; c1ccc(-c2nc3c(N(c4ccccc4)c4ccc5oc6ccccc6c5c4)cc(-c4ccc(N(c5ccccc5)c5ccccc5)cc4)cc3o2)cc1 ; c1ccc(-c2nc3c(N(c4ccccc4)c4ccc5oc6ccccc6c5c4)cc(-c4ccc(N(c5ccccc5)c5ccc6oc7ccccc7c6c5)cc4)cc3o2)cc1]

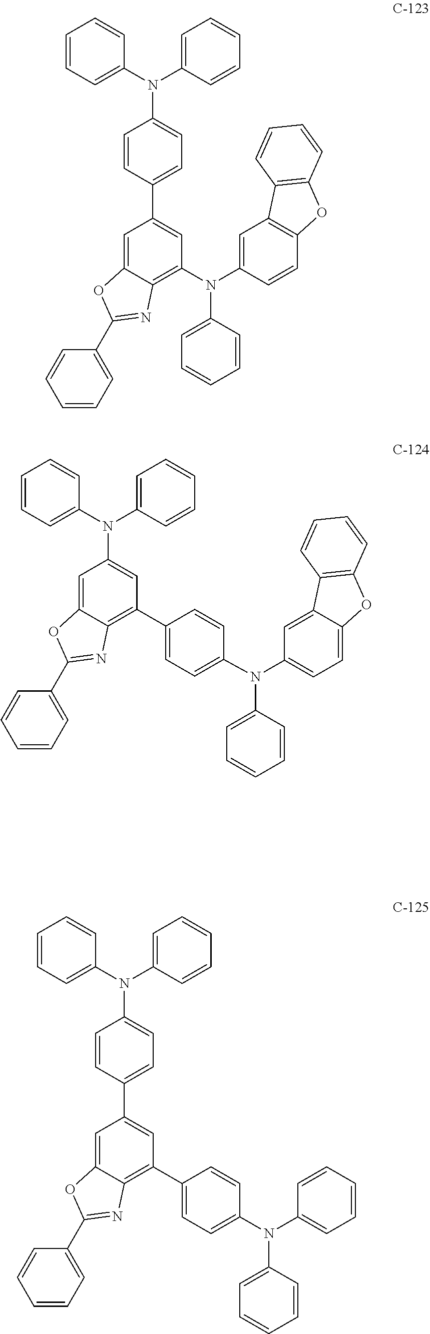 [SMILES: c1ccc(-c2nc3c(N(c4ccccc4)c4ccc5oc6ccccc6c5c4)cc(-c4ccc(N(c5ccccc5)c5ccccc5)cc4)cc3o2)cc1 ; c1ccc(-c2nc3c(-c4ccc(N(c5ccccc5)c5ccc6oc7ccccc7c6c5)cc4)cc(N(c4ccccc4)c4ccccc4)cc3o2)cc1 ; c1ccc(-c2nc3c(-c4ccc(N(c5ccccc5)c5ccccc5)cc4)cc(-c4ccc(N(c5ccccc5)c5ccccc5)cc4)cc3o2)cc1]

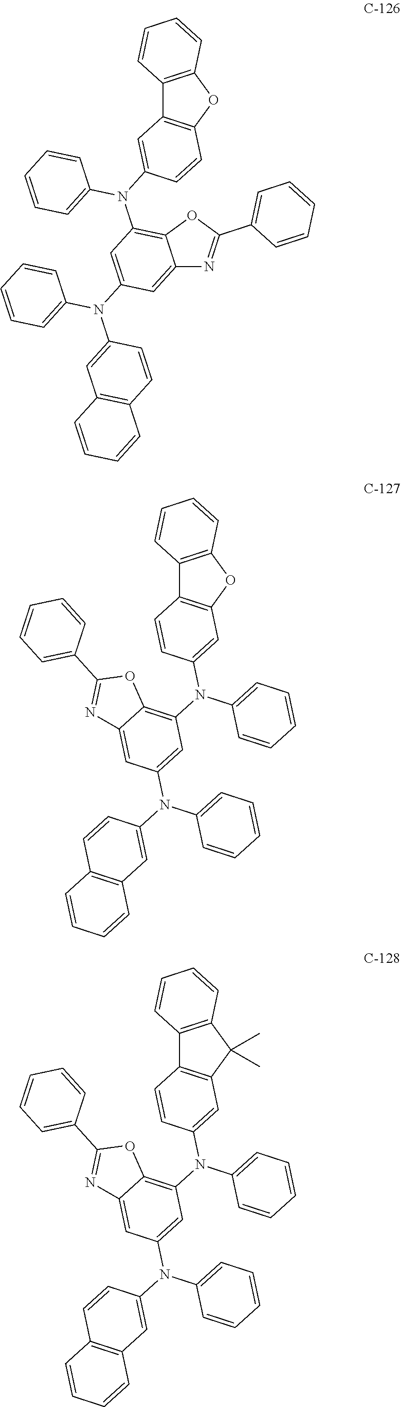 [SMILES: c1ccc(-c2nc3cc(N(c4ccccc4)c4ccc5ccccc5c4)cc(N(c4ccccc4)c4ccc5oc6ccccc6c5c4)c3o2)cc1 ; c1ccc(-c2nc3cc(N(c4ccccc4)c4ccc5ccccc5c4)cc(N(c4ccccc4)c4ccc5c(c4)oc4ccccc45)c3o2)cc1 ; CC1(C)c2ccccc2-c2ccc(N(c3ccccc3)c3cc(N(c4ccccc4)c4ccc5ccccc5c4)cc4nc(-c5ccccc5)oc34)cc21]

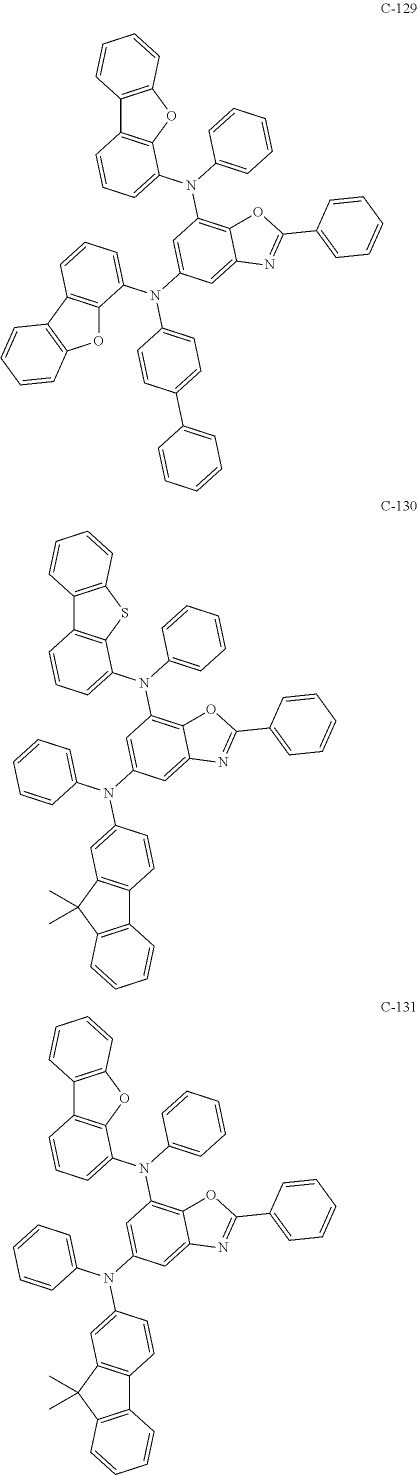

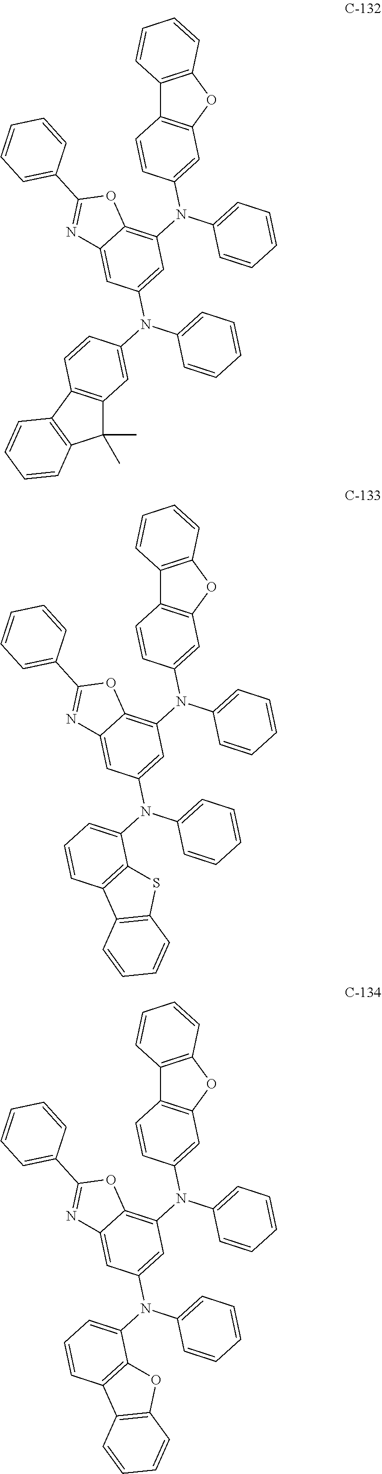

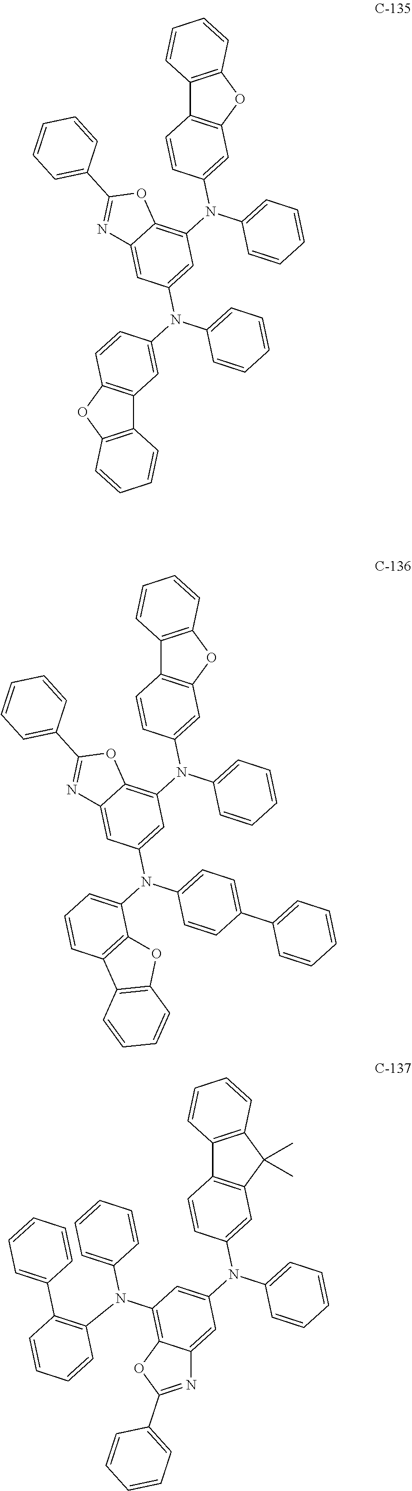 [SMILES: c1ccc(-c2nc3cc(N(c4ccccc4)c4ccc5oc6ccccc6c5c4)cc(N(c4ccccc4)c4ccc5c(c4)oc4ccccc45)c3o2)cc1 ; c1ccc(-c2ccc(N(c3cc(N(c4ccccc4)c4ccc5c(c4)oc4ccccc45)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4ccccc4-c4ccccc4)c4oc(-c5ccccc5)nc4c3)cc21]

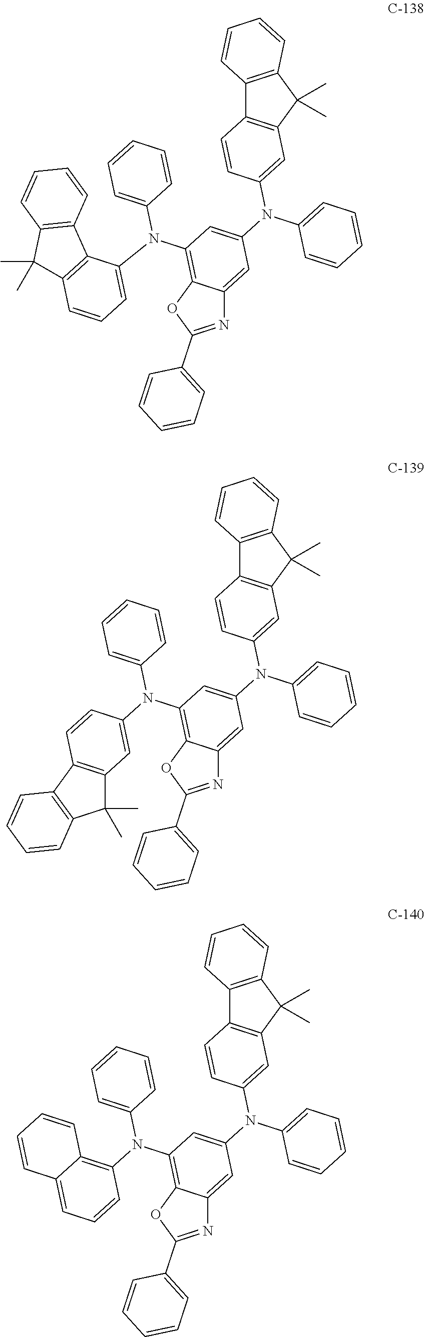 [SMILES: CC1(C)c2ccccc2-c2ccc(N(c3ccccc3)c3cc(N(c4ccccc4)c4cccc5c4-c4ccccc4C5(C)C)c4oc(-c5ccccc5)nc4c3)cc21 ; CC1(C)c2ccccc2-c2ccc(N(c3ccccc3)c3cc(N(c4ccccc4)c4ccc5c(c4)C(C)(C)c4ccccc4-5)c4oc(-c5ccccc5)nc4c3)cc21 ; CC1(C)c2ccccc2-c2ccc(N(c3ccccc3)c3cc(N(c4ccccc4)c4cccc5ccccc45)c4oc(-c5ccccc5)nc4c3)cc21]

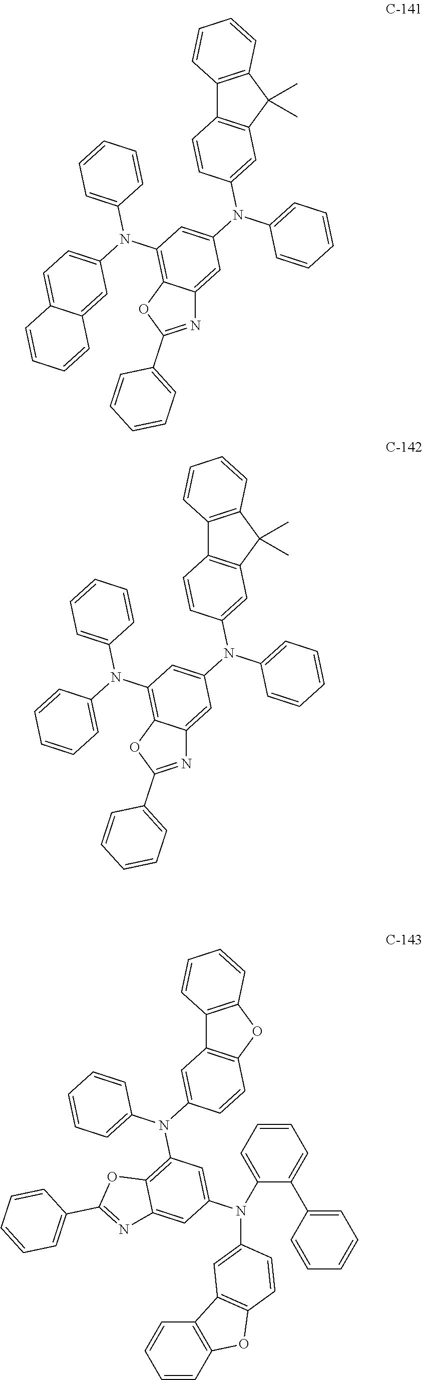 [SMILES: CC1(C)c2ccccc2-c2ccc(N(c3ccccc3)c3cc(N(c4ccccc4)c4ccc5ccccc5c4)c4oc(-c5ccccc5)nc4c3)cc21 ; CC1(C)c2ccccc2-c2ccc(N(c3ccccc3)c3cc(N(c4ccccc4)c4ccccc4)c4oc(-c5ccccc5)nc4c3)cc21 ; c1ccc(-c2nc3cc(N(c4ccc5oc6ccccc6c5c4)c4ccccc4-c4ccccc4)cc(N(c4ccccc4)c4ccc5oc6ccccc6c5c4)c3o2)cc1]

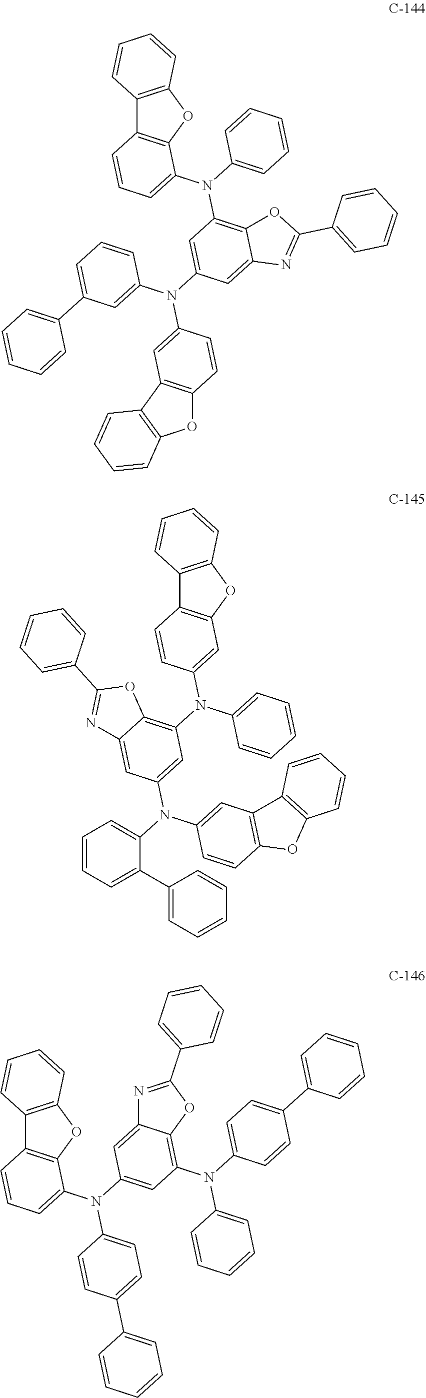 [SMILES: c1ccc(-c2cccc(N(c3cc(N(c4ccccc4)c4cccc5c4oc4ccccc45)c4oc(-c5ccccc5)nc4c3)c3ccc4oc5ccccc5c4c3)c2)cc1 ; c1ccc(-c2nc3cc(N(c4ccc5oc6ccccc6c5c4)c4ccccc4-c4ccccc4)cc(N(c4ccccc4)c4ccc5c(c4)oc4ccccc45)c3o2)cc1 ; c1ccc(-c2ccc(N(c3ccccc3)c3cc(N(c4ccc(-c5ccccc5)cc4)c4cccc5c4oc4ccccc45)cc4nc(-c5ccccc5)oc34)cc2)cc1]

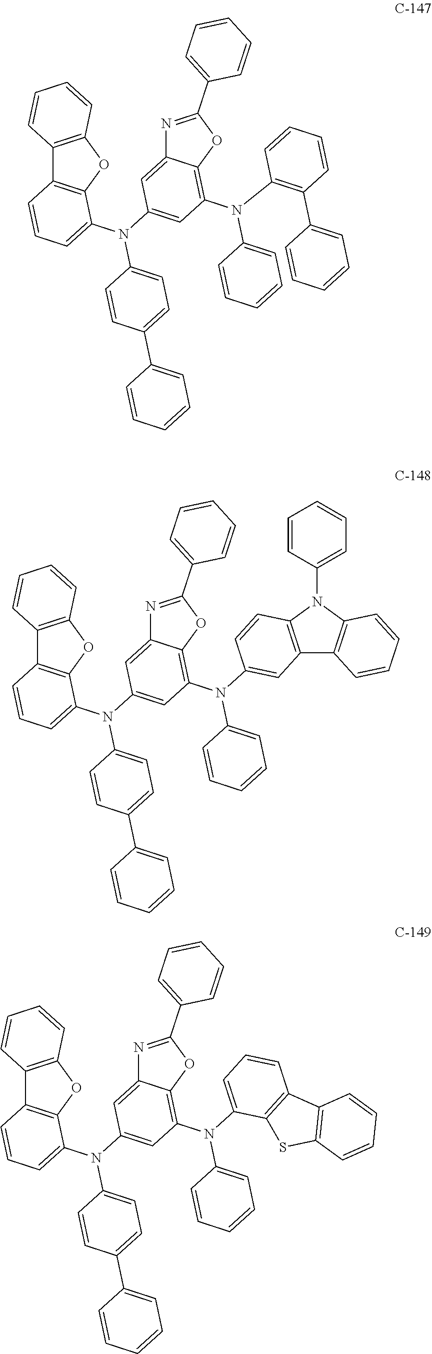

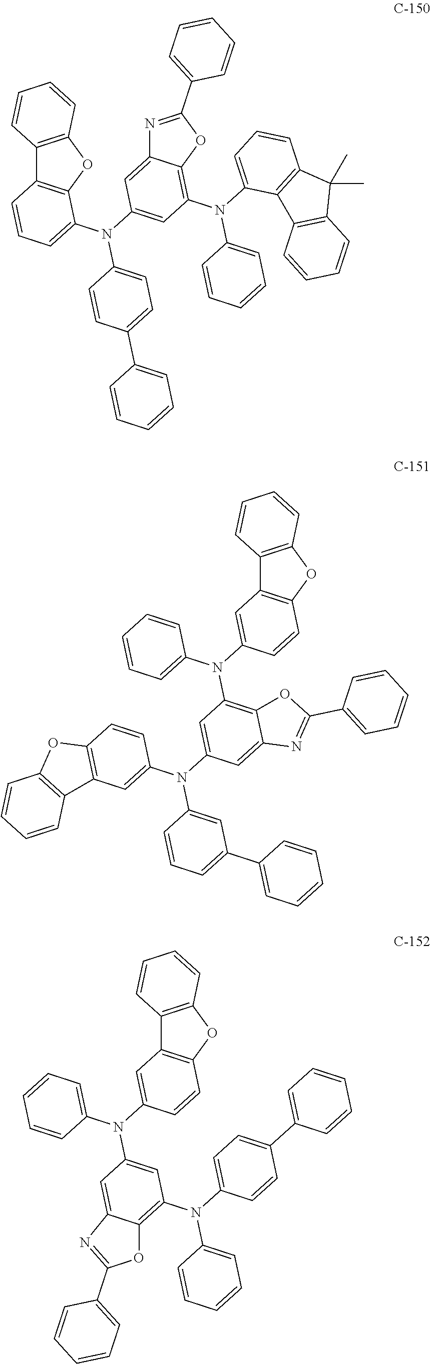 [SMILES: CC1(C)c2ccccc2-c2c(N(c3ccccc3)c3cc(N(c4ccc(-c5ccccc5)cc4)c4cccc5c4oc4ccccc45)cc4nc(-c5ccccc5)oc34)cccc21 ; c1ccc(-c2cccc(N(c3cc(N(c4ccccc4)c4ccc5oc6ccccc6c5c4)c4oc(-c5ccccc5)nc4c3)c3ccc4oc5ccccc5c4c3)c2)cc1 ; c1ccc(-c2ccc(N(c3ccccc3)c3cc(N(c4ccccc4)c4ccc5oc6ccccc6c5c4)cc4nc(-c5ccccc5)oc34)cc2)cc1]

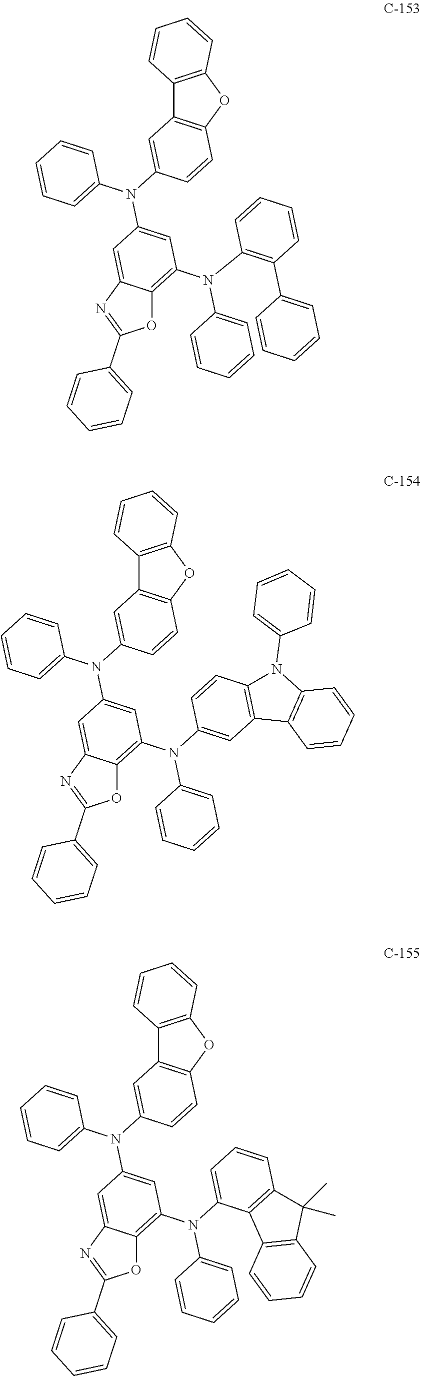 [SMILES: c1ccc(-c2nc3cc(N(c4ccccc4)c4ccc5oc6ccccc6c5c4)cc(N(c4ccccc4)c4ccccc4-c4ccccc4)c3o2)cc1 ; c1ccc(-c2nc3cc(N(c4ccccc4)c4ccc5oc6ccccc6c5c4)cc(N(c4ccccc4)c4ccc5c(c4)c4ccccc4n5-c4ccccc4)c3o2)cc1 ; CC1(C)c2ccccc2-c2c(N(c3ccccc3)c3cc(N(c4ccccc4)c4ccc5oc6ccccc6c5c4)cc4nc(-c5ccccc5)oc34)cccc21]

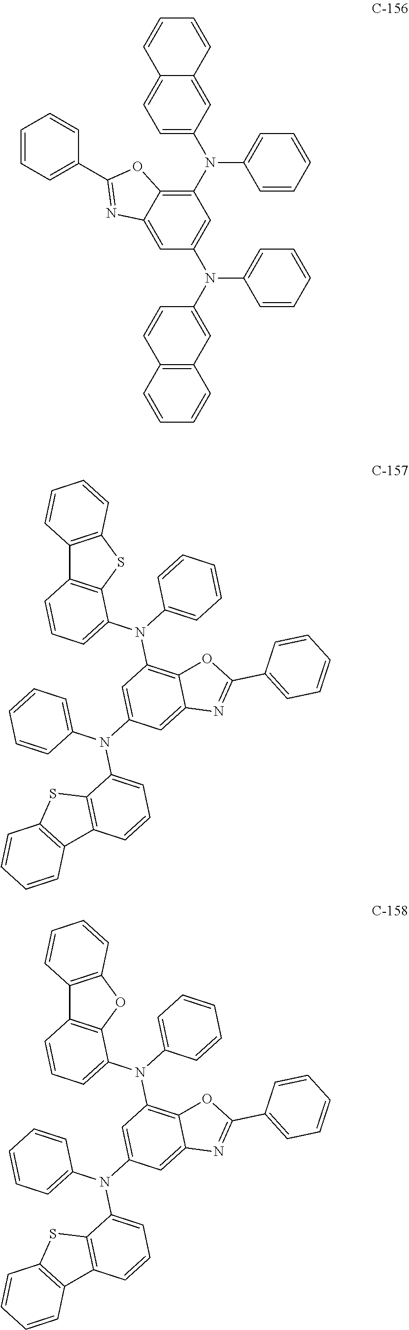 [SMILES: c1ccc(-c2nc3cc(N(c4ccccc4)c4ccc5ccccc5c4)cc(N(c4ccccc4)c4ccc5ccccc5c4)c3o2)cc1 ; c1ccc(-c2nc3cc(N(c4ccccc4)c4cccc5c4sc4ccccc45)cc(N(c4ccccc4)c4cccc5c4sc4ccccc45)c3o2)cc1 ; c1ccc(-c2nc3cc(N(c4ccccc4)c4cccc5c4sc4ccccc45)cc(N(c4ccccc4)c4cccc5c4oc4ccccc45)c3o2)cc1]

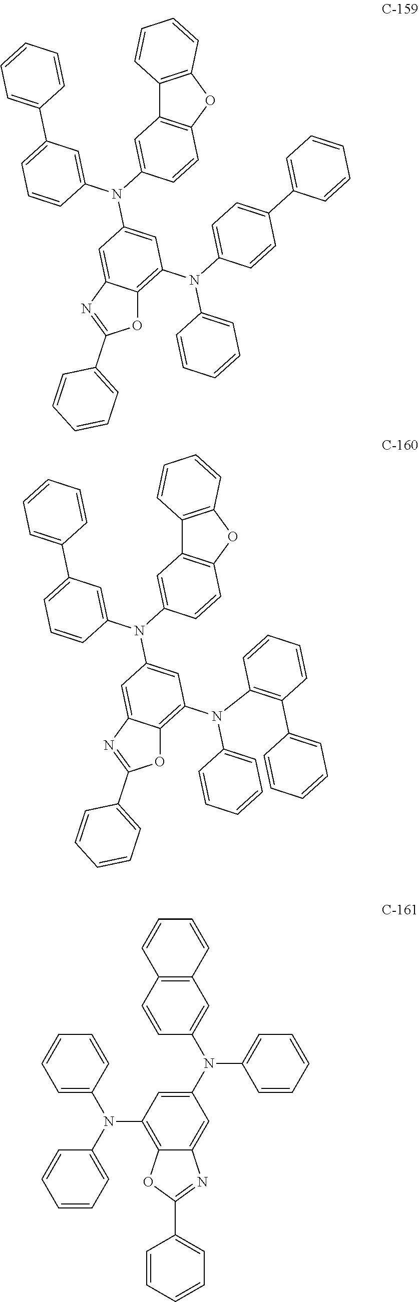 [SMILES: c1ccc(-c2ccc(N(c3ccccc3)c3cc(N(c4cccc(-c5ccccc5)c4)c4ccc5oc6ccccc6c5c4)cc4nc(-c5ccccc5)oc34)cc2)cc1 ; c1ccc(-c2cccc(N(c3cc(N(c4ccccc4)c4ccccc4-c4ccccc4)c4oc(-c5ccccc5)nc4c3)c3ccc4oc5ccccc5c4c3)c2)cc1 ; c1ccc(-c2nc3cc(N(c4ccccc4)c4ccc5ccccc5c4)cc(N(c4ccccc4)c4ccccc4)c3o2)cc1]

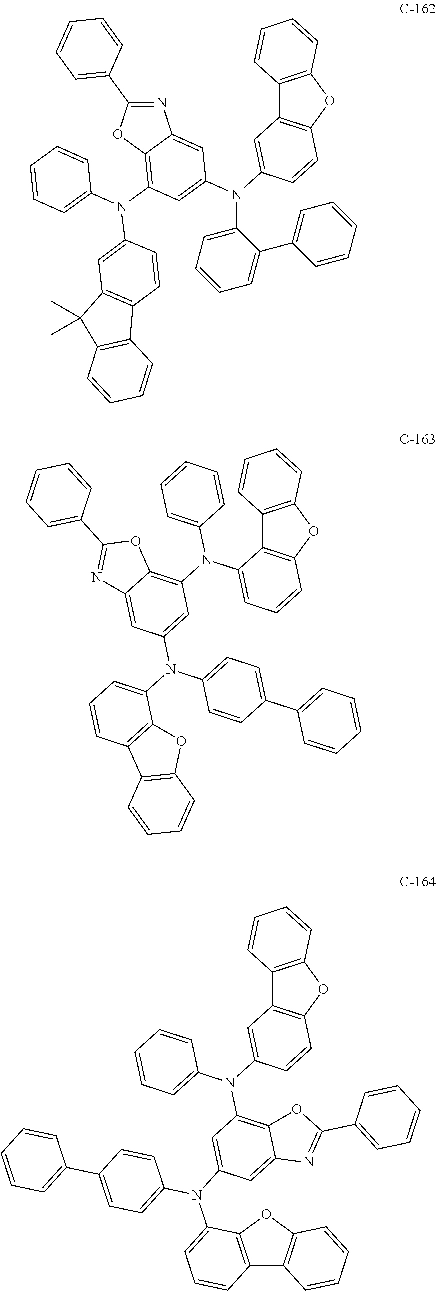 [SMILES: CC1(C)c2ccccc2-c2ccc(N(c3ccccc3)c3cc(N(c4ccc5oc6ccccc6c5c4)c4ccccc4-c4ccccc4)cc4nc(-c5ccccc5)oc34)cc21 ; c1ccc(-c2ccc(N(c3cc(N(c4ccccc4)c4cccc5oc6ccccc6c45)c4oc(-c5ccccc5)nc4c3)c3cccc4c3oc3ccccc34)cc2)cc1 ; c1ccc(-c2ccc(N(c3cc(N(c4ccccc4)c4ccc5oc6ccccc6c5c4)c4oc(-c5ccccc5)nc4c3)c3cccc4c3oc3ccccc34)cc2)cc1]

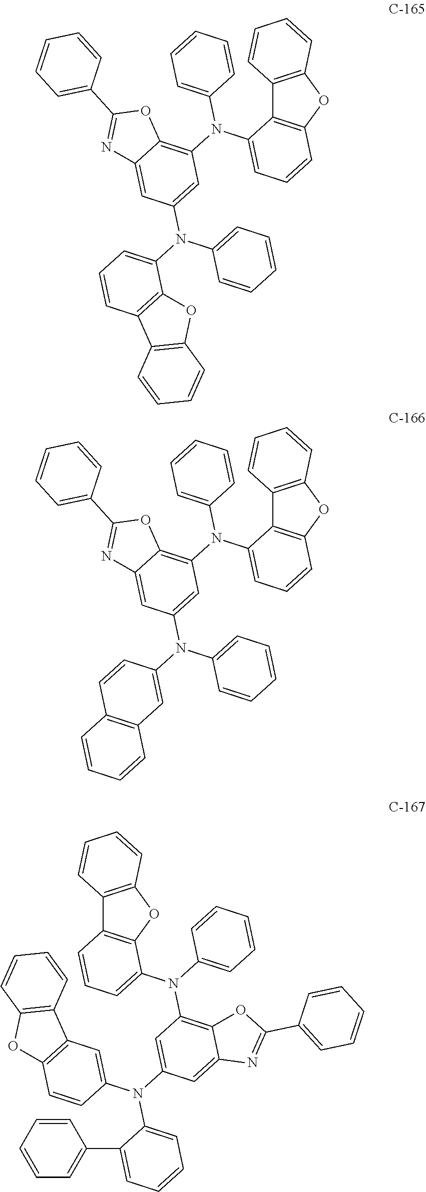

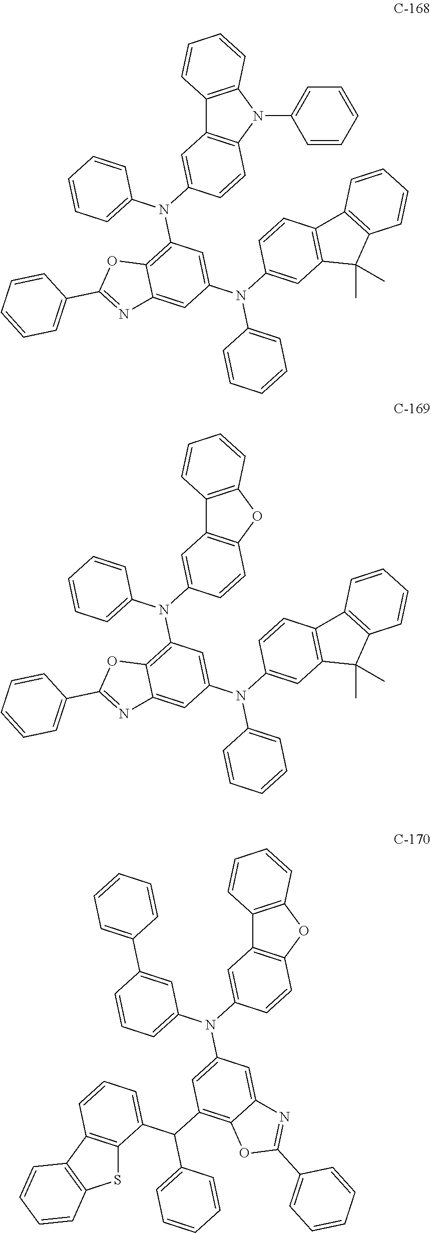 [SMILES: CC1(C)c2ccccc2-c2ccc(N(c3ccccc3)c3cc(N(c4ccccc4)c4ccc5c(c4)c4ccccc4n5-c4ccccc4)c4oc(-c5ccccc5)nc4c3)cc21 ; CC1(C)c2ccccc2-c2ccc(N(c3ccccc3)c3cc(N(c4ccccc4)c4ccc5oc6ccccc6c5c4)c4oc(-c5ccccc5)nc4c3)cc21 ; c1ccc(-c2cccc(N(c3cc(C(c4ccccc4)c4cccc5c4sc4ccccc45)c4oc(-c5ccccc5)nc4c3)c3ccc4oc5ccccc5c4c3)c2)cc1]

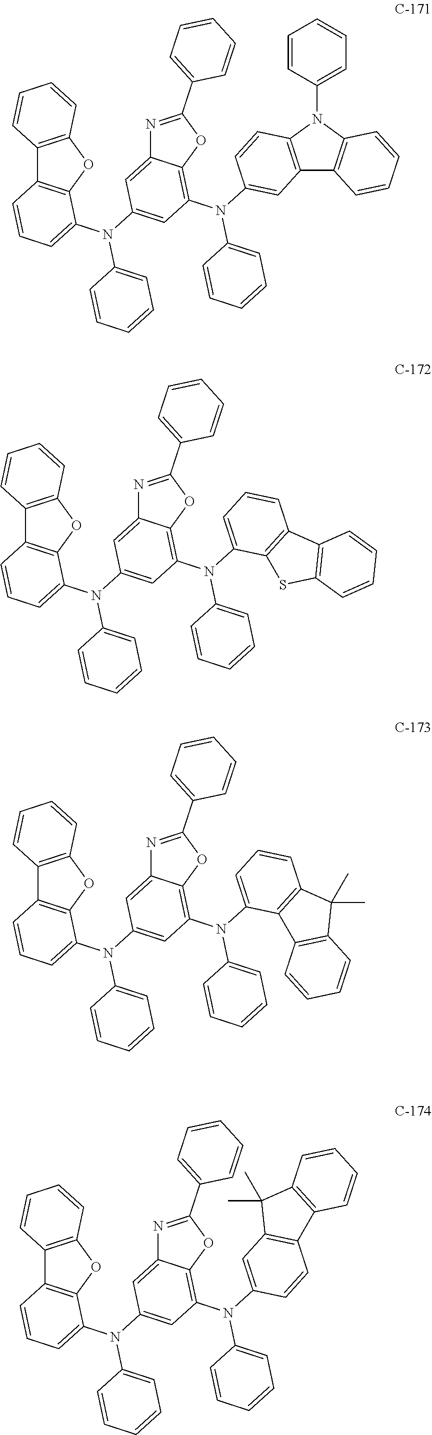 [SMILES: c1ccc(-c2nc3cc(N(c4ccccc4)c4cccc5c4oc4ccccc45)cc(N(c4ccccc4)c4ccc5c(c4)c4ccccc4n5-c4ccccc4)c3o2)cc1 ; c1ccc(-c2nc3cc(N(c4ccccc4)c4cccc5c4oc4ccccc45)cc(N(c4ccccc4)c4cccc5c4sc4ccccc45)c3o2)cc1 ; CC1(C)c2ccccc2-c2c(N(c3ccccc3)c3cc(N(c4ccccc4)c4cccc5c4oc4ccccc45)cc4nc(-c5ccccc5)oc34)cccc21 ; CC1(C)c2ccccc2-c2ccc(N(c3ccccc3)c3cc(N(c4ccccc4)c4cccc5c4oc4ccccc45)cc4nc(-c5ccccc5)oc34)cc21]

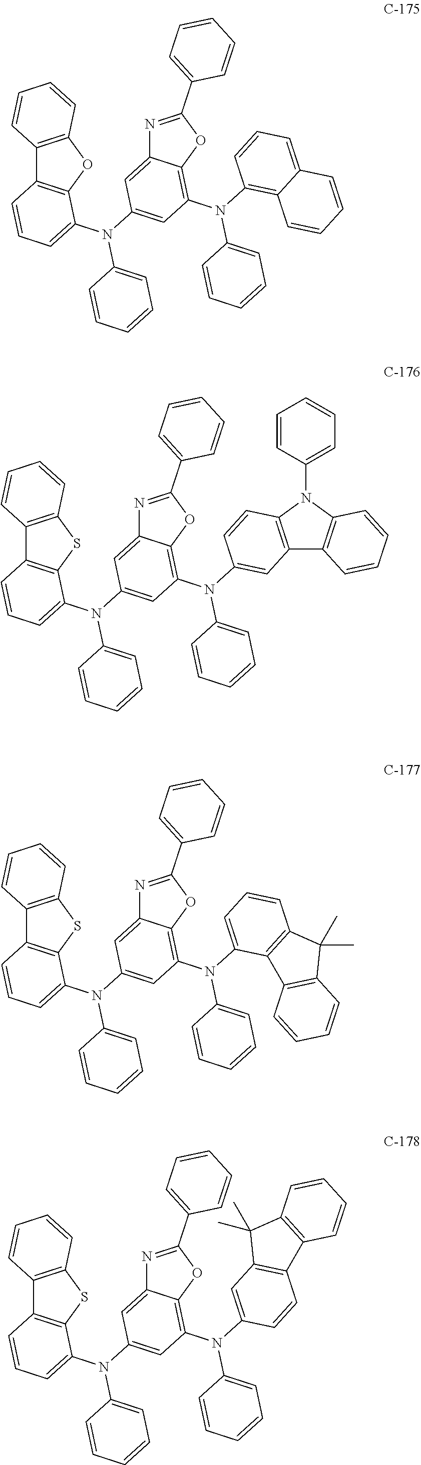 [SMILES: c1ccc(-c2nc3cc(N(c4ccccc4)c4cccc5c4oc4ccccc45)cc(N(c4ccccc4)c4cccc5ccccc45)c3o2)cc1 ; c1ccc(-c2nc3cc(N(c4ccccc4)c4cccc5c4sc4ccccc45)cc(N(c4ccccc4)c4ccc5c(c4)c4ccccc4n5-c4ccccc4)c3o2)cc1 ; CC1(C)c2ccccc2-c2c(N(c3ccccc3)c3cc(N(c4ccccc4)c4cccc5c4sc4ccccc45)cc4nc(-c5ccccc5)oc34)cccc21 ; CC1(C)c2ccccc2-c2ccc(N(c3ccccc3)c3cc(N(c4ccccc4)c4cccc5c4sc4ccccc45)cc4nc(-c5ccccc5)oc34)cc21]

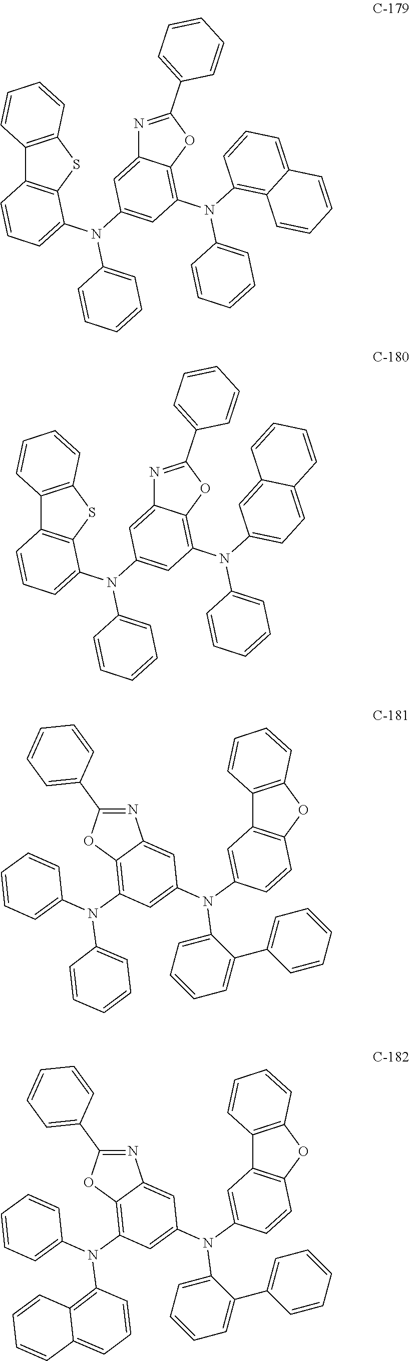 [SMILES: c1ccc(-c2nc3cc(N(c4ccccc4)c4cccc5c4sc4ccccc45)cc(N(c4ccccc4)c4cccc5ccccc45)c3o2)cc1 ; c1ccc(-c2nc3cc(N(c4ccccc4)c4cccc5c4sc4ccccc45)cc(N(c4ccccc4)c4ccc5ccccc5c4)c3o2)cc1 ; c1ccc(-c2nc3cc(N(c4ccc5oc6ccccc6c5c4)c4ccccc4-c4ccccc4)cc(N(c4ccccc4)c4ccccc4)c3o2)cc1 ; c1ccc(-c2nc3cc(N(c4ccc5oc6ccccc6c5c4)c4ccccc4-c4ccccc4)cc(N(c4ccccc4)c4cccc5ccccc45)c3o2)cc1]

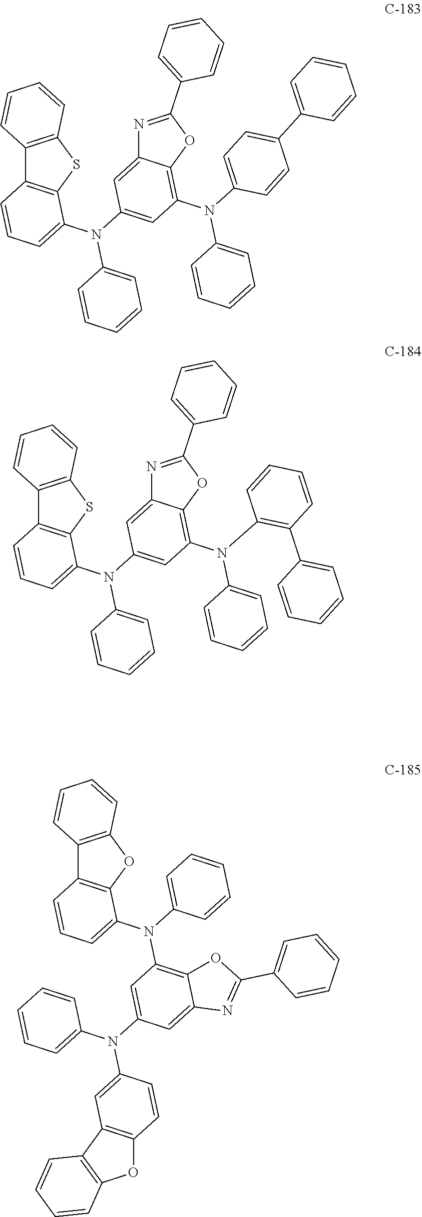 [SMILES: c1ccc(-c2ccc(N(c3ccccc3)c3cc(N(c4ccccc4)c4cccc5c4sc4ccccc45)cc4nc(-c5ccccc5)oc34)cc2)cc1 ; c1ccc(-c2nc3cc(N(c4ccccc4)c4cccc5c4sc4ccccc45)cc(N(c4ccccc4)c4ccccc4-c4ccccc4)c3o2)cc1 ; c1ccc(-c2nc3cc(N(c4ccccc4)c4ccc5oc6ccccc6c5c4)cc(N(c4ccccc4)c4cccc5c4oc4ccccc45)c3o2)cc1]

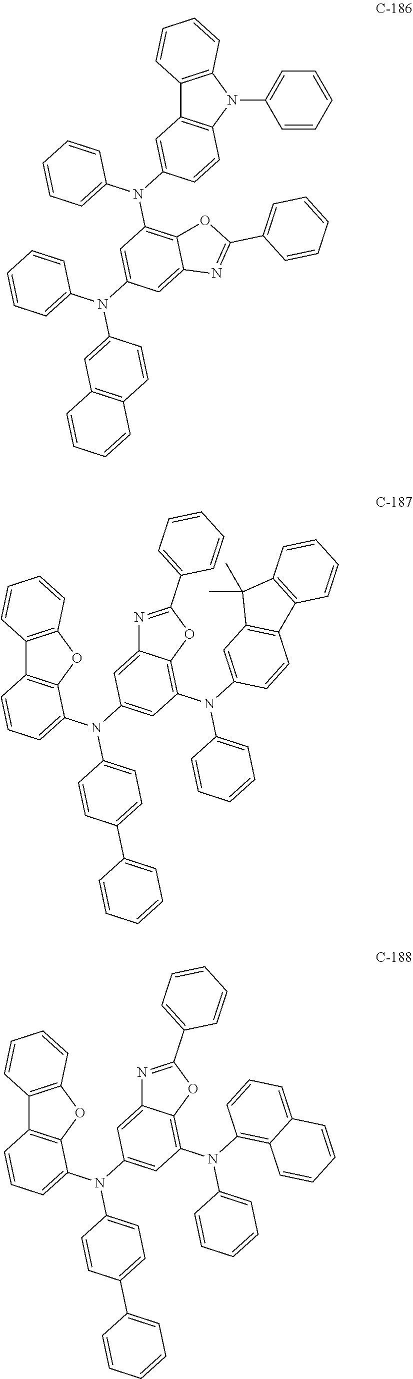 [SMILES: c1ccc(-c2nc3cc(N(c4ccccc4)c4ccc5ccccc5c4)cc(N(c4ccccc4)c4ccc5c(c4)c4ccccc4n5-c4ccccc4)c3o2)cc1 ; CC1(C)c2ccccc2-c2ccc(N(c3ccccc3)c3cc(N(c4ccc(-c5ccccc5)cc4)c4cccc5c4oc4ccccc45)cc4nc(-c5ccccc5)oc34)cc21 ; c1ccc(-c2ccc(N(c3cc(N(c4ccccc4)c4cccc5ccccc45)c4oc(-c5ccccc5)nc4c3)c3cccc4c3oc3ccccc34)cc2)cc1]

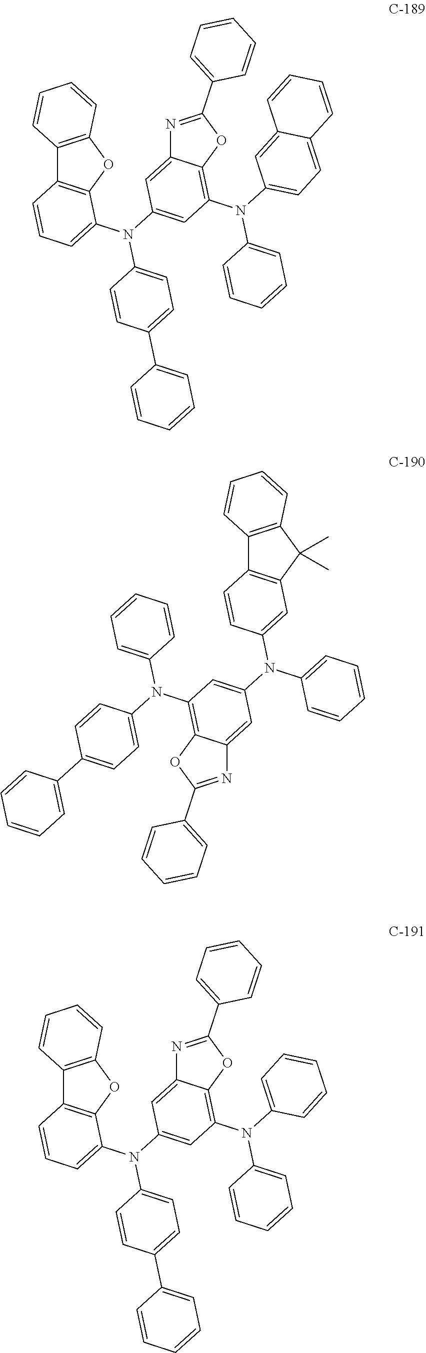 [SMILES: c1ccc(-c2ccc(N(c3cc(N(c4ccccc4)c4ccc5ccccc5c4)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4ccc(-c5ccccc5)cc4)c4oc(-c5ccccc5)nc4c3)cc21 ; c1ccc(-c2ccc(N(c3cc(N(c4ccccc4)c4ccccc4)c4oc(-c5ccccc5)nc4c3)c3cccc4c3oc3ccccc34)cc2)cc1]

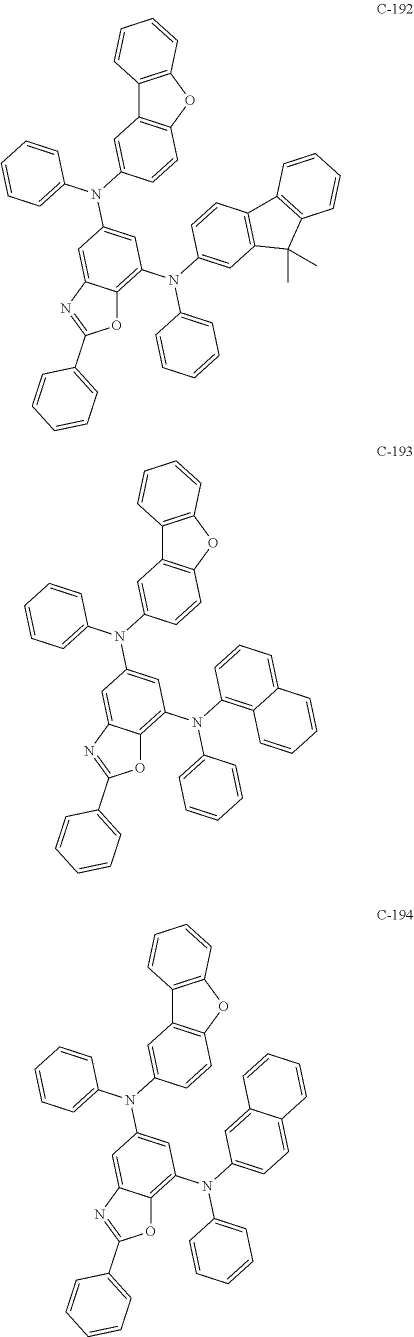 [SMILES: CC1(C)c2ccccc2-c2ccc(N(c3ccccc3)c3cc(N(c4ccccc4)c4ccc5oc6ccccc6c5c4)cc4nc(-c5ccccc5)oc34)cc21 ; c1ccc(-c2nc3cc(N(c4ccccc4)c4ccc5oc6ccccc6c5c4)cc(N(c4ccccc4)c4cccc5ccccc45)c3o2)cc1 ; c1ccc(-c2nc3cc(N(c4ccccc4)c4ccc5oc6ccccc6c5c4)cc(N(c4ccccc4)c4ccc5ccccc5c4)c3o2)cc1]

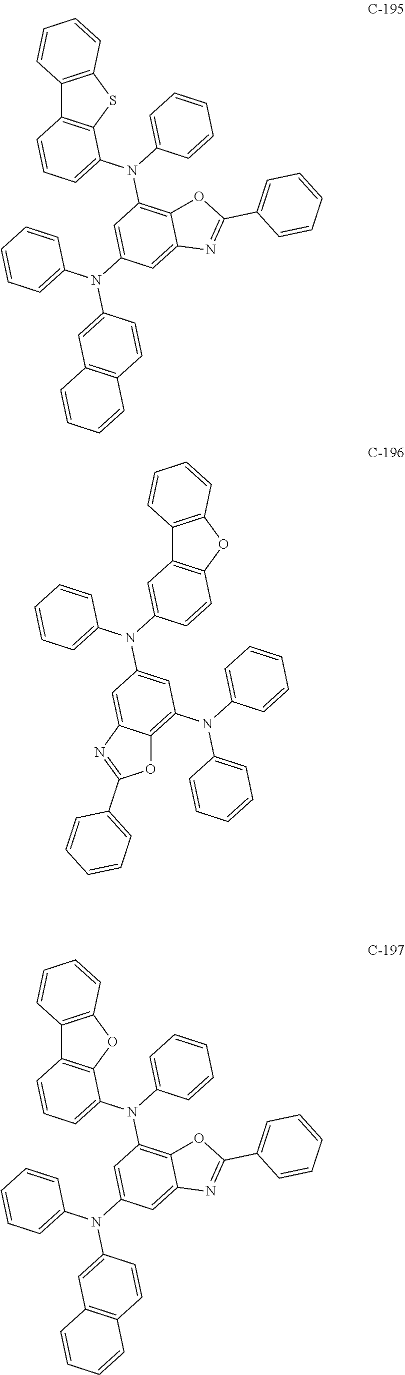 [SMILES: c1ccc(-c2nc3cc(N(c4ccccc4)c4ccc5ccccc5c4)cc(N(c4ccccc4)c4cccc5c4sc4ccccc45)c3o2)cc1 ; c1ccc(-c2nc3cc(N(c4ccccc4)c4ccc5oc6ccccc6c5c4)cc(N(c4ccccc4)c4ccccc4)c3o2)cc1 ; c1ccc(-c2nc3cc(N(c4ccccc4)c4ccc5ccccc5c4)cc(N(c4ccccc4)c4cccc5c4oc4ccccc45)c3o2)cc1]

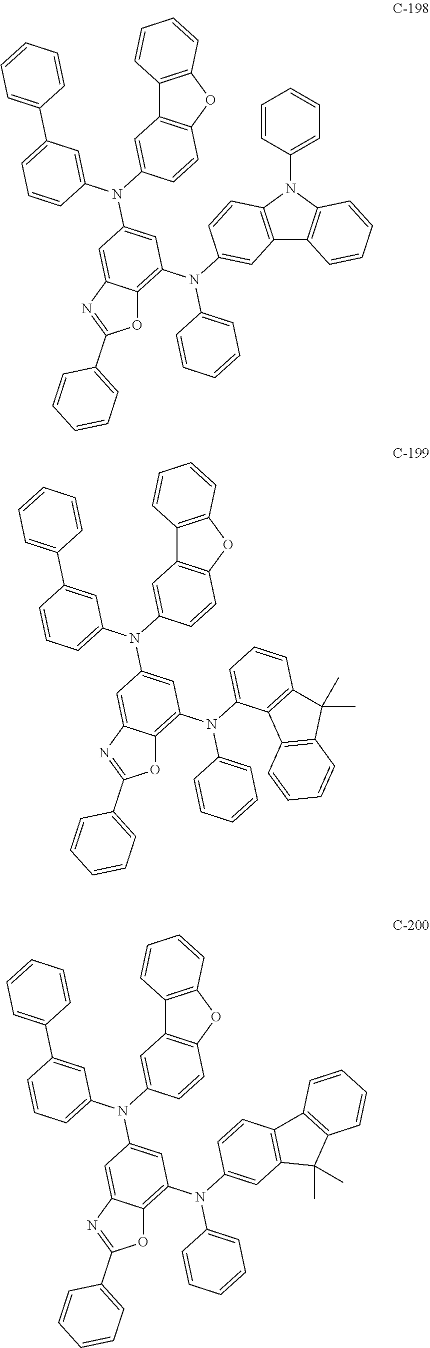 [SMILES: c1ccc(-c2cccc(N(c3cc(N(c4ccccc4)c4ccc5c(c4)c4ccccc4n5-c4ccccc4)c4oc(-c5ccccc5)nc4c3)c3ccc4oc5ccccc5c4c3)c2)cc1 ; CC1(C)c2ccccc2-c2c(N(c3ccccc3)c3cc(N(c4cccc(-c5ccccc5)c4)c4ccc5oc6ccccc6c5c4)cc4nc(-c5ccccc5)oc34)cccc21 ; CC1(C)c2ccccc2-c2ccc(N(c3ccccc3)c3cc(N(c4cccc(-c5ccccc5)c4)c4ccc5oc6ccccc6c5c4)cc4nc(-c5ccccc5)oc34)cc21]

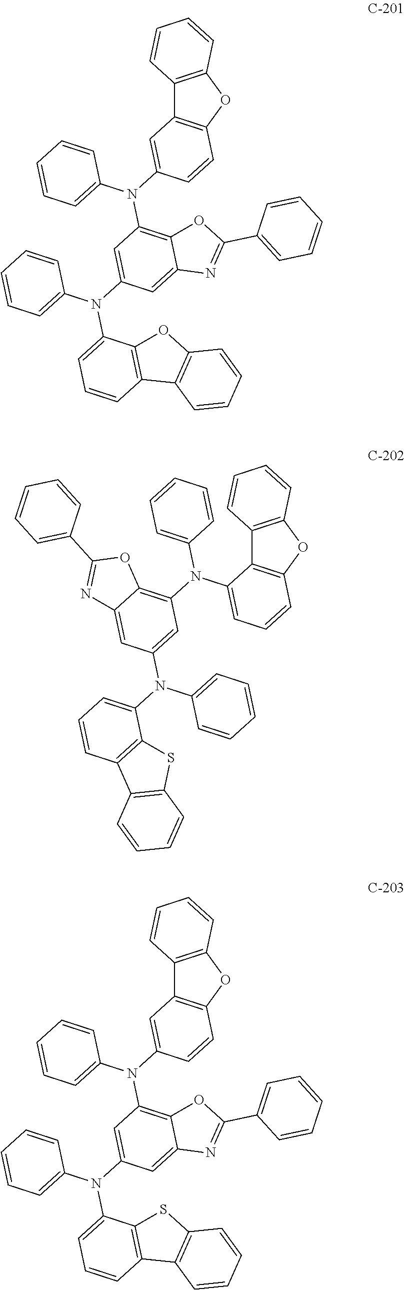 [SMILES: c1ccc(-c2nc3cc(N(c4ccccc4)c4cccc5c4oc4ccccc45)cc(N(c4ccccc4)c4ccc5oc6ccccc6c5c4)c3o2)cc1 ; c1ccc(-c2nc3cc(N(c4ccccc4)c4cccc5c4sc4ccccc45)cc(N(c4ccccc4)c4cccc5oc6ccccc6c45)c3o2)cc1 ; c1ccc(-c2nc3cc(N(c4ccccc4)c4cccc5c4sc4ccccc45)cc(N(c4ccccc4)c4ccc5oc6ccccc6c5c4)c3o2)cc1]

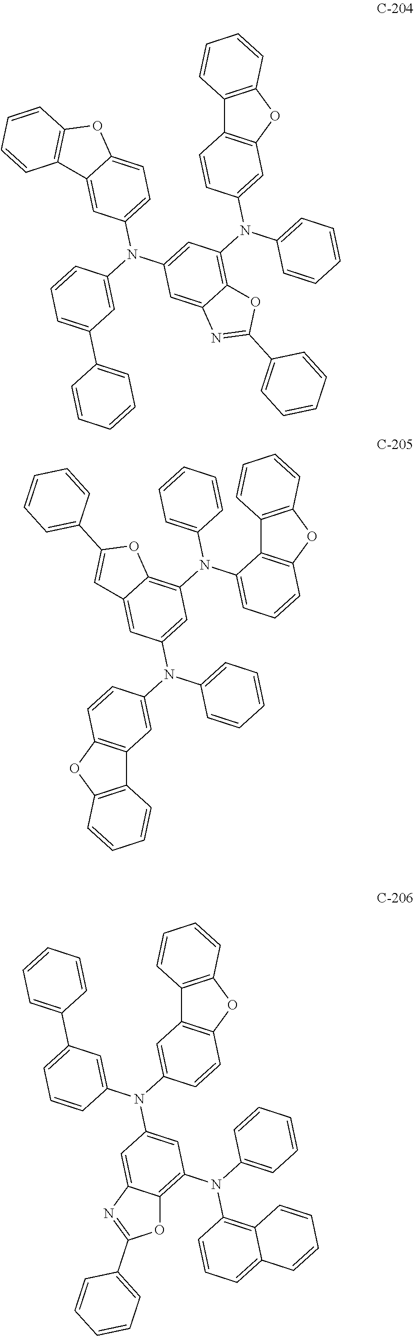

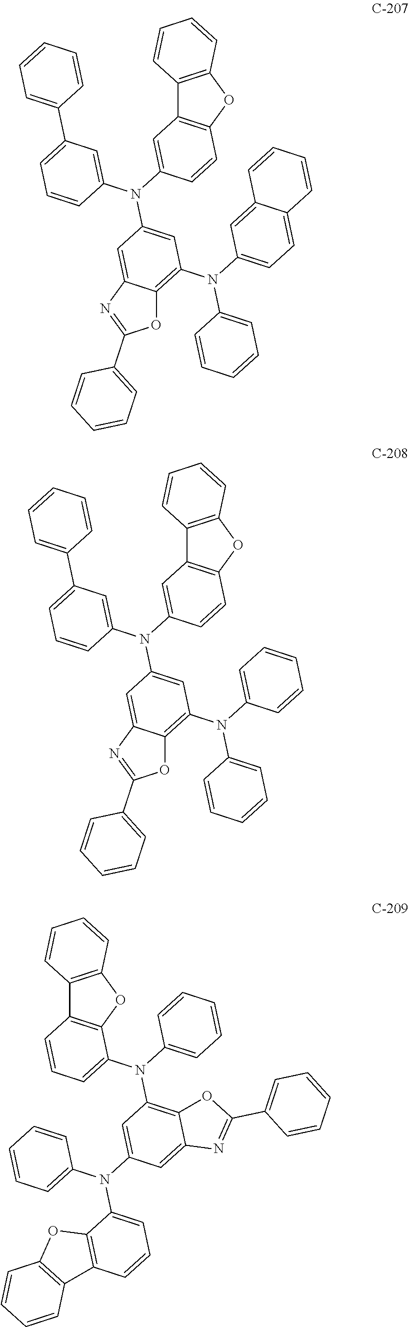

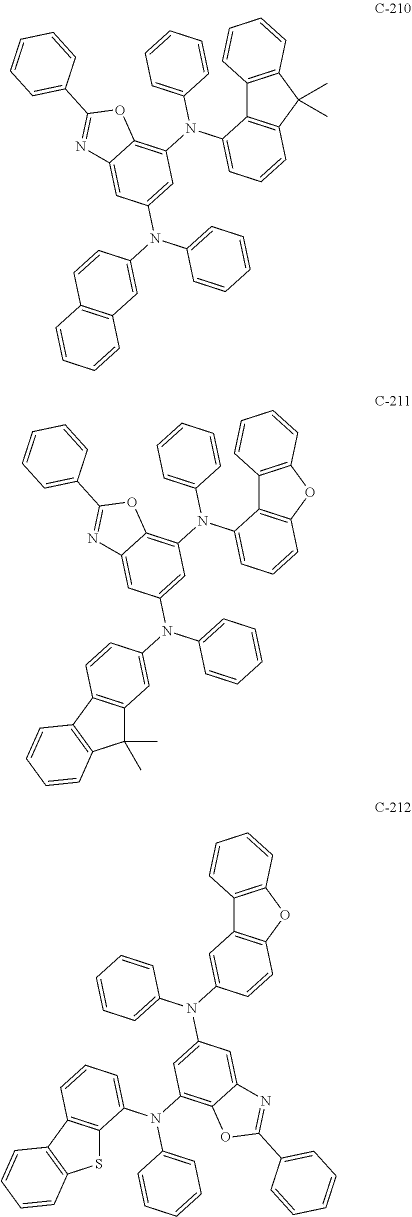 [SMILES: CC1(C)c2ccccc2-c2c(N(c3ccccc3)c3cc(N(c4ccccc4)c4ccc5ccccc5c4)cc4nc(-c5ccccc5)oc34)cccc21 ; CC1(C)c2ccccc2-c2ccc(N(c3ccccc3)c3cc(N(c4ccccc4)c4cccc5oc6ccccc6c45)c4oc(-c5ccccc5)nc4c3)cc21 ; c1ccc(-c2nc3cc(N(c4ccccc4)c4ccc5oc6ccccc6c5c4)cc(N(c4ccccc4)c4cccc5c4sc4ccccc45)c3o2)cc1]

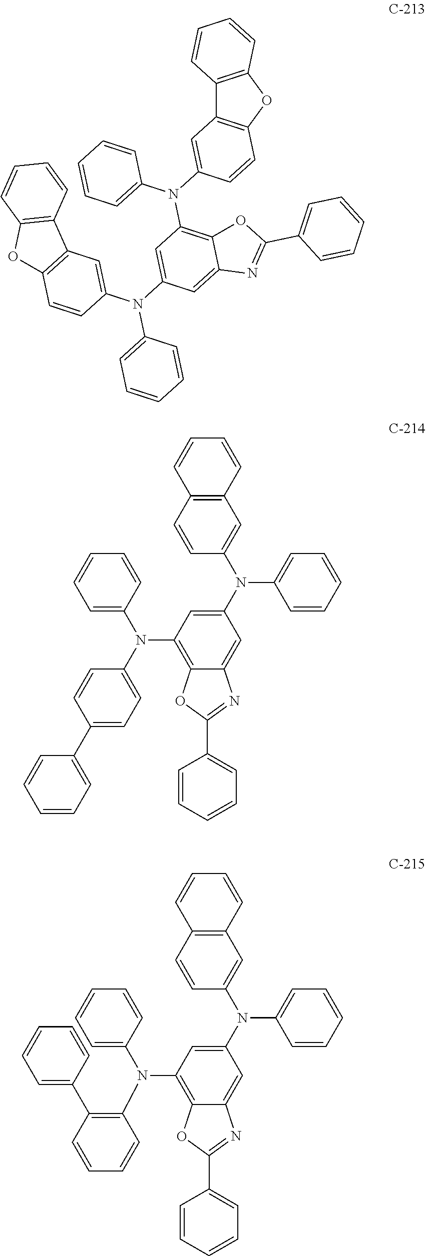 [SMILES: c1ccc(-c2nc3cc(N(c4ccccc4)c4ccc5oc6ccccc6c5c4)cc(N(c4ccccc4)c4ccc5oc6ccccc6c5c4)c3o2)cc1 ; c1ccc(-c2ccc(N(c3ccccc3)c3cc(N(c4ccccc4)c4ccc5ccccc5c4)cc4nc(-c5ccccc5)oc34)cc2)cc1 ; c1ccc(-c2nc3cc(N(c4ccccc4)c4ccc5ccccc5c4)cc(N(c4ccccc4)c4ccccc4-c4ccccc4)c3o2)cc1]

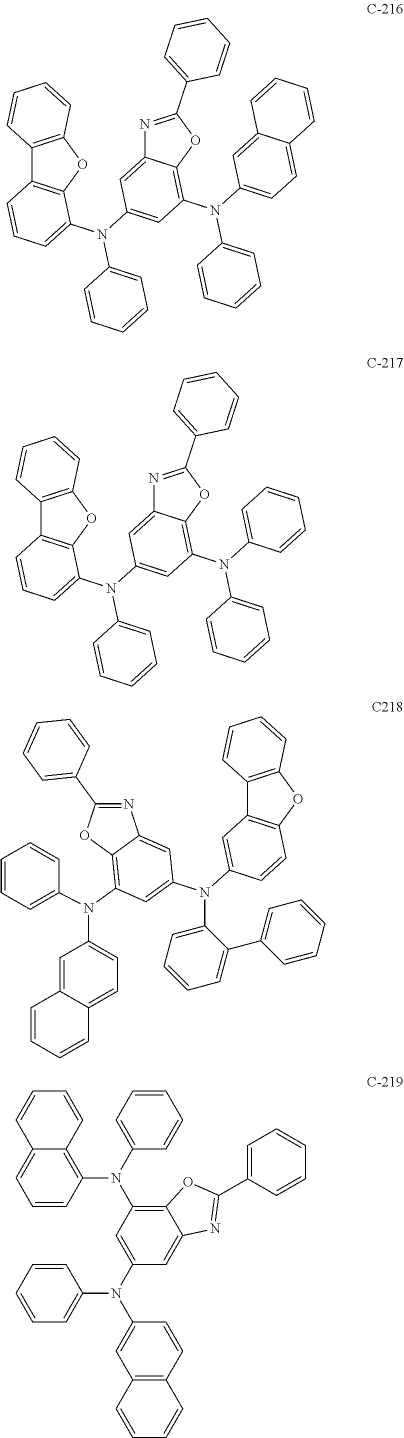

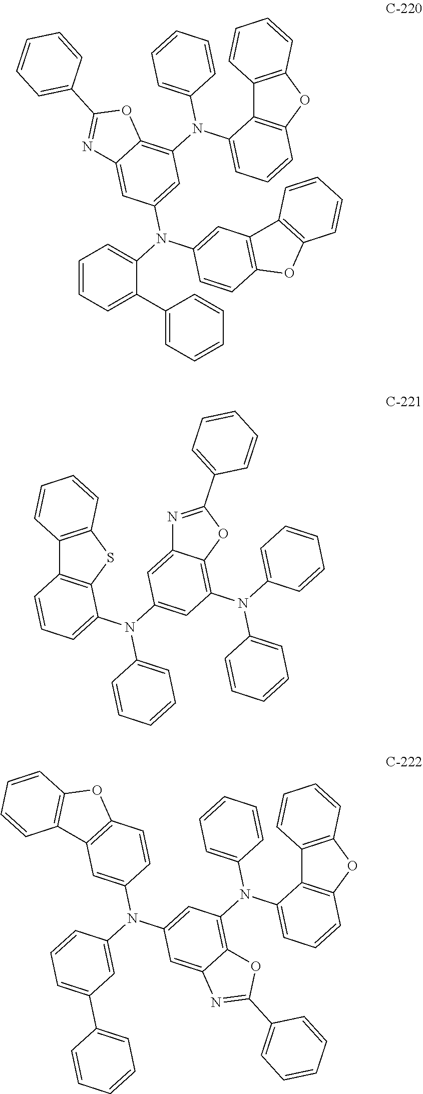 [SMILES: c1ccc(-c2nc3cc(N(c4ccc5oc6ccccc6c5c4)c4ccccc4-c4ccccc4)cc(N(c4ccccc4)c4cccc5oc6ccccc6c45)c3o2)cc1 ; c1ccc(-c2nc3cc(N(c4ccccc4)c4cccc5c4sc4ccccc45)cc(N(c4ccccc4)c4ccccc4)c3o2)cc1 ; c1ccc(-c2cccc(N(c3cc(N(c4ccccc4)c4cccc5oc6ccccc6c45)c4oc(-c5ccccc5)nc4c3)c3ccc4oc5ccccc5c4c3)c2)cc1]

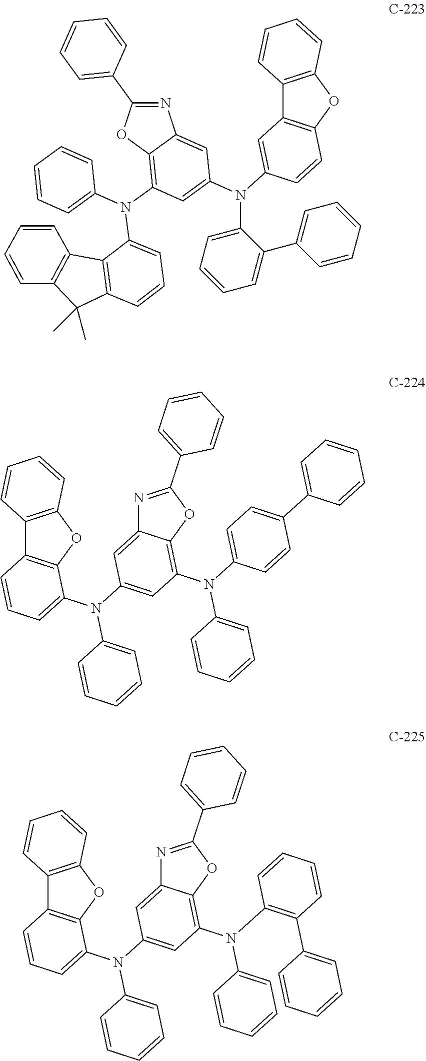 [SMILES: CC1(C)c2ccccc2-c2c(N(c3ccccc3)c3cc(N(c4ccc5oc6ccccc6c5c4)c4ccccc4-c4ccccc4)cc4nc(-c5ccccc5)oc34)cccc21 ; c1ccc(-c2ccc(N(c3ccccc3)c3cc(N(c4ccccc4)c4cccc5c4oc4ccccc45)cc4nc(-c5ccccc5)oc34)cc2)cc1 ; c1ccc(-c2nc3cc(N(c4ccccc4)c4cccc5c4oc4ccccc45)cc(N(c4ccccc4)c4ccccc4-c4ccccc4)c3o2)cc1]

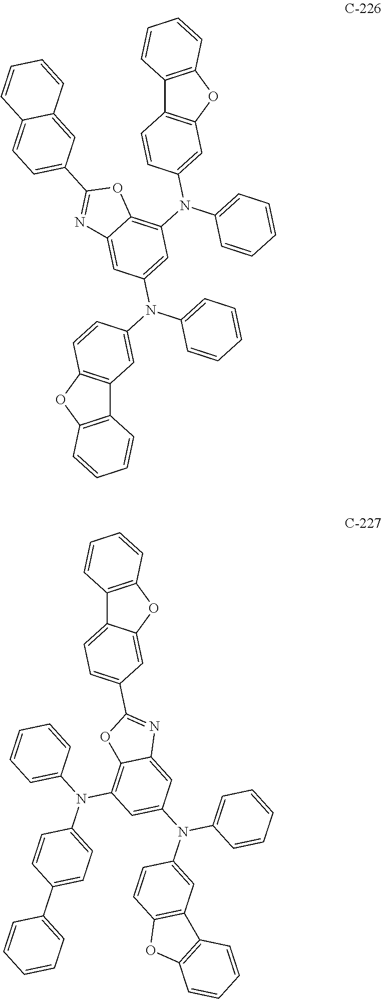 [SMILES: c1ccc(N(c2cc(N(c3ccccc3)c3ccc4c(c3)oc3ccccc34)c3oc(-c4ccc5ccccc5c4)nc3c2)c2ccc3oc4ccccc4c3c2)cc1 ; c1ccc(-c2ccc(N(c3ccccc3)c3cc(N(c4ccccc4)c4ccc5oc6ccccc6c5c4)cc4nc(-c5ccc6c(c5)oc5ccccc56)oc34)cc2)cc1]

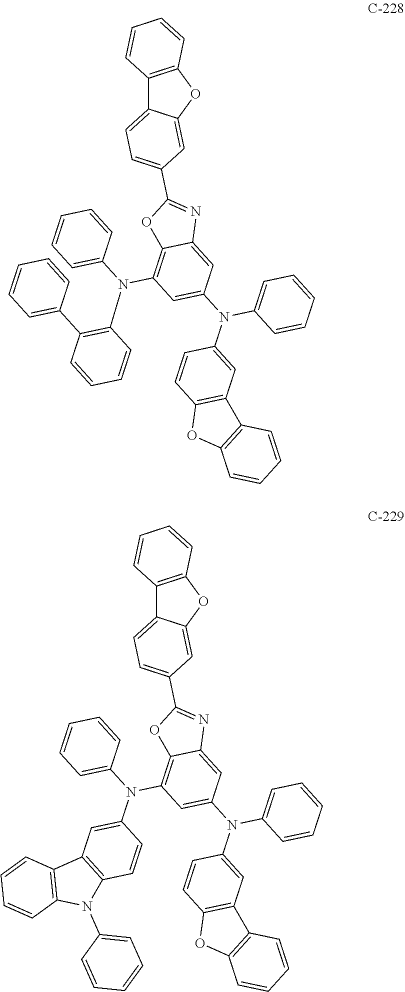 [SMILES: c1ccc(-c2ccccc2N(c2ccccc2)c2cc(N(c3ccccc3)c3ccc4oc5ccccc5c4c3)cc3nc(-c4ccc5c(c4)oc4ccccc45)oc23)cc1 ; c1ccc(N(c2cc(N(c3ccccc3)c3ccc4c(c3)c3ccccc3n4-c3ccccc3)c3oc(-c4ccc5c(c4)oc4ccccc45)nc3c2)c2ccc3oc4ccccc4c3c2)cc1]

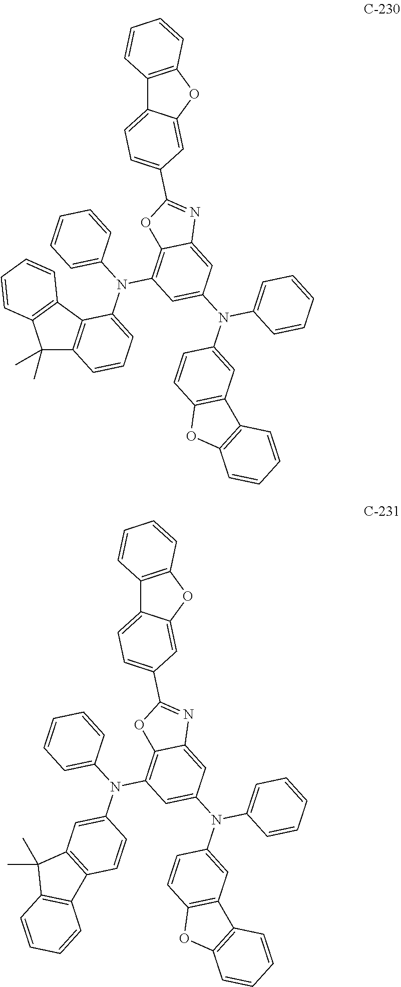 [SMILES: CC1(C)c2ccccc2-c2c(N(c3ccccc3)c3cc(N(c4ccccc4)c4ccc5oc6ccccc6c5c4)cc4nc(-c5ccc6c(c5)oc5ccccc56)oc34)cccc21 ; CC1(C)c2ccccc2-c2ccc(N(c3ccccc3)c3cc(N(c4ccccc4)c4ccc5oc6ccccc6c5c4)cc4nc(-c5ccc6c(c5)oc5ccccc56)oc34)cc21]

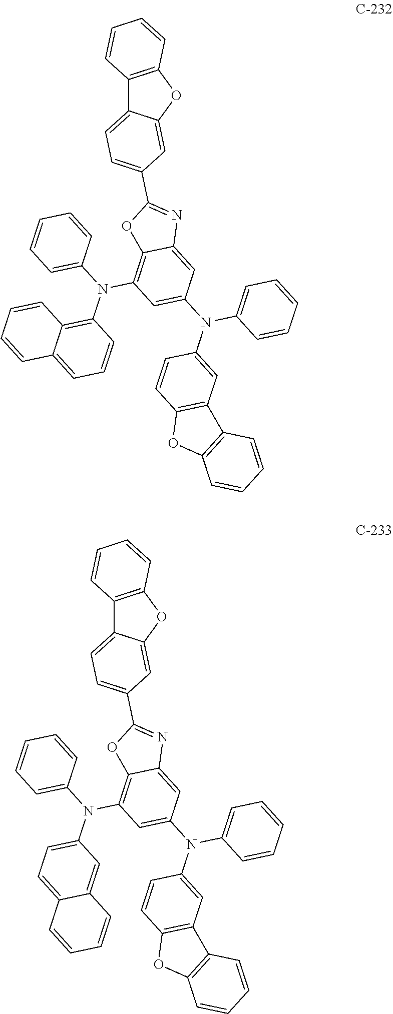 [SMILES: c1ccc(N(c2cc(N(c3ccccc3)c3cccc4ccccc34)c3oc(-c4ccc5c(c4)oc4ccccc45)nc3c2)c2ccc3oc4ccccc4c3c2)cc1 ; c1ccc(N(c2cc(N(c3ccccc3)c3ccc4ccccc4c3)c3oc(-c4ccc5c(c4)oc4ccccc45)nc3c2)c2ccc3oc4ccccc4c3c2)cc1]

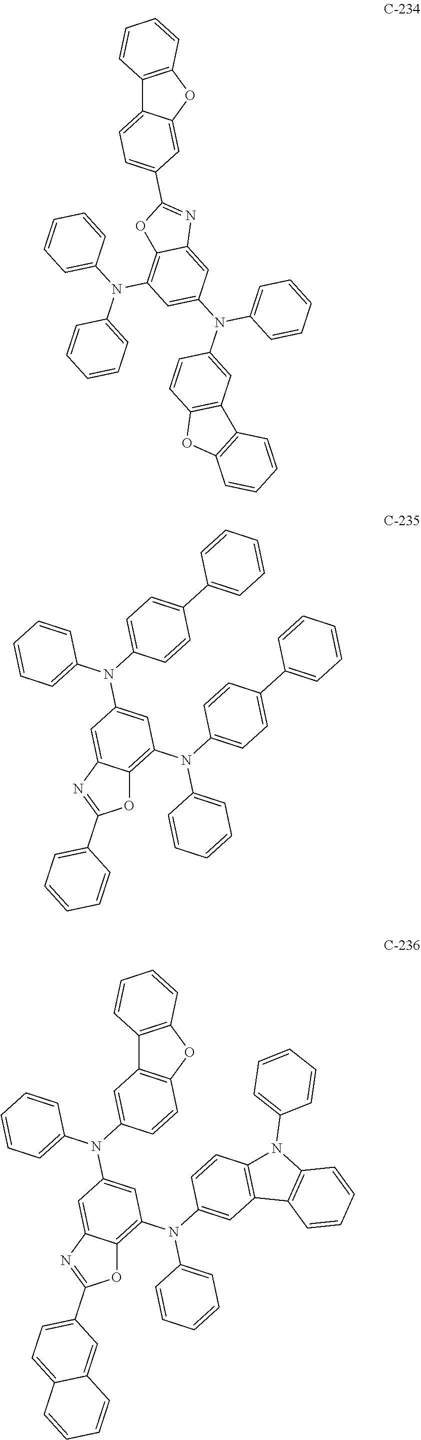

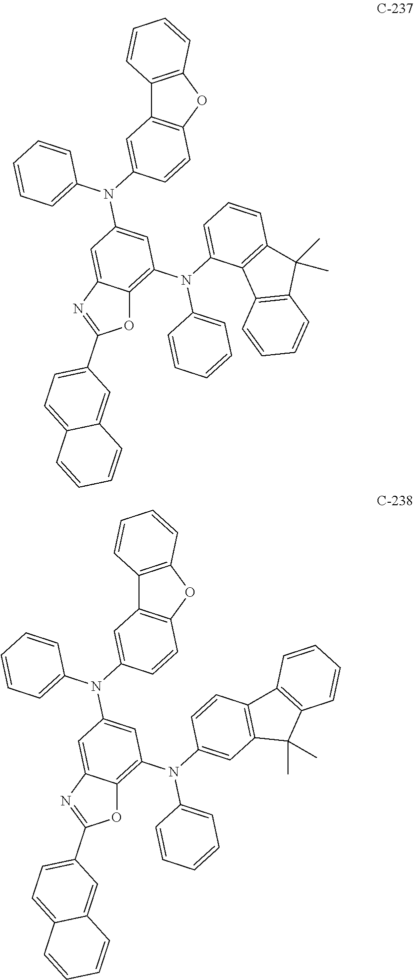

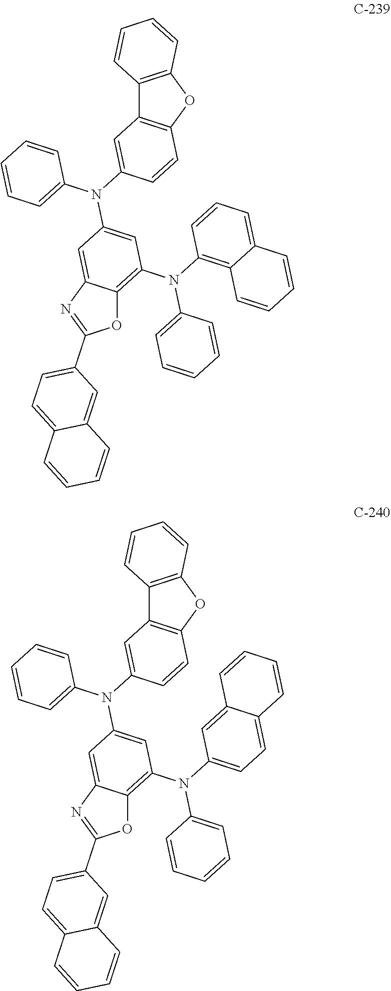 [SMILES: c1ccc(N(c2cc(N(c3ccccc3)c3cccc4ccccc34)c3oc(-c4ccc5ccccc5c4)nc3c2)c2ccc3oc4ccccc4c3c2)cc1 ; c1ccc(N(c2cc(N(c3ccccc3)c3ccc4ccccc4c3)c3oc(-c4ccc5ccccc5c4)nc3c2)c2ccc3oc4ccccc4c3c2)cc1]

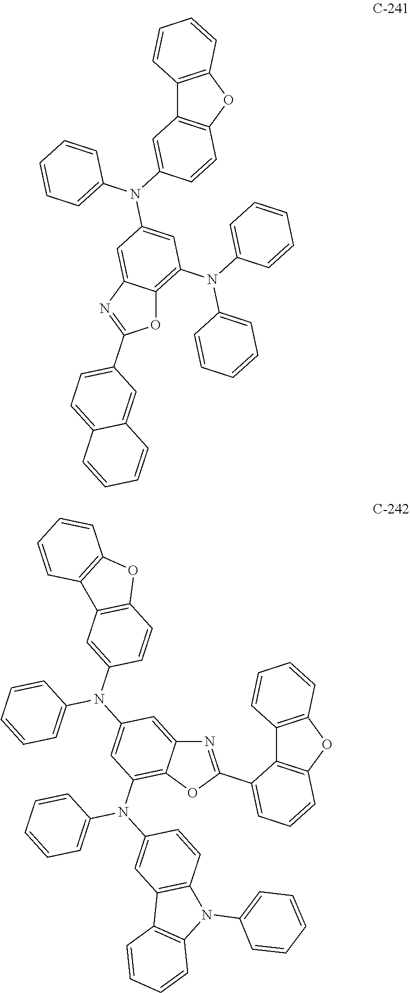

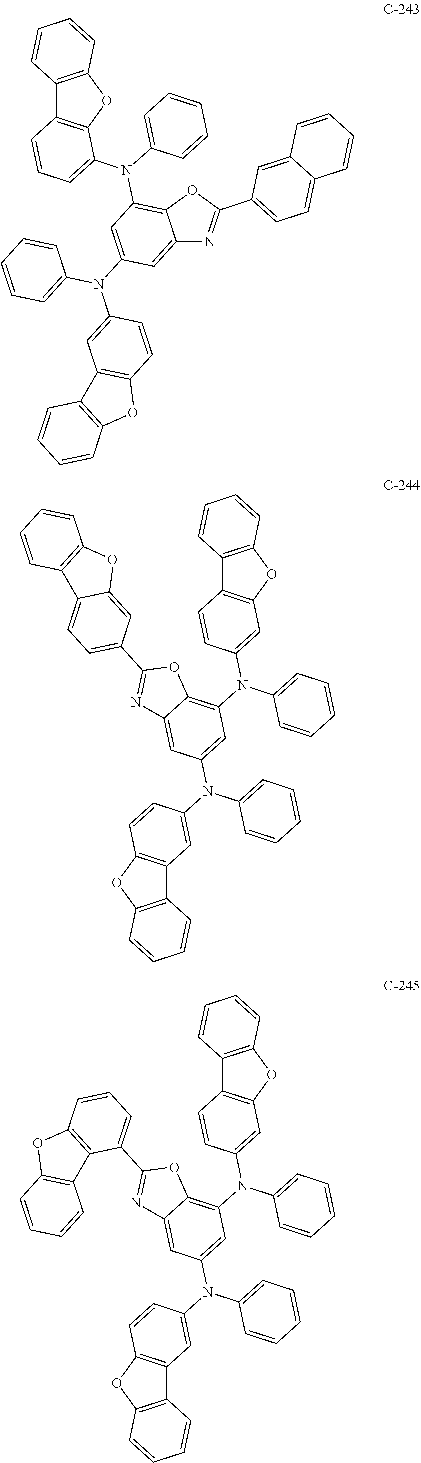 [SMILES: c1ccc(N(c2cc(N(c3ccccc3)c3cccc4c3oc3ccccc34)c3oc(-c4ccc5ccccc5c4)nc3c2)c2ccc3oc4ccccc4c3c2)cc1 ; c1ccc(N(c2cc(N(c3ccccc3)c3ccc4c(c3)oc3ccccc34)c3oc(-c4ccc5c(c4)oc4ccccc45)nc3c2)c2ccc3oc4ccccc4c3c2)cc1 ; c1ccc(N(c2cc(N(c3ccccc3)c3ccc4c(c3)oc3ccccc34)c3oc(-c4cccc5oc6ccccc6c45)nc3c2)c2ccc3oc4ccccc4c3c2)cc1]

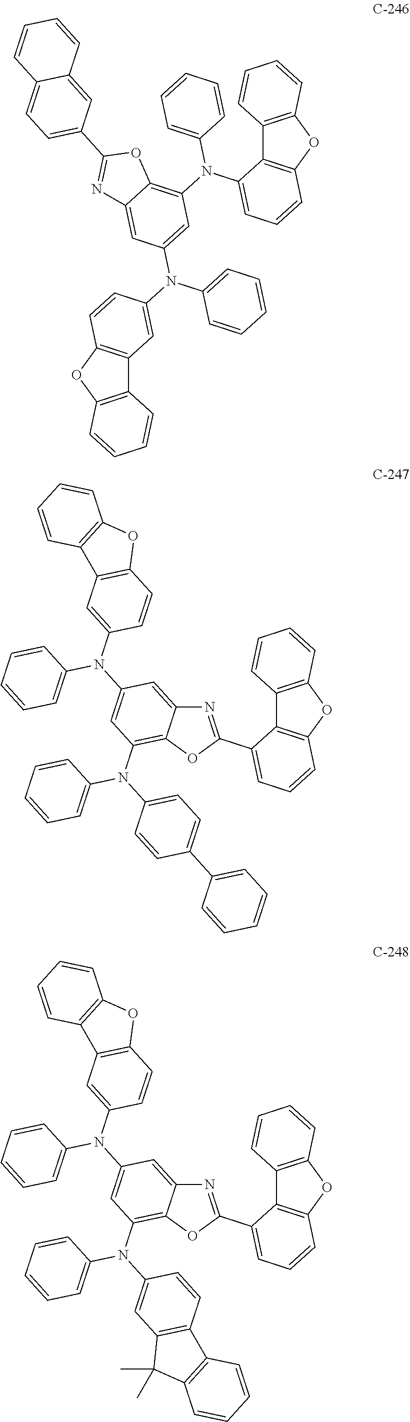

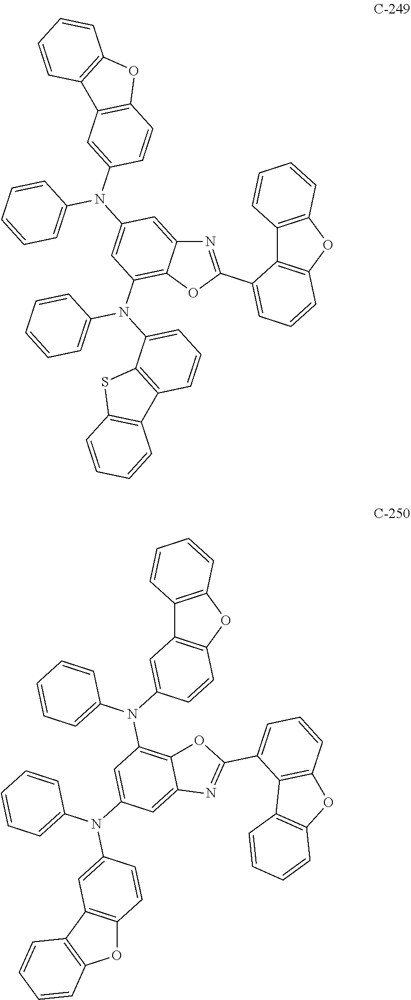 [SMILES: c1ccc(N(c2cc(N(c3ccccc3)c3cccc4c3sc3ccccc34)c3oc(-c4cccc5oc6ccccc6c45)nc3c2)c2ccc3oc4ccccc4c3c2)cc1 ; c1ccc(N(c2cc(N(c3ccccc3)c3ccc4oc5ccccc5c4c3)c3oc(-c4cccc5oc6ccccc6c45)nc3c2)c2ccc3oc4ccccc4c3c2)cc1]

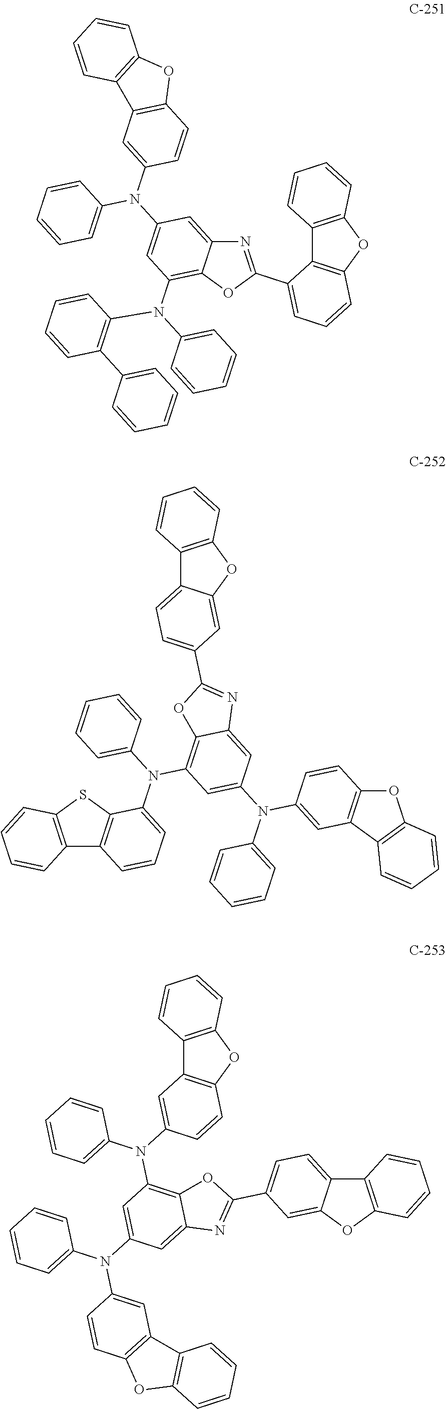 [SMILES: c1ccc(-c2ccccc2N(c2ccccc2)c2cc(N(c3ccccc3)c3ccc4oc5ccccc5c4c3)cc3nc(-c4cccc5oc6ccccc6c45)oc23)cc1 ; c1ccc(N(c2cc(N(c3ccccc3)c3cccc4c3sc3ccccc34)c3oc(-c4ccc5c(c4)oc4ccccc45)nc3c2)c2ccc3oc4ccccc4c3c2)cc1 ; c1ccc(N(c2cc(N(c3ccccc3)c3ccc4oc5ccccc5c4c3)c3oc(-c4ccc5c(c4)oc4ccccc45)nc3c2)c2ccc3oc4ccccc4c3c2)cc1]

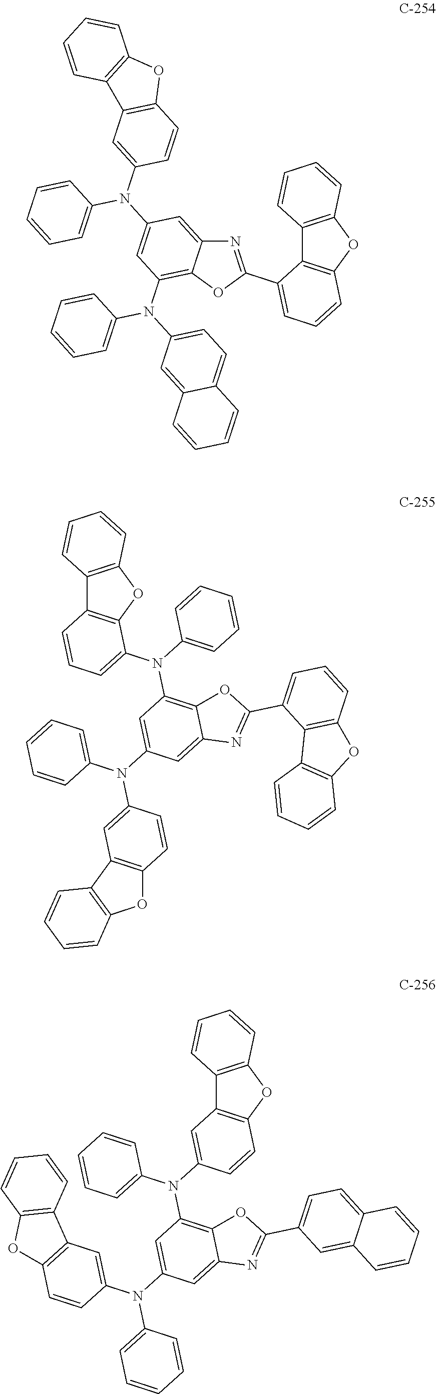 [SMILES: c1ccc(N(c2cc(N(c3ccccc3)c3ccc4ccccc4c3)c3oc(-c4cccc5oc6ccccc6c45)nc3c2)c2ccc3oc4ccccc4c3c2)cc1 ; c1ccc(N(c2cc(N(c3ccccc3)c3cccc4c3oc3ccccc34)c3oc(-c4cccc5oc6ccccc6c45)nc3c2)c2ccc3oc4ccccc4c3c2)cc1 ; c1ccc(N(c2cc(N(c3ccccc3)c3ccc4oc5ccccc5c4c3)c3oc(-c4ccc5ccccc5c4)nc3c2)c2ccc3oc4ccccc4c3c2)cc1]

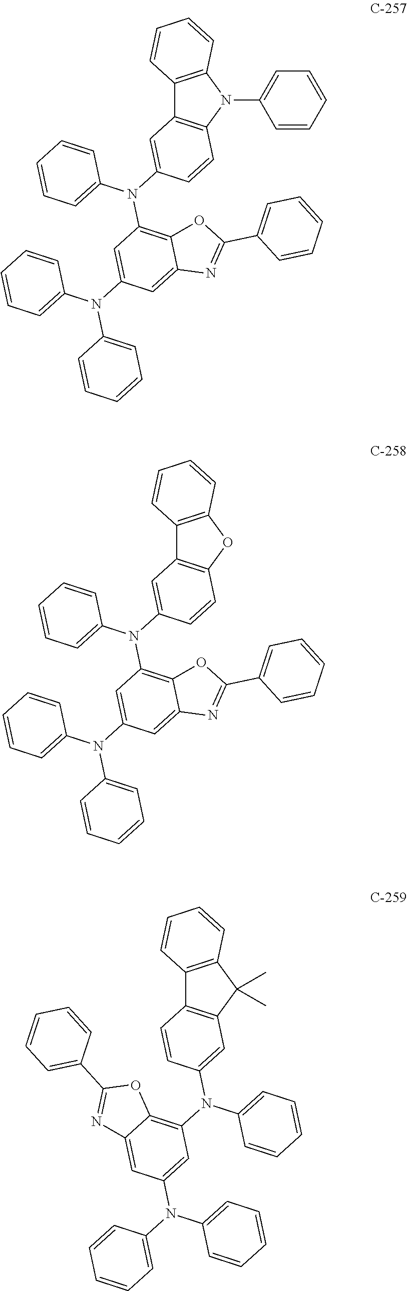 [SMILES: c1ccc(-c2nc3cc(N(c4ccccc4)c4ccccc4)cc(N(c4ccccc4)c4ccc5c(c4)c4ccccc4n5-c4ccccc4)c3o2)cc1 ; c1ccc(-c2nc3cc(N(c4ccccc4)c4ccccc4)cc(N(c4ccccc4)c4ccc5oc6ccccc6c5c4)c3o2)cc1 ; CC1(C)c2ccccc2-c2ccc(N(c3ccccc3)c3cc(N(c4ccccc4)c4ccccc4)cc4nc(-c5ccccc5)oc34)cc21]

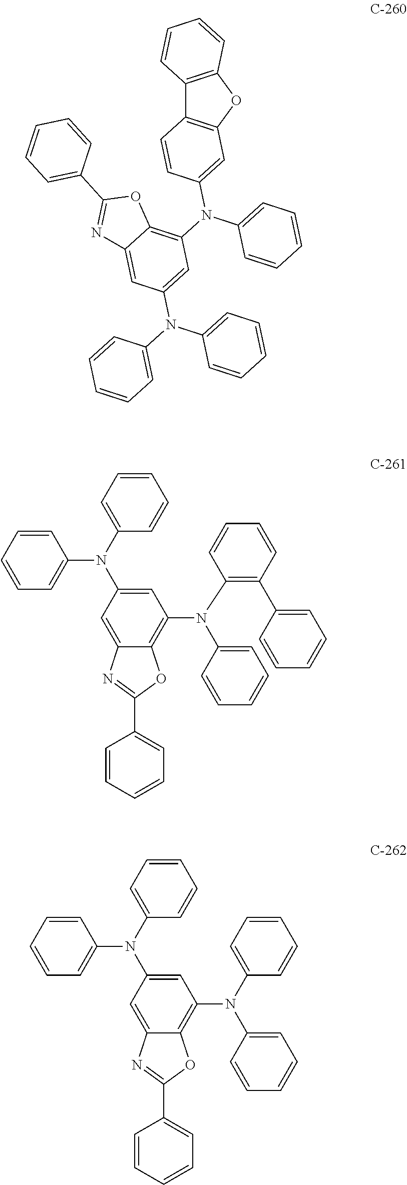 [SMILES: c1ccc(-c2nc3cc(N(c4ccccc4)c4ccccc4)cc(N(c4ccccc4)c4ccc5c(c4)oc4ccccc45)c3o2)cc1 ; c1ccc(-c2nc3cc(N(c4ccccc4)c4ccccc4)cc(N(c4ccccc4)c4ccccc4-c4ccccc4)c3o2)cc1 ; c1ccc(-c2nc3cc(N(c4ccccc4)c4ccccc4)cc(N(c4ccccc4)c4ccccc4)c3o2)cc1]

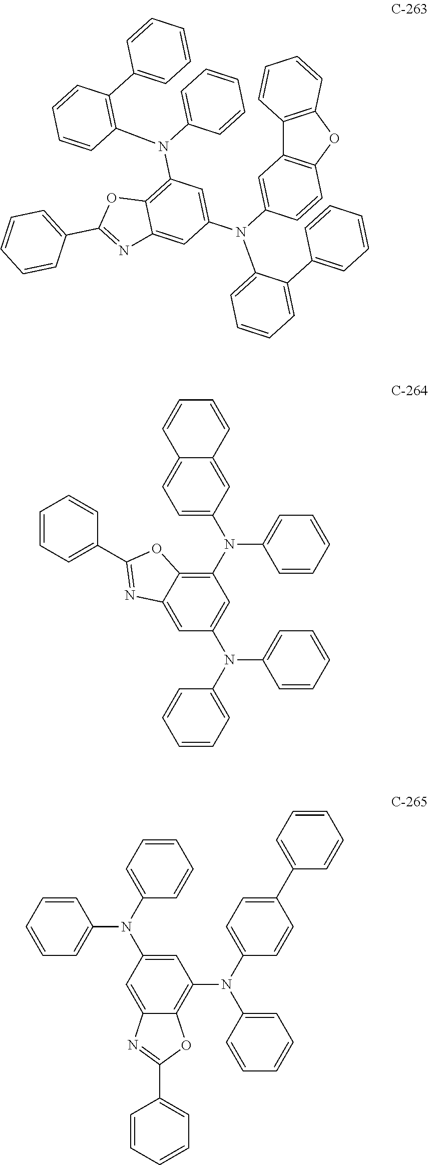 [SMILES: c1ccc(-c2nc3cc(N(c4ccc5oc6ccccc6c5c4)c4ccccc4-c4ccccc4)cc(N(c4ccccc4)c4ccccc4-c4ccccc4)c3o2)cc1 ; c1ccc(-c2nc3cc(N(c4ccccc4)c4ccccc4)cc(N(c4ccccc4)c4ccc5ccccc5c4)c3o2)cc1 ; c1ccc(-c2ccc(N(c3ccccc3)c3cc(N(c4ccccc4)c4ccccc4)cc4nc(-c5ccccc5)oc34)cc2)cc1]

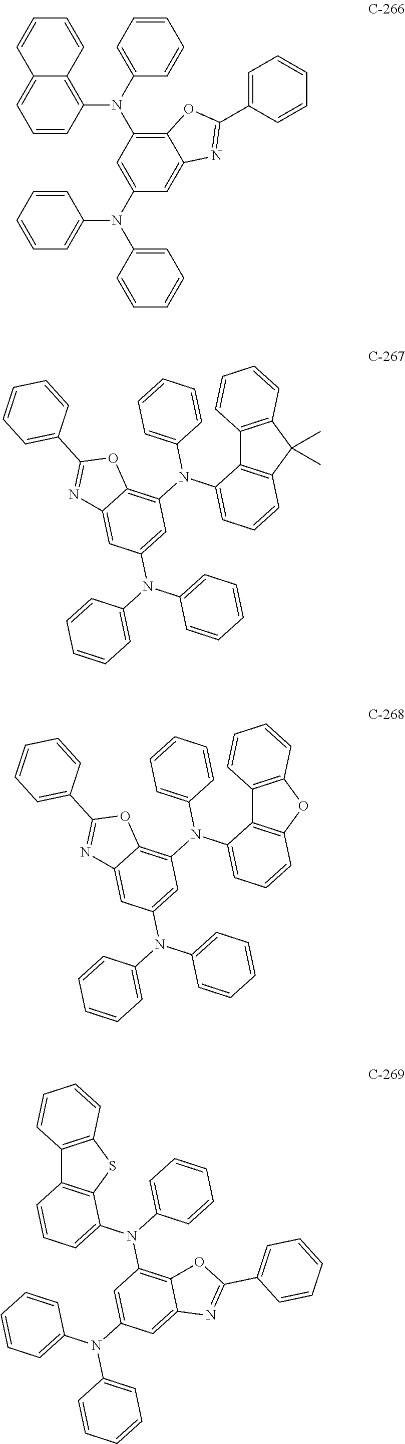 [SMILES: c1ccc(-c2nc3cc(N(c4ccccc4)c4ccccc4)cc(N(c4ccccc4)c4cccc5ccccc45)c3o2)cc1 ; CC1(C)c2ccccc2-c2c(N(c3ccccc3)c3cc(N(c4ccccc4)c4ccccc4)cc4nc(-c5ccccc5)oc34)cccc21 ; c1ccc(-c2nc3cc(N(c4ccccc4)c4ccccc4)cc(N(c4ccccc4)c4cccc5oc6ccccc6c45)c3o2)cc1 ; c1ccc(-c2nc3cc(N(c4ccccc4)c4ccccc4)cc(N(c4ccccc4)c4cccc5c4sc4ccccc45)c3o2)cc1]

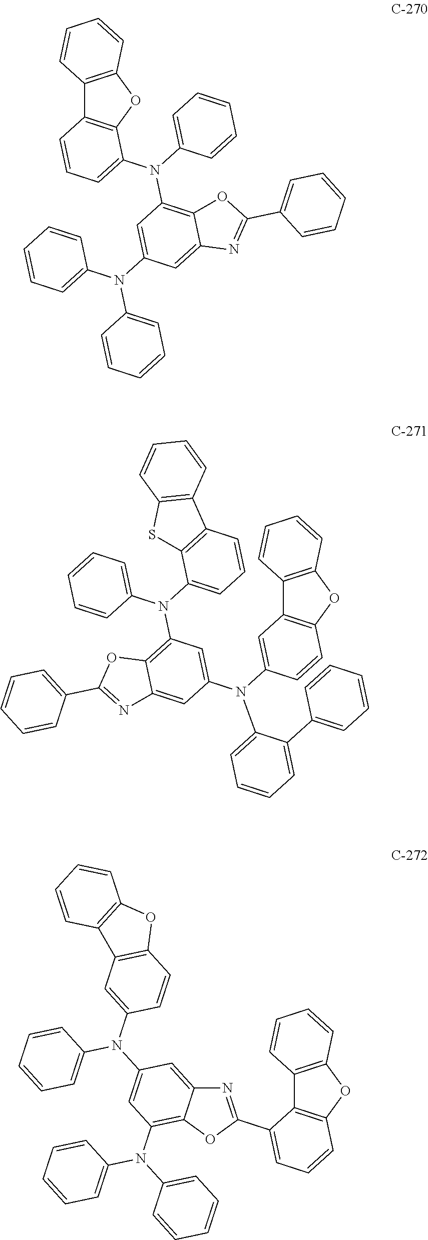 [SMILES: c1ccc(-c2nc3cc(N(c4ccccc4)c4ccccc4)cc(N(c4ccccc4)c4cccc5c4oc4ccccc45)c3o2)cc1 ; c1ccc(-c2nc3cc(N(c4ccc5oc6ccccc6c5c4)c4ccccc4-c4ccccc4)cc(N(c4ccccc4)c4cccc5c4sc4ccccc45)c3o2)cc1 ; c1ccc(N(c2cc(N(c3ccccc3)c3ccccc3)c3oc(-c4cccc5oc6ccccc6c45)nc3c2)c2ccc3oc4ccccc4c3c2)cc1]

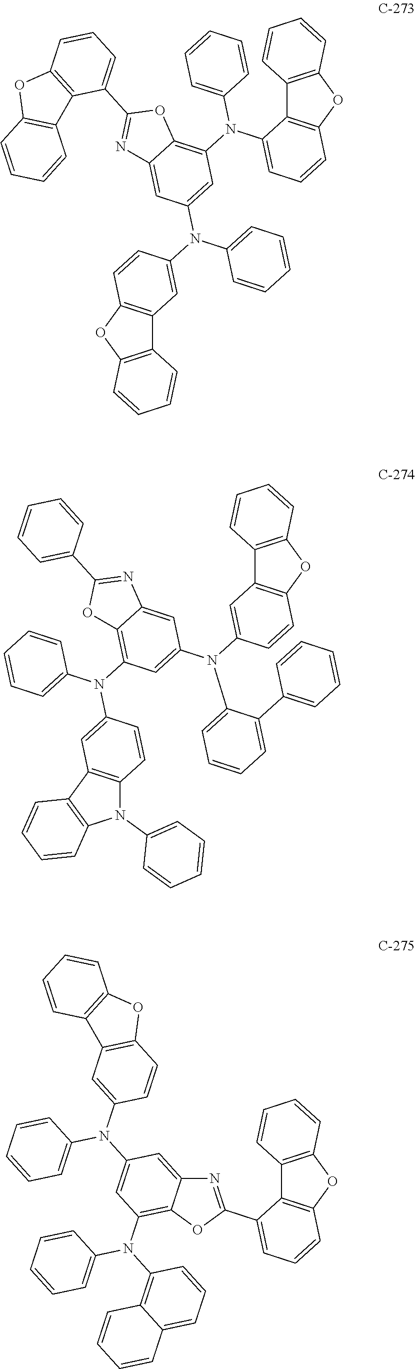 [SMILES: c1ccc(N(c2cc(N(c3ccccc3)c3cccc4oc5ccccc5c34)c3oc(-c4cccc5oc6ccccc6c45)nc3c2)c2ccc3oc4ccccc4c3c2)cc1 ; c1ccc(-c2nc3cc(N(c4ccc5oc6ccccc6c5c4)c4ccccc4-c4ccccc4)cc(N(c4ccccc4)c4ccc5c(c4)c4ccccc4n5-c4ccccc4)c3o2)cc1 ; c1ccc(N(c2cc(N(c3ccccc3)c3cccc4ccccc34)c3oc(-c4cccc5oc6ccccc6c45)nc3c2)c2ccc3oc4ccccc4c3c2)cc1]

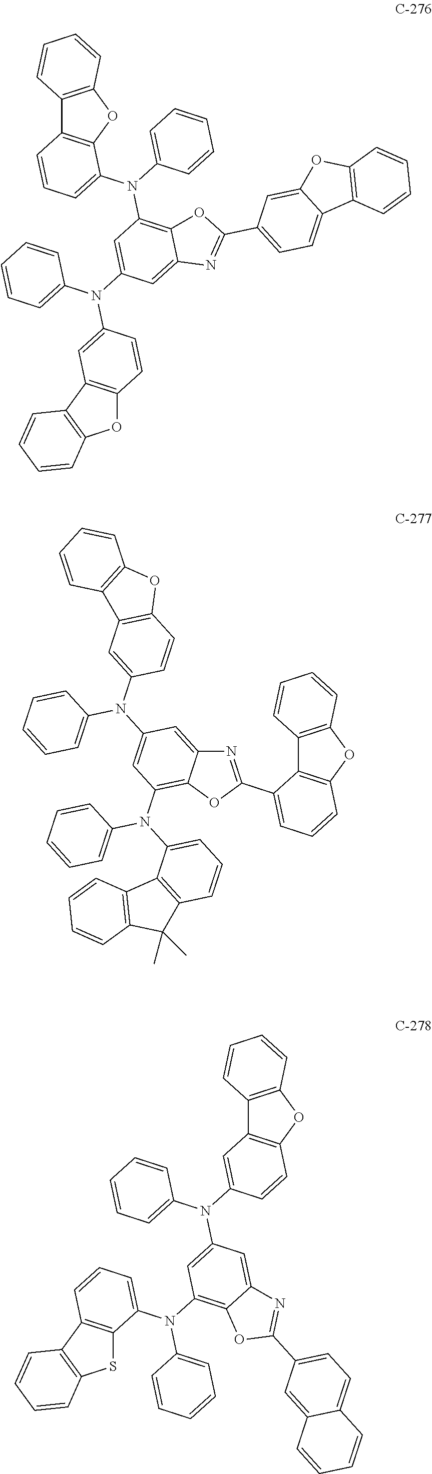 [SMILES: c1ccc(N(c2cc(N(c3ccccc3)c3cccc4c3oc3ccccc34)c3oc(-c4ccc5c(c4)oc4ccccc45)nc3c2)c2ccc3oc4ccccc4c3c2)cc1 ; CC1(C)c2ccccc2-c2c(N(c3ccccc3)c3cc(N(c4ccccc4)c4ccc5oc6ccccc6c5c4)cc4nc(-c5cccc6oc7ccccc7c56)oc34)cccc21 ; c1ccc(N(c2cc(N(c3ccccc3)c3cccc4c3sc3ccccc34)c3oc(-c4ccc5ccccc5c4)nc3c2)c2ccc3oc4ccccc4c3c2)cc1]

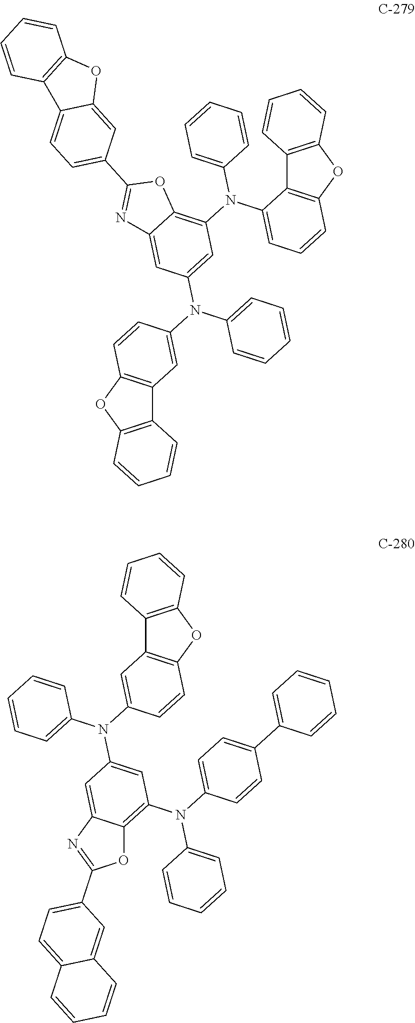 [SMILES: c1ccc(N(c2cc(N(c3ccccc3)c3cccc4oc5ccccc5c34)c3oc(-c4ccc5c(c4)oc4ccccc45)nc3c2)c2ccc3oc4ccccc4c3c2)cc1 ; c1ccc(-c2ccc(N(c3ccccc3)c3cc(N(c4ccccc4)c4ccc5oc6ccccc6c5c4)cc4nc(-c5ccc6ccccc6c5)oc34)cc2)cc1]

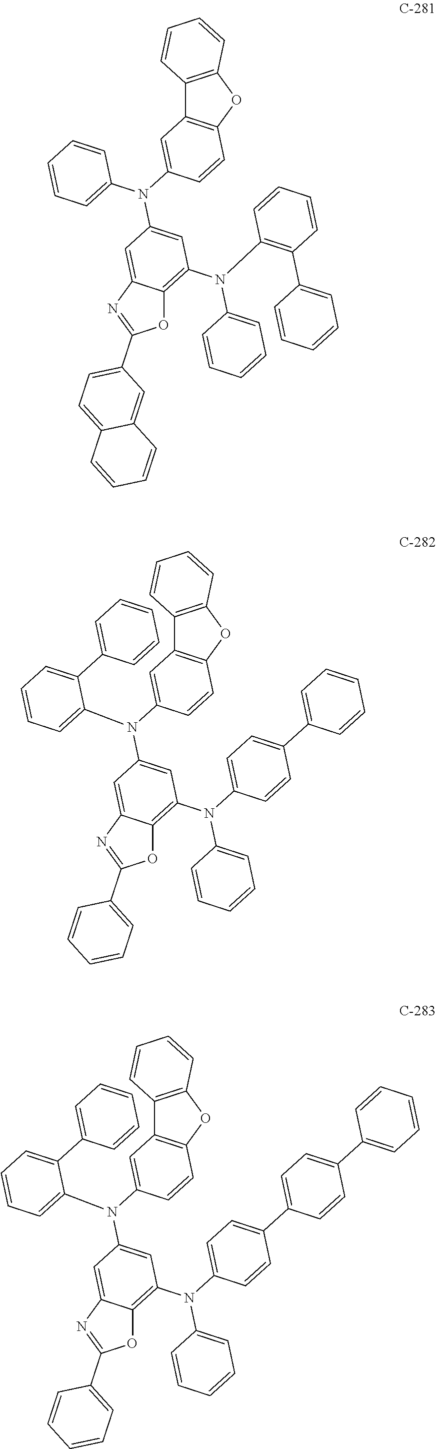 [SMILES: c1ccc(-c2ccccc2N(c2ccccc2)c2cc(N(c3ccccc3)c3ccc4oc5ccccc5c4c3)cc3nc(-c4ccc5ccccc5c4)oc23)cc1 ; c1ccc(-c2ccc(N(c3ccccc3)c3cc(N(c4ccc5oc6ccccc6c5c4)c4ccccc4-c4ccccc4)cc4nc(-c5ccccc5)oc34)cc2)cc1 ; c1ccc(-c2ccc(-c3ccc(N(c4ccccc4)c4cc(N(c5ccc6oc7ccccc7c6c5)c5ccccc5-c5ccccc5)cc5nc(-c6ccccc6)oc45)cc3)cc2)cc1]

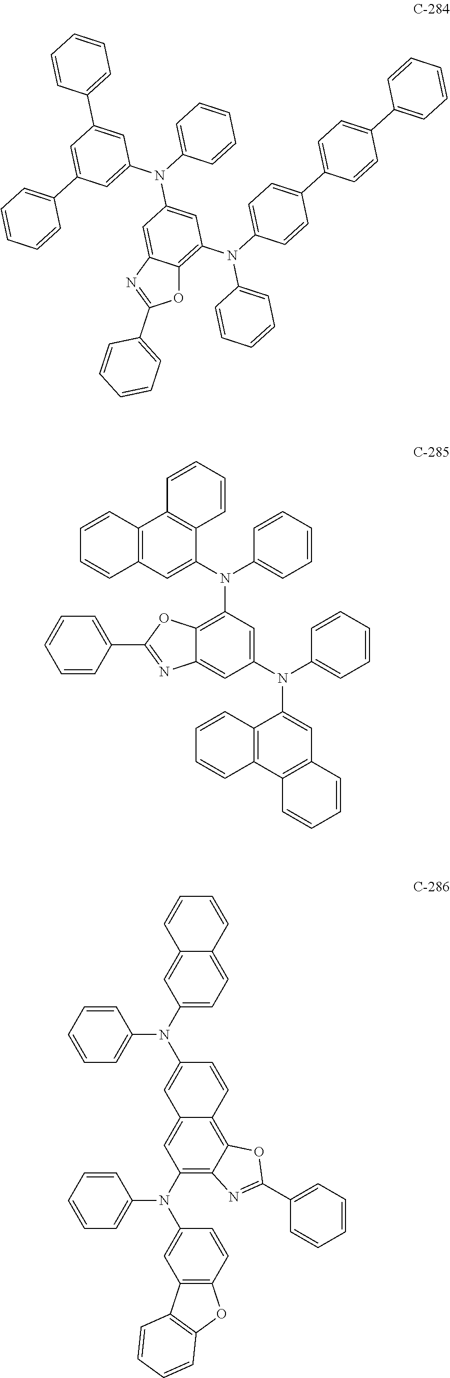 [SMILES: c1ccc(-c2ccc(-c3ccc(N(c4ccccc4)c4cc(N(c5ccccc5)c5cc(-c6ccccc6)cc(-c6ccccc6)c5)cc5nc(-c6ccccc6)oc45)cc3)cc2)cc1 ; c1ccc(-c2nc3cc(N(c4ccccc4)c4cc5ccccc5c5ccccc45)cc(N(c4ccccc4)c4cc5ccccc5c5ccccc45)c3o2)cc1 ; c1ccc(-c2nc3c(N(c4ccccc4)c4ccc5oc6ccccc6c5c4)cc4cc(N(c5ccccc5)c5ccc6ccccc6c5)ccc4c3o2)cc1]

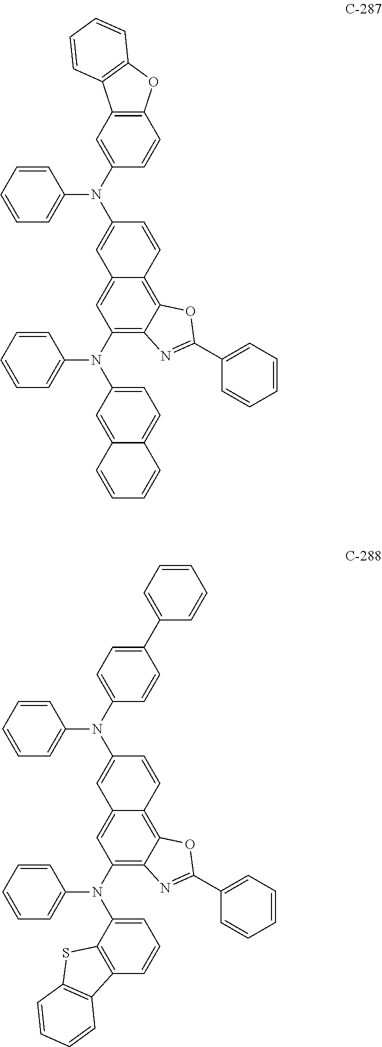 [SMILES: c1ccc(-c2nc3c(N(c4ccccc4)c4ccc5ccccc5c4)cc4cc(N(c5ccccc5)c5ccc6oc7ccccc7c6c5)ccc4c3o2)cc1 ; c1ccc(-c2ccc(N(c3ccccc3)c3ccc4c(c3)cc(N(c3ccccc3)c3cccc5c3sc3ccccc35)c3nc(-c5ccccc5)oc34)cc2)cc1]

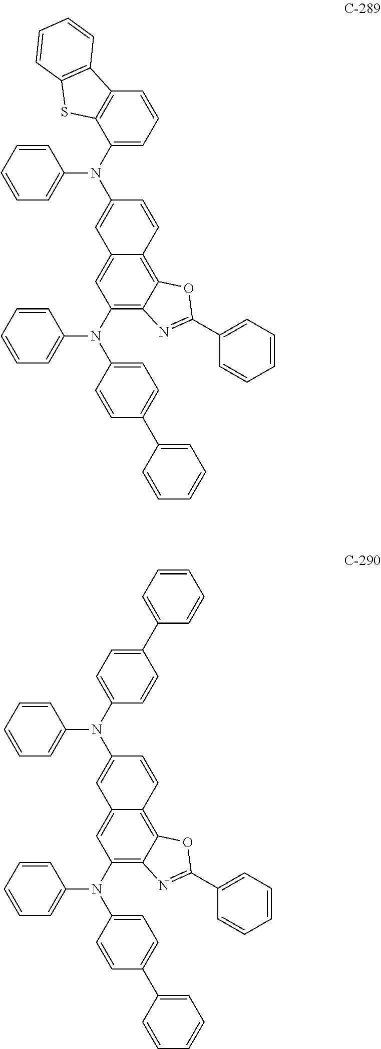 [SMILES: c1ccc(-c2ccc(N(c3ccccc3)c3cc4cc(N(c5ccccc5)c5cccc6c5sc5ccccc56)ccc4c4oc(-c5ccccc5)nc34)cc2)cc1 ; c1ccc(-c2ccc(N(c3ccccc3)c3ccc4c(c3)cc(N(c3ccccc3)c3ccc(-c5ccccc5)cc3)c3nc(-c5ccccc5)oc34)cc2)cc1]

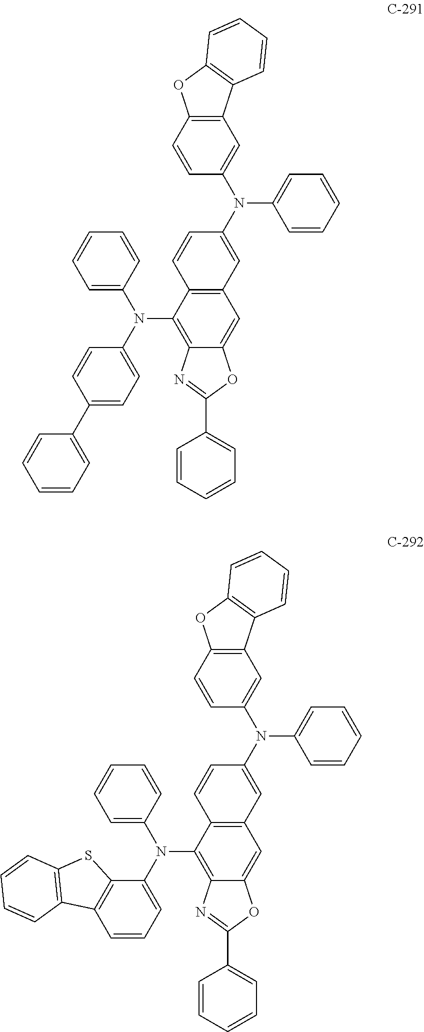 [SMILES: c1ccc(-c2ccc(N(c3ccccc3)c3c4ccc(N(c5ccccc5)c5ccc6oc7ccccc7c6c5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccc6oc7ccccc7c6c5)cc4cc3o2)cc1]

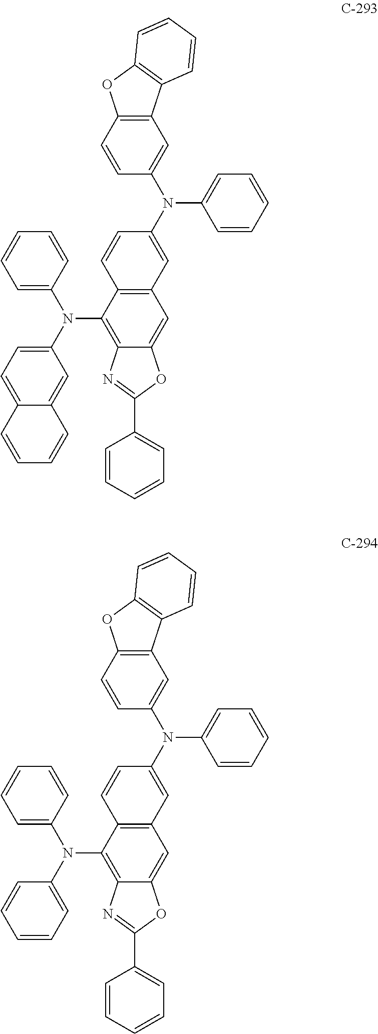 [SMILES: c1ccc(-c2nc3c(N(c4ccccc4)c4ccc5ccccc5c4)c4ccc(N(c5ccccc5)c5ccc6oc7ccccc7c6c5)cc4cc3o2)cc1 ; c1ccc(-c2nc3c(N(c4ccccc4)c4ccccc4)c4ccc(N(c5ccccc5)c5ccc6oc7ccccc7c6c5)cc4cc3o2)cc1]

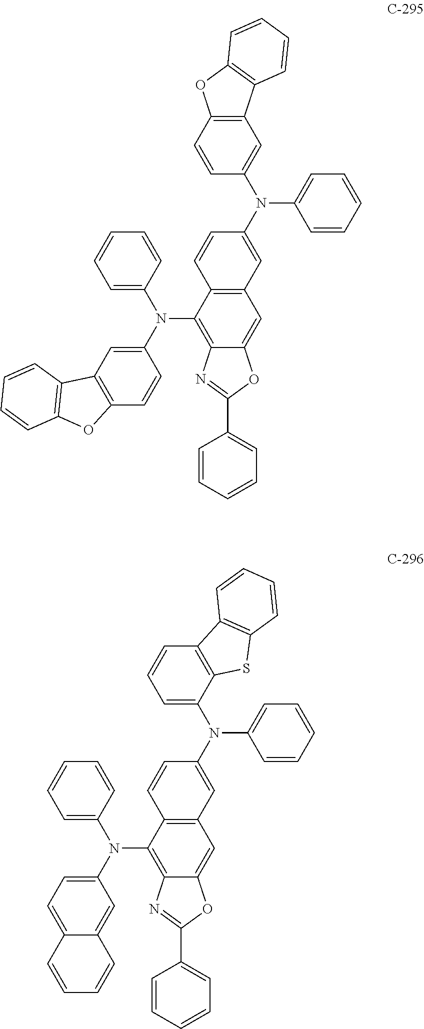 [SMILES: c1ccc(-c2nc3c(N(c4ccccc4)c4ccc5oc6ccccc6c5c4)c4ccc(N(c5ccccc5)c5ccc6oc7ccccc7c6c5)cc4cc3o2)cc1 ; c1ccc(-c2nc3c(N(c4ccccc4)c4ccc5ccccc5c4)c4ccc(N(c5ccccc5)c5cccc6c5sc5ccccc56)cc4cc3o2)cc1]

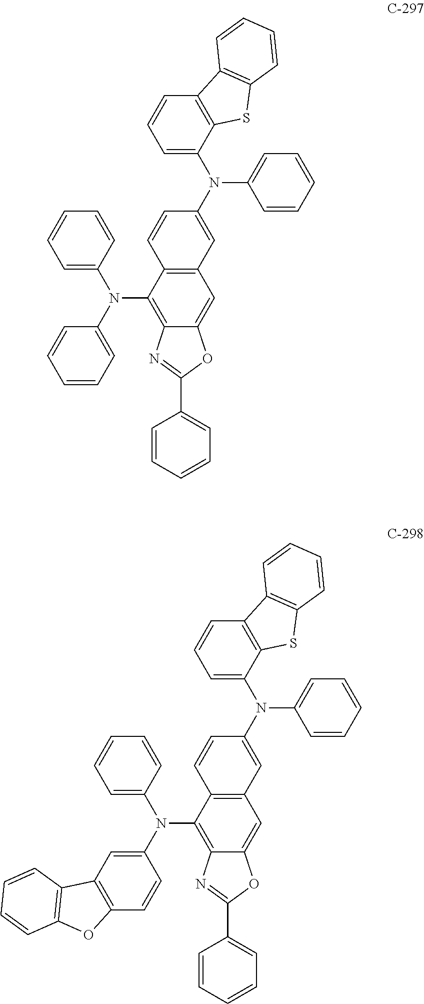 [SMILES: c1ccc(-c2nc3c(N(c4ccccc4)c4ccccc4)c4ccc(N(c5ccccc5)c5cccc6c5sc5ccccc56)cc4cc3o2)cc1 ; c1ccc(-c2nc3c(N(c4ccccc4)c4ccc5oc6ccccc6c5c4)c4ccc(N(c5ccccc5)c5cccc6c5sc5ccccc56)cc4cc3o2)cc1]

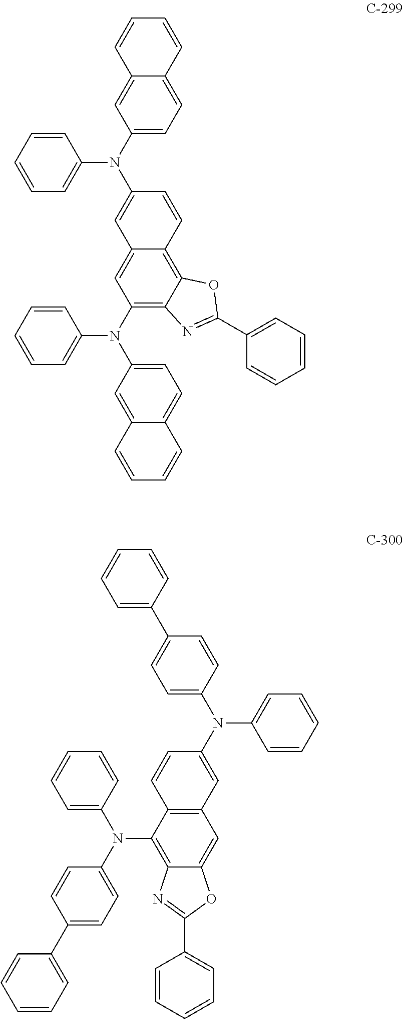 [SMILES: c1ccc(-c2nc3c(N(c4ccccc4)c4ccc5ccccc5c4)cc4cc(N(c5ccccc5)c5ccc6ccccc6c5)ccc4c3o2)cc1 ; c1ccc(-c2ccc(N(c3ccccc3)c3ccc4c(N(c5ccccc5)c5ccc(-c6ccccc6)cc5)c5nc(-c6ccccc6)oc5cc4c3)cc2)cc1]

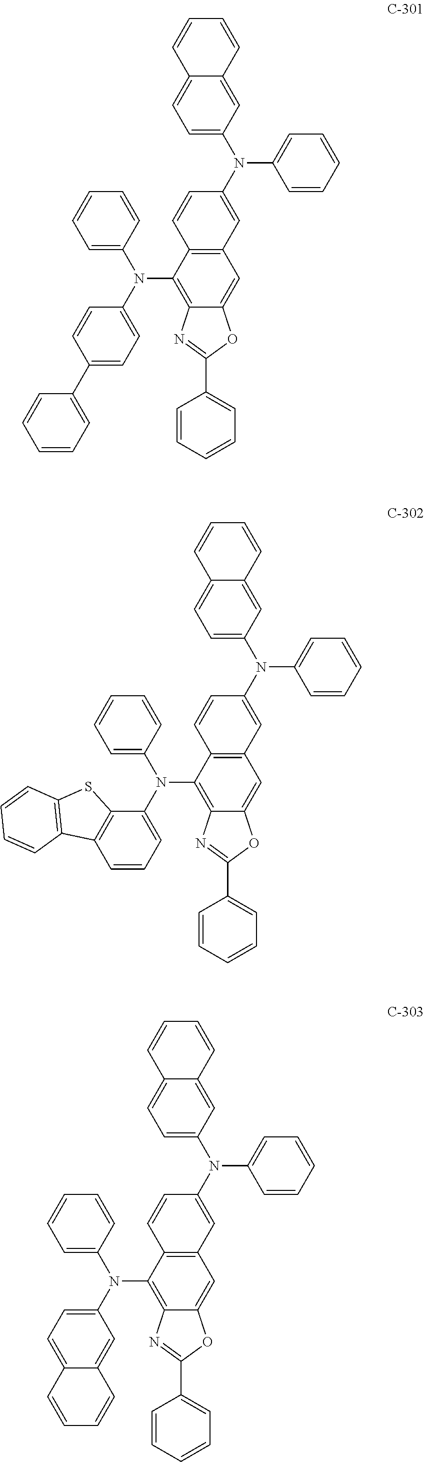 [SMILES: c1ccc(-c2ccc(N(c3ccccc3)c3c4ccc(N(c5ccccc5)c5ccc6ccccc6c5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccc6ccccc6c5)cc4cc3o2)cc1 ; c1ccc(-c2nc3c(N(c4ccccc4)c4ccc5ccccc5c4)c4ccc(N(c5ccccc5)c5ccc6ccccc6c5)cc4cc3o2)cc1]

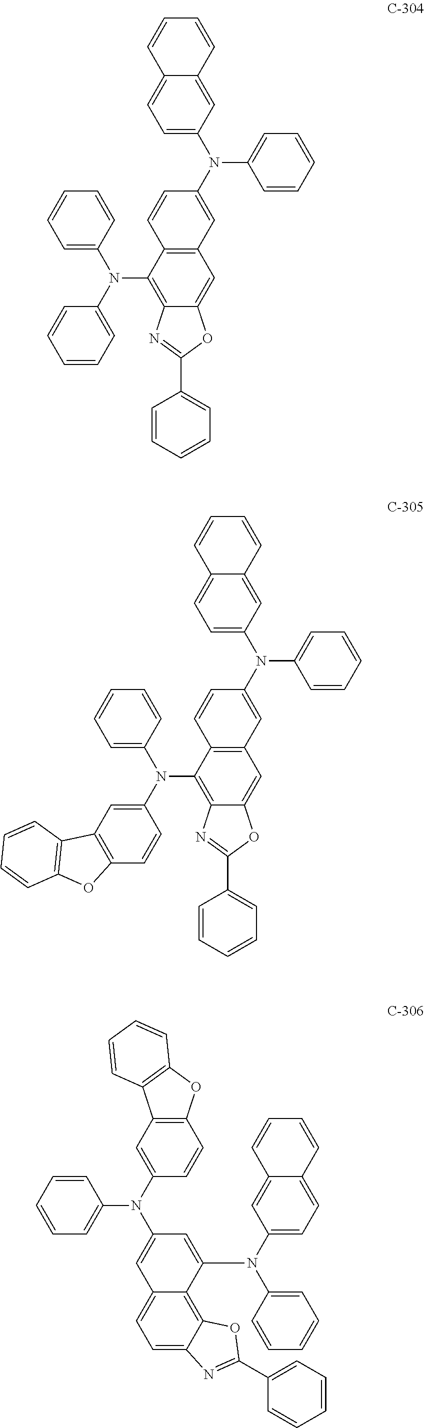 [SMILES: c1ccc(-c2nc3c(N(c4ccccc4)c4ccccc4)c4ccc(N(c5ccccc5)c5ccc6ccccc6c5)cc4cc3o2)cc1 ; c1ccc(-c2nc3c(N(c4ccccc4)c4ccc5oc6ccccc6c5c4)c4ccc(N(c5ccccc5)c5ccc6ccccc6c5)cc4cc3o2)cc1 ; c1ccc(-c2nc3ccc4cc(N(c5ccccc5)c5ccc6oc7ccccc7c6c5)cc(N(c5ccccc5)c5ccc6ccccc6c5)c4c3o2)cc1]

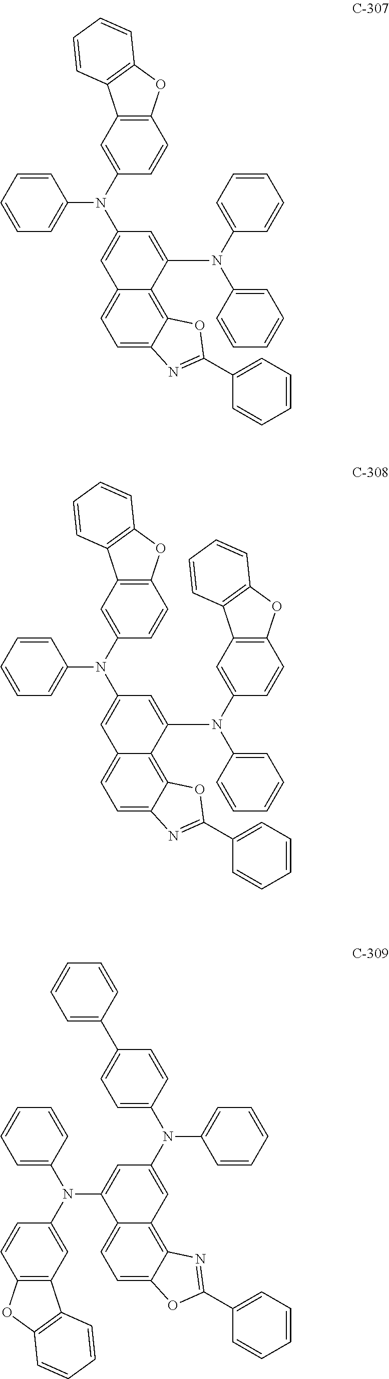 [SMILES: c1ccc(-c2nc3ccc4cc(N(c5ccccc5)c5ccc6oc7ccccc7c6c5)cc(N(c5ccccc5)c5ccccc5)c4c3o2)cc1 ; c1ccc(-c2nc3ccc4cc(N(c5ccccc5)c5ccc6oc7ccccc7c6c5)cc(N(c5ccccc5)c5ccc6oc7ccccc7c6c5)c4c3o2)cc1 ; c1ccc(-c2ccc(N(c3ccccc3)c3cc(N(c4ccccc4)c4ccc5oc6ccccc6c5c4)c4ccc5oc(-c6ccccc6)nc5c4c3)cc2)cc1]

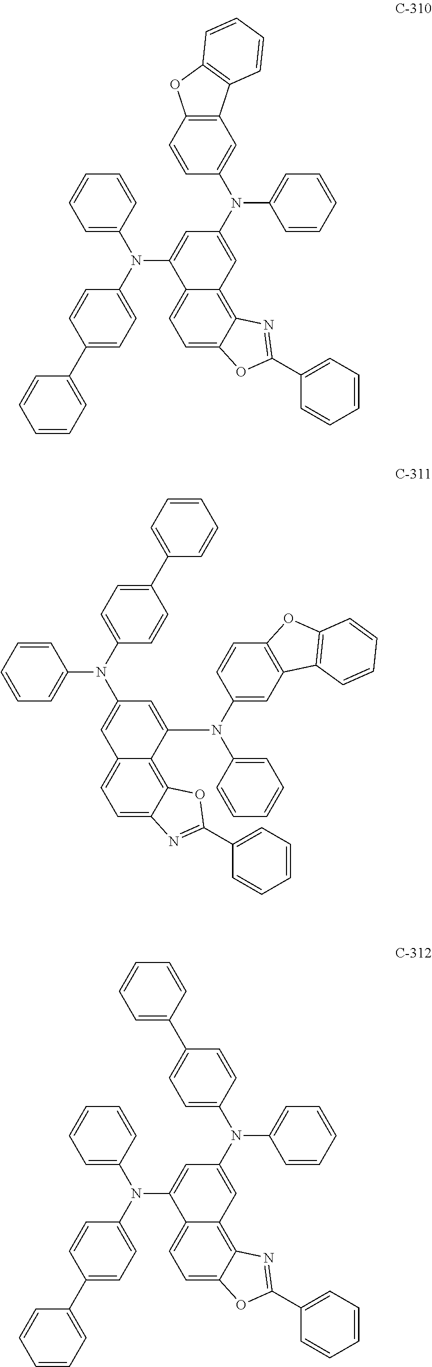 [SMILES: c1ccc(-c2ccc(N(c3ccccc3)c3cc(N(c4ccccc4)c4ccc5oc6ccccc6c5c4)cc4c3ccc3oc(-c5ccccc5)nc34)cc2)cc1 ; c1ccc(-c2ccc(N(c3ccccc3)c3cc(N(c4ccccc4)c4ccc5oc6ccccc6c5c4)c4c(ccc5nc(-c6ccccc6)oc54)c3)cc2)cc1 ; c1ccc(-c2ccc(N(c3ccccc3)c3cc(N(c4ccccc4)c4ccc(-c5ccccc5)cc4)c4ccc5oc(-c6ccccc6)nc5c4c3)cc2)cc1]

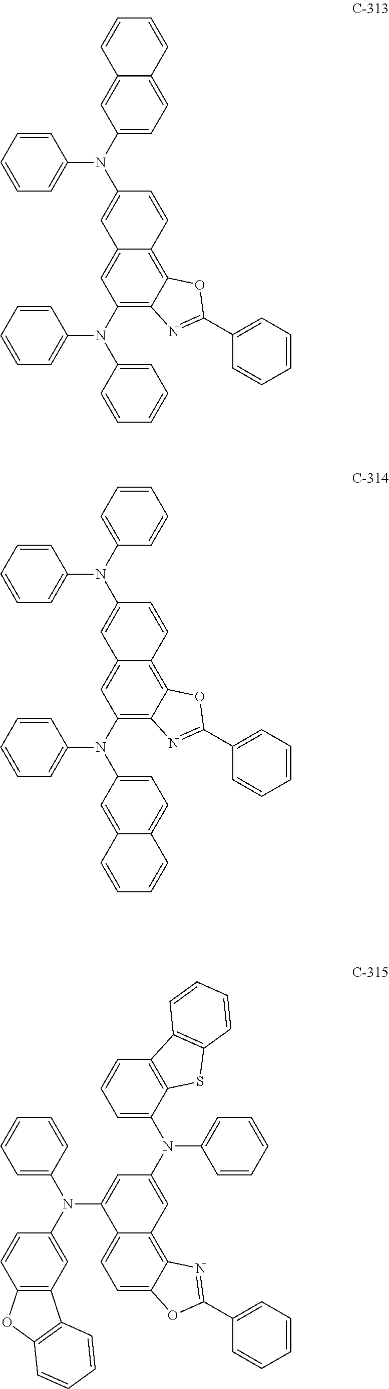 [SMILES: c1ccc(-c2nc3c(N(c4ccccc4)c4ccccc4)cc4cc(N(c5ccccc5)c5ccc6ccccc6c5)ccc4c3o2)cc1 ; c1ccc(-c2nc3c(N(c4ccccc4)c4ccc5ccccc5c4)cc4cc(N(c5ccccc5)c5ccccc5)ccc4c3o2)cc1 ; c1ccc(-c2nc3c(ccc4c(N(c5ccccc5)c5ccc6oc7ccccc7c6c5)cc(N(c5ccccc5)c5cccc6c5sc5ccccc56)cc43)o2)cc1]

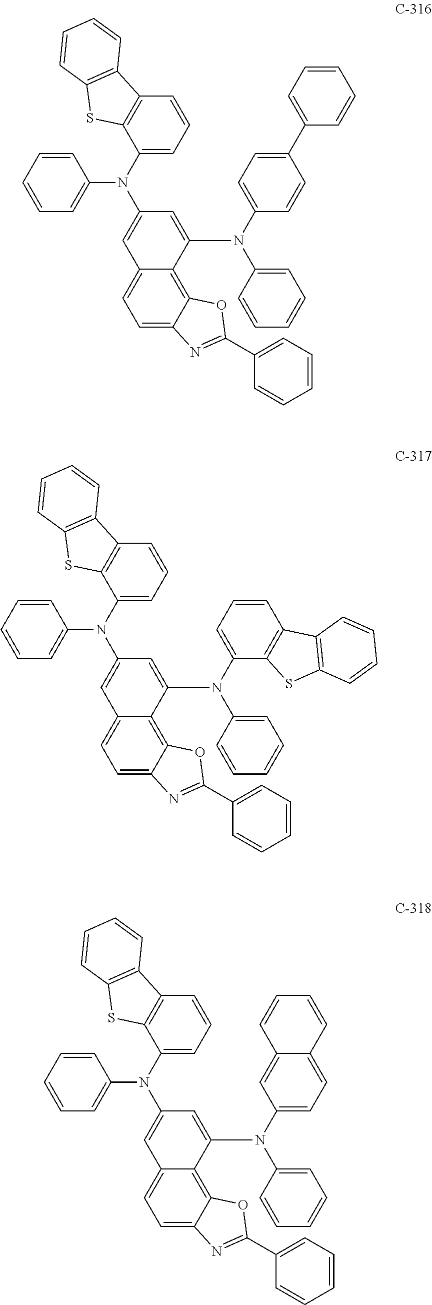 [SMILES: c1ccc(-c2ccc(N(c3ccccc3)c3cc(N(c4ccccc4)c4cccc5c4sc4ccccc45)cc4ccc5nc(-c6ccccc6)oc5c34)cc2)cc1 ; c1ccc(-c2nc3ccc4cc(N(c5ccccc5)c5cccc6c5sc5ccccc56)cc(N(c5ccccc5)c5cccc6c5sc5ccccc56)c4c3o2)cc1 ; c1ccc(-c2nc3ccc4cc(N(c5ccccc5)c5cccc6c5sc5ccccc56)cc(N(c5ccccc5)c5ccc6ccccc6c5)c4c3o2)cc1]

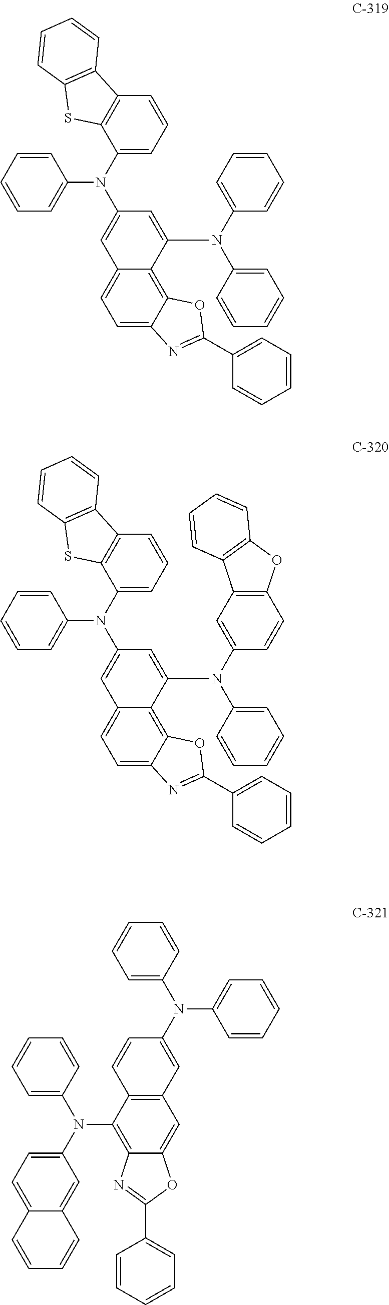 [SMILES: c1ccc(-c2nc3ccc4cc(N(c5ccccc5)c5cccc6c5sc5ccccc56)cc(N(c5ccccc5)c5ccccc5)c4c3o2)cc1 ; c1ccc(-c2nc3ccc4cc(N(c5ccccc5)c5cccc6c5sc5ccccc56)cc(N(c5ccccc5)c5ccc6oc7ccccc7c6c5)c4c3o2)cc1 ; c1ccc(-c2nc3c(N(c4ccccc4)c4ccc5ccccc5c4)c4ccc(N(c5ccccc5)c5ccccc5)cc4cc3o2)cc1]

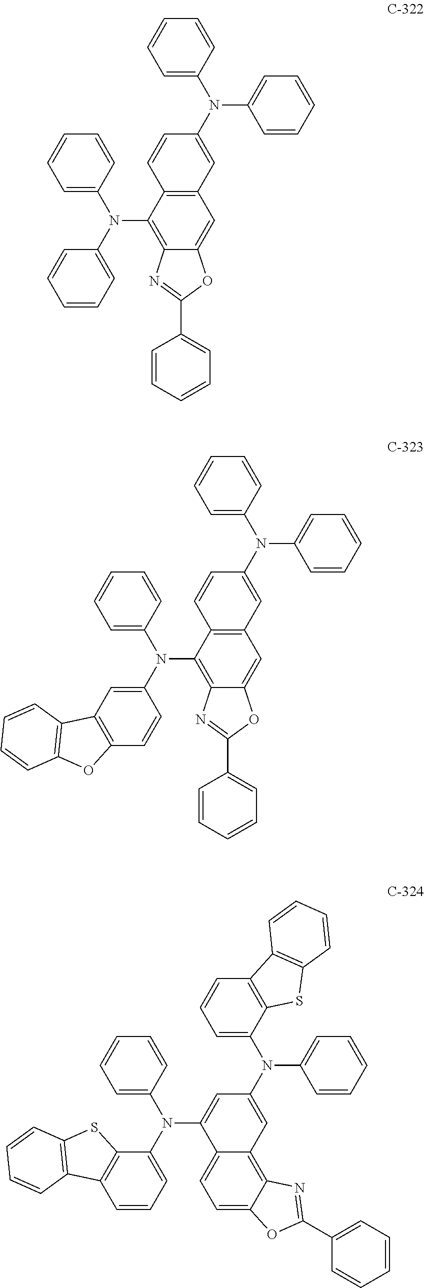 [SMILES: c1ccc(-c2nc3c(N(c4ccccc4)c4ccccc4)c4ccc(N(c5ccccc5)c5ccccc5)cc4cc3o2)cc1 ; c1ccc(-c2nc3c(N(c4ccccc4)c4ccc5oc6ccccc6c5c4)c4ccc(N(c5ccccc5)c5ccccc5)cc4cc3o2)cc1 ; c1ccc(-c2nc3c(ccc4c(N(c5ccccc5)c5cccc6c5sc5ccccc56)cc(N(c5ccccc5)c5cccc6c5sc5ccccc56)cc43)o2)cc1]

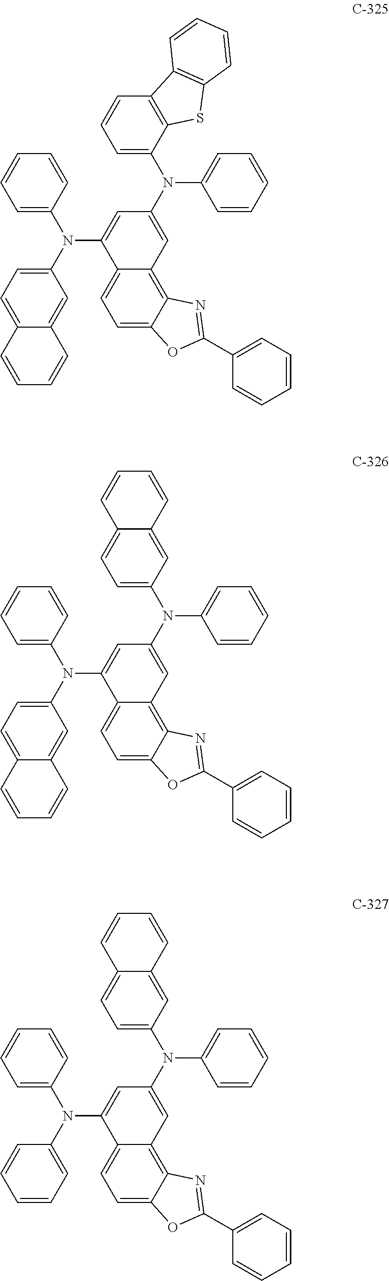 [SMILES: c1ccc(-c2nc3c(ccc4c(N(c5ccccc5)c5ccc6ccccc6c5)cc(N(c5ccccc5)c5cccc6c5sc5ccccc56)cc43)o2)cc1 ; c1ccc(-c2nc3c(ccc4c(N(c5ccccc5)c5ccc6ccccc6c5)cc(N(c5ccccc5)c5ccc6ccccc6c5)cc43)o2)cc1 ; c1ccc(-c2nc3c(ccc4c(N(c5ccccc5)c5ccccc5)cc(N(c5ccccc5)c5ccc6ccccc6c5)cc43)o2)cc1]

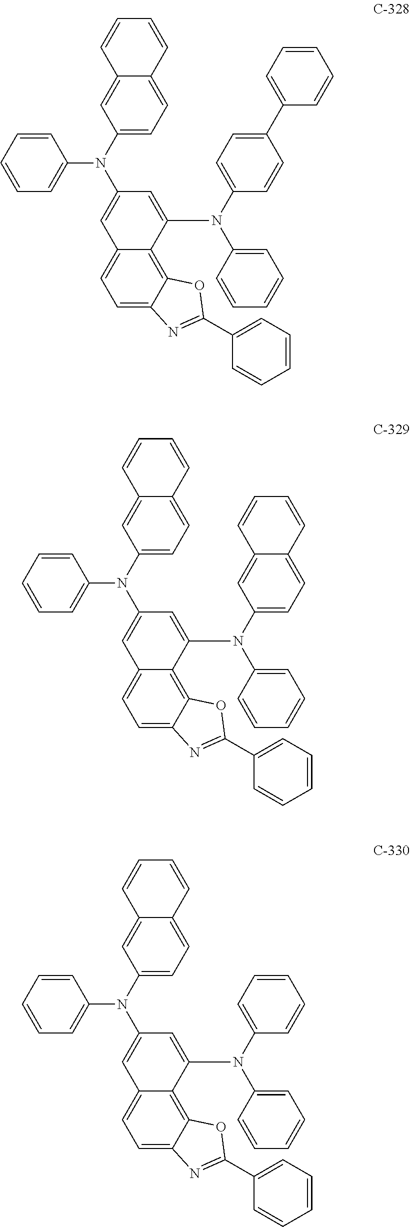 [SMILES: c1ccc(-c2ccc(N(c3ccccc3)c3cc(N(c4ccccc4)c4ccc5ccccc5c4)cc4ccc5nc(-c6ccccc6)oc5c34)cc2)cc1 ; c1ccc(-c2nc3ccc4cc(N(c5ccccc5)c5ccc6ccccc6c5)cc(N(c5ccccc5)c5ccc6ccccc6c5)c4c3o2)cc1 ; c1ccc(-c2nc3ccc4cc(N(c5ccccc5)c5ccc6ccccc6c5)cc(N(c5ccccc5)c5ccccc5)c4c3o2)cc1]

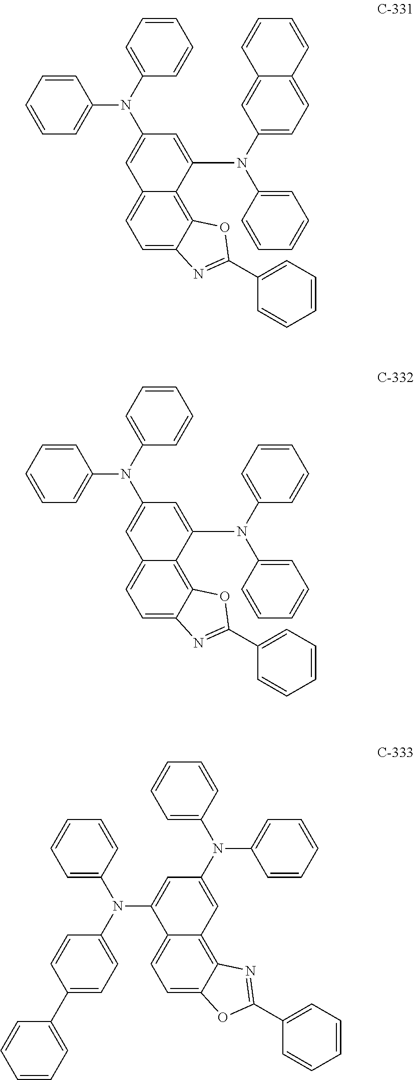 [SMILES: c1ccc(-c2nc3ccc4cc(N(c5ccccc5)c5ccccc5)cc(N(c5ccccc5)c5ccc6ccccc6c5)c4c3o2)cc1 ; c1ccc(-c2nc3ccc4cc(N(c5ccccc5)c5ccccc5)cc(N(c5ccccc5)c5ccccc5)c4c3o2)cc1 ; c1ccc(-c2ccc(N(c3ccccc3)c3cc(N(c4ccccc4)c4ccccc4)cc4c3ccc3oc(-c5ccccc5)nc34)cc2)cc1]

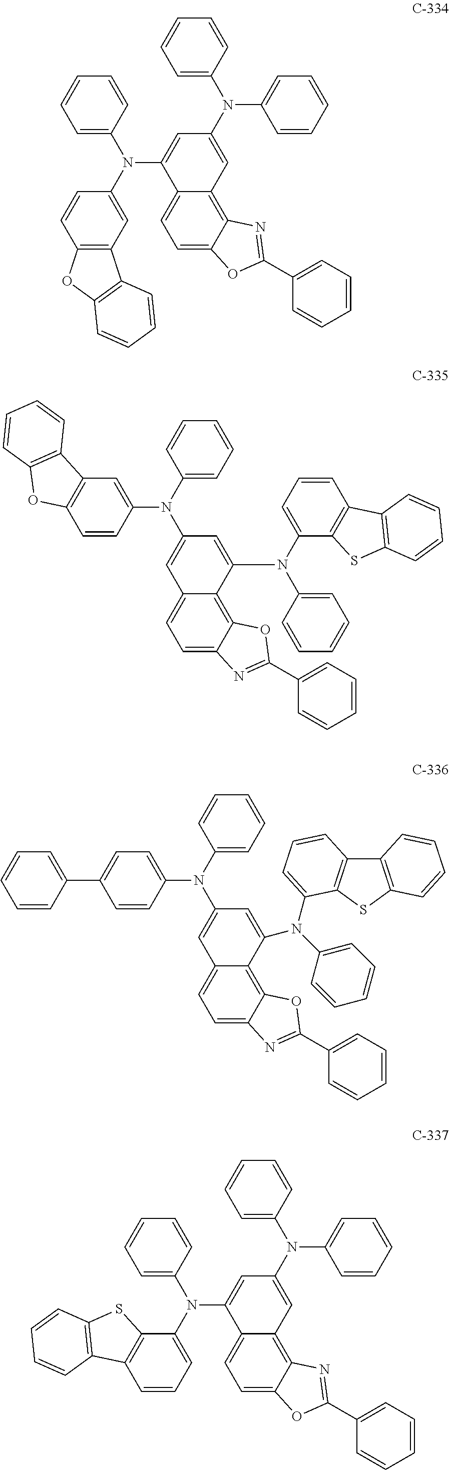 [SMILES: c1ccc(-c2nc3c(ccc4c(N(c5ccccc5)c5ccc6oc7ccccc7c6c5)cc(N(c5ccccc5)c5ccccc5)cc43)o2)cc1 ; c1ccc(-c2nc3ccc4cc(N(c5ccccc5)c5ccc6oc7ccccc7c6c5)cc(N(c5ccccc5)c5cccc6c5sc5ccccc56)c4c3o2)cc1 ; c1ccc(-c2ccc(N(c3ccccc3)c3cc(N(c4ccccc4)c4cccc5c4sc4ccccc45)c4c(ccc5nc(-c6ccccc6)oc54)c3)cc2)cc1 ; c1ccc(-c2nc3c(ccc4c(N(c5ccccc5)c5cccc6c5sc5ccccc56)cc(N(c5ccccc5)c5ccccc5)cc43)o2)cc1]

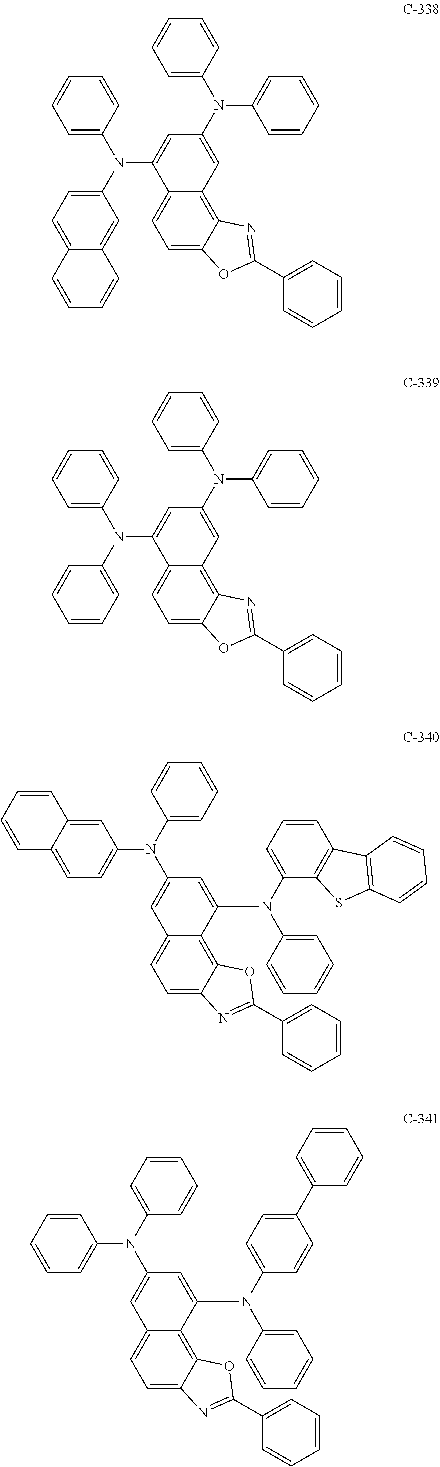 [SMILES: c1ccc(-c2nc3c(ccc4c(N(c5ccccc5)c5ccc6ccccc6c5)cc(N(c5ccccc5)c5ccccc5)cc43)o2)cc1 ; c1ccc(-c2nc3c(ccc4c(N(c5ccccc5)c5ccccc5)cc(N(c5ccccc5)c5ccccc5)cc43)o2)cc1 ; c1ccc(-c2nc3ccc4cc(N(c5ccccc5)c5ccc6ccccc6c5)cc(N(c5ccccc5)c5cccc6c5sc5ccccc56)c4c3o2)cc1 ; c1ccc(-c2ccc(N(c3ccccc3)c3cc(N(c4ccccc4)c4ccccc4)cc4ccc5nc(-c6ccccc6)oc5c34)cc2)cc1]

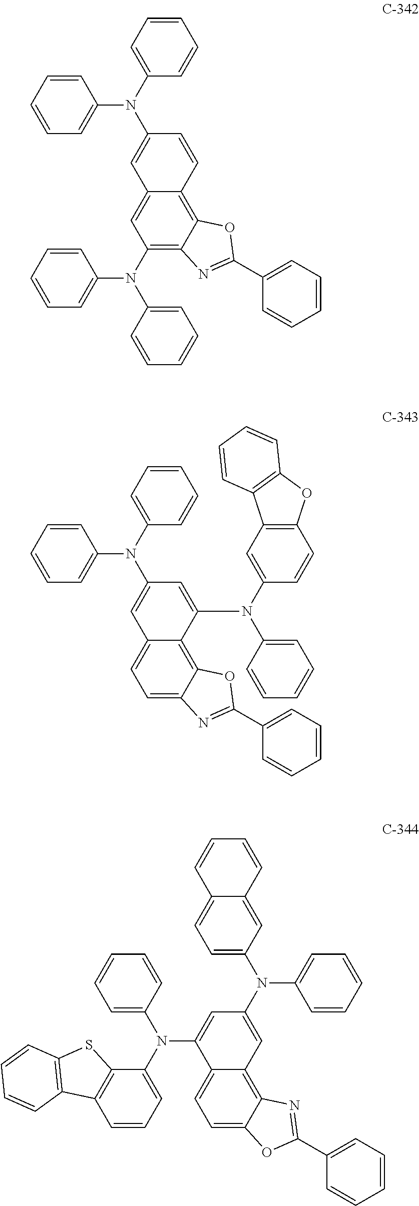 [SMILES: c1ccc(-c2nc3c(N(c4ccccc4)c4ccccc4)cc4cc(N(c5ccccc5)c5ccccc5)ccc4c3o2)cc1 ; c1ccc(-c2nc3ccc4cc(N(c5ccccc5)c5ccccc5)cc(N(c5ccccc5)c5ccc6oc7ccccc7c6c5)c4c3o2)cc1 ; c1ccc(-c2nc3c(ccc4c(N(c5ccccc5)c5cccc6c5sc5ccccc56)cc(N(c5ccccc5)c5ccc6ccccc6c5)cc43)o2)cc1]

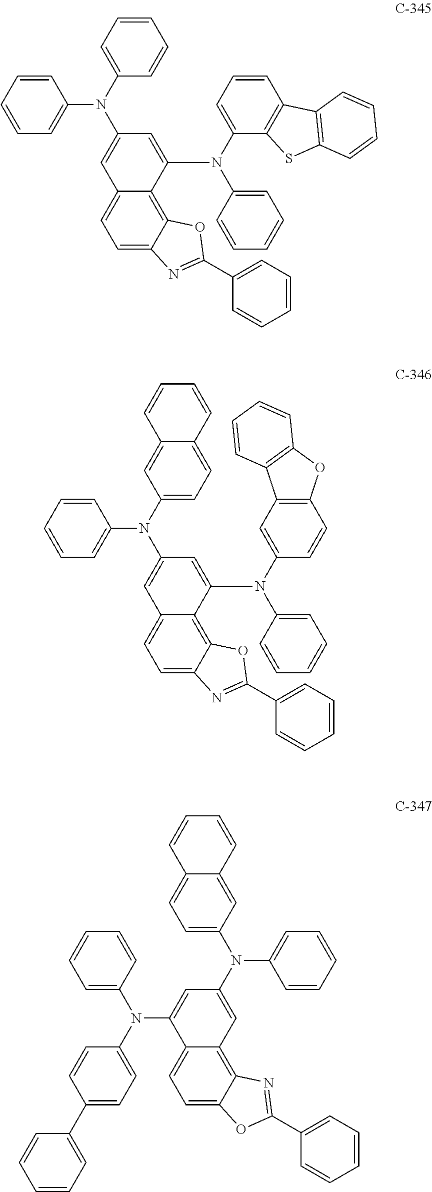 [SMILES: c1ccc(-c2nc3ccc4cc(N(c5ccccc5)c5ccccc5)cc(N(c5ccccc5)c5cccc6c5sc5ccccc56)c4c3o2)cc1 ; c1ccc(-c2nc3ccc4cc(N(c5ccccc5)c5ccc6ccccc6c5)cc(N(c5ccccc5)c5ccc6oc7ccccc7c6c5)c4c3o2)cc1 ; c1ccc(-c2ccc(N(c3ccccc3)c3cc(N(c4ccccc4)c4ccc5ccccc5c4)cc4c3ccc3oc(-c5ccccc5)nc34)cc2)cc1]

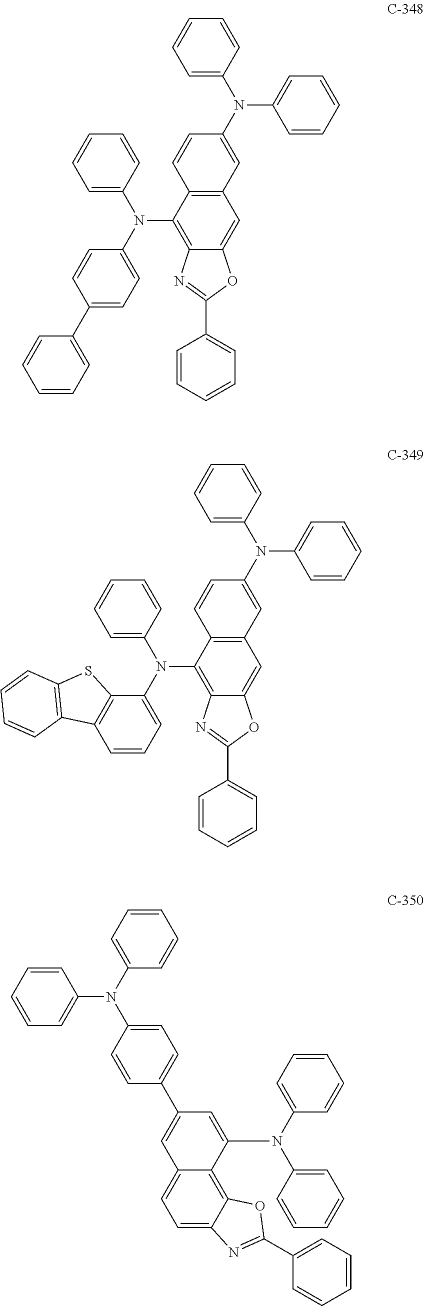 [SMILES: c1ccc(-c2ccc(N(c3ccccc3)c3c4ccc(N(c5ccccc5)c5ccccc5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccccc5)cc4cc3o2)cc1 ; c1ccc(-c2nc3ccc4cc(-c5ccc(N(c6ccccc6)c6ccccc6)cc5)cc(N(c5ccccc5)c5ccccc5)c4c3o2)cc1]

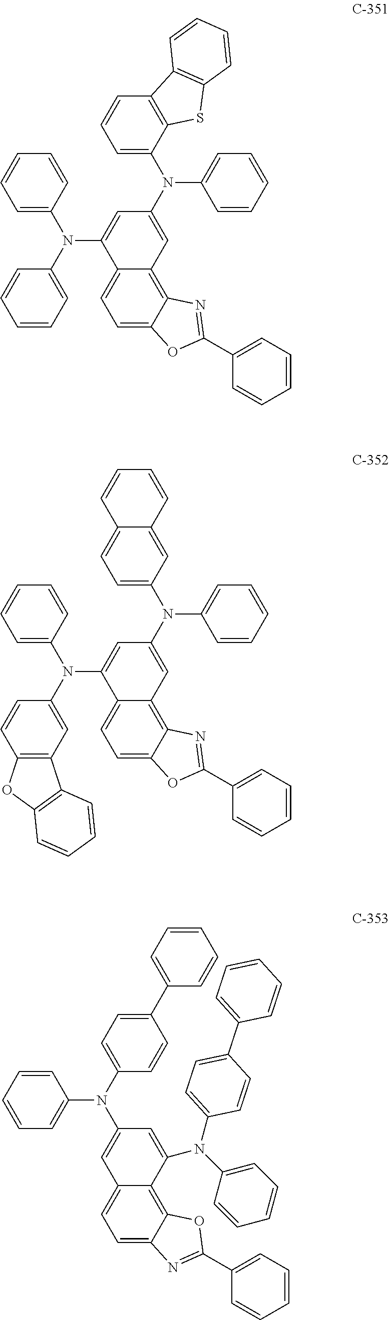 [SMILES: c1ccc(-c2nc3c(ccc4c(N(c5ccccc5)c5ccccc5)cc(N(c5ccccc5)c5cccc6c5sc5ccccc56)cc43)o2)cc1 ; c1ccc(-c2nc3c(ccc4c(N(c5ccccc5)c5ccc6oc7ccccc7c6c5)cc(N(c5ccccc5)c5ccc6ccccc6c5)cc43)o2)cc1 ; c1ccc(-c2ccc(N(c3ccccc3)c3cc(N(c4ccccc4)c4ccc(-c5ccccc5)cc4)c4c(ccc5nc(-c6ccccc6)oc54)c3)cc2)cc1]

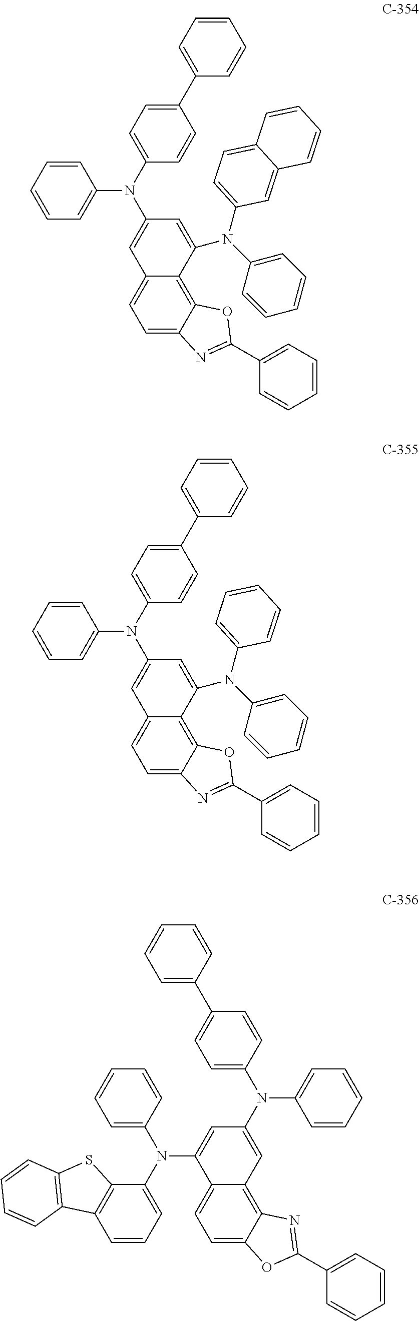 [SMILES: c1ccc(-c2ccc(N(c3ccccc3)c3cc(N(c4ccccc4)c4ccc5ccccc5c4)c4c(ccc5nc(-c6ccccc6)oc54)c3)cc2)cc1 ; c1ccc(-c2ccc(N(c3ccccc3)c3cc(N(c4ccccc4)c4ccccc4)c4c(ccc5nc(-c6ccccc6)oc54)c3)cc2)cc1 ; c1ccc(-c2ccc(N(c3ccccc3)c3cc(N(c4ccccc4)c4cccc5c4sc4ccccc45)c4ccc5oc(-c6ccccc6)nc5c4c3)cc2)cc1]

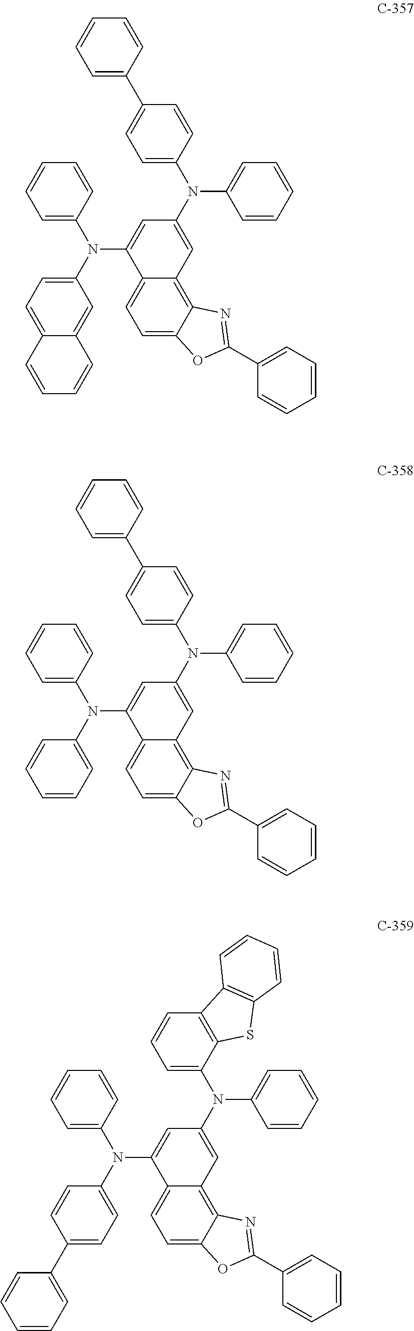 [SMILES: c1ccc(-c2ccc(N(c3ccccc3)c3cc(N(c4ccccc4)c4ccc5ccccc5c4)c4ccc5oc(-c6ccccc6)nc5c4c3)cc2)cc1 ; c1ccc(-c2ccc(N(c3ccccc3)c3cc(N(c4ccccc4)c4ccccc4)c4ccc5oc(-c6ccccc6)nc5c4c3)cc2)cc1 ; c1ccc(-c2ccc(N(c3ccccc3)c3cc(N(c4ccccc4)c4cccc5c4sc4ccccc45)cc4c3ccc3oc(-c5ccccc5)nc34)cc2)cc1]

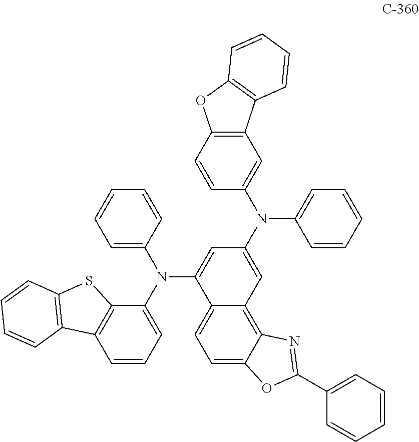 [SMILES: c1ccc(-c2nc3c(ccc4c(N(c5ccccc5)c5cccc6c5sc5ccccc56)cc(N(c5ccccc5)c5ccc6oc7ccccc7c6c5)cc43)o2)cc1]

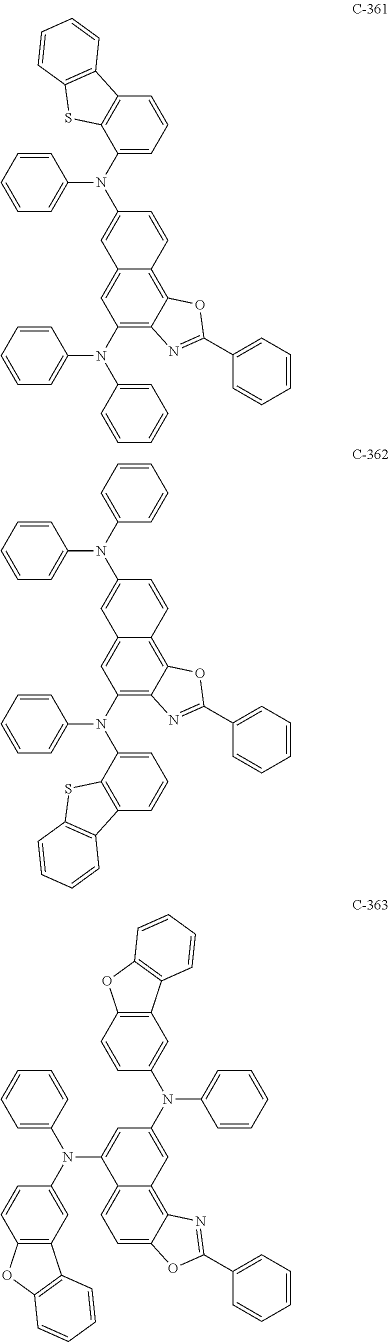

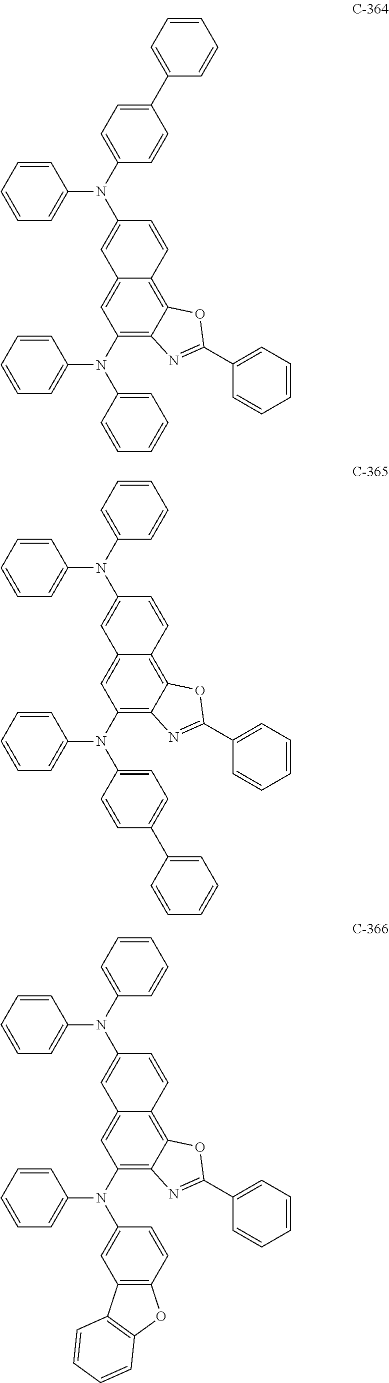

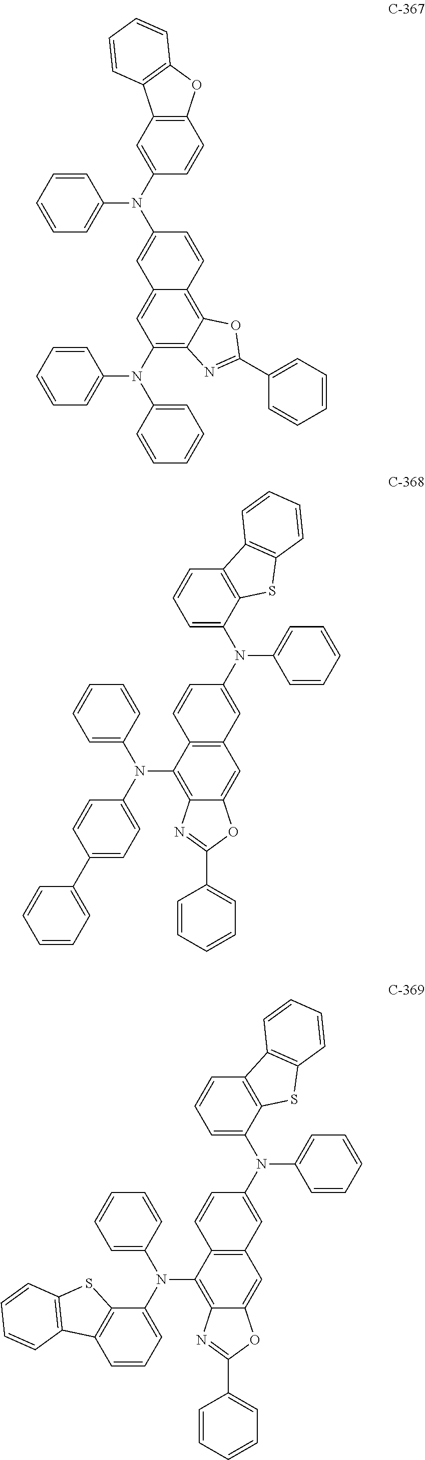 [SMILES: c1ccc(-c2nc3c(N(c4ccccc4)c4ccccc4)cc4cc(N(c5ccccc5)c5ccc6oc7ccccc7c6c5)ccc4c3o2)cc1 ; c1ccc(-c2ccc(N(c3ccccc3)c3c4ccc(N(c5ccccc5)c5cccc6c5sc5ccccc56)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5cccc6c5sc5ccccc56)cc4cc3o2)cc1]

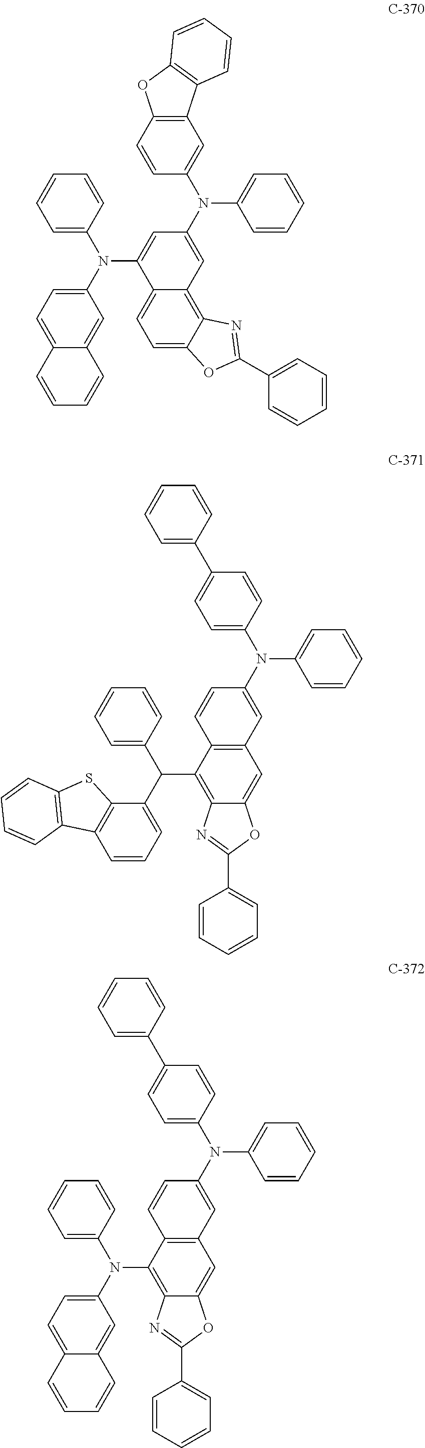 [SMILES: c1ccc(-c2nc3c(ccc4c(N(c5ccccc5)c5ccc6ccccc6c5)cc(N(c5ccccc5)c5ccc6oc7ccccc7c6c5)cc43)o2)cc1 ; c1ccc(-c2ccc(N(c3ccccc3)c3ccc4c(C(c5ccccc5)c5cccc6c5sc5ccccc56)c5nc(-c6ccccc6)oc5cc4c3)cc2)cc1 ; c1ccc(-c2ccc(N(c3ccccc3)c3ccc4c(N(c5ccccc5)c5ccc6ccccc6c5)c5nc(-c6ccccc6)oc5cc4c3)cc2)cc1]

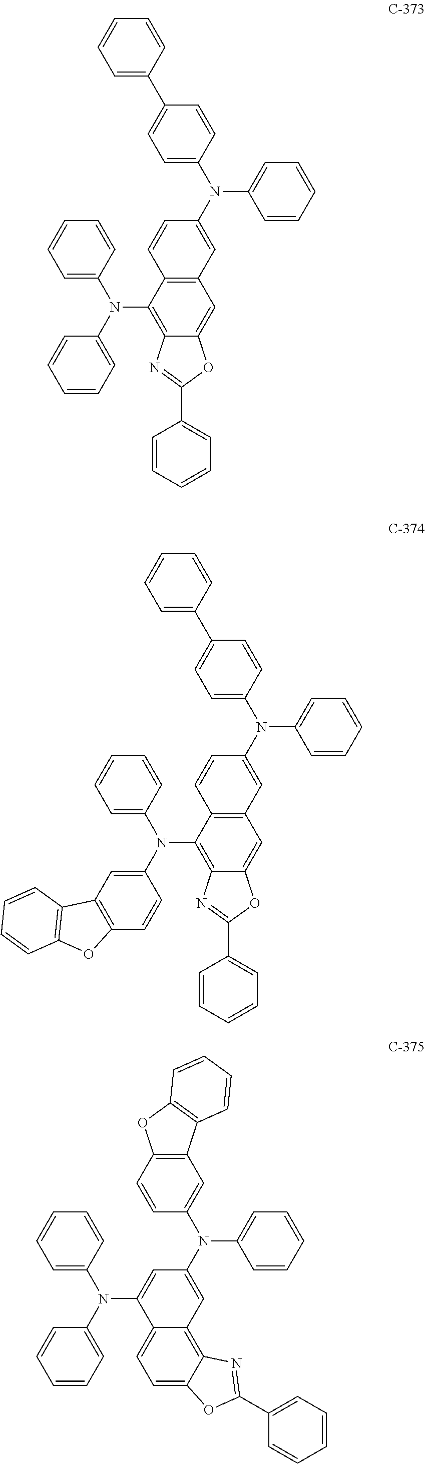

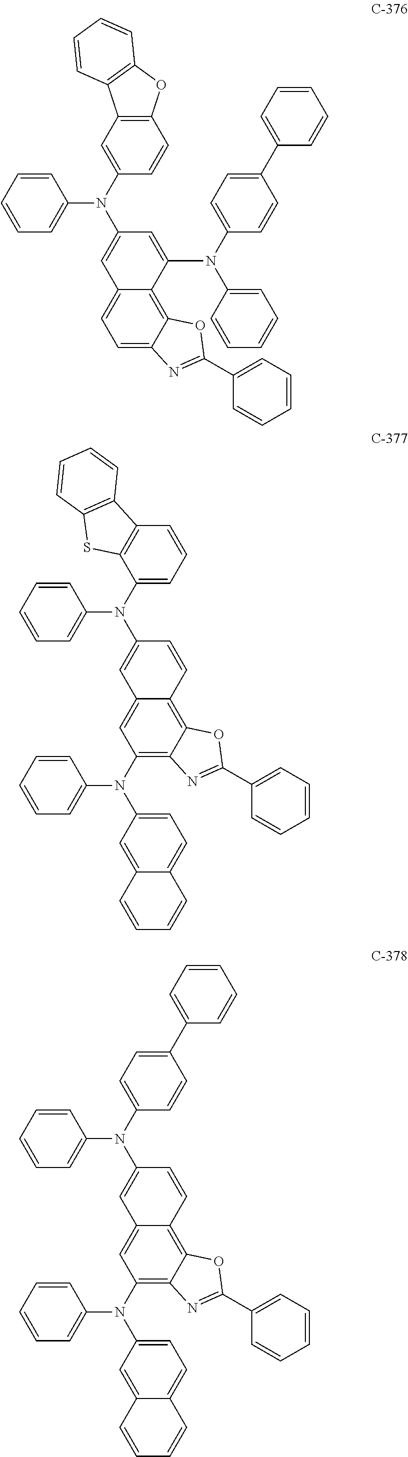

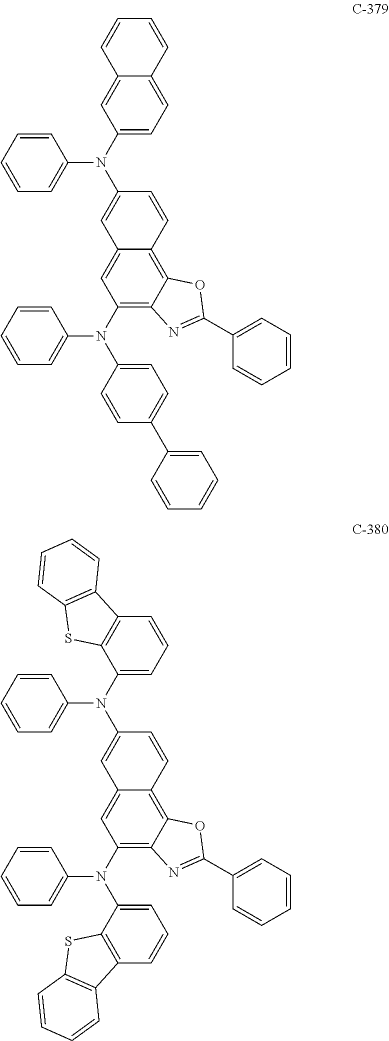 [SMILES: c1ccc(-c2ccc(N(c3ccccc3)c3cc4cc(N(c5ccccc5)c5ccc6ccccc6c5)ccc4c4oc(-c5ccccc5)nc34)cc2)cc1 ; c1ccc(-c2nc3c(N(c4ccccc4)c4cccc5c4sc4ccccc45)cc4cc(N(c5ccccc5)c5cccc6c5sc5ccccc56)ccc4c3o2)cc1]

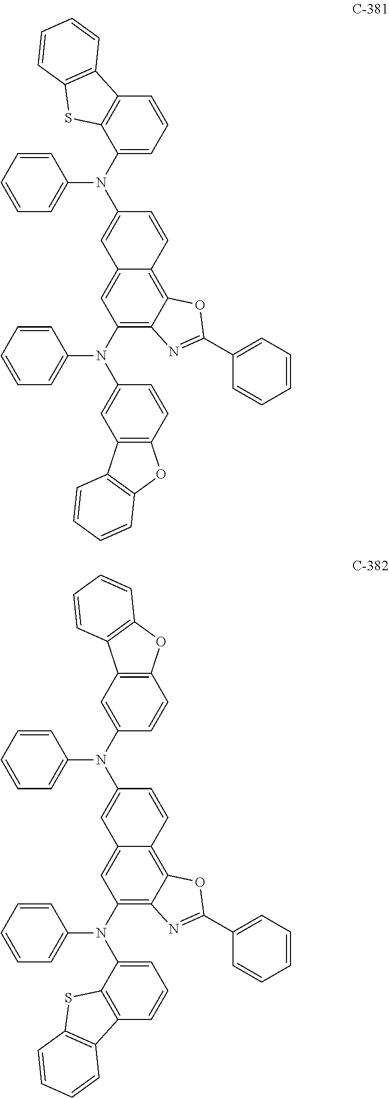

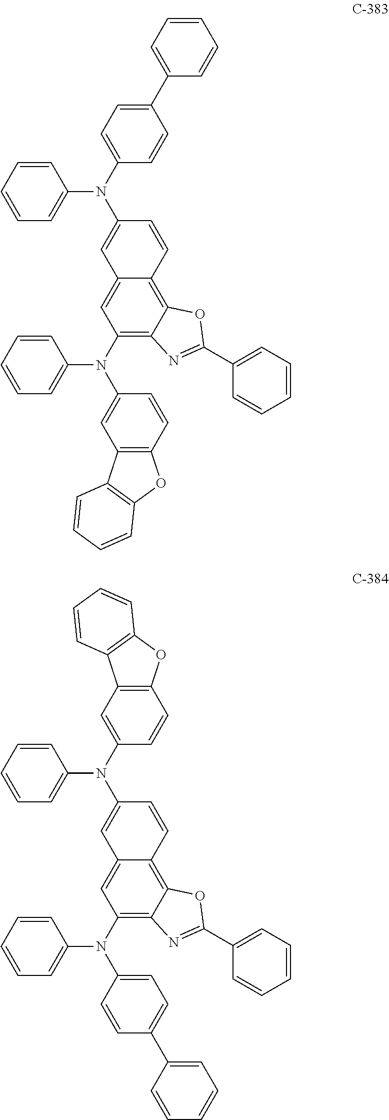

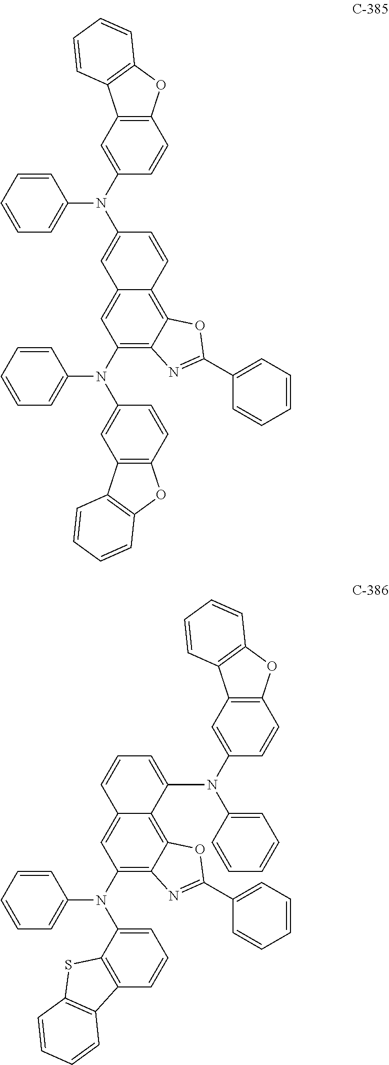 [SMILES: c1ccc(-c2nc3c(N(c4ccccc4)c4ccc5oc6ccccc6c5c4)cc4cc(N(c5ccccc5)c5ccc6oc7ccccc7c6c5)ccc4c3o2)cc1 ; c1ccc(-c2nc3c(N(c4ccccc4)c4cccc5c4sc4ccccc45)cc4cccc(N(c5ccccc5)c5ccc6oc7ccccc7c6c5)c4c3o2)cc1]

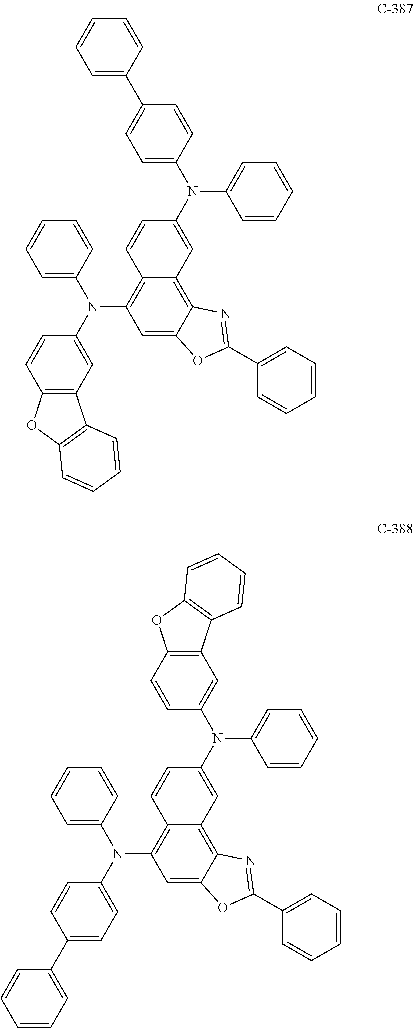 [SMILES: c1ccc(-c2ccc(N(c3ccccc3)c3ccc4c(N(c5ccccc5)c5ccc6oc7ccccc7c6c5)cc5oc(-c6ccccc6)nc5c4c3)cc2)cc1 ; c1ccc(-c2ccc(N(c3ccccc3)c3cc4oc(-c5ccccc5)nc4c4cc(N(c5ccccc5)c5ccc6oc7ccccc7c6c5)ccc34)cc2)cc1]

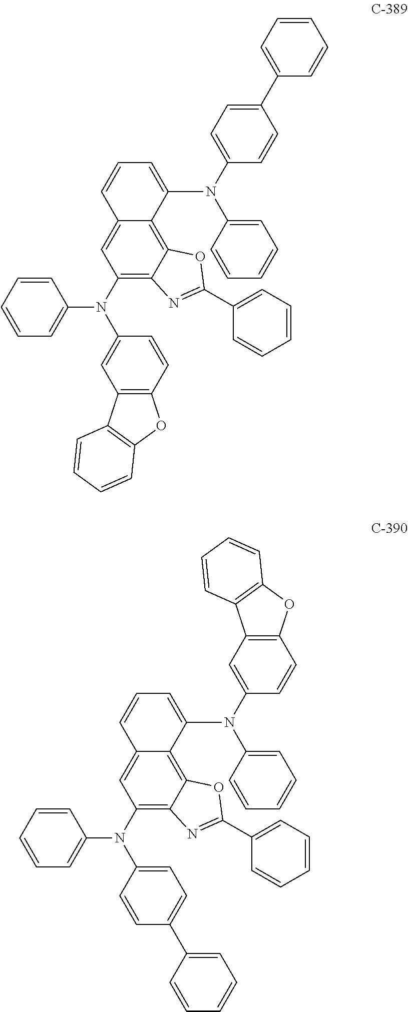 [SMILES: c1ccc(-c2ccc(N(c3ccccc3)c3cccc4cc(N(c5ccccc5)c5ccc6oc7ccccc7c6c5)c5nc(-c6ccccc6)oc5c34)cc2)cc1 ; c1ccc(-c2ccc(N(c3ccccc3)c3cc4cccc(N(c5ccccc5)c5ccc6oc7ccccc7c6c5)c4c4oc(-c5ccccc5)nc34)cc2)cc1]

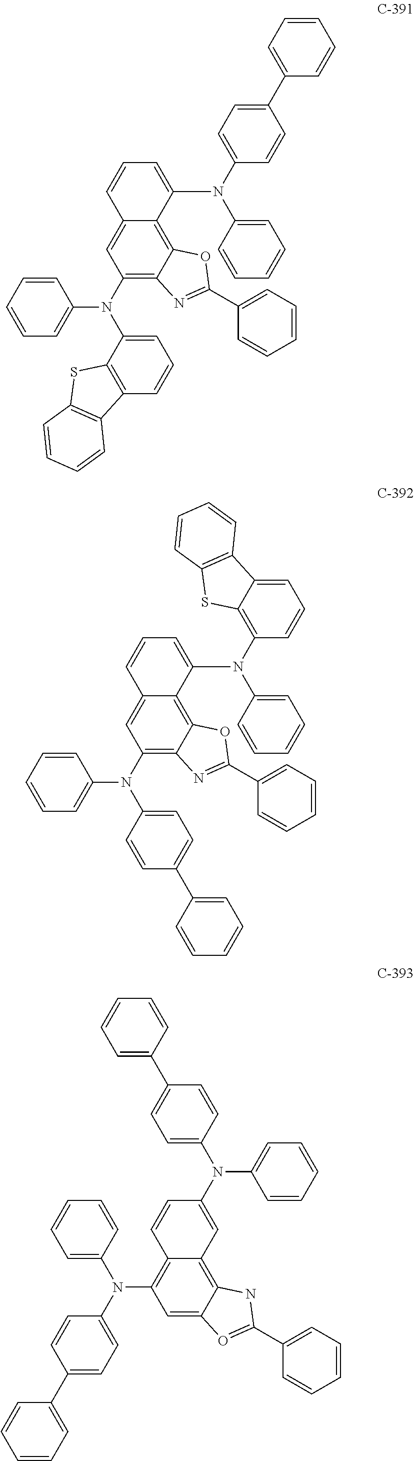

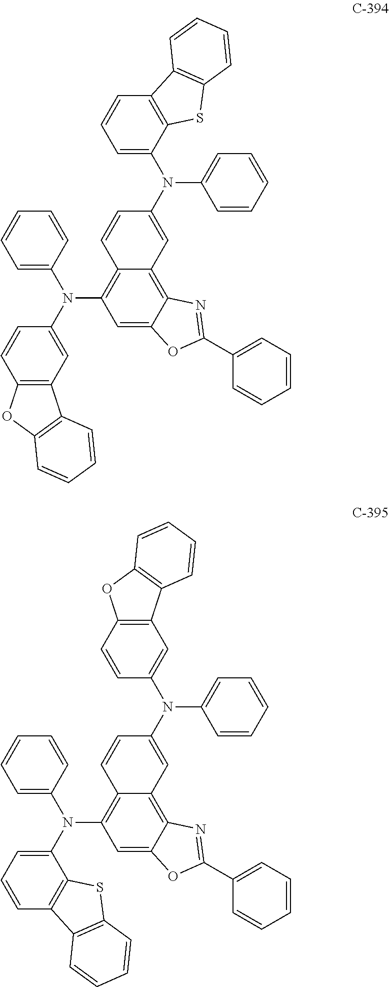 [SMILES: c1ccc(-c2nc3c(cc(N(c4ccccc4)c4ccc5oc6ccccc6c5c4)c4ccc(N(c5ccccc5)c5cccc6c5sc5ccccc56)cc43)o2)cc1 ; c1ccc(-c2nc3c(cc(N(c4ccccc4)c4cccc5c4sc4ccccc45)c4ccc(N(c5ccccc5)c5ccc6oc7ccccc7c6c5)cc43)o2)cc1]

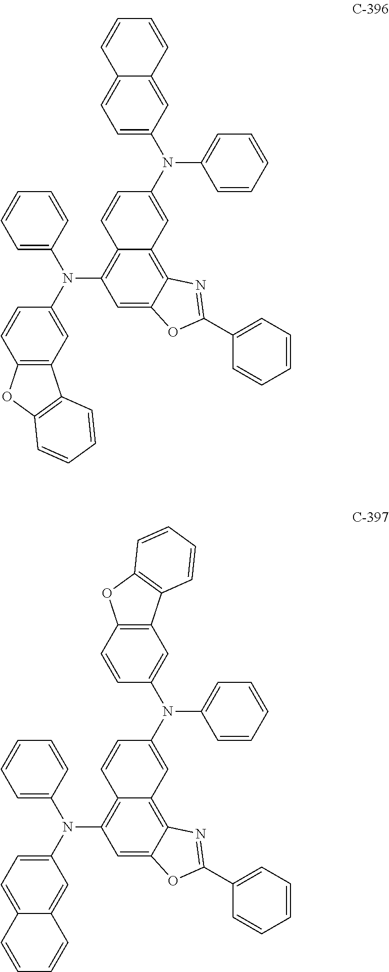 [SMILES: c1ccc(-c2nc3c(cc(N(c4ccccc4)c4ccc5oc6ccccc6c5c4)c4ccc(N(c5ccccc5)c5ccc6ccccc6c5)cc43)o2)cc1 ; c1ccc(-c2nc3c(cc(N(c4ccccc4)c4ccc5ccccc5c4)c4ccc(N(c5ccccc5)c5ccc6oc7ccccc7c6c5)cc43)o2)cc1]

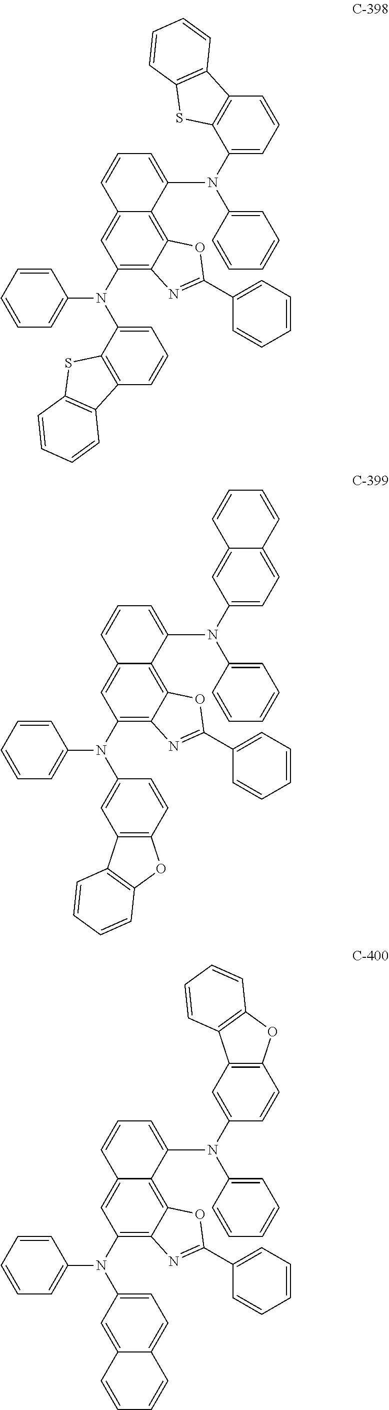 [SMILES: c1ccc(-c2nc3c(N(c4ccccc4)c4cccc5c4sc4ccccc45)cc4cccc(N(c5ccccc5)c5cccc6c5sc5ccccc56)c4c3o2)cc1 ; c1ccc(-c2nc3c(N(c4ccccc4)c4ccc5oc6ccccc6c5c4)cc4cccc(N(c5ccccc5)c5ccc6ccccc6c5)c4c3o2)cc1 ; c1ccc(-c2nc3c(N(c4ccccc4)c4ccc5ccccc5c4)cc4cccc(N(c5ccccc5)c5ccc6oc7ccccc7c6c5)c4c3o2)cc1]

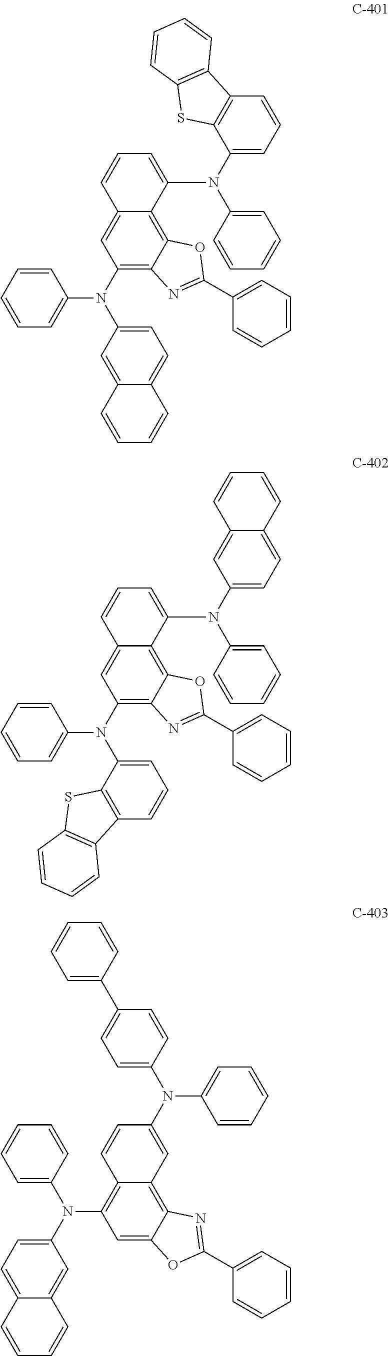

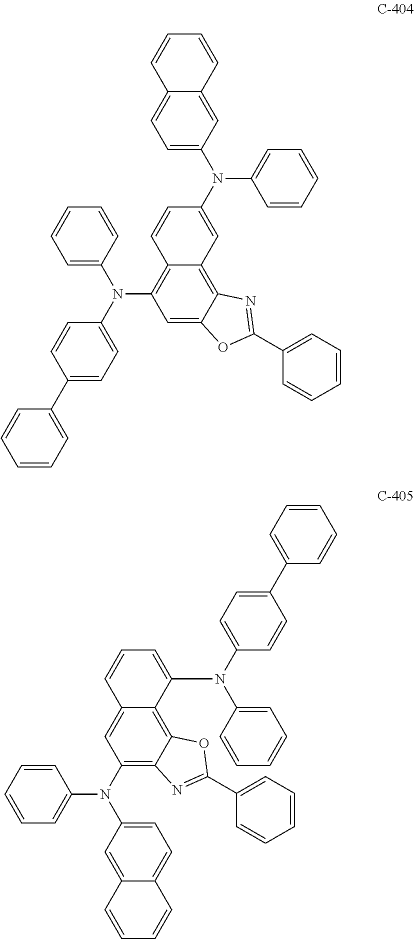 [SMILES: c1ccc(-c2ccc(N(c3ccccc3)c3cc4oc(-c5ccccc5)nc4c4cc(N(c5ccccc5)c5ccc6ccccc6c5)ccc34)cc2)cc1 ; c1ccc(-c2ccc(N(c3ccccc3)c3cccc4cc(N(c5ccccc5)c5ccc6ccccc6c5)c5nc(-c6ccccc6)oc5c34)cc2)cc1]

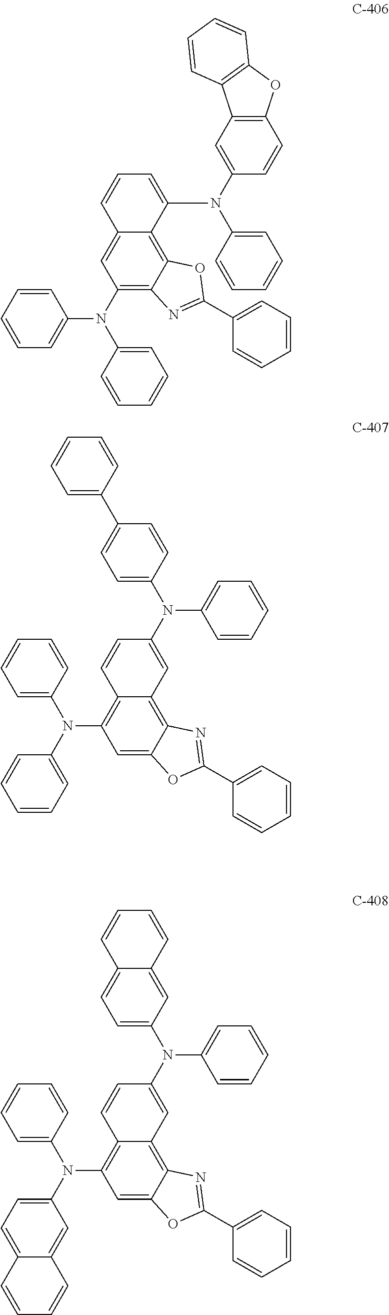

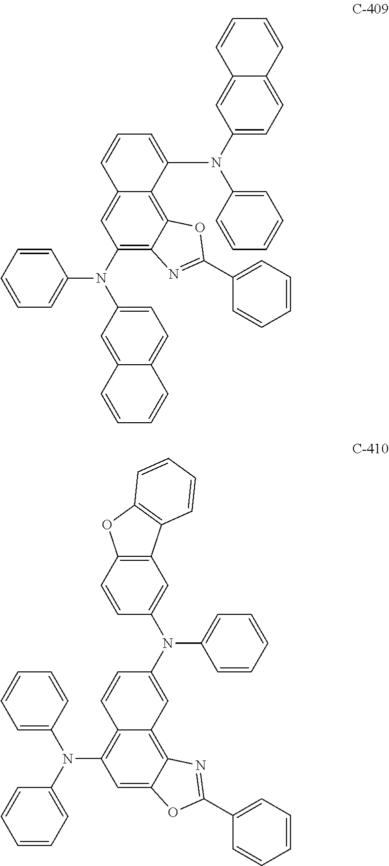

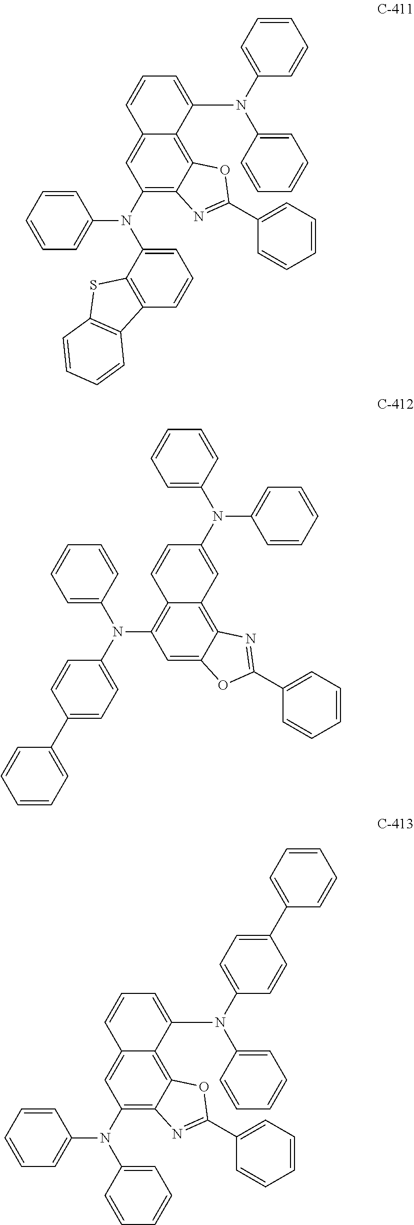 [SMILES: c1ccc(-c2nc3c(N(c4ccccc4)c4cccc5c4sc4ccccc45)cc4cccc(N(c5ccccc5)c5ccccc5)c4c3o2)cc1 ; c1ccc(-c2ccc(N(c3ccccc3)c3cc4oc(-c5ccccc5)nc4c4cc(N(c5ccccc5)c5ccccc5)ccc34)cc2)cc1 ; c1ccc(-c2ccc(N(c3ccccc3)c3cccc4cc(N(c5ccccc5)c5ccccc5)c5nc(-c6ccccc6)oc5c34)cc2)cc1]

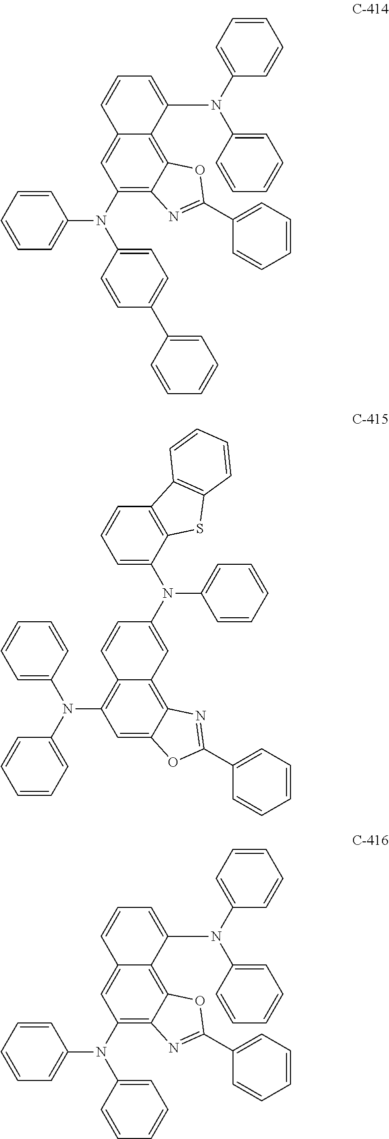

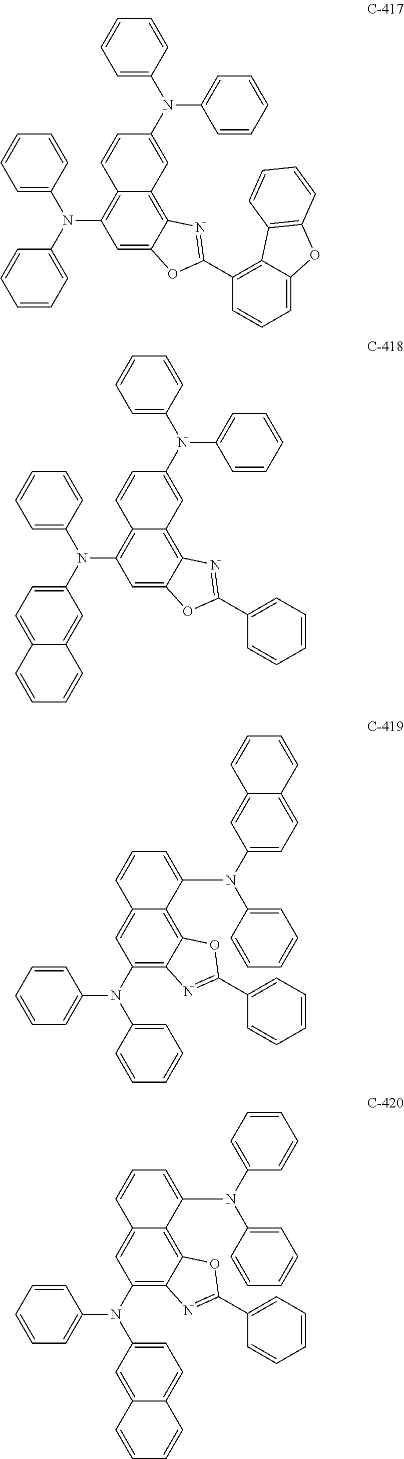 [SMILES: c1ccc(N(c2ccccc2)c2ccc3c(N(c4ccccc4)c4ccccc4)cc4oc(-c5cccc6oc7ccccc7c56)nc4c3c2)cc1 ; c1ccc(-c2nc3c(cc(N(c4ccccc4)c4ccc5ccccc5c4)c4ccc(N(c5ccccc5)c5ccccc5)cc43)o2)cc1 ; c1ccc(-c2nc3c(N(c4ccccc4)c4ccccc4)cc4cccc(N(c5ccccc5)c5ccc6ccccc6c5)c4c3o2)cc1 ; c1ccc(-c2nc3c(N(c4ccccc4)c4ccc5ccccc5c4)cc4cccc(N(c5ccccc5)c5ccccc5)c4c3o2)cc1]

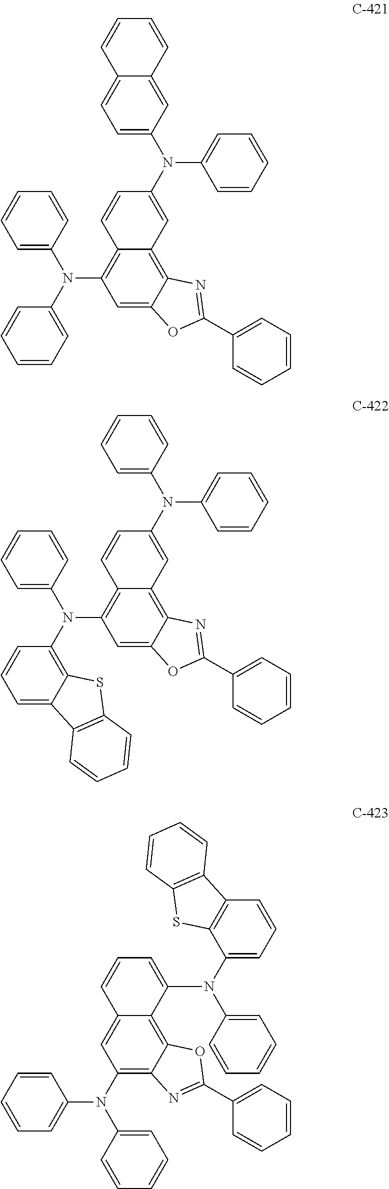 [SMILES: c1ccc(-c2nc3c(cc(N(c4ccccc4)c4ccccc4)c4ccc(N(c5ccccc5)c5ccc6ccccc6c5)cc43)o2)cc1 ; c1ccc(-c2nc3c(cc(N(c4ccccc4)c4cccc5c4sc4ccccc45)c4ccc(N(c5ccccc5)c5ccccc5)cc43)o2)cc1 ; c1ccc(-c2nc3c(N(c4ccccc4)c4ccccc4)cc4cccc(N(c5ccccc5)c5cccc6c5sc5ccccc56)c4c3o2)cc1]

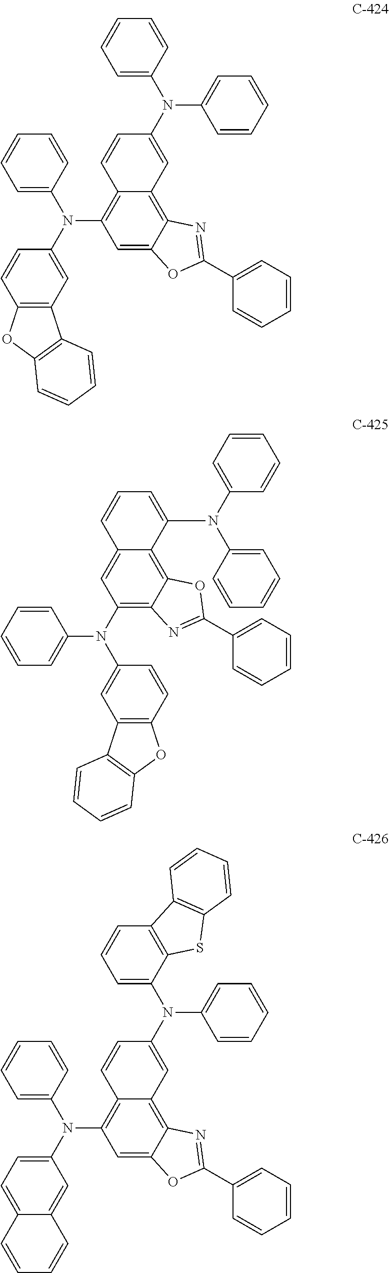 [SMILES: c1ccc(-c2nc3c(cc(N(c4ccccc4)c4ccc5oc6ccccc6c5c4)c4ccc(N(c5ccccc5)c5ccccc5)cc43)o2)cc1 ; c1ccc(-c2nc3c(N(c4ccccc4)c4ccc5oc6ccccc6c5c4)cc4cccc(N(c5ccccc5)c5ccccc5)c4c3o2)cc1 ; c1ccc(-c2nc3c(cc(N(c4ccccc4)c4ccc5ccccc5c4)c4ccc(N(c5ccccc5)c5cccc6c5sc5ccccc56)cc43)o2)cc1]

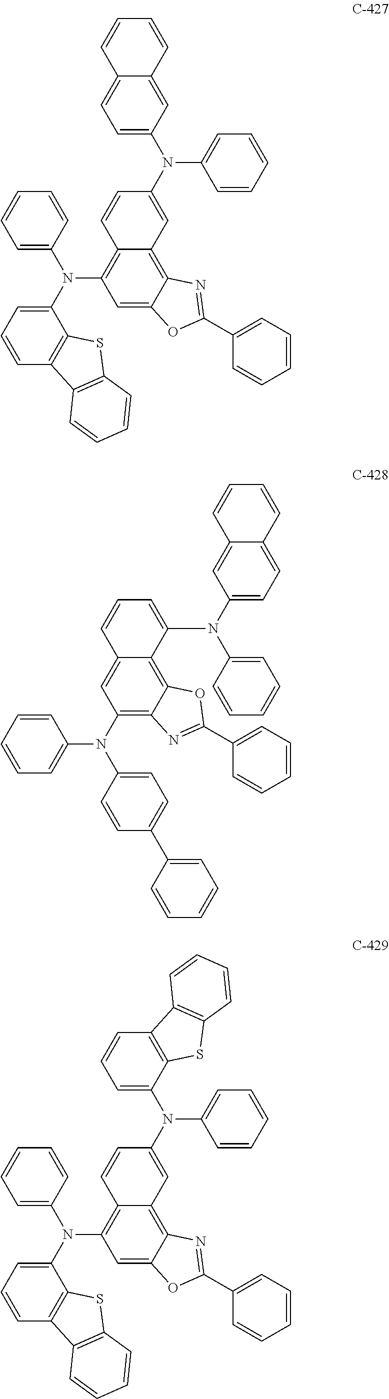

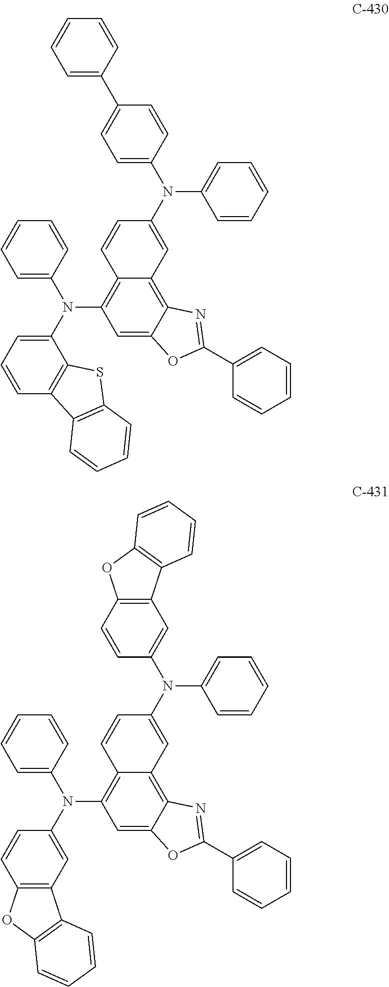 [SMILES: c1ccc(-c2ccc(N(c3ccccc3)c3ccc4c(N(c5ccccc5)c5cccc6c5sc5ccccc56)cc5oc(-c6ccccc6)nc5c4c3)cc2)cc1 ; c1ccc(-c2nc3c(cc(N(c4ccccc4)c4ccc5oc6ccccc6c5c4)c4ccc(N(c5ccccc5)c5ccc6oc7ccccc7c6c5)cc43)o2)cc1]

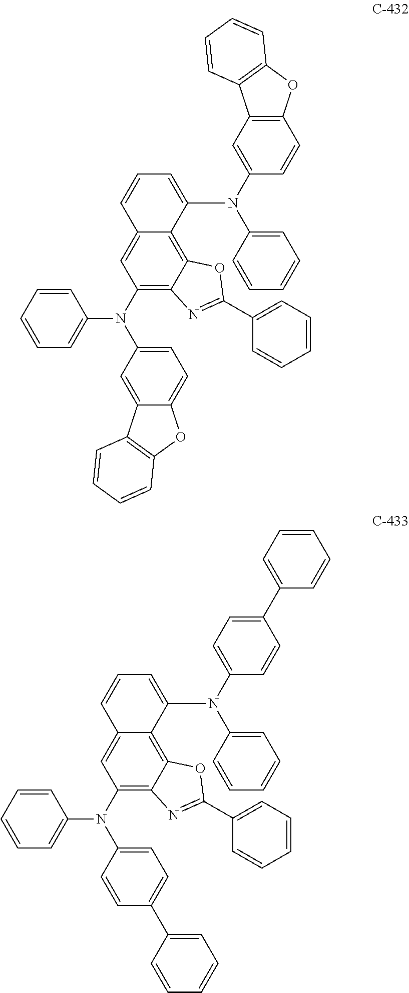 [SMILES: c1ccc(-c2nc3c(N(c4ccccc4)c4ccc5oc6ccccc6c5c4)cc4cccc(N(c5ccccc5)c5ccc6oc7ccccc7c6c5)c4c3o2)cc1 ; c1ccc(-c2ccc(N(c3ccccc3)c3cc4cccc(N(c5ccccc5)c5ccc(-c6ccccc6)cc5)c4c4oc(-c5ccccc5)nc34)cc2)cc1]

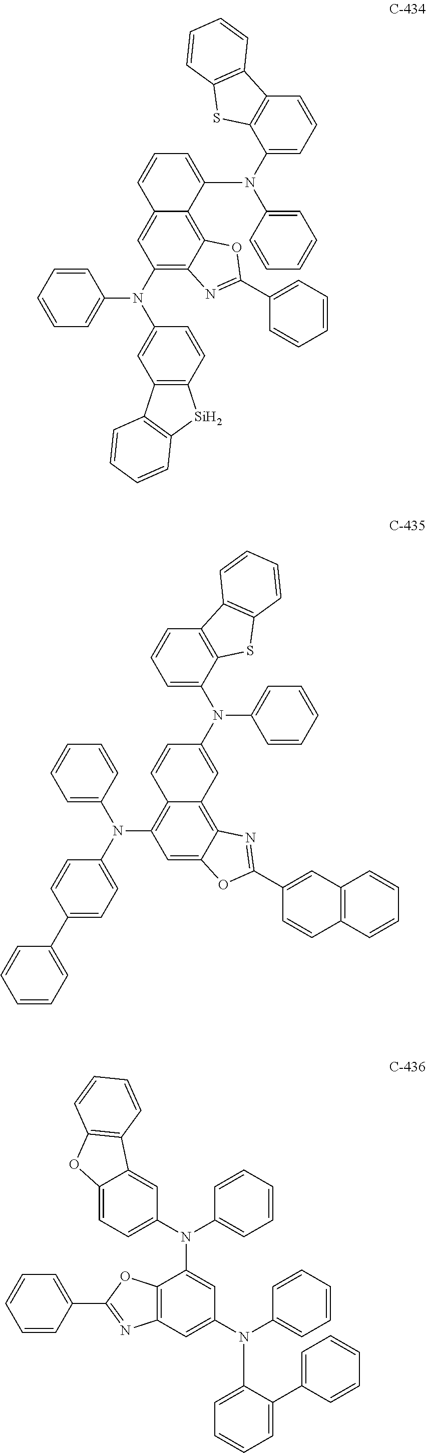

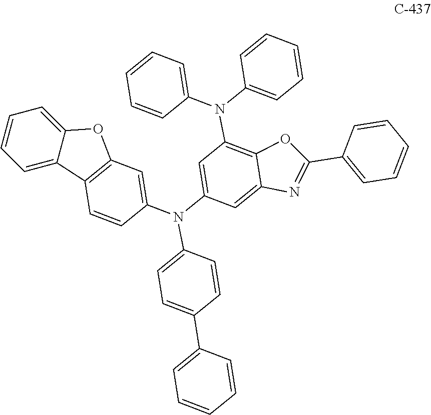 [SMILES: c1ccc(-c2ccc(N(c3cc(N(c4ccccc4)c4ccccc4)c4oc(-c5ccccc5)nc4c3)c3ccc4c(c3)oc3ccccc34)cc2)cc1]

9. The plurality of host materials according to claim 1, wherein the compound represented by Formula 2 is at least one selected from the following compounds:

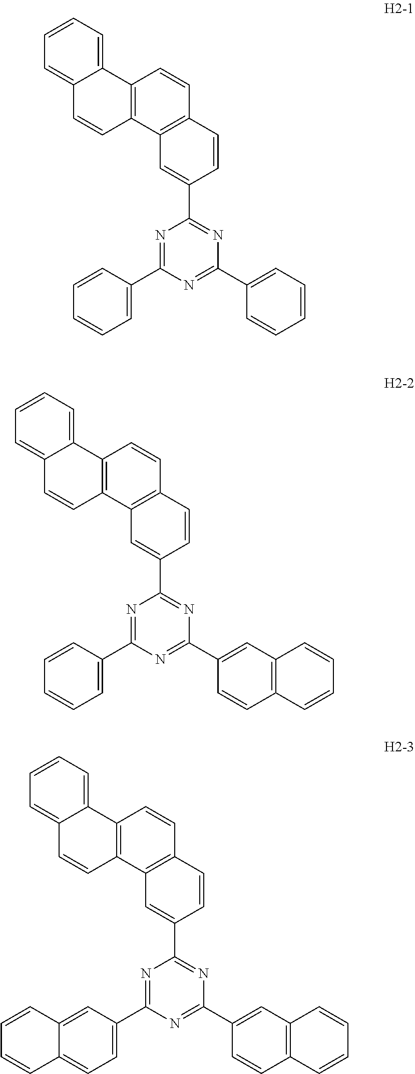 [SMILES: c1ccc(-c2nc(-c3ccccc3)nc(-c3ccc4ccc5c6ccccc6ccc5c4c3)n2)cc1 ; c1ccc(-c2nc(-c3ccc4ccccc4c3)nc(-c3ccc4ccc5c6ccccc6ccc5c4c3)n2)cc1 ; c1ccc2cc(-c3nc(-c4ccc5ccccc5c4)nc(-c4ccc5ccc6c7ccccc7ccc6c5c4)n3)ccc2c1]

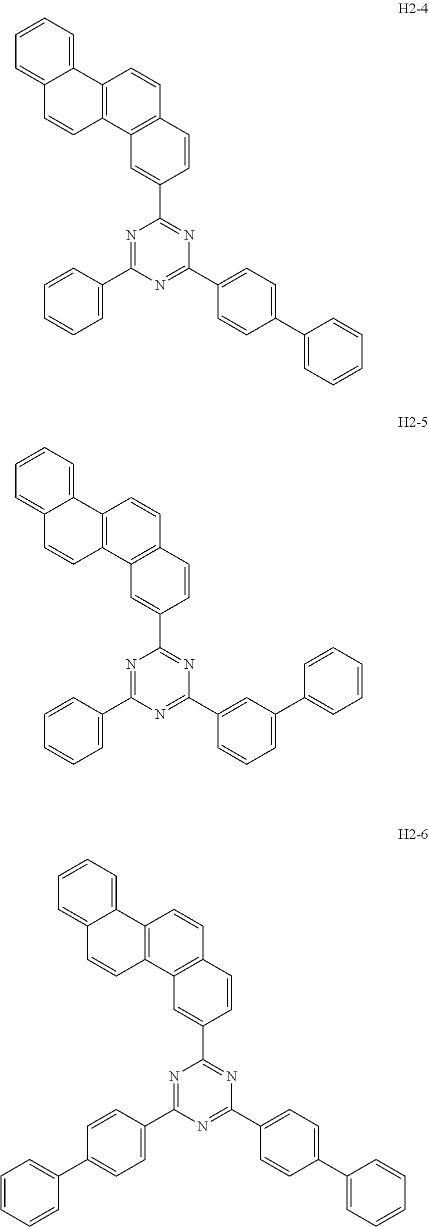 [SMILES: c1ccc(-c2ccc(-c3nc(-c4ccccc4)nc(-c4ccc5ccc6c7ccccc7ccc6c5c4)n3)cc2)cc1 ; c1ccc(-c2cccc(-c3nc(-c4ccccc4)nc(-c4ccc5ccc6c7ccccc7ccc6c5c4)n3)c2)cc1 ; c1ccc(-c2ccc(-c3nc(-c4ccc(-c5ccccc5)cc4)nc(-c4ccc5ccc6c7ccccc7ccc6c5c4)n3)cc2)cc1]

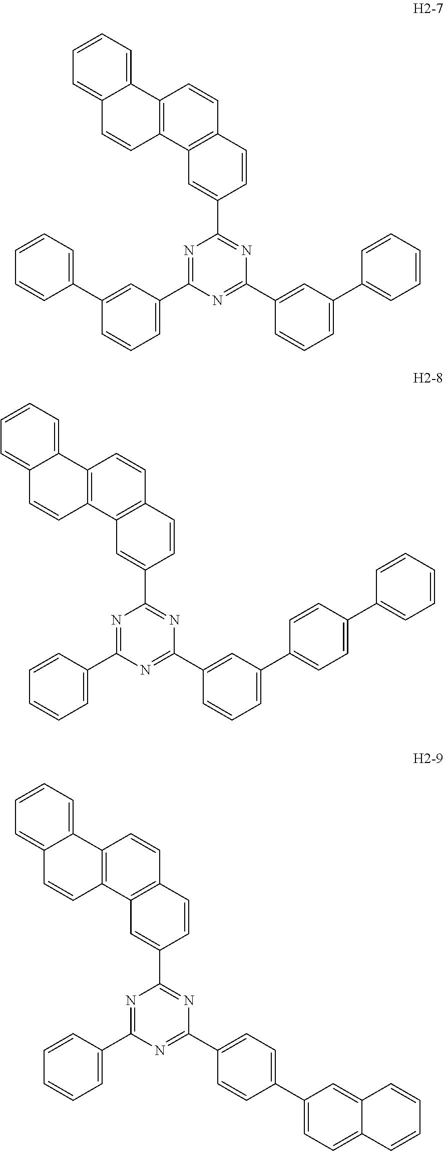 [SMILES: c1ccc(-c2cccc(-c3nc(-c4cccc(-c5ccccc5)c4)nc(-c4ccc5ccc6c7ccccc7ccc6c5c4)n3)c2)cc1 ; c1ccc(-c2ccc(-c3cccc(-c4nc(-c5ccccc5)nc(-c5ccc6ccc7c8ccccc8ccc7c6c5)n4)c3)cc2)cc1 ; c1ccc(-c2nc(-c3ccc(-c4ccc5ccccc5c4)cc3)nc(-c3ccc4ccc5c6ccccc6ccc5c4c3)n2)cc1]

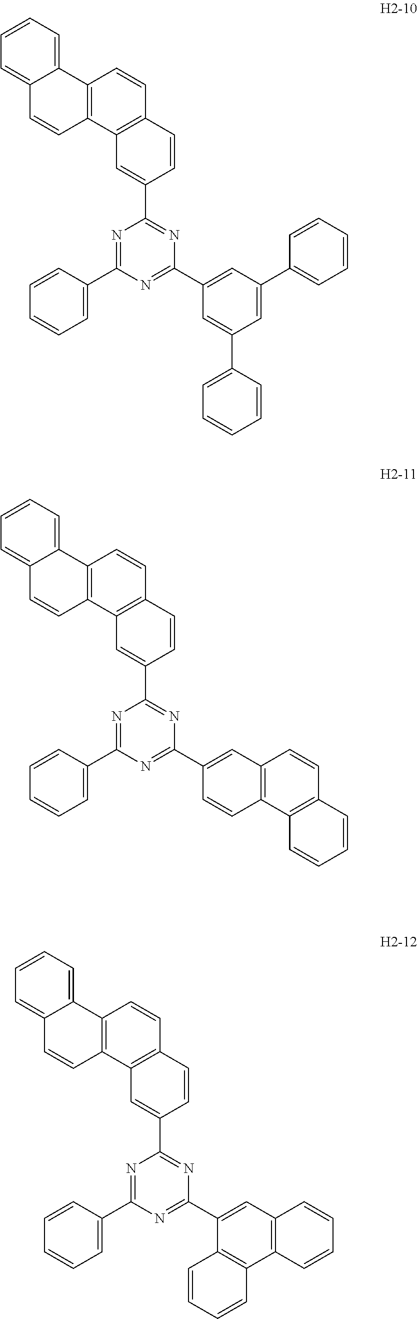 [SMILES: c1ccc(-c2cc(-c3ccccc3)cc(-c3nc(-c4ccccc4)nc(-c4ccc5ccc6c7ccccc7ccc6c5c4)n3)c2)cc1 ; c1ccc(-c2nc(-c3ccc4c(ccc5ccccc54)c3)nc(-c3ccc4ccc5c6ccccc6ccc5c4c3)n2)cc1 ; c1ccc(-c2nc(-c3ccc4ccc5c6ccccc6ccc5c4c3)nc(-c3cc4ccccc4c4ccccc34)n2)cc1]

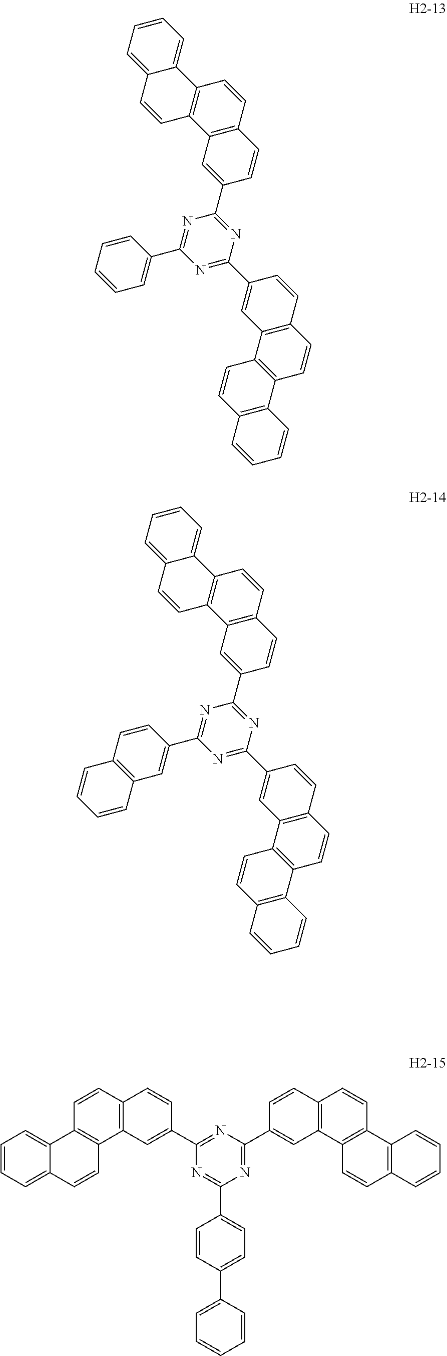 [SMILES: c1ccc(-c2nc(-c3ccc4ccc5c6ccccc6ccc5c4c3)nc(-c3ccc4ccc5c6ccccc6ccc5c4c3)n2)cc1 ; c1ccc2cc(-c3nc(-c4ccc5ccc6c7ccccc7ccc6c5c4)nc(-c4ccc5ccc6c7ccccc7ccc6c5c4)n3)ccc2c1 ; c1ccc(-c2ccc(-c3nc(-c4ccc5ccc6c7ccccc7ccc6c5c4)nc(-c4ccc5ccc6c7ccccc7ccc6c5c4)n3)cc2)cc1]

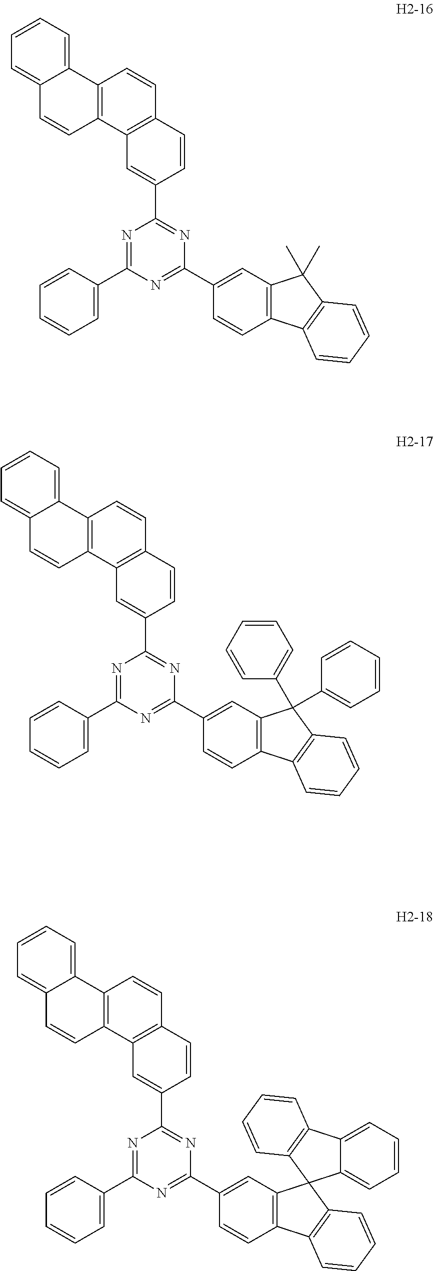 [SMILES: CC1(C)c2ccccc2-c2ccc(-c3nc(-c4ccccc4)nc(-c4ccc5ccc6c7ccccc7ccc6c5c4)n3)cc21 ; c1ccc(-c2nc(-c3ccc4c(c3)C(c3ccccc3)(c3ccccc3)c3ccccc3-4)nc(-c3ccc4ccc5c6ccccc6ccc5c4c3)n2)cc1 ; c1ccc(-c2nc(-c3ccc4c(c3)C3(c5ccccc5-c5ccccc53)c3ccccc3-4)nc(-c3ccc4ccc5c6ccccc6ccc5c4c3)n2)cc1]

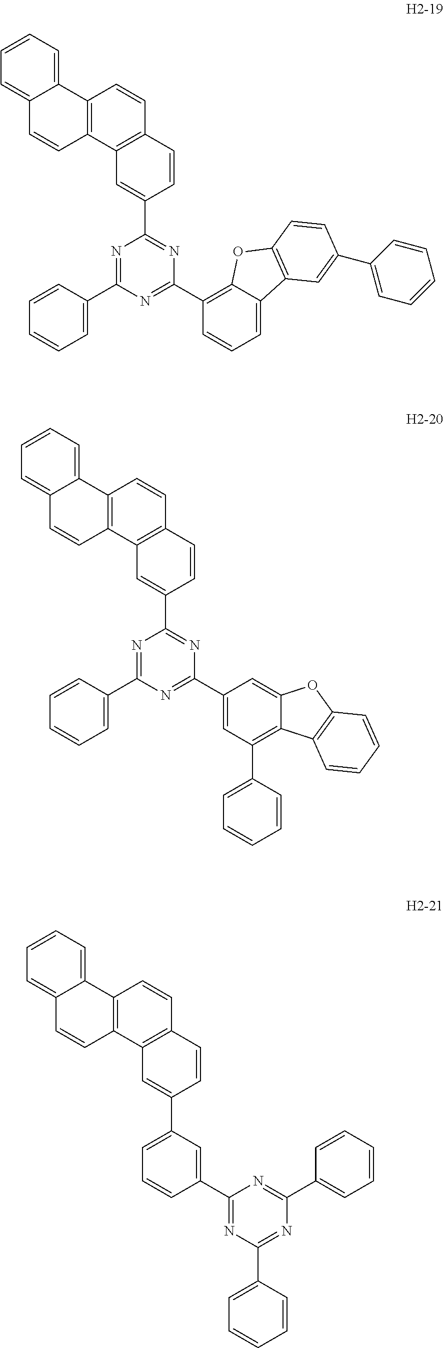 [SMILES: c1ccc(-c2ccc3oc4c(-c5nc(-c6ccccc6)nc(-c6ccc7ccc8c9ccccc9ccc8c7c6)n5)cccc4c3c2)cc1 ; c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccccc3)nc(-c3cccc(-c4ccc5ccc6c7ccccc7ccc6c5c4)c3)n2)cc1]

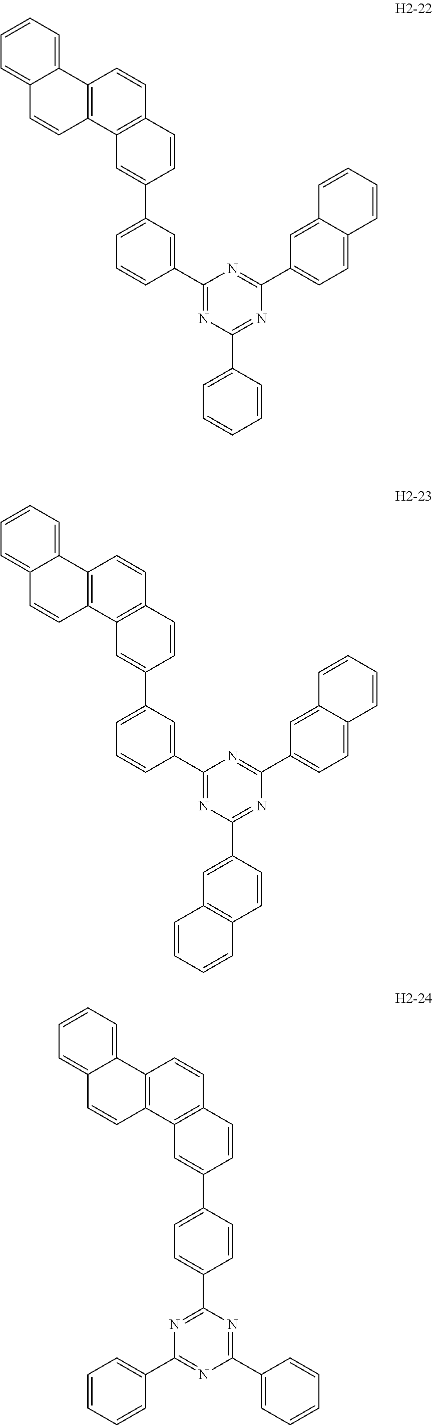 [SMILES: c1ccc(-c2nc(-c3cccc(-c4ccc5ccc6c7ccccc7ccc6c5c4)c3)nc(-c3ccc4ccccc4c3)n2)cc1 ; c1cc(-c2ccc3ccc4c5ccccc5ccc4c3c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5ccc6c7ccccc7ccc6c5c4)cc3)n2)cc1]

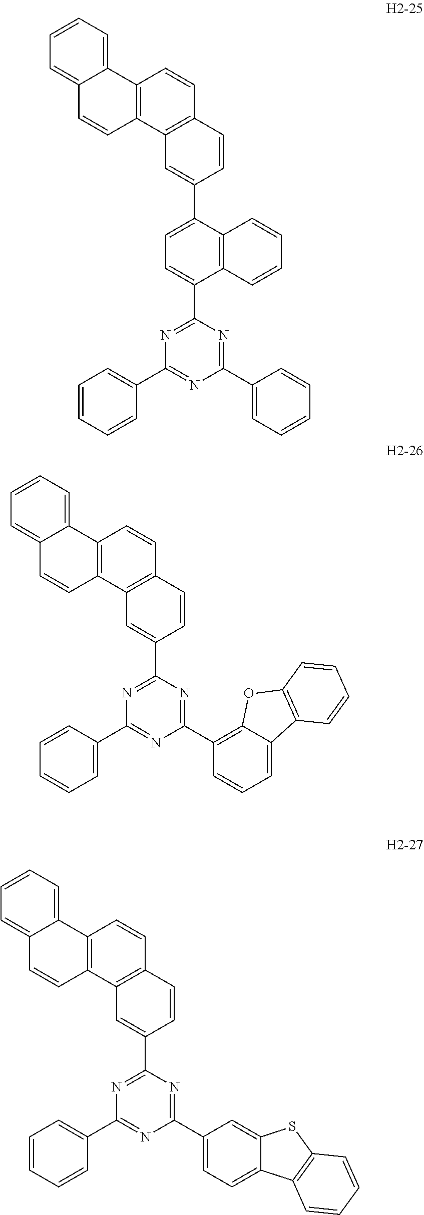 [SMILES: c1ccc(-c2nc(-c3ccccc3)nc(-c3ccc(-c4ccc5ccc6c7ccccc7ccc6c5c4)c4ccccc34)n2)cc1 ; c1ccc(-c2nc(-c3ccc4ccc5c6ccccc6ccc5c4c3)nc(-c3cccc4c3oc3ccccc34)n2)cc1 ; c1ccc(-c2nc(-c3ccc4c(c3)sc3ccccc34)nc(-c3ccc4ccc5c6ccccc6ccc5c4c3)n2)cc1]

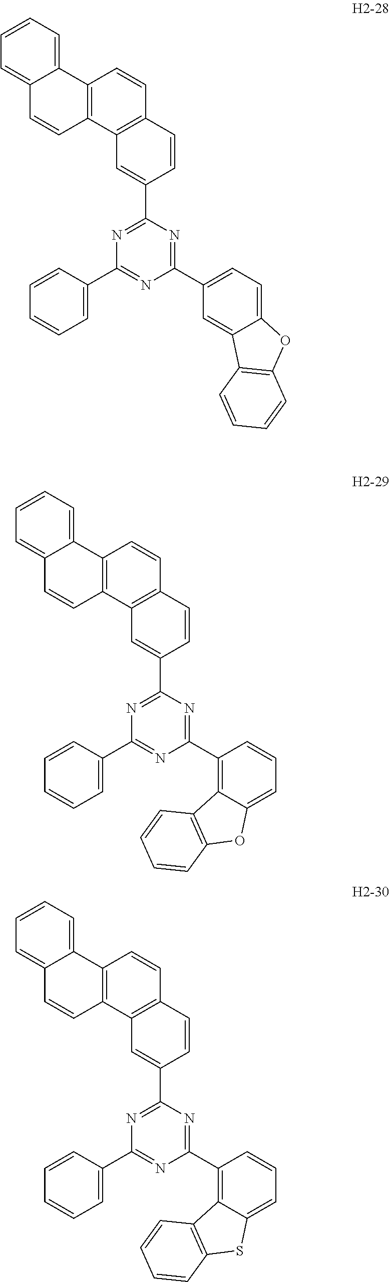 [SMILES: c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-c3cccc4sc5ccccc5c34)n2)cc1]

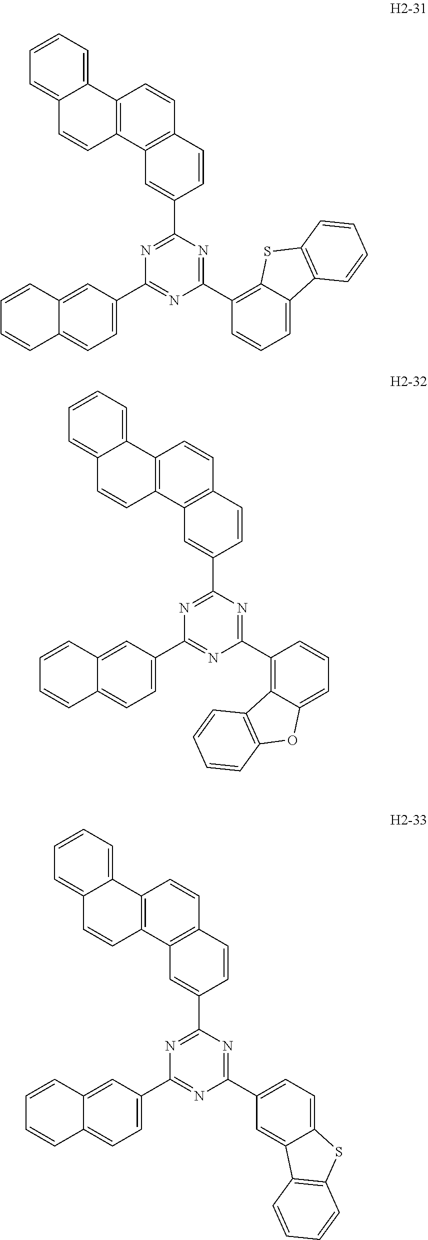

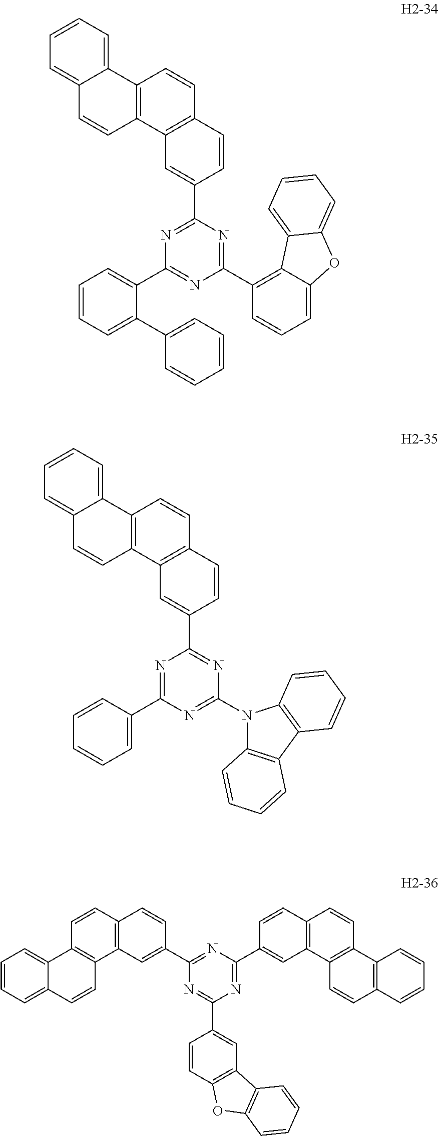 [SMILES: c1ccc(-c2ccccc2-c2nc(-c3ccc4ccc5c6ccccc6ccc5c4c3)nc(-c3cccc4oc5ccccc5c34)n2)cc1 ; c1ccc(-c2nc(-c3ccc4ccc5c6ccccc6ccc5c4c3)nc(-n3c4ccccc4c4ccccc43)n2)cc1 ; c1ccc2c(c1)ccc1c3cc(-c4nc(-c5ccc6ccc7c8ccccc8ccc7c6c5)nc(-c5ccc6oc7ccccc7c6c5)n4)ccc3ccc21]

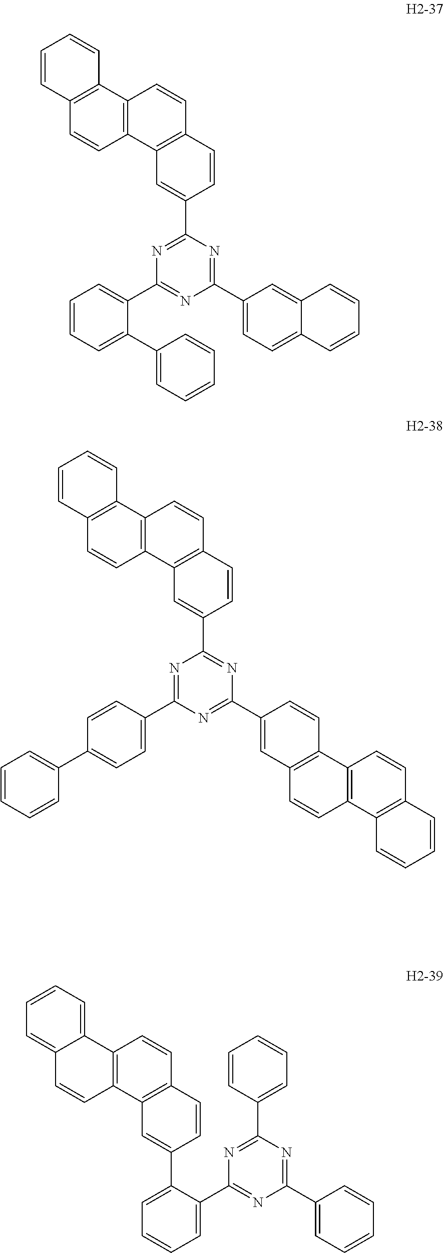 [SMILES: c1ccc(-c2ccccc2-c2nc(-c3ccc4ccccc4c3)nc(-c3ccc4ccc5c6ccccc6ccc5c4c3)n2)cc1 ; c1ccc(-c2ccc(-c3nc(-c4ccc5c(ccc6c7ccccc7ccc56)c4)nc(-c4ccc5ccc6c7ccccc7ccc6c5c4)n3)cc2)cc1 ; c1ccc(-c2nc(-c3ccccc3)nc(-c3ccccc3-c3ccc4ccc5c6ccccc6ccc5c4c3)n2)cc1]

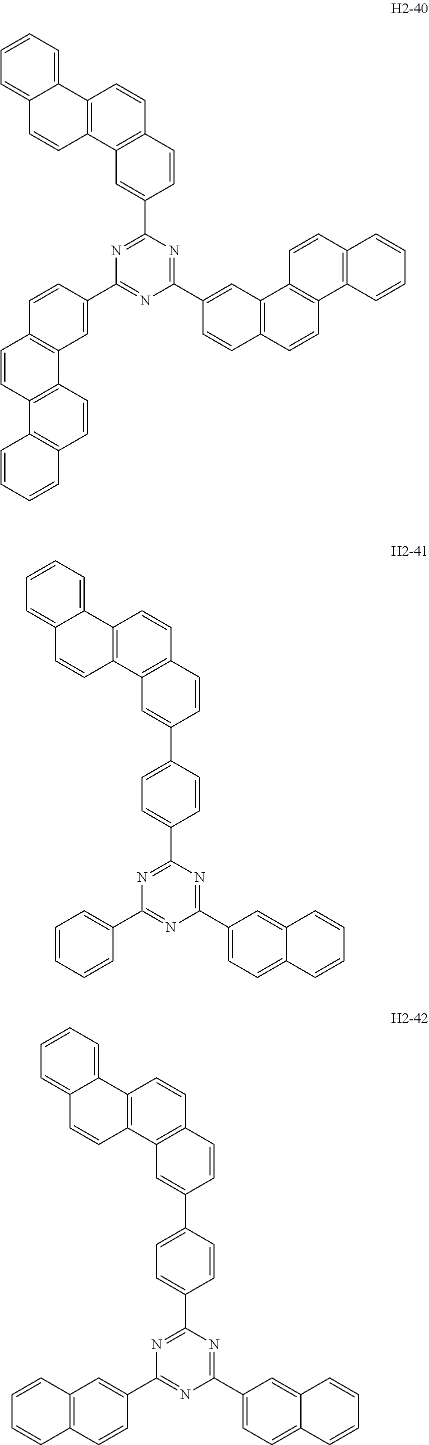 [SMILES: c1ccc2c(c1)ccc1c3cc(-c4nc(-c5ccc6ccc7c8ccccc8ccc7c6c5)nc(-c5ccc6ccc7c8ccccc8ccc7c6c5)n4)ccc3ccc21 ; c1ccc(-c2nc(-c3ccc(-c4ccc5ccc6c7ccccc7ccc6c5c4)cc3)nc(-c3ccc4ccccc4c3)n2)cc1 ; c1ccc2cc(-c3nc(-c4ccc(-c5ccc6ccc7c8ccccc8ccc7c6c5)cc4)nc(-c4ccc5ccccc5c4)n3)ccc2c1]

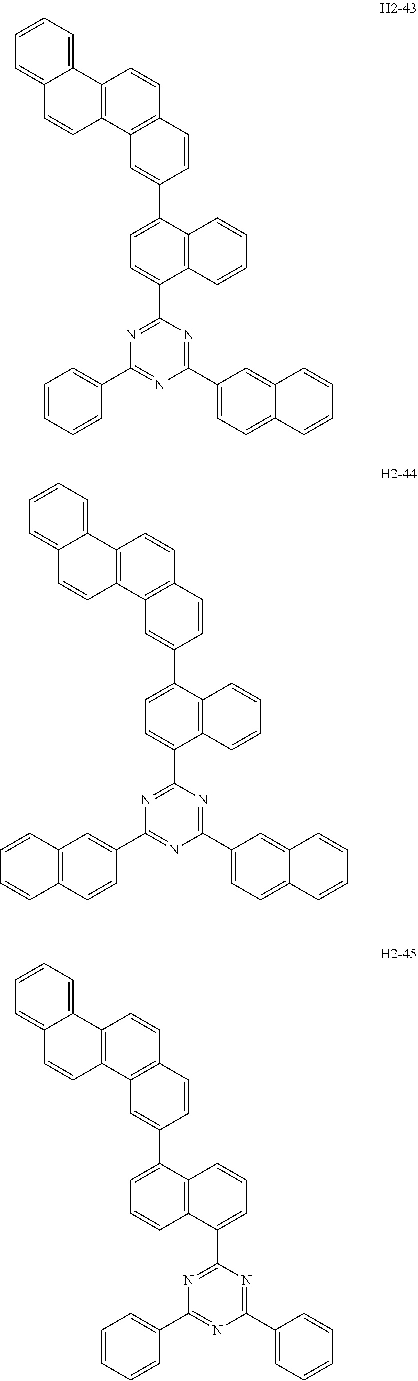 [SMILES: c1ccc(-c2nc(-c3ccc4ccccc4c3)nc(-c3ccc(-c4ccc5ccc6c7ccccc7ccc6c5c4)c4ccccc34)n2)cc1 ; c1ccc2cc(-c3nc(-c4ccc5ccccc5c4)nc(-c4ccc(-c5ccc6ccc7c8ccccc8ccc7c6c5)c5ccccc45)n3)ccc2c1 ; c1ccc(-c2nc(-c3ccccc3)nc(-c3cccc4c(-c5ccc6ccc7c8ccccc8ccc7c6c5)cccc34)n2)cc1]

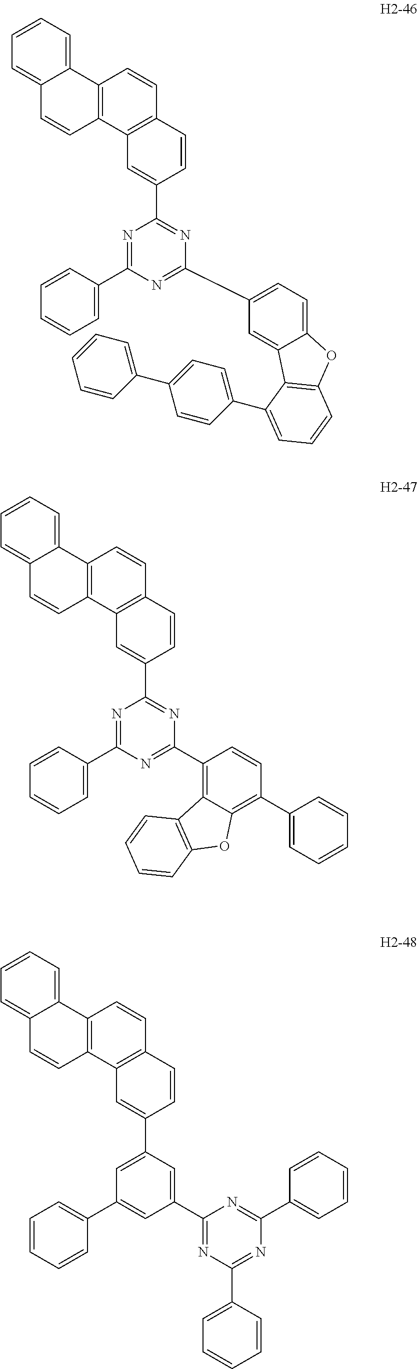 [SMILES: c1ccc(-c2ccc(-c3cccc4oc5ccc(-c6nc(-c7ccccc7)nc(-c7ccc8ccc9c%10ccccc%10ccc9c8c7)n6)cc5c34)cc2)cc1 ; c1ccc(-c2nc(-c3ccc4ccc5c6ccccc6ccc5c4c3)nc(-c3ccc(-c4ccccc4)c4oc5ccccc5c34)n2)cc1 ; c1ccc(-c2cc(-c3ccc4ccc5c6ccccc6ccc5c4c3)cc(-c3nc(-c4ccccc4)nc(-c4ccccc4)n3)c2)cc1]

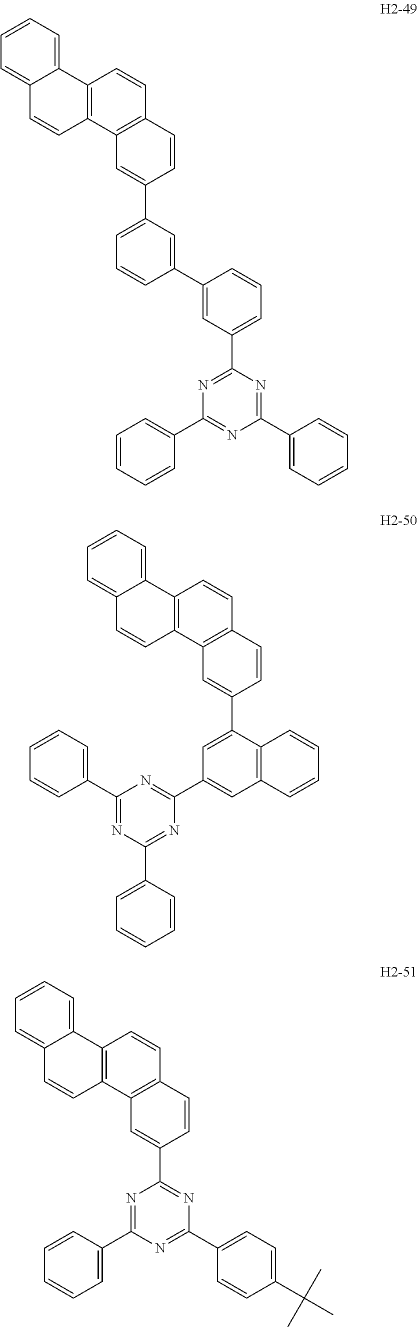 [SMILES: c1ccc(-c2nc(-c3ccccc3)nc(-c3cccc(-c4cccc(-c5ccc6ccc7c8ccccc8ccc7c6c5)c4)c3)n2)cc1 ; c1ccc(-c2nc(-c3ccccc3)nc(-c3cc(-c4ccc5ccc6c7ccccc7ccc6c5c4)c4ccccc4c3)n2)cc1 ; CC(C)(C)c1ccc(-c2nc(-c3ccccc3)nc(-c3ccc4ccc5c6ccccc6ccc5c4c3)n2)cc1]

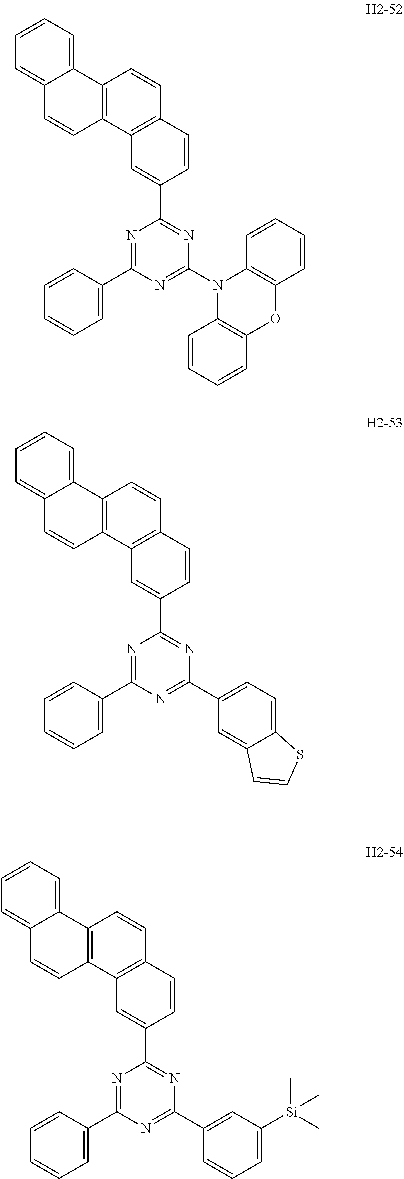 [SMILES: c1ccc(-c2nc(-c3ccc4ccc5c6ccccc6ccc5c4c3)nc(N3c4ccccc4Oc4ccccc43)n2)cc1 ; c1ccc(-c2nc(-c3ccc4sccc4c3)nc(-c3ccc4ccc5c6ccccc6ccc5c4c3)n2)cc1 ; C[Si](C)(C)c1cccc(-c2nc(-c3ccccc3)nc(-c3ccc4ccc5c6ccccc6ccc5c4c3)n2)c1]

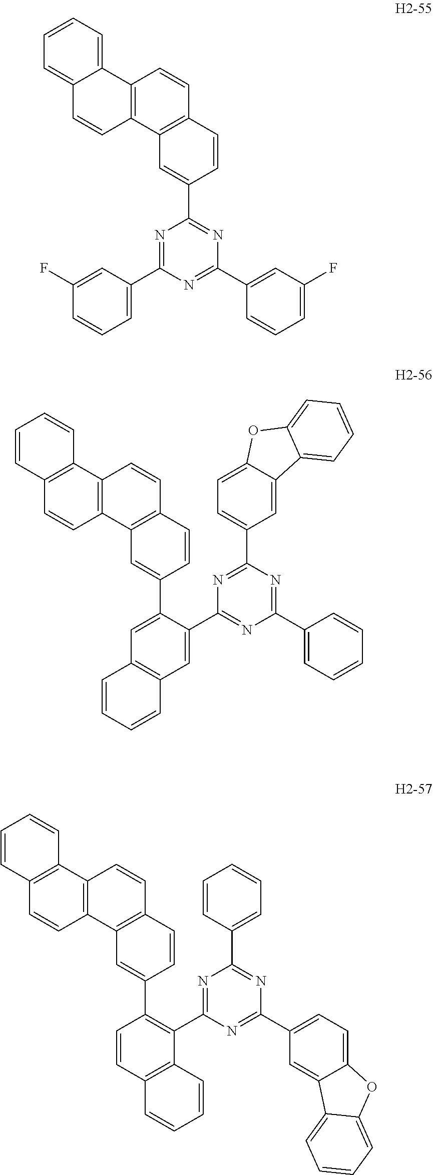 [SMILES: Fc1cccc(-c2nc(-c3cccc(F)c3)nc(-c3ccc4ccc5c6ccccc6ccc5c4c3)n2)c1 ; c1ccc(-c2nc(-c3ccc4oc5ccccc5c4c3)nc(-c3cc4ccccc4cc3-c3ccc4ccc5c6ccccc6ccc5c4c3)n2)cc1 ; c1ccc(-c2nc(-c3ccc4oc5ccccc5c4c3)nc(-c3c(-c4ccc5ccc6c7ccccc7ccc6c5c4)ccc4ccccc34)n2)cc1]

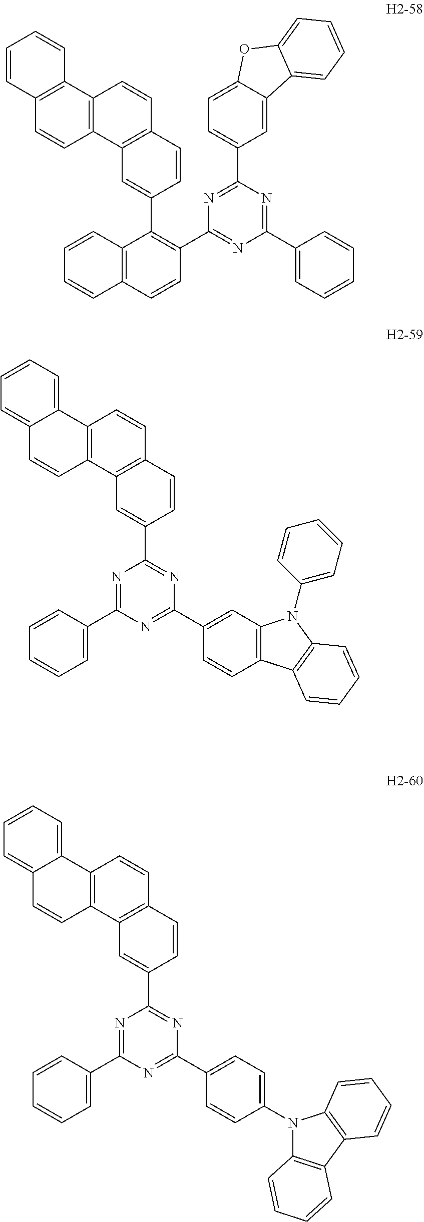 [SMILES: c1ccc(-c2nc(-c3ccc4oc5ccccc5c4c3)nc(-c3ccc4ccccc4c3-c3ccc4ccc5c6ccccc6ccc5c4c3)n2)cc1 ; c1ccc(-c2nc(-c3ccc4ccc5c6ccccc6ccc5c4c3)nc(-c3ccc4c5ccccc5n(-c5ccccc5)c4c3)n2)cc1 ; c1ccc(-c2nc(-c3ccc(-n4c5ccccc5c5ccccc54)cc3)nc(-c3ccc4ccc5c6ccccc6ccc5c4c3)n2)cc1]

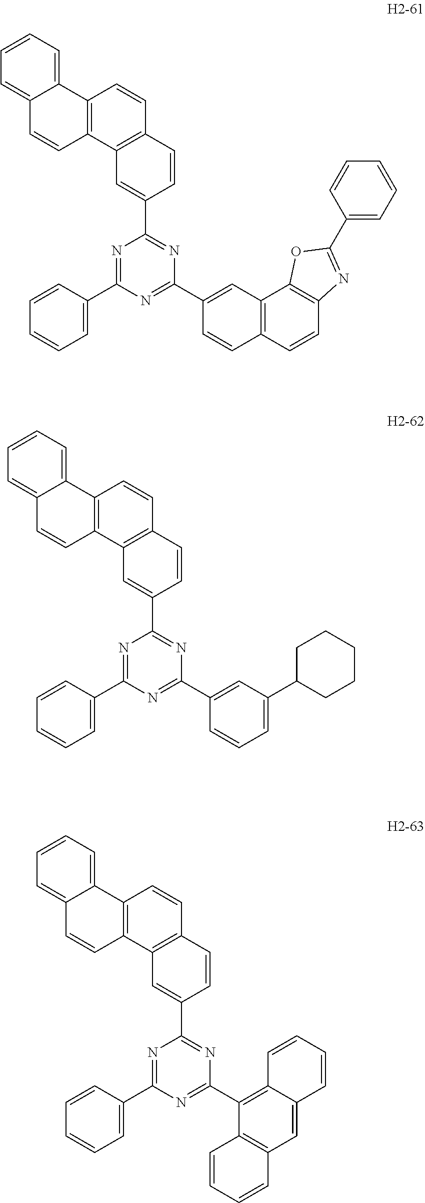 [SMILES: c1ccc(-c2nc(-c3ccc4ccc5c6ccccc6ccc5c4c3)nc(-c3ccc4ccc5nc(-c6ccccc6)oc5c4c3)n2)cc1 ; c1ccc(-c2nc(-c3cccc(C4CCCCC4)c3)nc(-c3ccc4ccc5c6ccccc6ccc5c4c3)n2)cc1 ; c1ccc(-c2nc(-c3ccc4ccc5c6ccccc6ccc5c4c3)nc(-c3c4ccccc4cc4ccccc34)n2)cc1]

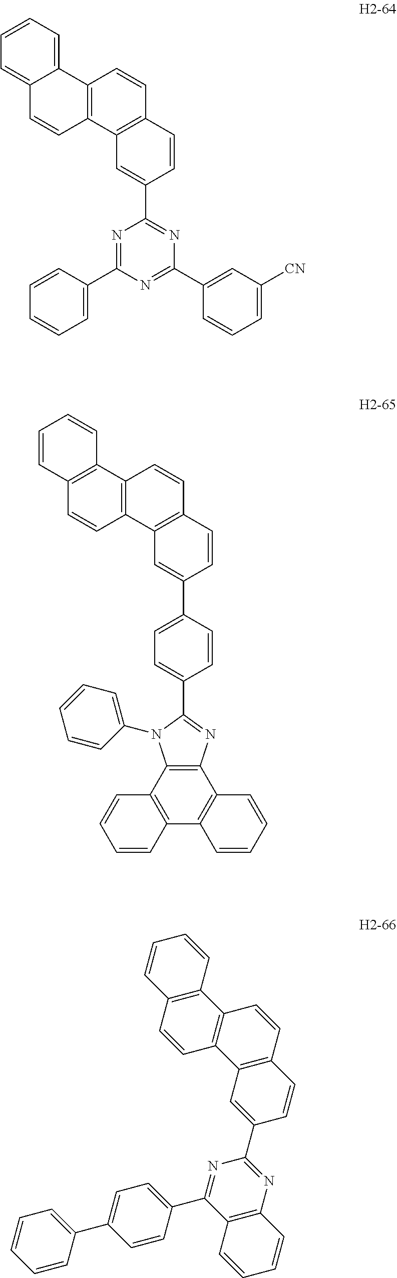 [SMILES: N#Cc1cccc(-c2nc(-c3ccccc3)nc(-c3ccc4ccc5c6ccccc6ccc5c4c3)n2)c1 ; c1ccc(-n2c(-c3ccc(-c4ccc5ccc6c7ccccc7ccc6c5c4)cc3)nc3c4ccccc4c4ccccc4c32)cc1 ; c1ccc(-c2ccc(-c3nc(-c4ccc5ccc6c7ccccc7ccc6c5c4)nc4ccccc34)cc2)cc1]

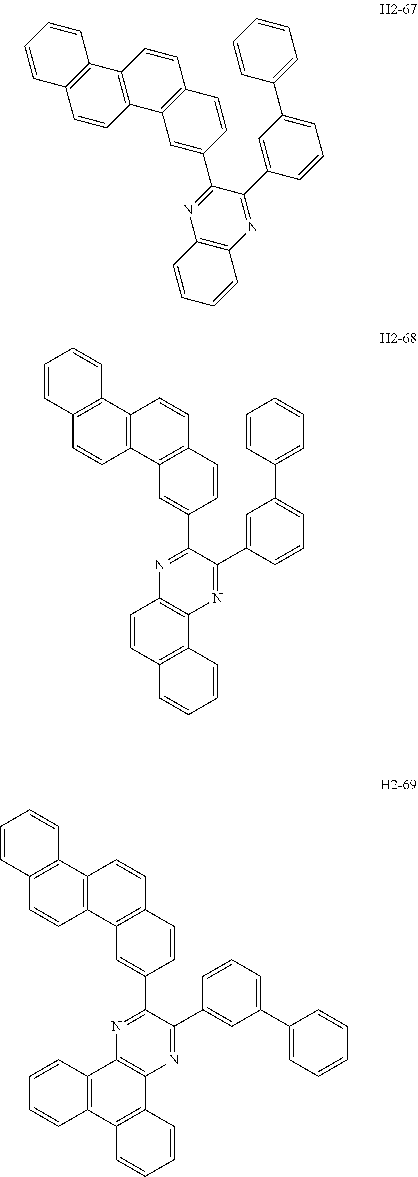 [SMILES: c1ccc(-c2cccc(-c3nc4ccccc4nc3-c3ccc4ccc5c6ccccc6ccc5c4c3)c2)cc1 ; c1ccc(-c2cccc(-c3nc4c(ccc5ccccc54)nc3-c3ccc4ccc5c6ccccc6ccc5c4c3)c2)cc1 ; c1ccc(-c2cccc(-c3nc4c5ccccc5c5ccccc5c4nc3-c3ccc4ccc5c6ccccc6ccc5c4c3)c2)cc1]

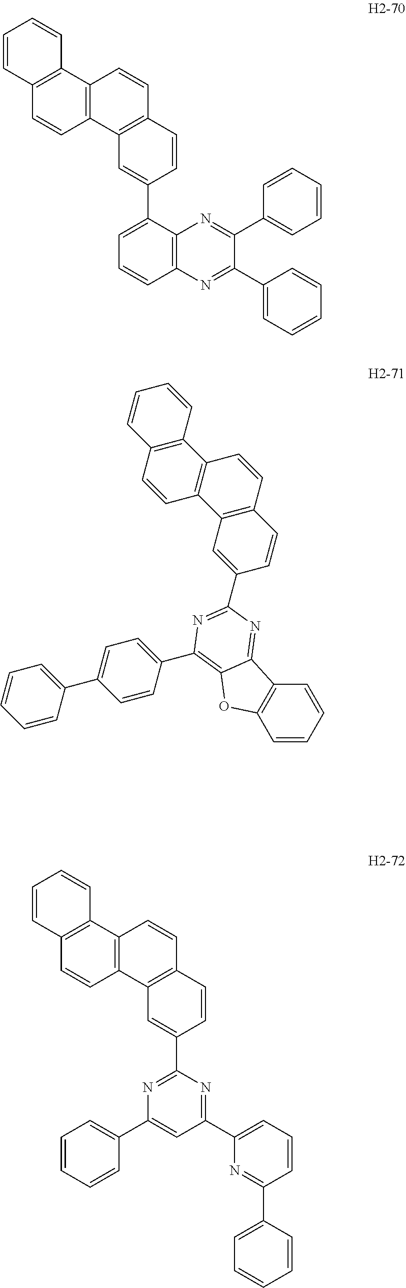 [SMILES: c1ccc(-c2nc3cccc(-c4ccc5ccc6c7ccccc7ccc6c5c4)c3nc2-c2ccccc2)cc1 ; c1ccc(-c2ccc(-c3nc(-c4ccc5ccc6c7ccccc7ccc6c5c4)nc4c3oc3ccccc34)cc2)cc1 ; c1ccc(-c2cccc(-c3cc(-c4ccccc4)nc(-c4ccc5ccc6c7ccccc7ccc6c5c4)n3)n2)cc1]

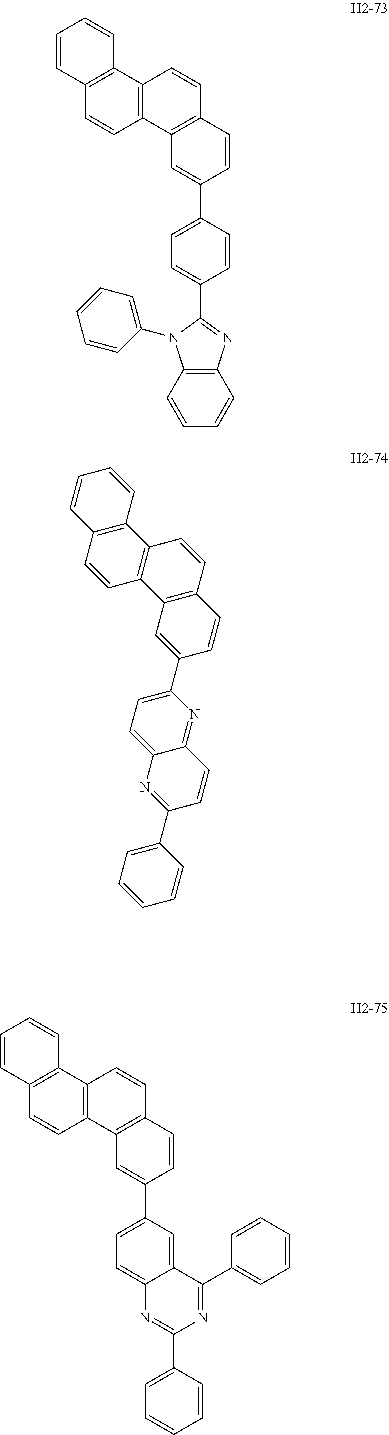 [SMILES: c1ccc(-n2c(-c3ccc(-c4ccc5ccc6c7ccccc7ccc6c5c4)cc3)nc3ccccc32)cc1 ; c1ccc(-c2ccc3nc(-c4ccc5ccc6c7ccccc7ccc6c5c4)ccc3n2)cc1 ; c1ccc(-c2nc(-c3ccccc3)c3cc(-c4ccc5ccc6c7ccccc7ccc6c5c4)ccc3n2)cc1]

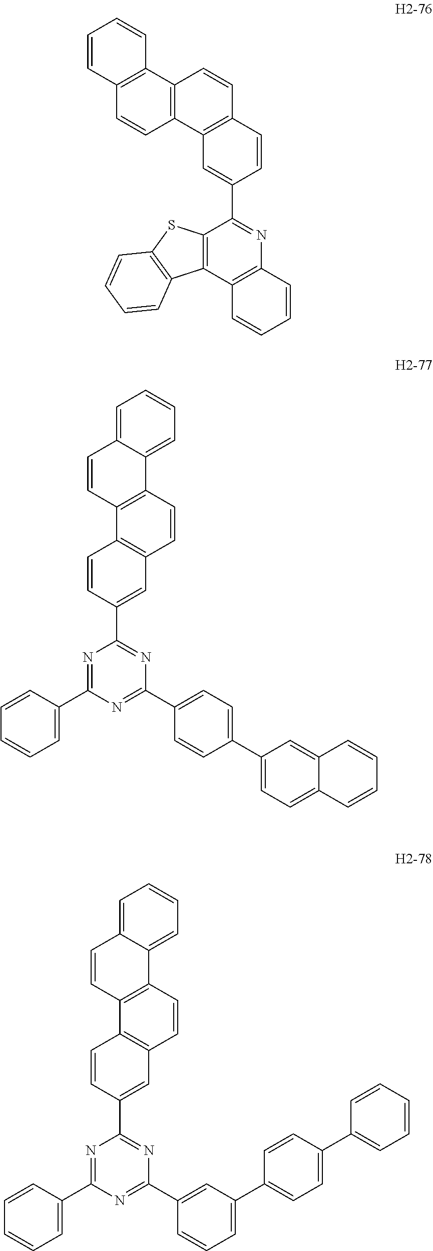 [SMILES: c1ccc2c(c1)ccc1c3cc(-c4nc5ccccc5c5c4sc4ccccc45)ccc3ccc21 ; c1ccc(-c2nc(-c3ccc(-c4ccc5ccccc5c4)cc3)nc(-c3ccc4c(ccc5c6ccccc6ccc45)c3)n2)cc1 ; c1ccc(-c2ccc(-c3cccc(-c4nc(-c5ccccc5)nc(-c5ccc6c(ccc7c8ccccc8ccc67)c5)n4)c3)cc2)cc1]

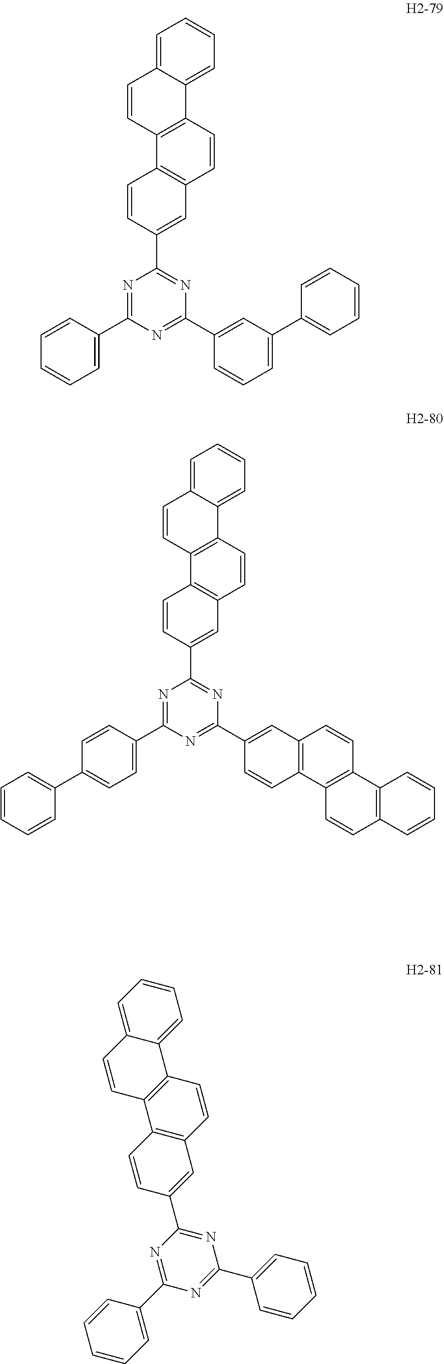 [SMILES: c1ccc(-c2cccc(-c3nc(-c4ccccc4)nc(-c4ccc5c(ccc6c7ccccc7ccc56)c4)n3)c2)cc1 ; c1ccc(-c2ccc(-c3nc(-c4ccc5c(ccc6c7ccccc7ccc56)c4)nc(-c4ccc5c(ccc6c7ccccc7ccc56)c4)n3)cc2)cc1 ; c1ccc(-c2nc(-c3ccccc3)nc(-c3ccc4c(ccc5c6ccccc6ccc45)c3)n2)cc1]

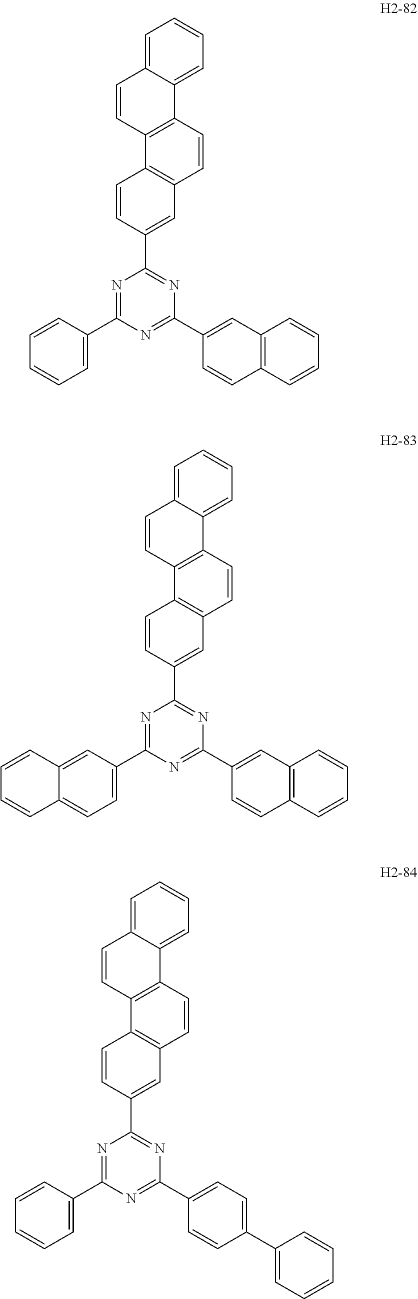 [SMILES: c1ccc(-c2nc(-c3ccc4ccccc4c3)nc(-c3ccc4c(ccc5c6ccccc6ccc45)c3)n2)cc1 ; c1ccc2cc(-c3nc(-c4ccc5ccccc5c4)nc(-c4ccc5c(ccc6c7ccccc7ccc56)c4)n3)ccc2c1 ; c1ccc(-c2ccc(-c3nc(-c4ccccc4)nc(-c4ccc5c(ccc6c7ccccc7ccc56)c4)n3)cc2)cc1]

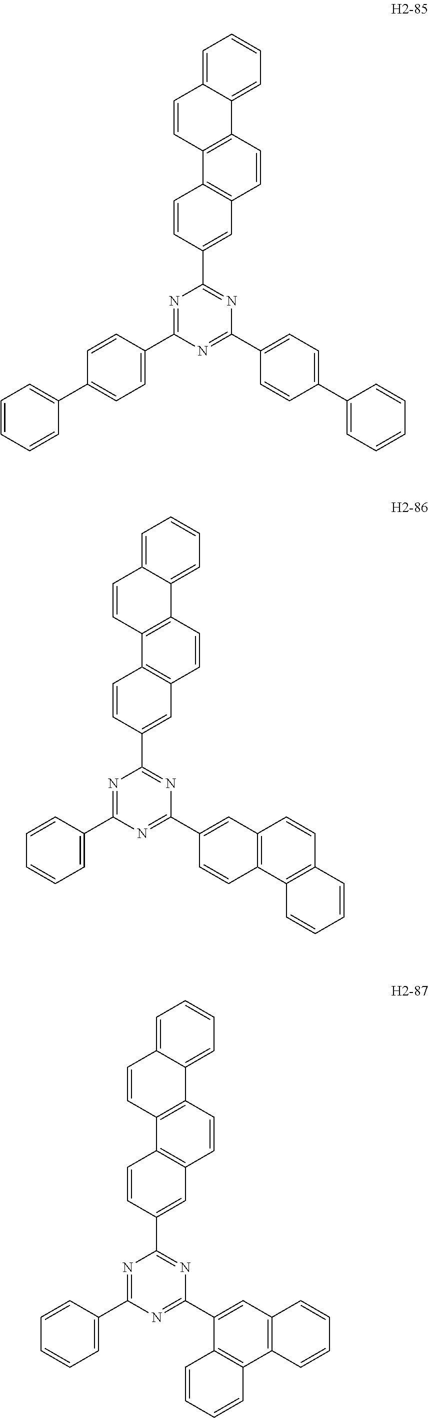 [SMILES: c1ccc(-c2ccc(-c3nc(-c4ccc(-c5ccccc5)cc4)nc(-c4ccc5c(ccc6c7ccccc7ccc56)c4)n3)cc2)cc1 ; c1ccc(-c2nc(-c3ccc4c(ccc5ccccc54)c3)nc(-c3ccc4c(ccc5c6ccccc6ccc45)c3)n2)cc1 ; c1ccc(-c2nc(-c3ccc4c(ccc5c6ccccc6ccc45)c3)nc(-c3cc4ccccc4c4ccccc34)n2)cc1]

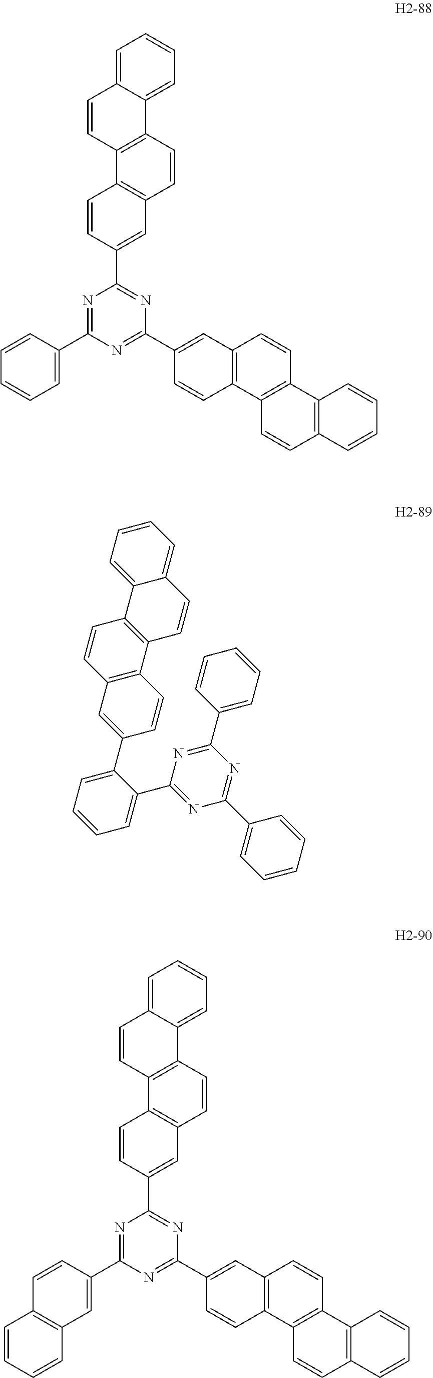 [SMILES: c1ccc(-c2nc(-c3ccc4c(ccc5c6ccccc6ccc45)c3)nc(-c3ccc4c(ccc5c6ccccc6ccc45)c3)n2)cc1 ; c1ccc(-c2nc(-c3ccccc3)nc(-c3ccccc3-c3ccc4c(ccc5c6ccccc6ccc45)c3)n2)cc1 ; c1ccc2cc(-c3nc(-c4ccc5c(ccc6c7ccccc7ccc56)c4)nc(-c4ccc5c(ccc6c7ccccc7ccc56)c4)n3)ccc2c1]

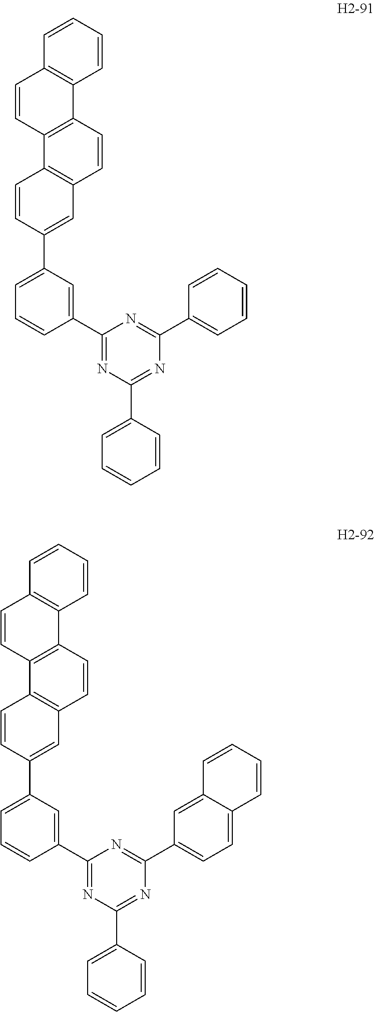 [SMILES: c1ccc(-c2nc(-c3ccccc3)nc(-c3cccc(-c4ccc5c(ccc6c7ccccc7ccc56)c4)c3)n2)cc1 ; c1ccc(-c2nc(-c3cccc(-c4ccc5c(ccc6c7ccccc7ccc56)c4)c3)nc(-c3ccc4ccccc4c3)n2)cc1]

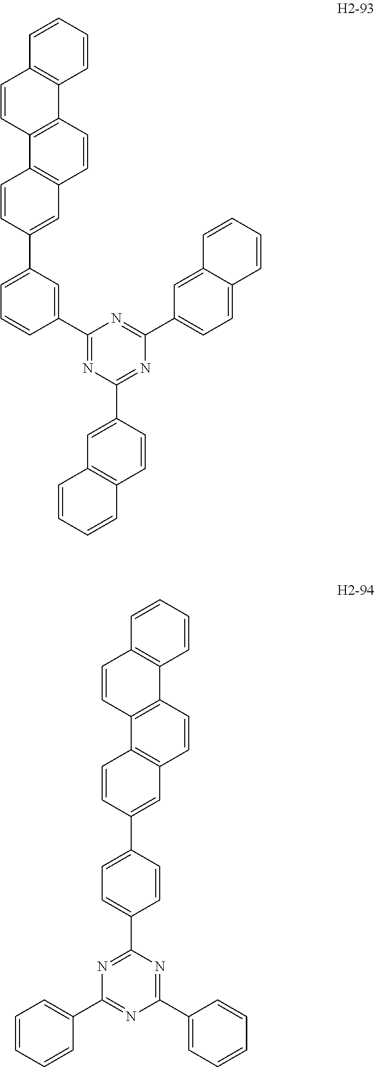 [SMILES: c1cc(-c2ccc3c(ccc4c5ccccc5ccc34)c2)cc(-c2nc(-c3ccc4ccccc4c3)nc(-c3ccc4ccccc4c3)n2)c1 ; c1ccc(-c2nc(-c3ccccc3)nc(-c3ccc(-c4ccc5c(ccc6c7ccccc7ccc56)c4)cc3)n2)cc1]

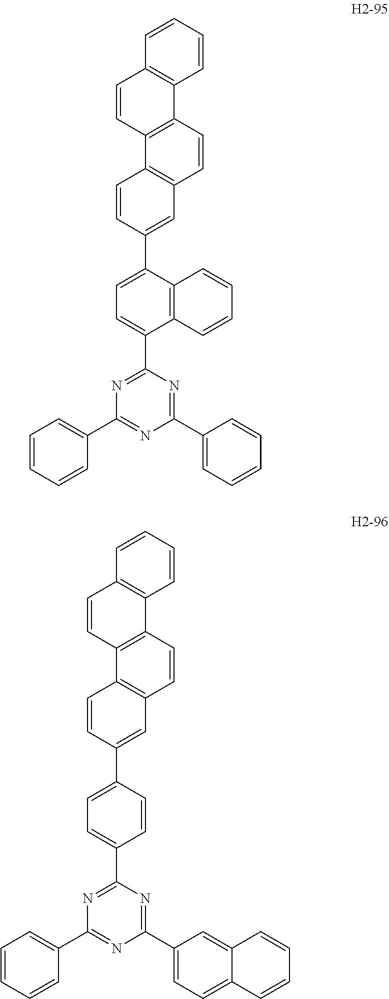 [SMILES: c1ccc(-c2nc(-c3ccccc3)nc(-c3ccc(-c4ccc5c(ccc6c7ccccc7ccc56)c4)c4ccccc34)n2)cc1 ; c1ccc(-c2nc(-c3ccc(-c4ccc5c(ccc6c7ccccc7ccc56)c4)cc3)nc(-c3ccc4ccccc4c3)n2)cc1]

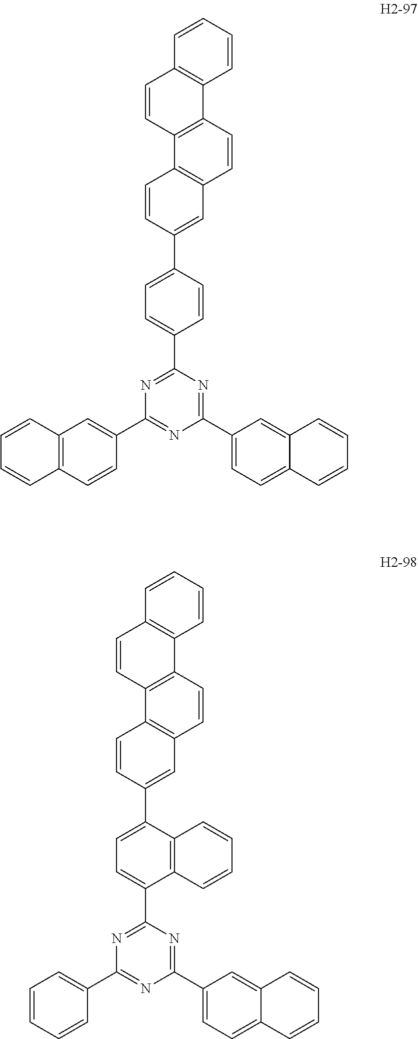 [SMILES: c1ccc2cc(-c3nc(-c4ccc(-c5ccc6c(ccc7c8ccccc8ccc67)c5)cc4)nc(-c4ccc5ccccc5c4)n3)ccc2c1 ; c1ccc(-c2nc(-c3ccc4ccccc4c3)nc(-c3ccc(-c4ccc5c(ccc6c7ccccc7ccc56)c4)c4ccccc34)n2)cc1]

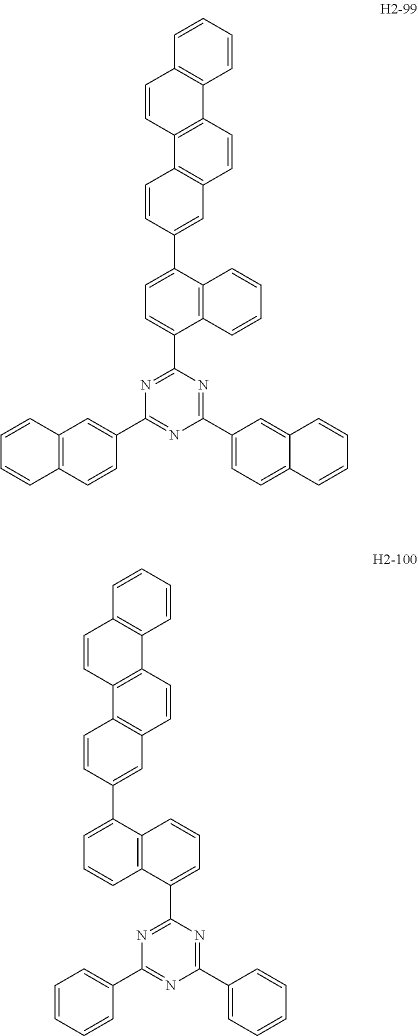 [SMILES: c1ccc2cc(-c3nc(-c4ccc5ccccc5c4)nc(-c4ccc(-c5ccc6c(ccc7c8ccccc8ccc67)c5)c5ccccc45)n3)ccc2c1 ; c1ccc(-c2nc(-c3ccccc3)nc(-c3cccc4c(-c5ccc6c(ccc7c8ccccc8ccc67)c5)cccc34)n2)cc1]

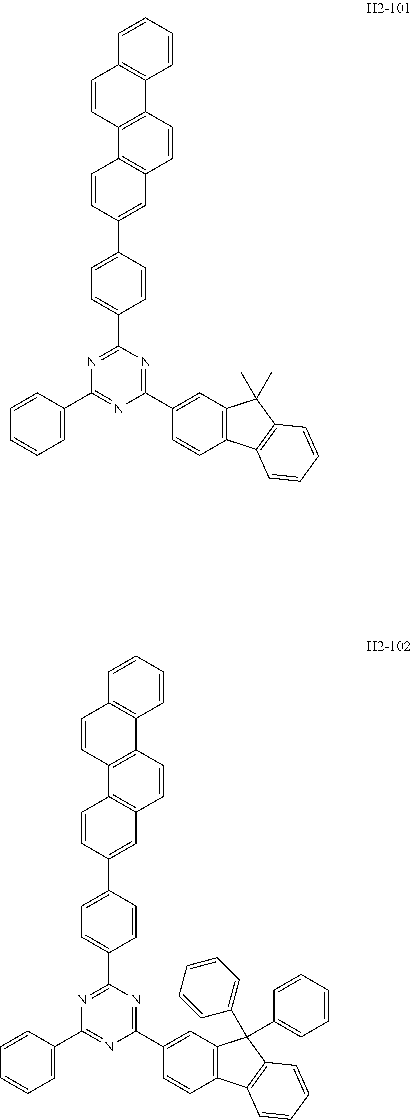 [SMILES: CC1(C)c2ccccc2-c2ccc(-c3nc(-c4ccccc4)nc(-c4ccc(-c5ccc6c(ccc7c8ccccc8ccc67)c5)cc4)n3)cc21 ; c1ccc(-c2nc(-c3ccc(-c4ccc5c(ccc6c7ccccc7ccc56)c4)cc3)nc(-c3ccc4c(c3)C(c3ccccc3)(c3ccccc3)c3ccccc3-4)n2)cc1]

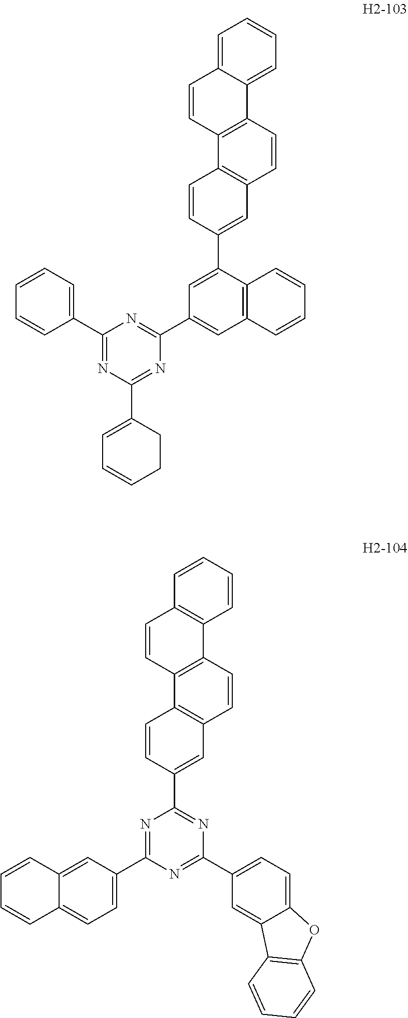 [SMILES: C1=CCCC(c2nc(-c3ccccc3)nc(-c3cc(-c4ccc5c(ccc6c7ccccc7ccc56)c4)c4ccccc4c3)n2)=C1 ; c1ccc2cc(-c3nc(-c4ccc5c(ccc6c7ccccc7ccc56)c4)nc(-c4ccc5oc6ccccc6c5c4)n3)ccc2c1]

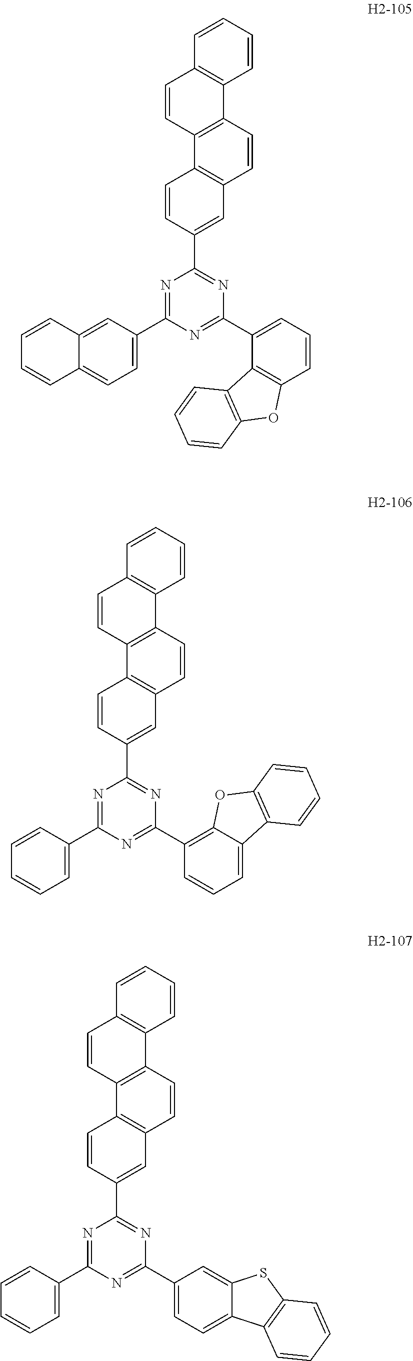 [SMILES: c1ccc2cc(-c3nc(-c4ccc5c(ccc6c7ccccc7ccc56)c4)nc(-c4cccc5oc6ccccc6c45)n3)ccc2c1 ; c1ccc(-c2nc(-c3ccc4c(ccc5c6ccccc6ccc45)c3)nc(-c3cccc4c3oc3ccccc34)n2)cc1 ; c1ccc(-c2nc(-c3ccc4c(ccc5c6ccccc6ccc45)c3)nc(-c3ccc4c(c3)sc3ccccc34)n2)cc1]

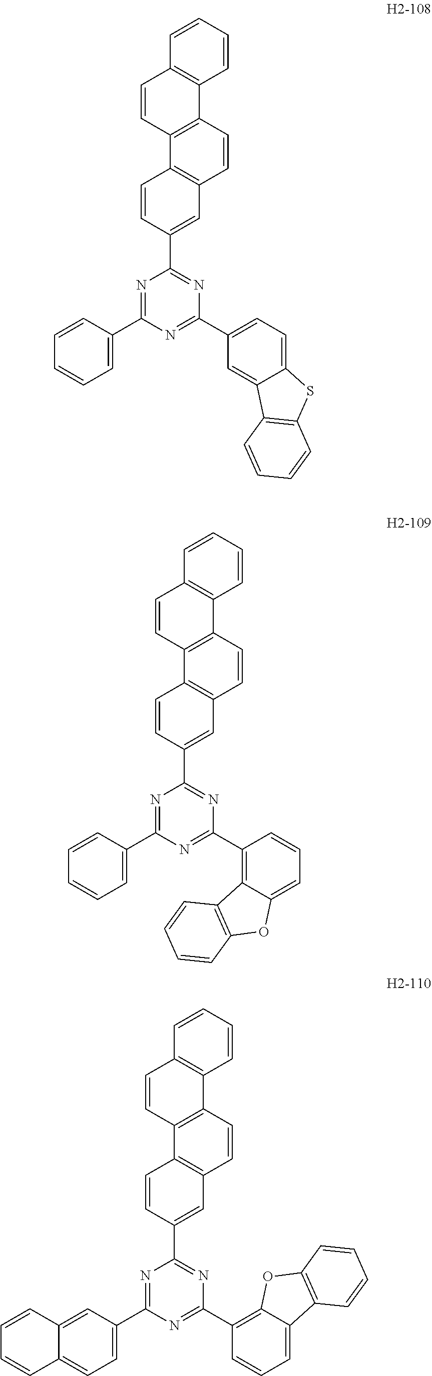 [SMILES: c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5c4oc4ccccc45)n3)ccc2c1]

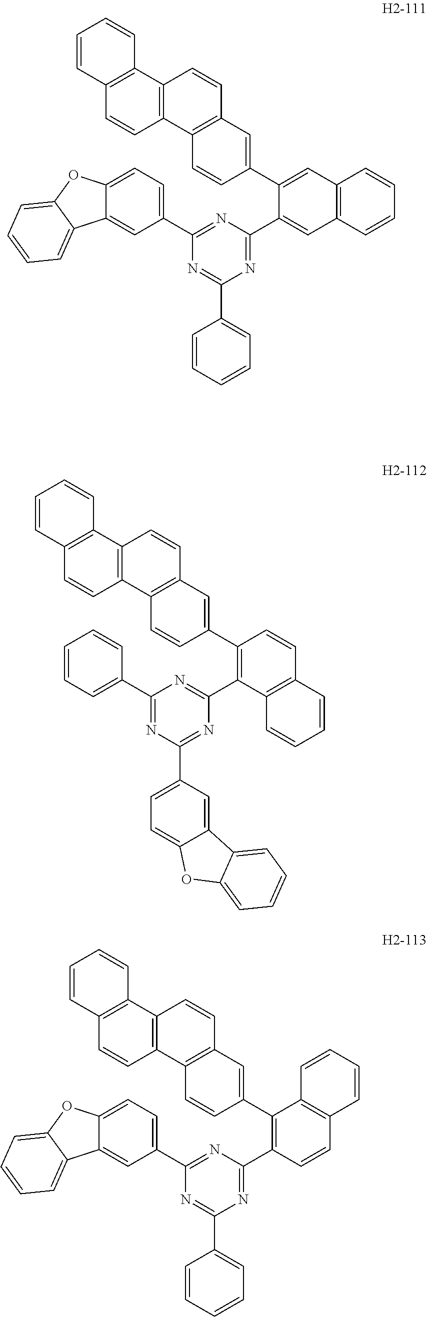 [SMILES: c1ccc(-c2nc(-c3ccc4oc5ccccc5c4c3)nc(-c3cc4ccccc4cc3-c3ccc4c(ccc5c6ccccc6ccc45)c3)n2)cc1 ; c1ccc(-c2nc(-c3ccc4oc5ccccc5c4c3)nc(-c3c(-c4ccc5c(ccc6c7ccccc7ccc56)c4)ccc4ccccc34)n2)cc1 ; c1ccc(-c2nc(-c3ccc4oc5ccccc5c4c3)nc(-c3ccc4ccccc4c3-c3ccc4c(ccc5c6ccccc6ccc45)c3)n2)cc1]

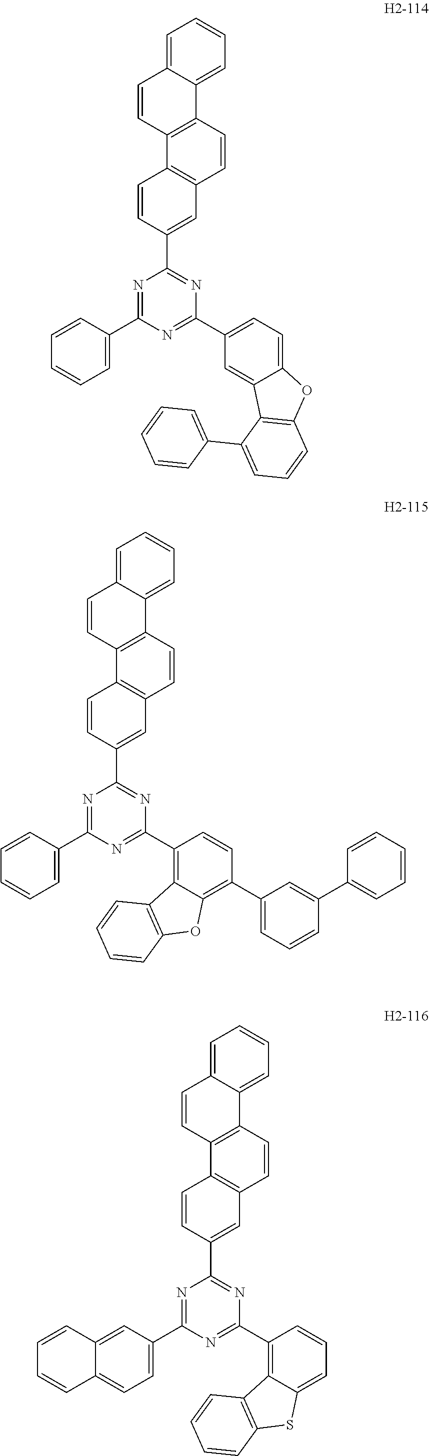 [SMILES: c1ccc(-c2nc(-c3ccc4c(ccc5c6ccccc6ccc45)c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6c(ccc7c8ccccc8ccc67)c5)n4)c4c3oc3ccccc34)c2)cc1 ; c1ccc2cc(-c3nc(-c4ccc5c(ccc6c7ccccc7ccc56)c4)nc(-c4cccc5sc6ccccc6c45)n3)ccc2c1]

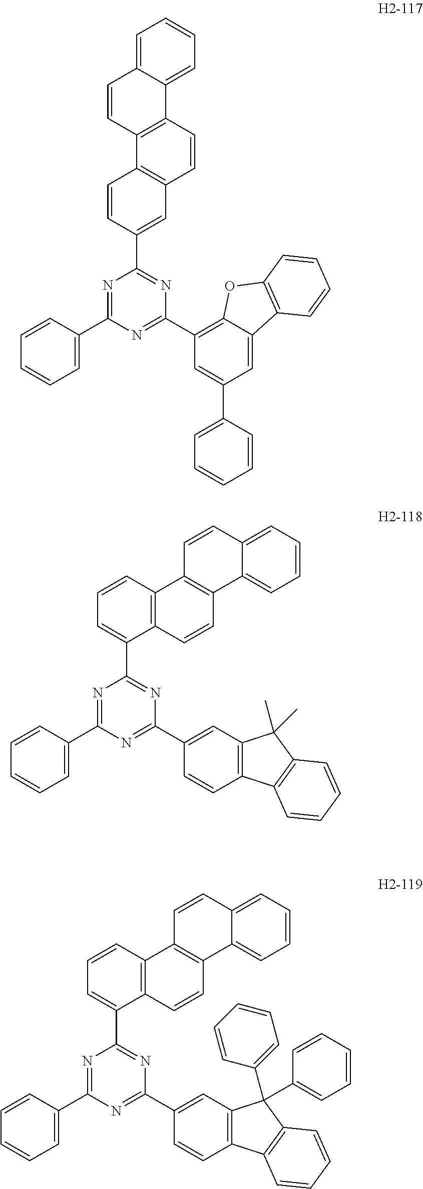

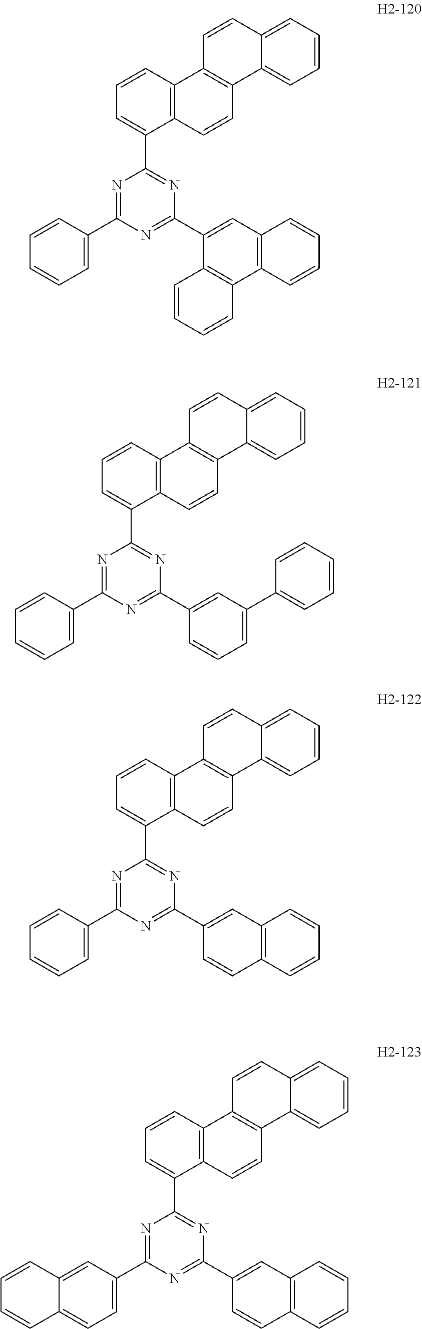 [SMILES: c1ccc(-c2nc(-c3cc4ccccc4c4ccccc34)nc(-c3cccc4c3ccc3c5ccccc5ccc43)n2)cc1 ; c1ccc(-c2cccc(-c3nc(-c4ccccc4)nc(-c4cccc5c4ccc4c6ccccc6ccc54)n3)c2)cc1 ; c1ccc(-c2nc(-c3ccc4ccccc4c3)nc(-c3cccc4c3ccc3c5ccccc5ccc43)n2)cc1 ; c1ccc2cc(-c3nc(-c4ccc5ccccc5c4)nc(-c4cccc5c4ccc4c6ccccc6ccc54)n3)ccc2c1]

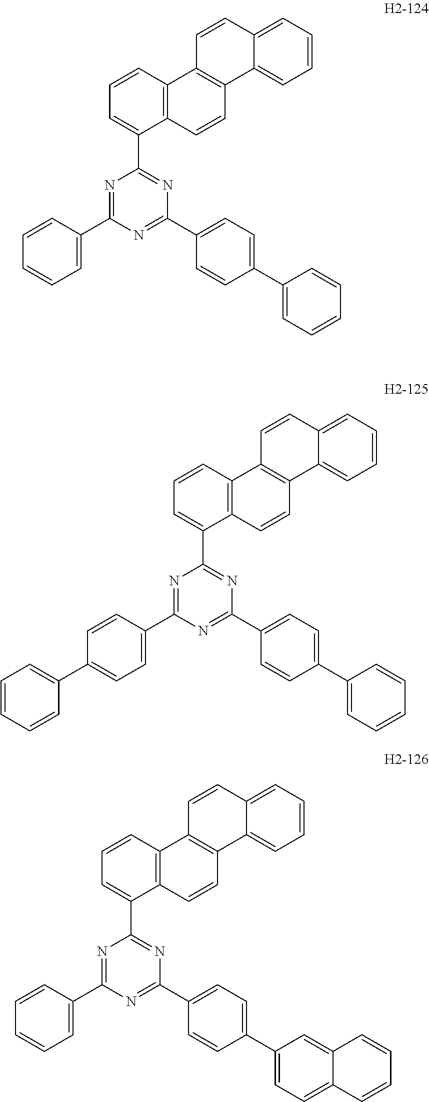 [SMILES: c1ccc(-c2ccc(-c3nc(-c4ccccc4)nc(-c4cccc5c4ccc4c6ccccc6ccc54)n3)cc2)cc1 ; c1ccc(-c2ccc(-c3nc(-c4ccc(-c5ccccc5)cc4)nc(-c4cccc5c4ccc4c6ccccc6ccc54)n3)cc2)cc1 ; c1ccc(-c2nc(-c3ccc(-c4ccc5ccccc5c4)cc3)nc(-c3cccc4c3ccc3c5ccccc5ccc43)n2)cc1]

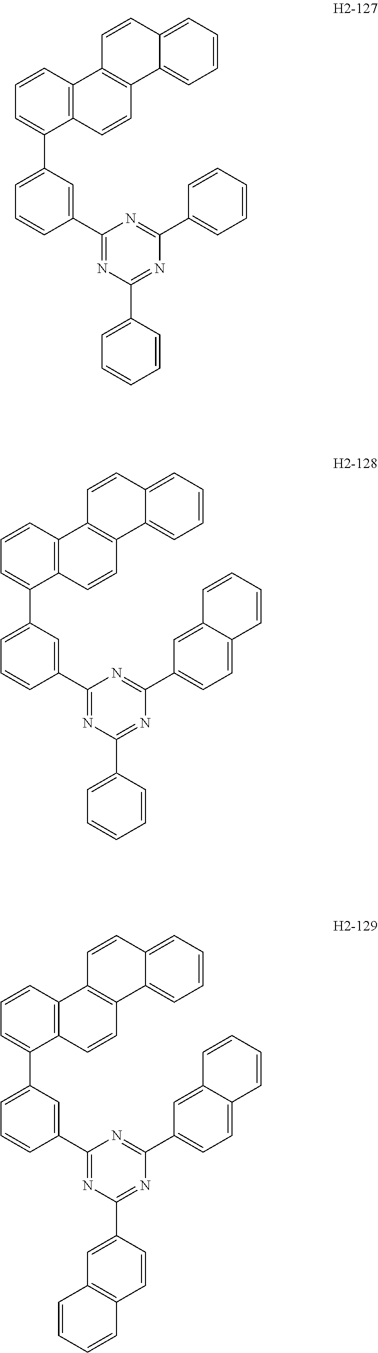 [SMILES: c1ccc(-c2nc(-c3ccccc3)nc(-c3cccc(-c4cccc5c4ccc4c6ccccc6ccc54)c3)n2)cc1 ; c1ccc(-c2nc(-c3cccc(-c4cccc5c4ccc4c6ccccc6ccc54)c3)nc(-c3ccc4ccccc4c3)n2)cc1 ; c1cc(-c2nc(-c3ccc4ccccc4c3)nc(-c3ccc4ccccc4c3)n2)cc(-c2cccc3c2ccc2c4ccccc4ccc32)c1]

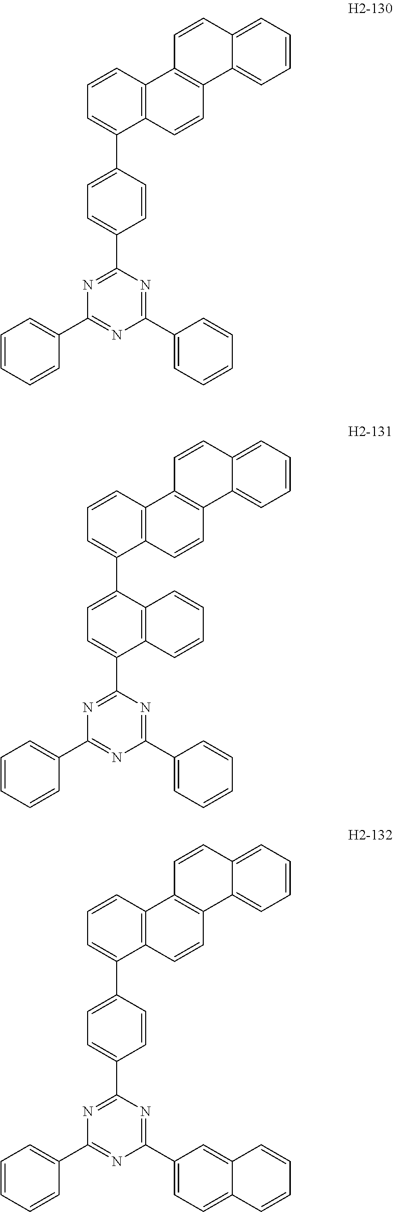

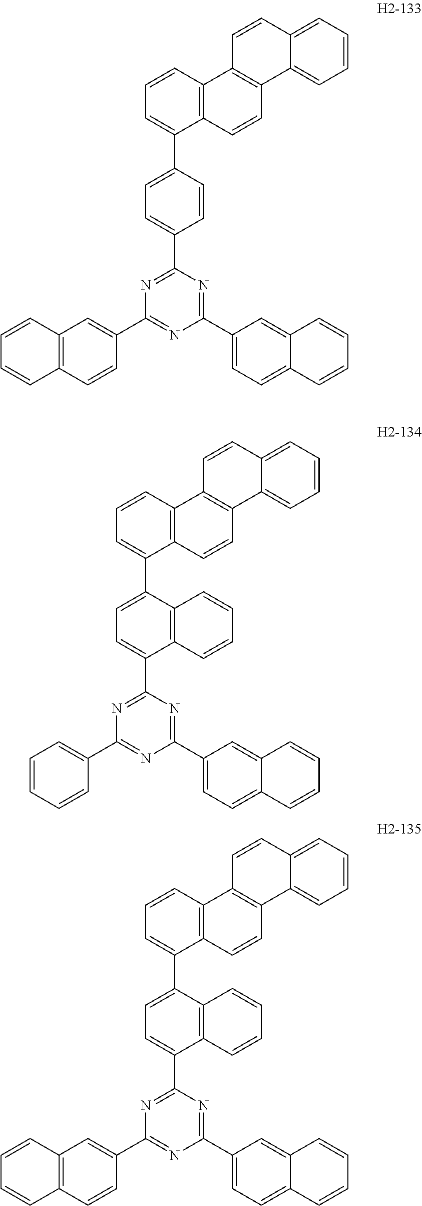

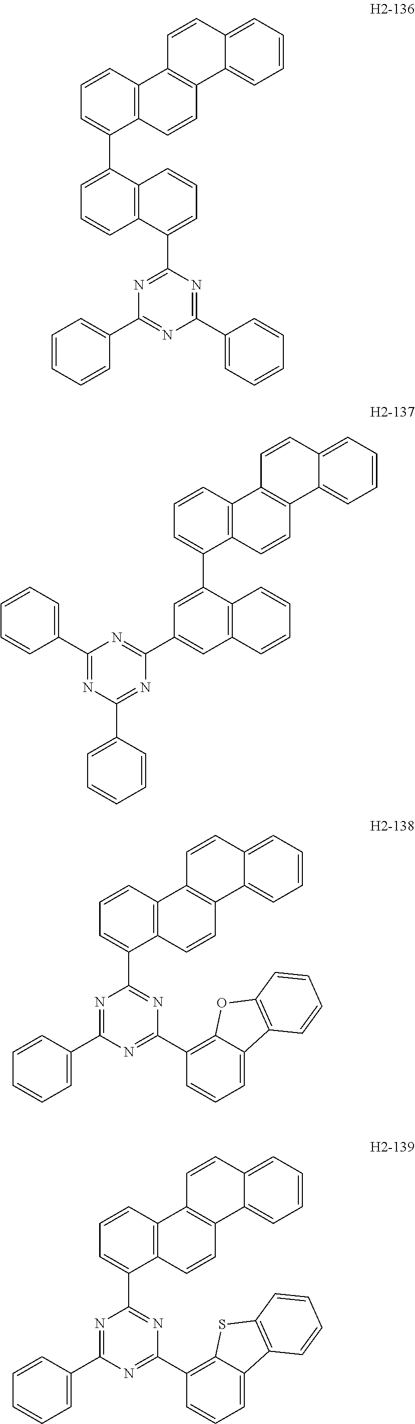 [SMILES: c1ccc(-c2nc(-c3ccccc3)nc(-c3cccc4c(-c5cccc6c5ccc5c7ccccc7ccc65)cccc34)n2)cc1 ; c1ccc(-c2nc(-c3ccccc3)nc(-c3cc(-c4cccc5c4ccc4c6ccccc6ccc54)c4ccccc4c3)n2)cc1 ; c1ccc(-c2nc(-c3cccc4c3ccc3c5ccccc5ccc43)nc(-c3cccc4c3oc3ccccc34)n2)cc1 ; c1ccc(-c2nc(-c3cccc4c3ccc3c5ccccc5ccc43)nc(-c3cccc4c3sc3ccccc34)n2)cc1]

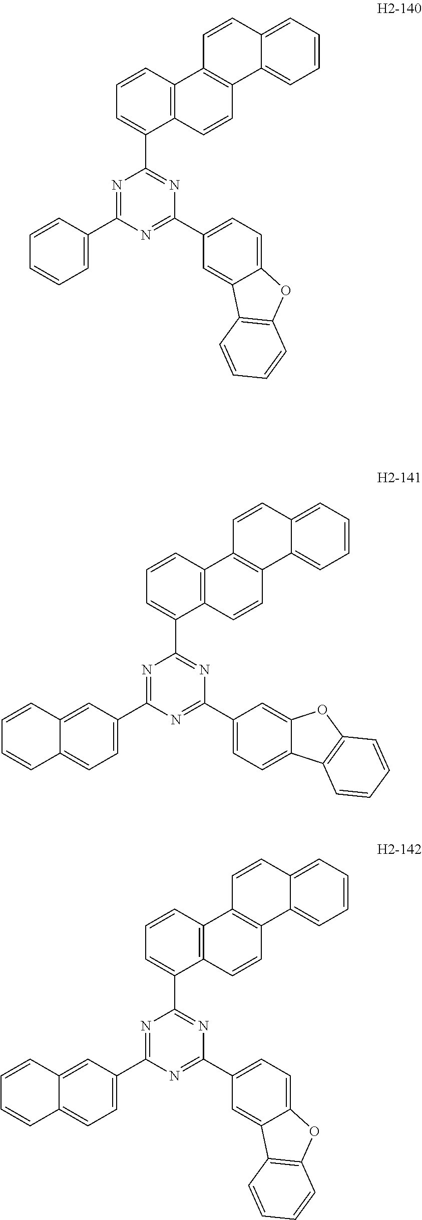 [SMILES: c1ccc(-c2nc(-c3ccc4oc5ccccc5c4c3)nc(-c3cccc4c3ccc3c5ccccc5ccc43)n2)cc1 ; c1ccc2cc(-c3nc(-c4ccc5c(c4)oc4ccccc45)nc(-c4cccc5c4ccc4c6ccccc6ccc54)n3)ccc2c1 ; c1ccc2cc(-c3nc(-c4ccc5oc6ccccc6c5c4)nc(-c4cccc5c4ccc4c6ccccc6ccc54)n3)ccc2c1]

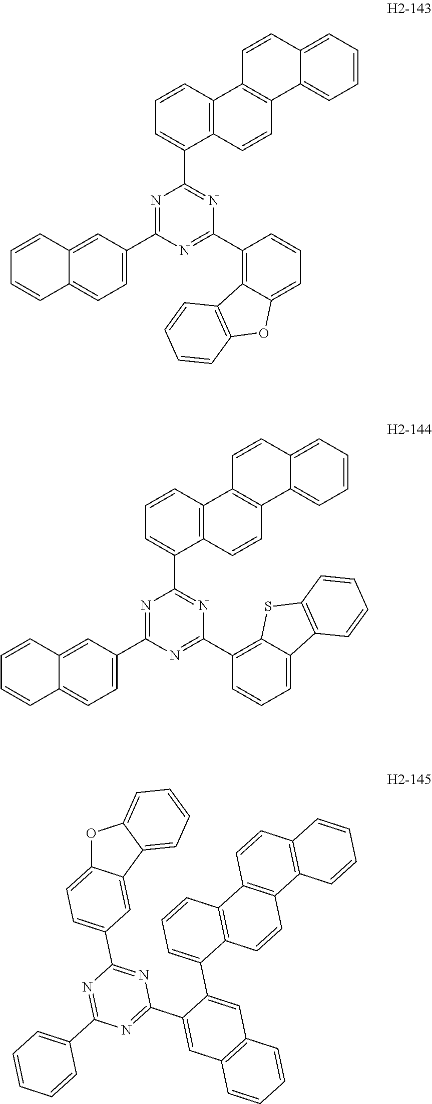 [SMILES: c1ccc2cc(-c3nc(-c4cccc5c4ccc4c6ccccc6ccc54)nc(-c4cccc5oc6ccccc6c45)n3)ccc2c1 ; c1ccc2cc(-c3nc(-c4cccc5c4ccc4c6ccccc6ccc54)nc(-c4cccc5c4sc4ccccc45)n3)ccc2c1 ; c1ccc(-c2nc(-c3ccc4oc5ccccc5c4c3)nc(-c3cc4ccccc4cc3-c3cccc4c3ccc3c5ccccc5ccc43)n2)cc1]

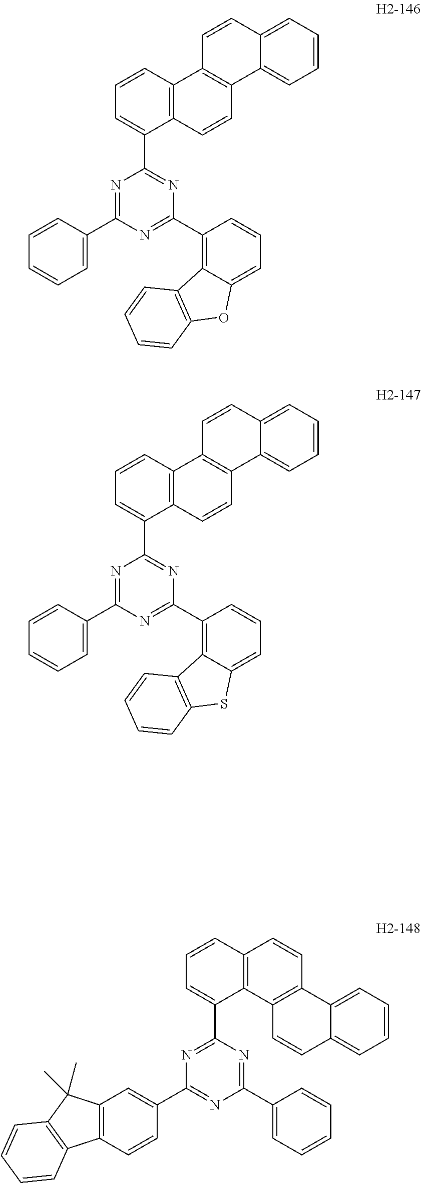 [SMILES: c1ccc(-c2nc(-c3cccc4c3ccc3c5ccccc5ccc43)nc(-c3cccc4oc5ccccc5c34)n2)cc1 ; c1ccc(-c2nc(-c3cccc4c3ccc3c5ccccc5ccc43)nc(-c3cccc4sc5ccccc5c34)n2)cc1 ; CC1(C)c2ccccc2-c2ccc(-c3nc(-c4ccccc4)nc(-c4cccc5ccc6c7ccccc7ccc6c45)n3)cc21]

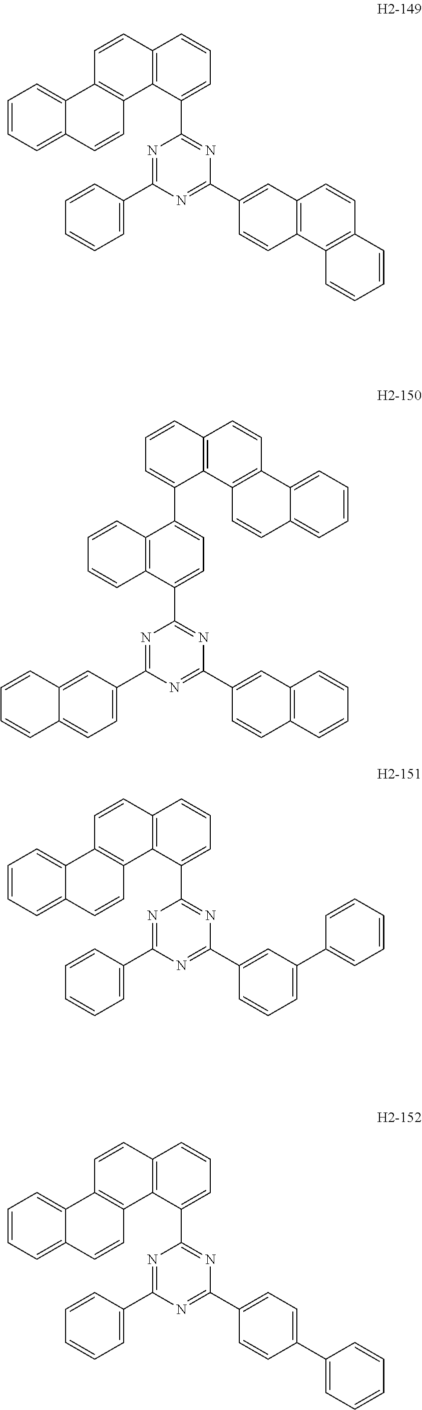 [SMILES: c1ccc(-c2nc(-c3ccc4c(ccc5ccccc54)c3)nc(-c3cccc4ccc5c6ccccc6ccc5c34)n2)cc1 ; c1ccc2cc(-c3nc(-c4ccc5ccccc5c4)nc(-c4ccc(-c5cccc6ccc7c8ccccc8ccc7c56)c5ccccc45)n3)ccc2c1 ; c1ccc(-c2cccc(-c3nc(-c4ccccc4)nc(-c4cccc5ccc6c7ccccc7ccc6c45)n3)c2)cc1 ; c1ccc(-c2ccc(-c3nc(-c4ccccc4)nc(-c4cccc5ccc6c7ccccc7ccc6c45)n3)cc2)cc1]

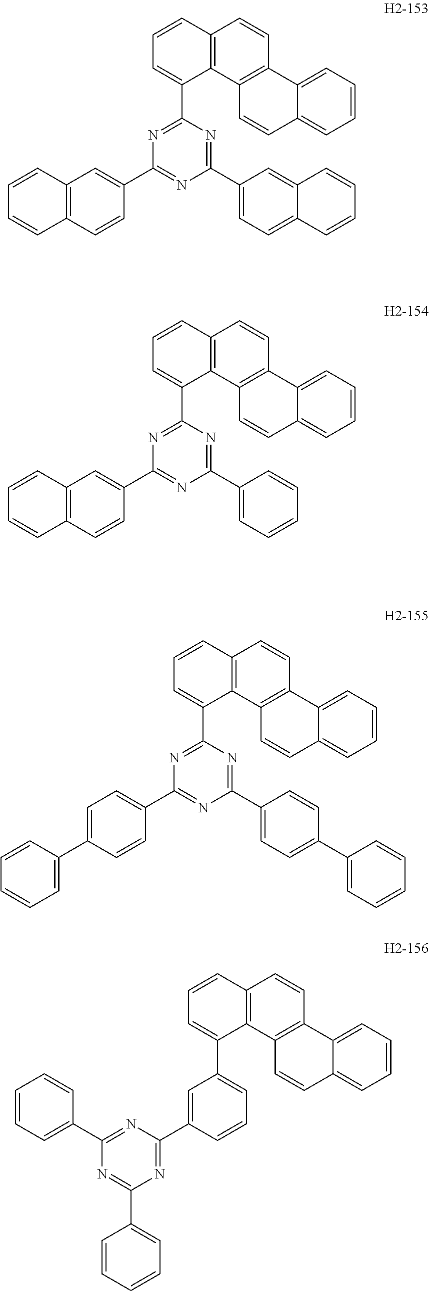 [SMILES: c1ccc2cc(-c3nc(-c4ccc5ccccc5c4)nc(-c4cccc5ccc6c7ccccc7ccc6c45)n3)ccc2c1 ; c1ccc(-c2nc(-c3ccc4ccccc4c3)nc(-c3cccc4ccc5c6ccccc6ccc5c34)n2)cc1 ; c1ccc(-c2ccc(-c3nc(-c4ccc(-c5ccccc5)cc4)nc(-c4cccc5ccc6c7ccccc7ccc6c45)n3)cc2)cc1 ; c1ccc(-c2nc(-c3ccccc3)nc(-c3cccc(-c4cccc5ccc6c7ccccc7ccc6c45)c3)n2)cc1]

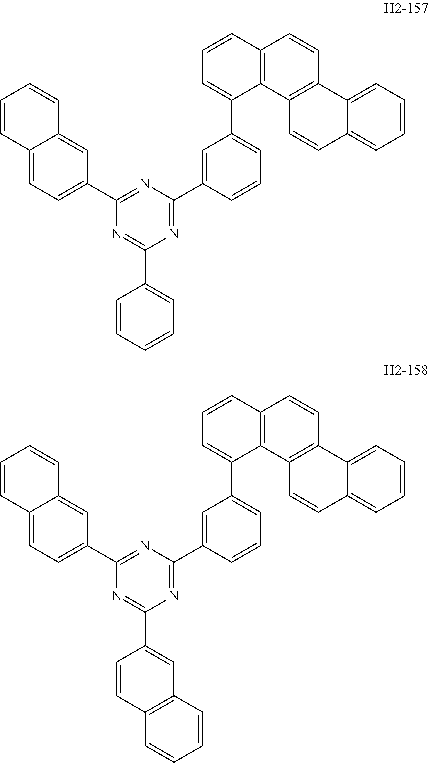 [SMILES: c1ccc(-c2nc(-c3cccc(-c4cccc5ccc6c7ccccc7ccc6c45)c3)nc(-c3ccc4ccccc4c3)n2)cc1 ; c1cc(-c2nc(-c3ccc4ccccc4c3)nc(-c3ccc4ccccc4c3)n2)cc(-c2cccc3ccc4c5ccccc5ccc4c23)c1]

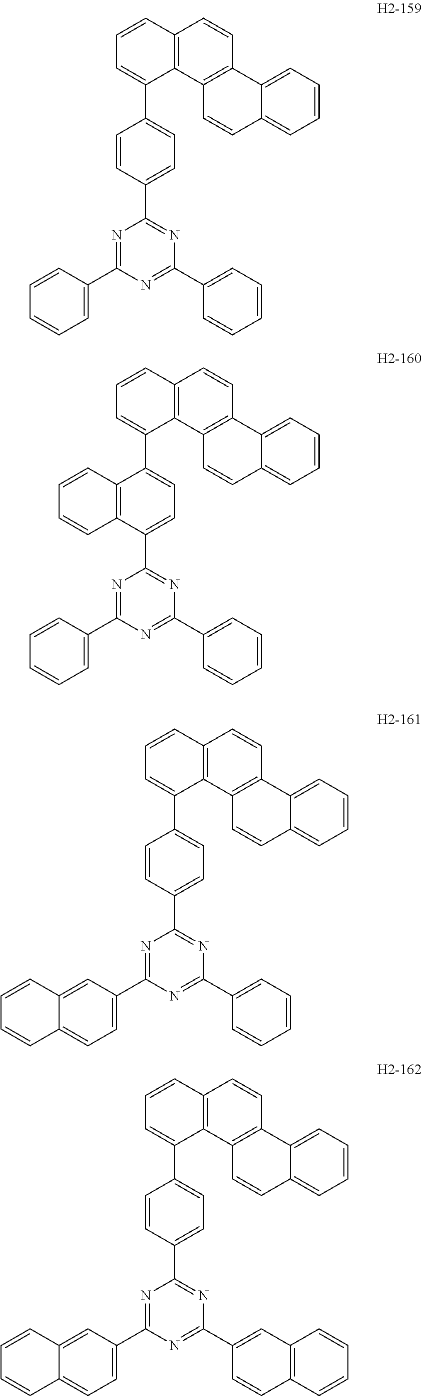

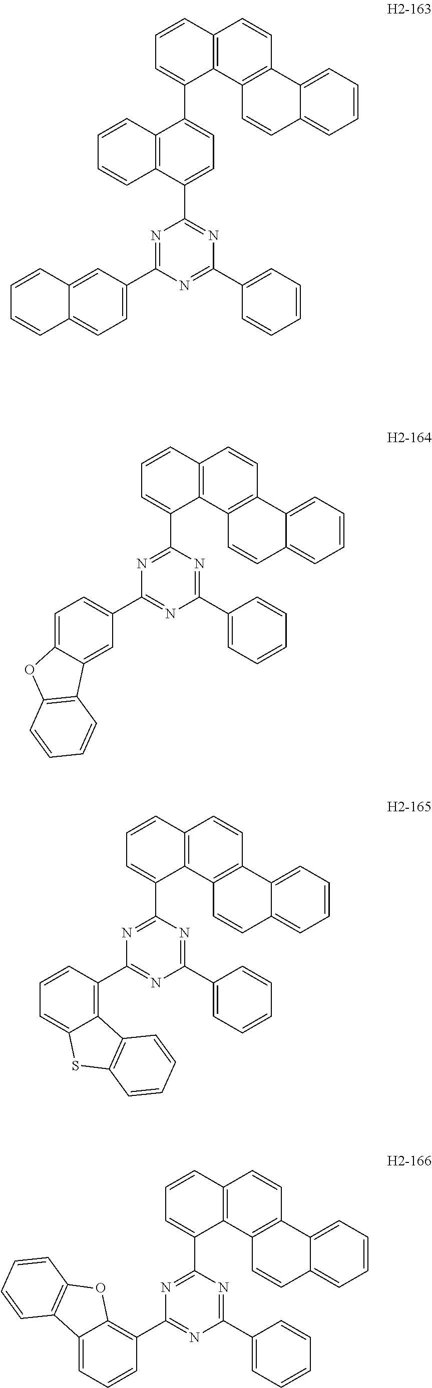 [SMILES: c1ccc(-c2nc(-c3ccc4ccccc4c3)nc(-c3ccc(-c4cccc5ccc6c7ccccc7ccc6c45)c4ccccc34)n2)cc1 ; c1ccc(-c2nc(-c3ccc4oc5ccccc5c4c3)nc(-c3cccc4ccc5c6ccccc6ccc5c34)n2)cc1 ; c1ccc(-c2nc(-c3cccc4ccc5c6ccccc6ccc5c34)nc(-c3cccc4sc5ccccc5c34)n2)cc1 ; c1ccc(-c2nc(-c3cccc4c3oc3ccccc34)nc(-c3cccc4ccc5c6ccccc6ccc5c34)n2)cc1]

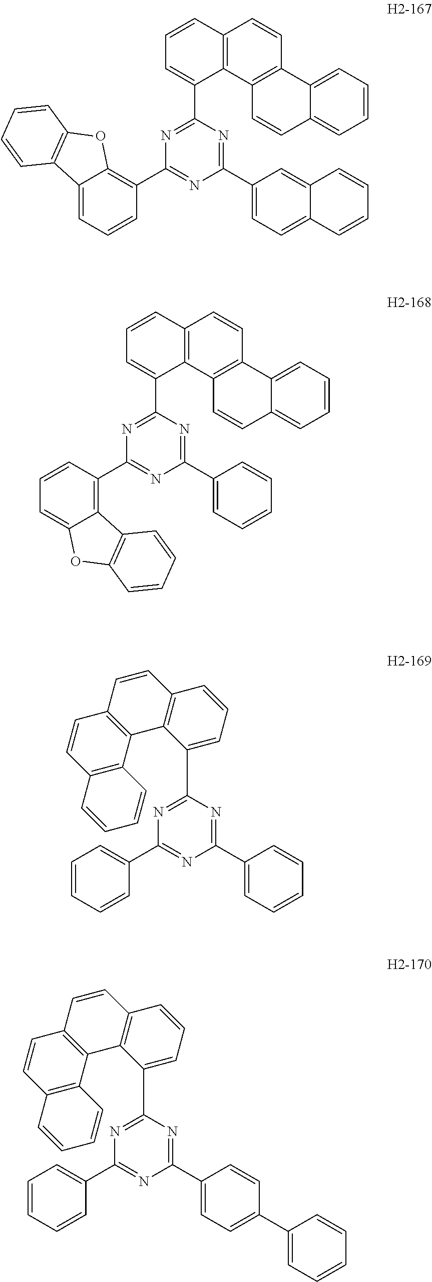 [SMILES: c1ccc2cc(-c3nc(-c4cccc5c4oc4ccccc45)nc(-c4cccc5ccc6c7ccccc7ccc6c45)n3)ccc2c1 ; c1ccc(-c2nc(-c3cccc4ccc5c6ccccc6ccc5c34)nc(-c3cccc4oc5ccccc5c34)n2)cc1 ; c1ccc(-c2nc(-c3ccccc3)nc(-c3cccc4ccc5ccc6ccccc6c5c34)n2)cc1 ; c1ccc(-c2ccc(-c3nc(-c4ccccc4)nc(-c4cccc5ccc6ccc7ccccc7c6c45)n3)cc2)cc1]

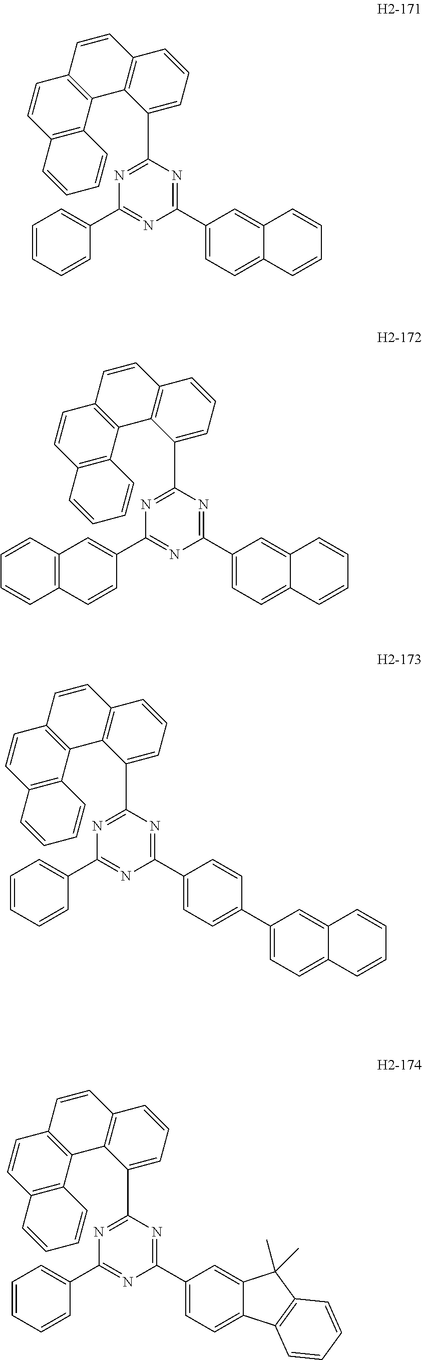 [SMILES: c1ccc(-c2nc(-c3ccc4ccccc4c3)nc(-c3cccc4ccc5ccc6ccccc6c5c34)n2)cc1 ; c1ccc2cc(-c3nc(-c4ccc5ccccc5c4)nc(-c4cccc5ccc6ccc7ccccc7c6c45)n3)ccc2c1 ; c1ccc(-c2nc(-c3ccc(-c4ccc5ccccc5c4)cc3)nc(-c3cccc4ccc5ccc6ccccc6c5c34)n2)cc1 ; CC1(C)c2ccccc2-c2ccc(-c3nc(-c4ccccc4)nc(-c4cccc5ccc6ccc7ccccc7c6c45)n3)cc21]

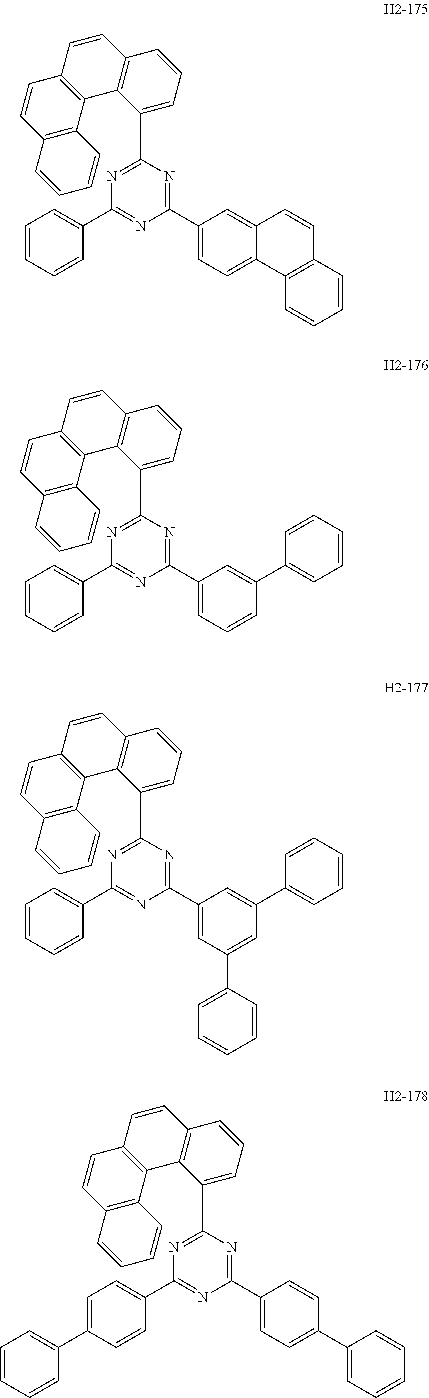 [SMILES: c1ccc(-c2nc(-c3ccc4c(ccc5ccccc54)c3)nc(-c3cccc4ccc5ccc6ccccc6c5c34)n2)cc1 ; c1ccc(-c2cccc(-c3nc(-c4ccccc4)nc(-c4cccc5ccc6ccc7ccccc7c6c45)n3)c2)cc1 ; c1ccc(-c2cc(-c3ccccc3)cc(-c3nc(-c4ccccc4)nc(-c4cccc5ccc6ccc7ccccc7c6c45)n3)c2)cc1 ; c1ccc(-c2ccc(-c3nc(-c4ccc(-c5ccccc5)cc4)nc(-c4cccc5ccc6ccc7ccccc7c6c45)n3)cc2)cc1]

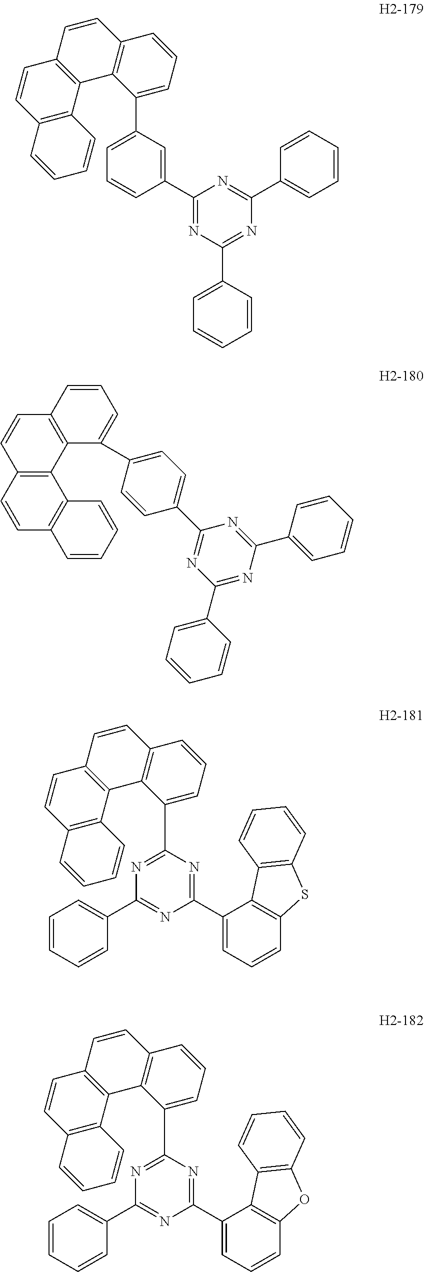 [SMILES: c1ccc(-c2nc(-c3ccccc3)nc(-c3cccc(-c4cccc5ccc6ccc7ccccc7c6c45)c3)n2)cc1 ; c1ccc(-c2nc(-c3ccccc3)nc(-c3ccc(-c4cccc5ccc6ccc7ccccc7c6c45)cc3)n2)cc1 ; c1ccc(-c2nc(-c3cccc4sc5ccccc5c34)nc(-c3cccc4ccc5ccc6ccccc6c5c34)n2)cc1 ; c1ccc(-c2nc(-c3cccc4oc5ccccc5c34)nc(-c3cccc4ccc5ccc6ccccc6c5c34)n2)cc1]

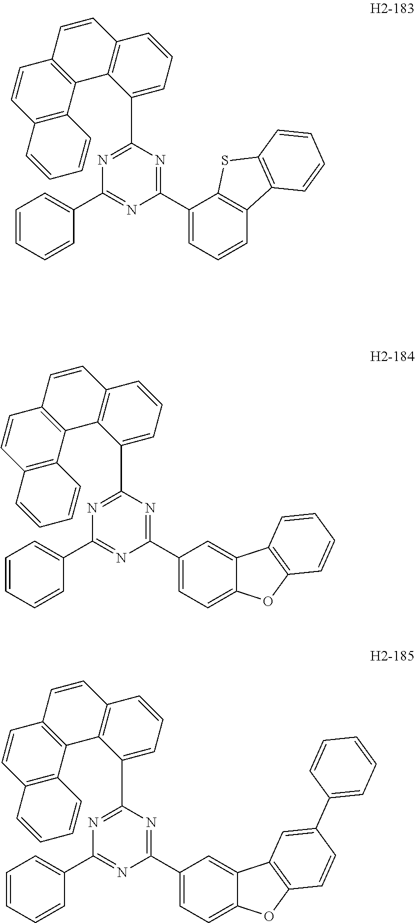 [SMILES: c1ccc(-c2nc(-c3cccc4c3sc3ccccc34)nc(-c3cccc4ccc5ccc6ccccc6c5c34)n2)cc1 ; c1ccc(-c2nc(-c3ccc4oc5ccccc5c4c3)nc(-c3cccc4ccc5ccc6ccccc6c5c34)n2)cc1 ; c1ccc(-c2ccc3oc4ccc(-c5nc(-c6ccccc6)nc(-c6cccc7ccc8ccc9ccccc9c8c67)n5)cc4c3c2)cc1]

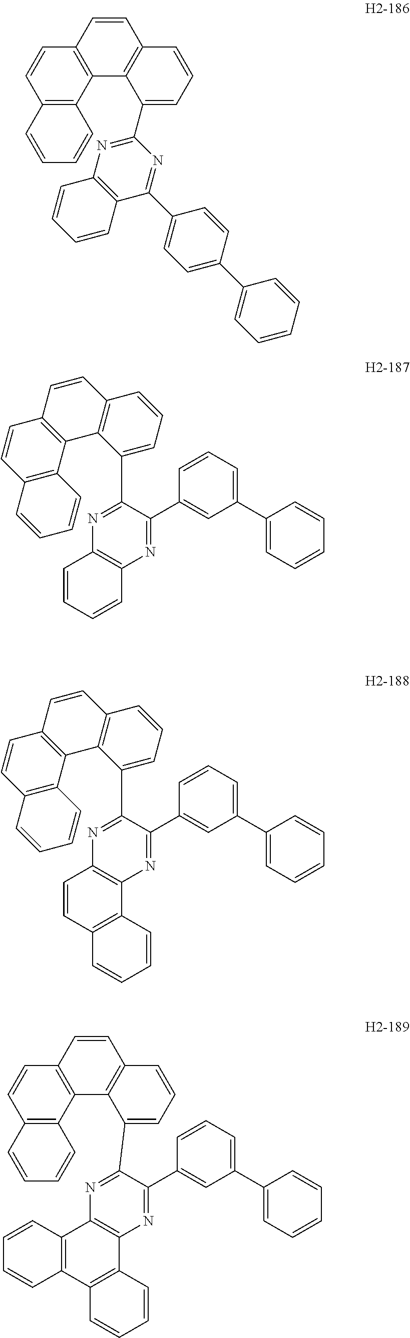 [SMILES: c1ccc(-c2ccc(-c3nc(-c4cccc5ccc6ccc7ccccc7c6c45)nc4ccccc34)cc2)cc1 ; c1ccc(-c2cccc(-c3nc4ccccc4nc3-c3cccc4ccc5ccc6ccccc6c5c34)c2)cc1 ; c1ccc(-c2cccc(-c3nc4c(ccc5ccccc54)nc3-c3cccc4ccc5ccc6ccccc6c5c34)c2)cc1 ; c1ccc(-c2cccc(-c3nc4c5ccccc5c5ccccc5c4nc3-c3cccc4ccc5ccc6ccccc6c5c34)c2)cc1]

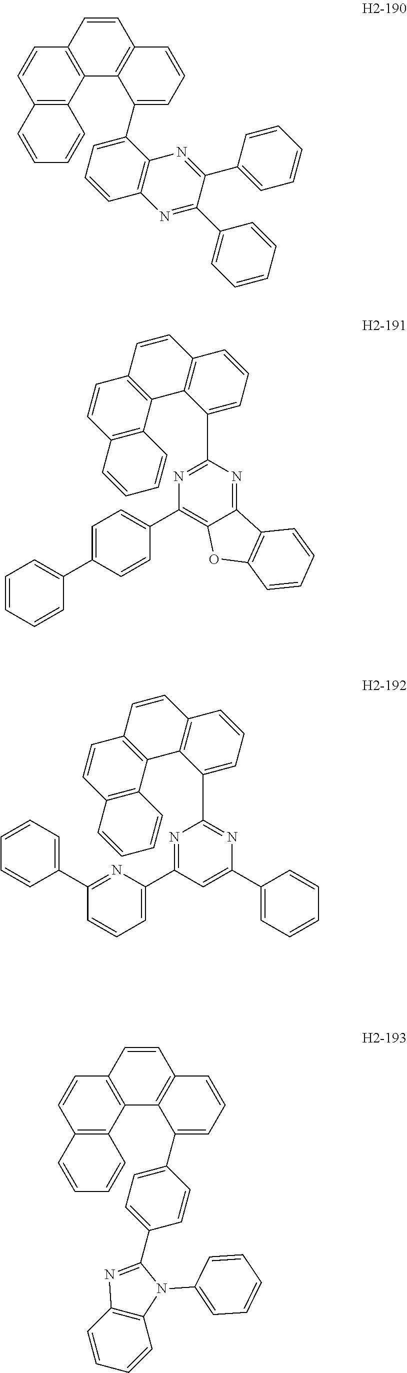 [SMILES: c1ccc(-c2nc3cccc(-c4cccc5ccc6ccc7ccccc7c6c45)c3nc2-c2ccccc2)cc1 ; c1ccc(-c2ccc(-c3nc(-c4cccc5ccc6ccc7ccccc7c6c45)nc4c3oc3ccccc34)cc2)cc1 ; c1ccc(-c2cccc(-c3cc(-c4ccccc4)nc(-c4cccc5ccc6ccc7ccccc7c6c45)n3)n2)cc1 ; c1ccc(-n2c(-c3ccc(-c4cccc5ccc6ccc7ccccc7c6c45)cc3)nc3ccccc32)cc1]

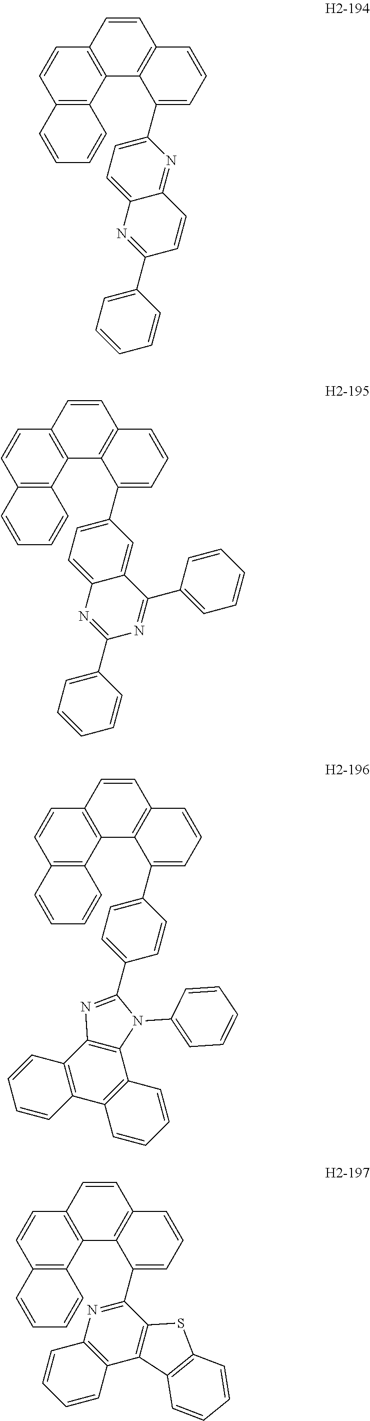

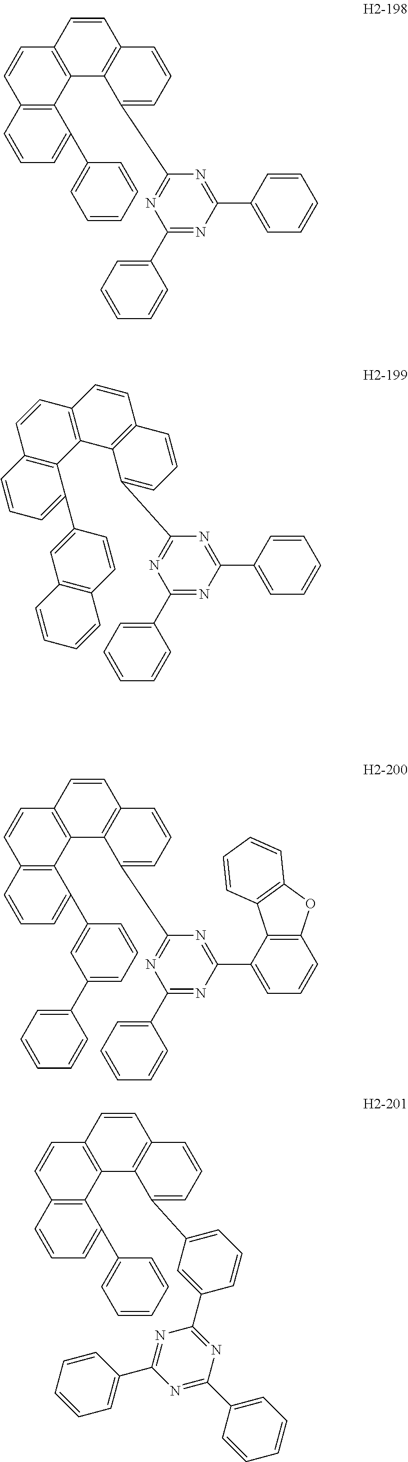

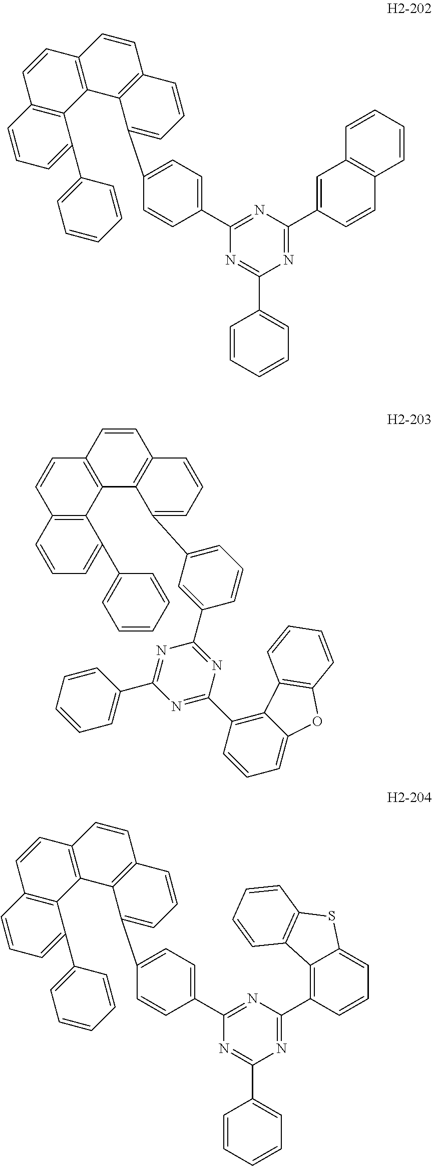 [SMILES: c1ccc(-c2nc(-c3ccc(-c4cccc5ccc6ccc7cccc(-c8ccccc8)c7c6c45)cc3)nc(-c3ccc4ccccc4c3)n2)cc1 ; c1ccc(-c2nc(-c3cccc(-c4cccc5ccc6ccc7cccc(-c8ccccc8)c7c6c45)c3)nc(-c3cccc4oc5ccccc5c34)n2)cc1 ; c1ccc(-c2nc(-c3ccc(-c4cccc5ccc6ccc7cccc(-c8ccccc8)c7c6c45)cc3)nc(-c3cccc4sc5ccccc5c34)n2)cc1]

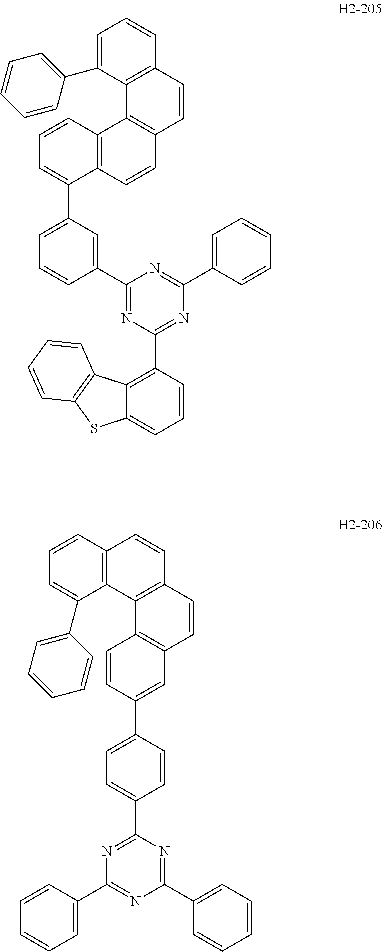 [SMILES: c1ccc(-c2nc(-c3cccc(-c4cccc5c4ccc4ccc6cccc(-c7ccccc7)c6c45)c3)nc(-c3cccc4sc5ccccc5c34)n2)cc1 ; c1ccc(-c2nc(-c3ccccc3)nc(-c3ccc(-c4ccc5c(ccc6ccc7cccc(-c8ccccc8)c7c65)c4)cc3)n2)cc1]

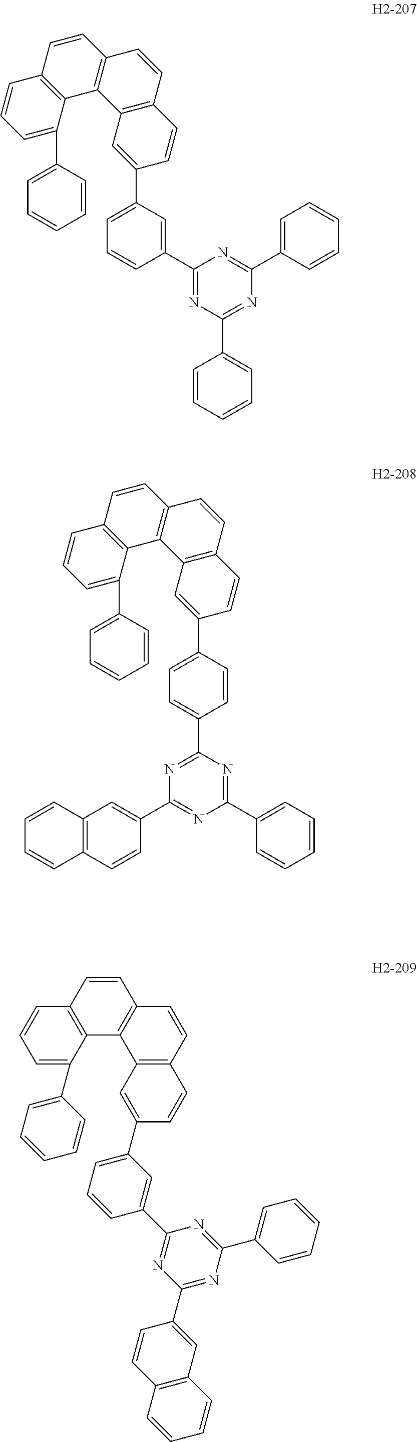 [SMILES: c1ccc(-c2nc(-c3ccccc3)nc(-c3cccc(-c4ccc5ccc6ccc7cccc(-c8ccccc8)c7c6c5c4)c3)n2)cc1 ; c1ccc(-c2nc(-c3ccc(-c4ccc5ccc6ccc7cccc(-c8ccccc8)c7c6c5c4)cc3)nc(-c3ccc4ccccc4c3)n2)cc1 ; c1ccc(-c2nc(-c3cccc(-c4ccc5ccc6ccc7cccc(-c8ccccc8)c7c6c5c4)c3)nc(-c3ccc4ccccc4c3)n2)cc1]

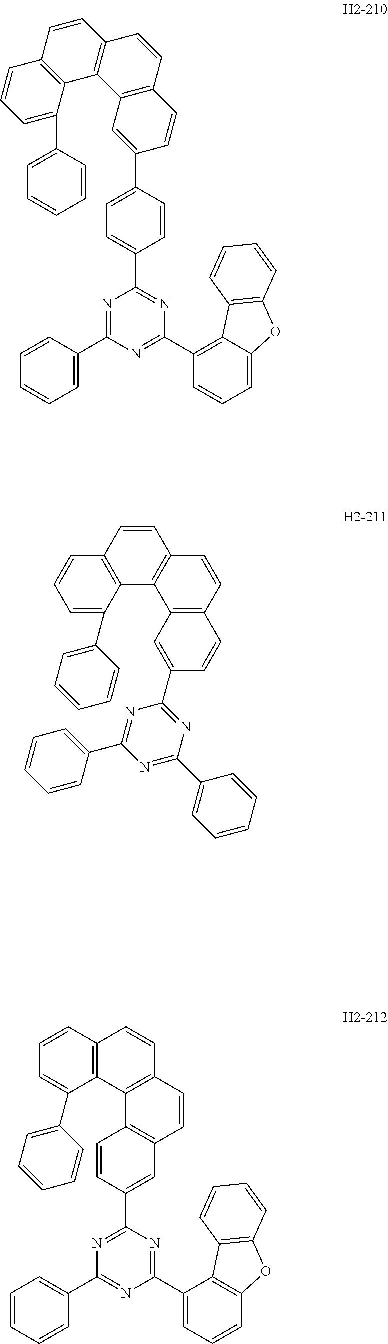 [SMILES: c1ccc(-c2nc(-c3ccc(-c4ccc5ccc6ccc7cccc(-c8ccccc8)c7c6c5c4)cc3)nc(-c3cccc4oc5ccccc5c34)n2)cc1 ; c1ccc(-c2nc(-c3ccccc3)nc(-c3ccc4ccc5ccc6cccc(-c7ccccc7)c6c5c4c3)n2)cc1 ; c1ccc(-c2nc(-c3ccc4c(ccc5ccc6cccc(-c7ccccc7)c6c54)c3)nc(-c3cccc4oc5ccccc5c34)n2)cc1]

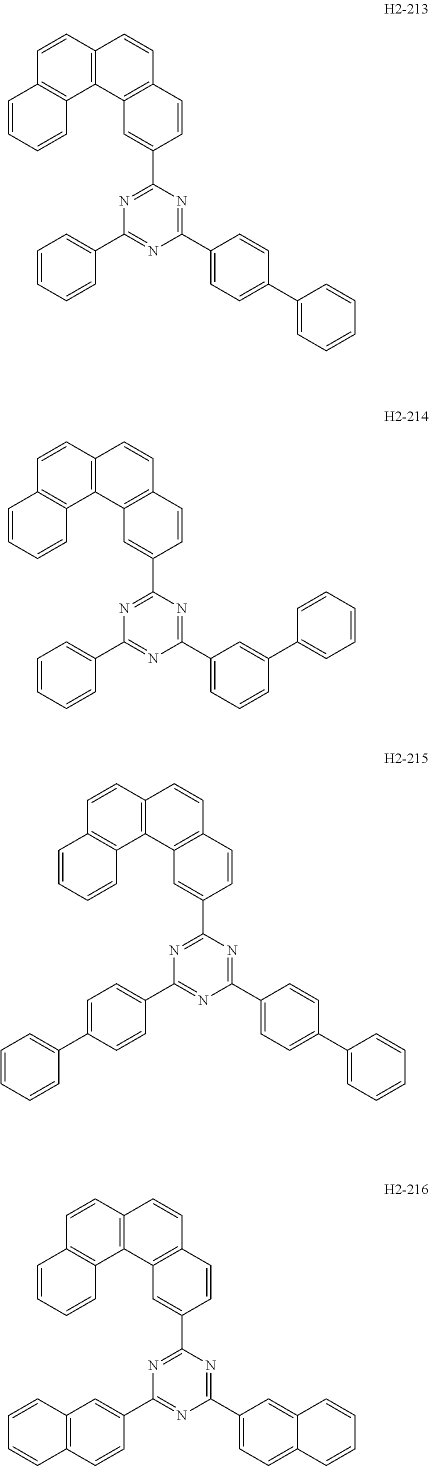 [SMILES: c1ccc(-c2ccc(-c3nc(-c4ccccc4)nc(-c4ccc5ccc6ccc7ccccc7c6c5c4)n3)cc2)cc1 ; c1ccc(-c2cccc(-c3nc(-c4ccccc4)nc(-c4ccc5ccc6ccc7ccccc7c6c5c4)n3)c2)cc1 ; c1ccc(-c2ccc(-c3nc(-c4ccc(-c5ccccc5)cc4)nc(-c4ccc5ccc6ccc7ccccc7c6c5c4)n3)cc2)cc1 ; c1ccc2cc(-c3nc(-c4ccc5ccccc5c4)nc(-c4ccc5ccc6ccc7ccccc7c6c5c4)n3)ccc2c1]

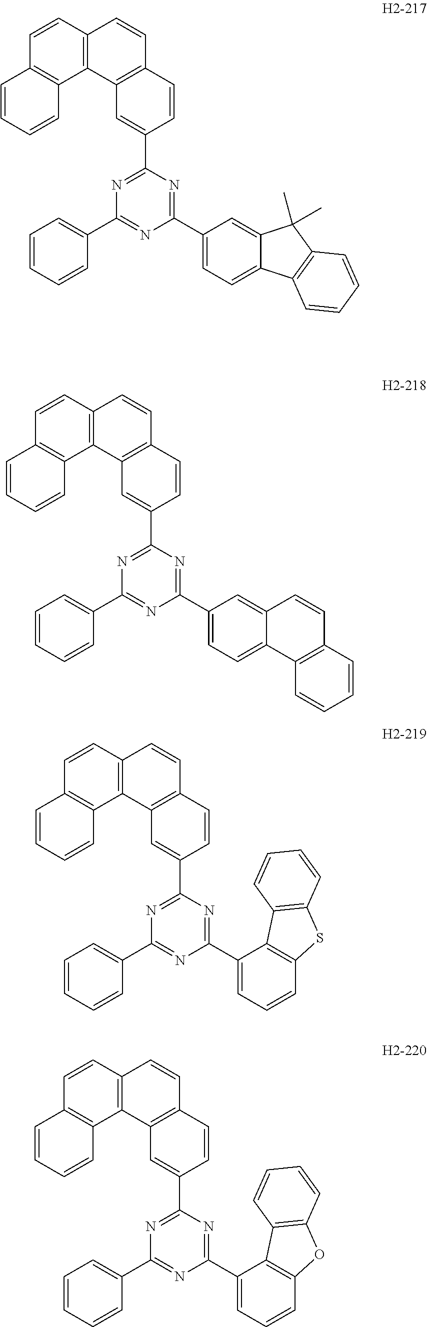 [SMILES: CC1(C)c2ccccc2-c2ccc(-c3nc(-c4ccccc4)nc(-c4ccc5ccc6ccc7ccccc7c6c5c4)n3)cc21 ; c1ccc(-c2nc(-c3ccc4c(ccc5ccccc54)c3)nc(-c3ccc4ccc5ccc6ccccc6c5c4c3)n2)cc1 ; c1ccc(-c2nc(-c3ccc4ccc5ccc6ccccc6c5c4c3)nc(-c3cccc4sc5ccccc5c34)n2)cc1 ; c1ccc(-c2nc(-c3ccc4ccc5ccc6ccccc6c5c4c3)nc(-c3cccc4oc5ccccc5c34)n2)cc1]

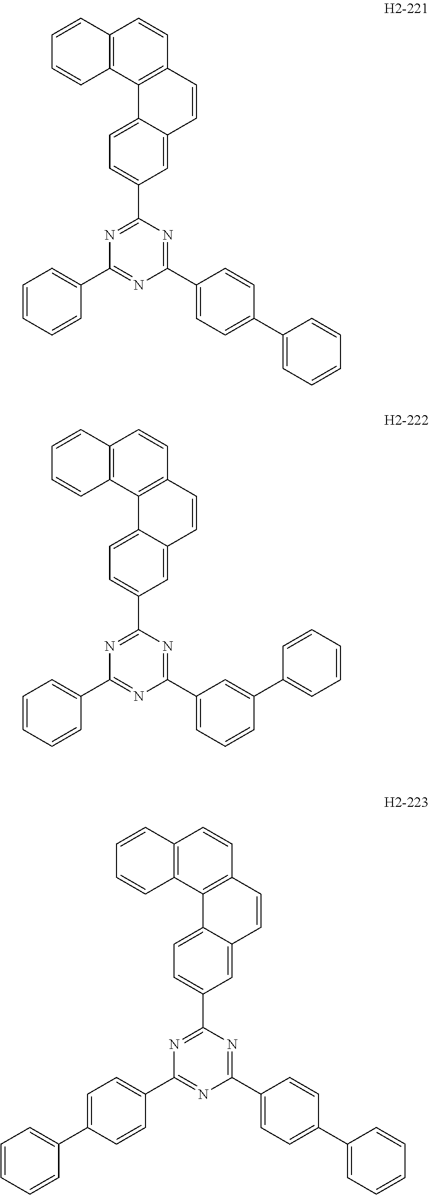 [SMILES: c1ccc(-c2ccc(-c3nc(-c4ccccc4)nc(-c4ccc5c(ccc6ccc7ccccc7c65)c4)n3)cc2)cc1 ; c1ccc(-c2cccc(-c3nc(-c4ccccc4)nc(-c4ccc5c(ccc6ccc7ccccc7c65)c4)n3)c2)cc1 ; c1ccc(-c2ccc(-c3nc(-c4ccc(-c5ccccc5)cc4)nc(-c4ccc5c(ccc6ccc7ccccc7c65)c4)n3)cc2)cc1]

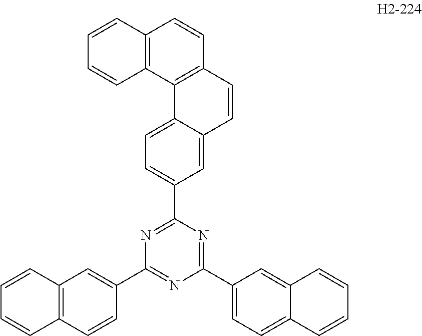 [SMILES: c1ccc2cc(-c3nc(-c4ccc5ccccc5c4)nc(-c4ccc5c(ccc6ccc7ccccc7c65)c4)n3)ccc2c1]

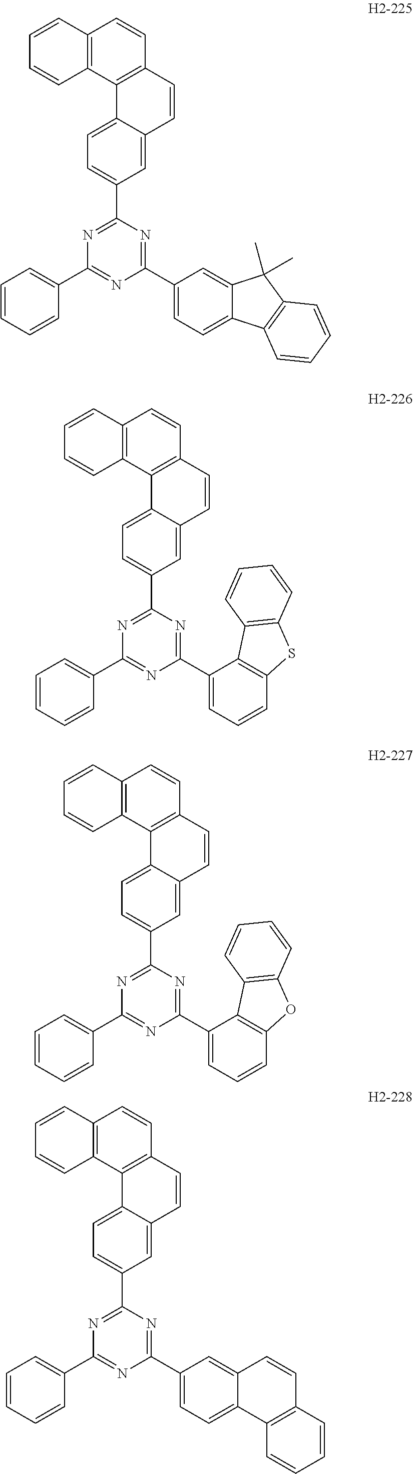

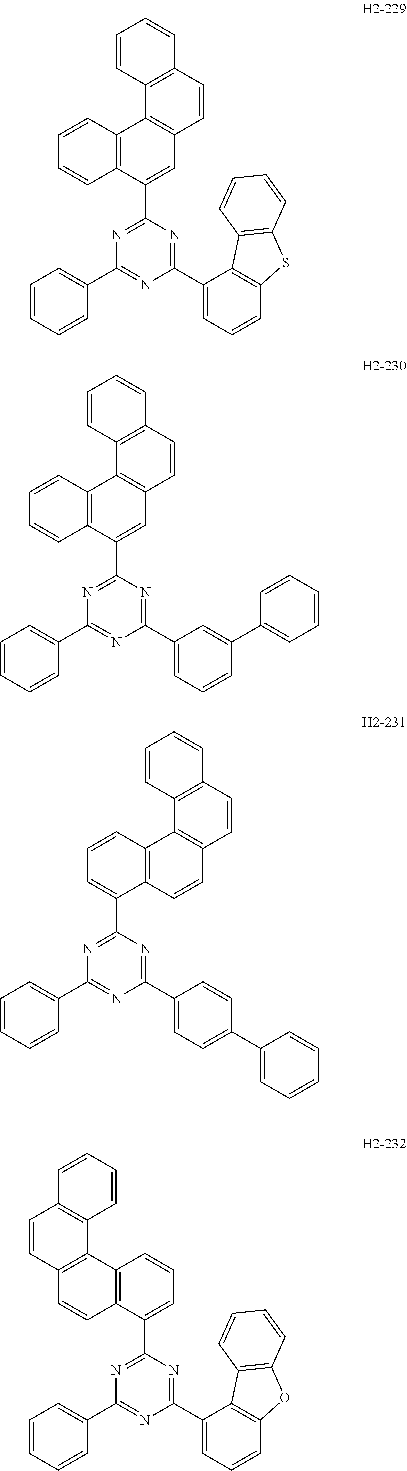 [SMILES: c1ccc(-c2nc(-c3cc4ccc5ccccc5c4c4ccccc34)nc(-c3cccc4sc5ccccc5c34)n2)cc1 ; c1ccc(-c2cccc(-c3nc(-c4ccccc4)nc(-c4cc5ccc6ccccc6c5c5ccccc45)n3)c2)cc1 ; c1ccc(-c2ccc(-c3nc(-c4ccccc4)nc(-c4cccc5c4ccc4ccc6ccccc6c45)n3)cc2)cc1 ; c1ccc(-c2nc(-c3cccc4c3ccc3ccc5ccccc5c34)nc(-c3cccc4oc5ccccc5c34)n2)cc1]

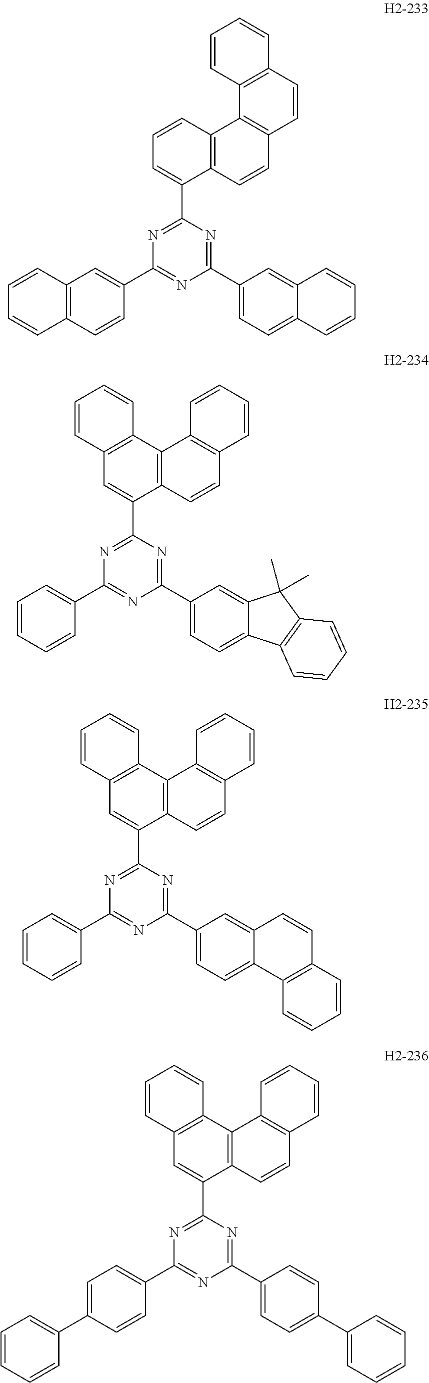

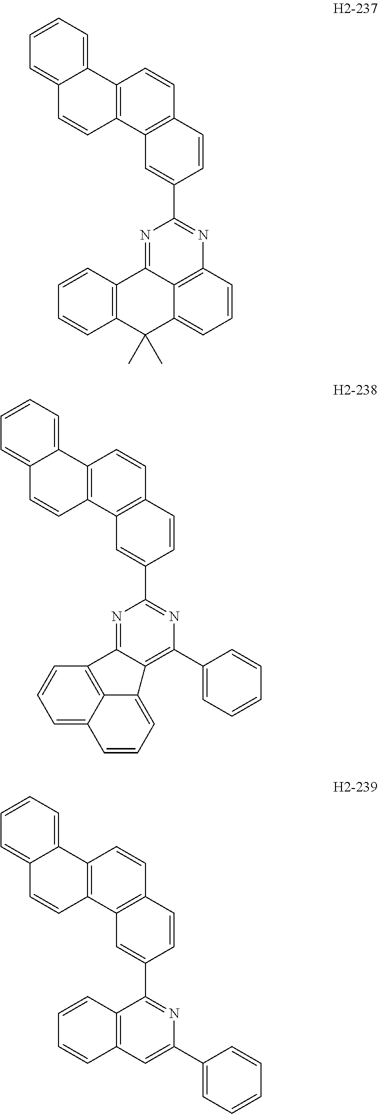 [SMILES: CC1(C)c2ccccc2-c2nc(-c3ccc4ccc5c6ccccc6ccc5c4c3)nc3cccc1c23 ; c1ccc(-c2nc(-c3ccc4ccc5c6ccccc6ccc5c4c3)nc3c2-c2cccc4cccc-3c24)cc1 ; c1ccc(-c2cc3ccccc3c(-c3ccc4ccc5c6ccccc6ccc5c4c3)n2)cc1]

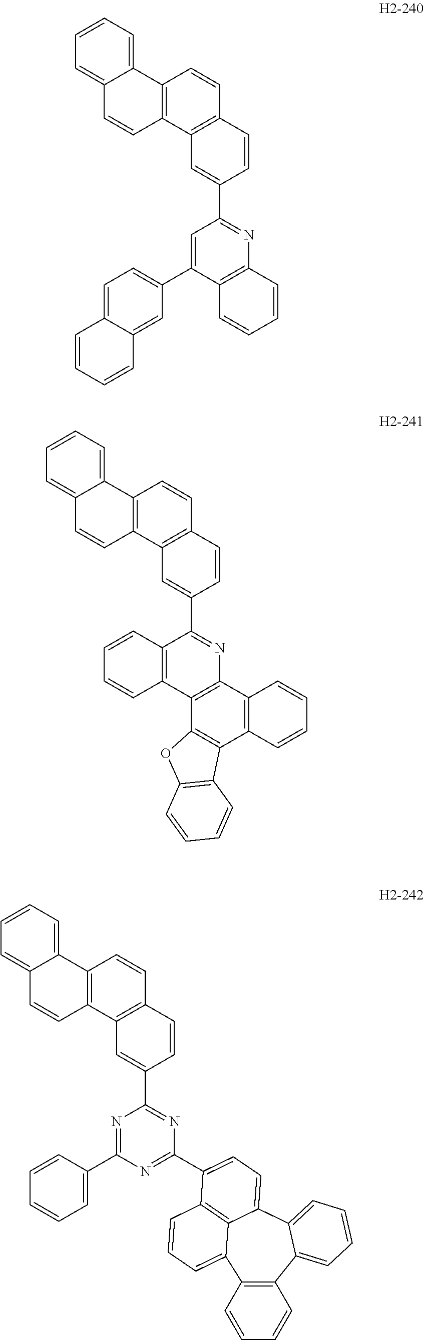 [SMILES: c1ccc2cc(-c3cc(-c4ccc5ccc6c7ccccc7ccc6c5c4)nc4ccccc34)ccc2c1 ; c1ccc2c(c1)ccc1c3cc(-c4nc5c6ccccc6c6c7ccccc7oc6c5c5ccccc45)ccc3ccc21 ; c1ccc(-c2nc(-c3ccc4ccc5c6ccccc6ccc5c4c3)nc(-c3ccc4c5c(cccc35)-c3ccccc3-c3ccccc3-4)n2)cc1]

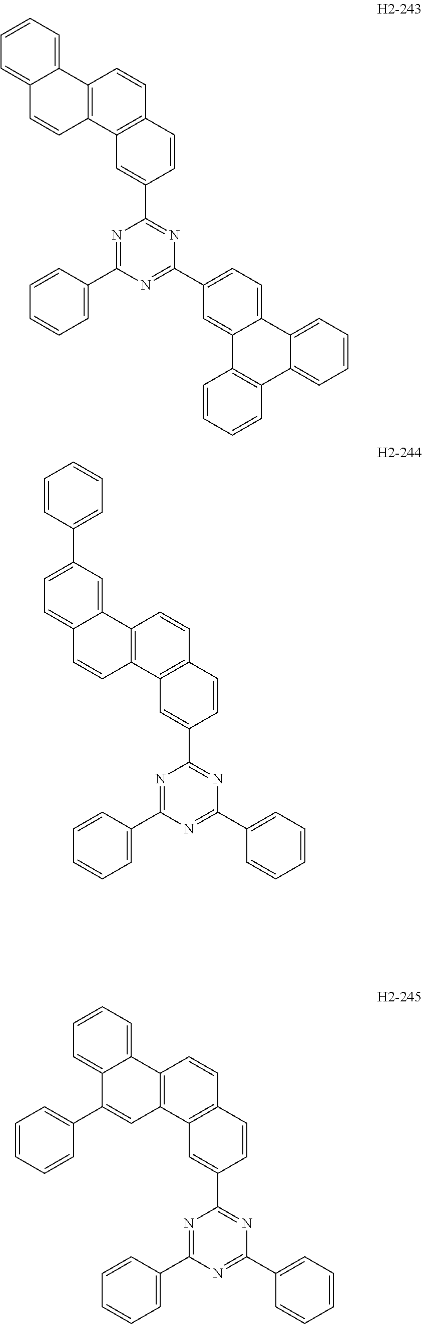 [SMILES: c1ccc(-c2nc(-c3ccc4ccc5c6ccccc6ccc5c4c3)nc(-c3ccc4c5ccccc5c5ccccc5c4c3)n2)cc1 ; c1ccc(-c2ccc3ccc4c5cc(-c6nc(-c7ccccc7)nc(-c7ccccc7)n6)ccc5ccc4c3c2)cc1 ; c1ccc(-c2nc(-c3ccccc3)nc(-c3ccc4ccc5c6ccccc6c(-c6ccccc6)cc5c4c3)n2)cc1]

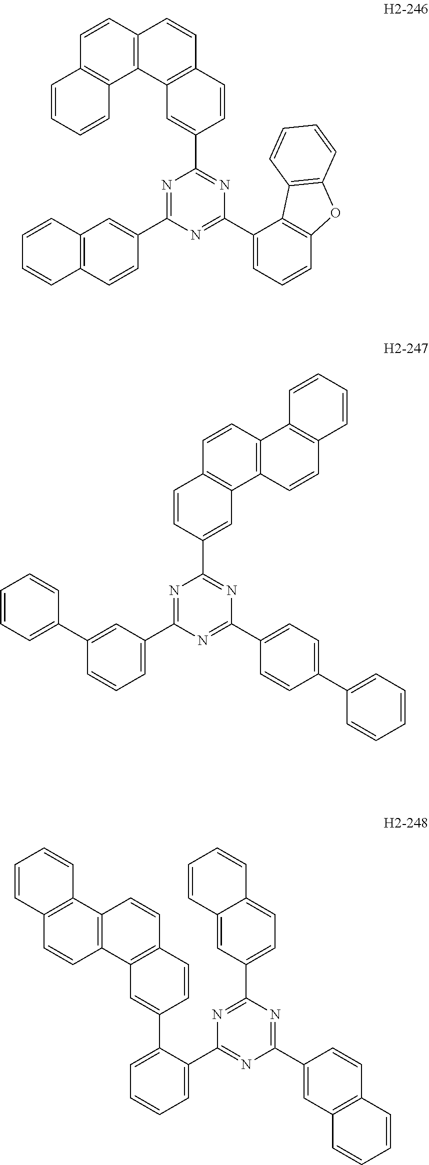 [SMILES: c1ccc2cc(-c3nc(-c4ccc5ccc6ccc7ccccc7c6c5c4)nc(-c4cccc5oc6ccccc6c45)n3)ccc2c1 ; c1ccc(-c2ccc(-c3nc(-c4cccc(-c5ccccc5)c4)nc(-c4ccc5ccc6c7ccccc7ccc6c5c4)n3)cc2)cc1 ; c1ccc(-c2nc(-c3ccc4ccccc4c3)nc(-c3ccc4ccccc4c3)n2)c(-c2ccc3ccc4c5ccccc5ccc4c3c2)c1]

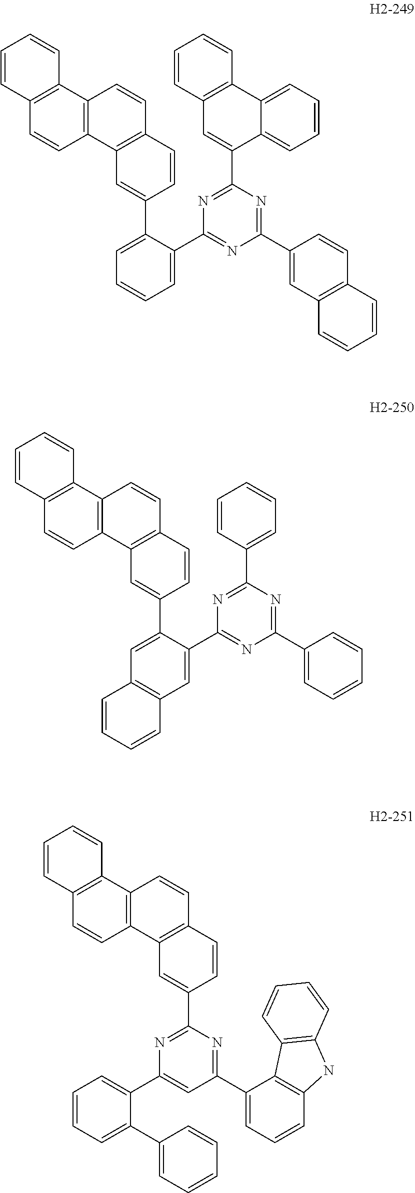 [SMILES: c1ccc(-c2nc(-c3ccc4ccccc4c3)nc(-c3cc4ccccc4c4ccccc34)n2)c(-c2ccc3ccc4c5ccccc5ccc4c3c2)c1 ; c1ccc(-c2nc(-c3ccccc3)nc(-c3cc4ccccc4cc3-c3ccc4ccc5c6ccccc6ccc5c4c3)n2)cc1 ; c1ccc(-c2ccccc2-c2cc(-c3cccc4[nH]c5ccccc5c34)nc(-c3ccc4ccc5c6ccccc6ccc5c4c3)n2)cc1]

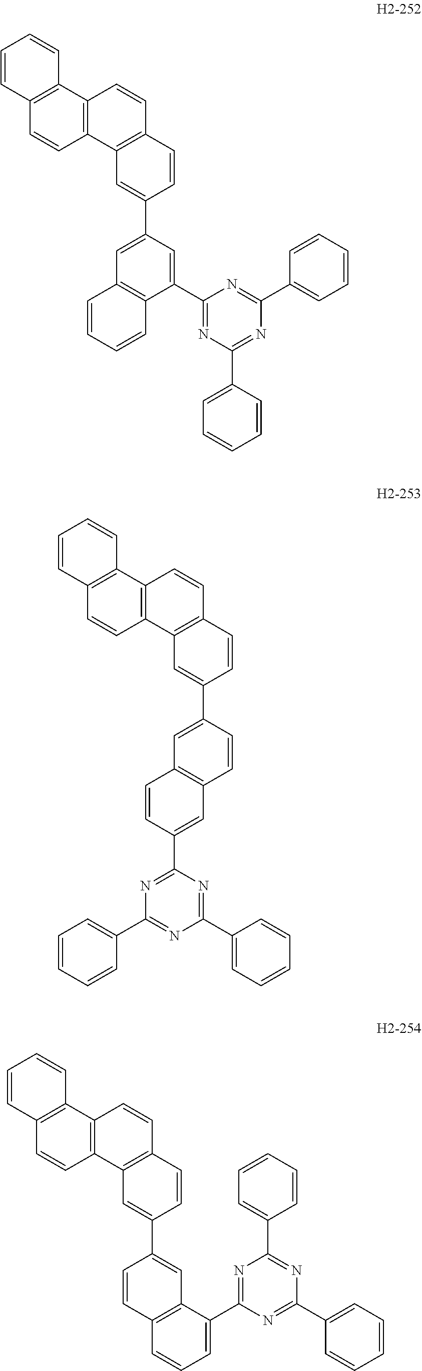 [SMILES: c1ccc(-c2nc(-c3ccccc3)nc(-c3cc(-c4ccc5ccc6c7ccccc7ccc6c5c4)cc4ccccc34)n2)cc1 ; c1ccc(-c2nc(-c3ccccc3)nc(-c3ccc4cc(-c5ccc6ccc7c8ccccc8ccc7c6c5)ccc4c3)n2)cc1 ; c1ccc(-c2nc(-c3ccccc3)nc(-c3cccc4ccc(-c5ccc6ccc7c8ccccc8ccc7c6c5)cc34)n2)cc1]

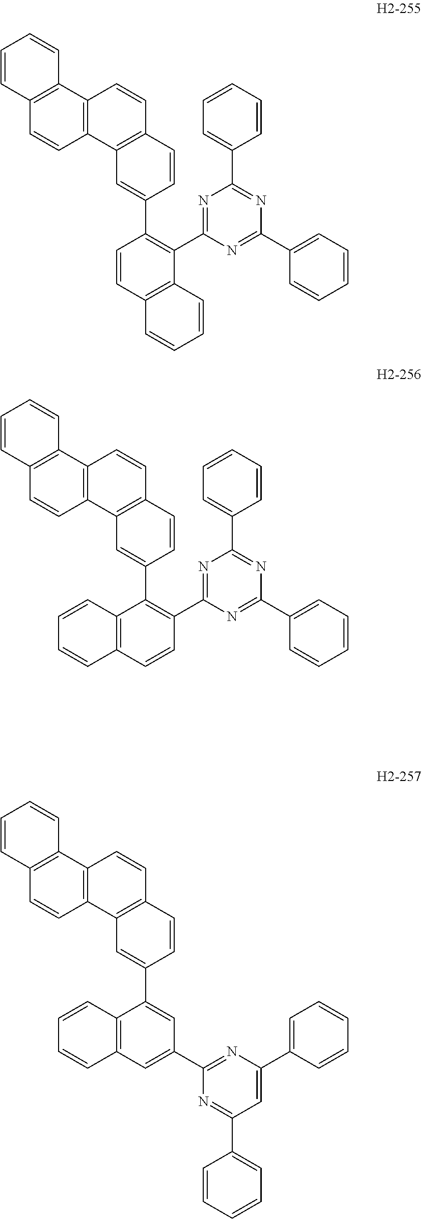 [SMILES: c1ccc(-c2nc(-c3ccccc3)nc(-c3c(-c4ccc5ccc6c7ccccc7ccc6c5c4)ccc4ccccc34)n2)cc1 ; c1ccc(-c2nc(-c3ccccc3)nc(-c3ccc4ccccc4c3-c3ccc4ccc5c6ccccc6ccc5c4c3)n2)cc1 ; c1ccc(-c2cc(-c3ccccc3)nc(-c3cc(-c4ccc5ccc6c7ccccc7ccc6c5c4)c4ccccc4c3)n2)cc1]

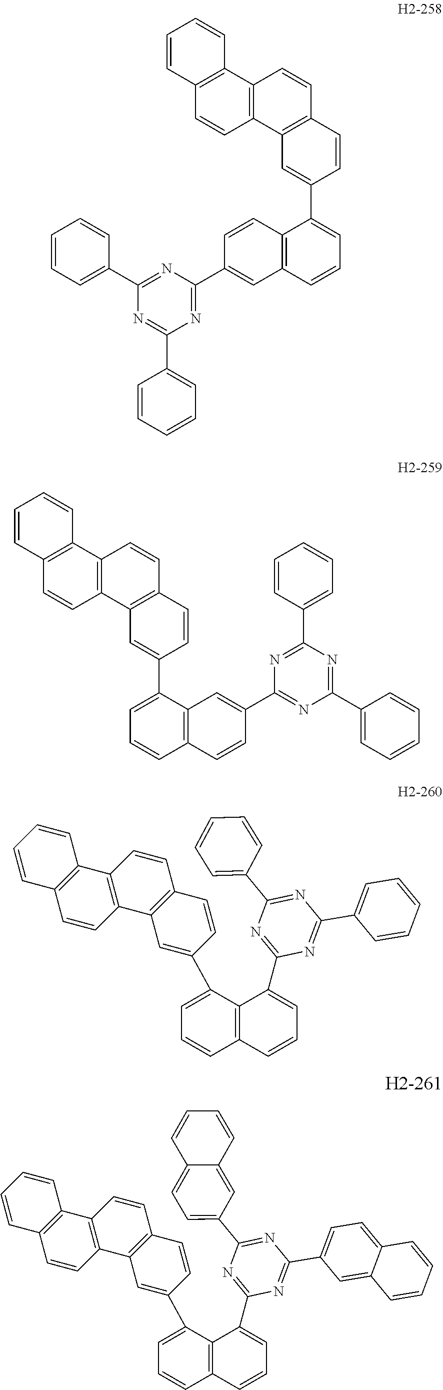 [SMILES: c1ccc(-c2nc(-c3ccccc3)nc(-c3ccc4c(-c5ccc6ccc7c8ccccc8ccc7c6c5)cccc4c3)n2)cc1 ; c1ccc(-c2nc(-c3ccccc3)nc(-c3ccc4cccc(-c5ccc6ccc7c8ccccc8ccc7c6c5)c4c3)n2)cc1 ; c1ccc(-c2nc(-c3ccccc3)nc(-c3cccc4cccc(-c5ccc6ccc7c8ccccc8ccc7c6c5)c34)n2)cc1 ; c1ccc2cc(-c3nc(-c4ccc5ccccc5c4)nc(-c4cccc5cccc(-c6ccc7ccc8c9ccccc9ccc8c7c6)c45)n3)ccc2c1]

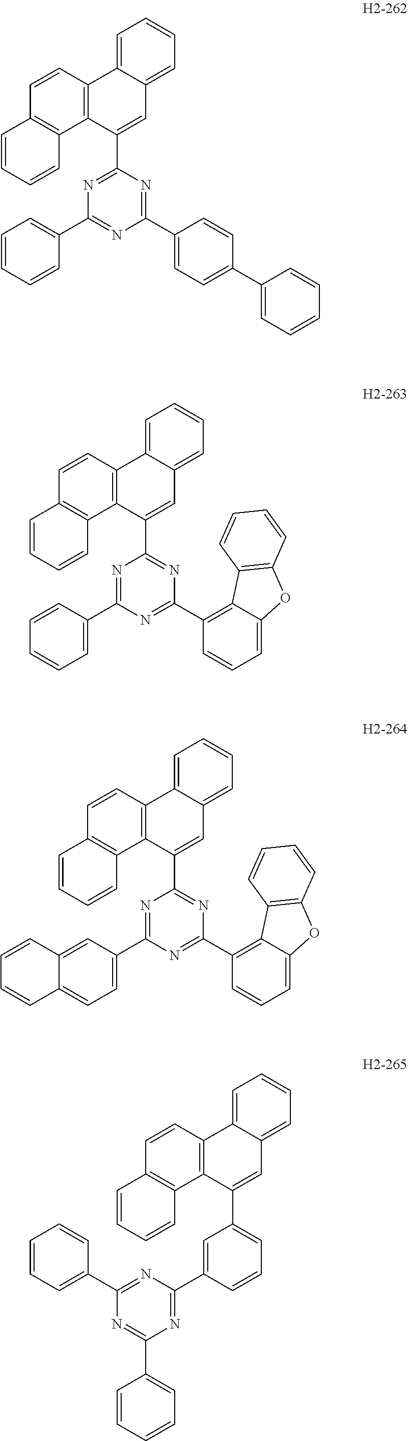 [SMILES: c1ccc(-c2ccc(-c3nc(-c4ccccc4)nc(-c4cc5ccccc5c5ccc6ccccc6c45)n3)cc2)cc1 ; c1ccc(-c2nc(-c3cccc4oc5ccccc5c34)nc(-c3cc4ccccc4c4ccc5ccccc5c34)n2)cc1 ; c1ccc2cc(-c3nc(-c4cccc5oc6ccccc6c45)nc(-c4cc5ccccc5c5ccc6ccccc6c45)n3)ccc2c1 ; c1ccc(-c2nc(-c3ccccc3)nc(-c3cccc(-c4cc5ccccc5c5ccc6ccccc6c45)c3)n2)cc1]

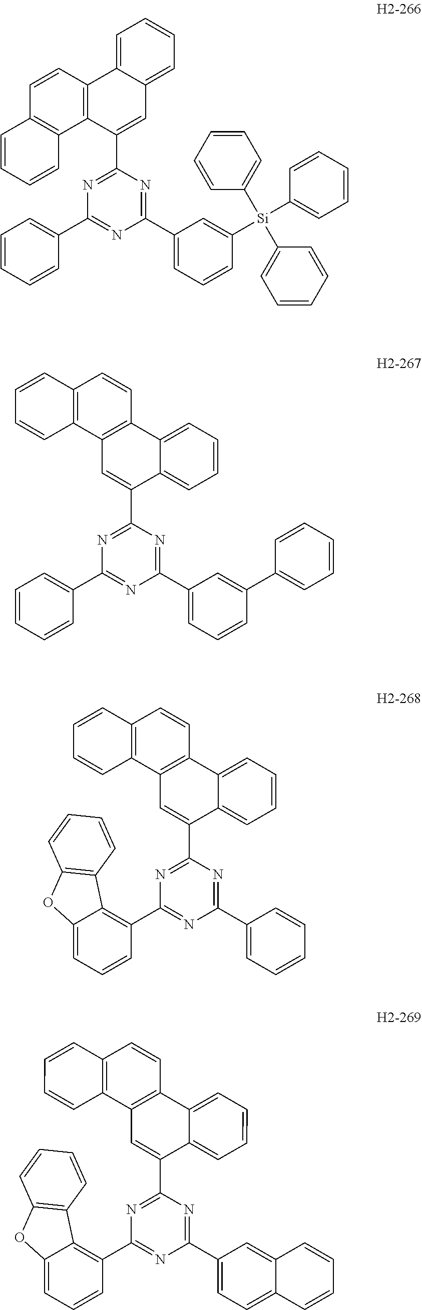 [SMILES: c1ccc(-c2nc(-c3cccc([Si](c4ccccc4)(c4ccccc4)c4ccccc4)c3)nc(-c3cc4ccccc4c4ccc5ccccc5c34)n2)cc1 ; c1ccc(-c2cccc(-c3nc(-c4ccccc4)nc(-c4cc5c6ccccc6ccc5c5ccccc45)n3)c2)cc1 ; c1ccc(-c2nc(-c3cc4c5ccccc5ccc4c4ccccc34)nc(-c3cccc4oc5ccccc5c34)n2)cc1 ; c1ccc2cc(-c3nc(-c4cc5c6ccccc6ccc5c5ccccc45)nc(-c4cccc5oc6ccccc6c45)n3)ccc2c1]

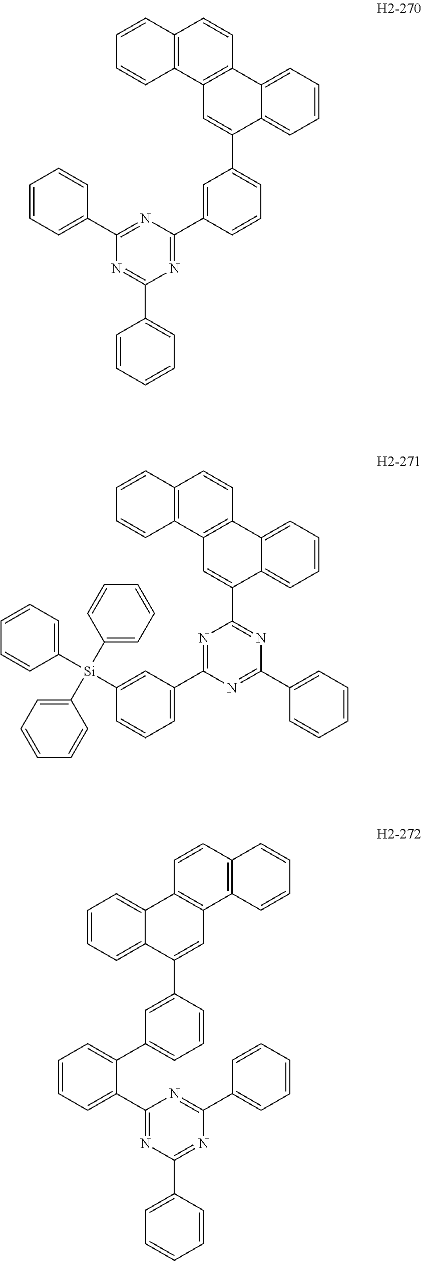 [SMILES: c1ccc(-c2nc(-c3ccccc3)nc(-c3cccc(-c4cc5c6ccccc6ccc5c5ccccc45)c3)n2)cc1 ; c1ccc(-c2nc(-c3cccc([Si](c4ccccc4)(c4ccccc4)c4ccccc4)c3)nc(-c3cc4c5ccccc5ccc4c4ccccc34)n2)cc1 ; c1ccc(-c2nc(-c3ccccc3)nc(-c3ccccc3-c3cccc(-c4cc5c6ccccc6ccc5c5ccccc45)c3)n2)cc1]

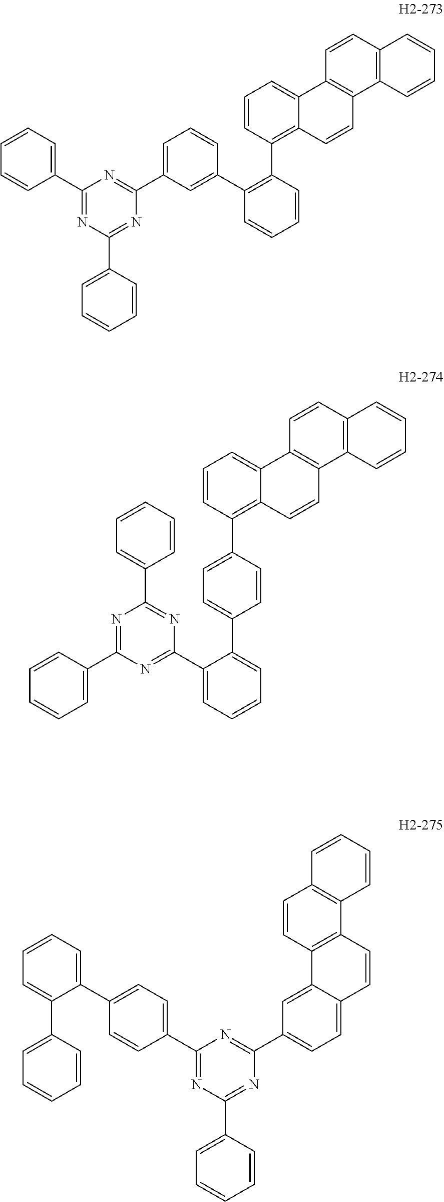 [SMILES: c1ccc(-c2nc(-c3ccccc3)nc(-c3cccc(-c4ccccc4-c4cccc5c4ccc4c6ccccc6ccc54)c3)n2)cc1 ; c1ccc(-c2nc(-c3ccccc3)nc(-c3ccccc3-c3ccc(-c4cccc5c4ccc4c6ccccc6ccc54)cc3)n2)cc1 ; c1ccc(-c2nc(-c3ccc(-c4ccccc4-c4ccccc4)cc3)nc(-c3ccc4ccc5c6ccccc6ccc5c4c3)n2)cc1]

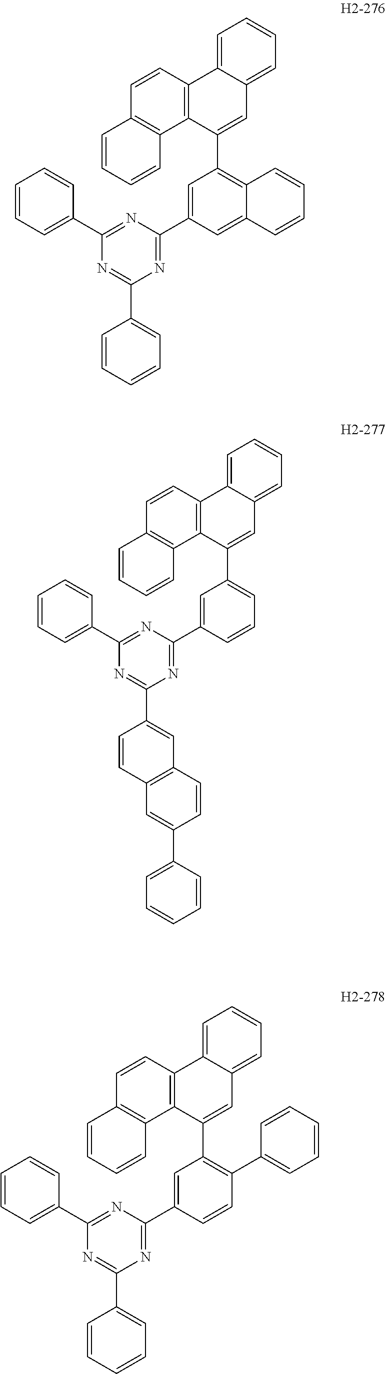 [SMILES: c1ccc(-c2nc(-c3ccccc3)nc(-c3cc(-c4cc5ccccc5c5ccc6ccccc6c45)c4ccccc4c3)n2)cc1 ; c1ccc(-c2ccc3cc(-c4nc(-c5ccccc5)nc(-c5cccc(-c6cc7ccccc7c7ccc8ccccc8c67)c5)n4)ccc3c2)cc1 ; c1ccc(-c2nc(-c3ccccc3)nc(-c3ccc(-c4ccccc4)c(-c4cc5ccccc5c5ccc6ccccc6c45)c3)n2)cc1]

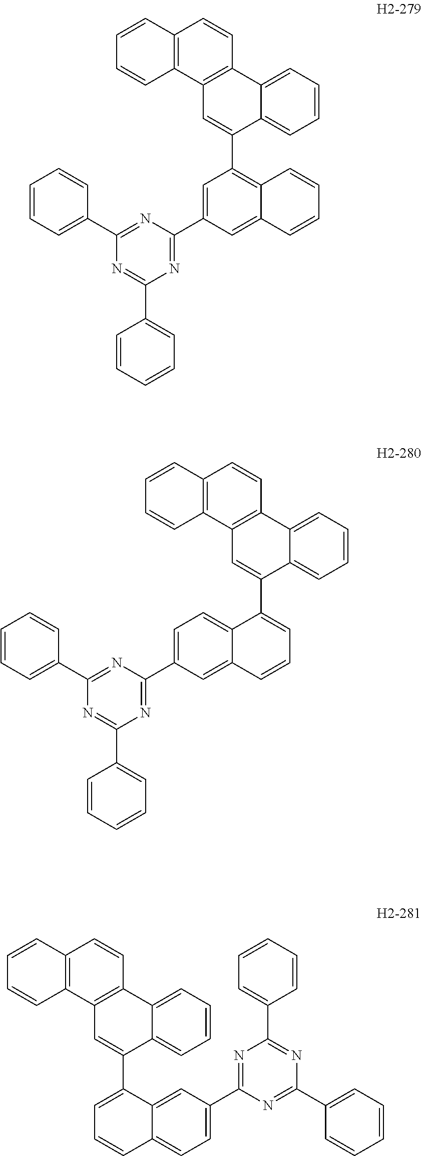 [SMILES: c1ccc(-c2nc(-c3ccccc3)nc(-c3cc(-c4cc5c6ccccc6ccc5c5ccccc45)c4ccccc4c3)n2)cc1 ; c1ccc(-c2nc(-c3ccccc3)nc(-c3ccc4c(-c5cc6c7ccccc7ccc6c6ccccc56)cccc4c3)n2)cc1 ; c1ccc(-c2nc(-c3ccccc3)nc(-c3ccc4cccc(-c5cc6c7ccccc7ccc6c6ccccc56)c4c3)n2)cc1]

10. An organic electroluminescent compound represented by the following Formula 11: 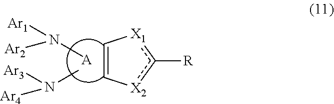
in Formula 11,
one of X₁ and X₂ represents —N═, and the other represents —O— or —S—;
R represents a substituted or unsubstituted (C1-C30)alkyl, a substituted or unsubstituted (C6-C30)aryl, or a substituted or unsubstituted (3- to 30-membered)heteroaryl;
ring A represents a (C6-C12)arene; and
Ar₁ to Ar₄ each independently represent a substituted or unsubstituted (C6-C30)aryl, or a substituted or unsubstituted (3- to 30-membered)heteroaryl;
provided that, when ring A is benzene, —N(Ar₁)(Ar₂) and —N(Ar₃)(Ar₄) are at an ortho or meta position to each other.

11. The organic electroluminescent compound according to claim 10, wherein R is a substituted or unsubstituted phenyl, a substituted or unsubstituted biphenyl, a substituted or unsubstituted terphenyl, a substituted or unsubstituted naphthyl, a substituted or unsubstituted phenylnaphthyl, a substituted or unsubstituted naphthylphenyl, a substituted or unsubstituted phenanthrenyl, a substituted or unsubstituted dibenzofuranyl, or a substituted or unsubstituted dibenzothiophenyl.

12. The organic electroluminescent compound according to claim 10, wherein the compound represented by Formula 11 is at least one selected from the following compounds:

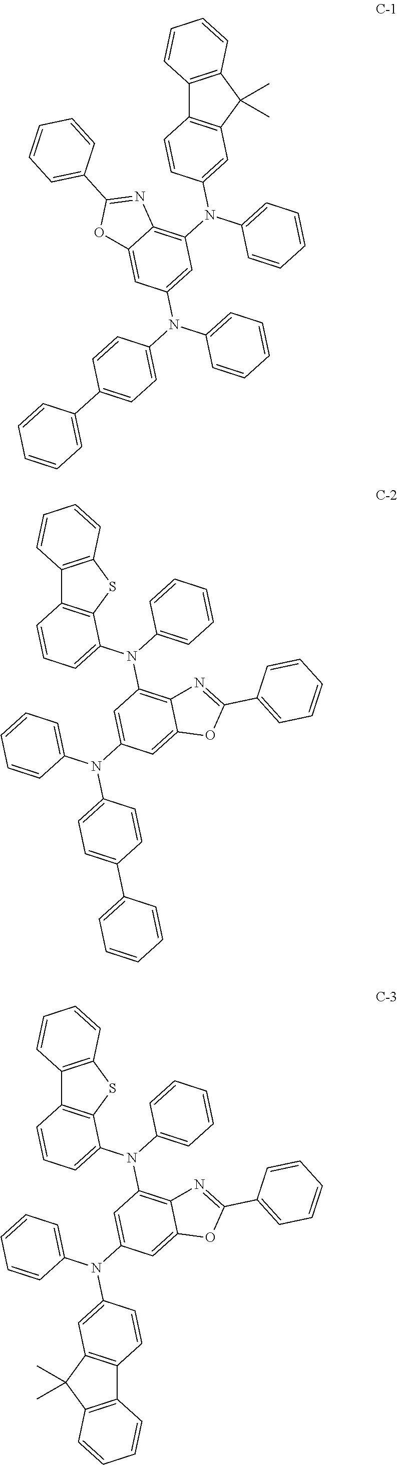

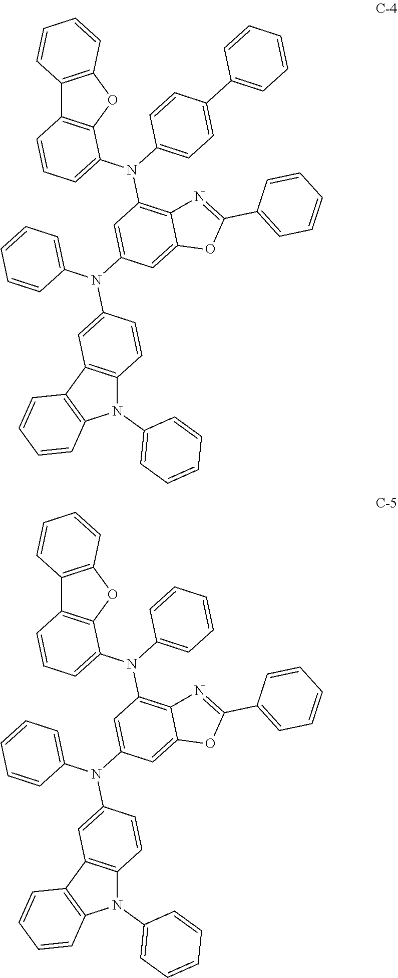 [SMILES: c1ccc(-c2ccc(N(c3cc(N(c4ccccc4)c4ccc5c(c4)c4ccccc4n5-c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccc5c(c4)c4ccccc4n5-c4ccccc4)cc3o2)cc1]

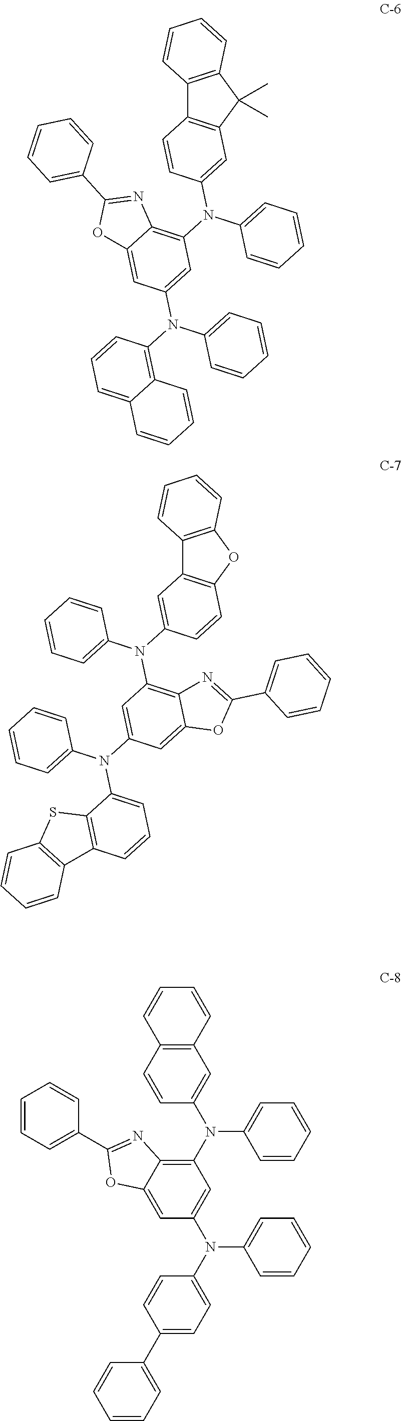

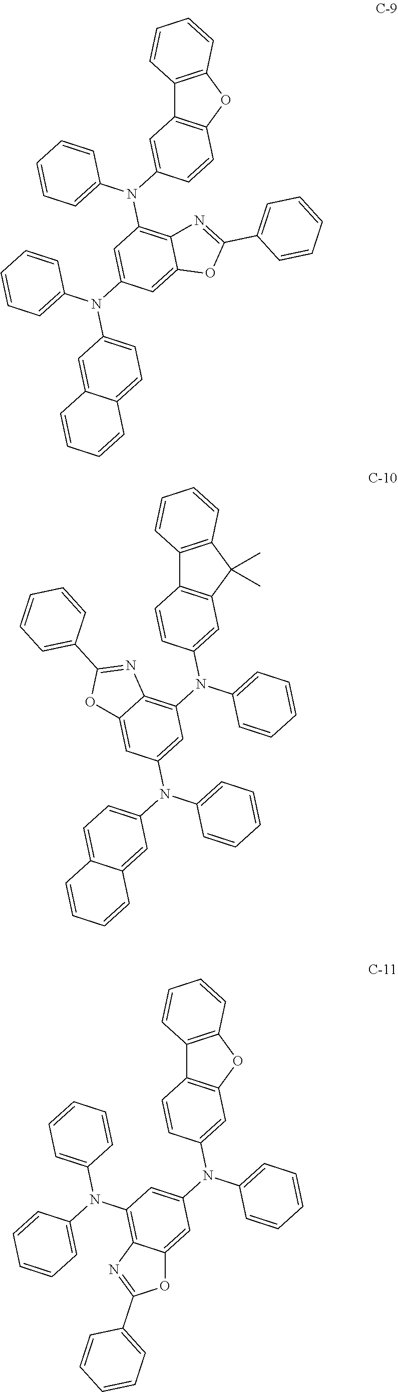 [SMILES: c1ccc(-c2nc3c(N(c4ccccc4)c4ccc5oc6ccccc6c5c4)cc(N(c4ccccc4)c4ccc5ccccc5c4)cc3o2)cc1 ; CC1(C)c2ccccc2-c2ccc(N(c3ccccc3)c3cc(N(c4ccccc4)c4ccc5ccccc5c4)cc4oc(-c5ccccc5)nc34)cc21 ; c1ccc(-c2nc3c(N(c4ccccc4)c4ccccc4)cc(N(c4ccccc4)c4ccc5c(c4)oc4ccccc45)cc3o2)cc1]

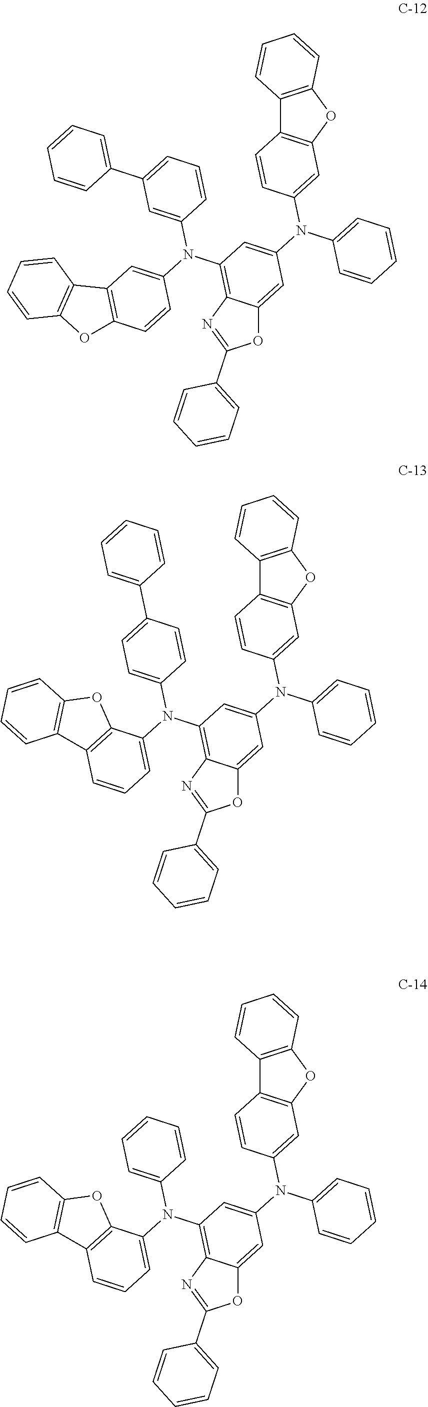 [SMILES: c1ccc(-c2cccc(N(c3ccc4oc5ccccc5c4c3)c3cc(N(c4ccccc4)c4ccc5c(c4)oc4ccccc45)cc4oc(-c5ccccc5)nc34)c2)cc1 ; c1ccc(-c2ccc(N(c3cc(N(c4ccccc4)c4ccc5c(c4)oc4ccccc45)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccc5c(c4)oc4ccccc45)cc3o2)cc1]

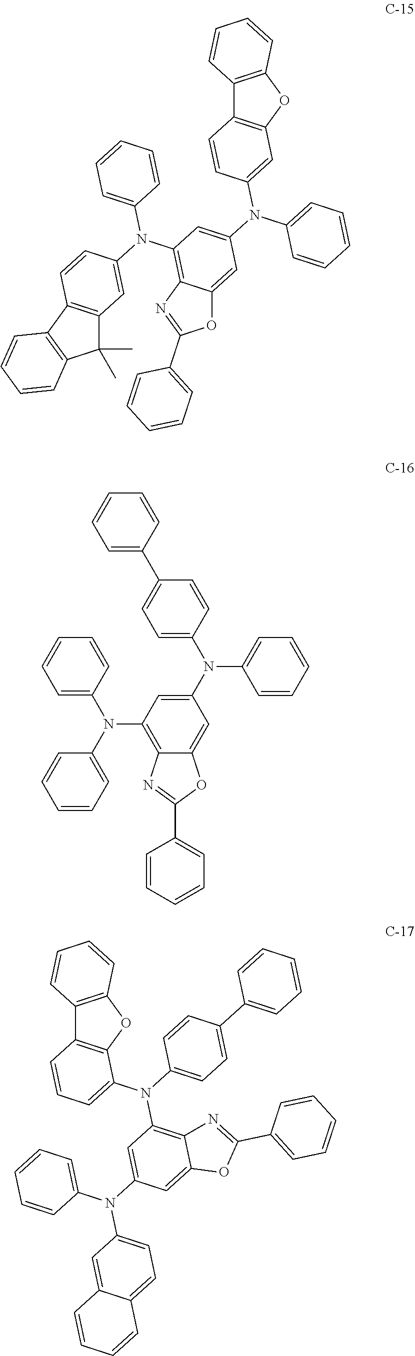 [SMILES: CC1(C)c2ccccc2-c2ccc(N(c3ccccc3)c3cc(N(c4ccccc4)c4ccc5c(c4)oc4ccccc45)cc4oc(-c5ccccc5)nc34)cc21 ; c1ccc(-c2ccc(N(c3ccccc3)c3cc(N(c4ccccc4)c4ccccc4)c4nc(-c5ccccc5)oc4c3)cc2)cc1 ; c1ccc(-c2ccc(N(c3cc(N(c4ccccc4)c4ccc5ccccc5c4)cc4oc(-c5ccccc5)nc34)c3cccc4c3oc3ccccc34)cc2)cc1]

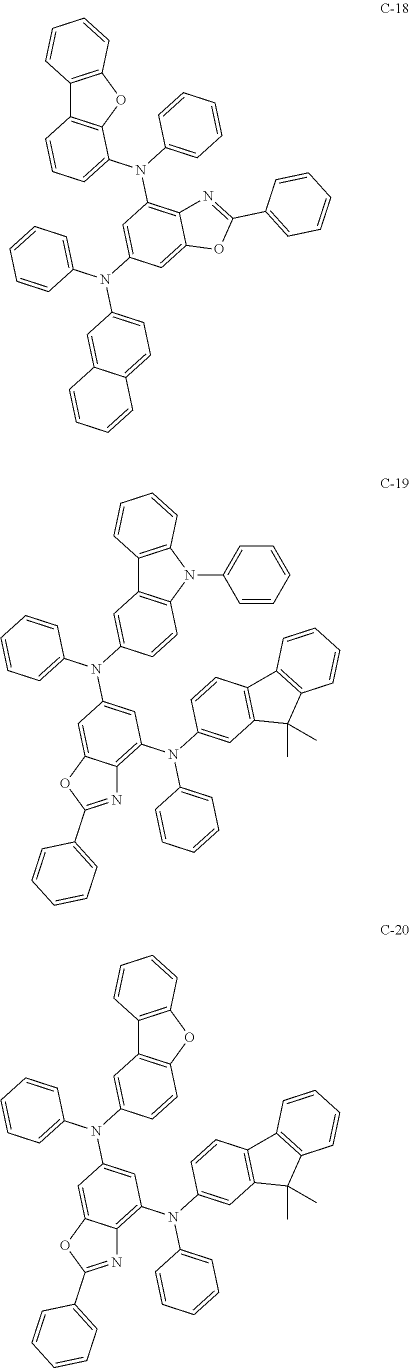 [SMILES: c1ccc(-c2nc3c(N(c4ccccc4)c4cccc5c4oc4ccccc45)cc(N(c4ccccc4)c4ccc5ccccc5c4)cc3o2)cc1 ; CC1(C)c2ccccc2-c2ccc(N(c3ccccc3)c3cc(N(c4ccccc4)c4ccc5c(c4)c4ccccc4n5-c4ccccc4)cc4oc(-c5ccccc5)nc34)cc21 ; CC1(C)c2ccccc2-c2ccc(N(c3ccccc3)c3cc(N(c4ccccc4)c4ccc5oc6ccccc6c5c4)cc4oc(-c5ccccc5)nc34)cc21]

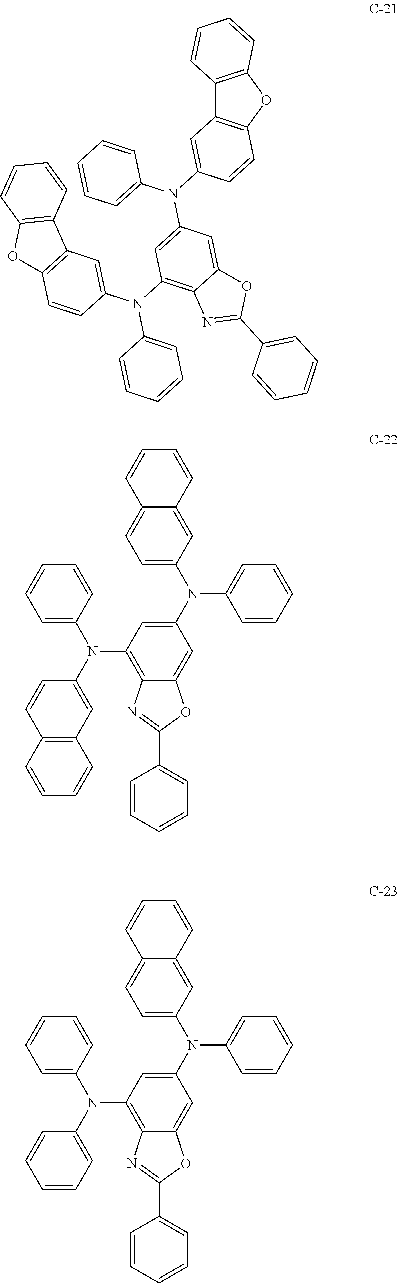 [SMILES: c1ccc(-c2nc3c(N(c4ccccc4)c4ccc5oc6ccccc6c5c4)cc(N(c4ccccc4)c4ccc5oc6ccccc6c5c4)cc3o2)cc1 ; c1ccc(-c2nc3c(N(c4ccccc4)c4ccc5ccccc5c4)cc(N(c4ccccc4)c4ccc5ccccc5c4)cc3o2)cc1 ; c1ccc(-c2nc3c(N(c4ccccc4)c4ccccc4)cc(N(c4ccccc4)c4ccc5ccccc5c4)cc3o2)cc1]

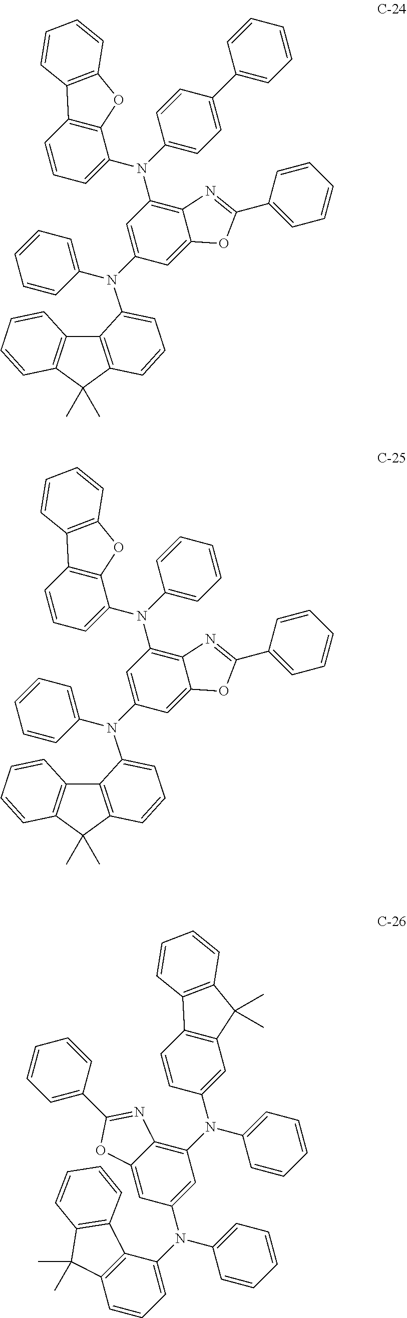 [SMILES: CC1(C)c2ccccc2-c2c(N(c3ccccc3)c3cc(N(c4ccc(-c5ccccc5)cc4)c4cccc5c4oc4ccccc45)c4nc(-c5ccccc5)oc4c3)cccc21 ; CC1(C)c2ccccc2-c2c(N(c3ccccc3)c3cc(N(c4ccccc4)c4cccc5c4oc4ccccc45)c4nc(-c5ccccc5)oc4c3)cccc21 ; CC1(C)c2ccccc2-c2ccc(N(c3ccccc3)c3cc(N(c4ccccc4)c4cccc5c4-c4ccccc4C5(C)C)cc4oc(-c5ccccc5)nc34)cc21]

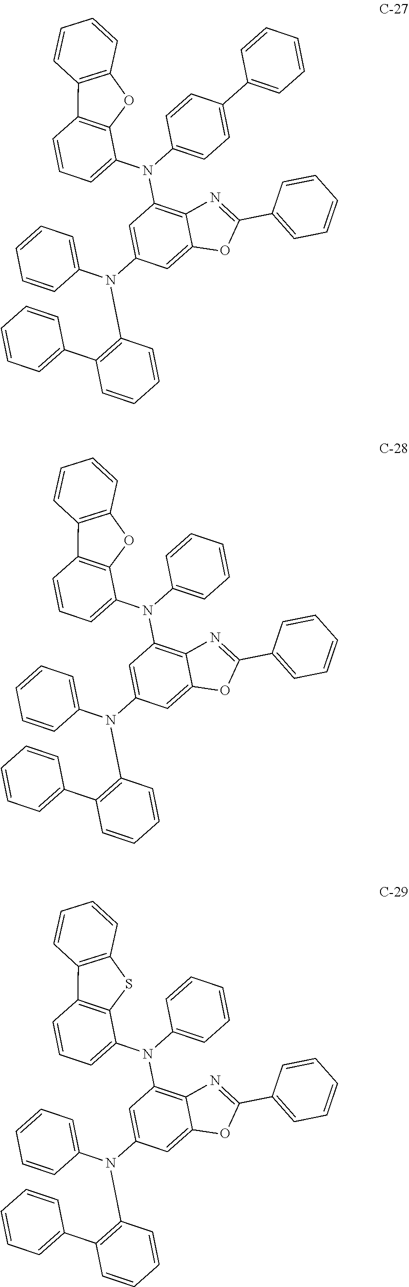 [SMILES: c1ccc(-c2ccc(N(c3cc(N(c4ccccc4)c4ccccc4-c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccccc4-c4ccccc4)cc3o2)cc1 ; c1ccc(-c2nc3c(N(c4ccccc4)c4cccc5c4sc4ccccc45)cc(N(c4ccccc4)c4ccccc4-c4ccccc4)cc3o2)cc1]

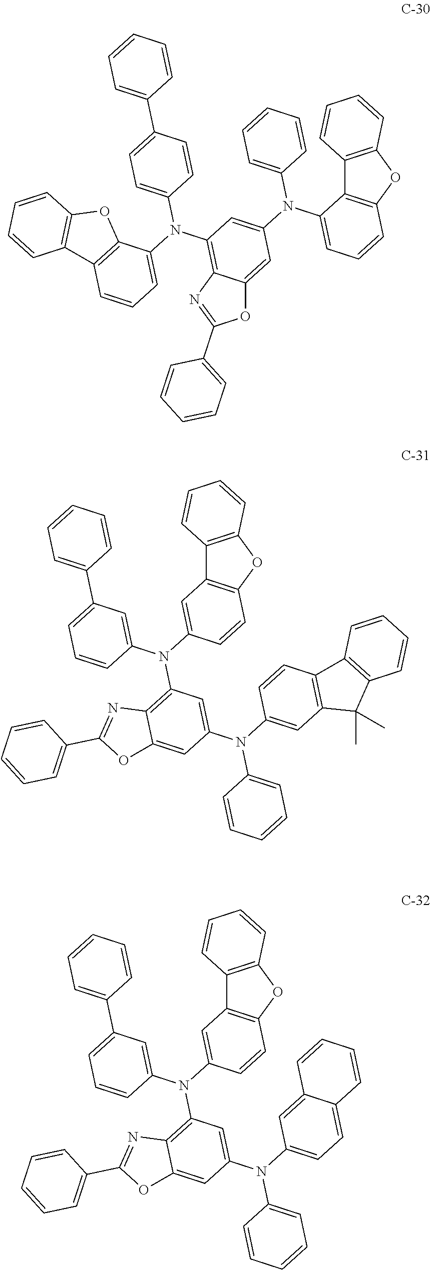 [SMILES: c1ccc(-c2ccc(N(c3cc(N(c4ccccc4)c4cccc5oc6ccccc6c45)cc4oc(-c5ccccc5)nc34)c3cccc4c3oc3ccccc34)cc2)cc1 ; CC1(C)c2ccccc2-c2ccc(N(c3ccccc3)c3cc(N(c4cccc(-c5ccccc5)c4)c4ccc5oc6ccccc6c5c4)c4nc(-c5ccccc5)oc4c3)cc21 ; c1ccc(-c2cccc(N(c3ccc4oc5ccccc5c4c3)c3cc(N(c4ccccc4)c4ccc5ccccc5c4)cc4oc(-c5ccccc5)nc34)c2)cc1]

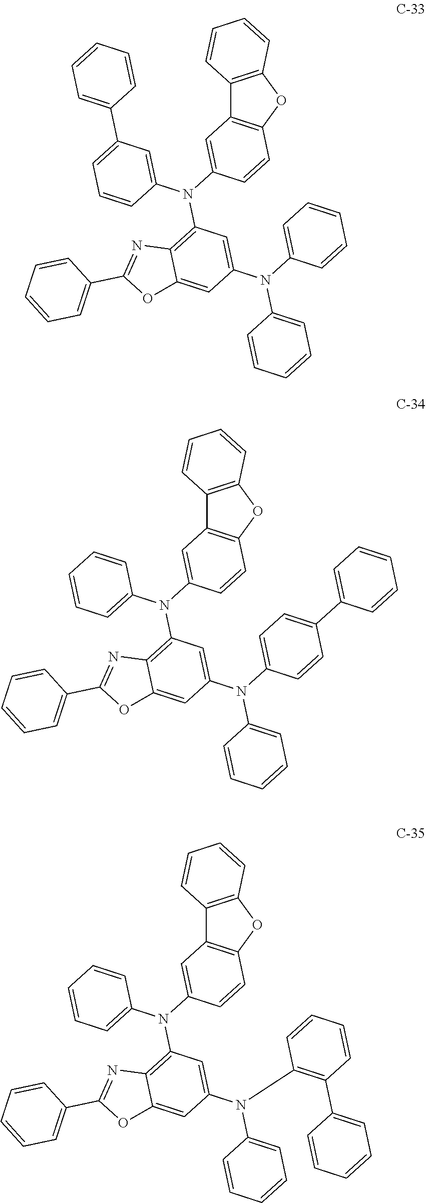 [SMILES: c1ccc(-c2cccc(N(c3ccc4oc5ccccc5c4c3)c3cc(N(c4ccccc4)c4ccccc4)cc4oc(-c5ccccc5)nc34)c2)cc1 ; c1ccc(-c2ccc(N(c3ccccc3)c3cc(N(c4ccccc4)c4ccc5oc6ccccc6c5c4)c4nc(-c5ccccc5)oc4c3)cc2)cc1 ; c1ccc(-c2nc3c(N(c4ccccc4)c4ccc5oc6ccccc6c5c4)cc(N(c4ccccc4)c4ccccc4-c4ccccc4)cc3o2)cc1]

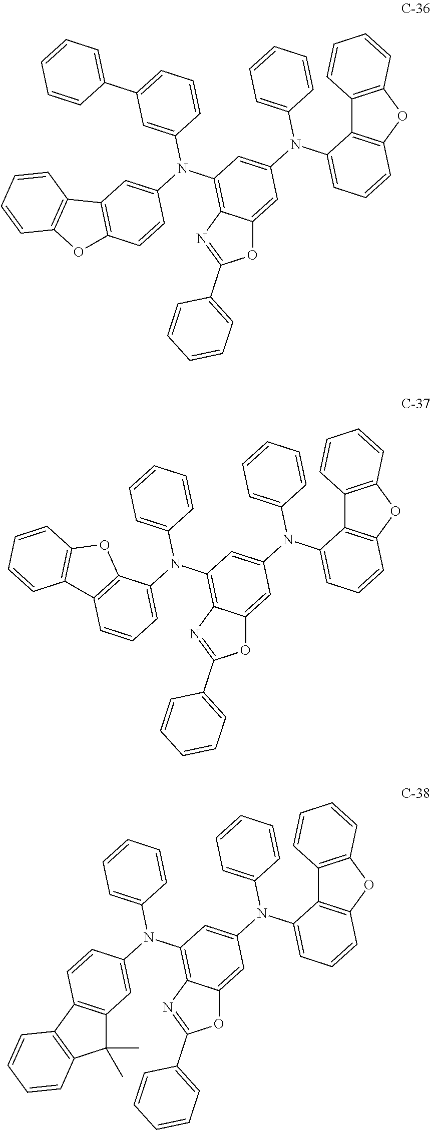 [SMILES: c1ccc(-c2cccc(N(c3ccc4oc5ccccc5c4c3)c3cc(N(c4ccccc4)c4cccc5oc6ccccc6c45)cc4oc(-c5ccccc5)nc34)c2)cc1 ; c1ccc(-c2nc3c(N(c4ccccc4)c4cccc5c4oc4ccccc45)cc(N(c4ccccc4)c4cccc5oc6ccccc6c45)cc3o2)cc1 ; CC1(C)c2ccccc2-c2ccc(N(c3ccccc3)c3cc(N(c4ccccc4)c4cccc5oc6ccccc6c45)cc4oc(-c5ccccc5)nc34)cc21]

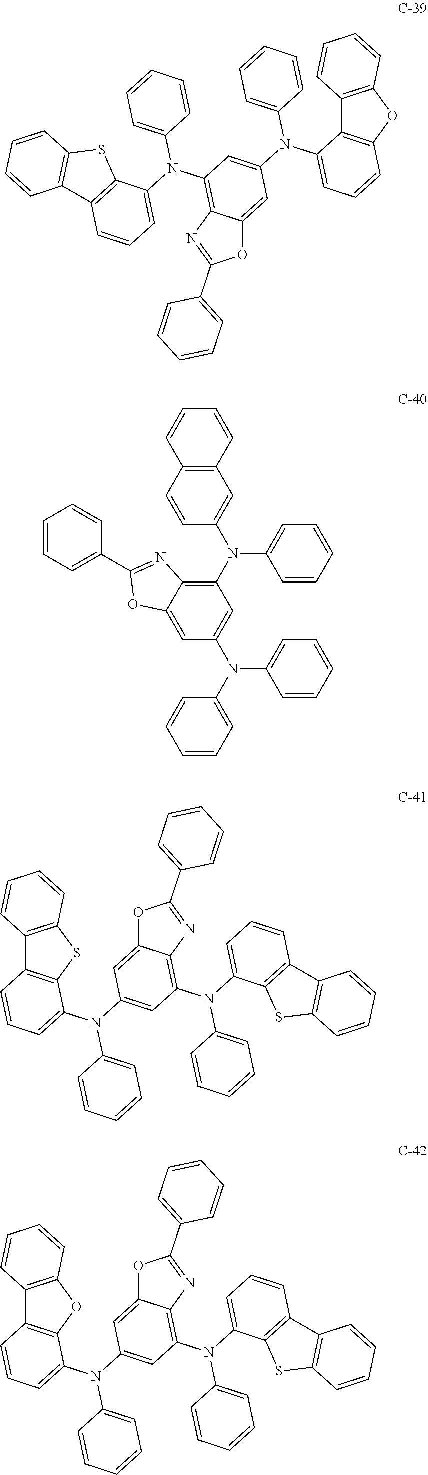 [SMILES: c1ccc(-c2nc3c(N(c4ccccc4)c4cccc5c4sc4ccccc45)cc(N(c4ccccc4)c4cccc5oc6ccccc6c45)cc3o2)cc1 ; c1ccc(-c2nc3c(N(c4ccccc4)c4ccc5ccccc5c4)cc(N(c4ccccc4)c4ccccc4)cc3o2)cc1 ; c1ccc(-c2nc3c(N(c4ccccc4)c4cccc5c4sc4ccccc45)cc(N(c4ccccc4)c4cccc5c4sc4ccccc45)cc3o2)cc1 ; c1ccc(-c2nc3c(N(c4ccccc4)c4cccc5c4sc4ccccc45)cc(N(c4ccccc4)c4cccc5c4oc4ccccc45)cc3o2)cc1]

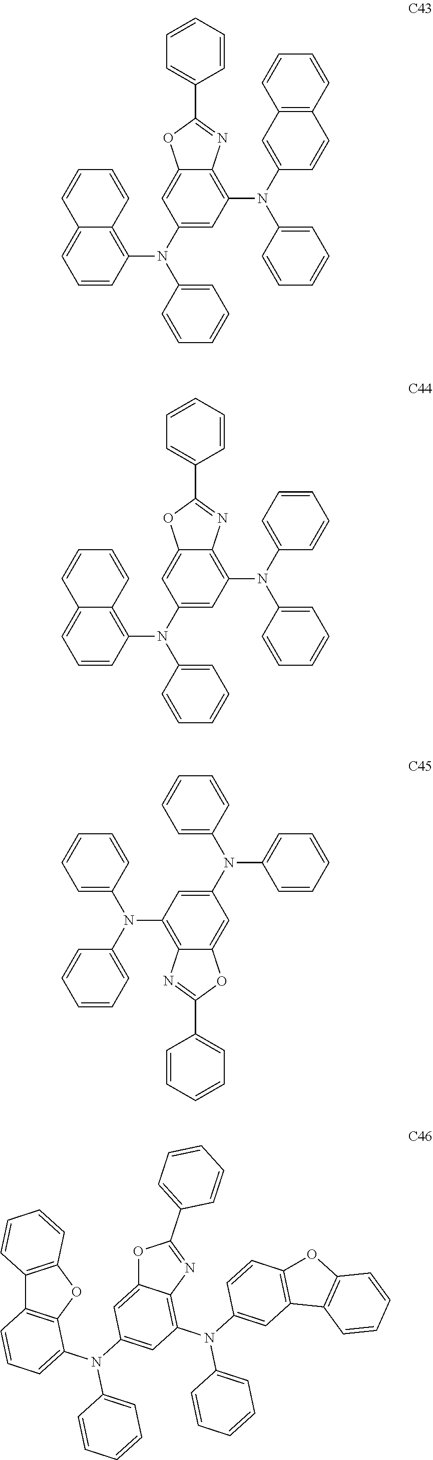

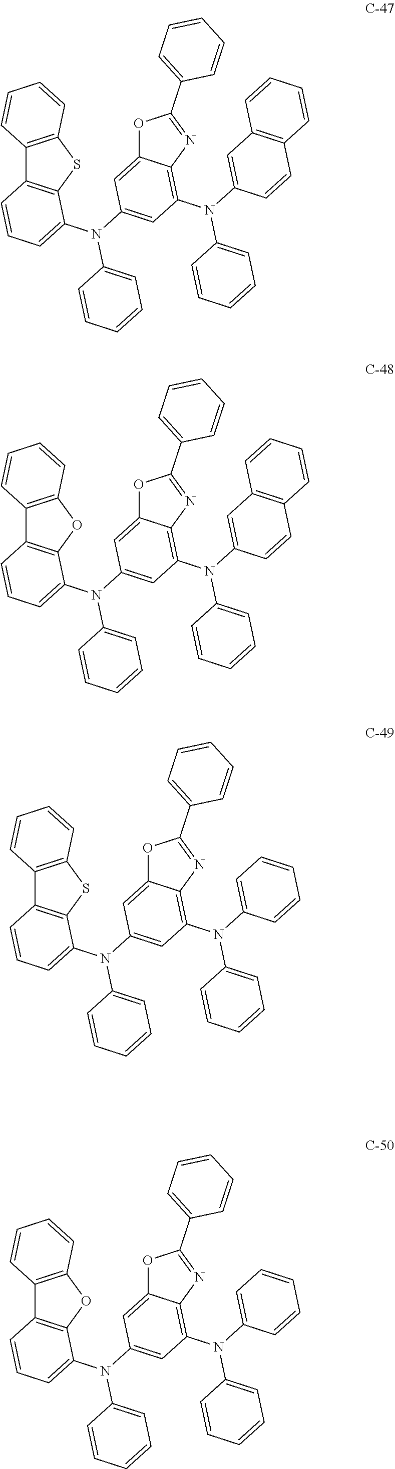 [SMILES: c1ccc(-c2nc3c(N(c4ccccc4)c4ccc5ccccc5c4)cc(N(c4ccccc4)c4cccc5c4sc4ccccc45)cc3o2)cc1 ; c1ccc(-c2nc3c(N(c4ccccc4)c4ccc5ccccc5c4)cc(N(c4ccccc4)c4cccc5c4oc4ccccc45)cc3o2)cc1 ; c1ccc(-c2nc3c(N(c4ccccc4)c4ccccc4)cc(N(c4ccccc4)c4cccc5c4sc4ccccc45)cc3o2)cc1 ; c1ccc(-c2nc3c(N(c4ccccc4)c4ccccc4)cc(N(c4ccccc4)c4cccc5c4oc4ccccc45)cc3o2)cc1]

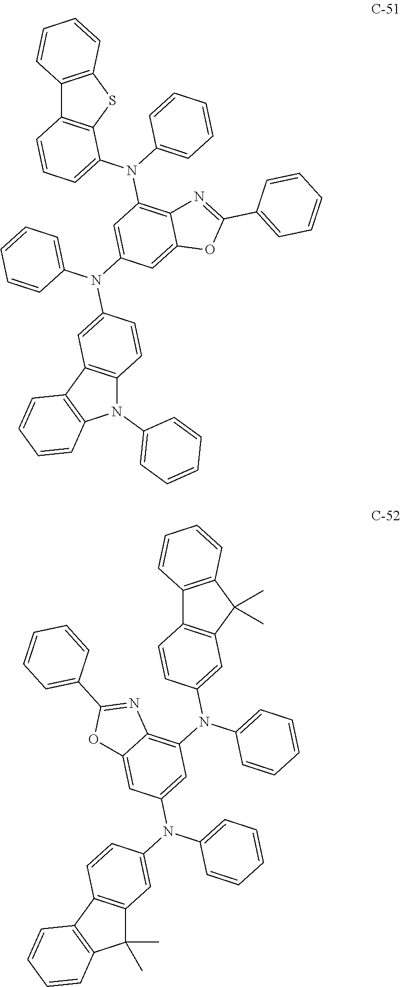 [SMILES: c1ccc(-c2nc3c(N(c4ccccc4)c4cccc5c4sc4ccccc45)cc(N(c4ccccc4)c4ccc5c(c4)c4ccccc4n5-c4ccccc4)cc3o2)cc1 ; CC1(C)c2ccccc2-c2ccc(N(c3ccccc3)c3cc(N(c4ccccc4)c4ccc5c(c4)C(C)(C)c4ccccc4-5)c4nc(-c5ccccc5)oc4c3)cc21]

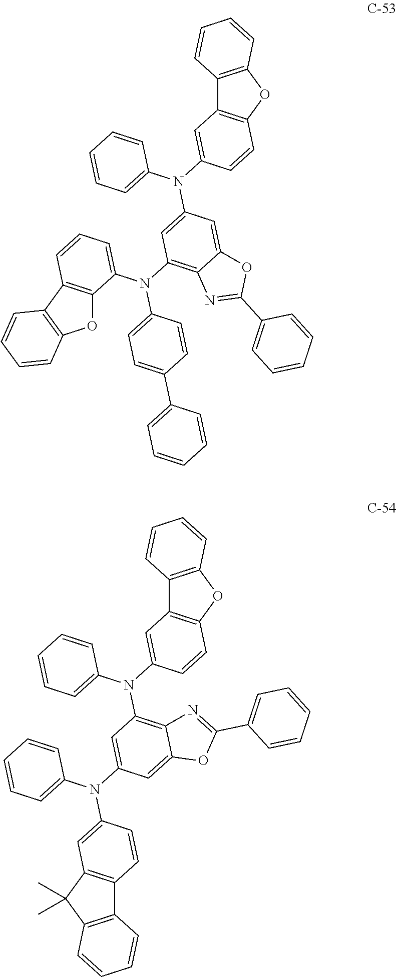 [SMILES: c1ccc(-c2ccc(N(c3cc(N(c4ccccc4)c4ccc5oc6ccccc6c5c4)cc4oc(-c5ccccc5)nc34)c3cccc4c3oc3ccccc34)cc2)cc1 ; CC1(C)c2ccccc2-c2ccc(N(c3ccccc3)c3cc(N(c4ccccc4)c4ccc5oc6ccccc6c5c4)c4nc(-c5ccccc5)oc4c3)cc21]

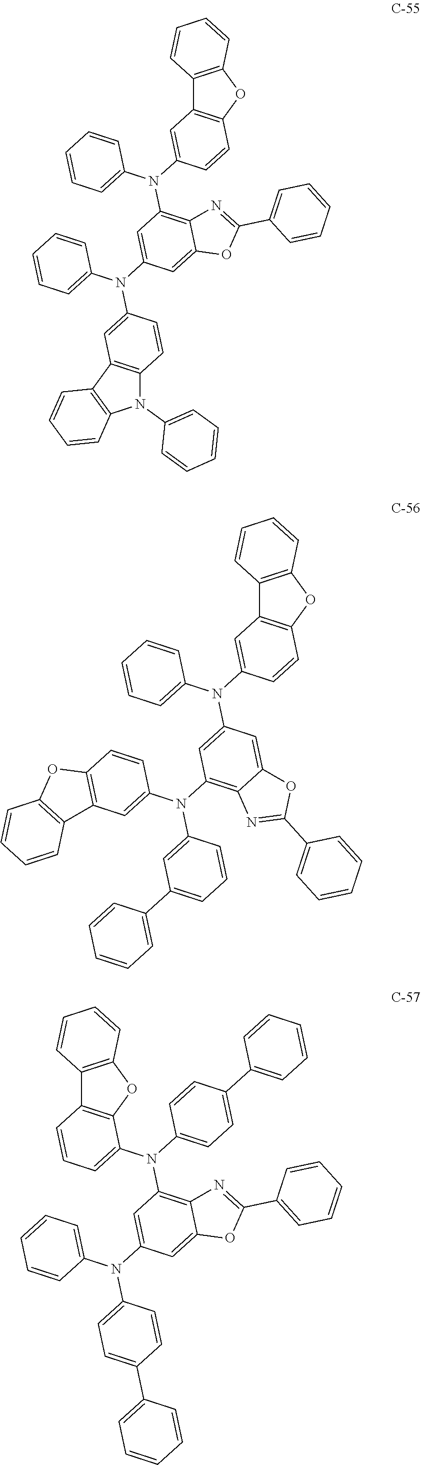 [SMILES: c1ccc(-c2nc3c(N(c4ccccc4)c4ccc5oc6ccccc6c5c4)cc(N(c4ccccc4)c4ccc5c(c4)c4ccccc4n5-c4ccccc4)cc3o2)cc1 ; c1ccc(-c2cccc(N(c3ccc4oc5ccccc5c4c3)c3cc(N(c4ccccc4)c4ccc5oc6ccccc6c5c4)cc4oc(-c5ccccc5)nc34)c2)cc1 ; c1ccc(-c2ccc(N(c3ccccc3)c3cc(N(c4ccc(-c5ccccc5)cc4)c4cccc5c4oc4ccccc45)c4nc(-c5ccccc5)oc4c3)cc2)cc1]

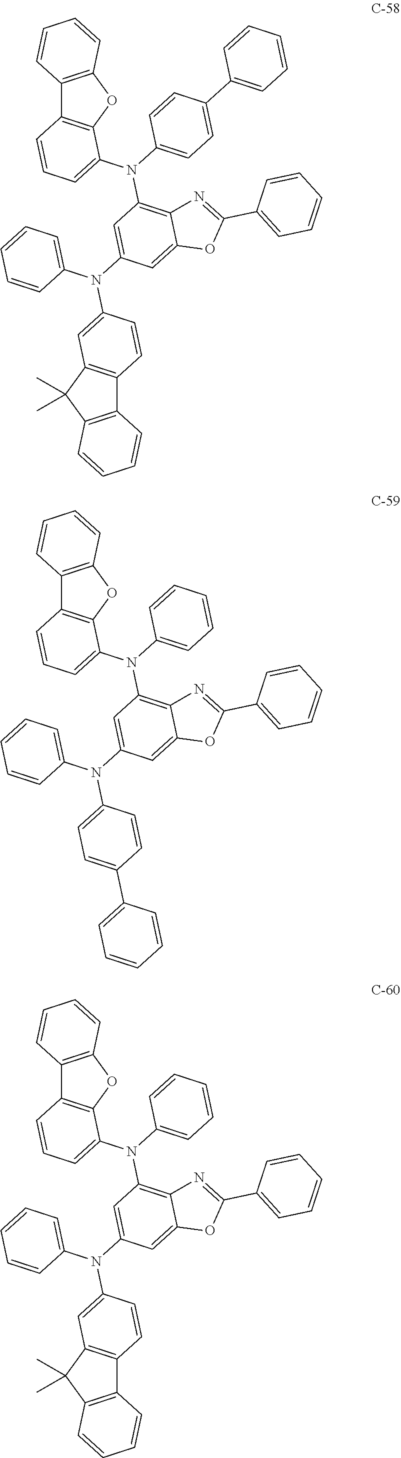

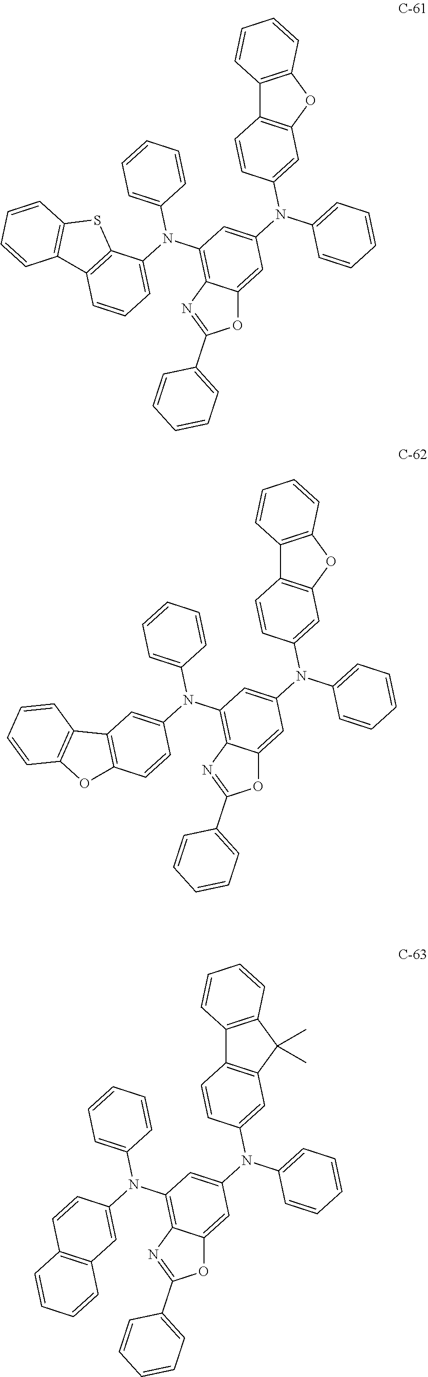 [SMILES: c1ccc(-c2nc3c(N(c4ccccc4)c4cccc5c4sc4ccccc45)cc(N(c4ccccc4)c4ccc5c(c4)oc4ccccc45)cc3o2)cc1 ; c1ccc(-c2nc3c(N(c4ccccc4)c4ccc5oc6ccccc6c5c4)cc(N(c4ccccc4)c4ccc5c(c4)oc4ccccc45)cc3o2)cc1 ; CC1(C)c2ccccc2-c2ccc(N(c3ccccc3)c3cc(N(c4ccccc4)c4ccc5ccccc5c4)c4nc(-c5ccccc5)oc4c3)cc21]

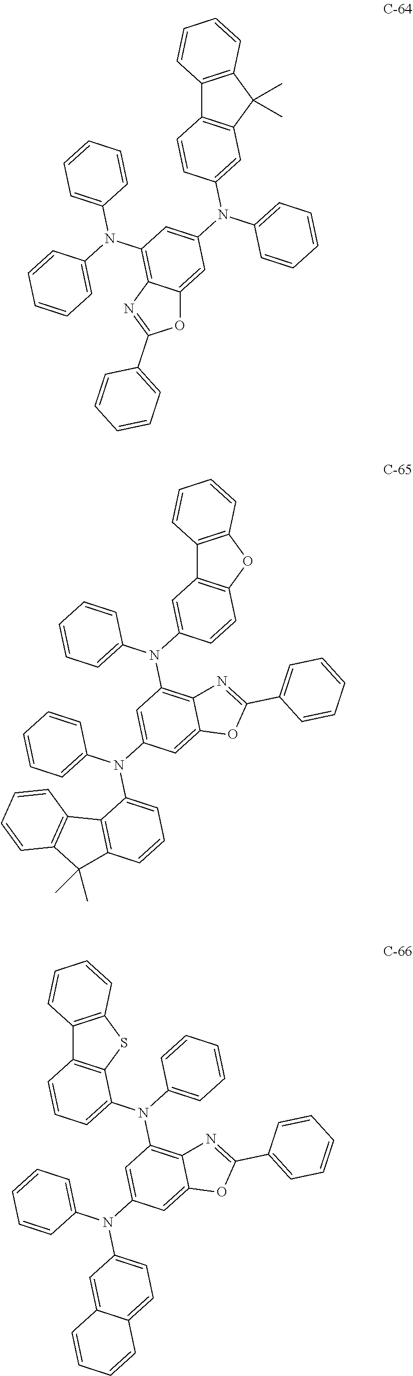 [SMILES: CC1(C)c2ccccc2-c2ccc(N(c3ccccc3)c3cc(N(c4ccccc4)c4ccccc4)c4nc(-c5ccccc5)oc4c3)cc21 ; CC1(C)c2ccccc2-c2c(N(c3ccccc3)c3cc(N(c4ccccc4)c4ccc5oc6ccccc6c5c4)c4nc(-c5ccccc5)oc4c3)cccc21 ; c1ccc(-c2nc3c(N(c4ccccc4)c4cccc5c4sc4ccccc45)cc(N(c4ccccc4)c4ccc5ccccc5c4)cc3o2)cc1]

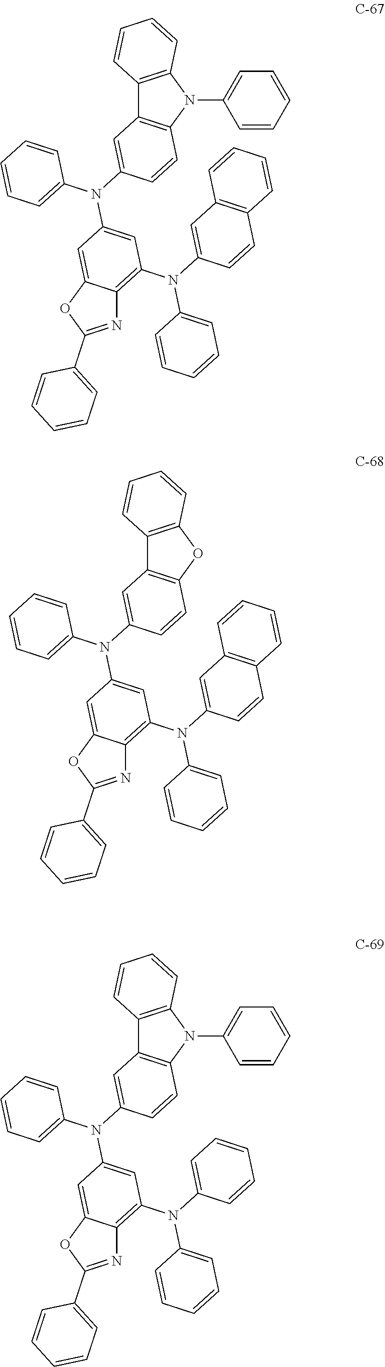 [SMILES: c1ccc(-c2nc3c(N(c4ccccc4)c4ccc5ccccc5c4)cc(N(c4ccccc4)c4ccc5c(c4)c4ccccc4n5-c4ccccc4)cc3o2)cc1 ; c1ccc(-c2nc3c(N(c4ccccc4)c4ccc5ccccc5c4)cc(N(c4ccccc4)c4ccc5oc6ccccc6c5c4)cc3o2)cc1 ; c1ccc(-c2nc3c(N(c4ccccc4)c4ccccc4)cc(N(c4ccccc4)c4ccc5c(c4)c4ccccc4n5-c4ccccc4)cc3o2)cc1]

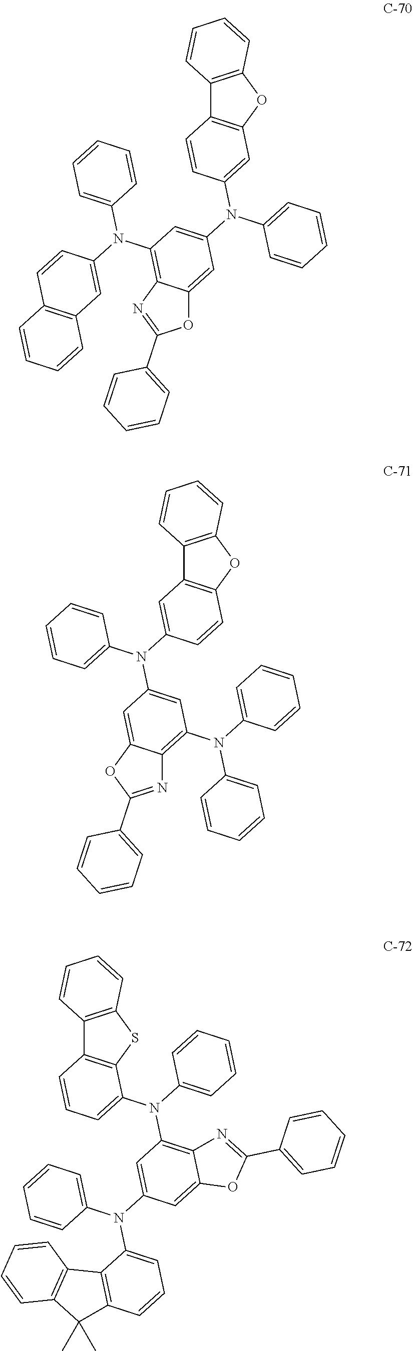 [SMILES: c1ccc(-c2nc3c(N(c4ccccc4)c4ccc5ccccc5c4)cc(N(c4ccccc4)c4ccc5c(c4)oc4ccccc45)cc3o2)cc1 ; c1ccc(-c2nc3c(N(c4ccccc4)c4ccccc4)cc(N(c4ccccc4)c4ccc5oc6ccccc6c5c4)cc3o2)cc1 ; CC1(C)c2ccccc2-c2c(N(c3ccccc3)c3cc(N(c4ccccc4)c4cccc5c4sc4ccccc45)c4nc(-c5ccccc5)oc4c3)cccc21]

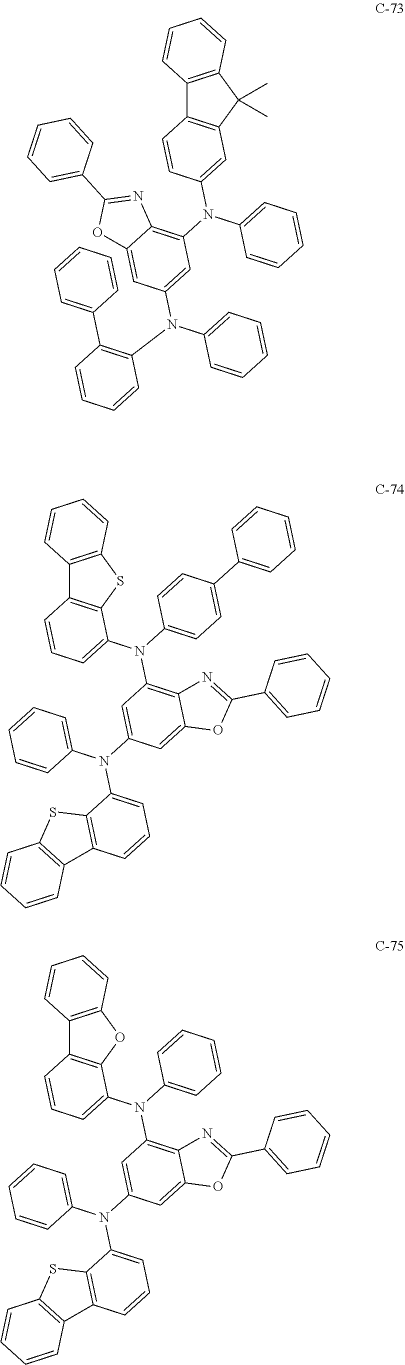 [SMILES: CC1(C)c2ccccc2-c2ccc(N(c3ccccc3)c3cc(N(c4ccccc4)c4ccccc4-c4ccccc4)cc4oc(-c5ccccc5)nc34)cc21 ; c1ccc(-c2ccc(N(c3cc(N(c4ccccc4)c4cccc5c4sc4ccccc45)cc4oc(-c5ccccc5)nc34)c3cccc4c3sc3ccccc34)cc2)cc1 ; c1ccc(-c2nc3c(N(c4ccccc4)c4cccc5c4oc4ccccc45)cc(N(c4ccccc4)c4cccc5c4sc4ccccc45)cc3o2)cc1]

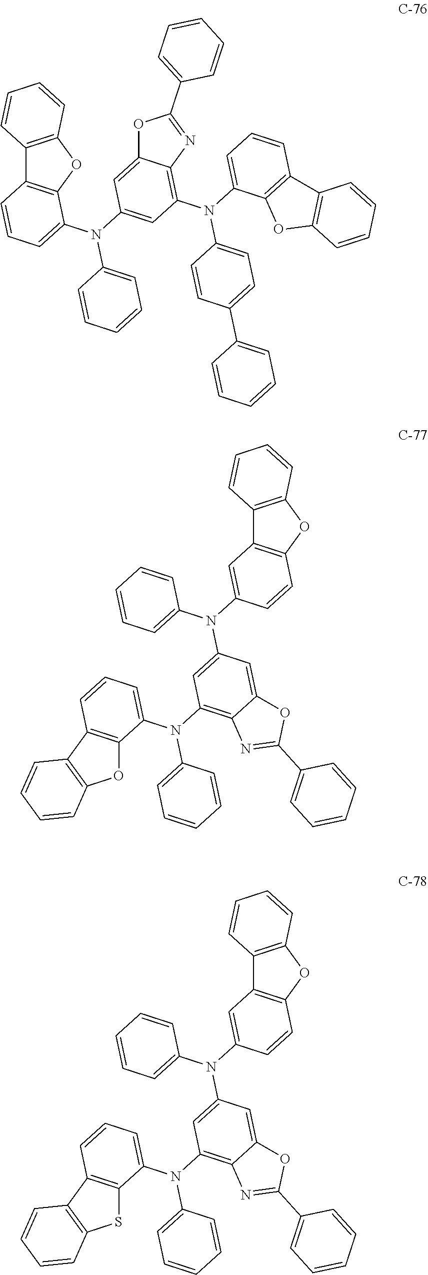

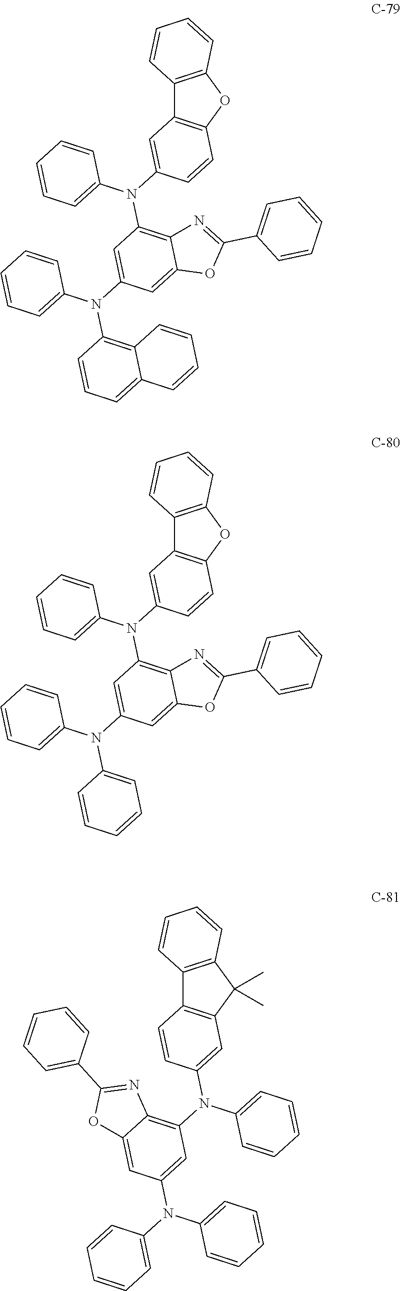 [SMILES: c1ccc(-c2nc3c(N(c4ccccc4)c4ccc5oc6ccccc6c5c4)cc(N(c4ccccc4)c4cccc5ccccc45)cc3o2)cc1 ; c1ccc(-c2nc3c(N(c4ccccc4)c4ccc5oc6ccccc6c5c4)cc(N(c4ccccc4)c4ccccc4)cc3o2)cc1 ; CC1(C)c2ccccc2-c2ccc(N(c3ccccc3)c3cc(N(c4ccccc4)c4ccccc4)cc4oc(-c5ccccc5)nc34)cc21]

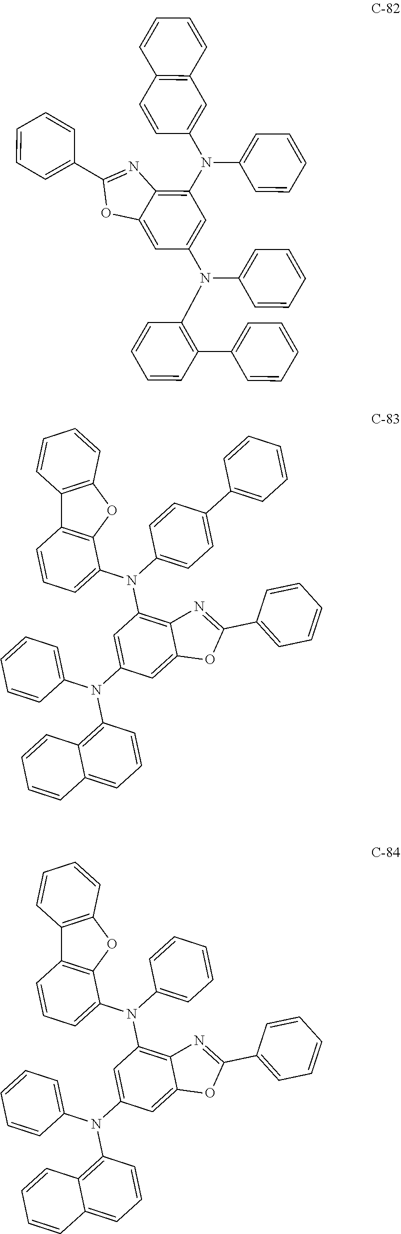 [SMILES: c1ccc(-c2nc3c(N(c4ccccc4)c4ccc5ccccc5c4)cc(N(c4ccccc4)c4ccccc4-c4ccccc4)cc3o2)cc1 ; c1ccc(-c2ccc(N(c3cc(N(c4ccccc4)c4cccc5ccccc45)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4cccc5ccccc45)cc3o2)cc1]

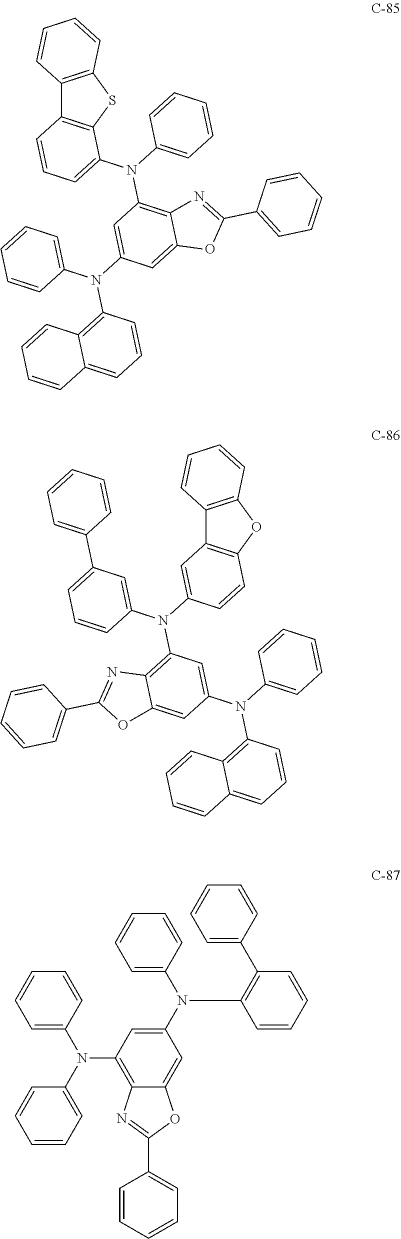 [SMILES: c1ccc(-c2nc3c(N(c4ccccc4)c4cccc5c4sc4ccccc45)cc(N(c4ccccc4)c4cccc5ccccc45)cc3o2)cc1 ; c1ccc(-c2cccc(N(c3ccc4oc5ccccc5c4c3)c3cc(N(c4ccccc4)c4cccc5ccccc45)cc4oc(-c5ccccc5)nc34)c2)cc1 ; c1ccc(-c2nc3c(N(c4ccccc4)c4ccccc4)cc(N(c4ccccc4)c4ccccc4-c4ccccc4)cc3o2)cc1]

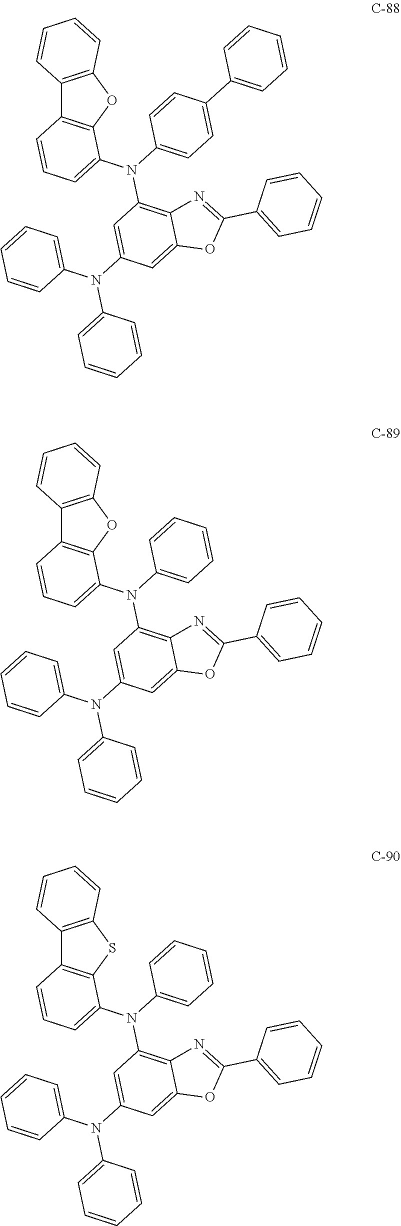 [SMILES: c1ccc(-c2ccc(N(c3cc(N(c4ccccc4)c4ccccc4)cc4oc(-c5ccccc5)nc34)c3cccc4c3oc3ccccc34)cc2)cc1 ; c1ccc(-c2nc3c(N(c4ccccc4)c4cccc5c4oc4ccccc45)cc(N(c4ccccc4)c4ccccc4)cc3o2)cc1 ; c1ccc(-c2nc3c(N(c4ccccc4)c4cccc5c4sc4ccccc45)cc(N(c4ccccc4)c4ccccc4)cc3o2)cc1]

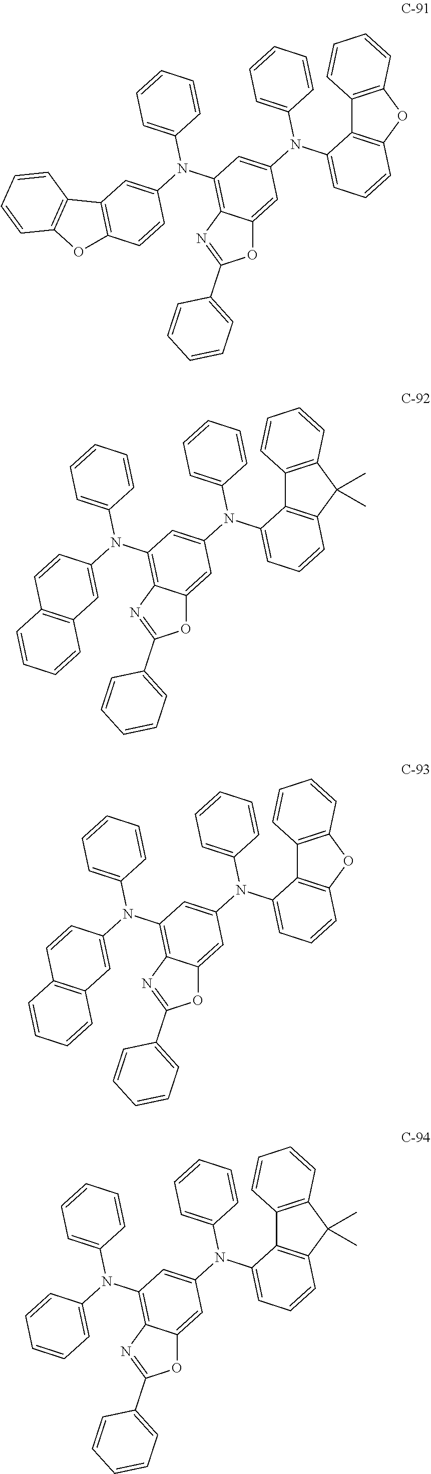 [SMILES: c1ccc(-c2nc3c(N(c4ccccc4)c4ccc5oc6ccccc6c5c4)cc(N(c4ccccc4)c4cccc5oc6ccccc6c45)cc3o2)cc1 ; CC1(C)c2ccccc2-c2c(N(c3ccccc3)c3cc(N(c4ccccc4)c4ccc5ccccc5c4)c4nc(-c5ccccc5)oc4c3)cccc21 ; c1ccc(-c2nc3c(N(c4ccccc4)c4ccc5ccccc5c4)cc(N(c4ccccc4)c4cccc5oc6ccccc6c45)cc3o2)cc1 ; CC1(C)c2ccccc2-c2c(N(c3ccccc3)c3cc(N(c4ccccc4)c4ccccc4)c4nc(-c5ccccc5)oc4c3)cccc21]

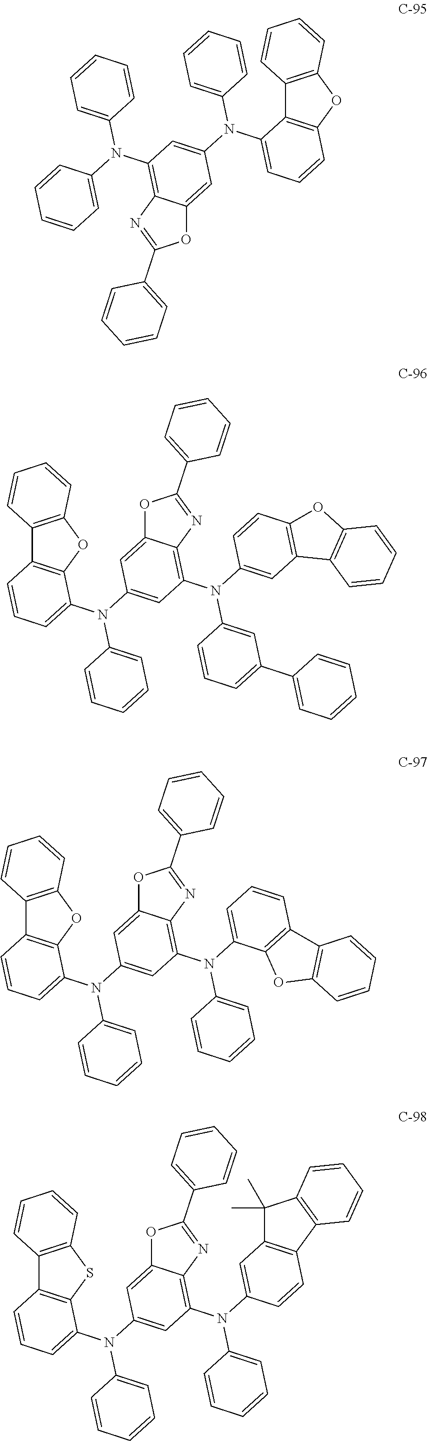 [SMILES: c1ccc(-c2nc3c(N(c4ccccc4)c4ccccc4)cc(N(c4ccccc4)c4cccc5oc6ccccc6c45)cc3o2)cc1 ; c1ccc(-c2cccc(N(c3ccc4oc5ccccc5c4c3)c3cc(N(c4ccccc4)c4cccc5c4oc4ccccc45)cc4oc(-c5ccccc5)nc34)c2)cc1 ; c1ccc(-c2nc3c(N(c4ccccc4)c4cccc5c4oc4ccccc45)cc(N(c4ccccc4)c4cccc5c4oc4ccccc45)cc3o2)cc1 ; CC1(C)c2ccccc2-c2ccc(N(c3ccccc3)c3cc(N(c4ccccc4)c4cccc5c4sc4ccccc45)cc4oc(-c5ccccc5)nc34)cc21]

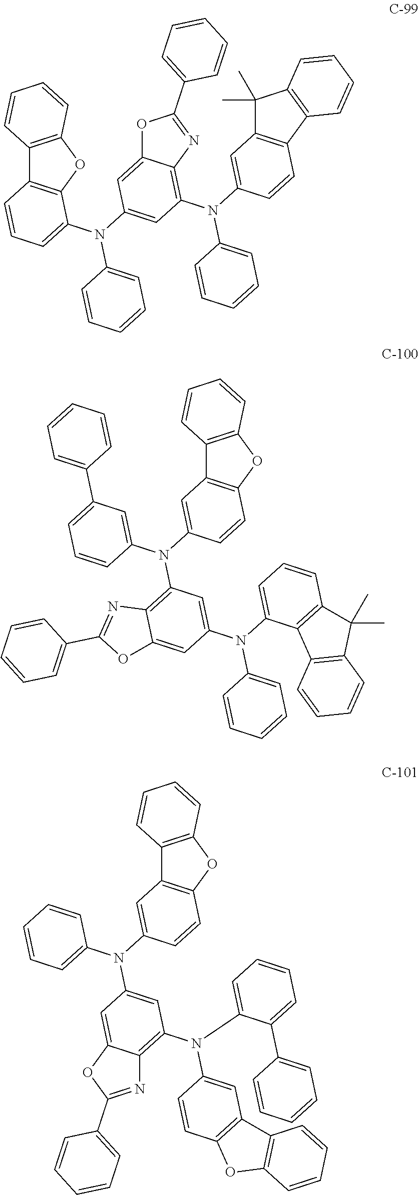 [SMILES: CC1(C)c2ccccc2-c2ccc(N(c3ccccc3)c3cc(N(c4ccccc4)c4cccc5c4oc4ccccc45)cc4oc(-c5ccccc5)nc34)cc21 ; CC1(C)c2ccccc2-c2c(N(c3ccccc3)c3cc(N(c4cccc(-c5ccccc5)c4)c4ccc5oc6ccccc6c5c4)c4nc(-c5ccccc5)oc4c3)cccc21 ; c1ccc(-c2nc3c(N(c4ccc5oc6ccccc6c5c4)c4ccccc4-c4ccccc4)cc(N(c4ccccc4)c4ccc5oc6ccccc6c5c4)cc3o2)cc1]

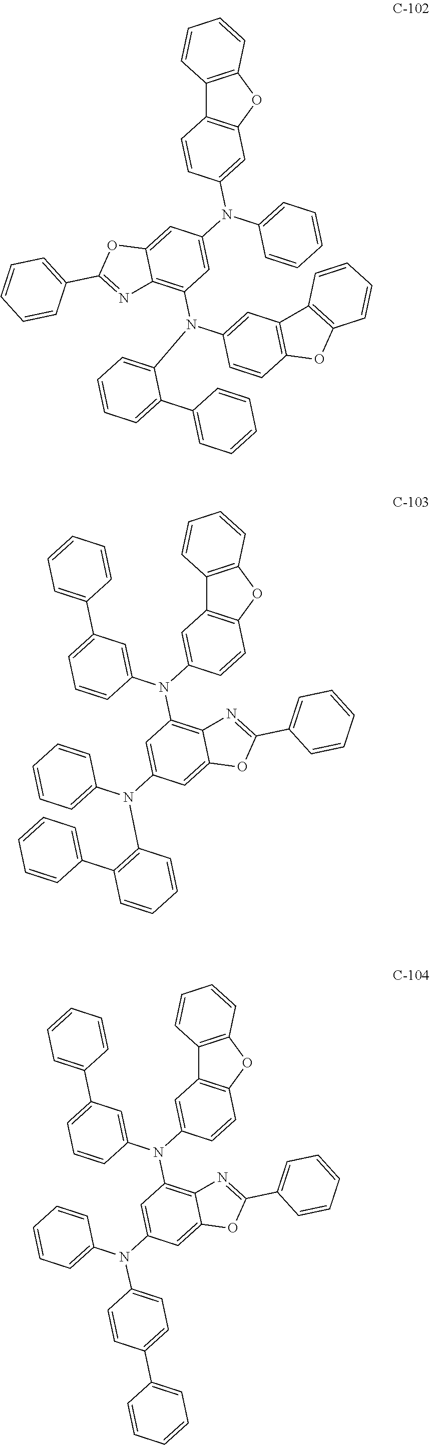 [SMILES: c1ccc(-c2nc3c(N(c4ccc5oc6ccccc6c5c4)c4ccccc4-c4ccccc4)cc(N(c4ccccc4)c4ccc5c(c4)oc4ccccc45)cc3o2)cc1 ; c1ccc(-c2cccc(N(c3ccc4oc5ccccc5c4c3)c3cc(N(c4ccccc4)c4ccccc4-c4ccccc4)cc4oc(-c5ccccc5)nc34)c2)cc1 ; c1ccc(-c2ccc(N(c3ccccc3)c3cc(N(c4cccc(-c5ccccc5)c4)c4ccc5oc6ccccc6c5c4)c4nc(-c5ccccc5)oc4c3)cc2)cc1]

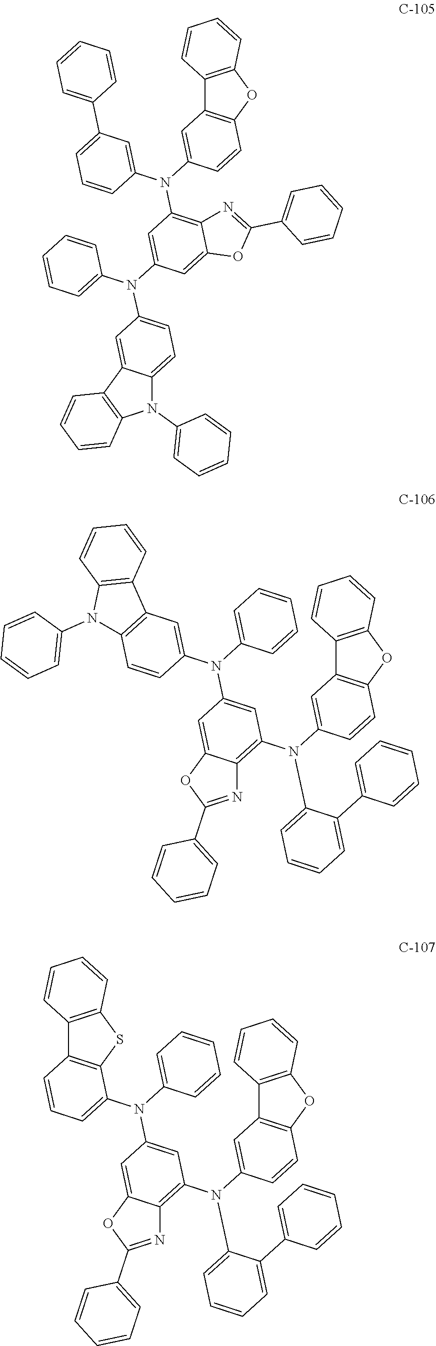 [SMILES: c1ccc(-c2cccc(N(c3ccc4oc5ccccc5c4c3)c3cc(N(c4ccccc4)c4ccc5c(c4)c4ccccc4n5-c4ccccc4)cc4oc(-c5ccccc5)nc34)c2)cc1 ; c1ccc(-c2nc3c(N(c4ccc5oc6ccccc6c5c4)c4ccccc4-c4ccccc4)cc(N(c4ccccc4)c4ccc5c(c4)c4ccccc4n5-c4ccccc4)cc3o2)cc1 ; c1ccc(-c2nc3c(N(c4ccc5oc6ccccc6c5c4)c4ccccc4-c4ccccc4)cc(N(c4ccccc4)c4cccc5c4sc4ccccc45)cc3o2)cc1]

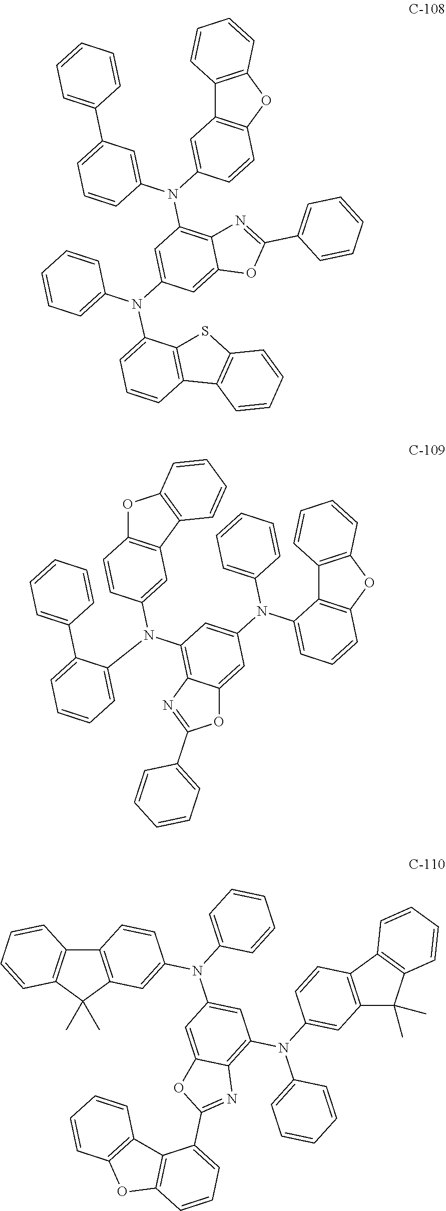 [SMILES: c1ccc(-c2cccc(N(c3ccc4oc5ccccc5c4c3)c3cc(N(c4ccccc4)c4cccc5c4sc4ccccc45)cc4oc(-c5ccccc5)nc34)c2)cc1 ; c1ccc(-c2nc3c(N(c4ccc5oc6ccccc6c5c4)c4ccccc4-c4ccccc4)cc(N(c4ccccc4)c4cccc5oc6ccccc6c45)cc3o2)cc1 ; CC1(C)c2ccccc2-c2ccc(N(c3ccccc3)c3cc(N(c4ccccc4)c4ccc5c(c4)C(C)(C)c4ccccc4-5)c4nc(-c5cccc6oc7ccccc7c56)oc4c3)cc21]

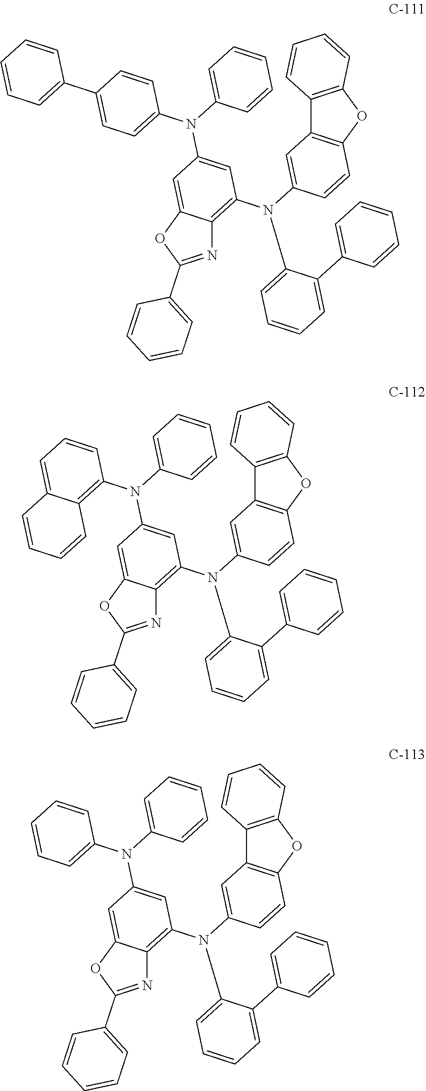 [SMILES: c1ccc(-c2ccc(N(c3ccccc3)c3cc(N(c4ccc5oc6ccccc6c5c4)c4ccccc4-c4ccccc4)c4nc(-c5ccccc5)oc4c3)cc2)cc1 ; c1ccc(-c2nc3c(N(c4ccc5oc6ccccc6c5c4)c4ccccc4-c4ccccc4)cc(N(c4ccccc4)c4cccc5ccccc45)cc3o2)cc1 ; c1ccc(-c2nc3c(N(c4ccc5oc6ccccc6c5c4)c4ccccc4-c4ccccc4)cc(N(c4ccccc4)c4ccccc4)cc3o2)cc1]

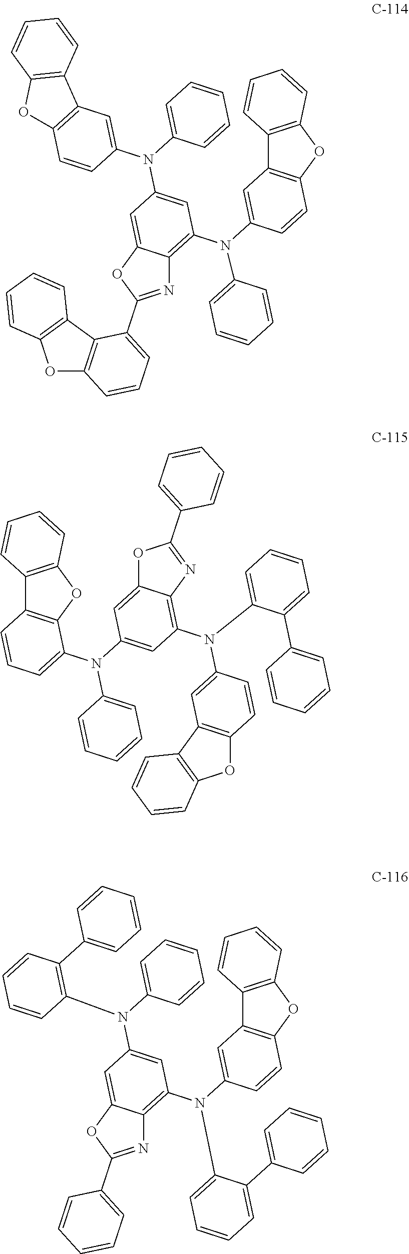 [SMILES: c1ccc(N(c2cc(N(c3ccccc3)c3ccc4oc5ccccc5c4c3)c3nc(-c4cccc5oc6ccccc6c45)oc3c2)c2ccc3oc4ccccc4c3c2)cc1 ; c1ccc(-c2nc3c(N(c4ccc5oc6ccccc6c5c4)c4ccccc4-c4ccccc4)cc(N(c4ccccc4)c4cccc5c4oc4ccccc45)cc3o2)cc1 ; c1ccc(-c2nc3c(N(c4ccc5oc6ccccc6c5c4)c4ccccc4-c4ccccc4)cc(N(c4ccccc4)c4ccccc4-c4ccccc4)cc3o2)cc1]

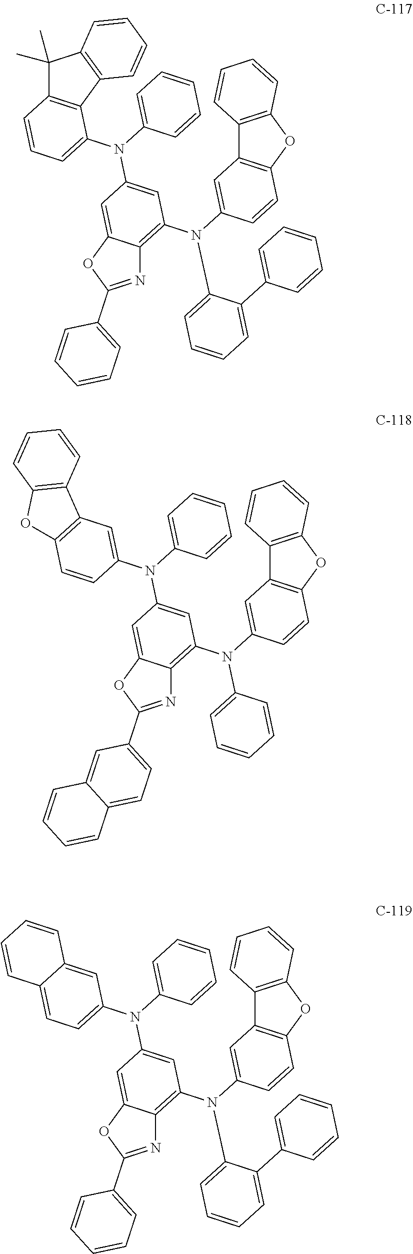 [SMILES: CC1(C)c2ccccc2-c2c(N(c3ccccc3)c3cc(N(c4ccc5oc6ccccc6c5c4)c4ccccc4-c4ccccc4)c4nc(-c5ccccc5)oc4c3)cccc21 ; c1ccc(N(c2cc(N(c3ccccc3)c3ccc4oc5ccccc5c4c3)c3nc(-c4ccc5ccccc5c4)oc3c2)c2ccc3oc4ccccc4c3c2)cc1 ; c1ccc(-c2nc3c(N(c4ccc5oc6ccccc6c5c4)c4ccccc4-c4ccccc4)cc(N(c4ccccc4)c4ccc5ccccc5c4)cc3o2)cc1]

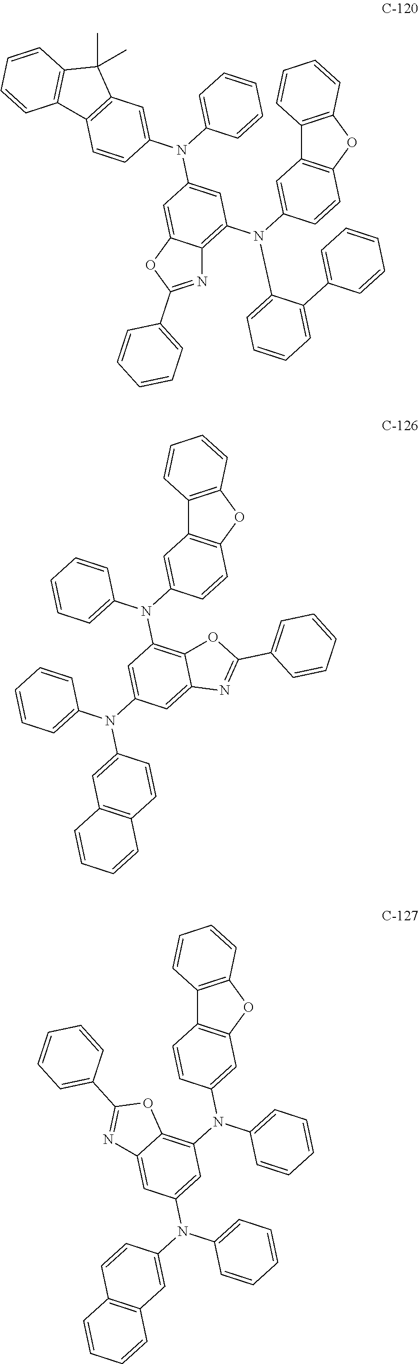 [SMILES: CC1(C)c2ccccc2-c2ccc(N(c3ccccc3)c3cc(N(c4ccc5oc6ccccc6c5c4)c4ccccc4-c4ccccc4)c4nc(-c5ccccc5)oc4c3)cc21 ; c1ccc(-c2nc3cc(N(c4ccccc4)c4ccc5ccccc5c4)cc(N(c4ccccc4)c4ccc5oc6ccccc6c5c4)c3o2)cc1 ; c1ccc(-c2nc3cc(N(c4ccccc4)c4ccc5ccccc5c4)cc(N(c4ccccc4)c4ccc5c(c4)oc4ccccc45)c3o2)cc1]

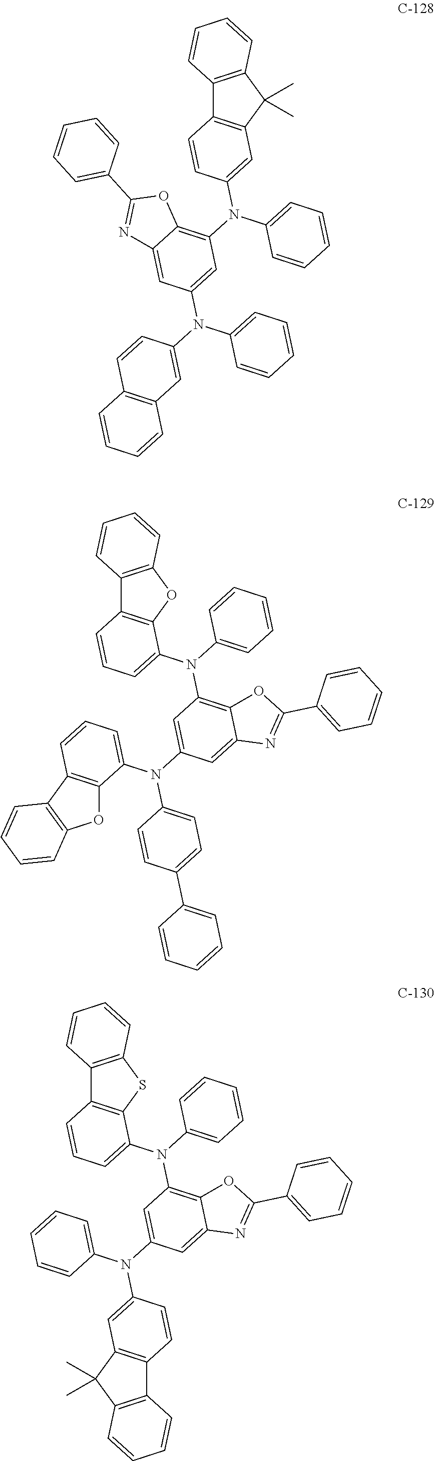 [SMILES: CC1(C)c2ccccc2-c2ccc(N(c3ccccc3)c3cc(N(c4ccccc4)c4ccc5ccccc5c4)cc4nc(-c5ccccc5)oc34)cc21 ; c1ccc(-c2ccc(N(c3cc(N(c4ccccc4)c4cccc5c4oc4ccccc45)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4cccc5c4sc4ccccc45)c4oc(-c5ccccc5)nc4c3)cc21]

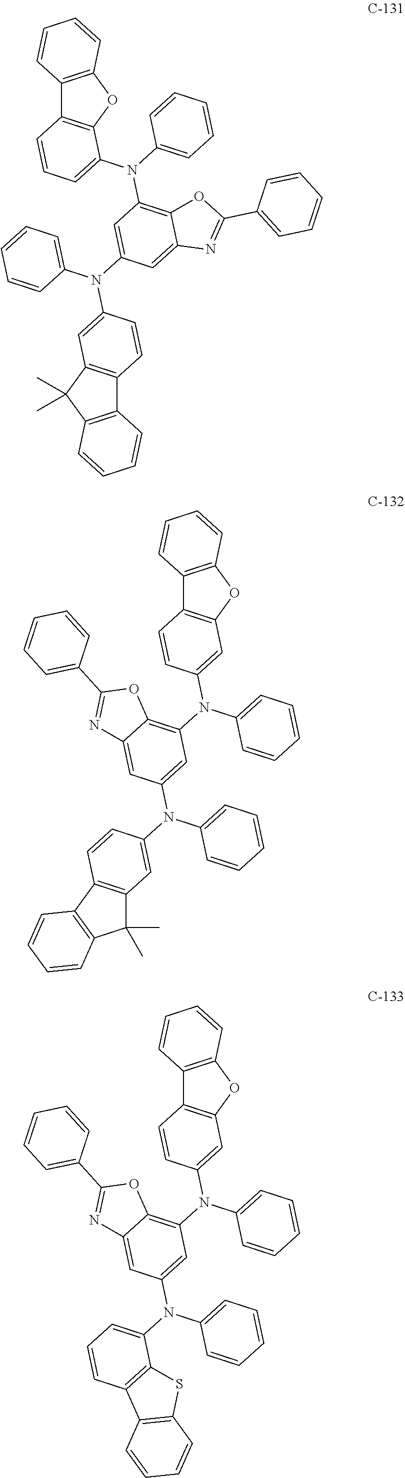 [SMILES: CC1(C)c2ccccc2-c2ccc(N(c3ccccc3)c3cc(N(c4ccccc4)c4cccc5c4oc4ccccc45)c4oc(-c5ccccc5)nc4c3)cc21 ; CC1(C)c2ccccc2-c2ccc(N(c3ccccc3)c3cc(N(c4ccccc4)c4ccc5c(c4)oc4ccccc45)c4oc(-c5ccccc5)nc4c3)cc21 ; c1ccc(-c2nc3cc(N(c4ccccc4)c4cccc5c4sc4ccccc45)cc(N(c4ccccc4)c4ccc5c(c4)oc4ccccc45)c3o2)cc1]

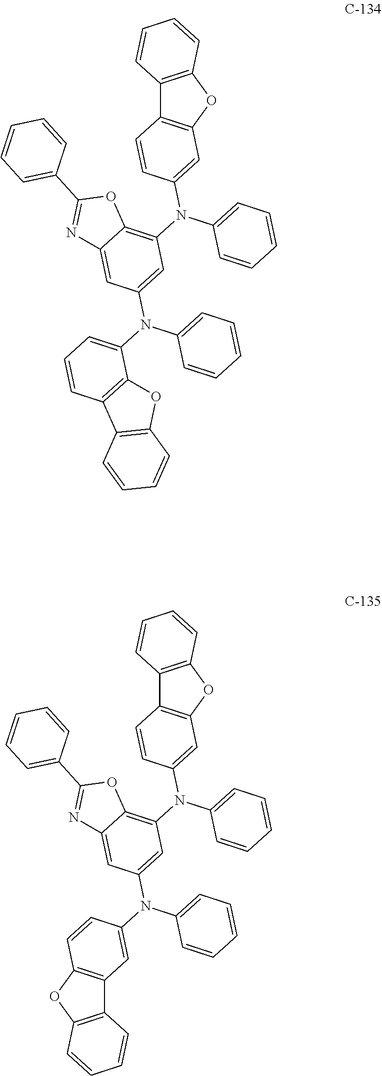 [SMILES: c1ccc(-c2nc3cc(N(c4ccccc4)c4cccc5c4oc4ccccc45)cc(N(c4ccccc4)c4ccc5c(c4)oc4ccccc45)c3o2)cc1 ; c1ccc(-c2nc3cc(N(c4ccccc4)c4ccc5oc6ccccc6c5c4)cc(N(c4ccccc4)c4ccc5c(c4)oc4ccccc45)c3o2)cc1]

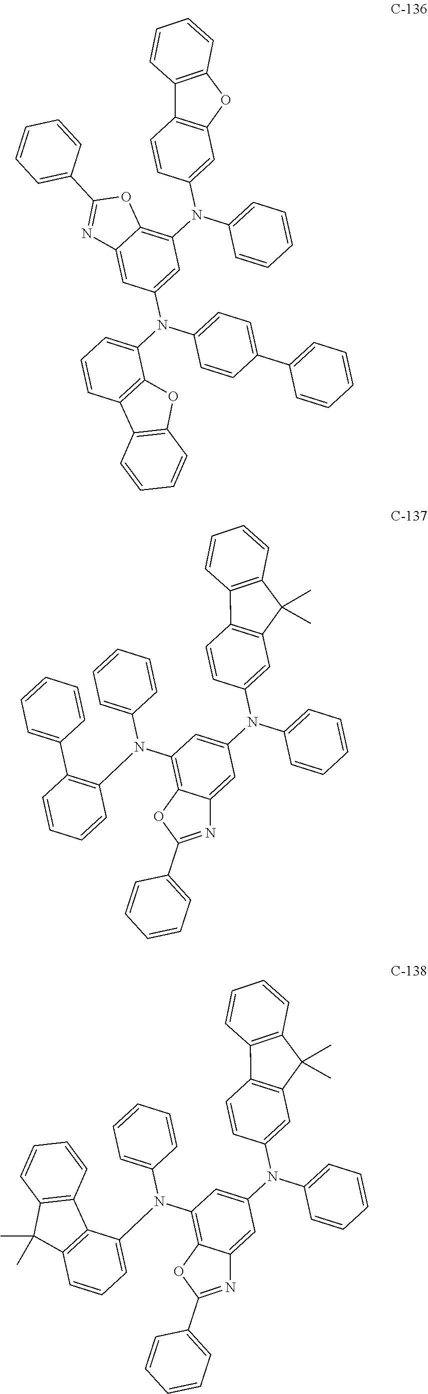 [SMILES: c1ccc(-c2ccc(N(c3cc(N(c4ccccc4)c4ccc5c(c4)oc4ccccc45)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4ccccc4-c4ccccc4)c4oc(-c5ccccc5)nc4c3)cc21 ; CC1(C)c2ccccc2-c2ccc(N(c3ccccc3)c3cc(N(c4ccccc4)c4cccc5c4-c4ccccc4C5(C)C)c4oc(-c5ccccc5)nc4c3)cc21]

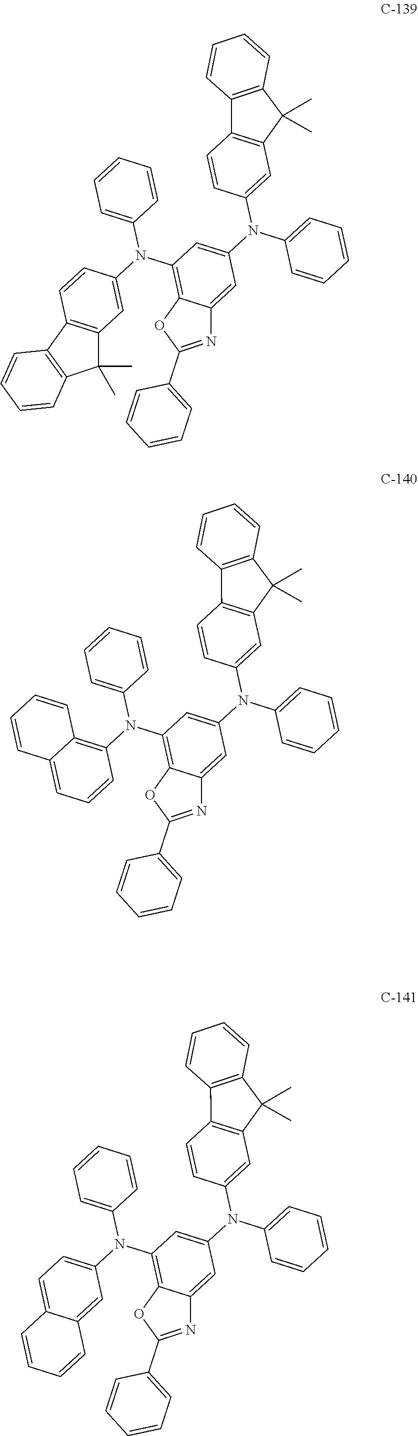 [SMILES: CC1(C)c2ccccc2-c2ccc(N(c3ccccc3)c3cc(N(c4ccccc4)c4ccc5c(c4)C(C)(C)c4ccccc4-5)c4oc(-c5ccccc5)nc4c3)cc21 ; CC1(C)c2ccccc2-c2ccc(N(c3ccccc3)c3cc(N(c4ccccc4)c4cccc5ccccc45)c4oc(-c5ccccc5)nc4c3)cc21 ; CC1(C)c2ccccc2-c2ccc(N(c3ccccc3)c3cc(N(c4ccccc4)c4ccc5ccccc5c4)c4oc(-c5ccccc5)nc4c3)cc21]

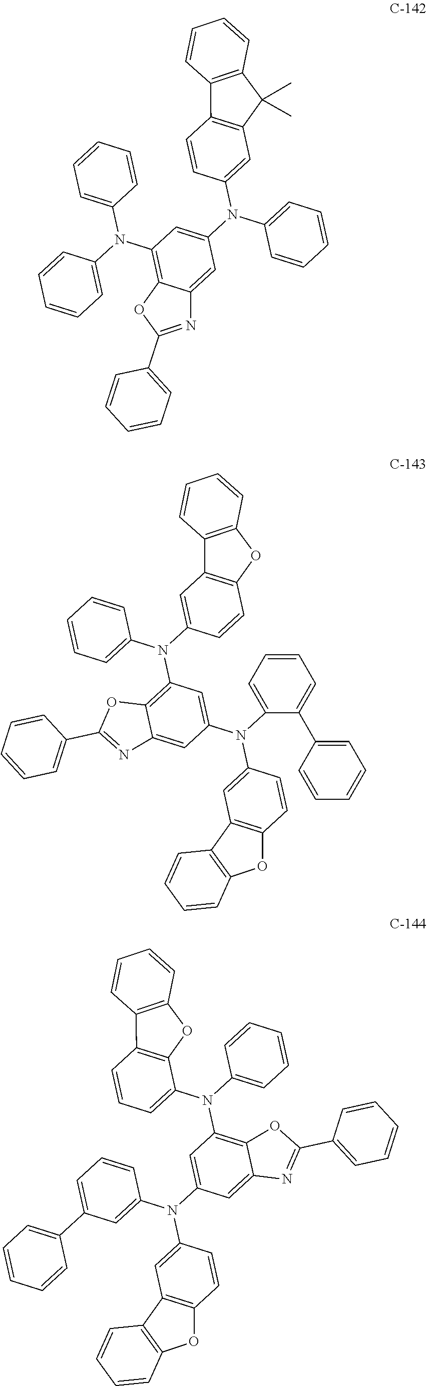 [SMILES: CC1(C)c2ccccc2-c2ccc(N(c3ccccc3)c3cc(N(c4ccccc4)c4ccccc4)c4oc(-c5ccccc5)nc4c3)cc21 ; c1ccc(-c2nc3cc(N(c4ccc5oc6ccccc6c5c4)c4ccccc4-c4ccccc4)cc(N(c4ccccc4)c4ccc5oc6ccccc6c5c4)c3o2)cc1 ; c1ccc(-c2cccc(N(c3cc(N(c4ccccc4)c4cccc5c4oc4ccccc45)c4oc(-c5ccccc5)nc4c3)c3ccc4oc5ccccc5c4c3)c2)cc1]

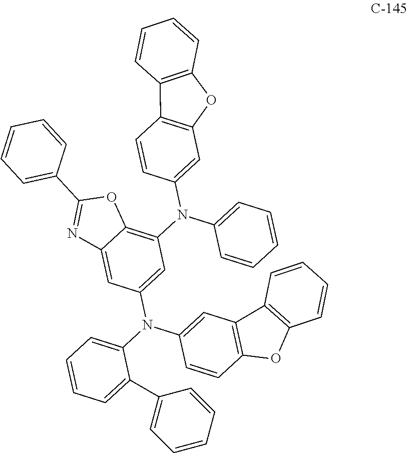 [SMILES: c1ccc(-c2nc3cc(N(c4ccc5oc6ccccc6c5c4)c4ccccc4-c4ccccc4)cc(N(c4ccccc4)c4ccc5c(c4)oc4ccccc45)c3o2)cc1]

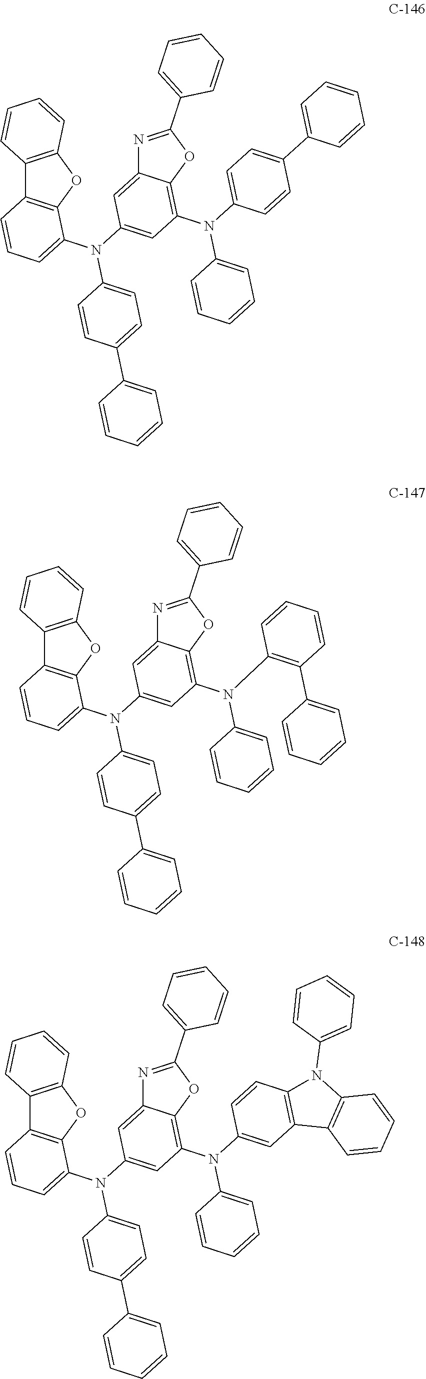 [SMILES: c1ccc(-c2ccc(N(c3ccccc3)c3cc(N(c4ccc(-c5ccccc5)cc4)c4cccc5c4oc4ccccc45)cc4nc(-c5ccccc5)oc34)cc2)cc1 ; c1ccc(-c2ccc(N(c3cc(N(c4ccccc4)c4ccccc4-c4ccccc4)c4oc(-c5ccccc5)nc4c3)c3cccc4c3oc3ccccc34)cc2)cc1 ; c1ccc(-c2ccc(N(c3cc(N(c4ccccc4)c4ccc5c(c4)c4ccccc4n5-c4ccccc4)c4oc(-c5ccccc5)nc4c3)c3cccc4c3oc3ccccc34)cc2)cc1]

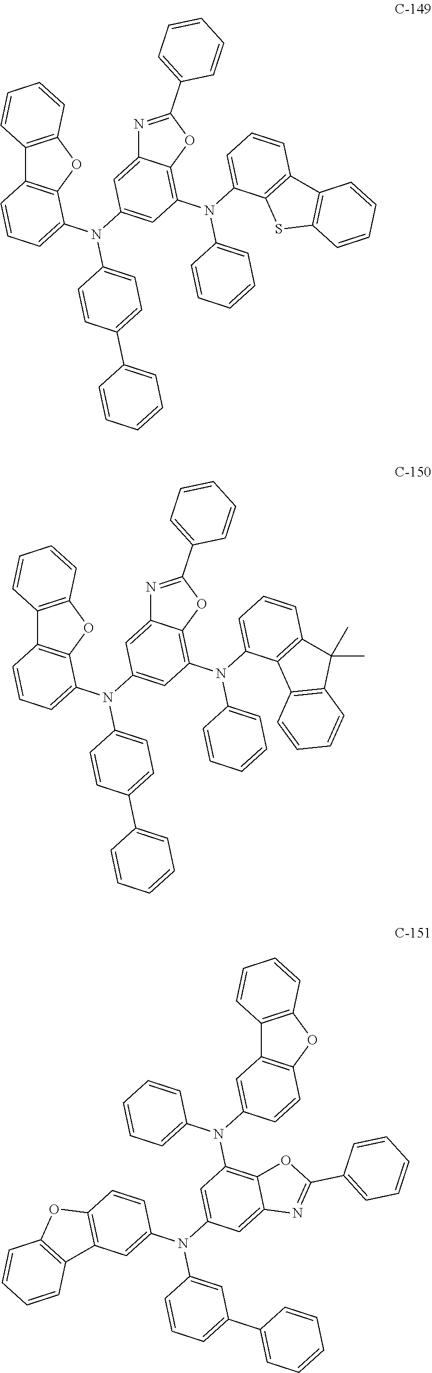 [SMILES: c1ccc(-c2ccc(N(c3cc(N(c4ccccc4)c4cccc5c4sc4ccccc45)c4oc(-c5ccccc5)nc4c3)c3cccc4c3oc3ccccc34)cc2)cc1 ; CC1(C)c2ccccc2-c2c(N(c3ccccc3)c3cc(N(c4ccc(-c5ccccc5)cc4)c4cccc5c4oc4ccccc45)cc4nc(-c5ccccc5)oc34)cccc21 ; c1ccc(-c2cccc(N(c3cc(N(c4ccccc4)c4ccc5oc6ccccc6c5c4)c4oc(-c5ccccc5)nc4c3)c3ccc4oc5ccccc5c4c3)c2)cc1]

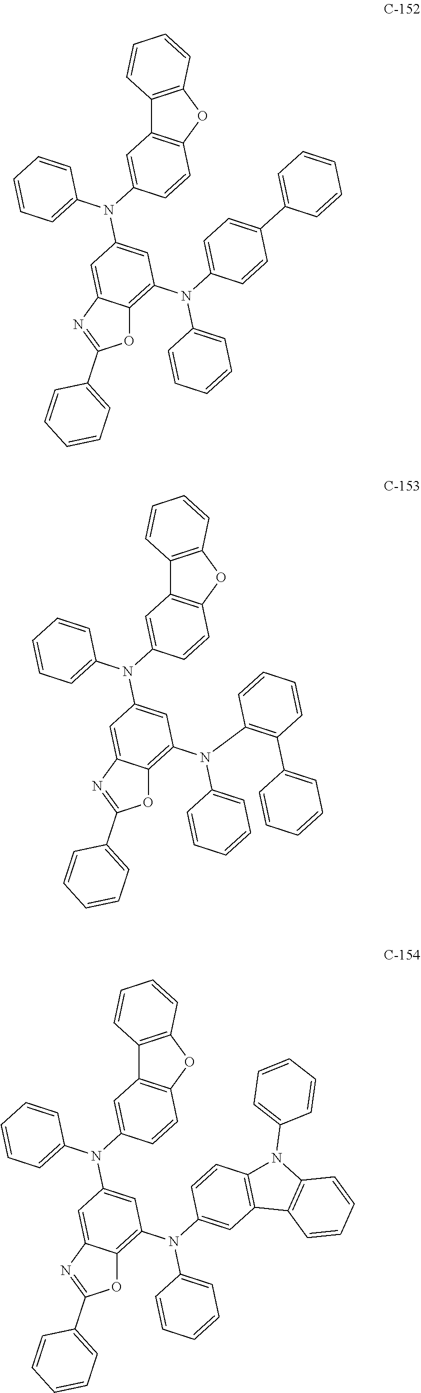 [SMILES: c1ccc(-c2ccc(N(c3ccccc3)c3cc(N(c4ccccc4)c4ccc5oc6ccccc6c5c4)cc4nc(-c5ccccc5)oc34)cc2)cc1 ; c1ccc(-c2nc3cc(N(c4ccccc4)c4ccc5oc6ccccc6c5c4)cc(N(c4ccccc4)c4ccccc4-c4ccccc4)c3o2)cc1 ; c1ccc(-c2nc3cc(N(c4ccccc4)c4ccc5oc6ccccc6c5c4)cc(N(c4ccccc4)c4ccc5c(c4)c4ccccc4n5-c4ccccc4)c3o2)cc1]

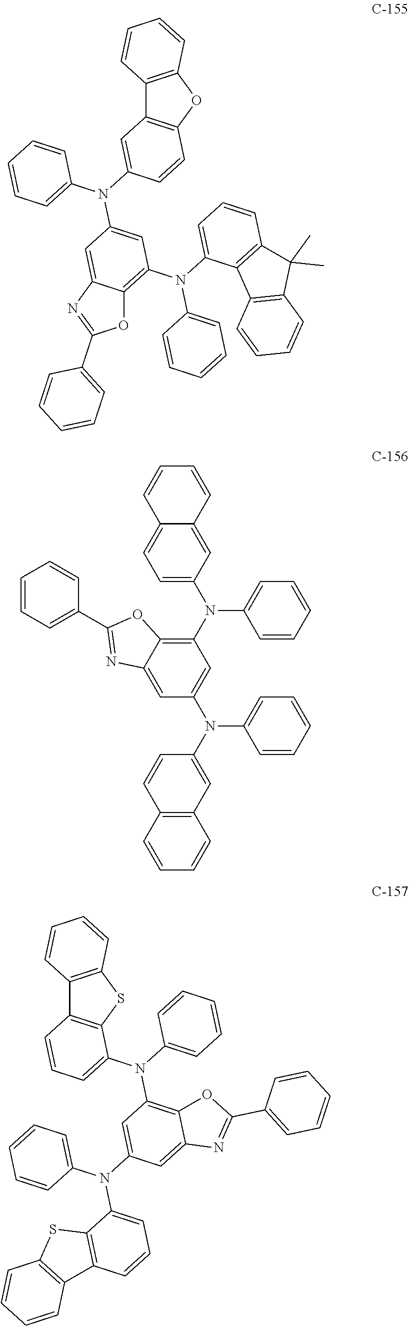 [SMILES: CC1(C)c2ccccc2-c2c(N(c3ccccc3)c3cc(N(c4ccccc4)c4ccc5oc6ccccc6c5c4)cc4nc(-c5ccccc5)oc34)cccc21 ; c1ccc(-c2nc3cc(N(c4ccccc4)c4ccc5ccccc5c4)cc(N(c4ccccc4)c4ccc5ccccc5c4)c3o2)cc1 ; c1ccc(-c2nc3cc(N(c4ccccc4)c4cccc5c4sc4ccccc45)cc(N(c4ccccc4)c4cccc5c4sc4ccccc45)c3o2)cc1]

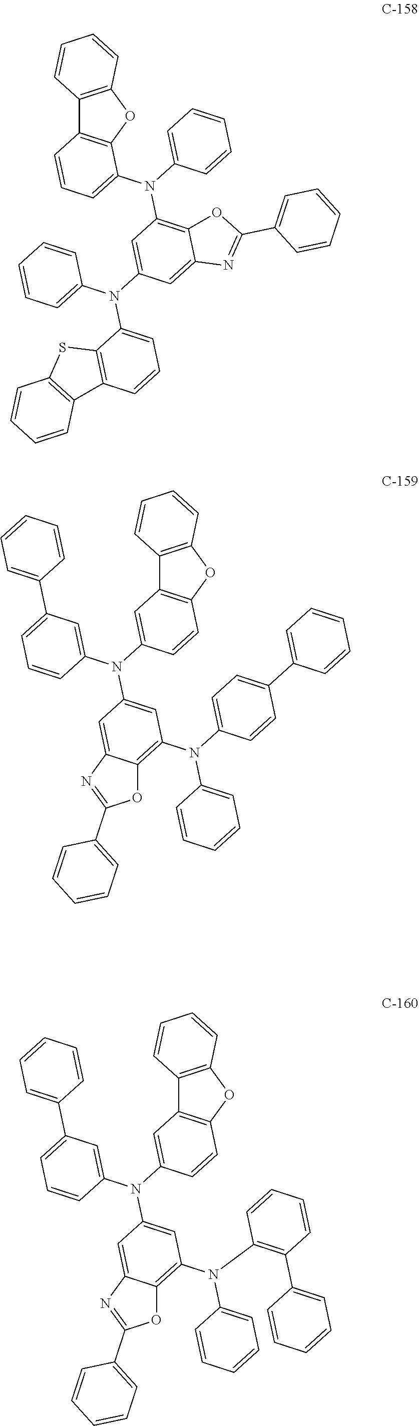 [SMILES: c1ccc(-c2nc3cc(N(c4ccccc4)c4cccc5c4sc4ccccc45)cc(N(c4ccccc4)c4cccc5c4oc4ccccc45)c3o2)cc1 ; c1ccc(-c2ccc(N(c3ccccc3)c3cc(N(c4cccc(-c5ccccc5)c4)c4ccc5oc6ccccc6c5c4)cc4nc(-c5ccccc5)oc34)cc2)cc1 ; c1ccc(-c2cccc(N(c3cc(N(c4ccccc4)c4ccccc4-c4ccccc4)c4oc(-c5ccccc5)nc4c3)c3ccc4oc5ccccc5c4c3)c2)cc1]

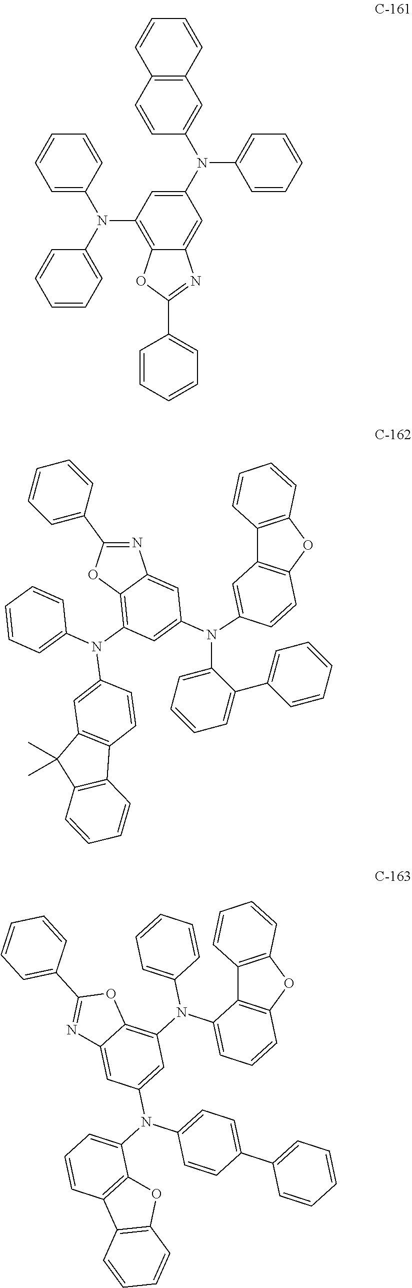 [SMILES: c1ccc(-c2nc3cc(N(c4ccccc4)c4ccc5ccccc5c4)cc(N(c4ccccc4)c4ccccc4)c3o2)cc1 ; CC1(C)c2ccccc2-c2ccc(N(c3ccccc3)c3cc(N(c4ccc5oc6ccccc6c5c4)c4ccccc4-c4ccccc4)cc4nc(-c5ccccc5)oc34)cc21 ; c1ccc(-c2ccc(N(c3cc(N(c4ccccc4)c4cccc5oc6ccccc6c45)c4oc(-c5ccccc5)nc4c3)c3cccc4c3oc3ccccc34)cc2)cc1]

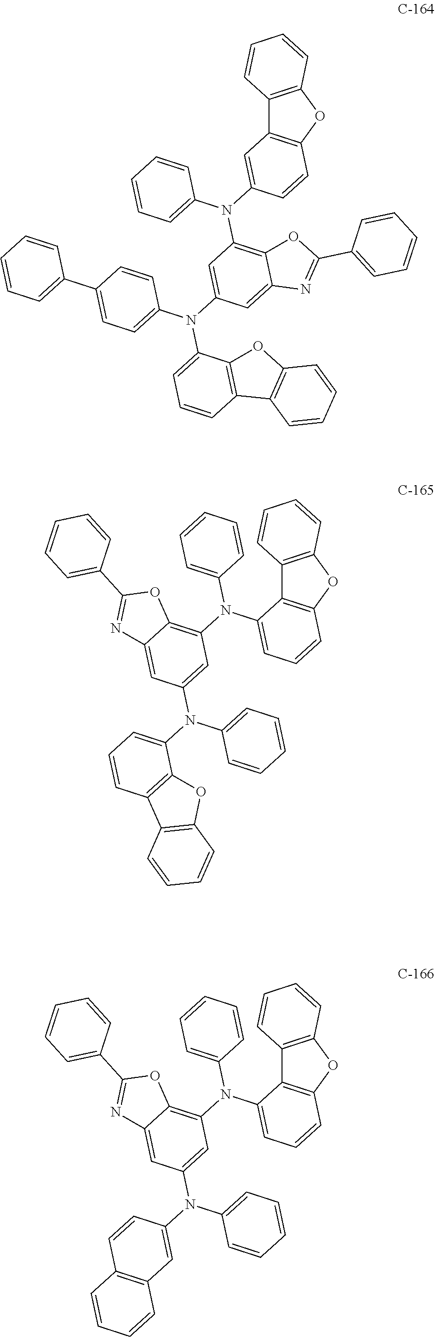 [SMILES: c1ccc(-c2ccc(N(c3cc(N(c4ccccc4)c4ccc5oc6ccccc6c5c4)c4oc(-c5ccccc5)nc4c3)c3cccc4c3oc3ccccc34)cc2)cc1 ; c1ccc(-c2nc3cc(N(c4ccccc4)c4cccc5c4oc4ccccc45)cc(N(c4ccccc4)c4cccc5oc6ccccc6c45)c3o2)cc1 ; c1ccc(-c2nc3cc(N(c4ccccc4)c4ccc5ccccc5c4)cc(N(c4ccccc4)c4cccc5oc6ccccc6c45)c3o2)cc1]

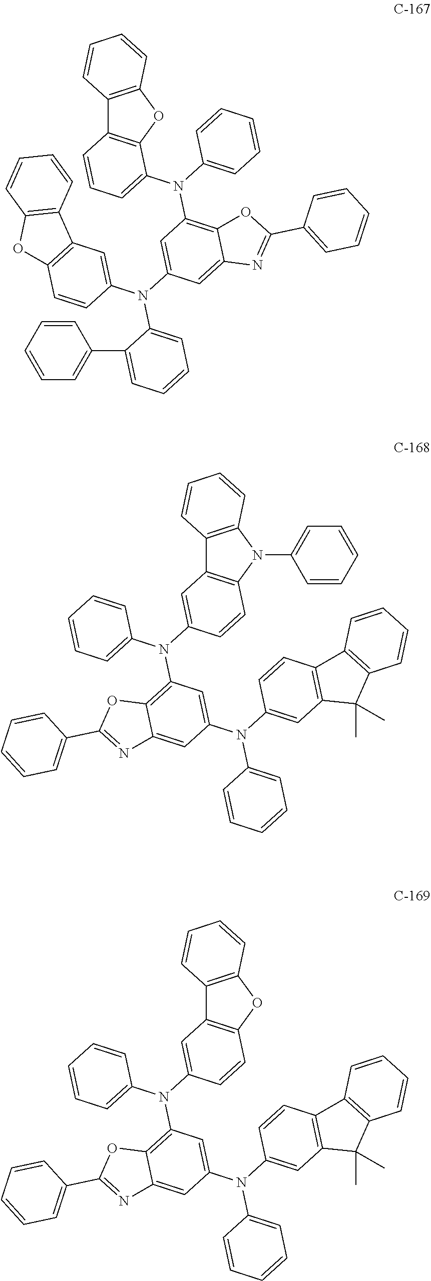 [SMILES: c1ccc(-c2nc3cc(N(c4ccc5oc6ccccc6c5c4)c4ccccc4-c4ccccc4)cc(N(c4ccccc4)c4cccc5c4oc4ccccc45)c3o2)cc1 ; CC1(C)c2ccccc2-c2ccc(N(c3ccccc3)c3cc(N(c4ccccc4)c4ccc5c(c4)c4ccccc4n5-c4ccccc4)c4oc(-c5ccccc5)nc4c3)cc21 ; CC1(C)c2ccccc2-c2ccc(N(c3ccccc3)c3cc(N(c4ccccc4)c4ccc5oc6ccccc6c5c4)c4oc(-c5ccccc5)nc4c3)cc21]

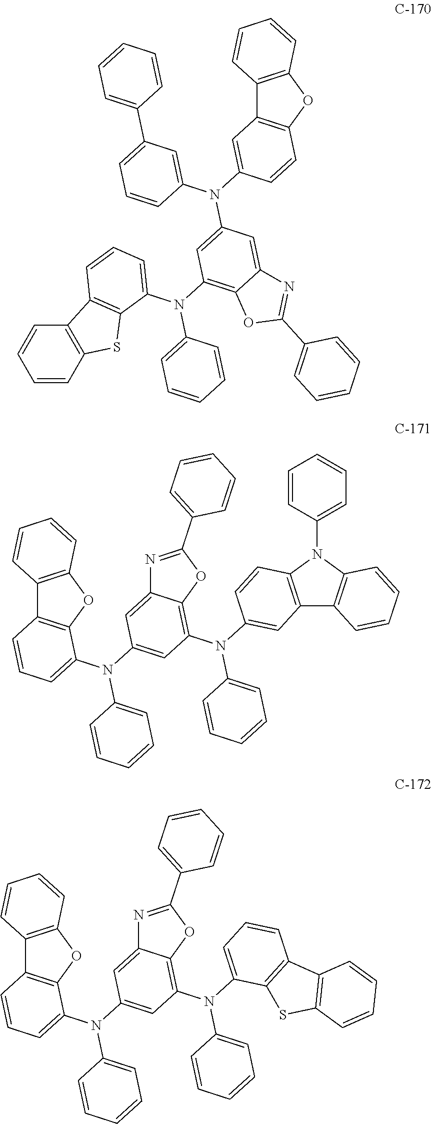 [SMILES: c1ccc(-c2cccc(N(c3cc(N(c4ccccc4)c4cccc5c4sc4ccccc45)c4oc(-c5ccccc5)nc4c3)c3ccc4oc5ccccc5c4c3)c2)cc1 ; c1ccc(-c2nc3cc(N(c4ccccc4)c4cccc5c4oc4ccccc45)cc(N(c4ccccc4)c4ccc5c(c4)c4ccccc4n5-c4ccccc4)c3o2)cc1 ; c1ccc(-c2nc3cc(N(c4ccccc4)c4cccc5c4oc4ccccc45)cc(N(c4ccccc4)c4cccc5c4sc4ccccc45)c3o2)cc1]

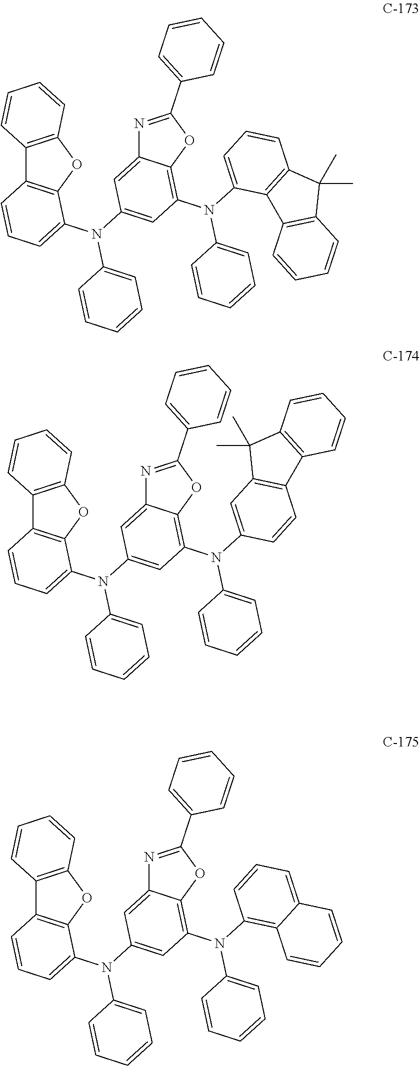 [SMILES: CC1(C)c2ccccc2-c2c(N(c3ccccc3)c3cc(N(c4ccccc4)c4cccc5c4oc4ccccc45)cc4nc(-c5ccccc5)oc34)cccc21 ; CC1(C)c2ccccc2-c2ccc(N(c3ccccc3)c3cc(N(c4ccccc4)c4cccc5c4oc4ccccc45)cc4nc(-c5ccccc5)oc34)cc21 ; c1ccc(-c2nc3cc(N(c4ccccc4)c4cccc5c4oc4ccccc45)cc(N(c4ccccc4)c4cccc5ccccc45)c3o2)cc1]

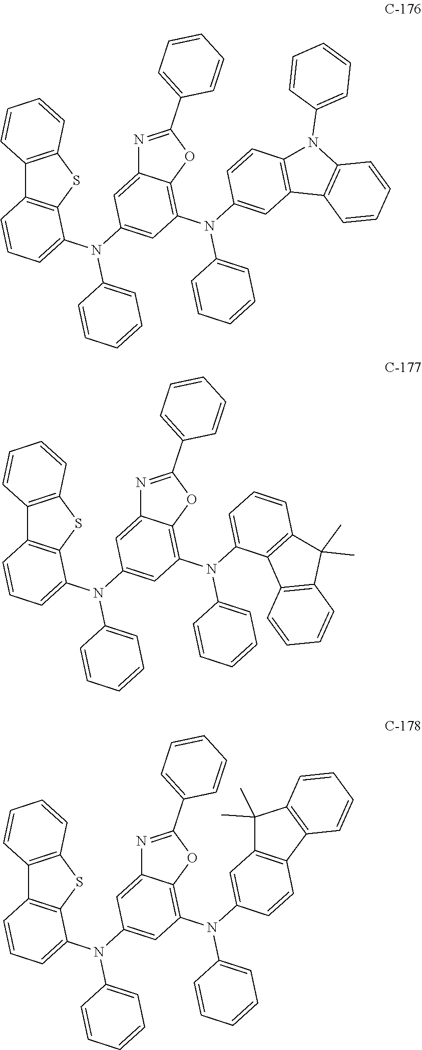 [SMILES: c1ccc(-c2nc3cc(N(c4ccccc4)c4cccc5c4sc4ccccc45)cc(N(c4ccccc4)c4ccc5c(c4)c4ccccc4n5-c4ccccc4)c3o2)cc1 ; CC1(C)c2ccccc2-c2c(N(c3ccccc3)c3cc(N(c4ccccc4)c4cccc5c4sc4ccccc45)cc4nc(-c5ccccc5)oc34)cccc21 ; CC1(C)c2ccccc2-c2ccc(N(c3ccccc3)c3cc(N(c4ccccc4)c4cccc5c4sc4ccccc45)cc4nc(-c5ccccc5)oc34)cc21]

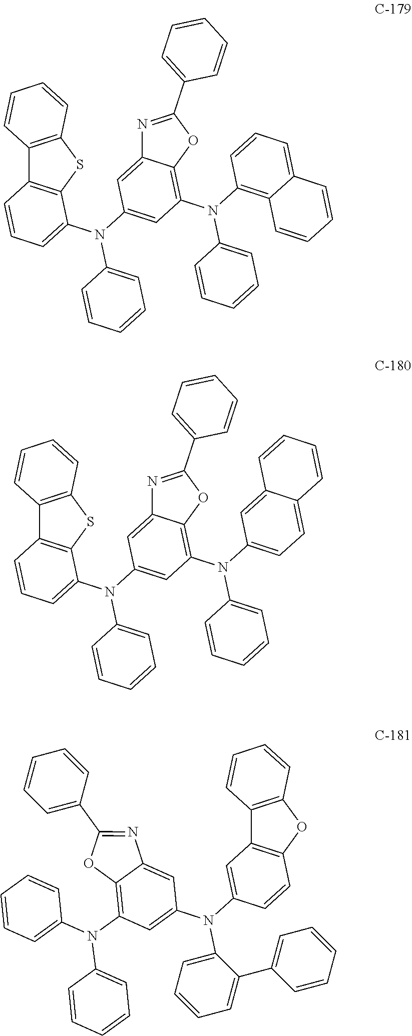 [SMILES: c1ccc(-c2nc3cc(N(c4ccccc4)c4cccc5c4sc4ccccc45)cc(N(c4ccccc4)c4cccc5ccccc45)c3o2)cc1 ; c1ccc(-c2nc3cc(N(c4ccccc4)c4cccc5c4sc4ccccc45)cc(N(c4ccccc4)c4ccc5ccccc5c4)c3o2)cc1 ; c1ccc(-c2nc3cc(N(c4ccc5oc6ccccc6c5c4)c4ccccc4-c4ccccc4)cc(N(c4ccccc4)c4ccccc4)c3o2)cc1]

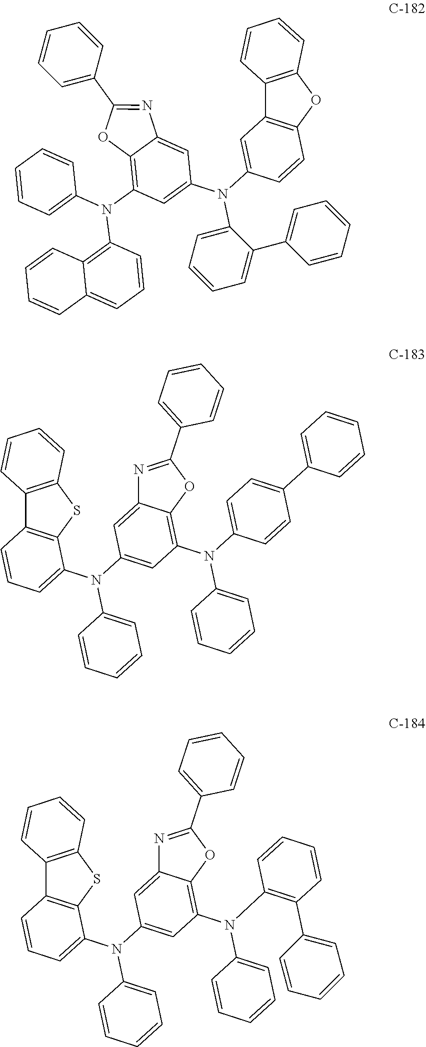 [SMILES: c1ccc(-c2nc3cc(N(c4ccc5oc6ccccc6c5c4)c4ccccc4-c4ccccc4)cc(N(c4ccccc4)c4cccc5ccccc45)c3o2)cc1 ; c1ccc(-c2ccc(N(c3ccccc3)c3cc(N(c4ccccc4)c4cccc5c4sc4ccccc45)cc4nc(-c5ccccc5)oc34)cc2)cc1 ; c1ccc(-c2nc3cc(N(c4ccccc4)c4cccc5c4sc4ccccc45)cc(N(c4ccccc4)c4ccccc4-c4ccccc4)c3o2)cc1]

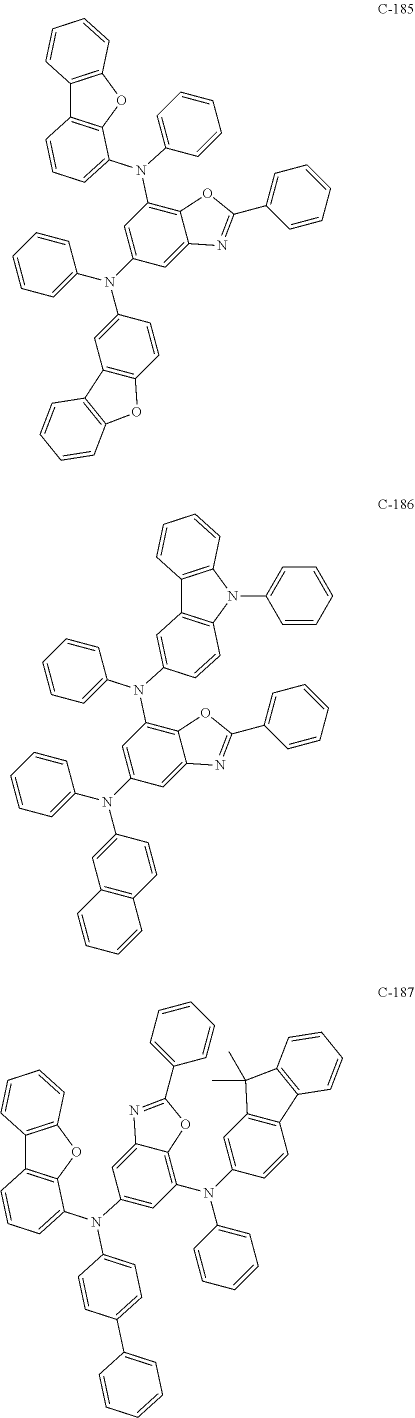 [SMILES: c1ccc(-c2nc3cc(N(c4ccccc4)c4ccc5oc6ccccc6c5c4)cc(N(c4ccccc4)c4cccc5c4oc4ccccc45)c3o2)cc1 ; c1ccc(-c2nc3cc(N(c4ccccc4)c4ccc5ccccc5c4)cc(N(c4ccccc4)c4ccc5c(c4)c4ccccc4n5-c4ccccc4)c3o2)cc1 ; CC1(C)c2ccccc2-c2ccc(N(c3ccccc3)c3cc(N(c4ccc(-c5ccccc5)cc4)c4cccc5c4oc4ccccc45)cc4nc(-c5ccccc5)oc34)cc21]

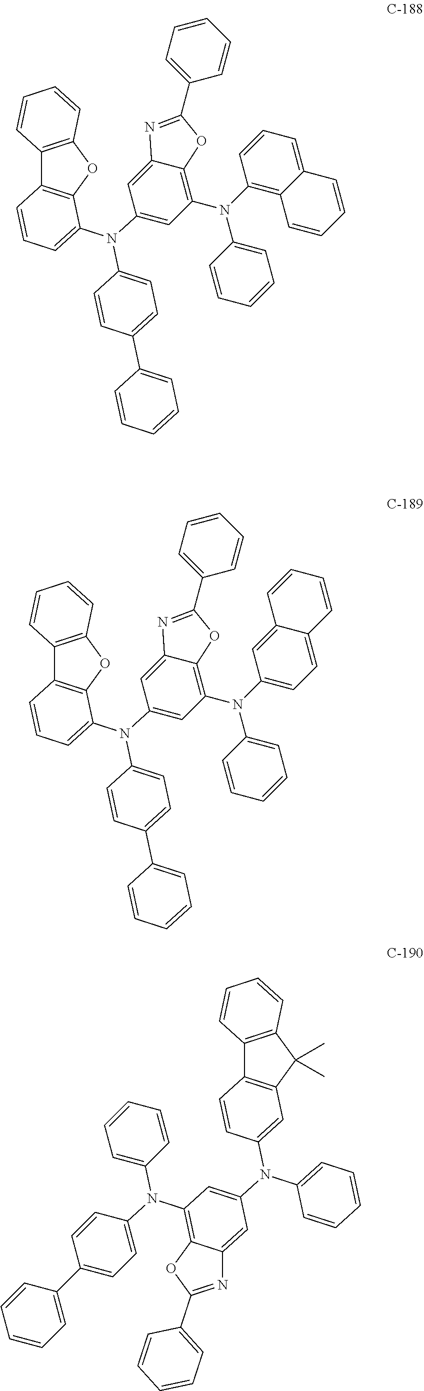 [SMILES: c1ccc(-c2ccc(N(c3cc(N(c4ccccc4)c4cccc5ccccc45)c4oc(-c5ccccc5)nc4c3)c3cccc4c3oc3ccccc34)cc2)cc1 ; c1ccc(-c2ccc(N(c3cc(N(c4ccccc4)c4ccc5ccccc5c4)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4ccc(-c5ccccc5)cc4)c4oc(-c5ccccc5)nc4c3)cc21]

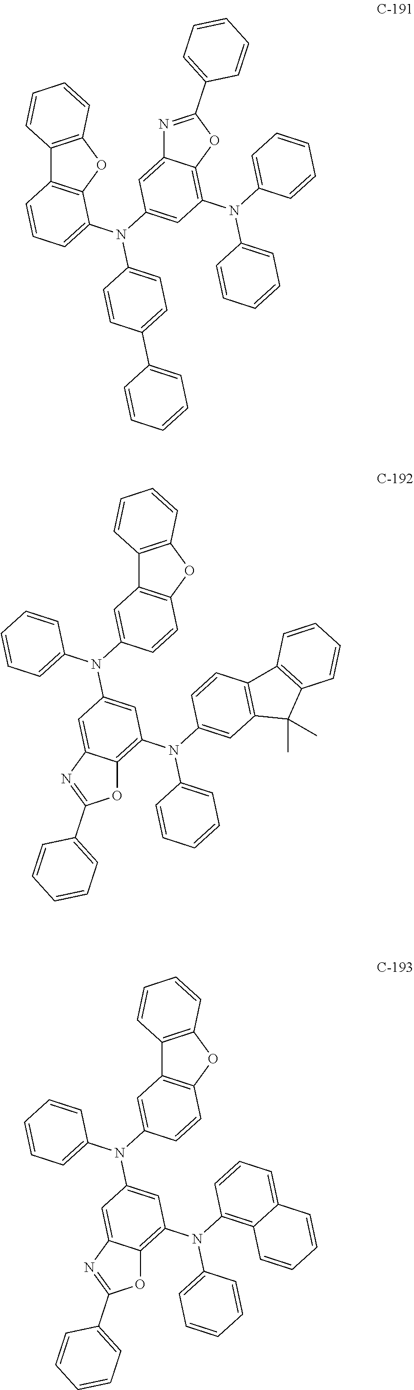 [SMILES: c1ccc(-c2ccc(N(c3cc(N(c4ccccc4)c4ccccc4)c4oc(-c5ccccc5)nc4c3)c3cccc4c3oc3ccccc34)cc2)cc1 ; CC1(C)c2ccccc2-c2ccc(N(c3ccccc3)c3cc(N(c4ccccc4)c4ccc5oc6ccccc6c5c4)cc4nc(-c5ccccc5)oc34)cc21 ; c1ccc(-c2nc3cc(N(c4ccccc4)c4ccc5oc6ccccc6c5c4)cc(N(c4ccccc4)c4cccc5ccccc45)c3o2)cc1]

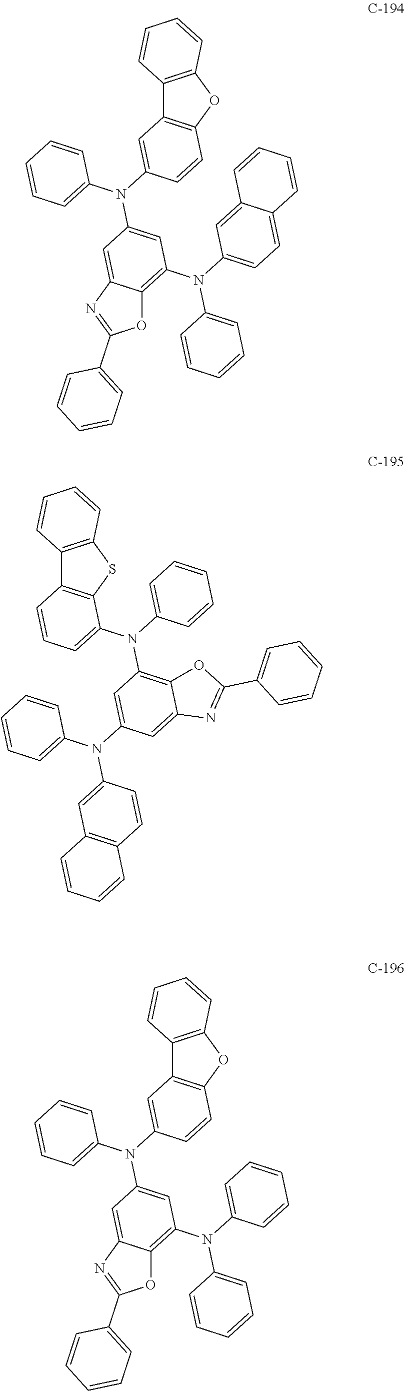 [SMILES: c1ccc(-c2nc3cc(N(c4ccccc4)c4ccc5oc6ccccc6c5c4)cc(N(c4ccccc4)c4ccc5ccccc5c4)c3o2)cc1 ; c1ccc(-c2nc3cc(N(c4ccccc4)c4ccc5ccccc5c4)cc(N(c4ccccc4)c4cccc5c4sc4ccccc45)c3o2)cc1 ; c1ccc(-c2nc3cc(N(c4ccccc4)c4ccc5oc6ccccc6c5c4)cc(N(c4ccccc4)c4ccccc4)c3o2)cc1]

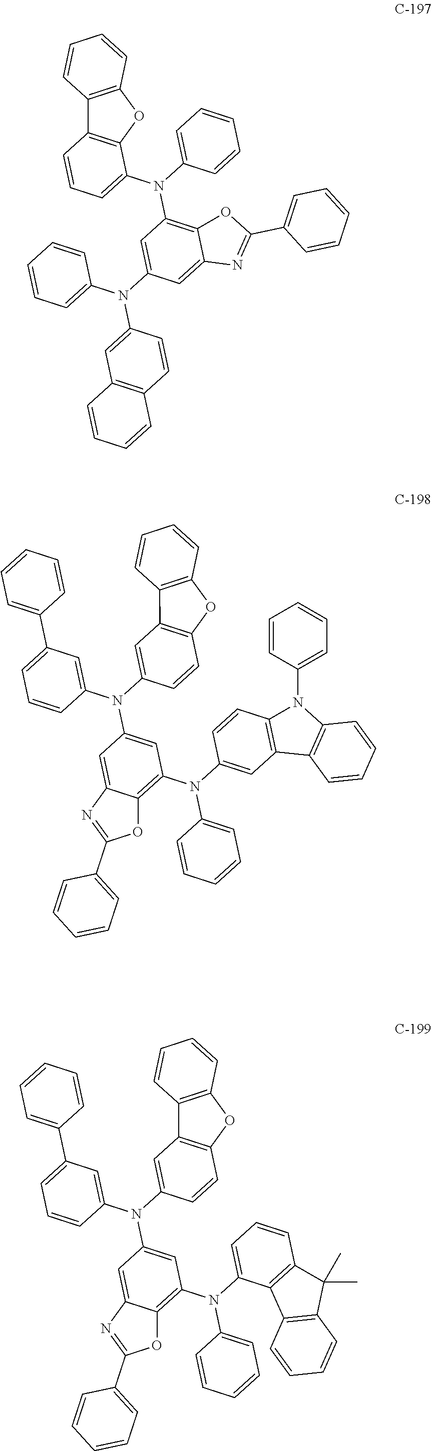 [SMILES: c1ccc(-c2nc3cc(N(c4ccccc4)c4ccc5ccccc5c4)cc(N(c4ccccc4)c4cccc5c4oc4ccccc45)c3o2)cc1 ; c1ccc(-c2cccc(N(c3cc(N(c4ccccc4)c4ccc5c(c4)c4ccccc4n5-c4ccccc4)c4oc(-c5ccccc5)nc4c3)c3ccc4oc5ccccc5c4c3)c2)cc1 ; CC1(C)c2ccccc2-c2c(N(c3ccccc3)c3cc(N(c4cccc(-c5ccccc5)c4)c4ccc5oc6ccccc6c5c4)cc4nc(-c5ccccc5)oc34)cccc21]

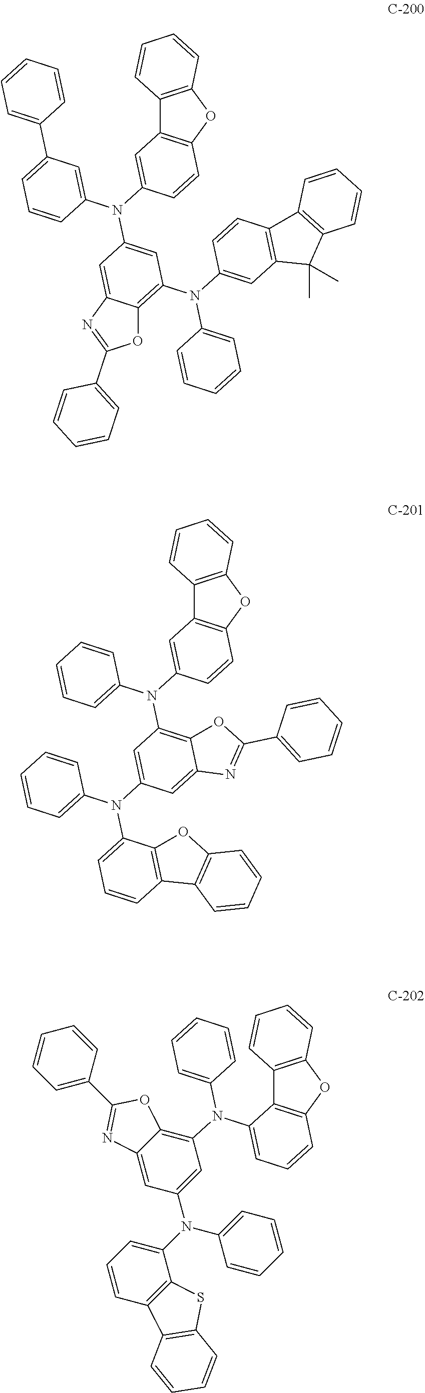 [SMILES: CC1(C)c2ccccc2-c2ccc(N(c3ccccc3)c3cc(N(c4cccc(-c5ccccc5)c4)c4ccc5oc6ccccc6c5c4)cc4nc(-c5ccccc5)oc34)cc21 ; c1ccc(-c2nc3cc(N(c4ccccc4)c4cccc5c4oc4ccccc45)cc(N(c4ccccc4)c4ccc5oc6ccccc6c5c4)c3o2)cc1 ; c1ccc(-c2nc3cc(N(c4ccccc4)c4cccc5c4sc4ccccc45)cc(N(c4ccccc4)c4cccc5oc6ccccc6c45)c3o2)cc1]

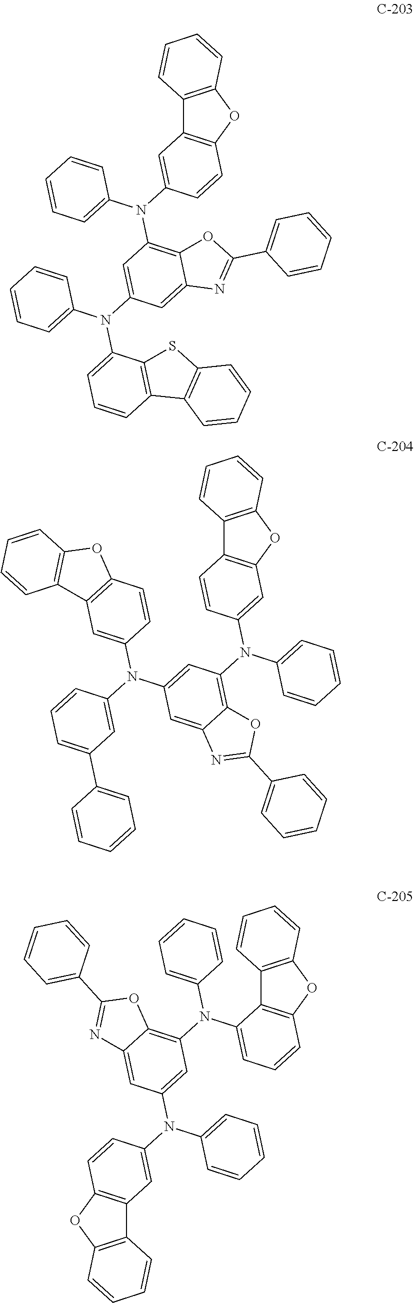

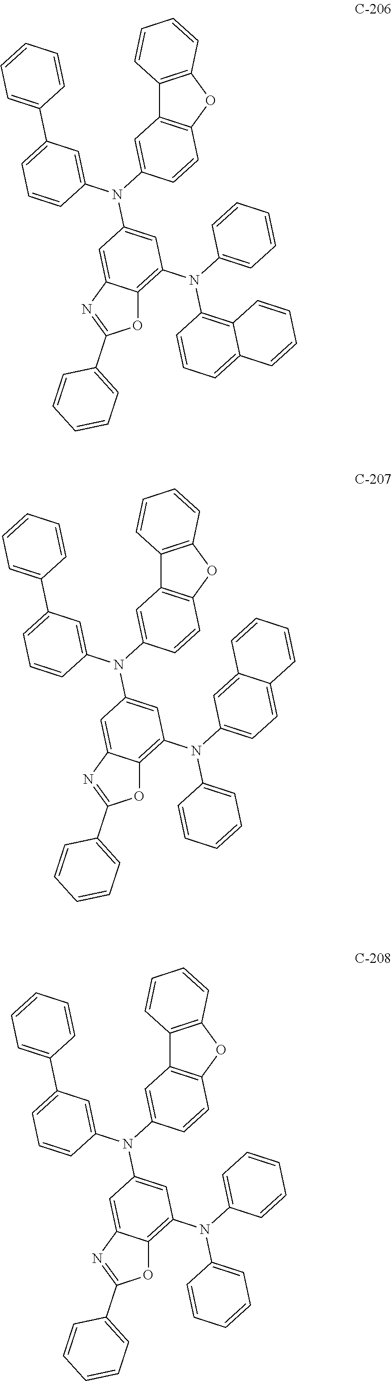 [SMILES: c1ccc(-c2cccc(N(c3cc(N(c4ccccc4)c4cccc5ccccc45)c4oc(-c5ccccc5)nc4c3)c3ccc4oc5ccccc5c4c3)c2)cc1 ; c1ccc(-c2cccc(N(c3cc(N(c4ccccc4)c4ccc5ccccc5c4)c4oc(-c5ccccc5)nc4c3)c3ccc4oc5ccccc5c4c3)c2)cc1 ; c1ccc(-c2cccc(N(c3cc(N(c4ccccc4)c4ccccc4)c4oc(-c5ccccc5)nc4c3)c3ccc4oc5ccccc5c4c3)c2)cc1]

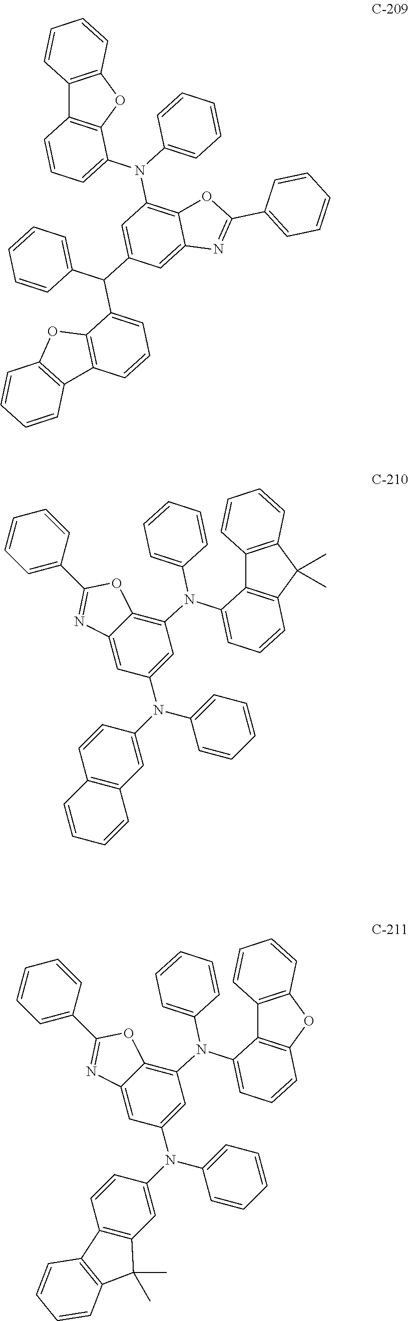 [SMILES: c1ccc(-c2nc3cc(C(c4ccccc4)c4cccc5c4oc4ccccc45)cc(N(c4ccccc4)c4cccc5c4oc4ccccc45)c3o2)cc1 ; CC1(C)c2ccccc2-c2c(N(c3ccccc3)c3cc(N(c4ccccc4)c4ccc5ccccc5c4)cc4nc(-c5ccccc5)oc34)cccc21 ; CC1(C)c2ccccc2-c2ccc(N(c3ccccc3)c3cc(N(c4ccccc4)c4cccc5oc6ccccc6c45)c4oc(-c5ccccc5)nc4c3)cc21]

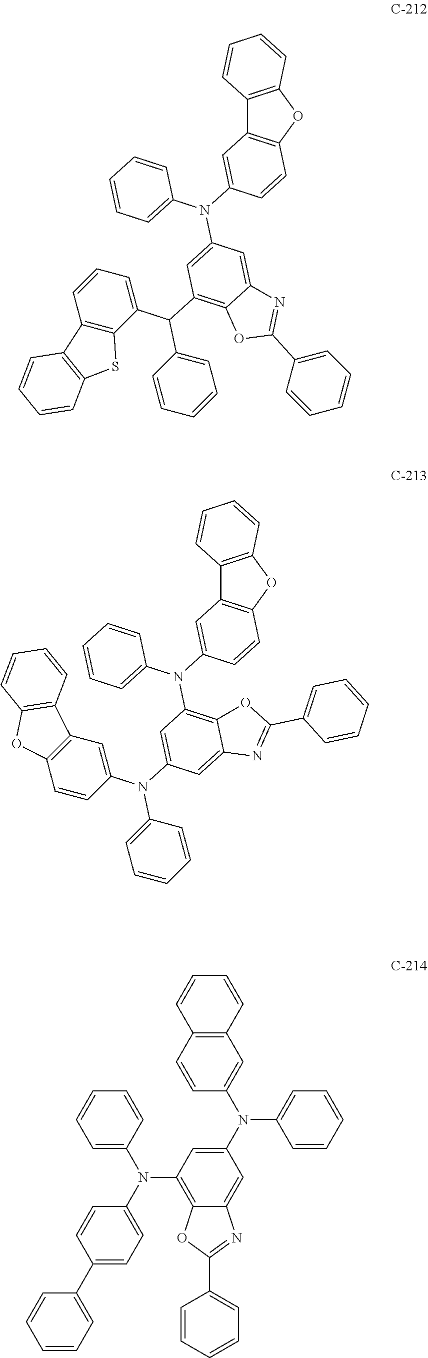 [SMILES: c1ccc(-c2nc3cc(N(c4ccccc4)c4ccc5oc6ccccc6c5c4)cc(C(c4ccccc4)c4cccc5c4sc4ccccc45)c3o2)cc1 ; c1ccc(-c2nc3cc(N(c4ccccc4)c4ccc5oc6ccccc6c5c4)cc(N(c4ccccc4)c4ccc5oc6ccccc6c5c4)c3o2)cc1 ; c1ccc(-c2ccc(N(c3ccccc3)c3cc(N(c4ccccc4)c4ccc5ccccc5c4)cc4nc(-c5ccccc5)oc34)cc2)cc1]

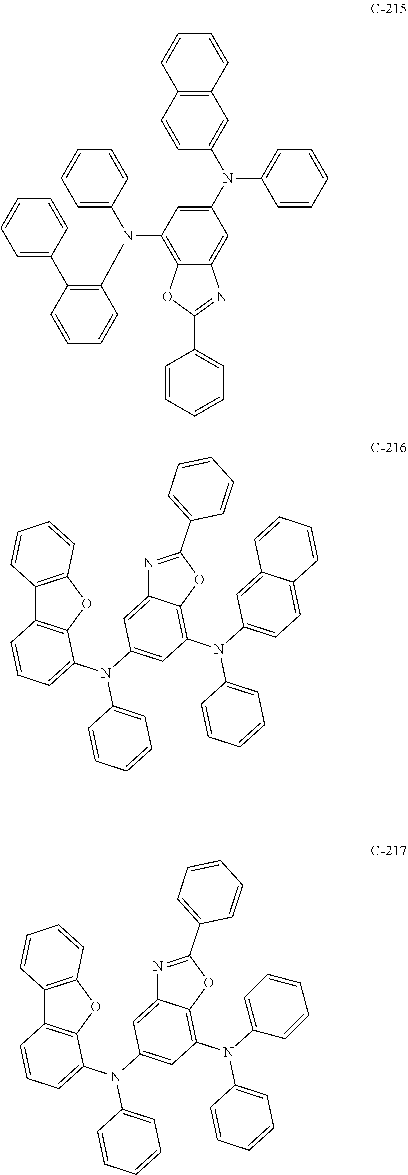

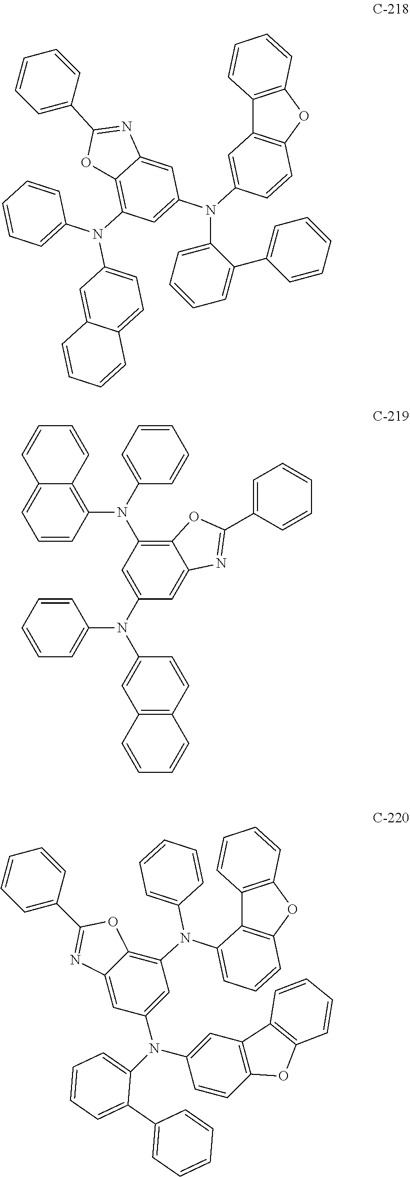 [SMILES: c1ccc(-c2nc3cc(N(c4ccc5oc6ccccc6c5c4)c4ccccc4-c4ccccc4)cc(N(c4ccccc4)c4ccc5ccccc5c4)c3o2)cc1 ; c1ccc(-c2nc3cc(N(c4ccccc4)c4ccc5ccccc5c4)cc(N(c4ccccc4)c4cccc5ccccc45)c3o2)cc1 ; c1ccc(-c2nc3cc(N(c4ccc5oc6ccccc6c5c4)c4ccccc4-c4ccccc4)cc(N(c4ccccc4)c4cccc5oc6ccccc6c45)c3o2)cc1]

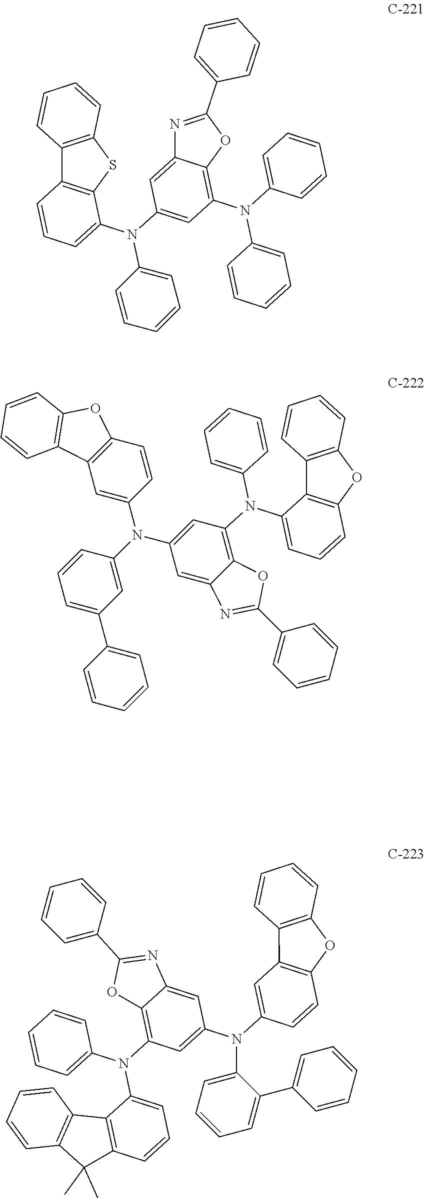 [SMILES: c1ccc(-c2nc3cc(N(c4ccccc4)c4cccc5c4sc4ccccc45)cc(N(c4ccccc4)c4ccccc4)c3o2)cc1 ; c1ccc(-c2cccc(N(c3cc(N(c4ccccc4)c4cccc5oc6ccccc6c45)c4oc(-c5ccccc5)nc4c3)c3ccc4oc5ccccc5c4c3)c2)cc1 ; CC1(C)c2ccccc2-c2c(N(c3ccccc3)c3cc(N(c4ccc5oc6ccccc6c5c4)c4ccccc4-c4ccccc4)cc4nc(-c5ccccc5)oc34)cccc21]

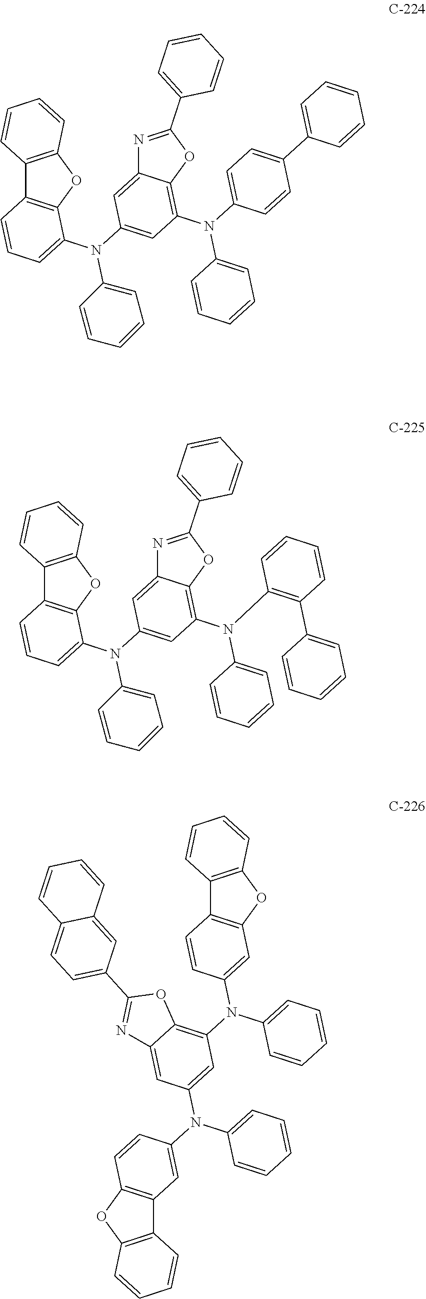 [SMILES: c1ccc(-c2ccc(N(c3ccccc3)c3cc(N(c4ccccc4)c4cccc5c4oc4ccccc45)cc4nc(-c5ccccc5)oc34)cc2)cc1 ; c1ccc(-c2nc3cc(N(c4ccccc4)c4cccc5c4oc4ccccc45)cc(N(c4ccccc4)c4ccccc4-c4ccccc4)c3o2)cc1 ; c1ccc(N(c2cc(N(c3ccccc3)c3ccc4c(c3)oc3ccccc34)c3oc(-c4ccc5ccccc5c4)nc3c2)c2ccc3oc4ccccc4c3c2)cc1]

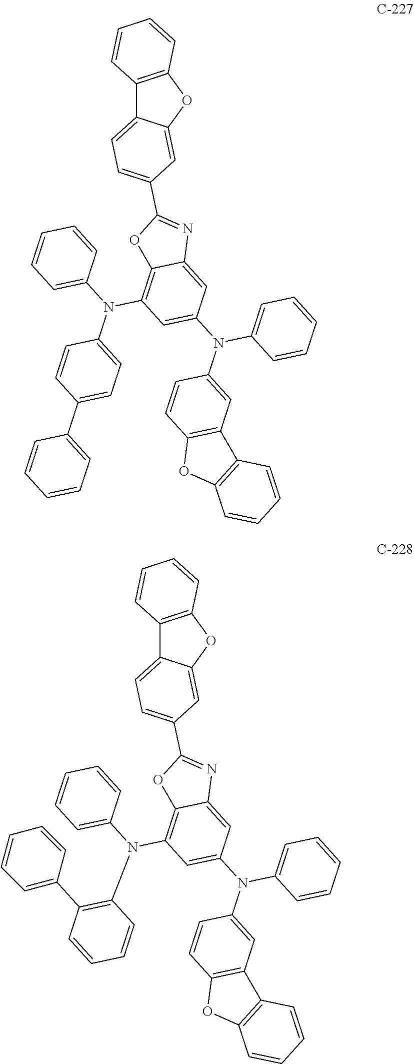 [SMILES: c1ccc(-c2ccc(N(c3ccccc3)c3cc(N(c4ccccc4)c4ccc5oc6ccccc6c5c4)cc4nc(-c5ccc6c(c5)oc5ccccc56)oc34)cc2)cc1 ; c1ccc(-c2ccccc2N(c2ccccc2)c2cc(N(c3ccccc3)c3ccc4oc5ccccc5c4c3)cc3nc(-c4ccc5c(c4)oc4ccccc45)oc23)cc1]

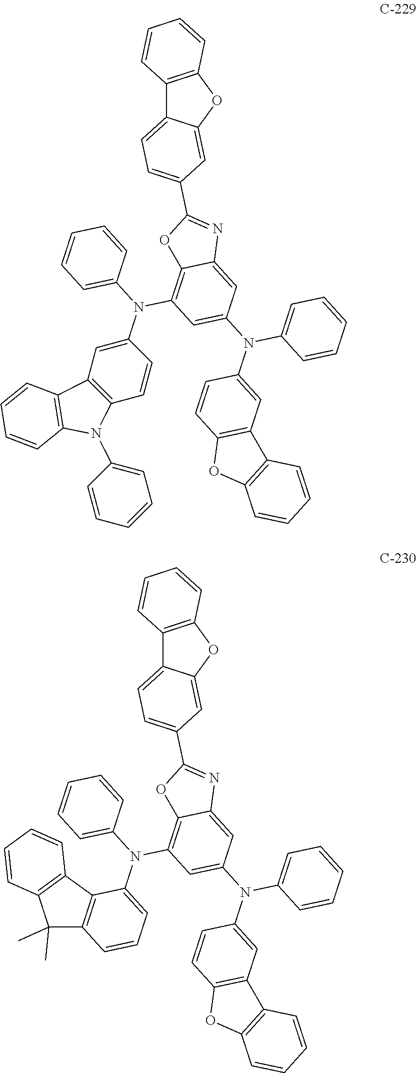 [SMILES: c1ccc(N(c2cc(N(c3ccccc3)c3ccc4c(c3)c3ccccc3n4-c3ccccc3)c3oc(-c4ccc5c(c4)oc4ccccc45)nc3c2)c2ccc3oc4ccccc4c3c2)cc1 ; CC1(C)c2ccccc2-c2c(N(c3ccccc3)c3cc(N(c4ccccc4)c4ccc5oc6ccccc6c5c4)cc4nc(-c5ccc6c(c5)oc5ccccc56)oc34)cccc21]

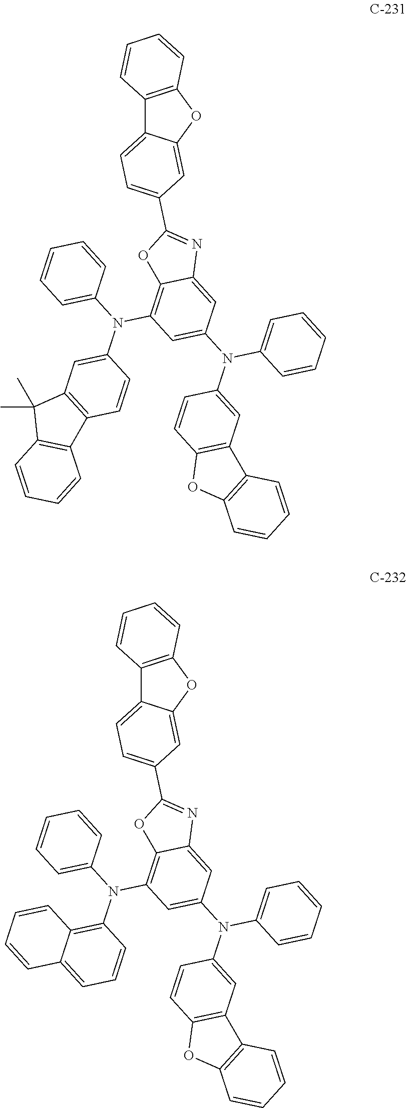 [SMILES: CC1(C)c2ccccc2-c2ccc(N(c3ccccc3)c3cc(N(c4ccccc4)c4ccc5oc6ccccc6c5c4)cc4nc(-c5ccc6c(c5)oc5ccccc56)oc34)cc21 ; c1ccc(N(c2cc(N(c3ccccc3)c3cccc4ccccc34)c3oc(-c4ccc5c(c4)oc4ccccc45)nc3c2)c2ccc3oc4ccccc4c3c2)cc1]

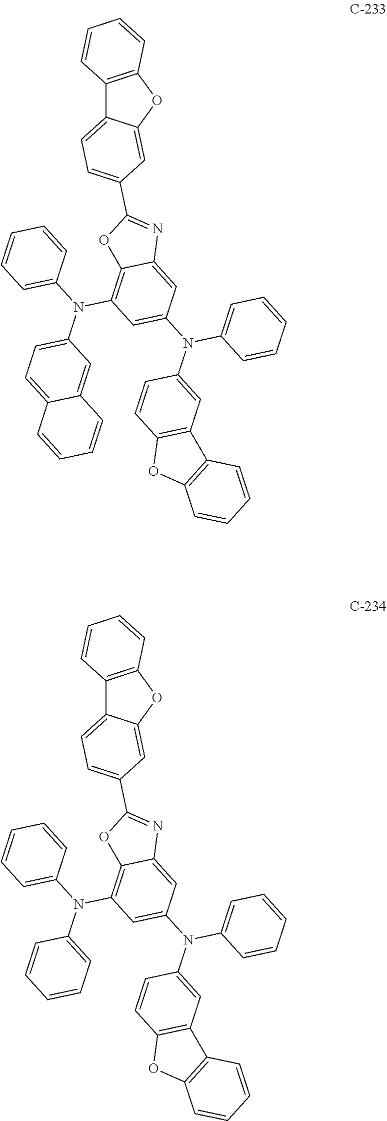 [SMILES: c1ccc(N(c2cc(N(c3ccccc3)c3ccc4ccccc4c3)c3oc(-c4ccc5c(c4)oc4ccccc45)nc3c2)c2ccc3oc4ccccc4c3c2)cc1 ; c1ccc(N(c2cc(N(c3ccccc3)c3ccccc3)c3oc(-c4ccc5c(c4)oc4ccccc45)nc3c2)c2ccc3oc4ccccc4c3c2)cc1]

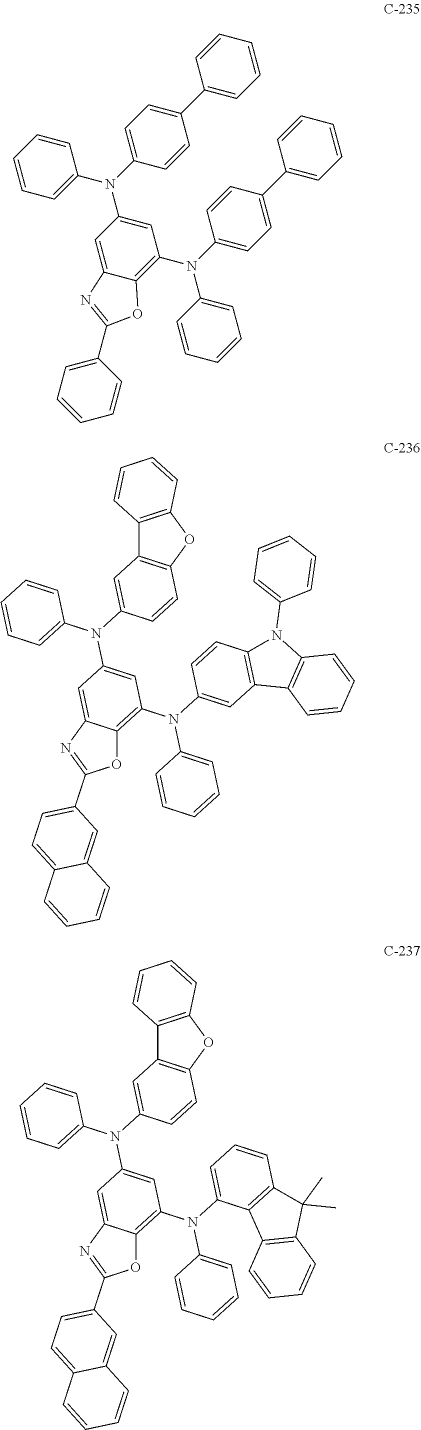 [SMILES: c1ccc(-c2ccc(N(c3ccccc3)c3cc(N(c4ccccc4)c4ccc(-c5ccccc5)cc4)c4oc(-c5ccccc5)nc4c3)cc2)cc1 ; c1ccc(N(c2cc(N(c3ccccc3)c3ccc4c(c3)c3ccccc3n4-c3ccccc3)c3oc(-c4ccc5ccccc5c4)nc3c2)c2ccc3oc4ccccc4c3c2)cc1 ; CC1(C)c2ccccc2-c2c(N(c3ccccc3)c3cc(N(c4ccccc4)c4ccc5oc6ccccc6c5c4)cc4nc(-c5ccc6ccccc6c5)oc34)cccc21]

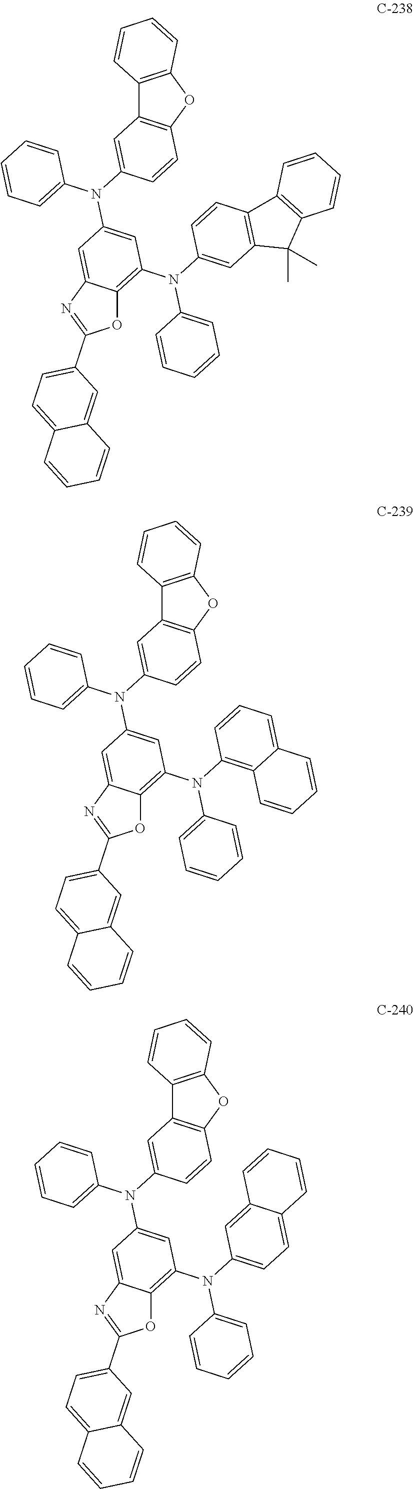 [SMILES: CC1(C)c2ccccc2-c2ccc(N(c3ccccc3)c3cc(N(c4ccccc4)c4ccc5oc6ccccc6c5c4)cc4nc(-c5ccc6ccccc6c5)oc34)cc21 ; c1ccc(N(c2cc(N(c3ccccc3)c3cccc4ccccc34)c3oc(-c4ccc5ccccc5c4)nc3c2)c2ccc3oc4ccccc4c3c2)cc1 ; c1ccc(N(c2cc(N(c3ccccc3)c3ccc4ccccc4c3)c3oc(-c4ccc5ccccc5c4)nc3c2)c2ccc3oc4ccccc4c3c2)cc1]

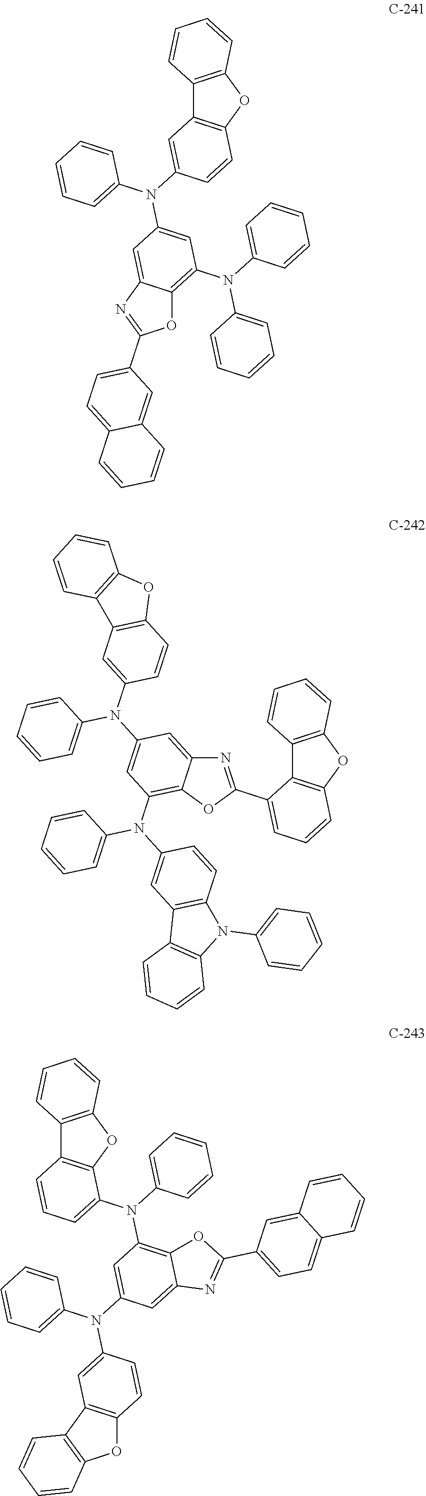 [SMILES: c1ccc(N(c2cc(N(c3ccccc3)c3ccccc3)c3oc(-c4ccc5ccccc5c4)nc3c2)c2ccc3oc4ccccc4c3c2)cc1 ; c1ccc(N(c2cc(N(c3ccccc3)c3ccc4c(c3)c3ccccc3n4-c3ccccc3)c3oc(-c4cccc5oc6ccccc6c45)nc3c2)c2ccc3oc4ccccc4c3c2)cc1 ; c1ccc(N(c2cc(N(c3ccccc3)c3cccc4c3oc3ccccc34)c3oc(-c4ccc5ccccc5c4)nc3c2)c2ccc3oc4ccccc4c3c2)cc1]

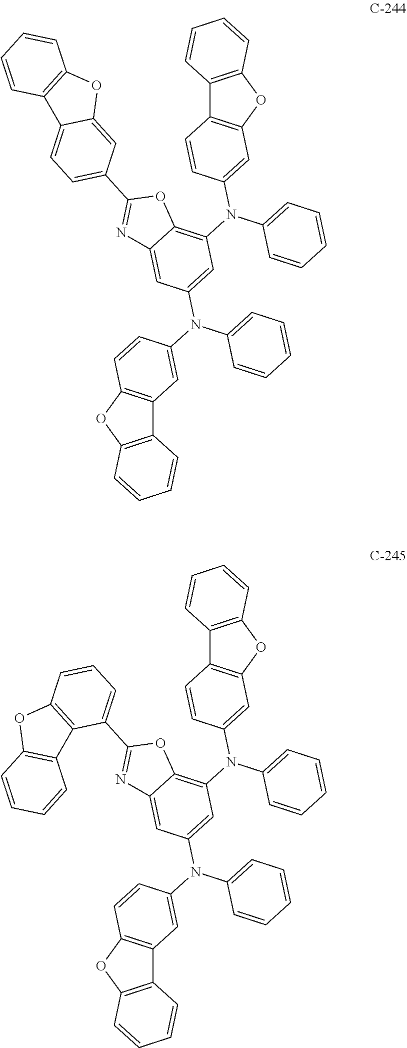 [SMILES: c1ccc(N(c2cc(N(c3ccccc3)c3ccc4c(c3)oc3ccccc34)c3oc(-c4ccc5c(c4)oc4ccccc45)nc3c2)c2ccc3oc4ccccc4c3c2)cc1 ; c1ccc(N(c2cc(N(c3ccccc3)c3ccc4c(c3)oc3ccccc34)c3oc(-c4cccc5oc6ccccc6c45)nc3c2)c2ccc3oc4ccccc4c3c2)cc1]

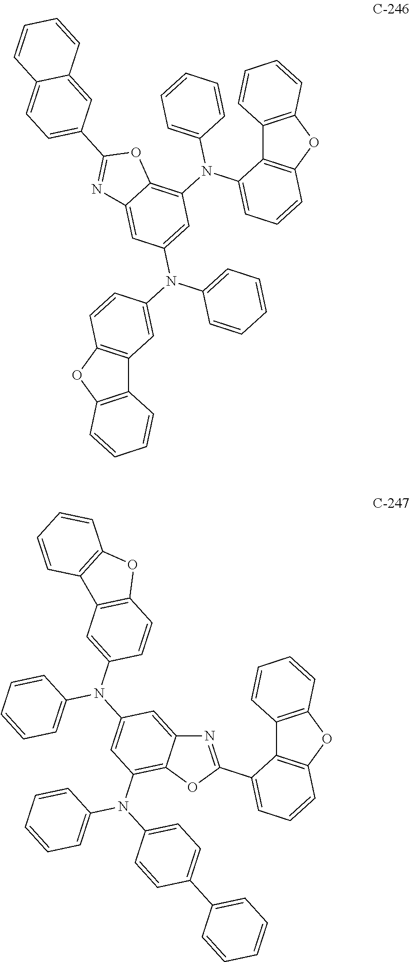 [SMILES: c1ccc(N(c2cc(N(c3ccccc3)c3cccc4oc5ccccc5c34)c3oc(-c4ccc5ccccc5c4)nc3c2)c2ccc3oc4ccccc4c3c2)cc1 ; c1ccc(-c2ccc(N(c3ccccc3)c3cc(N(c4ccccc4)c4ccc5oc6ccccc6c5c4)cc4nc(-c5cccc6oc7ccccc7c56)oc34)cc2)cc1]

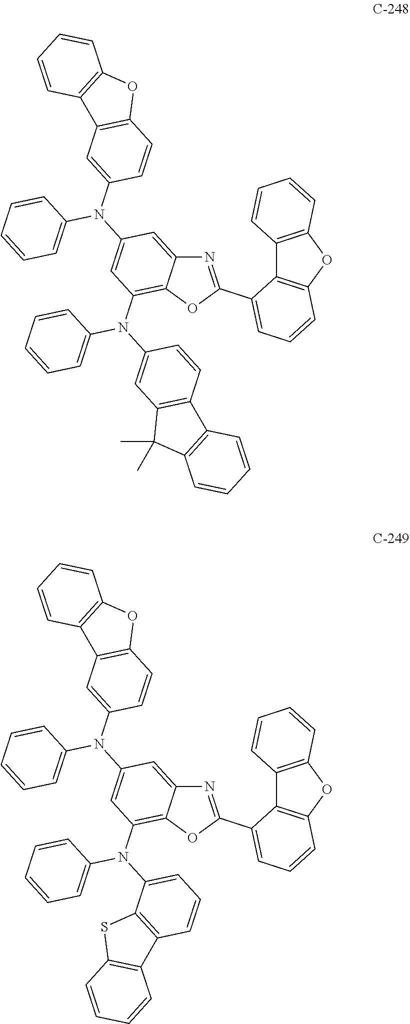 [SMILES: CC1(C)c2ccccc2-c2ccc(N(c3ccccc3)c3cc(N(c4ccccc4)c4ccc5oc6ccccc6c5c4)cc4nc(-c5cccc6oc7ccccc7c56)oc34)cc21 ; c1ccc(N(c2cc(N(c3ccccc3)c3cccc4c3sc3ccccc34)c3oc(-c4cccc5oc6ccccc6c45)nc3c2)c2ccc3oc4ccccc4c3c2)cc1]

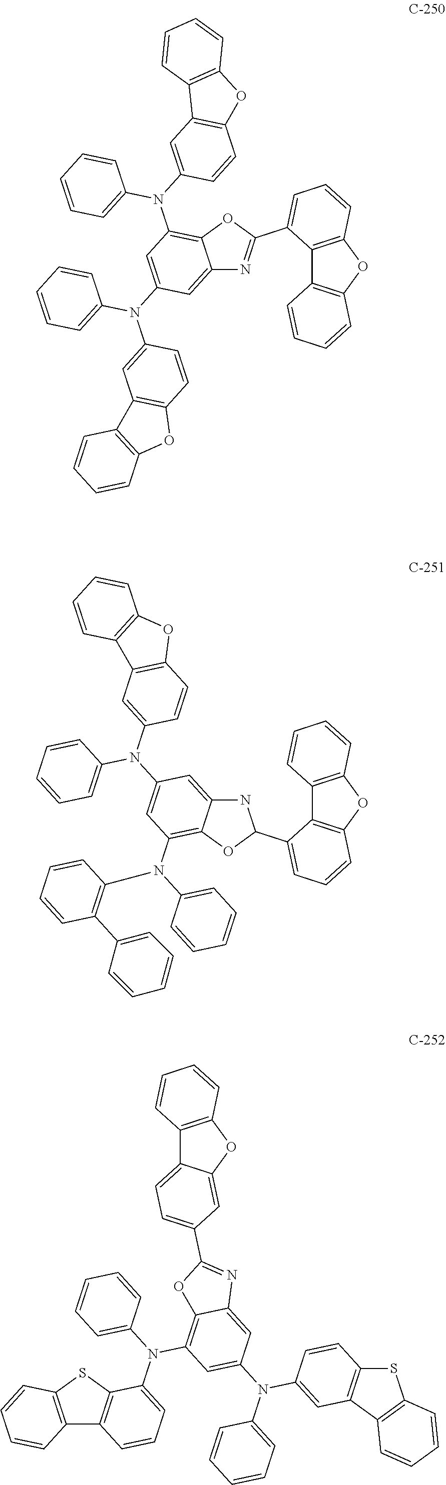 [SMILES: c1ccc(N(c2cc(N(c3ccccc3)c3ccc4oc5ccccc5c4c3)c3oc(-c4cccc5oc6ccccc6c45)nc3c2)c2ccc3oc4ccccc4c3c2)cc1 ; c1ccc(-c2ccccc2N(c2ccccc2)c2cc(N(c3ccccc3)c3ccc4oc5ccccc5c4c3)cc3c2OC(c2cccc4oc5ccccc5c24)N3)cc1 ; c1ccc(N(c2cc(N(c3ccccc3)c3cccc4c3sc3ccccc34)c3oc(-c4ccc5c(c4)oc4ccccc45)nc3c2)c2ccc3sc4ccccc4c3c2)cc1]

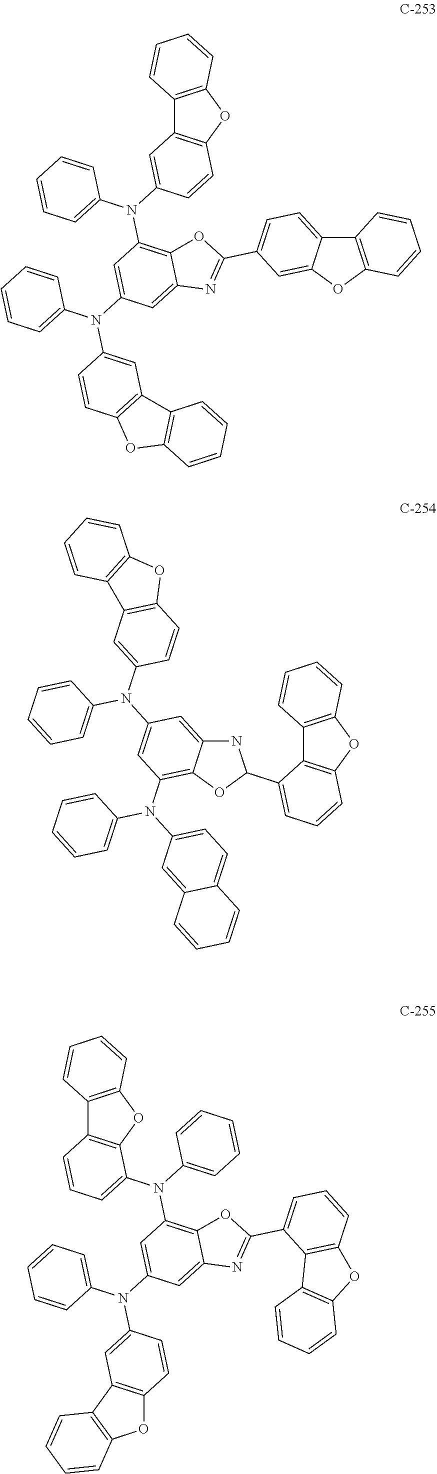 [SMILES: c1ccc(N(c2cc(N(c3ccccc3)c3ccc4oc5ccccc5c4c3)c3oc(-c4ccc5c(c4)oc4ccccc45)nc3c2)c2ccc3oc4ccccc4c3c2)cc1 ; c1ccc(N(c2cc3c(c(N(c4ccccc4)c4ccc5ccccc5c4)c2)OC(c2cccc4oc5ccccc5c24)N3)c2ccc3oc4ccccc4c3c2)cc1 ; c1ccc(N(c2cc(N(c3ccccc3)c3cccc4c3oc3ccccc34)c3oc(-c4cccc5oc6ccccc6c45)nc3c2)c2ccc3oc4ccccc4c3c2)cc1]

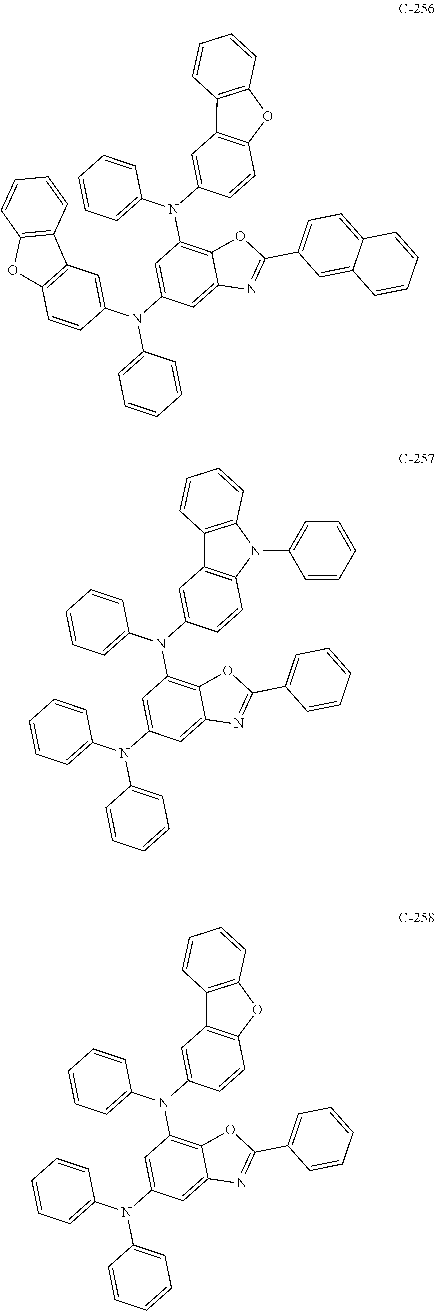 [SMILES: c1ccc(N(c2cc(N(c3ccccc3)c3ccc4oc5ccccc5c4c3)c3oc(-c4ccc5ccccc5c4)nc3c2)c2ccc3oc4ccccc4c3c2)cc1 ; c1ccc(-c2nc3cc(N(c4ccccc4)c4ccccc4)cc(N(c4ccccc4)c4ccc5c(c4)c4ccccc4n5-c4ccccc4)c3o2)cc1 ; c1ccc(-c2nc3cc(N(c4ccccc4)c4ccccc4)cc(N(c4ccccc4)c4ccc5oc6ccccc6c5c4)c3o2)cc1]

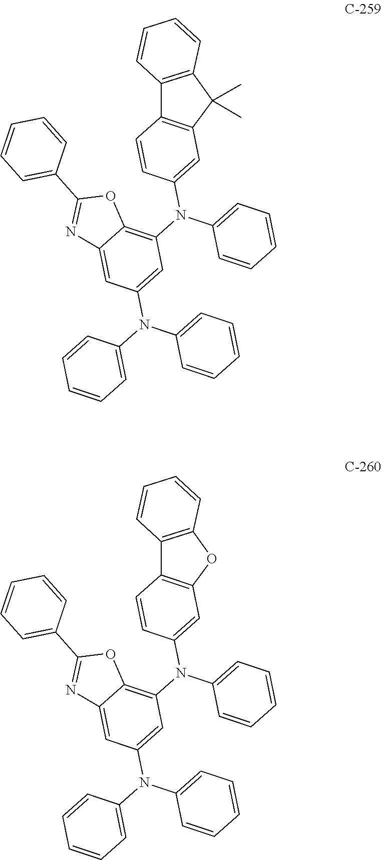 [SMILES: CC1(C)c2ccccc2-c2ccc(N(c3ccccc3)c3cc(N(c4ccccc4)c4ccccc4)cc4nc(-c5ccccc5)oc34)cc21 ; c1ccc(-c2nc3cc(N(c4ccccc4)c4ccccc4)cc(N(c4ccccc4)c4ccc5c(c4)oc4ccccc45)c3o2)cc1]

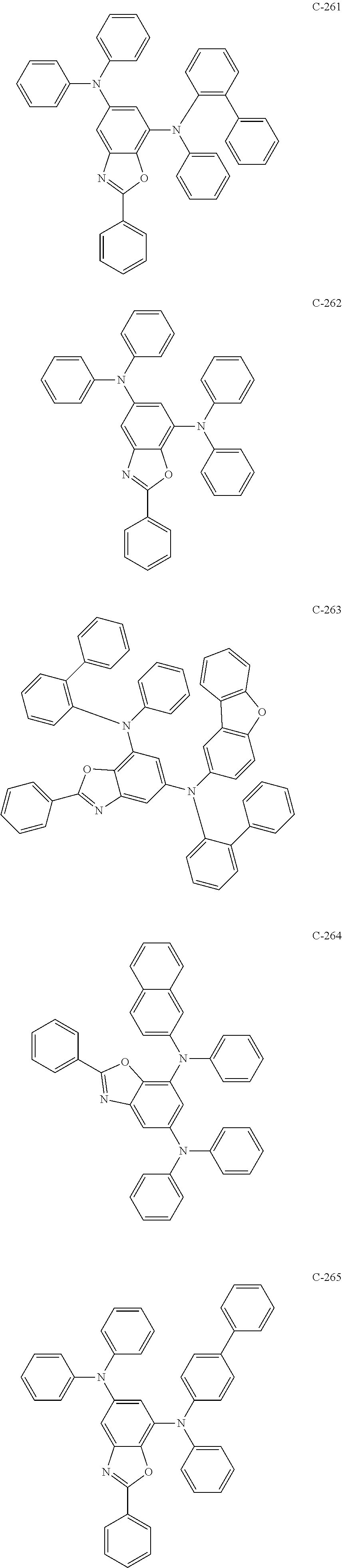 [SMILES: c1ccc(-c2nc3cc(N(c4ccccc4)c4ccccc4)cc(N(c4ccccc4)c4ccccc4-c4ccccc4)c3o2)cc1 ; c1ccc(-c2nc3cc(N(c4ccccc4)c4ccccc4)cc(N(c4ccccc4)c4ccccc4)c3o2)cc1 ; c1ccc(-c2nc3cc(N(c4ccc5oc6ccccc6c5c4)c4ccccc4-c4ccccc4)cc(N(c4ccccc4)c4ccccc4-c4ccccc4)c3o2)cc1 ; c1ccc(-c2nc3cc(N(c4ccccc4)c4ccccc4)cc(N(c4ccccc4)c4ccc5ccccc5c4)c3o2)cc1 ; c1ccc(-c2ccc(N(c3ccccc3)c3cc(N(c4ccccc4)c4ccccc4)cc4nc(-c5ccccc5)oc34)cc2)cc1]

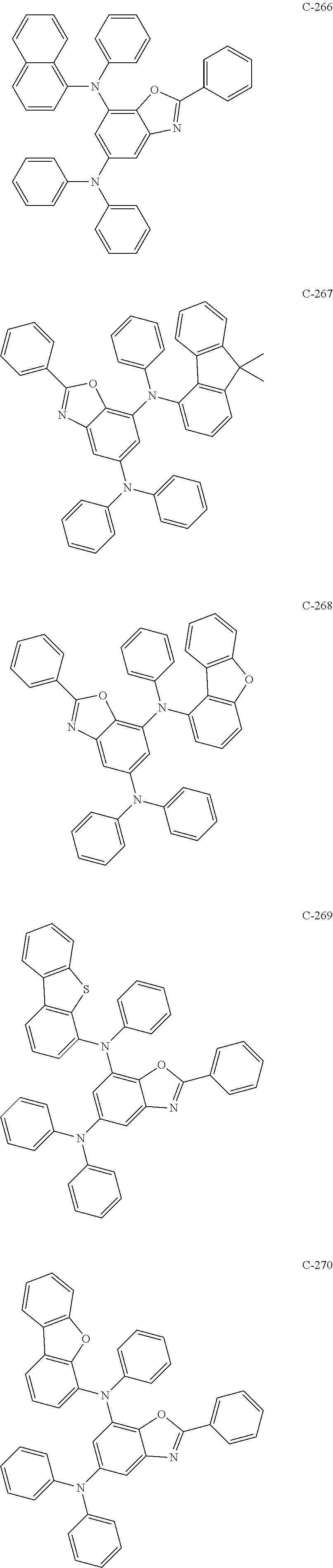 [SMILES: c1ccc(-c2nc3cc(N(c4ccccc4)c4ccccc4)cc(N(c4ccccc4)c4cccc5ccccc45)c3o2)cc1 ; CC1(C)c2ccccc2-c2c(N(c3ccccc3)c3cc(N(c4ccccc4)c4ccccc4)cc4nc(-c5ccccc5)oc34)cccc21 ; c1ccc(-c2nc3cc(N(c4ccccc4)c4ccccc4)cc(N(c4ccccc4)c4cccc5oc6ccccc6c45)c3o2)cc1 ; c1ccc(-c2nc3cc(N(c4ccccc4)c4ccccc4)cc(N(c4ccccc4)c4cccc5c4sc4ccccc45)c3o2)cc1 ; c1ccc(-c2nc3cc(N(c4ccccc4)c4ccccc4)cc(N(c4ccccc4)c4cccc5c4oc4ccccc45)c3o2)cc1]

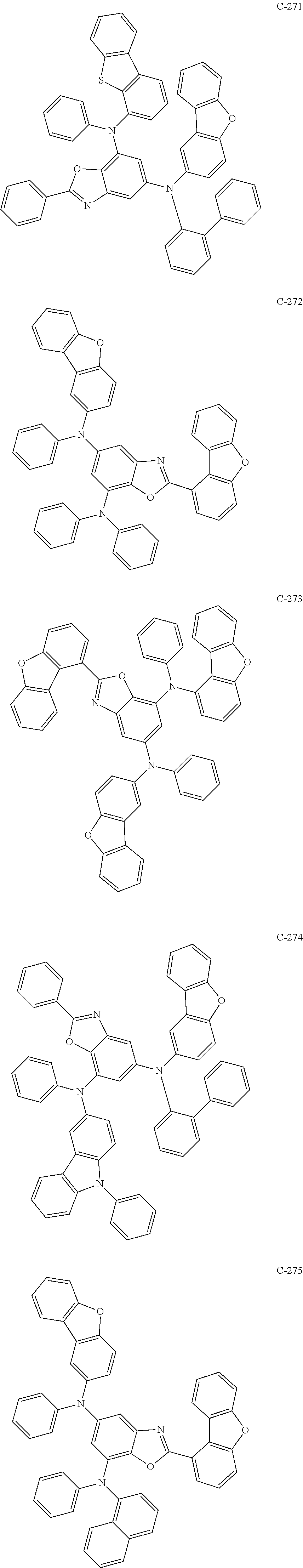 [SMILES: c1ccc(-c2nc3cc(N(c4ccc5oc6ccccc6c5c4)c4ccccc4-c4ccccc4)cc(N(c4ccccc4)c4cccc5c4sc4ccccc45)c3o2)cc1 ; c1ccc(N(c2cc(N(c3ccccc3)c3ccccc3)c3oc(-c4cccc5oc6ccccc6c45)nc3c2)c2ccc3oc4ccccc4c3c2)cc1 ; c1ccc(N(c2cc(N(c3ccccc3)c3cccc4oc5ccccc5c34)c3oc(-c4cccc5oc6ccccc6c45)nc3c2)c2ccc3oc4ccccc4c3c2)cc1 ; c1ccc(-c2nc3cc(N(c4ccc5oc6ccccc6c5c4)c4ccccc4-c4ccccc4)cc(N(c4ccccc4)c4ccc5c(c4)c4ccccc4n5-c4ccccc4)c3o2)cc1 ; c1ccc(N(c2cc(N(c3ccccc3)c3cccc4ccccc34)c3oc(-c4cccc5oc6ccccc6c45)nc3c2)c2ccc3oc4ccccc4c3c2)cc1]

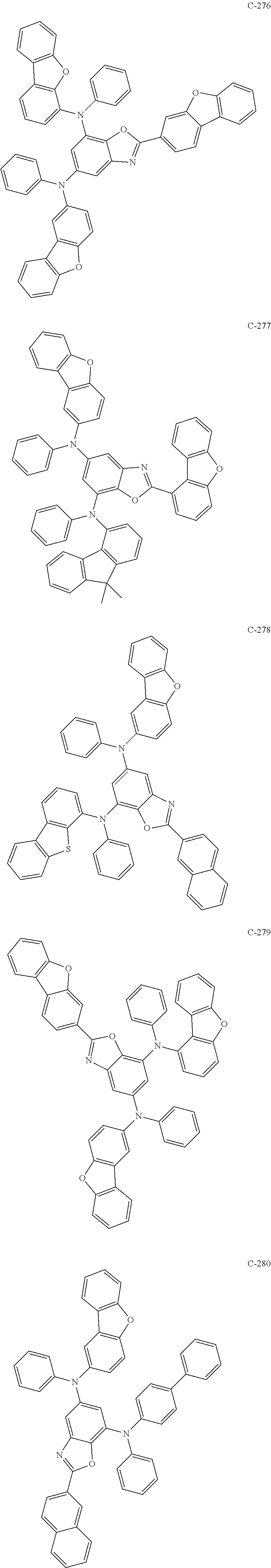

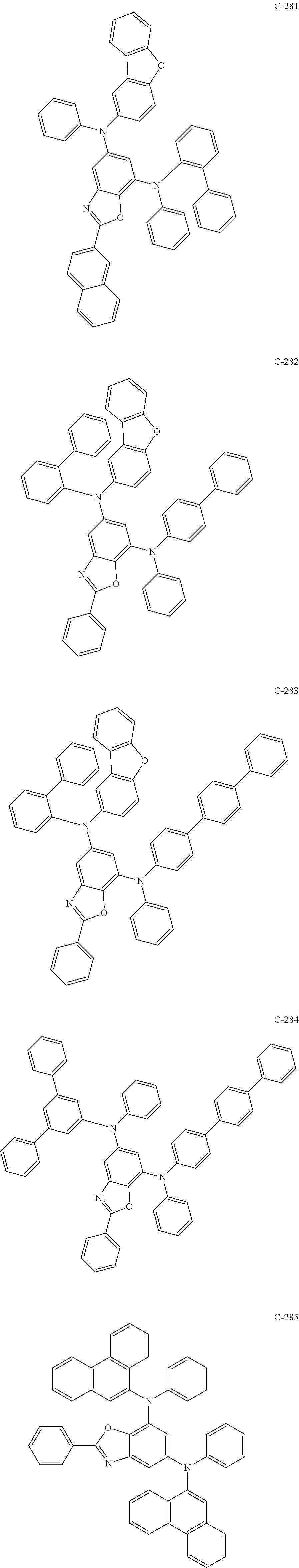

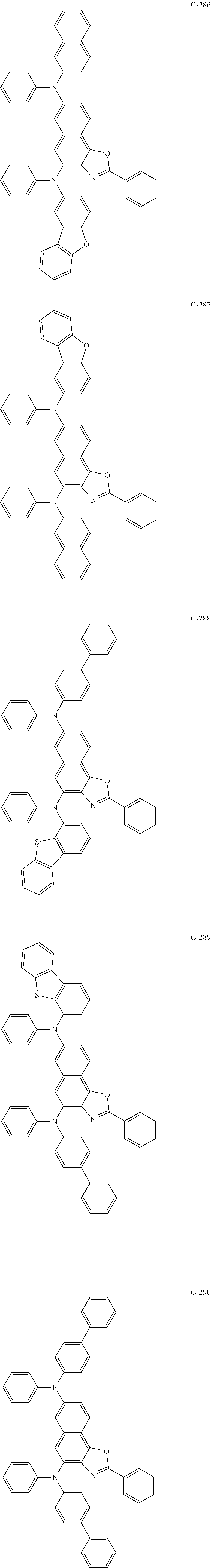 [SMILES: c1ccc(-c2nc3c(N(c4ccccc4)c4ccc5oc6ccccc6c5c4)cc4cc(N(c5ccccc5)c5ccc6ccccc6c5)ccc4c3o2)cc1 ; c1ccc(-c2nc3c(N(c4ccccc4)c4ccc5ccccc5c4)cc4cc(N(c5ccccc5)c5ccc6oc7ccccc7c6c5)ccc4c3o2)cc1 ; c1ccc(-c2ccc(N(c3ccccc3)c3ccc4c(c3)cc(N(c3ccccc3)c3cccc5c3sc3ccccc35)c3nc(-c5ccccc5)oc34)cc2)cc1 ; c1ccc(-c2ccc(N(c3ccccc3)c3cc4cc(N(c5ccccc5)c5cccc6c5sc5ccccc56)ccc4c4oc(-c5ccccc5)nc34)cc2)cc1 ; c1ccc(-c2ccc(N(c3ccccc3)c3ccc4c(c3)cc(N(c3ccccc3)c3ccc(-c5ccccc5)cc3)c3nc(-c5ccccc5)oc34)cc2)cc1]

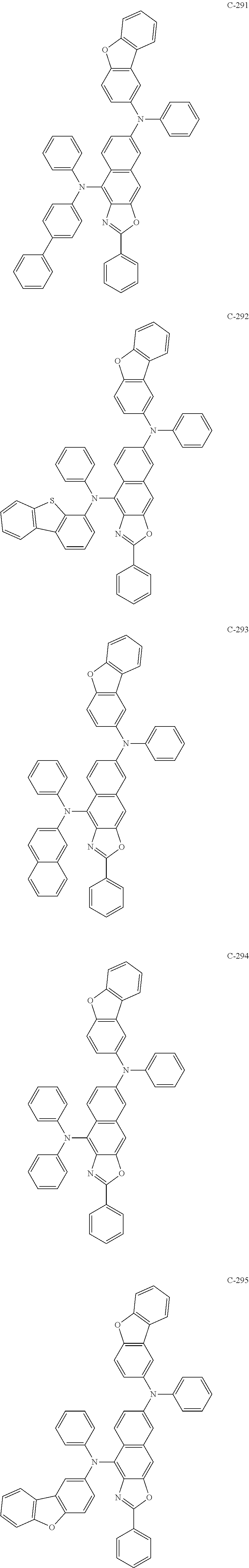 [SMILES: c1ccc(-c2ccc(N(c3ccccc3)c3c4ccc(N(c5ccccc5)c5ccc6oc7ccccc7c6c5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccc6oc7ccccc7c6c5)cc4cc3o2)cc1 ; c1ccc(-c2nc3c(N(c4ccccc4)c4ccc5ccccc5c4)c4ccc(N(c5ccccc5)c5ccc6oc7ccccc7c6c5)cc4cc3o2)cc1 ; c1ccc(-c2nc3c(N(c4ccccc4)c4ccccc4)c4ccc(N(c5ccccc5)c5ccc6oc7ccccc7c6c5)cc4cc3o2)cc1 ; c1ccc(-c2nc3c(N(c4ccccc4)c4ccc5oc6ccccc6c5c4)c4ccc(N(c5ccccc5)c5ccc6oc7ccccc7c6c5)cc4cc3o2)cc1]

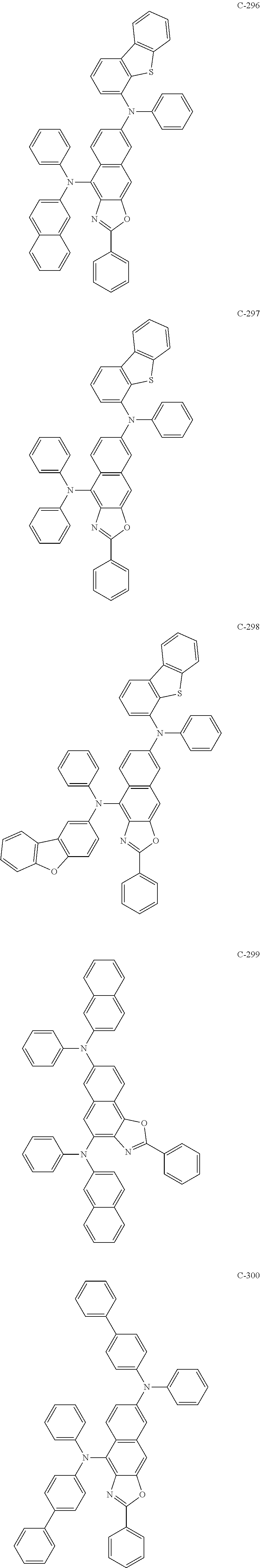 [SMILES: c1ccc(-c2nc3c(N(c4ccccc4)c4ccc5ccccc5c4)c4ccc(N(c5ccccc5)c5cccc6c5sc5ccccc56)cc4cc3o2)cc1 ; c1ccc(-c2nc3c(N(c4ccccc4)c4ccccc4)c4ccc(N(c5ccccc5)c5cccc6c5sc5ccccc56)cc4cc3o2)cc1 ; c1ccc(-c2nc3c(N(c4ccccc4)c4ccc5oc6ccccc6c5c4)c4ccc(N(c5ccccc5)c5cccc6c5sc5ccccc56)cc4cc3o2)cc1 ; c1ccc(-c2nc3c(N(c4ccccc4)c4ccc5ccccc5c4)cc4cc(N(c5ccccc5)c5ccc6ccccc6c5)ccc4c3o2)cc1 ; c1ccc(-c2ccc(N(c3ccccc3)c3ccc4c(N(c5ccccc5)c5ccc(-c6ccccc6)cc5)c5nc(-c6ccccc6)oc5cc4c3)cc2)cc1]

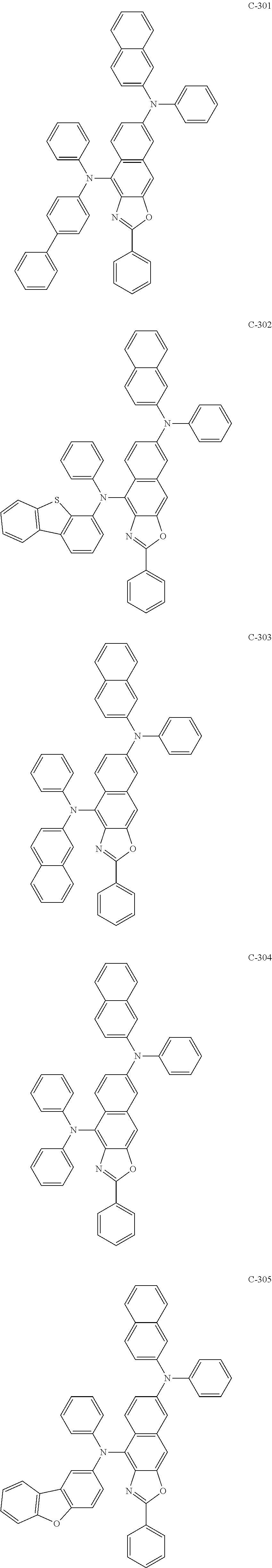 [SMILES: c1ccc(-c2ccc(N(c3ccccc3)c3c4ccc(N(c5ccccc5)c5ccc6ccccc6c5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccc6ccccc6c5)cc4cc3o2)cc1 ; c1ccc(-c2nc3c(N(c4ccccc4)c4ccc5ccccc5c4)c4ccc(N(c5ccccc5)c5ccc6ccccc6c5)cc4cc3o2)cc1 ; c1ccc(-c2nc3c(N(c4ccccc4)c4ccccc4)c4ccc(N(c5ccccc5)c5ccc6ccccc6c5)cc4cc3o2)cc1 ; c1ccc(-c2nc3c(N(c4ccccc4)c4ccc5oc6ccccc6c5c4)c4ccc(N(c5ccccc5)c5ccc6ccccc6c5)cc4cc3o2)cc1]

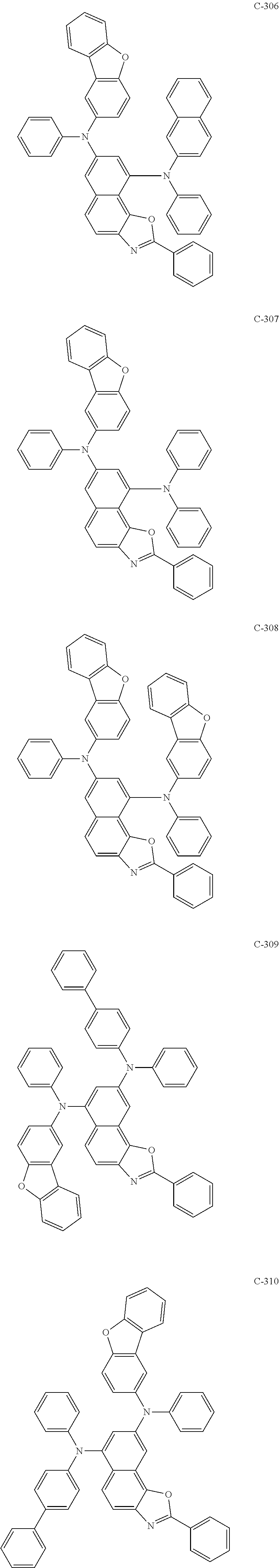 [SMILES: c1ccc(-c2nc3ccc4cc(N(c5ccccc5)c5ccc6oc7ccccc7c6c5)cc(N(c5ccccc5)c5ccc6ccccc6c5)c4c3o2)cc1 ; c1ccc(-c2nc3ccc4cc(N(c5ccccc5)c5ccc6oc7ccccc7c6c5)cc(N(c5ccccc5)c5ccccc5)c4c3o2)cc1 ; c1ccc(-c2nc3ccc4cc(N(c5ccccc5)c5ccc6oc7ccccc7c6c5)cc(N(c5ccccc5)c5ccc6oc7ccccc7c6c5)c4c3o2)cc1 ; c1ccc(-c2ccc(N(c3ccccc3)c3cc(N(c4ccccc4)c4ccc5oc6ccccc6c5c4)c4ccc5nc(-c6ccccc6)oc5c4c3)cc2)cc1 ; c1ccc(-c2ccc(N(c3ccccc3)c3cc(N(c4ccccc4)c4ccc5oc6ccccc6c5c4)cc4c3ccc3nc(-c5ccccc5)oc34)cc2)cc1]

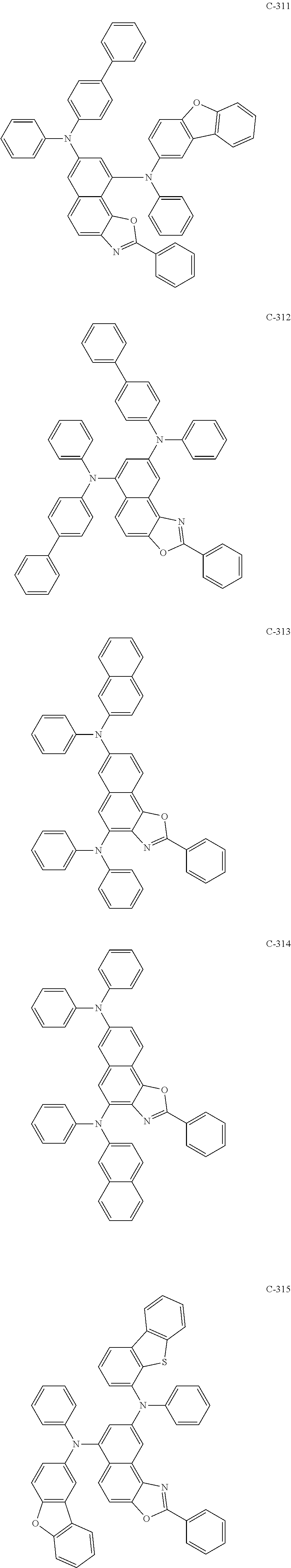 [SMILES: c1ccc(-c2ccc(N(c3ccccc3)c3cc(N(c4ccccc4)c4ccc5oc6ccccc6c5c4)c4c(ccc5nc(-c6ccccc6)oc54)c3)cc2)cc1 ; c1ccc(-c2ccc(N(c3ccccc3)c3cc(N(c4ccccc4)c4ccc(-c5ccccc5)cc4)c4ccc5oc(-c6ccccc6)nc5c4c3)cc2)cc1 ; c1ccc(-c2nc3c(N(c4ccccc4)c4ccccc4)cc4cc(N(c5ccccc5)c5ccc6ccccc6c5)ccc4c3o2)cc1 ; c1ccc(-c2nc3c(N(c4ccccc4)c4ccc5ccccc5c4)cc4cc(N(c5ccccc5)c5ccccc5)ccc4c3o2)cc1 ; c1ccc(-c2nc3c(ccc4c(N(c5ccccc5)c5ccc6oc7ccccc7c6c5)cc(N(c5ccccc5)c5cccc6c5sc5ccccc56)cc43)o2)cc1]

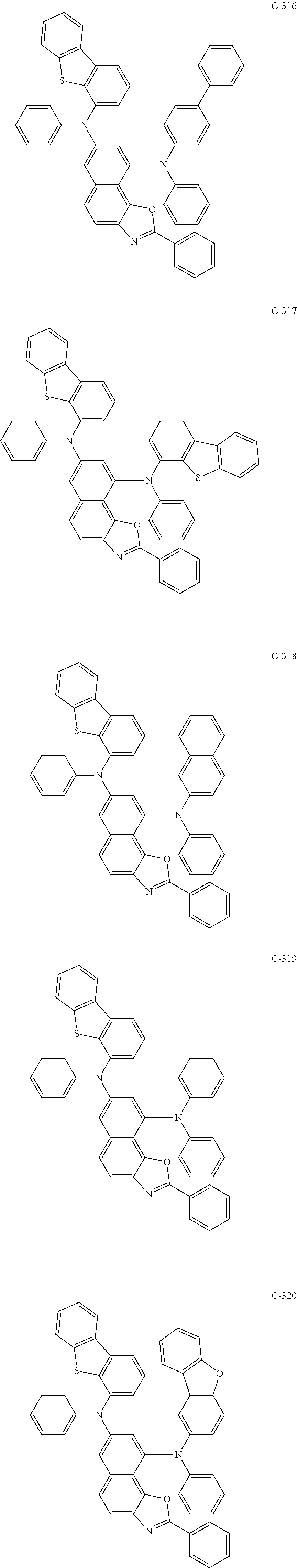 [SMILES: c1ccc(-c2ccc(N(c3ccccc3)c3cc(N(c4ccccc4)c4cccc5c4sc4ccccc45)cc4ccc5nc(-c6ccccc6)oc5c34)cc2)cc1 ; c1ccc(-c2nc3ccc4cc(N(c5ccccc5)c5cccc6c5sc5ccccc56)cc(N(c5ccccc5)c5cccc6c5sc5ccccc56)c4c3o2)cc1 ; c1ccc(-c2nc3ccc4cc(N(c5ccccc5)c5cccc6c5sc5ccccc56)cc(N(c5ccccc5)c5ccc6ccccc6c5)c4c3o2)cc1 ; c1ccc(-c2nc3ccc4cc(N(c5ccccc5)c5cccc6c5sc5ccccc56)cc(N(c5ccccc5)c5ccccc5)c4c3o2)cc1 ; c1ccc(-c2nc3ccc4cc(N(c5ccccc5)c5cccc6c5sc5ccccc56)cc(N(c5ccccc5)c5ccc6oc7ccccc7c6c5)c4c3o2)cc1]

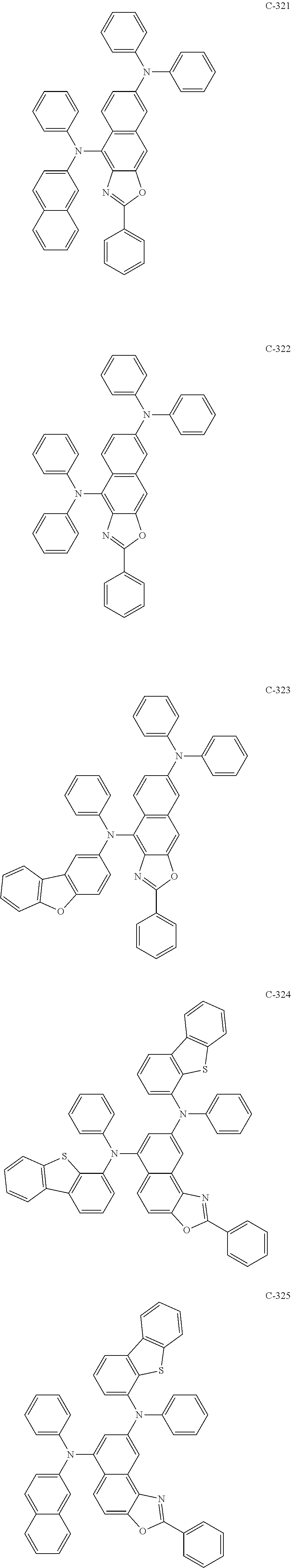 [SMILES: c1ccc(-c2nc3c(N(c4ccccc4)c4ccc5ccccc5c4)c4ccc(N(c5ccccc5)c5ccccc5)cc4cc3o2)cc1 ; c1ccc(-c2nc3c(N(c4ccccc4)c4ccccc4)c4ccc(N(c5ccccc5)c5ccccc5)cc4cc3o2)cc1 ; c1ccc(-c2nc3c(N(c4ccccc4)c4ccc5oc6ccccc6c5c4)c4ccc(N(c5ccccc5)c5ccccc5)cc4cc3o2)cc1 ; c1ccc(-c2nc3c(ccc4c(N(c5ccccc5)c5cccc6c5sc5ccccc56)cc(N(c5ccccc5)c5cccc6c5sc5ccccc56)cc43)o2)cc1 ; c1ccc(-c2nc3c(ccc4c(N(c5ccccc5)c5ccc6ccccc6c5)cc(N(c5ccccc5)c5cccc6c5sc5ccccc56)cc43)o2)cc1]

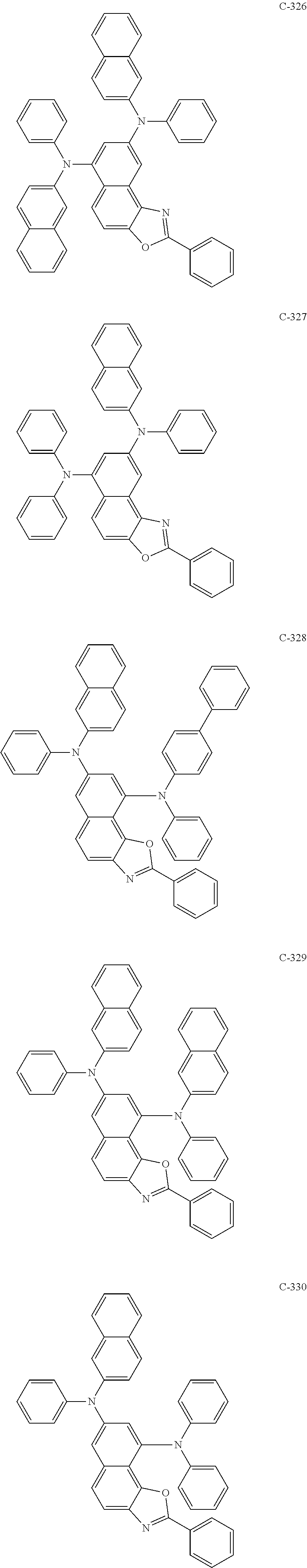 [SMILES: c1ccc(-c2nc3c(ccc4c(N(c5ccccc5)c5ccc6ccccc6c5)cc(N(c5ccccc5)c5ccc6ccccc6c5)cc43)o2)cc1 ; c1ccc(-c2nc3c(ccc4c(N(c5ccccc5)c5ccccc5)cc(N(c5ccccc5)c5ccc6ccccc6c5)cc43)o2)cc1 ; c1ccc(-c2ccc(N(c3ccccc3)c3cc(N(c4ccccc4)c4ccc5ccccc5c4)cc4ccc5nc(-c6ccccc6)oc5c34)cc2)cc1 ; c1ccc(-c2nc3ccc4cc(N(c5ccccc5)c5ccc6ccccc6c5)cc(N(c5ccccc5)c5ccc6ccccc6c5)c4c3o2)cc1 ; c1ccc(-c2nc3ccc4cc(N(c5ccccc5)c5ccc6ccccc6c5)cc(N(c5ccccc5)c5ccccc5)c4c3o2)cc1]

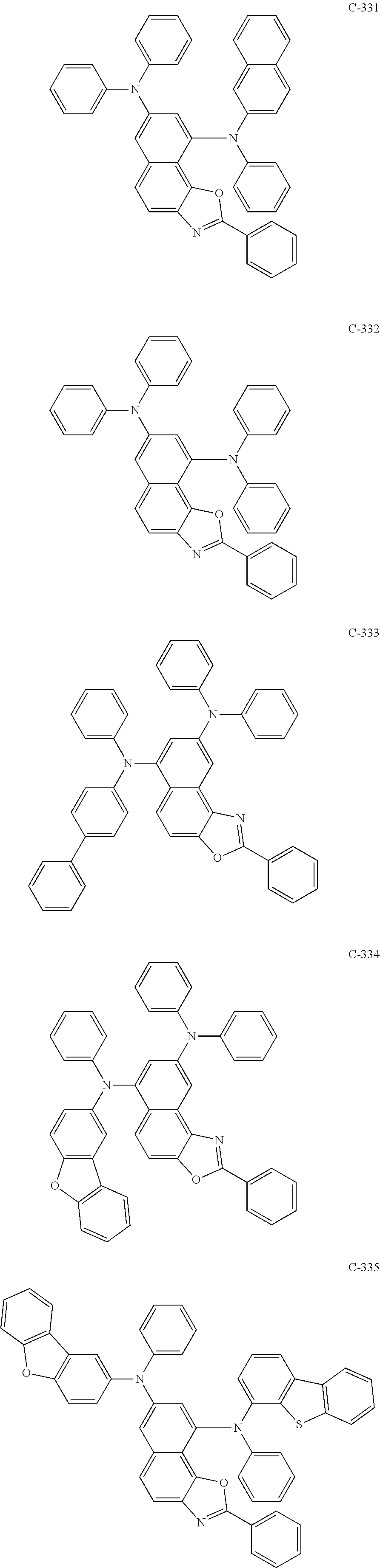 [SMILES: c1ccc(-c2nc3ccc4cc(N(c5ccccc5)c5ccccc5)cc(N(c5ccccc5)c5ccc6ccccc6c5)c4c3o2)cc1 ; c1ccc(-c2nc3ccc4cc(N(c5ccccc5)c5ccccc5)cc(N(c5ccccc5)c5ccccc5)c4c3o2)cc1 ; c1ccc(-c2ccc(N(c3ccccc3)c3cc(N(c4ccccc4)c4ccccc4)cc4c3ccc3oc(-c5ccccc5)nc34)cc2)cc1 ; c1ccc(-c2nc3c(ccc4c(N(c5ccccc5)c5ccc6oc7ccccc7c6c5)cc(N(c5ccccc5)c5ccccc5)cc43)o2)cc1 ; c1ccc(-c2nc3ccc4cc(N(c5ccccc5)c5ccc6oc7ccccc7c6c5)cc(N(c5ccccc5)c5cccc6c5sc5ccccc56)c4c3o2)cc1]

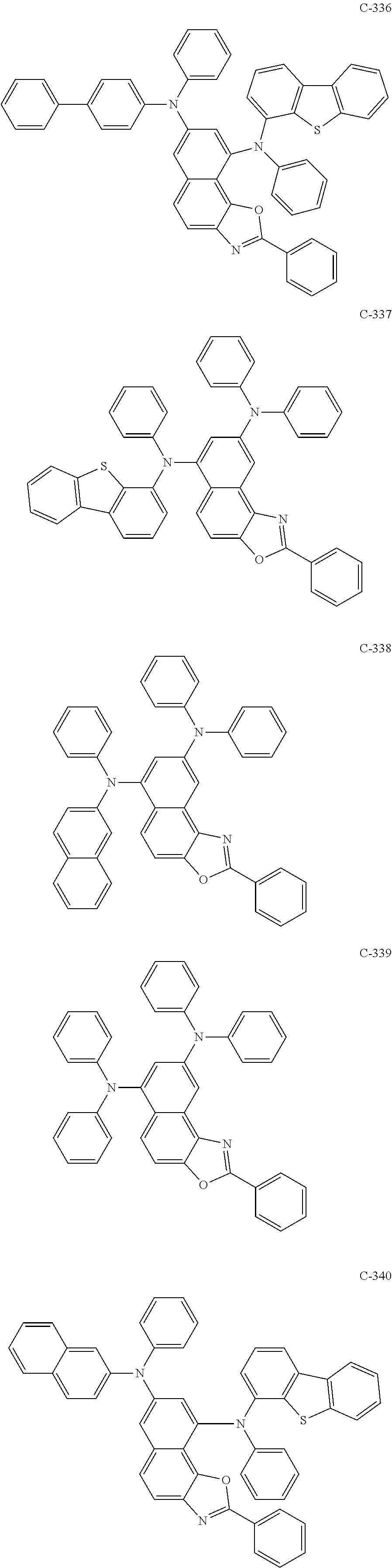 [SMILES: c1ccc(-c2ccc(N(c3ccccc3)c3cc(N(c4ccccc4)c4cccc5c4sc4ccccc45)c4c(ccc5nc(-c6ccccc6)oc54)c3)cc2)cc1 ; c1ccc(-c2nc3c(ccc4c(N(c5ccccc5)c5cccc6c5sc5ccccc56)cc(N(c5ccccc5)c5ccccc5)cc43)o2)cc1 ; c1ccc(-c2nc3c(ccc4c(N(c5ccccc5)c5ccc6ccccc6c5)cc(N(c5ccccc5)c5ccccc5)cc43)o2)cc1 ; c1ccc(-c2nc3c(ccc4c(N(c5ccccc5)c5ccccc5)cc(N(c5ccccc5)c5ccccc5)cc43)o2)cc1 ; c1ccc(-c2nc3ccc4cc(N(c5ccccc5)c5ccc6ccccc6c5)cc(N(c5ccccc5)c5cccc6c5sc5ccccc56)c4c3o2)cc1]

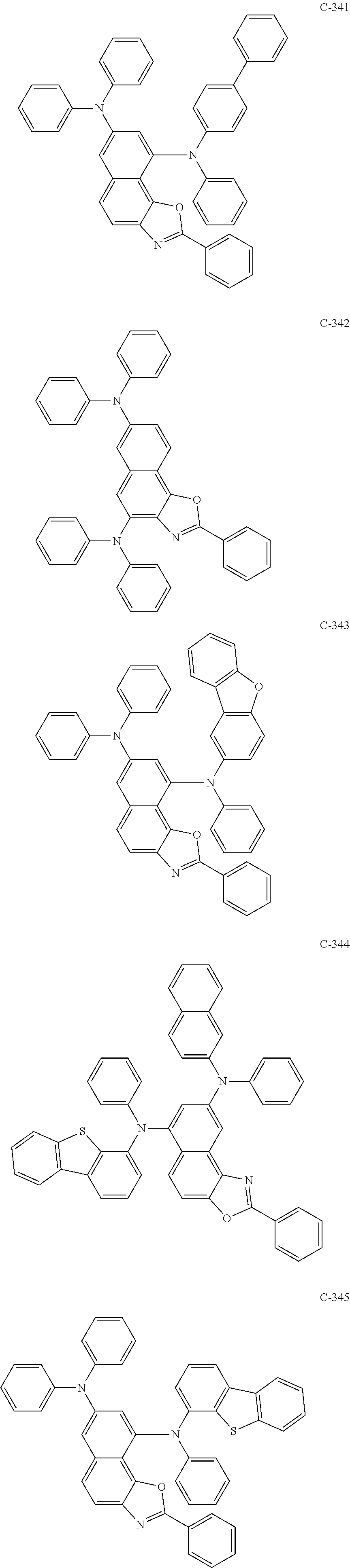 [SMILES: c1ccc(-c2ccc(N(c3ccccc3)c3cc(N(c4ccccc4)c4ccccc4)cc4ccc5nc(-c6ccccc6)oc5c34)cc2)cc1 ; c1ccc(-c2nc3c(N(c4ccccc4)c4ccccc4)cc4cc(N(c5ccccc5)c5ccccc5)ccc4c3o2)cc1 ; c1ccc(-c2nc3ccc4cc(N(c5ccccc5)c5ccccc5)cc(N(c5ccccc5)c5ccc6oc7ccccc7c6c5)c4c3o2)cc1 ; c1ccc(-c2nc3c(ccc4c(N(c5ccccc5)c5cccc6c5sc5ccccc56)cc(N(c5ccccc5)c5ccc6ccccc6c5)cc43)o2)cc1 ; c1ccc(-c2nc3ccc4cc(N(c5ccccc5)c5ccccc5)cc(N(c5ccccc5)c5cccc6c5sc5ccccc56)c4c3o2)cc1]

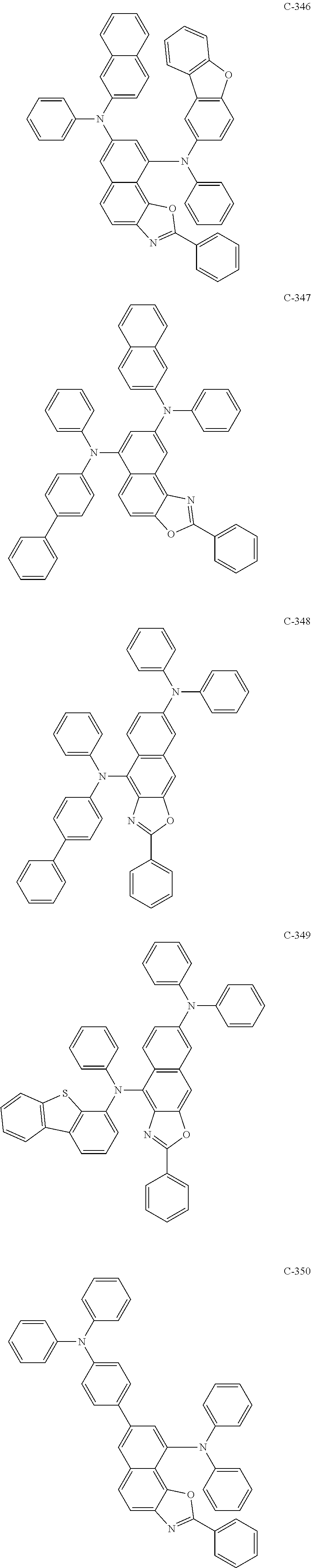 [SMILES: c1ccc(-c2nc3ccc4cc(N(c5ccccc5)c5ccc6ccccc6c5)cc(N(c5ccccc5)c5ccc6oc7ccccc7c6c5)c4c3o2)cc1 ; c1ccc(-c2ccc(N(c3ccccc3)c3cc(N(c4ccccc4)c4ccc5ccccc5c4)cc4c3ccc3oc(-c5ccccc5)nc34)cc2)cc1 ; c1ccc(-c2ccc(N(c3ccccc3)c3c4ccc(N(c5ccccc5)c5ccccc5)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5ccccc5)cc4cc3o2)cc1 ; c1ccc(-c2nc3ccc4cc(-c5ccc(N(c6ccccc6)c6ccccc6)cc5)cc(N(c5ccccc5)c5ccccc5)c4c3o2)cc1]

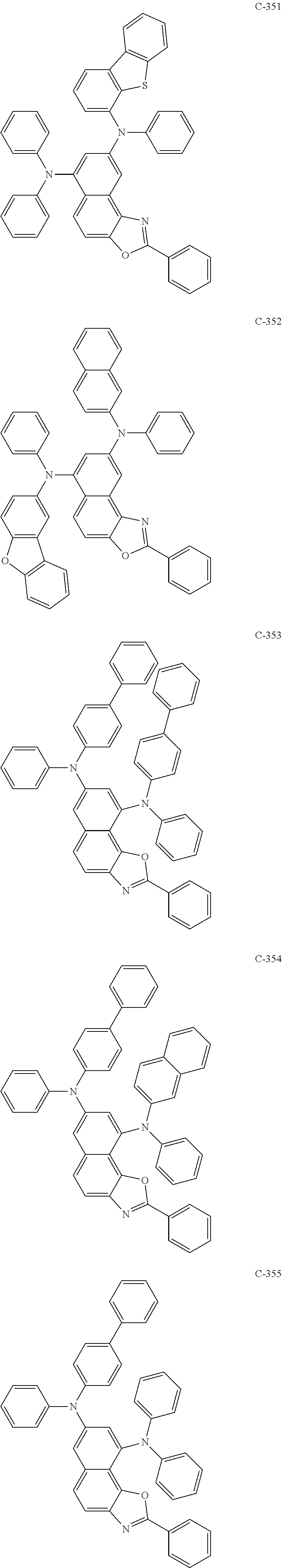 [SMILES: c1ccc(-c2nc3c(ccc4c(N(c5ccccc5)c5ccccc5)cc(N(c5ccccc5)c5cccc6c5sc5ccccc56)cc43)o2)cc1 ; c1ccc(-c2nc3c(ccc4c(N(c5ccccc5)c5ccc6oc7ccccc7c6c5)cc(N(c5ccccc5)c5ccc6ccccc6c5)cc43)o2)cc1 ; c1ccc(-c2ccc(N(c3ccccc3)c3cc(N(c4ccccc4)c4ccc(-c5ccccc5)cc4)c4c(ccc5nc(-c6ccccc6)oc54)c3)cc2)cc1 ; c1ccc(-c2ccc(N(c3ccccc3)c3cc(N(c4ccccc4)c4ccc5ccccc5c4)c4c(ccc5nc(-c6ccccc6)oc54)c3)cc2)cc1 ; c1ccc(-c2ccc(N(c3ccccc3)c3cc(N(c4ccccc4)c4ccccc4)c4c(ccc5nc(-c6ccccc6)oc54)c3)cc2)cc1]

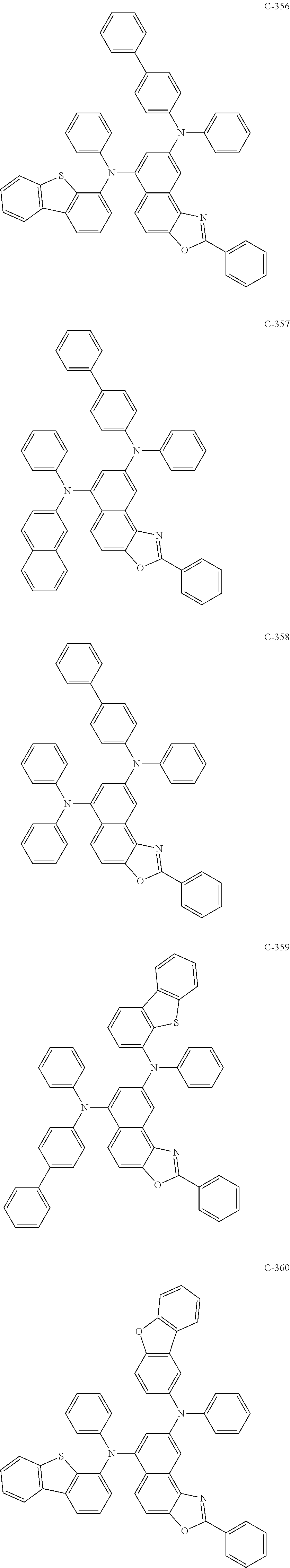 [SMILES: c1ccc(-c2ccc(N(c3ccccc3)c3cc(N(c4ccccc4)c4cccc5c4sc4ccccc45)c4ccc5oc(-c6ccccc6)nc5c4c3)cc2)cc1 ; c1ccc(-c2ccc(N(c3ccccc3)c3cc(N(c4ccccc4)c4ccc5ccccc5c4)c4ccc5oc(-c6ccccc6)nc5c4c3)cc2)cc1 ; c1ccc(-c2ccc(N(c3ccccc3)c3cc(N(c4ccccc4)c4ccccc4)c4ccc5oc(-c6ccccc6)nc5c4c3)cc2)cc1 ; c1ccc(-c2ccc(N(c3ccccc3)c3cc(N(c4ccccc4)c4cccc5c4sc4ccccc45)cc4c3ccc3oc(-c5ccccc5)nc34)cc2)cc1 ; c1ccc(-c2nc3c(ccc4c(N(c5ccccc5)c5cccc6c5sc5ccccc56)cc(N(c5ccccc5)c5ccc6oc7ccccc7c6c5)cc43)o2)cc1]

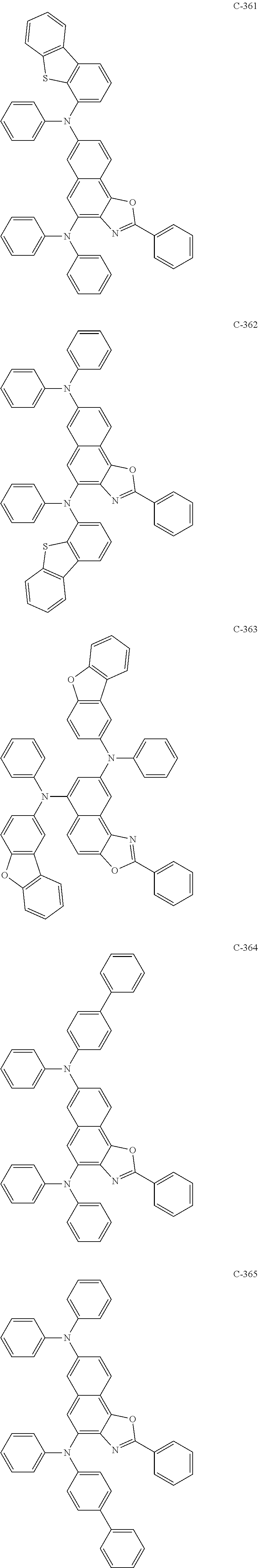 [SMILES: c1ccc(-c2nc3c(N(c4ccccc4)c4ccccc4)cc4cc(N(c5ccccc5)c5cccc6c5sc5ccccc56)ccc4c3o2)cc1 ; c1ccc(-c2nc3c(N(c4ccccc4)c4cccc5c4sc4ccccc45)cc4cc(N(c5ccccc5)c5ccccc5)ccc4c3o2)cc1 ; c1ccc(-c2nc3c(ccc4c(N(c5ccccc5)c5ccc6oc7ccccc7c6c5)cc(N(c5ccccc5)c5ccc6oc7ccccc7c6c5)cc43)o2)cc1 ; c1ccc(-c2ccc(N(c3ccccc3)c3ccc4c(c3)cc(N(c3ccccc3)c3ccccc3)c3nc(-c5ccccc5)oc34)cc2)cc1 ; c1ccc(-c2ccc(N(c3ccccc3)c3cc4cc(N(c5ccccc5)c5ccccc5)ccc4c4oc(-c5ccccc5)nc34)cc2)cc1]

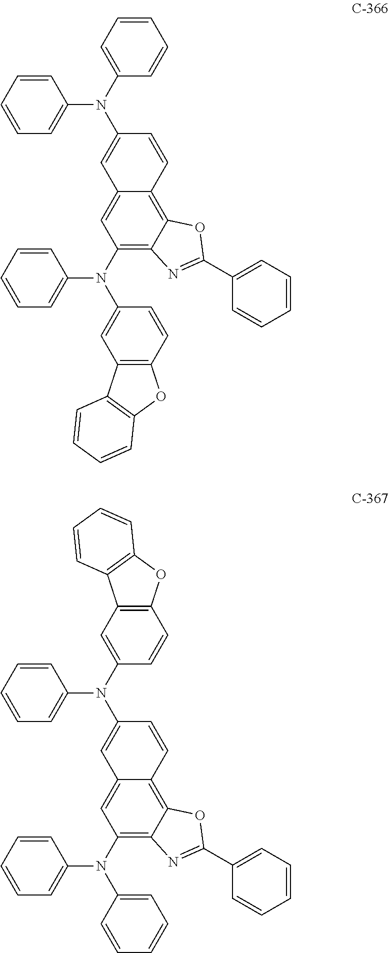

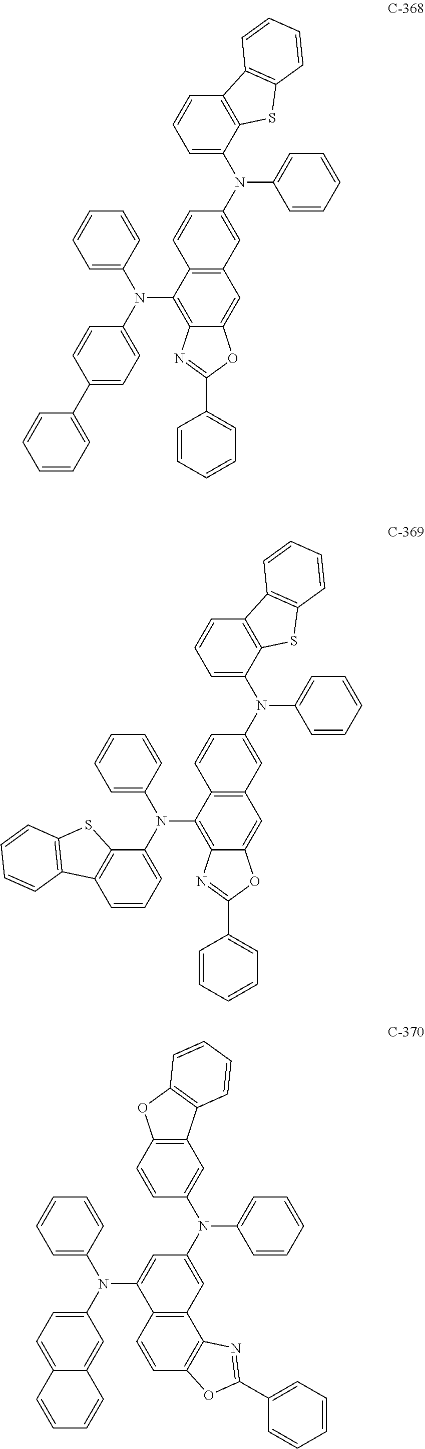 [SMILES: c1ccc(-c2ccc(N(c3ccccc3)c3c4ccc(N(c5ccccc5)c5cccc6c5sc5ccccc56)cc4cc4oc(-c5ccccc5)nc34)cc2)cc1 ; c1ccc(-c2nc3c(N(c4ccccc4)c4cccc5c4sc4ccccc45)c4ccc(N(c5ccccc5)c5cccc6c5sc5ccccc56)cc4cc3o2)cc1 ; c1ccc(-c2nc3c(ccc4c(N(c5ccccc5)c5ccc6ccccc6c5)cc(N(c5ccccc5)c5ccc6oc7ccccc7c6c5)cc43)o2)cc1]

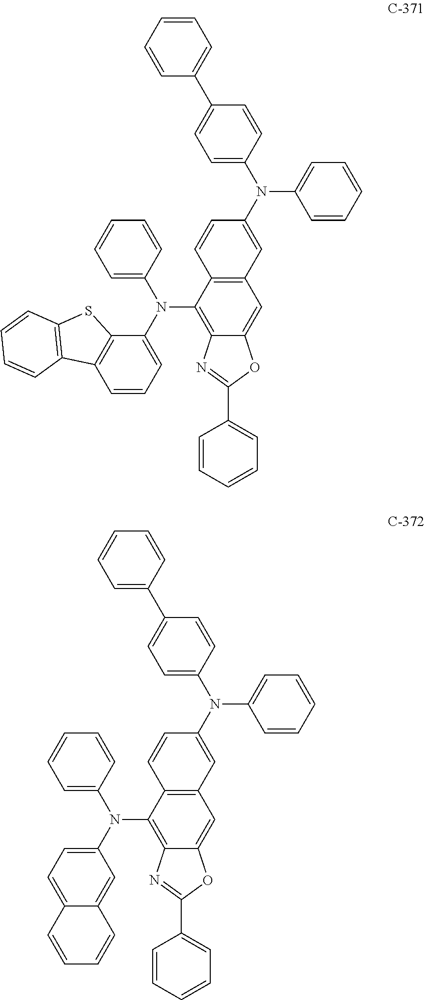 [SMILES: c1ccc(-c2ccc(N(c3ccccc3)c3ccc4c(N(c5ccccc5)c5cccc6c5sc5ccccc56)c5nc(-c6ccccc6)oc5cc4c3)cc2)cc1 ; c1ccc(-c2ccc(N(c3ccccc3)c3ccc4c(N(c5ccccc5)c5ccc6ccccc6c5)c5nc(-c6ccccc6)oc5cc4c3)cc2)cc1]

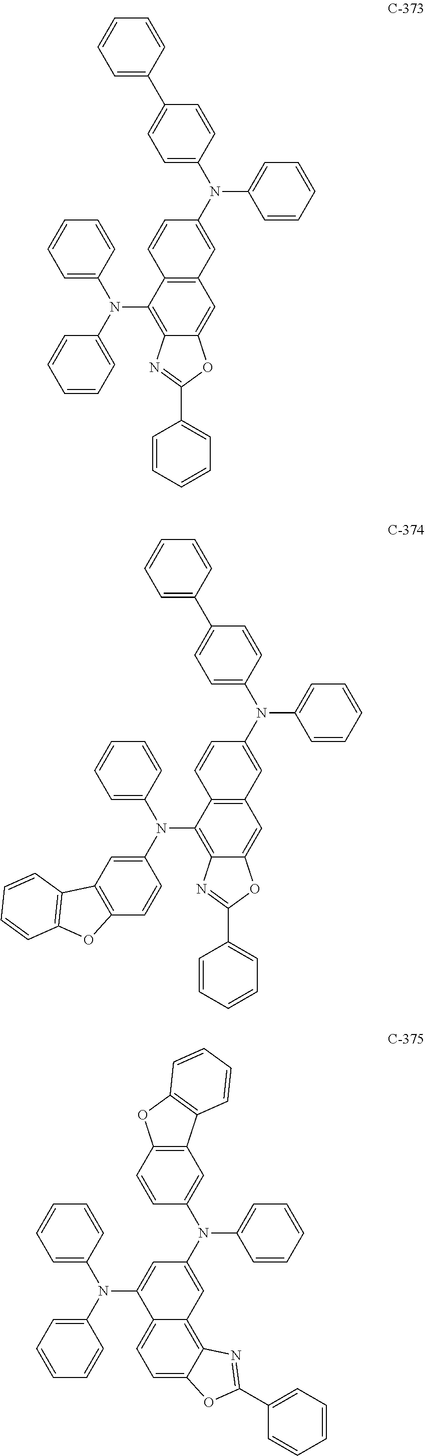 [SMILES: c1ccc(-c2ccc(N(c3ccccc3)c3ccc4c(N(c5ccccc5)c5ccccc5)c5nc(-c6ccccc6)oc5cc4c3)cc2)cc1 ; c1ccc(-c2ccc(N(c3ccccc3)c3ccc4c(N(c5ccccc5)c5ccc6oc7ccccc7c6c5)c5nc(-c6ccccc6)oc5cc4c3)cc2)cc1 ; c1ccc(-c2nc3c(ccc4c(N(c5ccccc5)c5ccccc5)cc(N(c5ccccc5)c5ccc6oc7ccccc7c6c5)cc43)o2)cc1]

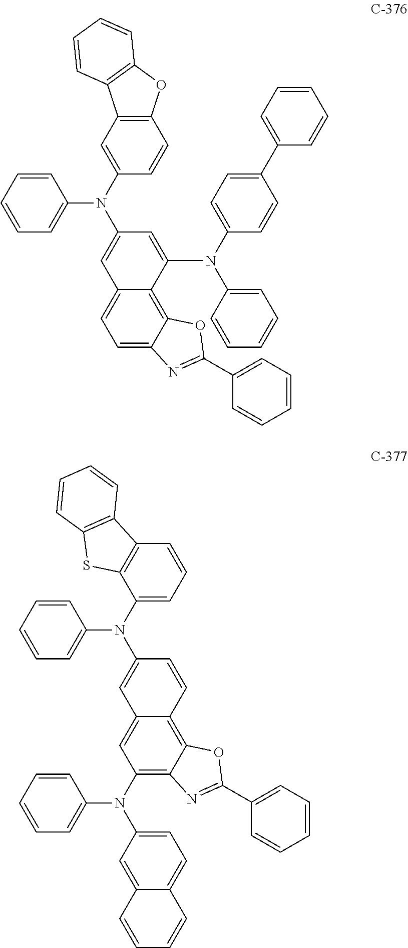 [SMILES: c1ccc(-c2ccc(N(c3ccccc3)c3cc(N(c4ccccc4)c4ccc5oc6ccccc6c5c4)cc4ccc5nc(-c6ccccc6)oc5c34)cc2)cc1 ; c1ccc(-c2nc3c(N(c4ccccc4)c4ccc5ccccc5c4)cc4cc(N(c5ccccc5)c5cccc6c5sc5ccccc56)ccc4c3o2)cc1]

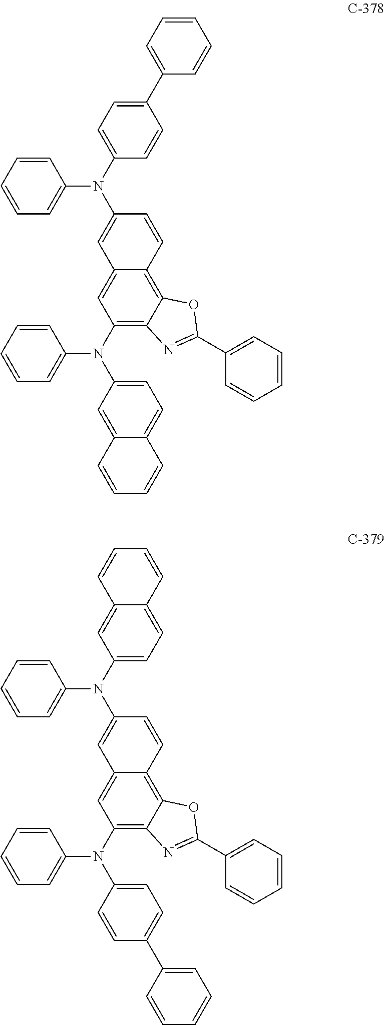 [SMILES: c1ccc(-c2ccc(N(c3ccccc3)c3ccc4c(c3)cc(N(c3ccccc3)c3ccc5ccccc5c3)c3nc(-c5ccccc5)oc34)cc2)cc1 ; c1ccc(-c2ccc(N(c3ccccc3)c3cc4cc(N(c5ccccc5)c5ccc6ccccc6c5)ccc4c4oc(-c5ccccc5)nc34)cc2)cc1]

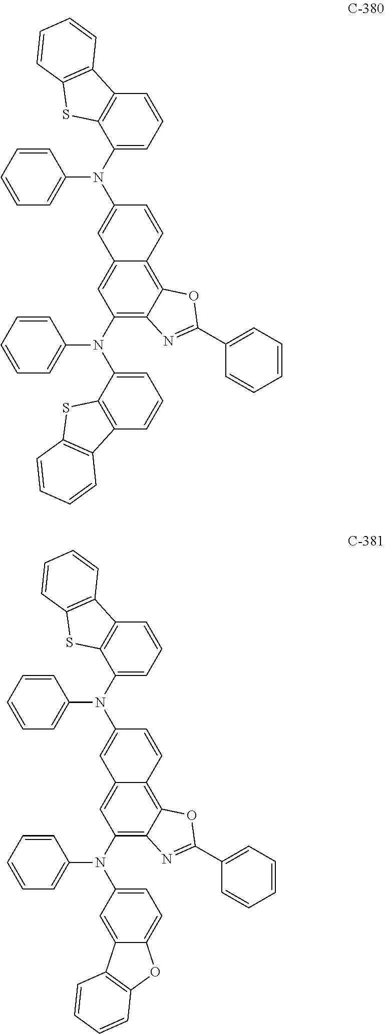 [SMILES: c1ccc(-c2nc3c(N(c4ccccc4)c4cccc5c4sc4ccccc45)cc4cc(N(c5ccccc5)c5cccc6c5sc5ccccc56)ccc4c3o2)cc1 ; c1ccc(-c2nc3c(N(c4ccccc4)c4ccc5oc6ccccc6c5c4)cc4cc(N(c5ccccc5)c5cccc6c5sc5ccccc56)ccc4c3o2)cc1]

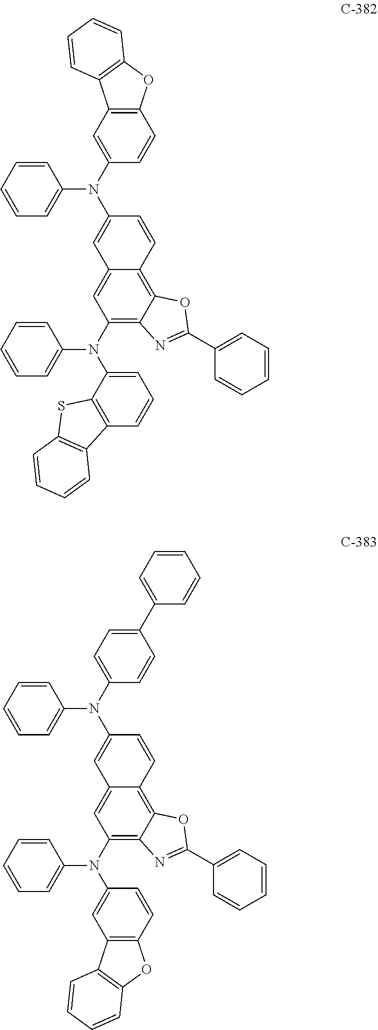 [SMILES: c1ccc(-c2nc3c(N(c4ccccc4)c4cccc5c4sc4ccccc45)cc4cc(N(c5ccccc5)c5ccc6oc7ccccc7c6c5)ccc4c3o2)cc1 ; c1ccc(-c2ccc(N(c3ccccc3)c3ccc4c(c3)cc(N(c3ccccc3)c3ccc5oc6ccccc6c5c3)c3nc(-c5ccccc5)oc34)cc2)cc1]

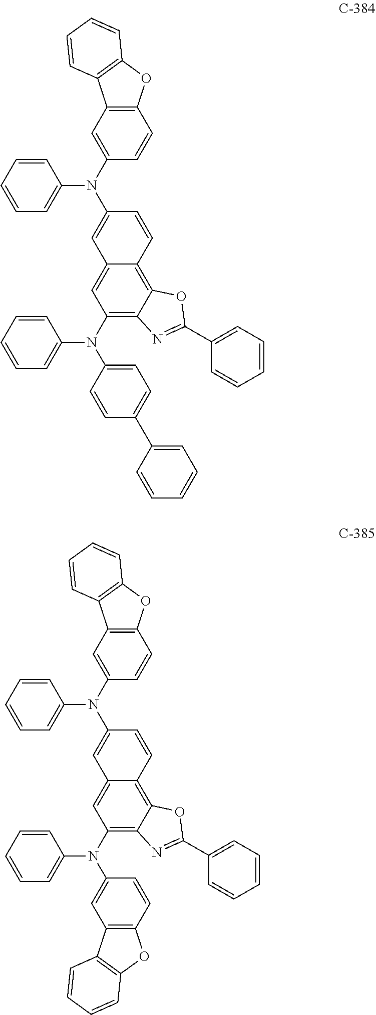 [SMILES: c1ccc(-c2ccc(N(c3ccccc3)c3cc4cc(N(c5ccccc5)c5ccc6oc7ccccc7c6c5)ccc4c4oc(-c5ccccc5)nc34)cc2)cc1 ; c1ccc(-c2nc3c(N(c4ccccc4)c4ccc5oc6ccccc6c5c4)cc4cc(N(c5ccccc5)c5ccc6oc7ccccc7c6c5)ccc4c3o2)cc1]

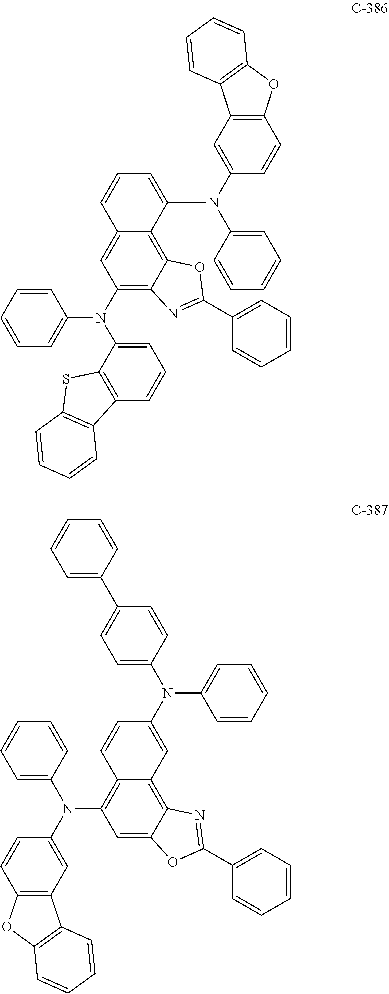

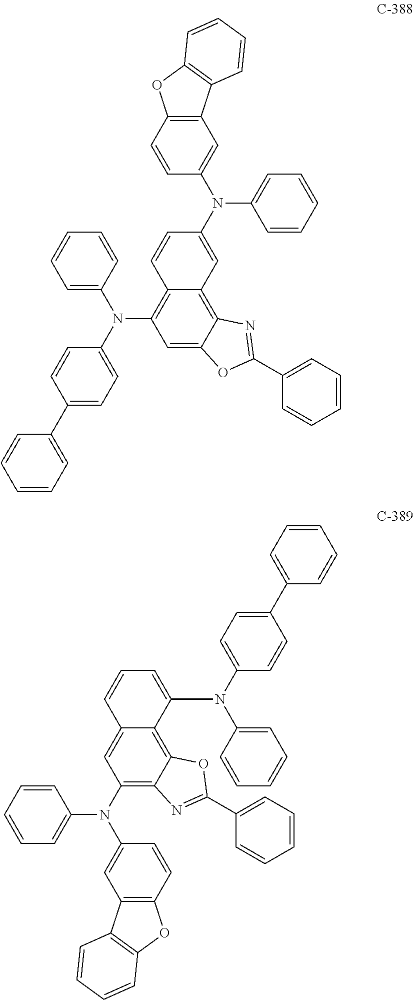 [SMILES: c1ccc(-c2ccc(N(c3ccccc3)c3cc4oc(-c5ccccc5)nc4c4cc(N(c5ccccc5)c5ccc6oc7ccccc7c6c5)ccc34)cc2)cc1 ; c1ccc(-c2ccc(N(c3ccccc3)c3cccc4cc(N(c5ccccc5)c5ccc6oc7ccccc7c6c5)c5nc(-c6ccccc6)oc5c34)cc2)cc1]

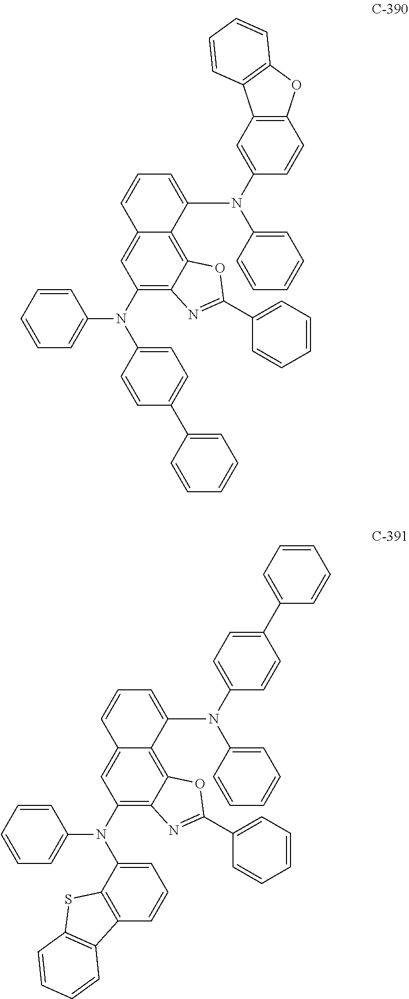 [SMILES: c1ccc(-c2ccc(N(c3ccccc3)c3cc4cccc(N(c5ccccc5)c5ccc6oc7ccccc7c6c5)c4c4oc(-c5ccccc5)nc34)cc2)cc1 ; c1ccc(-c2ccc(N(c3ccccc3)c3cccc4cc(N(c5ccccc5)c5cccc6c5sc5ccccc56)c5nc(-c6ccccc6)oc5c34)cc2)cc1]

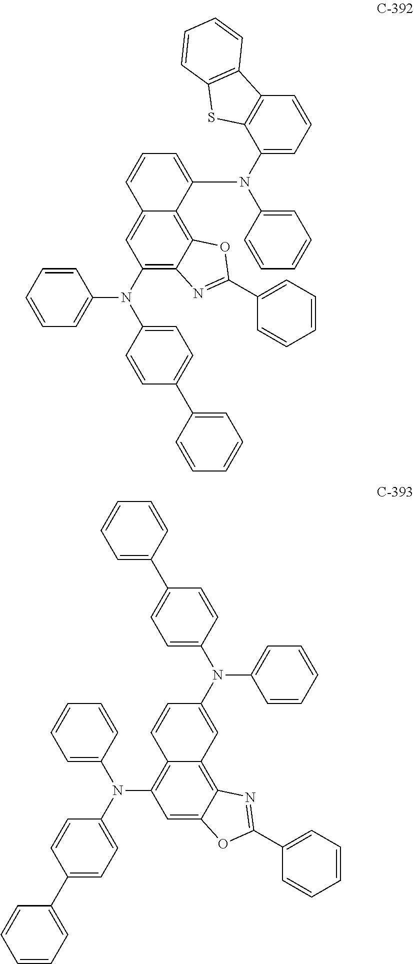 [SMILES: c1ccc(-c2ccc(N(c3ccccc3)c3cc4cccc(N(c5ccccc5)c5cccc6c5sc5ccccc56)c4c4oc(-c5ccccc5)nc34)cc2)cc1 ; c1ccc(-c2ccc(N(c3ccccc3)c3ccc4c(N(c5ccccc5)c5ccc(-c6ccccc6)cc5)cc5oc(-c6ccccc6)nc5c4c3)cc2)cc1]

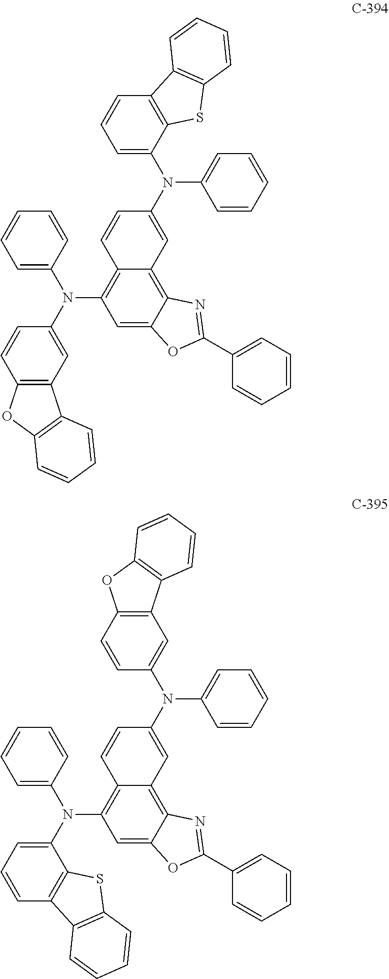 [SMILES: c1ccc(-c2nc3c(cc(N(c4ccccc4)c4ccc5oc6ccccc6c5c4)c4ccc(N(c5ccccc5)c5cccc6c5sc5ccccc56)cc43)o2)cc1 ; c1ccc(-c2nc3c(cc(N(c4ccccc4)c4cccc5c4sc4ccccc45)c4ccc(N(c5ccccc5)c5ccc6oc7ccccc7c6c5)cc43)o2)cc1]

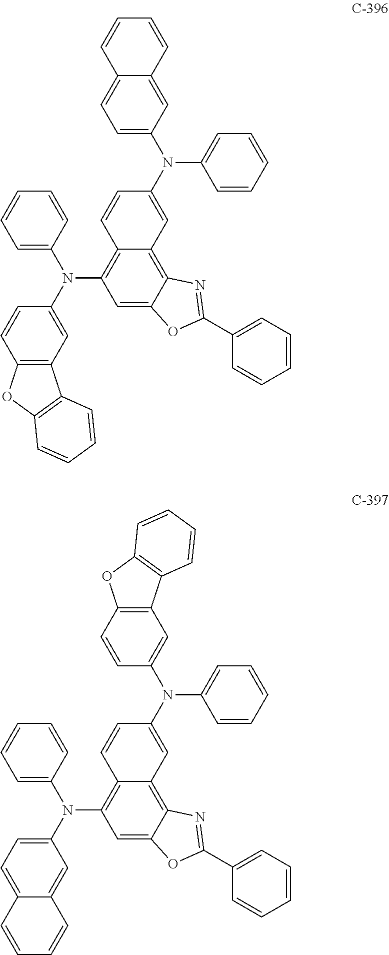 [SMILES: c1ccc(-c2nc3c(cc(N(c4ccccc4)c4ccc5oc6ccccc6c5c4)c4ccc(N(c5ccccc5)c5ccc6ccccc6c5)cc43)o2)cc1 ; c1ccc(-c2nc3c(cc(N(c4ccccc4)c4ccc5ccccc5c4)c4ccc(N(c5ccccc5)c5ccc6oc7ccccc7c6c5)cc43)o2)cc1]

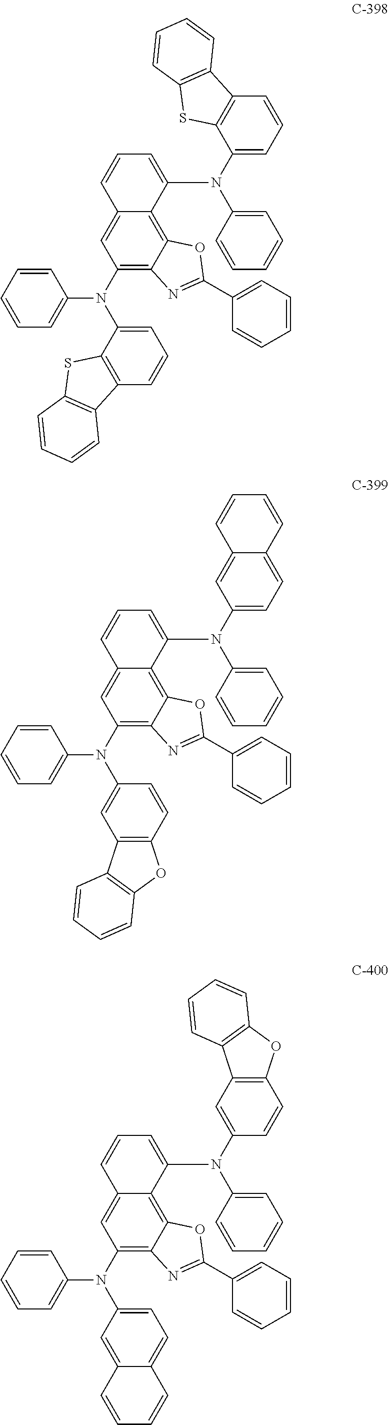 [SMILES: c1ccc(-c2nc3c(N(c4ccccc4)c4cccc5c4sc4ccccc45)cc4cccc(N(c5ccccc5)c5cccc6c5sc5ccccc56)c4c3o2)cc1 ; c1ccc(-c2nc3c(N(c4ccccc4)c4ccc5oc6ccccc6c5c4)cc4cccc(N(c5ccccc5)c5ccc6ccccc6c5)c4c3o2)cc1 ; c1ccc(-c2nc3c(N(c4ccccc4)c4ccc5ccccc5c4)cc4cccc(N(c5ccccc5)c5ccc6oc7ccccc7c6c5)c4c3o2)cc1]

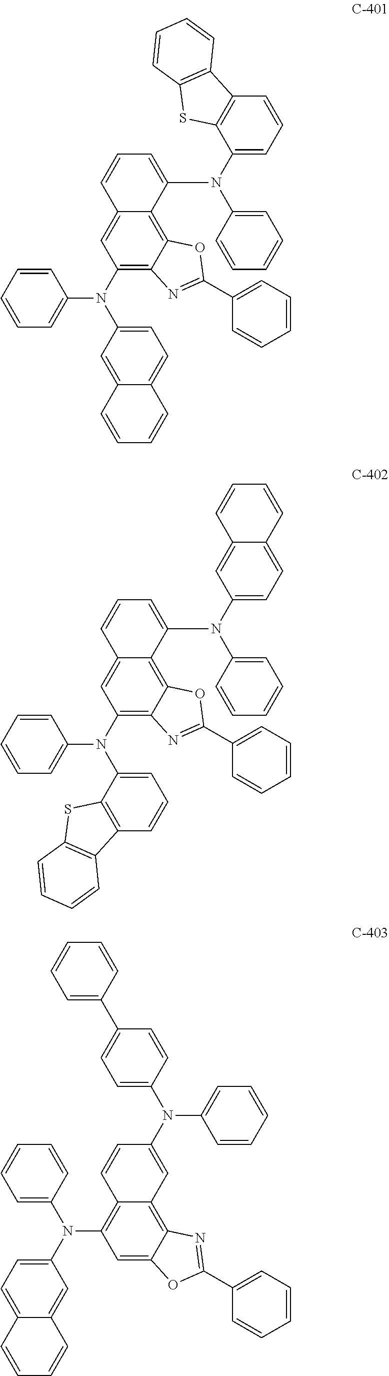

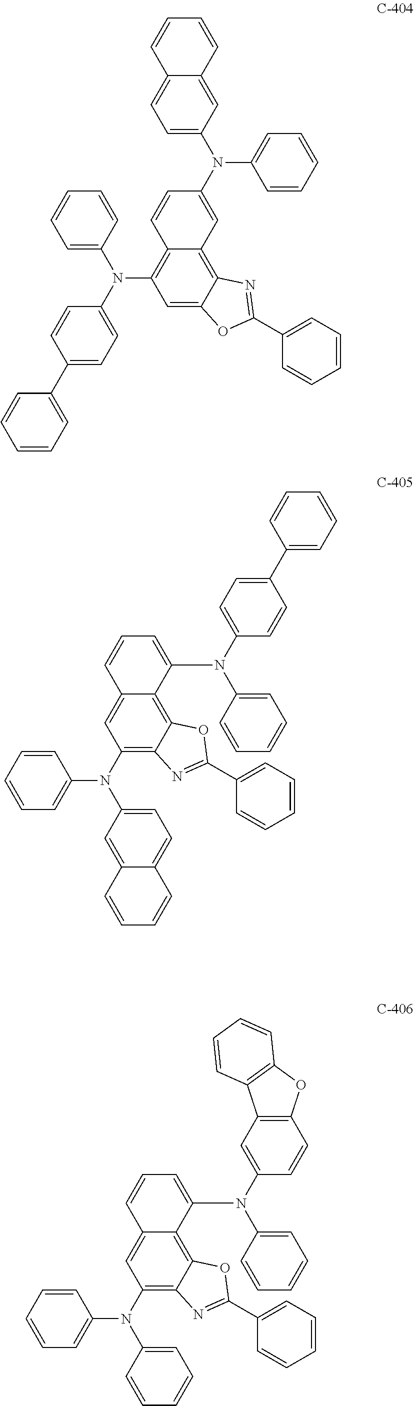 [SMILES: c1ccc(-c2ccc(N(c3ccccc3)c3cc4oc(-c5ccccc5)nc4c4cc(N(c5ccccc5)c5ccc6ccccc6c5)ccc34)cc2)cc1 ; c1ccc(-c2ccc(N(c3ccccc3)c3cccc4cc(N(c5ccccc5)c5ccc6ccccc6c5)c5nc(-c6ccccc6)oc5c34)cc2)cc1 ; c1ccc(-c2nc3c(N(c4ccccc4)c4ccccc4)cc4cccc(N(c5ccccc5)c5ccc6oc7ccccc7c6c5)c4c3o2)cc1]

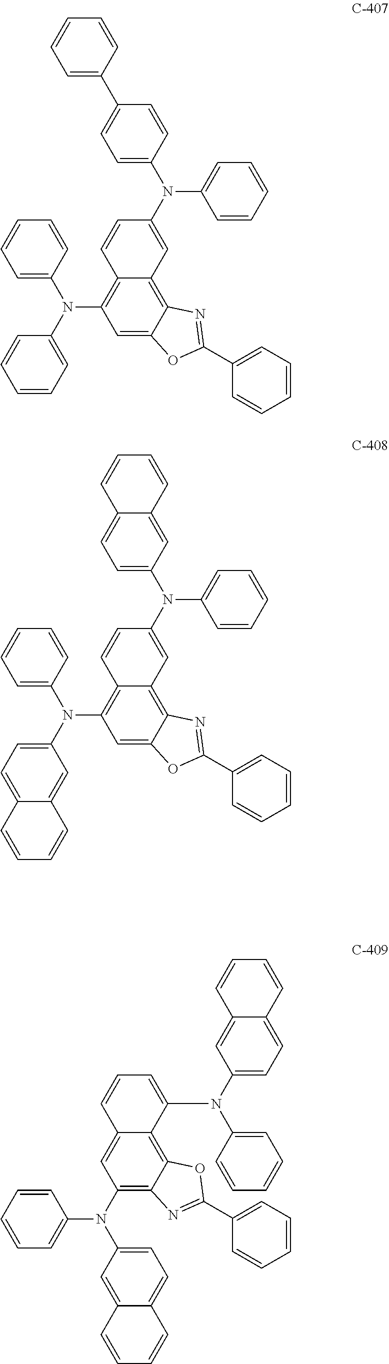 [SMILES: c1ccc(-c2ccc(N(c3ccccc3)c3ccc4c(N(c5ccccc5)c5ccccc5)cc5oc(-c6ccccc6)nc5c4c3)cc2)cc1 ; c1ccc(-c2nc3c(cc(N(c4ccccc4)c4ccc5ccccc5c4)c4ccc(N(c5ccccc5)c5ccc6ccccc6c5)cc43)o2)cc1 ; c1ccc(-c2nc3c(N(c4ccccc4)c4ccc5ccccc5c4)cc4cccc(N(c5ccccc5)c5ccc6ccccc6c5)c4c3o2)cc1]

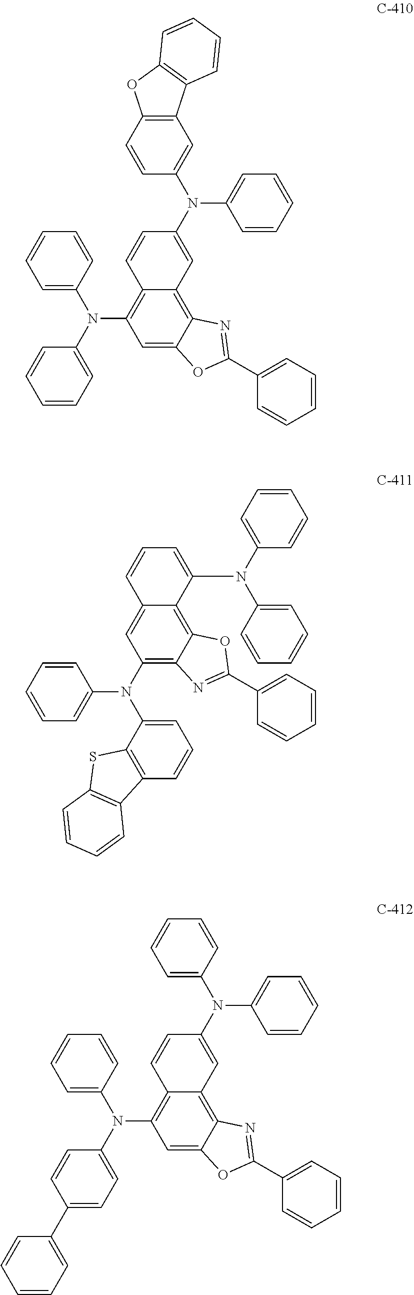 [SMILES: c1ccc(-c2nc3c(cc(N(c4ccccc4)c4ccccc4)c4ccc(N(c5ccccc5)c5ccc6oc7ccccc7c6c5)cc43)o2)cc1 ; c1ccc(-c2nc3c(N(c4ccccc4)c4cccc5c4sc4ccccc45)cc4cccc(N(c5ccccc5)c5ccccc5)c4c3o2)cc1 ; c1ccc(-c2ccc(N(c3ccccc3)c3cc4oc(-c5ccccc5)nc4c4cc(N(c5ccccc5)c5ccccc5)ccc34)cc2)cc1]

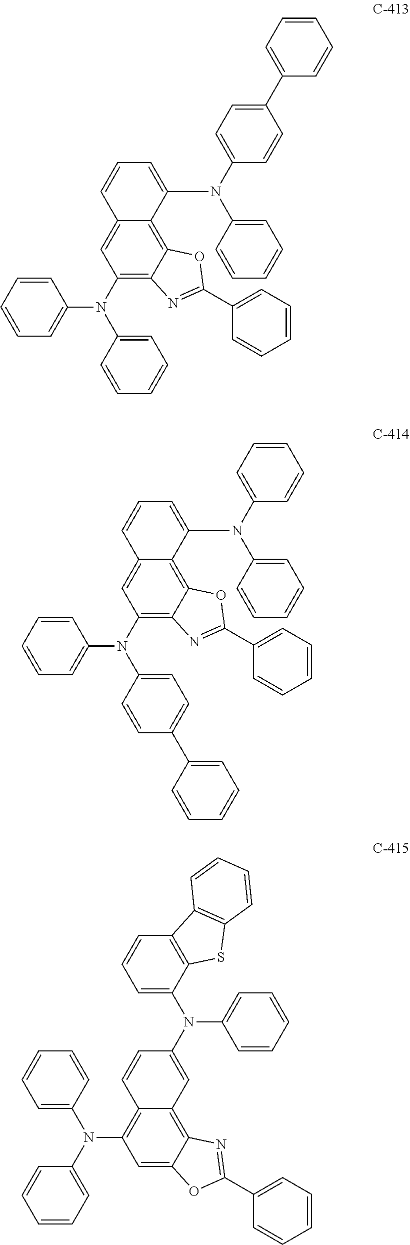

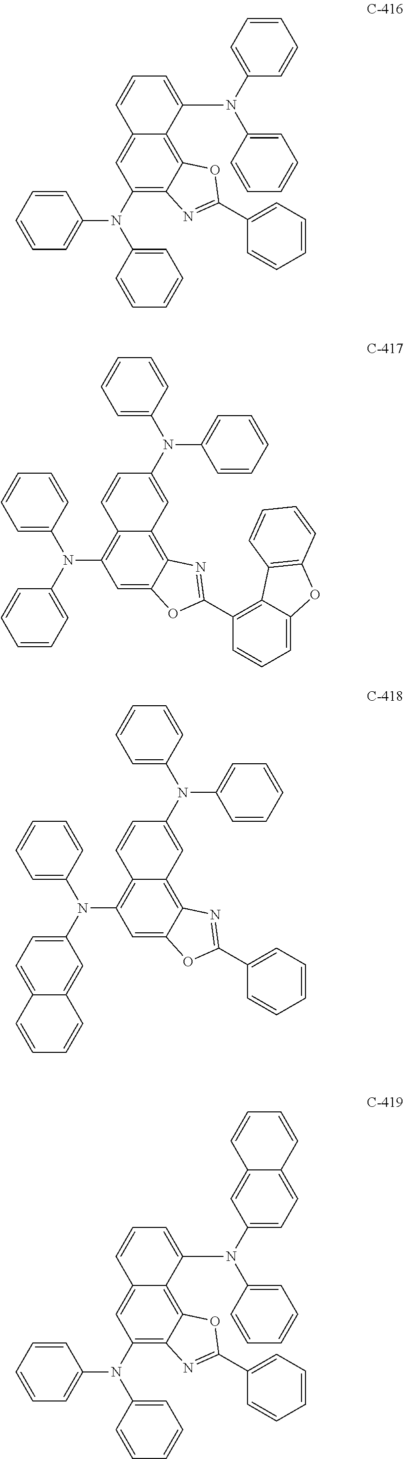 [SMILES: c1ccc(-c2nc3c(N(c4ccccc4)c4ccccc4)cc4cccc(N(c5ccccc5)c5ccccc5)c4c3o2)cc1 ; c1ccc(N(c2ccccc2)c2ccc3c(N(c4ccccc4)c4ccccc4)cc4oc(-c5cccc6oc7ccccc7c56)nc4c3c2)cc1 ; c1ccc(-c2nc3c(cc(N(c4ccccc4)c4ccc5ccccc5c4)c4ccc(N(c5ccccc5)c5ccccc5)cc43)o2)cc1 ; c1ccc(-c2nc3c(N(c4ccccc4)c4ccccc4)cc4cccc(N(c5ccccc5)c5ccc6ccccc6c5)c4c3o2)cc1]

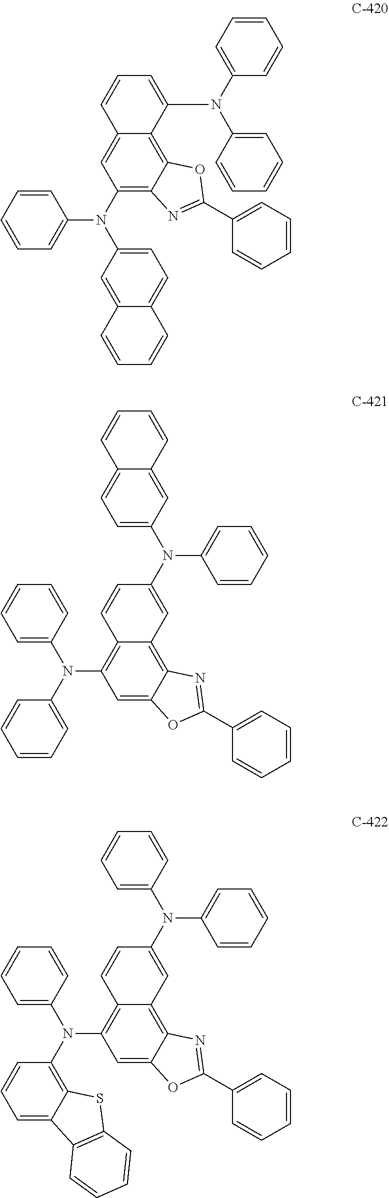 [SMILES: c1ccc(-c2nc3c(N(c4ccccc4)c4ccc5ccccc5c4)cc4cccc(N(c5ccccc5)c5ccccc5)c4c3o2)cc1 ; c1ccc(-c2nc3c(cc(N(c4ccccc4)c4ccccc4)c4ccc(N(c5ccccc5)c5ccc6ccccc6c5)cc43)o2)cc1 ; c1ccc(-c2nc3c(cc(N(c4ccccc4)c4cccc5c4sc4ccccc45)c4ccc(N(c5ccccc5)c5ccccc5)cc43)o2)cc1]

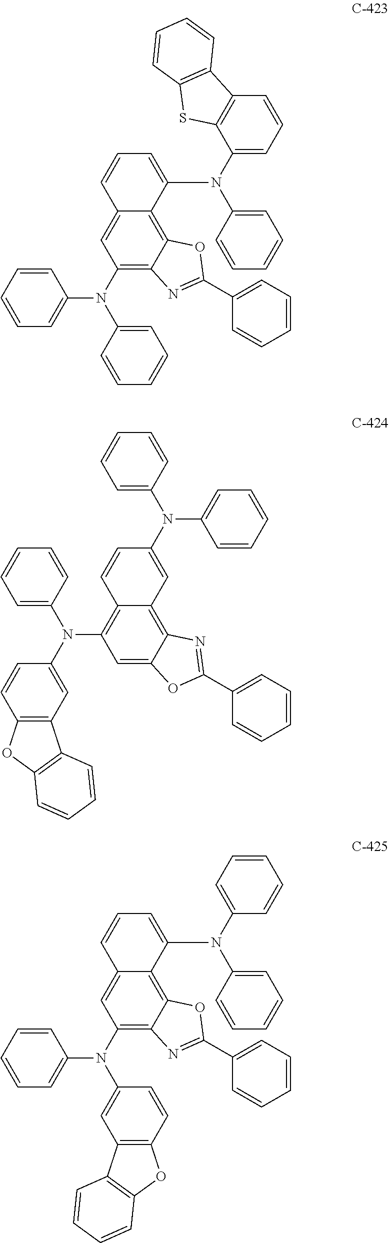 [SMILES: c1ccc(-c2nc3c(N(c4ccccc4)c4ccccc4)cc4cccc(N(c5ccccc5)c5cccc6c5sc5ccccc56)c4c3o2)cc1 ; c1ccc(-c2nc3c(cc(N(c4ccccc4)c4ccc5oc6ccccc6c5c4)c4ccc(N(c5ccccc5)c5ccccc5)cc43)o2)cc1 ; c1ccc(-c2nc3c(N(c4ccccc4)c4ccc5oc6ccccc6c5c4)cc4cccc(N(c5ccccc5)c5ccccc5)c4c3o2)cc1]

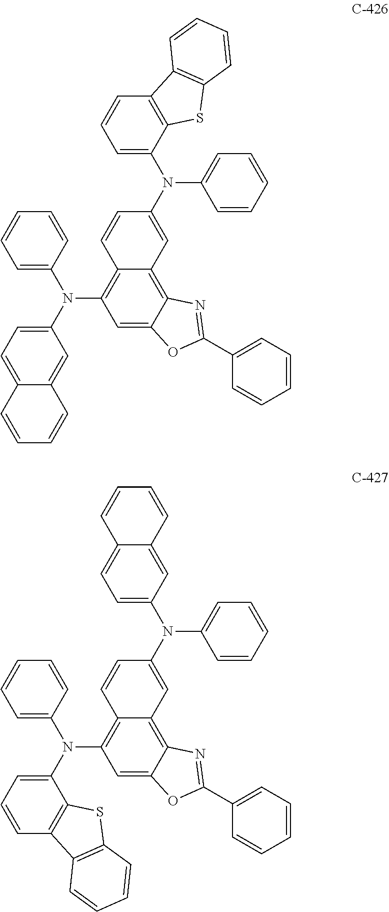 [SMILES: c1ccc(-c2nc3c(cc(N(c4ccccc4)c4ccc5ccccc5c4)c4ccc(N(c5ccccc5)c5cccc6c5sc5ccccc56)cc43)o2)cc1 ; c1ccc(-c2nc3c(cc(N(c4ccccc4)c4cccc5c4sc4ccccc45)c4ccc(N(c5ccccc5)c5ccc6ccccc6c5)cc43)o2)cc1]

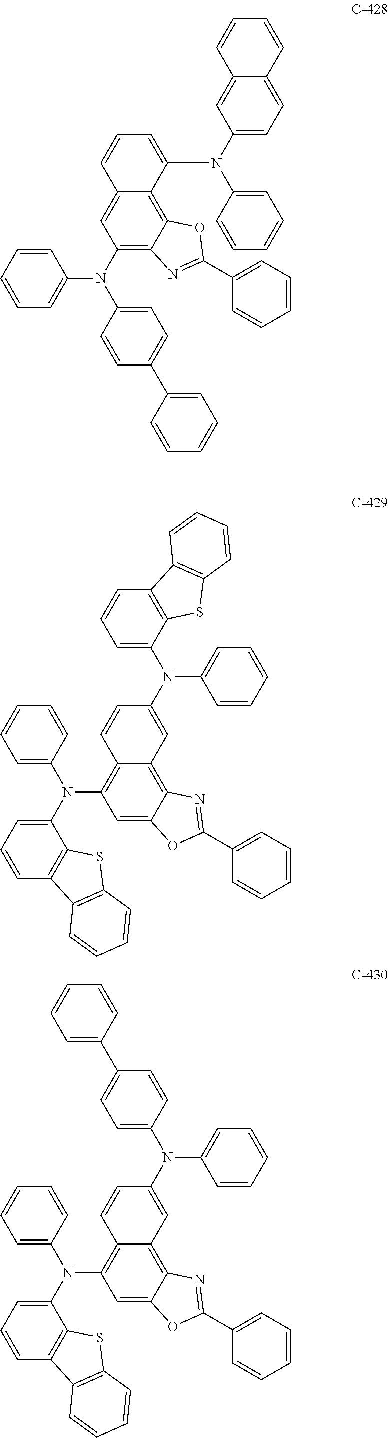

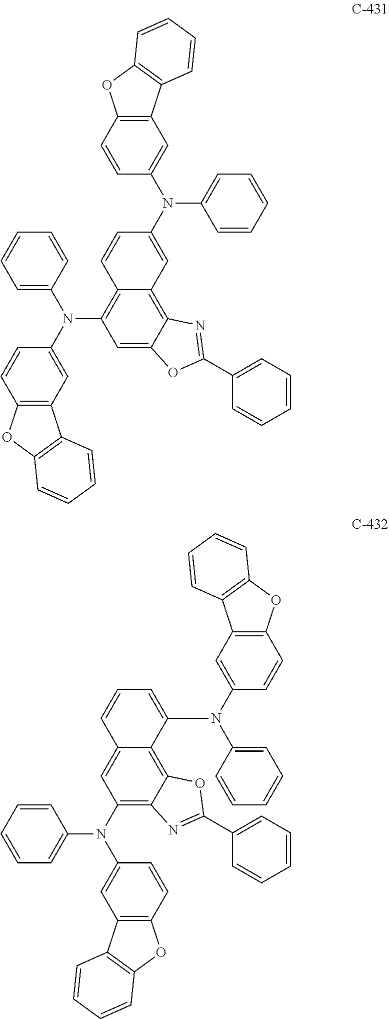 [SMILES: c1ccc(-c2nc3c(cc(N(c4ccccc4)c4ccc5oc6ccccc6c5c4)c4ccc(N(c5ccccc5)c5ccc6oc7ccccc7c6c5)cc43)o2)cc1 ; c1ccc(-c2nc3c(N(c4ccccc4)c4ccc5oc6ccccc6c5c4)cc4cccc(N(c5ccccc5)c5ccc6oc7ccccc7c6c5)c4c3o2)cc1]

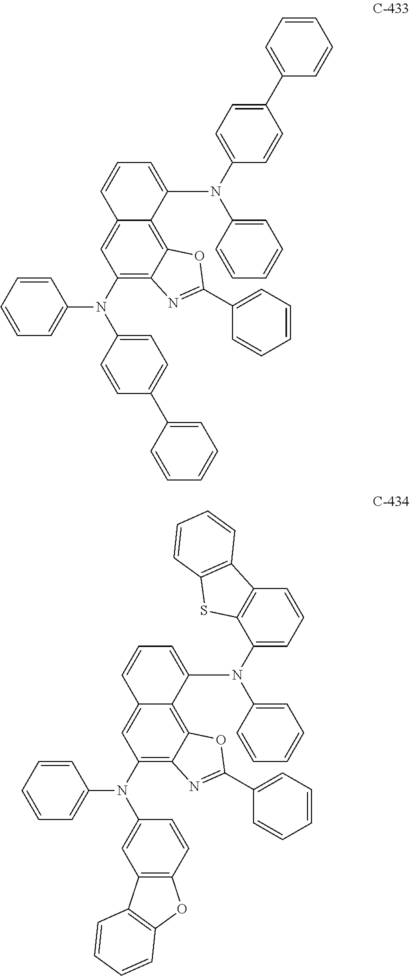

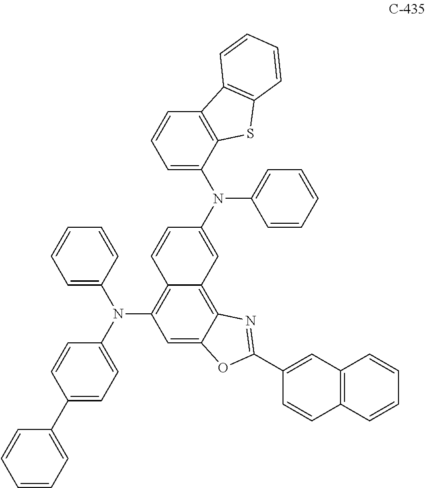 [SMILES: c1ccc(-c2ccc(N(c3ccccc3)c3cc4oc(-c5ccc6ccccc6c5)nc4c4cc(N(c5ccccc5)c5cccc6c5sc5ccccc56)ccc34)cc2)cc1]

13. An organic electroluminescent device comprising an anode; a cathode; and at least one light-emitting layer between the anode and the cathode, wherein the at least one light-emitting layer comprises the plurality of host materials according to claim 1.

14. An organic electroluminescent material comprising the organic electroluminescent compound according to claim 10.

15. An organic electroluminescent device comprising the organic electroluminescent compound according to claim 10.
